(19) United States
(12) Patent Application Publication
(10) Pub. No.: US 2023/0209998 A1
(43) Pub. Date: Jun. 29, 2023

(54) ORGANIC ELECTROLUMINESCENCE DEVICE, AND ELECTRONIC APPARATUS

(71) Applicant: IDEMITSU KOSAN CO.,LTD., Tokyo (JP)

(72) Inventors: Ryota TAKAHASHI, Tokyo (JP); Yoshinori AOYAMA, Tokyo (JP); Sayaka MIZUTANI, Tokyo (JP); Masato MITANI, Tokyo (JP); Tomonori NAKAMURA, Tokyo (JP)

(73) Assignee: IDEMITSU KOSAN CO.,LTD., Tokyo (JP)

(21) Appl. No.: 18/081,365

(22) Filed: Dec. 14, 2022

(30) Foreign Application Priority Data
Dec. 22, 2021 (JP) 2021-208486

(51) Int. Cl. H10K 85/60; C09K 11/06

(52) U.S. Cl. CPC H10K 85/626; C09K 11/06; H10K 85/615; H10K 85/6572; H10K 85/6574; H10K 85/622; H10K 50/165

(57) ABSTRACT

An organic electroluminescence device including a cathode, an anode, and one or two or more organic layers arranged between the cathode and the anode, wherein at least one layer of the one or two or more organic layers includes a first component and a second component, the first component is a compound represented by the following formula (1), and the second component is a compound represented by the following formula (2).

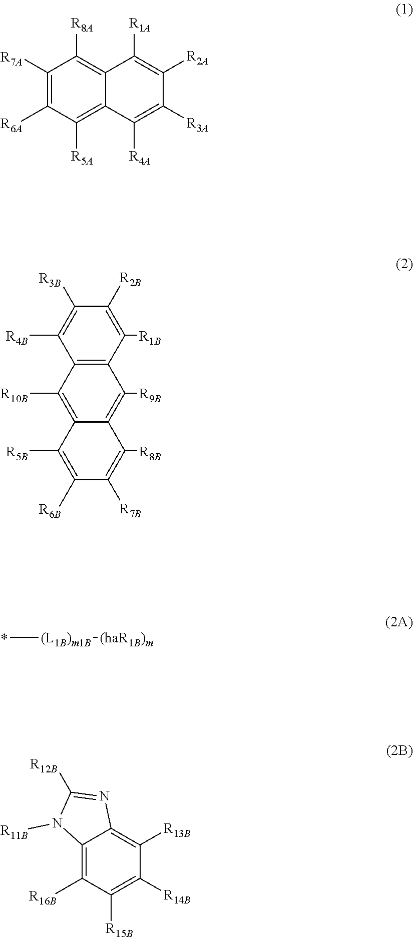

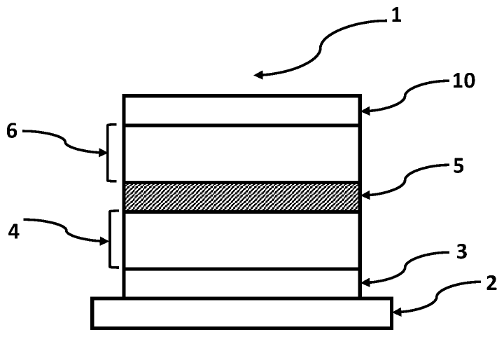

### TECHNICAL FIELD

Embodiments described in the present specification generally relate to an organic electroluminescence device and an electronic apparatus.

### BACKGROUND ART

When voltage is applied to an organic electroluminescence device (hereinafter, also referred to as an organic EL device), holes and electrons are injected into an emitting layer from an anode and a cathode, respectively. Then, thus injected holes and electrons are recombined in the emitting layer, and excitons are formed therein.

Conventional organic EL devices have not yet had sufficient device performance. Although organic EL devices are gradually improved to enhance the device performance, further performance enhancement is required.

Patent Documents 1 and 2 disclose that a compound having the specific structure is used as an electron-transporting layer in an organic EL device.

### RELATED ART DOCUMENTS

### Patent Documents

[Patent Document 1] WO 2008/062773 A1

[Patent Document 2] JP-A-2003-338377

### SUMMARY OF THE INVENTION

It is an object of the present invention to provide an organic EL device having higher performance.

As a result of intensive studies to achieve the above object, the present inventors have found that an organic EL device having low driving voltage and high efficiency can be obtained by using the specific two components in combination for at least one layer of organic layers of an organic EL device, and have completed the present invention.

According to the present invention, the following organic EL device and the like are provided.
1 An organic electroluminescence device comprising

a cathode,

an anode, and

one or two or more organic layers arranged between the cathode and the anode,

wherein at least one layer of the one or two or more organic layers

comprises a first component and a second component,

the first component is a compound represented by the following formula (1),

the second component is a compound represented by the following formula (2):

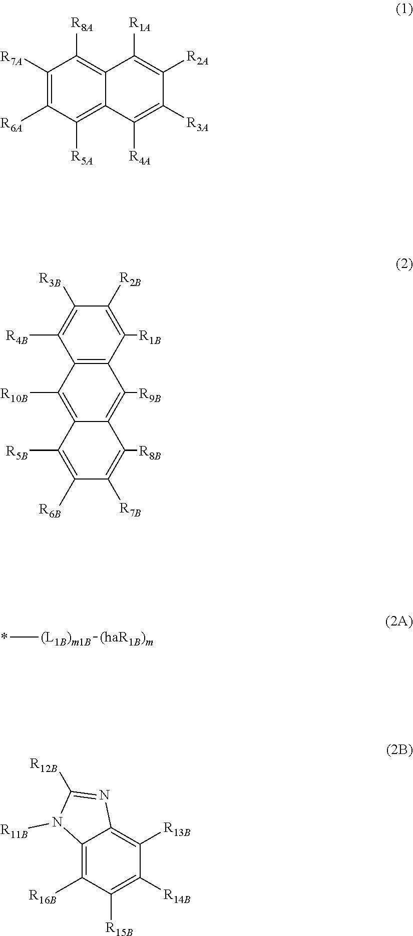

wherein in the formula (1),

one or more sets of the adjacent two or more of R_{1A} to R_{8A} form a substituted or unsubstituted single ring by bonding with each other, or form a substituted or unsubstituted fused ring by bonding with each other;

provided that when at least one set of a set of R_{4A} and R_{5A}, and a set of R_{8A} and R_{1A} is bonded, it is excluded that the compound represented by the formula (1) is a compound having a structure represented by the following formula (1A):

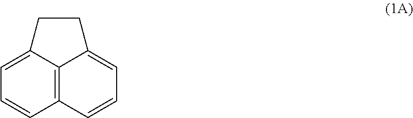 [SMILES: c1cc2c3c(cccc3c1)CC2]

R_{1A} to R_{8A} which do not form the substituted or unsubstituted single ring and which do not form the substituted or unsubstituted fused ring are independently a hydrogen atom or a substituent R;

the substituent R is

a substituted or unsubstituted alkyl group having 1 to 50 carbon atoms,

a substituted or unsubstituted alkenyl group having 2 to 50 carbon atoms,

a substituted or unsubstituted alkynyl group having 2 to 50 carbon atoms,

a substituted or unsubstituted cycloalkyl group having 3 to 50 ring carbon atoms,

—Si(R₉₀₁)(R₉₀₂)(R₉₀₃),

—O—(R₉₀₄),

—S—(R₉₀₅),

—N(R₉₀₆)(R₉₀₇)

(wherein R₉₀₁ to R₉₀₇ are independently

a hydrogen atom,

a substituted or unsubstituted alkyl group having 1 to 50 carbon atoms,

a substituted or unsubstituted cycloalkyl group having 3 to 50 ring carbon atoms,

a substituted or unsubstituted aryl group having 6 to 50 ring carbon atoms, or

a substituted or unsubstituted monovalent heterocyclic group having 5 to 50 ring atoms;
when two or more of each of R₉₀₁ to R₉₀₇ are present, the two or more of each of R₉₀₁ to R₉₀₇ may be the same as or different from each other),

a halogen atom, a cyano group, a nitro group,

a substituted or unsubstituted aryl group having 6 to 50 ring carbon atoms, or

a substituted or unsubstituted monovalent heterocyclic group having 5 to 50 ring atoms;

when two or more substituents R are present, the two or more substituents R may be the same as or different from each other;

provided that the compound represented by the formula (1) does not have a structure represented by the following formula (1 B), a structure represented by the following formula (1C), and a structure represented by the following formula (1 D) within a molecular thereof:

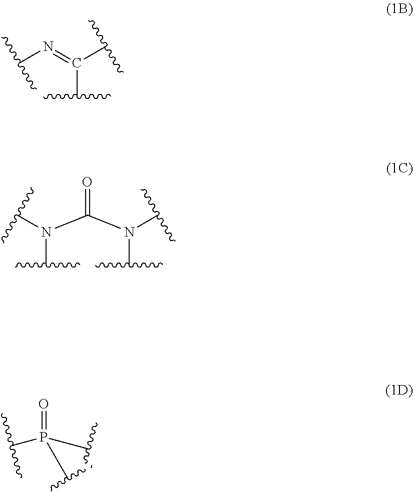 [SMILES: *N=C(*)* ; *N(*)C(=O)N(*)* ; *P(*)(*)=O]

wherein in the formula (2),

at least one of R_{1B} to R_{10B} is a group represented by the formula (2A);

one or more sets of the adjacent two or more of R_{1B} to R_{10B} which are not the group represented by the formula (2A) form a substituted or unsubstituted single ring by bonding with each other, form a substituted or unsubstituted fused ring by bonding with each other, or do not bond with each other;

R_{1B} to R_{10B} which are not the group represented by the formula (2A) and which do not bond with each other are independently a hydrogen atom or a substituent R;

in the formula (2A),

HAr_{1B} is a group represented by the formula (2B); m is an integer of 1 to 5; when two or more HAr_{1B}'s are present, the two or more HAr_{1B}'s may be the same as or different from each other;

m1B is an integer of 0 to 3; when m1 B is 0, m is 1 and HAr_{1B} is directly bonded with the anthracene skeleton in the formula (2) via a single bond; when m1B is 2 or 3, a plurality of L_{1B}'s is linked in series with each other and HAr_{1B} is bonded with L_{1B} which is farthest from the anthracene skeleton; when two or more L_{1B}'s are present, one or more sets of the adjacent two or more of the two or more L_{1B}'s form a substituted or unsubstituted single ring by bonding with each other, form a substituted or unsubstituted fused ring by bonding with each other, or do not bond with each other; when two or more L_{1B}'s are present, the two or more L_{1B}'s may be the same as or different from each other;

L_{1B} which does not form the ring is

a substituted or unsubstituted aromatic hydrocarbon group having 6 to 30 ring carbon atoms, or

a substituted or unsubstituted heterocyclic group having 5 to 30 ring atoms;

in the formula (2B),

any one of R_{11B} to R_{16B} represents a bond with L_{1B} in the formula (2A); when m1B is 0, any of carbon atoms and nitrogen atoms in the benzimidazole and any of carbon atoms in the anthracene skeleton of the formula (2) are directly bonded via a single bond;

one or more sets of the adjacent two or more of R_{11B} to R_{16B} which do not represent a bond with L_{1B} form a substituted or unsubstituted single ring by bonding with each other, form a substituted or unsubstituted fused ring by bonding with each other, or do not bond with each other;

R_{11B} to R_{16B} which do not represent a bond with L_{1B} and which do not bond with each other are independently a hydrogen atom or a substituent R; and the substituent R is the same as defined in the formula (1).
2. An electronic apparatus, comprising the organic electroluminescence device according to 1.
3. A composition comprising a first component and a second component,

the first component is a compound represented by the following formula (1),

the second component is a compound represented by the following formula (2):

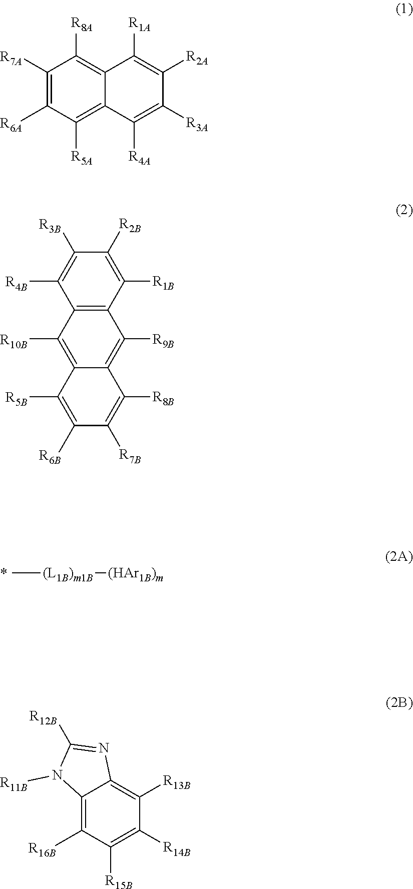

wherein in the formula (1),

one or more sets of the adjacent two or more of R_{1A} to R_{8A} form a substituted or unsubstituted single ring by bonding with each other, or form a substituted or unsubstituted fused ring by bonding with each other;

provided that when at least one set of a set of R_{4A} and R_{5A}, and a set of R_{8A} and R_{1A} is bonded, it is excluded that the compound represented by the formula (1) is a compound having a structure represented by the following formula (1A):

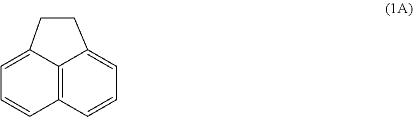 [SMILES: c1cc2c3c(cccc3c1)CC2]

R_{1A} to R_{8A} which do not form the substituted or unsubstituted single ring and which do not form the substituted or unsubstituted fused ring are independently a hydrogen atom or a substituent R;

the substituent R is

a substituted or unsubstituted alkyl group having 1 to 50 carbon atoms,

a substituted or unsubstituted alkenyl group having 2 to 50 carbon atoms,

a substituted or unsubstituted alkynyl group having 2 to 50 carbon atoms,

a substituted or unsubstituted cycloalkyl group having 3 to 50 ring carbon atoms,

—Si(R₉₀₁)(R₉₀₂)(R₉₀₃),

—O—(R₉₀₄),

—S—(R₉₀₅),

—N(R₉₀₆)(R₉₀₇)

(wherein R₉₀₁ to R₉₀₇ are independently

a hydrogen atom,

a substituted or unsubstituted alkyl group having 1 to 50 carbon atoms,

a substituted or unsubstituted cycloalkyl group having 3 to 50 ring carbon atoms,

a substituted or unsubstituted aryl group having 6 to 50 ring carbon atoms, or

a substituted or unsubstituted monovalent heterocyclic group having 5 to 50 ring atoms;
when two or more of each of R₉₀₁ to R₉₀₇ are present, the two or more of each of R₉₀₁ to R₉₀₇ may be the same as or different from each other),

a halogen atom, a cyano group, a nitro group,

a substituted or unsubstituted aryl group having 6 to 50 ring carbon atoms, or

a substituted or unsubstituted monovalent heterocyclic group having 5 to 50 ring atoms;

when two or more substituents R are present, the two or more substituents R may be the same as or different from each other;

provided that the compound represented by the formula (1) does not have a structure represented by the following formula (1 B), a structure represented by the following formula (1C), and a structure represented by the following formula (1 D) within a molecular thereof:

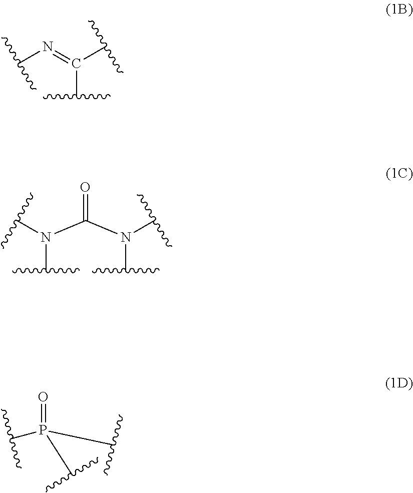 [SMILES: *N=C(*)* ; *N(*)C(=O)N(*)* ; *P(*)(*)=O]

wherein in the formula (2),

at least one of R_{1B} to R_{10B} is a group represented by the formula (2A);

one or more sets of the adjacent two or more of R_{1B} to R_{10B} which are not the group represented by the formula (2A) form a substituted or unsubstituted single ring by bonding with each other, form a substituted or unsubstituted fused ring by bonding with each other, or do not bond with each other;

R_{1B} to R_{10B} which are not the group represented by the formula (2A) and which do not bond with each other are independently a hydrogen atom or a substituent R;

in the formula (2A),

HAr_{1B} is a group represented by the formula (2B); m is an integer of 1 to 5; when two or more HAr_{1B}'s are present, the two or more HAr_{1B}'s may be the same as or different from each other;

L_{1B} is

a substituted or unsubstituted aromatic hydrocarbon group having 6 to 30 ring carbon atoms, or

a substituted or unsubstituted heterocyclic group having 5 to 30 ring atoms;

m1B is an integer of 0 to 3; when m1 B is 0, m is 1 and HAr_{1B} is directly bonded with the anthracene skeleton in the formula (2) via a single bond; when m1B is 2 or 3, a plurality of L_{1B}'s is linked in series with each other and HAr_{1B} is bonded with L_{1B} which is farthest from the anthracene skeleton; when two or more L_{1B}'s are present, the two or more L_{1B}'s may be the same as or different from each other;

in the formula (2B),

any one of R_{11B} to R_{16B} represents a bond with L_{1B} in the formula (2A); when m1B is 0, any of carbon atoms and nitrogen atoms in the benzimidazole and any of carbon atoms in the anthracene skeleton of the formula (2) are directly bonded via a single bond;

one or more sets of the adjacent two or more of R_{11B} to R_{16B} which do not represent a bond with L_{1B} form a substituted or unsubstituted single ring by bonding with each other, form a substituted or unsubstituted fused ring by bonding with each other, or do not bond with each other;

R_{11B} to R_{16B} which do not represent a bond with L_{1B} and which do not bond with each other are independently a hydrogen atom or a substituent R; and

the substituent R is the same as defined in the formula (1).

According to the present invention, there can be provided an organic EL device having higher performance.

### BRIEF DESCRIPTION OF THE DRAWINGS

The FIGURE is a diagram showing a schematic configuration of an organic EL device according to an aspect of the present invention.

### MODE FOR CARRYING OUT THE INVENTION

### [Definition]

In this specification, a hydrogen atom includes its isotopes different in the number of neutrons, namely, a protium, a deuterium and a tritium.

In this specification, at a bondable position in a chemical formula where a symbol such as “R”, or “D” representing a deuterium atom is not indicated, a hydrogen atom, that is, a protium atom, a deuterium atom or a tritium atom is bonded.

In this specification, the number of ring carbon atoms represents the number of carbon atoms forming a subject ring itself among the carbon atoms of a compound having a structure in which atoms are bonded in a ring form (for example, a monocyclic compound, a fused ring compound, a cross-linked compound, a carbocyclic compound, or a heterocyclic compound). When the subject ring is substituted by a substituent, the carbon contained in the substituent is not included in the number of ring carbon atoms. The same shall apply to “the number of ring carbon atoms” described below, unless otherwise specified. For example, a benzene ring has 6 ring carbon atoms, a naphthalene ring includes 10 ring carbon atoms, a pyridine ring includes 5 ring carbon atoms, and a furan ring includes 4 ring carbon atoms. Further, for example, a 9,9-diphenylfluorenyl group includes 13 ring carbon atoms, and a 9,9′-spirobifluorenyl group includes 25 ring carbon atoms.

When a benzene ring is substituted by, for example, an alkyl group as a substituent, the number of carbon atoms of the alkyl group is not included in the number of ring carbon atoms of the benzene ring. Therefore, the number of ring carbon atoms of the benzene ring substituted by the alkyl group is 6. When a naphthalene ring is substituted by, for example, an alkyl group as a substituent, the number of carbon atoms of the alkyl group is not included in the number of ring carbon atoms of the naphthalene ring. Therefore, the number of ring carbon atoms of the naphthalene ring substituted by the alkyl group is 10.

In this specification, the number of ring atoms represents the number of atoms forming a subject ring itself among the atoms of a compound having a structure in which atoms are bonded in a ring form (for example, the structure includes a monocyclic ring, a fused ring and a ring assembly) (for example, a monocyclic compound, a fused ring compound, a cross-linked compound, a carbocyclic compound and a heterocyclic compound). The number of ring atoms does not include atoms which do not form the ring (for example, a hydrogen atom which terminates a bond of the atoms forming the ring), or atoms contained in a substituent when the ring is substituted by the substituent. The same shall apply to “the number of ring atoms” described below, unless otherwise specified. For example, the number of atoms of a pyridine ring is 6, the number of atoms of a quinazoline ring is 10, and the number of a furan ring is 5. For example, hydrogen atoms bonded to a pyridine ring and atoms constituting a substituent substituted on the pyridine ring are not included in the number of ring atoms of the pyridine ring. Therefore, the number of ring atoms of a pyridine ring with which a hydrogen atom or a substituent is bonded is 6. For example, hydrogen atoms and atoms constituting a substituent which are bonded with a quinazoline ring is not included in the number of ring atoms of the quinazoline ring. Therefore, the number of ring atoms of a quinazoline ring with which a hydrogen atom or a substituent is bonded is 10.

In this specification, “XX to YY carbon atoms” in the expression “a substituted or unsubstituted ZZ group including XX to YY carbon atoms” represents the number of carbon atoms in the case where the ZZ group is unsubstituted by a substituent, and does not include the number of carbon atoms of a substituent in the case where the ZZ group is substituted by the substituent. Here, “YY” is larger than “XX”, and “XX” means an integer of 1 or more and “YY” means an integer of 2 or more.

In this specification, “XX to YY atoms” in the expression “a substituted or unsubstituted ZZ group including XX to YY atoms” represents the number of atoms in the case where the ZZ group is unsubstituted by a substituent, and does not include the number of atoms of a substituent in the case where the ZZ group is substituted by the substituent. Here, “YY” is larger than “XX”, and “XX” means an integer of 1 or more and “YY” means an integer of 2 or more.

In this specification, the unsubstituted ZZ group represents the case where the “substituted or unsubstituted ZZ group” is a “ZZ group unsubstituted by a substituent”, and the substituted ZZ group represents the case where the “substituted or unsubstituted ZZ group” is a “ ZZ group substituted by a substituent” .

In this specification, a term “unsubstituted” in the case of “a substituted or unsubstituted ZZ group” means that hydrogen atoms in the ZZ group are not substituted by a substituent. Hydrogen atoms in a term “unsubstituted ZZ group” are a protium atom, a deuterium atom, or a tritium atom.

In this specification, a term “substituted” in the case of “a substituted or unsubstituted ZZ group” means that one or more hydrogen atoms in the ZZ group are substituted by a substituent. Similarly, a term “substituted” in the case of “a BB group substituted by an AA group” means that one or more hydrogen atoms in the BB group are substituted by the AA group.

“Substituent as Described in this Specification”

Hereinafter, the substituent described in this specification will be explained.

The number of ring carbon atoms of the “unsubstituted aryl group” described in this specification is 6 to 50, preferably 6 to 30, and more preferably 6 to 18, unless otherwise specified.

The number of ring atoms of the “unsubstituted heterocyclic group” described in this specification is 5 to 50, preferably 5 to 30, and more preferably 5 to 18, unless otherwise specified.

The number of carbon atoms of the “unsubstituted alkyl group” described in this specification is 1 to 50, preferably 1 to 20, and more preferably 1 to 6, unless otherwise specified.

The number of carbon atoms of the “unsubstituted alkenyl group” described in this specification is 2 to 50, preferably 2 to 20, and more preferably 2 to 6, unless otherwise specified.

The number of carbon atoms of the “unsubstituted alkynyl group” described in this specification is 2 to 50, preferably 2 to 20, and more preferably 2 to 6, unless otherwise specified.

The number of ring carbon atoms of the “unsubstituted cycloalkyl group” described in this specification is 3 to 50, preferably 3 to 20, and more preferably 3 to 6, unless otherwise specified.

The number of ring carbon atoms of the “unsubstituted arylene group” described in this specification is 6 to 50, preferably 6 to 30, and more preferably 6 to 18, unless otherwise specified.

The number of ring atoms of the “unsubstituted divalent heterocyclic group” described in this specification is 5 to 50, preferably 5 to 30, and more preferably 5 to 18, unless otherwise specified.

The number of carbon atoms of the “unsubstituted alkylene group” described in this specification is 1 to 50, preferably 1 to 20, and more preferably 1 to 6, unless otherwise specified.
“Substituted or unsubstituted aryl group”

Specific examples of the “substituted or unsubstituted aryl group” described in this specification (specific example group G1) include the following unsubstituted aryl groups (specific example group G1A), substituted aryl groups (specific example group G1B), and the like. (Here, the unsubstituted aryl group refers to the case where the “substituted or unsubstituted aryl group” is an “ aryl group unsubstituted by a substituent” , and the substituted aryl group refers to the case where the “substituted or unsubstituted aryl group” is an “ aryl group substituted by a substituent” .). In this specification, in the case where simply referred as an “aryl group”, it includes both a “unsubstituted aryl group” and a “substituted aryl group.”

The “substituted aryl group” means a group in which one or more hydrogen atoms of the “unsubstituted aryl group” are substituted by a substituent. Specific examples of the “substituted aryl group” include, for example, groups in which one or more hydrogen atoms of the “unsubstituted aryl group” of the following specific example group G1A are substituted by a substituent, the substituted aryl groups of the following specific example group G1B, and the like. It should be noted that the examples of the “unsubstituted aryl group” and the examples of the “substituted aryl group” enumerated in this specification are mere examples, and the “substituted aryl group” described in this specification also includes a group in which a hydrogen atom bonded with a carbon atom of the aryl group itself in the “substituted aryl group” of the following specific group G1 B is further substituted by a substituent, and a group in which a hydrogen atom of a substituent in the “substituted aryl group” of the following specific group G1B is further substituted by a substituent.
Unsubstituted aryl group (specific example group G1A):

a phenyl group,

a p-biphenyl group,

a m-biphenyl group,

an o-biphenyl group,

a p-terphenyl-4-yl group,

a p-terphenyl-3-yl group,

a p-terphenyl-2-yl group,

a m-terphenyl-4-yl group,

a m-terphenyl-3-yl group,

a m-terphenyl-2-yl group,

an o-terphenyl-4-yl group,

an o-terphenyl-3-yl group,

an o-terphenyl-2-yl group,

a 1-naphthyl group,

a 2-naphthyl group,

an anthryl group,

a benzanthryl group,

a phenanthryl group,

a benzophenanthryl group,

a phenanthryl group,

a benzophenanthryl group,

a phenalenyl group,

a pyrenyl group,

a chrysenyl group,

a benzochrysenyl group,

a triphenylenyl group,

a benzotriphenylenyl group,

a tetracenyl group,

a pentacenyl group,

a fluorenyl group,

a 9,9′-spirobifluorenyl group,

a benzofluorenyl group,

a dibenzofluorenyl group,

a fluoranthenyl group,

a benzofluoranthenyl group,

a perylenyl group, and

a monovalent aryl group derived by removing one hydrogen atom from the ring structures represented by any of the following general formulas (TEMP-1) to (TEMP-15).

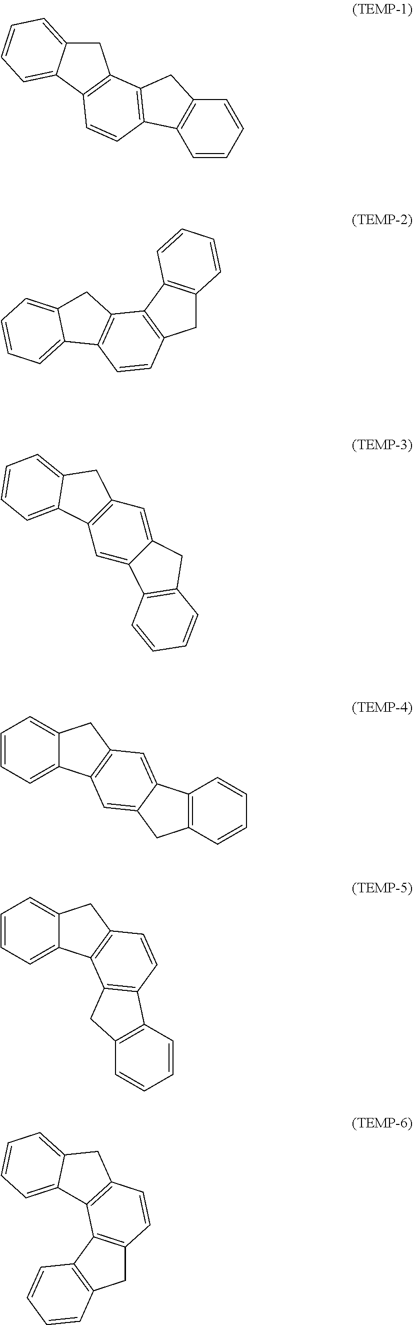

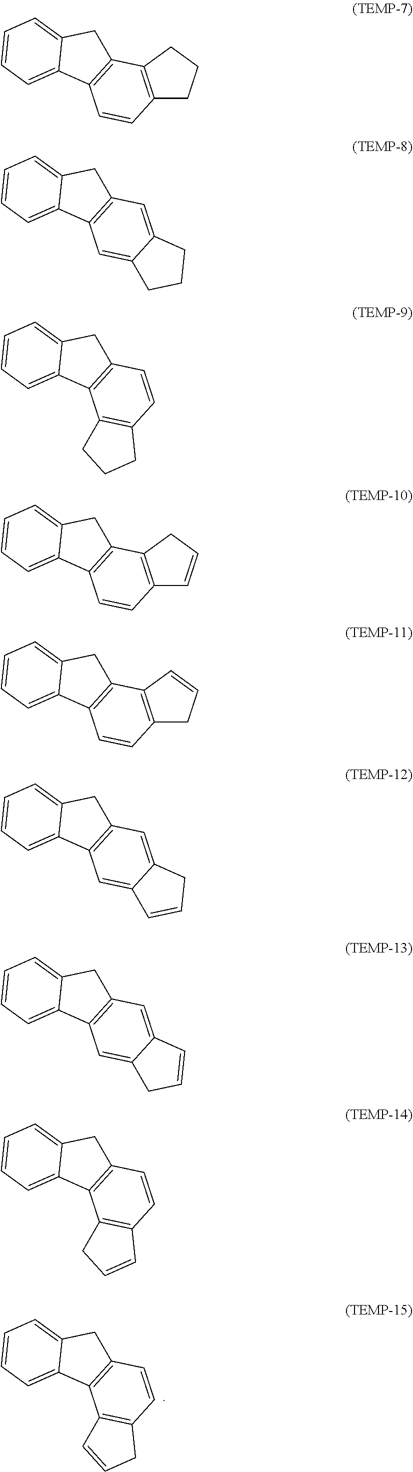

Substituted Aryl Group (Specific Example Group G1B):

an o-tolyl group,

a m-tolyl group,

a p-tolyl group,

a p-xylyl group,

a m-xylyl group,

an o-xylyl group,

a p-isopropylphenyl group,

a m-isopropylphenyl group,

an o-isopropylphenyl group,

a p-t-butylphenyl group,

a m-t-butylphenyl group,

an o-t-butylphenyl group,

a 3,4,5-trimethylphenyl group,

a 9,9-dimethylfluorenyl group,

a 9,9-diphenylfluorenyl group,

a 9,9-bis(4-methylphenyl)fluorenyl group,

a 9,9-bis(4-isopropylphenyl)fluorenyl group,

a 9,9-bis(4-t-butylphenyl)fluorenyl group,

a cyanophenyl group,

a triphenylsilylphenyl group,

a trimethylsilylphenyl group,

a phenylnaphthyl group,

a naphthylphenyl group, and

a group in which one or more hydrogen atoms of a monovalent group derived from the ring structures represented by any of the general formulas (TEMP-1) to (TEMP-15) are substituted by a substituent.
“Substituted or Unsubstituted Heterocyclic Group”

The “heterocyclic group” described in this specification is a ring group having at least one hetero atom in the ring atom. Specific examples of the hetero atom include a nitrogen atom, an oxygen atom, a sulfur atom, a silicon atom, a phosphorus atom, and a boron atom.

The “heterocyclic group” in this specification is a monocyclic group or a fused ring group.

The “heterocyclic group” in this specification is an aromatic heterocyclic group or a non-aromatic heterocyclic group.

Specific examples of the “substituted or unsubstituted heterocyclic group” (specific example group G2) described in this specification include the following unsubstituted heterocyclic group (specific example group G2A), the following substituted heterocyclic group (specific example group G2B), and the like. (Here, the unsubstituted heterocyclic group refers to the case where the “substituted or unsubstituted heterocyclic group” is a “ heterocyclic group unsubstituted by a substituent”, and the substituted heterocyclic group refers to the case where the “substituted or unsubstituted heterocyclic group” is a “ heterocyclic group substituted by a substituent”.). In this specification, in the case where simply referred as a “heterocyclic group”, it includes both the “unsubstituted heterocyclic group” and the “substituted heterocyclic group.”

The “substituted heterocyclic group” means a group in which one or more hydrogen atom of the “unsubstituted heterocyclic group” are substituted by a substituent. Specific examples of the “substituted heterocyclic group” include a group in which a hydrogen atom of “unsubstituted heterocyclic group” of the following specific example group G2A is substituted by a substituent, the substituted heterocyclic groups of the following specific example group G2B, and the like. It should be noted that the examples of the “unsubstituted heterocyclic group” and the examples of the “substituted heterocyclic group” enumerated in this specification are mere examples, and the “substituted heterocyclic group” described in this specification includes groups in which hydrogen atom bonded with a ring atom of the heterocyclic group itself in the “substituted heterocyclic group” of the specific example group G2B is further substituted by a substituent, and a group in which hydrogen atom of a substituent in the “substituted heterocyclic group” of the specific example group G2B is further substituted by a substituent.

Specific example group G2A includes, for example, the following unsubstituted heterocyclic group containing a nitrogen atom (specific example group G2A1), the following unsubstituted heterocyclic group containing an oxygen atom (specific example group G2A2), the following unsubstituted heterocyclic group containing a sulfur atom (specific example group G2A3), and the monovalent heterocyclic group derived by removing one hydrogen atom from the ring structures represented by any of the following general formulas (TEMP-16) to (TEMP-33) (specific example group G2A4).

Specific example group G2B includes, for example, the following substituted heterocyclic group containing a nitrogen atom (specific example group G2B1), the following substituted heterocyclic group containing an oxygen atom (specific example group G2B2), the following substituted heterocyclic group containing a sulfur atom (specific example group G2B3), and the following group in which one or more hydrogen atoms of the monovalent heterocyclic group derived from the ring structures represented by any of the following general formulas (TEMP-16) to (TEMP-33) are substituted by a substituent (specific example group G2B4).
Unsubstituted heterocyclic group containing a nitrogen atom (specific example group G2A1):

a pyrroyl group,

an imidazolyl group,

a pyrazolyl group,

a triazolyl group,

a tetrazolyl group,

an oxazolyl group,

an isoxazolyl group,

an oxadiazolyl group,

a thiazolyl group,

an isothiazolyl group,

a thiadiazolyl group,

a pyridyl group,

a pyridazinyl group,

a pyrazinyl group,

a triazinyl group,

an indolyl group,

an isoindolyl group,

an indolizinyl group,

a quinolizinyl group,

a quinolyl group,

an isoquinolyl group,

a cinnolyl group,

a phthalazinyl group,

a quinazolinyl group,

a quinoxalinyl group,

a benzimidazolyl group,

a indazolyl group,

a phenanthrolinyl group,

a phenanthridinyl group,

an acridinyl group,

a phenazinyl group,

a carbazolyl group,

a benzocarbazolyl group,

a morpholino group,

a phenoxazinyl group,

a phenothiazinyl group,

an azacarbazolyl group, and

a diazacarbazolyl group.
Unsubstituted heterocyclic group containing an oxygen atom (specific example group G2A2):

a furyl group,

an oxazolyl group,

an isoxazolyl group,

an oxadiazolyl group,

a xanthenyl group,

a benzofuranyl group,

an isobenzofuranyl group,

a dibenzofuranyl group,

a naphthobenzofuranyl group,

a benzoxazolyl group,

a benzisoxazolyl group,

a phenoxazinyl group,

a morpholino group,

a dinaphthofuranyl group,

an azadibenzofuranyl group,

a diazadibenzofuranyl group,

an azanaphthobenzofuranyl group, and

a diazanaphthobenzofuranyl group.
Unsubstituted Heterocyclic Group Containing a Sulfur Atom (Specific Example Group G2A3):

a thienyl group,

a thiazolyl group,

an isothiazolyl group,

a thiadiazolyl group,

a benzothiophenyl group (benzothienyl group),

an isobenzothiophenyl group (isobenzothienyl group),

a dibenzothiophenyl group (dibenzothienyl group),

a naphthobenzothiophenyl group (naphthobenzothienyl group),

a benzothiazolyl group,

a benzisothiazolyl group,

a phenothiazinyl group,

a dinaphthothiophenyl group (dinaphthothienyl group),

an azadibenzothiophenyl group (azadibenzothienyl group),

a diazadibenzothiophenyl group (diazadibenzothienyl group),

an azanaphthobenzothiophenyl group (azanaphthobenzothienyl group), and

a diazanaphthobenzothiophenyl group (diazanaphthobenzothienyl group).
Monovalent heterocyclic group derived by removing one hydrogen atom from the ring structures represented by any of the following general formulas (TEMP-16) to (TEMP-33) (specific example group G2A4):

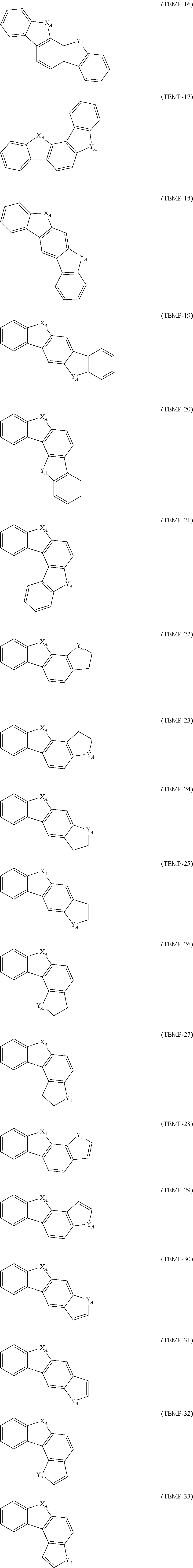

In the general formulas (TEMP-16) to (TEMP-33), X_{A} and Y_{A} are independently an oxygen atom, a sulfur atom, NH, or CH₂. Provided that at least one of X_{A} and Y_{A} is an oxygen atom, a sulfur atom, or NH.

In the general formulas (TEMP-16) to (TEMP-33), when at least one of X_{A} and Y_{A} is NH or CH₂, the monovalent heterocyclic group derived from the ring structures represented by any of the general formulas (TEMP-16) to (TEMP-33) includes a monovalent group derived by removing one hydrogen atom from these NH or CH₂.
Substituted heterocyclic group containing a nitrogen atom (specific example group G2B1):

a (9-phenyl)carbazolyl group,

a (9-biphenylyl)carbazolyl group,

a (9-phenyl)phenylcarbazolyl group,

a (9-naphthyl)carbazolyl group,

a diphenylcarbazol-9-yl group,

a phenylcarbazol-9-yl group,

a methylbenzimidazolyl group,

an ethylbenzimidazolyl group,

a phenyltriazinyl group,

a biphenylyltriazinyl group,

a diphenyltriazinyl group,

a phenylquinazolinyl group, and

a biphenylylquinazolinyl group.
Substituted heterocyclic group containing an oxygen atom (specific example group G2B2):

a phenyldibenzofuranyl group,

a methyldibenzofuranyl group,

a t-butyldibenzofuranyl group, and

a monovalent residue of spiro[9H-xanthene-9,9′-[9H]fluorene].
Substituted heterocyclic group containing a sulfur atom (specific example group G2B3):

a phenyldibenzothiophenyl group,

a methyldibenzothiophenyl group,

a t-butyldibenzothiophenyl group, and

a monovalent residue of spiro[9H-thioxanthene-9,9′-[9H]fluorene].
Group in which one or more hydrogen atoms of the monovalent heterocyclic group derived from the ring structures represented by any of the following general formulas (TEMP-16) to (TEMP-33) are substituted by a substituent (specific example group G2B4):

The “one or more hydrogen atoms of the monovalent heterocyclic group” means one or more hydrogen atoms selected from hydrogen atoms bonded with ring carbon atoms of the monovalent heterocyclic group, a hydrogen atom bonded with a nitrogen atom when at least one of X_{A} and Y_{A} is NH, and hydrogen atoms of a methylene group when one of X_{A} and Y_{A} is CH₂.
“Substituted or unsubstituted alkyl group”

Specific examples of the “substituted or unsubstituted alkyl group” (specific example group G3) described in this specification include the following unsubstituted alkyl groups (specific example group G3A) and the following substituted alkyl groups (specific example group G3B). (Here, the unsubstituted alkyl group refers to the case where the “substituted or unsubstituted alkyl group” is an “ alkyl group unsubstituted by a substituent”, and the substituted alkyl group refers to the case where the “substituted or unsubstituted alkyl group” is an “ alkyl group substituted by a substituent”.). In this specification, in the case where simply referred as an “alkyl group” includes both the “unsubstituted alkyl group” and the “substituted alkyl group.”

The “substituted alkyl group” means a group in which one or more hydrogen atoms in the “unsubstituted alkyl group” are substituted by a substituent. Specific examples of the “substituted alkyl group” include groups in which one or more hydrogen atoms in the following “unsubstituted alkyl group” (specific example group G3A) are substituted by a substituent, the following substituted alkyl group (specific example group G3B), and the like. In this specification, the alkyl group in the “unsubstituted alkyl group” means a linear alkyl group. Thus, the “unsubstituted alkyl group” includes a straight-chain “unsubstituted alkyl group” and a branched-chain “unsubstituted alkyl group”. It should be noted that the examples of the “unsubstituted alkyl group” and the examples of the “substituted alkyl group” enumerated in this specification are mere examples, and the “substituted alkyl group” described in this specification includes a group in which hydrogen atom of the alkyl group itself in the “substituted alkyl group” of the specific example group G3B is further substituted by a substituent, and a group in which hydrogen atom of a substituent in the “substituted alkyl group” of the specific example group G3B is further substituted by a substituent.
Unsubstituted alkyl group (specific example group G3A):

a methyl group,

an ethyl group,

a n-propyl group,

an isopropyl group,

a n-butyl group,

an isobutyl group,

a s-butyl group, and

a t-butyl group.
Substituted alkyl group (specific example group G3B):

a heptafluoropropyl group (including isomers),

a pentafluoroethyl group,

a 2,2,2-trifluoroethyl group, and

a trifluoromethyl group.
“Substituted or unsubstituted alkenyl group”

Specific examples of the “substituted or unsubstituted alkenyl group” described in this specification (specific example group G4) include the following unsubstituted alkenyl group (specific example group G4A), the following substituted alkenyl group (specific example group G4B), and the like. (Here, the unsubstituted alkenyl group refers to the case where the “substituted or unsubstituted alkenyl group” is a “ alkenyl group unsubstituted by a substituent”, and the “substituted alkenyl group” refers to the case where the “substituted or unsubstituted alkenyl group” is a “ alkenyl group substituted by a substituent.”). In this specification, in the case where simply referred as an “alkenyl group” includes both the “unsubstituted alkenyl group” and the “substituted alkenyl group.”

The “substituted alkenyl group” means a group in which one or more hydrogen atoms in the “unsubstituted alkenyl group” are substituted by a substituent. Specific examples of the “substituted alkenyl group” include a group in which the following “unsubstituted alkenyl group” (specific example group G4A) has a substituent, the following substituted alkenyl group (specific example group G4B), and the like. It should be noted that the examples of the “unsubstituted alkenyl group” and the examples of the “substituted alkenyl group” enumerated in this specification are mere examples, and the “substituted alkenyl group” described in this specification includes a group in which a hydrogen atom of the alkenyl group itself in the “substituted alkenyl group” of the specific example group G4B is further substituted by a substituent, and a group in which a hydrogen atom of a substituent in the “substituted alkenyl group” of the specific example group G4B is further substituted by a substituent.
Unsubstituted alkenyl group (specific example group G4A):

a vinyl group,

an allyl group,

a 1-butenyl group,

a 2-butenyl group, and

a 3-butenyl group.
Substituted alkenyl group (specific example group G4B):

a 1,3-butanedienyl group,

a 1-methylvinyl group,

a 1-methylallyl group,

a 1,1-dimethylallyl group,

a 2-methylally group, and

a 1,2-dimethylallylgroup.
“Substituted or unsubstituted alkynyl group”

Specific examples of the “substituted or unsubstituted alkynyl group” described in this specification (specific example group G5) include the following unsubstituted alkynyl group (specific example group G5A) and the like. (Here, the unsubstituted alkynyl group refers to the case where the “substituted or unsubstituted alkynyl group” is an “alkynyl group unsubstituted by a substituent”.). In this specification, in the case where simply referred as an “alkynyl group” includes both the “unsubstituted alkynyl group” and the “substituted alkynyl group.”

The “substituted alkynyl group” means a group in which one or more hydrogen atoms in the “unsubstituted alkynyl group” are substituted by a substituent. Specific examples of the “substituted alkynyl group” include a group in which one or more hydrogen atoms in the following “unsubstituted alkynyl group” (specific example group G5A) are substituted by a substituent, and the like.
Unsubstituted alkynyl group (specific example group G5A):

an ethynyl group.
“Substituted or unsubstituted cycloalkyl group”

Specific examples of the “substituted or unsubstituted cycloalkyl group” described in this specification (specific example group G6) include the following unsubstituted cycloalkyl group (specific example group G6A), the following substituted cycloalkyl group (specific example group G6B), and the like. (Here, the unsubstituted cycloalkyl group refers to the case where the “substituted or unsubstituted cycloalkyl group” is a “ cycloalkyl group unsubstituted by a substituent”, and the substituted cycloalkyl group refers to the case where the “substituted or unsubstituted cycloalkyl group” is a “ cycloalkyl group substituted by a substituent”.). In this specification, in the case where simply referred as a “cycloalkyl group” includes both the “unsubstituted cycloalkyl group” and the “substituted cycloalkyl group.”

The “substituted cycloalkyl group” means a group in which one or more hydrogen atoms in the “unsubstituted cycloalkyl group” are substituted by a substituent. Specific examples of the “substituted cycloalkyl group” include a group in which one or more hydrogen atoms in the following “unsubstituted cycloalkyl group” (specific example group G6A) are substituted by a substituent, and examples of the following substituted cycloalkyl group (specific example group G6B), and the like. It should be noted that the examples of the “unsubstituted cycloalkyl group” and the examples of the “substituted cycloalkyl group” enumerated in this specification are mere examples, and the “substituted cycloalkyl group” in this specification includes a group in which one or more hydrogen atoms bonded with the carbon atom of the cycloalkyl group itself in the “substituted cycloalkyl group ” of the specific example group G6B are substituted by a substituent, and a group in which a hydrogen atom of a substituent in the “substituted cycloalkyl group” of specific example group G6B is further substituted by a substituent.
Unsubstituted cycloalkyl group (specific example group G6A):

a cyclopropyl group,

a cyclobutyl group,

a cyclopentyl group,

a cyclohexyl group,

a 1-adamantyl group,

a 2-adamantyl group,

a 1-norbornyl group, and

a 2-norbornyl group.
Substituted cycloalkyl group (specific example group G6B):

a 4-methylcyclohexyl group.
“Group represented by —Si(R₉₀₁)(R₉₀₂)(R₉₀₃)”

Specific examples of the group represented by —Si(R₉₀₁)(R₉₀₂)(R₉₀₃) described in this specification (specific example group G7) include:

—Si(G1)(G1)(G1),

—Si(G1)(G2)(G2),

—Si(G1)(G1)(G2),

—Si(G2)(G2)(G2),

—Si(G3)(G3)(G3), and

—Si(G6)(G6)(G6).

G1 is the “substituted or unsubstituted aryl group” described in the specific example group G1.

G2 is the “substituted or unsubstituted heterocyclic group” described in the specific example group G2.

G3 is the “substituted or unsubstituted alkyl group” described in the specific example group G3.

G6 is the “substituted or unsubstituted cycloalkyl group” described in the specific example group G6.

Plural G1's in —Si(G1)(G1)(G1) are the same or different. Plural G2's in —Si(G1)(G2)(G2) are the same or different. Plural G1's in —Si(G1)(G1)(G2) are the same or different. Plural G2's in —Si(G2)(G2)(G2) are be the same or different. Plural G3's in —Si(G3)(G3)(G3) are the same or different. Plural G6's in —Si(G6)(G6)(G6) are be the same or different.
“Group represented by —O—(R₉₀₄)”

Specific examples of the group represented by —O—(R₉₀₄) in this specification (specific example group G8) include:

—O(G1),

—O(G2),

—O(G3), and

—O(G6).

G1 is the “substituted or unsubstituted aryl group” described in the specific example group G1.

G2 is the “substituted or unsubstituted heterocyclic group” described in the specific example group G2.

G3 is the “substituted or unsubstituted alkyl group” described in the specific example group G3.

G6 is the “substituted or unsubstituted cycloalkyl group” described in the specific example group G6.
“Group represented by —S—(R₉₀₅)”

Specific examples of the group represented by —S—(R₉₀₅) in this specification (specific example group G9) include:

—S(G1),

—S(G2),

—S(G3), and

—S(G6).

G1 is the “substituted or unsubstituted aryl group” described in the specific example group G1.

G2 is the “substituted or unsubstituted heterocyclic group” described in the specific example group G2.

G3 is the “substituted or unsubstituted alkyl group” described in the specific example group G3.

G6 is the “substituted or unsubstituted cycloalkyl group” described in the specific example group G6.
“Group represented by —N(R₉₀₆)(R₉₀₇)”

Specific examples of the group represented by —N(R₉₀₆)(R₉₀₇) in this specification (specific example group G10) include:

—N(G1)(G1),

—N(G2)(G2),

—N(G1)(G2),

—N(G3)(G3), and

—N(G6)(G6).

G1 is the “substituted or unsubstituted aryl group” described in the specific example group G1.

G2 is the “substituted or unsubstituted heterocyclic group” described in the specific example group G2.

G3 is the “substituted or unsubstituted alkyl group” described in the specific example group G3.

G6 is the “substituted or unsubstituted cycloalkyl group” described in the specific example group G6.

Plural G1's in —N(G1)(G1) are the same or different.

Plural G2's in —N(G2)(G2) are the same or different.

Plural G3's in —N(G3)(G3) are the same or different.

Plural G6's in —N(G6)(G6) are the same or different.
“Halogen atom”

Specific examples of the “halogen atom” described in this specification (specific example group G11) include a fluorine atom, a chlorine atom, a bromine atom, an iodine atom, and the like.
“Substituted or unsubstituted fluoroalkyl group”

The “substituted or unsubstituted fluoroalkyl group” described in this specification is a group in which at least one hydrogen atom bonded with a carbon atom constituting the alkyl group in the “substituted or unsubstituted alkyl group” is substituted by a fluorine atom, and includes a group in which all hydrogen atoms bonded with a carbon atom constituting the alkyl group in the “substituted or unsubstituted alkyl group” are substituted by a fluorine atom (a perfluoro group). The number of carbon atoms of the “unsubstituted fluoroalkyl group” is 1 to 50, preferably 1 to 30, more preferably 1 to 18, unless otherwise specified in this specification. The “substituted fluoroalkyl group” means a group in which one or more hydrogen atoms of the “fluoroalkyl group” are substituted by a substituent. The “substituted fluoroalkyl group” described in this specification also includes a group in which one or more hydrogen atoms bonded with a carbon atom of the alkyl chains in the “substituted fluoroalkyl group” are further substituted by a substituent, and a group in which one or more hydrogen atom of a substituent in the “substituted fluoroalkyl group” are further substituted by a substituent. Specific examples of the “unsubstituted fluoroalkyl group” include a group in which one or more hydrogen atoms in the “alkyl group” (specific group G3) are substituted by a fluorine atom, and the like.
“Substituted or unsubstituted haloalkyl group”

The “substituted or unsubstituted haloalkyl group” described in this specification is a group in which at least one hydrogen atom bonded with a carbon atom constituting the alkyl group in the “substituted or unsubstituted alkyl group” is substituted by a halogen atom, and also includes a group in which all hydrogen atoms bonded with a carbon atom constituting the alkyl group in the “substituted or unsubstituted alkyl group” are substituted by a halogen atom. The number of carbon atoms of the “unsubstituted haloalkyl group” is 1 to 50, preferably 1 to 30, more preferably 1 to 18, unless otherwise specified in this specification. The “substituted haloalkyl group” means a group in which one or more hydrogen atoms of the “haloalkyl group” are substituted by a substituent. The “substituted haloalkyl group” described in this specification also includes a group in which one or more hydrogen atoms bonded with a carbon atom of the alkyl chain in the “substituted haloalkyl group” are further substituted by a substituent, and a group in which one or more hydrogen atoms of a substituent in the “substituted haloalkyl group” are further substituted by a substituent. Specific examples of the “unsubstituted haloalkyl group” include a group in which one or more hydrogen atoms in the “alkyl group” (specific example group G3) are substituted by a halogen atom, and the like. A haloalkyl group is sometimes referred to as an alkyl halide group.
“Substituted or unsubstituted alkoxy group”

Specific examples of the “substituted or unsubstituted alkoxy group” described in this specification include a group represented by —O(G3), wherein G3 is the “substituted or unsubstituted alkyl group” described in the specific example group G3. The number of carbon atoms of the “unsubstituted alkoxy group” is 1 to 50, preferably 1 to 30, more preferably 1 to 18, unless otherwise specified in this specification.
“Substituted or unsubstituted alkylthio group”

Specific examples of the “substituted or unsubstituted alkylthio group” described in this specification include a group represented by —S(G3), wherein G3 is the “substituted or unsubstituted alkyl group” described in the specific example group G3. The number of carbon atoms of the “unsubstituted alkylthio group” is 1 to 50, preferably 1 to 30, more preferably 1 to 18, unless otherwise specified in this specification.
“Substituted or unsubstituted aryloxy group”

Specific examples of the “substituted or unsubstituted aryloxy group” described in this specification include a group represented by —O(G1), wherein G1 is the “substituted or unsubstituted aryl group” described in the specific example group G1. The number of ring carbon atoms of the “unsubstituted aryloxy group” is 6 to 50, preferably 6 to 30, more preferably 6 to 18, unless otherwise specified in this specification.
“Substituted or unsubstituted arylthio group”

Specific examples of the “substituted or unsubstituted arylthio group” described in this specification include a group represented by —S(G1), wherein G1 is a “substituted or unsubstituted aryl group” described in the specific example group G1. The number of ring carbon atoms of the “unsubstituted arylthio group” is 6 to 50, preferably 6 to 30, more preferably 6 to 18, unless otherwise specified in this specification.
“Substituted or unsubstituted trialkylsilyl group”

Specific examples of the “trialkylsilyl group” described in this specification include a group represented by —Si(G3)(G3)(G3), where G3 is the “substituted or unsubstituted alkyl group” described in the specific example group G3. Plural G3's in —Si(G3)(G3)(G3) are the same or different. The number of carbon atoms in each alkyl group of the “trialkylsilyl group” is 1 to 50, preferably 1 to 20, more preferably 1 to 6, unless otherwise specified in this specification.
“Substituted or unsubstituted aralkyl group”

Specific examples of the “substituted or unsubstituted aralkyl group” described in this specification is a group represented by -(G3)-(G1), wherein G3 is the “substituted or unsubstituted alkyl group” described in the specific example group G3, and G1 is the “substituted or unsubstituted aryl group” described in the specific example group G1. Therefore, the “aralkyl group” is a group in which a hydrogen atom of the “alkyl group” is substituted by an “aryl group” as a substituent, and is one form of the “substituted alkyl group.” The “unsubstituted aralkyl group” is the “unsubstituted alkyl group” substituted by the “unsubstituted aryl group”, and the number of carbon atoms of the “unsubstituted aralkyl group” is 7 to 50, preferably 7 to 30, more preferably 7 to 18, unless otherwise specified in this specification.

Specific examples of the “substituted or unsubstituted aralkyl group” include a benzyl group, a 1-phenylethyl group, a 2-phenylethyl group, a 1-phenylisopropyl group, a 2-phenylisopropyl group, a phenyl-t-butyl group, an a-naphthylmethyl group, a 1-a-naphthylethyl group, a 2-α-naphthylethyl group, a 1-α-naphthylisopropyl group, a 2-α-naphthylisopropyl group, a β-naphthylmethyl group, a 1-β-naphthylethyl group, a 2-β-naphthylethyl group, a 1-β-naphthylisopropyl group, a 2-β-naphthylisopropyl group, and the like.

Unless otherwise specified in this specification, examples of the substituted or unsubstituted aryl group described in this specification preferably include a phenyl group, a p-biphenyl group, a m-biphenyl group, an o-biphenyl group, a p-terphenyl-4-yl group, a p-terphenyl-3-yl group, a p-terphenyl-2-yl group, a m-terphenyl-4-yl group, a m-terphenyl-3-yl group, a m-terphenyl yl group, an o-terphenyl-4-yl group, an o-terphenyl-3-yl group, an o-terphenyl-2-yl group, a 1-naphthyl group, a 2-naphthyl group, an anthryl group, a phenanthryl group, a pyrenyl group, a chrysenyl group, a triphenylenyl group, a fluorenyl group, a 9,9′-spirobifluorenyl group, 9,9-dimethylfluorenyl group, 9,9-diphenylfluorenyl group, and the like.

Unless otherwise specified in this specification, examples of the substituted or unsubstituted heterocyclic groups described in this specification preferably include a pyridyl group, a pyrimidinyl group, a triazinyl group, a quinolyl group, an isoquinolyl group, a quinazolinyl group, a benzimidazolyl group, a phenanthrolinyl group, a carbazolyl group (a 1-carbazolyl group, a 2-carbazolyl group, a 3-carbazolyl group, a 4-carbazolyl group, or a 9-carbazolyl group), a benzocarbazolyl group, an azacarbazolyl group, a diazacarbazolyl group, a dibenzofuranyl group, a naphthobenzofuranyl group, an azadibenzofuranyl group, a diazadibenzofuranyl group, a dibenzothiophenyl group, a naphthobenzothiophenyl group, an azadibenzothiophenyl group, a diazadibenzothiophenyl group, a (9-phenyl)carbazolyl group (a (9-phenyl)carbazol-1-yl group, a (9-phenyl)carbazol-2-yl group, a (9-phenyl)carbazol-3-yl group, or a (9-phenyl)carbazol-4-yl group), a (9-biphenylyl)carbazolyl group, a (9-phenyl)phenylcarbazolyl group, a diphenylcarbazol-9-yl group, a phenylcarbazol-9-yl group, a phenyltriazinyl group, a biphenylyltriazinyl group, a diphenyltriazinyl group, a phenyldibenzofuranyl group, a phenyldibenzothiophenyl group, and the like.

In this specification, the carbazolyl group is specifically any of the following groups, unless otherwise specified in this specification.

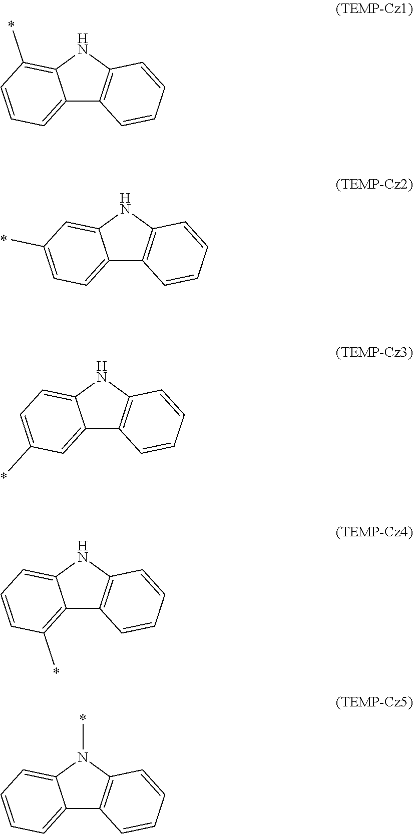

In this specification, the (9-phenyl)carbazolyl group is specifically any of the following groups, unless otherwise specified in this specification.

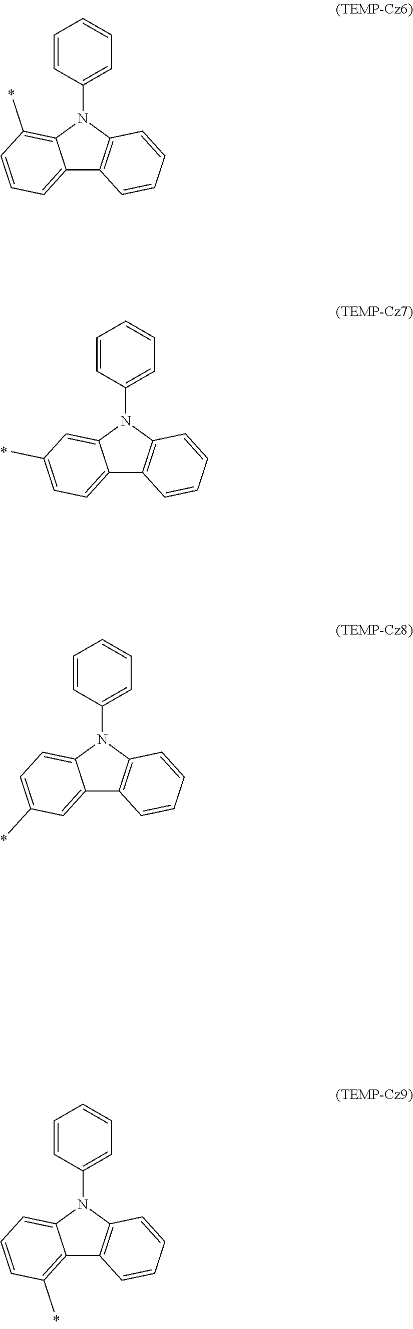 [SMILES: Cc1cccc2c3ccccc3n(-c3ccccc3)c12 ; Cc1ccc2c3ccccc3n(-c3ccccc3)c2c1 ; Cc1ccc2c(c1)c1ccccc1n2-c1ccccc1 ; Cc1cccc2c1c1ccccc1n2-c1ccccc1]

In the general formulas (TEMP-Cz1) to (TEMP-Cz9), * represents a bonding site.

In this specification, the dibenzofuranyl group and the dibenzothiophenyl group are specifically any of the following groups, unless otherwise specified in this specification.

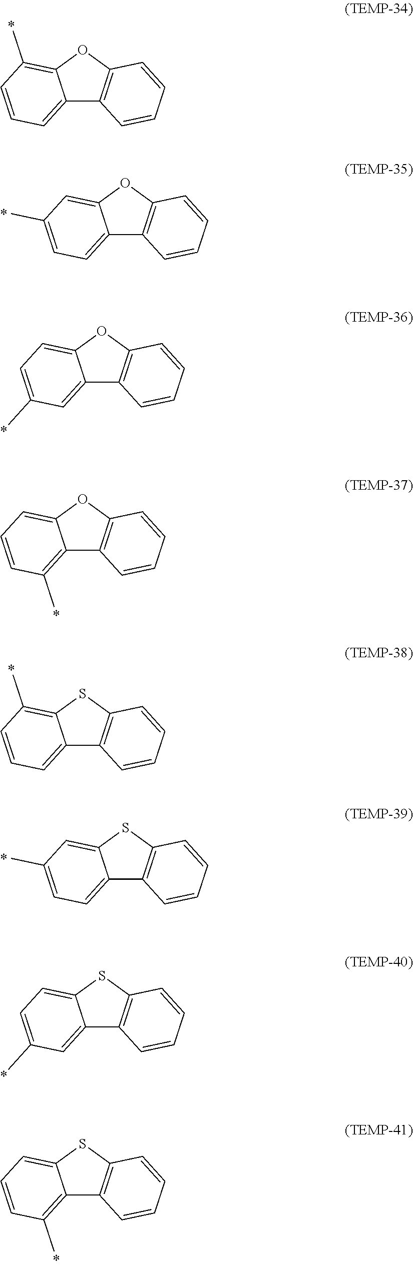

In the general formulas (TEMP-34) to (TEMP-41), * represents a bonding site.

The substituted or unsubstituted alkyl group described in this specification is preferably a methyl group, an ethyl group, a propyl group, an isopropyl group, a n-butyl group, an isobutyl group, a t-butyl group, or the like, unless otherwise specified in this specification.
“Substituted or unsubstituted arylene group”

The “substituted or unsubstituted arylene group” described in this specification is a divalent group derived by removing one hydrogen atom on the aryl ring of the “substituted or unsubstituted aryl group”, unless otherwise specified. Specific examples of the “substituted or unsubstituted arylene group” (specific example group G12) include a divalent group derived by removing one hydrogen atom on the aryl ring of the “substituted or unsubstituted aryl group” described in the specific example group G1, and the like.
“Substituted or unsubstituted divalent heterocyclic group”

The “substituted or unsubstituted divalent heterocyclic group” described in this specification is a divalent group derived by removing one hydrogen atom on the heterocycle of the “substituted or unsubstituted heterocyclic group”, unless otherwise specified. Specific examples of the “substituted or unsubstituted divalent heterocyclic group” (specific example group G13) include a divalent group derived by removing one hydrogen atom on the heterocycle of the “substituted or unsubstituted heterocyclic group” described in the specific example group G2, and the like.
“Substituted or unsubstituted alkylene group”

The “substituted or unsubstituted alkylene group” described in this specification is a divalent group derived by removing one hydrogen atom on the alkyl chain of the “substituted or unsubstituted alkyl group”, unless otherwise specified. Specific examples of the “substituted or unsubstituted alkylene group” (specific example group G14) include a divalent group derived by removing one hydrogen atom on the alkyl chain of the “substituted or unsubstituted alkyl group” described in the specific example group G3, and the like.

The substituted or unsubstituted arylene group described in this specification is preferably any group of the following general formulas (TEMP-42) to (TEMP-68), unless otherwise specified in this specification.

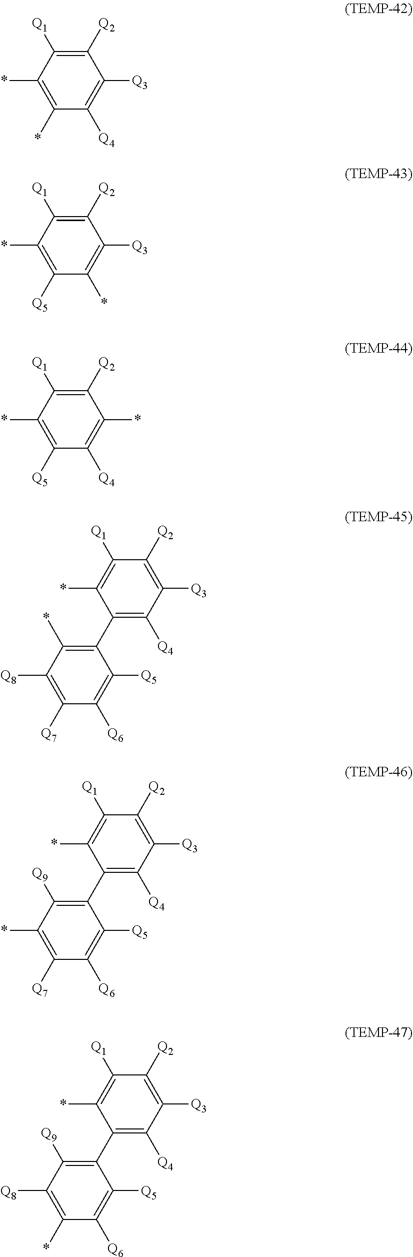

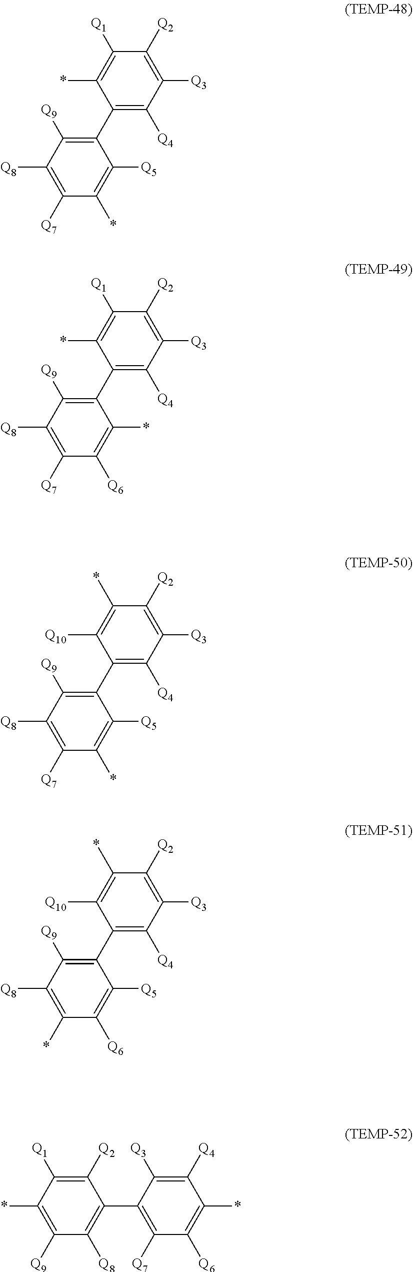

In the general formulas (TEMP-42) to (TEMP-52), Q₁ to Q₁₀ are independently a hydrogen atom or a substituent.

In the general formulas (TEMP-42) to (TEMP-52), * represents a bonding site.

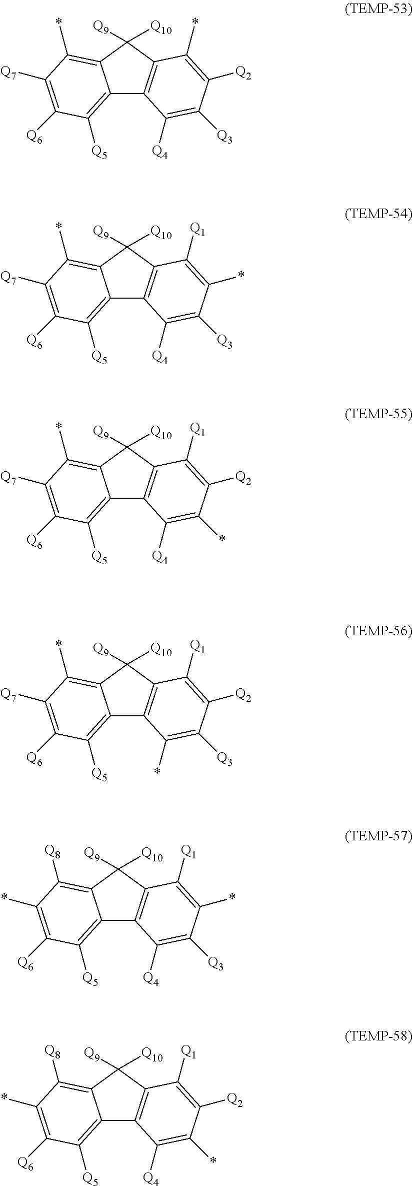

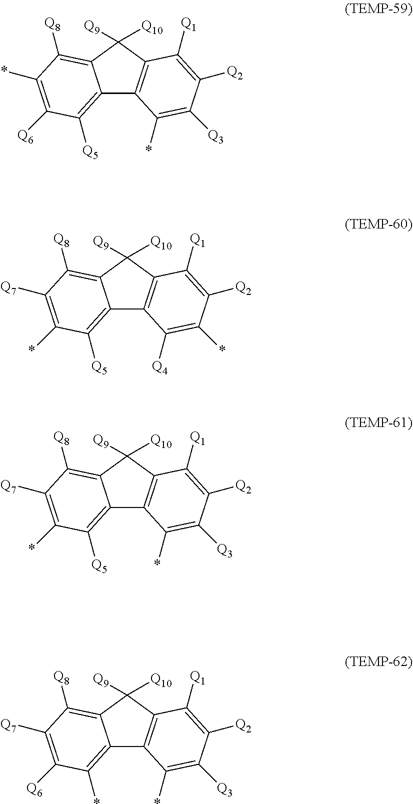

In the general formulas (TEMP-53) to (TEMP-62), Q₁ to Q₁₀ are independently a hydrogen atom or a substituent.

Q₉ and Q₁₀ may be bonded with each other via a single bond to form a ring. In the general formulas (TEMP-53) to (TEMP-62), * represents a bonding site.

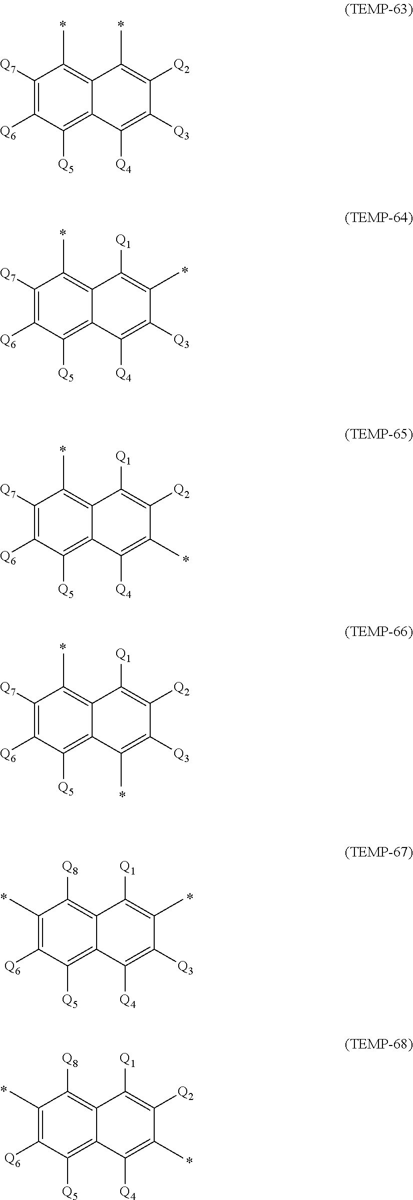

In the general formulas (TEMP-63) to (TEMP-68), Q₁ to Q₈ are independently a hydrogen atom or a substituent.

In the general formulas (TEMP-63) to (TEMP-68), * represents a bonding site.

The substituted or unsubstituted divalent heterocyclic group described in this specification is preferably any group of the following general formulas (TEMP-69) to (TEMP-102), unless otherwise specified in this specification.

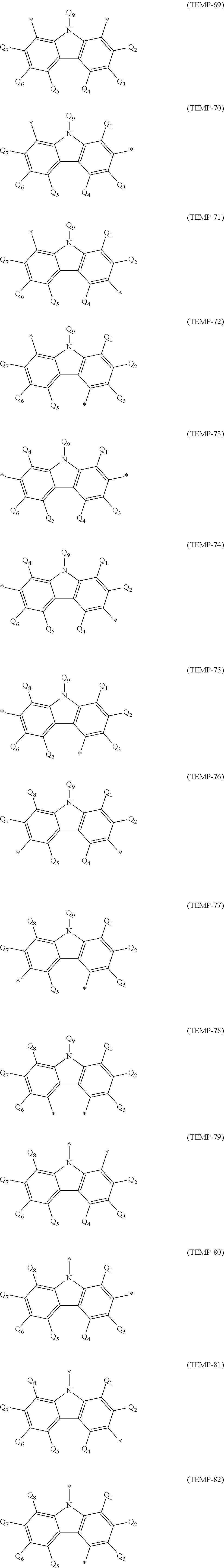

In the general formulas (TEMP-69) to (TEMP-82), Q₁ to Q₉ are independently a hydrogen atom or a substituent.

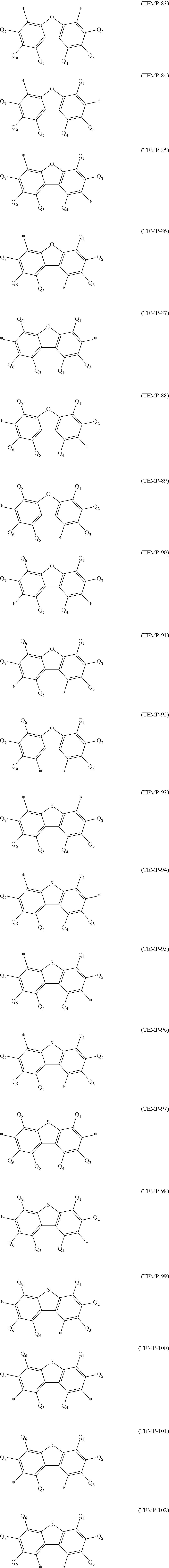

In the general formulas (TEMP-83) to (TEMP-102), Q₁ to Q₈ are independently a hydrogen atom or a substituent.

The above is the explanation of the “Substituent described in this specification.”
“The case where bonded with each other to form a ring”

In this specification, the case where “one or more sets of adjacent two or more form a substituted or unsubstituted monocycle by bonding with each other, form a substituted or unsubstituted fused ring by bonding with each other, or do not bond with each other” means the case where “one or more sets of adjacent two or more form a substituted or unsubstituted monocycle by bonding with each other”; the case where “one or more sets of adjacent two or more form a substituted or unsubstituted fused ring by bonding with each other”; and the case where “one or more sets of adjacent two or more do not bond with each other.”

The case where “one or more sets of adjacent two or more form a substituted or unsubstituted monocycle by bonding with each other” and the case where “one or more sets of adjacent two or more form a substituted or unsubstituted fused ring by bonding with each other” in this specification (these cases may be collectively referred to as “the case where forming a ring by bonding with each other”) will be described below. The case of an anthracene compound represented by the following general formula (TEMP-103) in which the mother skeleton is an anthracene ring will be described as an example.

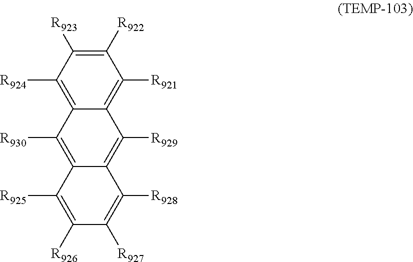

For example, in the case where “one or more sets of adjacent two or more among R₉₂₁ to R₉₃₀ form a ring by bonding with each other”, the one set of adjacent two includes a pair of R₉₂₁ and R₉₂₂, a pair of R₉₂₂ and R₉₂₃, a pair of R₉₂₃ and R₉₂₄, a pair of R₉₂₄ and R₉₃₀, a pair of R₉₃₀ and R₉₂₅, a pair of R₉₂₅ and R₉₂₆, a pair of R₉₂₆ and R₉₂₇, a pair of R₉₂₇ and R₉₂₈, a pair of R₉₂₈ and R₉₂₉, and a pair of R₉₂₉ and R₉₂₁.

The “one or more sets” means that two or more sets of the adjacent two or more sets may form a ring at the same time. For example, R₉₂₁ and R₉₂₂ form a ring Q_{A} by bonding with each other, and at the same, time R₉₂₅ and R₉₂₆ form a ring Q_{B} by bonding with each other, the anthracene compound represented by the general formula (TEMP-103) is represented by the following general formula (TEMP-104).

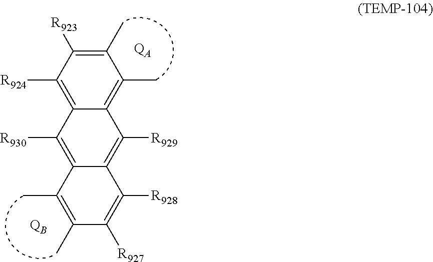

The case where the “set of adjacent two or more” form a ring includes not only the case where the set (pair) of adjacent “two” is bonded with as in the above-mentioned examples, but also the case where the set of adjacent “three or more” are bonded with each other. For example, it means the case where R₉₂₁ and R₉₂₂ form a ring Q_{A} by bonding with each other, and R₉₂₂ and R₉₂₃ form a ring Qc by bonding with each other, and adjacent three (R₉₂₁, R₉₂₂ and R₉₂₃) form rings by bonding with each other and together fused to the anthracene mother skeleton. In this case, the anthracene compound represented by the general formula (TEMP-103) is represented by the following general formula (TEMP-105). In the following general formula (TEMP-105), the ring Q_{A} and the ring Q_{C} share R₉₂₂.

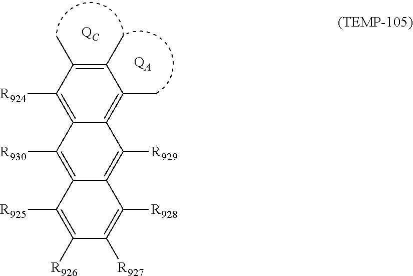

The “monocycle” or “fused ring” formed may be a saturated ring or an unsaturated ring, as a structure of the formed ring alone. Even when the “one pair of adjacent two” forms a “monocycle” or a “fused ring” , the “monocycle” or the “fused ring” may form a saturated ring or an unsaturated ring. For example, the ring Q_{A} and the ring Q_{B} formed in the general formula (TEMP-104) are independently a “monocycle” or a “fused ring.” The ring Q_{A} and the ring Qc formed in the general formula (TEMP-105) are “fused ring.” The ring Q_{A} and ring Qc of the general formula (TEMP-105) are fused ring by fusing the ring Q_{A} and the ring Q_{C} together. When the ring Q_{A} of the general formula (TMEP-104) is a benzene ring, the ring Q_{A} is a monocycle. When the ring Q_{A} of the general formula (TMEP-104) is a naphthalene ring, the ring Q_{A} is a fused ring.

The “unsaturated ring” includes, in addition to an aromatic hydrocarbon ring and an aromatic heterocycle, an aliphatic hydrocarbon ring with an unsaturated bond, i.e., double and/or triple bonds in the ring structure (e.g., cyclohexene, cyclohexadiene, etc.), and a non-aromatic heterocycle with an unsaturated bond (e.g., dihydropyran, imidazoline, pyrazoline, quinolizine, indoline, isoindoline, etc.). The “saturated ring” includes an aliphatic hydrocarbon ring without an unsaturated bond and a non-aromatic heterocycle without ab unsaturated bond.

Specific examples of the aromatic hydrocarbon ring include a structure in which the group listed as a specific example in the specific example group G1 is terminated by a hydrogen atom.

Specific examples of the aromatic heterocycle include a structure in which the aromatic heterocyclic group listed as a specific example in the example group G2 is terminated by a hydrogen atom.

Specific examples of the aliphatic hydrocarbon ring include a structure in which the group listed as a specific example in the specific example group G6 is terminated by a hydrogen atom.

The term “to form a ring” means forming a ring only with plural atoms of the mother skeleton, or with plural atoms of the mother skeleton and one or more arbitrary atoms in addition. For example, the ring Q_{A} shown in the general formula (TEMP-104), which is formed by bonding 8921 and R₉₂₂ with each other, is a ring formed from the carbon atom of the anthracene skeleton with which R₉₂₁ is bonded, the carbon atom of the anthracene skeleton with which R₉₂₂ is bonded, and one or more arbitrary atoms. For example, in the case where the ring Q_{A} is formed with R₉₂₁ and R_{922,} when a monocyclic unsaturated ring is formed with the carbon atom of the anthracene skeleton with which R₉₂₁ is bonded, the carbon atom of the anthracene skeleton with which R₉₂₂ is bonded, and four carbon atoms, the ring formed with R₉₂₁ and R₉₂₂ is a benzene ring.

Here, the “arbitrary atom” is preferably at least one atom selected from the group consisting of a carbon atom, a nitrogen atom, an oxygen atom, and a sulfur atom, unless otherwise specified in this specification. In the arbitrary atom (for example, a carbon atom or a nitrogen atom), a bond which does not form a ring may be terminated with a hydrogen atom or the like, or may be substituted with “arbitrary substituent” described below. When an arbitrary atom other than a carbon atom is contained, the ring formed is a heterocycle.

The number of “one or more arbitrary atom(s)” constituting a monocycle or a fused ring is preferably 2 or more and 15 or less, more preferably 3 or more and 12 or less, and still more preferably 3 or more and 5 or less, unless otherwise specified in this specification.

The “monocycle” is preferable among the “monocycle” and the “fused ring”, unless otherwise specified in this specification.

The “unsaturated ring” is preferable among the “saturated ring” and the “unsaturated ring”, unless otherwise specified in this specification.

Unless otherwise specified in this specification, the “monocycle ” is preferably a benzene ring.

Unless otherwise specified in this specification, the “unsaturated ring” is preferably a benzene ring.

Unless otherwise specified in this specification, when “one or more sets of adjacent two or more” are “bonded with each other to form a substituted or unsubstituted monocycle” or “bonded with each other to form a substituted or unsubstituted fused ring”, this specification, one or more sets of adjacent two or more are preferably bonded with each other to form a substituted or unsubstituted “unsaturated ring” from plural atoms of the mother skeleton and one or more and 15 or less atoms which is at least one kind selected from a carbon atom, a nitrogen atom, an oxygen atom, and a sulfur atom.

The substituent in the case where the above-mentioned “monocycle” or “fused ring” has a substituent is, for example, an “arbitrary substituent” described below. Specific examples of the substituent which the above-mentioned “monocycle” or “fused ring” has include the substituent described above in the “Substituent described in this specification” section.

The substituent in the case where the above-mentioned “saturated ring” or “unsaturated ring” has a substituent is, for example, an “arbitrary substituent” described below. Specific examples of the substituent which the above-mentioned “monocycle” or “fused ring” has include the substituent described above in the “Substituent described in this specification” section.

The foregoing describes the case where “one or more sets of adjacent two or more form a substituted or unsubstituted monocycle by bonding with each other” and the case where “one or more sets of adjacent two or more form a substituted or unsubstituted fused ring by bonding with each other ” (the case where “forming a ring by bonding with each other”).
Substituent in the case of “substituted or unsubstituted”

In one embodiment in this specification, the substituent (in this specification, sometimes referred to as an “arbitrary substituent”) in the case of “substituted or unsubstituted” is, for example, a group selected from the group consisting of:

an unsubstituted alkyl group including 1 to 50 carbon atoms,

an unsubstituted alkenyl group including 2 to 50 carbon atoms,

an unsubstituted alkynyl group including 2 to 50 carbon atoms,

an unsubstituted cycloalkyl group including 3 to 50 ring carbon atoms,

—Si(R₉₀₁)(R₉₀₂)(R₉₀₃),

—O—(R₉₀₄),

—S—(R₉₀₅),

—N(R₉₀₆)(R₉₀₇),

a halogen atom, a cyano group, a nitro group,

an unsubstituted aryl group including 6 to 50 ring carbon atoms, and

an unsubstituted heterocyclic group including 5 to 50 ring atoms,

wherein, R₉₀₁ to R₉₀₇ are independently

a hydrogen atom,

a substituted or unsubstituted alkyl group including 1 to 50 carbon atoms,

a substituted or unsubstituted cycloalkyl group including 3 to 50 ring carbon atoms,

a substituted or unsubstituted aryl group including 6 to 50 ring carbon atoms, or

a substituted or unsubstituted heterocyclic group including 5 to 50 ring atoms.

When two or more R₉₀₁'s are present, the two or more R₉₀₁'s may be the same or different.

When two or more R₉₀₂'s are present, the two or more R₉₀₂'s may be the same or different.

When two or more R₉₀₃'s are present, the two or more R₉₀₃'s may be the same or different.

When two or more R₉₀₄'s are present, the two or more R₉₀₄'s may be the same or different.

When two or more R₉₀₅'s are present, the two or more R₉₀₅'s may be the same or different.

When two or more R₉₀₆'s are present, the two or more R₉₀₆'s may be the same or different.

When two or more R₉₀₇'s are present, the two or more R₉₀₇'s may be the same or different.

In one embodiment, the substituent in the case of “substituted or unsubstituted” is a group selected from the group consisting of:

an alkyl group including 1 to 50 carbon atoms,

an aryl group including 6 to 50 ring carbon atoms, and

a heterocyclic group including 5 to 50 ring atoms.

In one embodiment, the substituent in the case of “substituted or unsubstituted” is a group selected from the group consisting of:

an alkyl group including 1 to 18 carbon atoms,

an aryl group including 6 to 18 ring carbon atoms, and

a heterocyclic group including 5 to 18 ring atoms.

Specific examples of each of the arbitrary substituents include specific examples of substituent described in the section “Substituent described in this specification” above.

Unless otherwise specified in this specification, adjacent arbitrary substituents may form a “saturated ring” or an “unsaturated ring”, preferably form a substituted or unsubstituted saturated 5-membered ring, a substituted or unsubstituted saturated 6-membered ring, a substituted or unsubstituted unsaturated 5-membered ring, or a substituted or unsubstituted unsaturated 6-membered ring, more preferably form a benzene ring.

Unless otherwise specified in this specification, the arbitrary substituent may further have a substituent. The substituent which the arbitrary substituent further has is the same as that of the above-mentioned arbitrary substituent.

In this specification, the numerical range represented by “AA to BB” means the range including the numerical value AA described on the front side of “AA to BB” as the lower limit and the numerical value BB described on the rear side of “AA to BB” as the upper limit.

### [Organic EL Device]

An organic EL device according to an aspect of the present invention including a cathode, an anode, and one or two or more organic layers arranged between the cathode and the anode, wherein at least one layer of the one or two or more organic layers includes a first component and a second component, the first component is a compound represented by the formula (1) described later, and the second component is a compound represented by the formula (2) described later.

When the organic EL device according to an aspect of the present invention includes the above configuration, higher device performance thereof can be achieved. Specifically, an organic EL device having low driving voltage and high efficiency can be achieved.

As understood by the definition of each component, the first component and the second component are different compounds.

Each configuration of the organic EL device according to an aspect of the present invention will be described below.

### (First Component)

A first component in the organic EL device according to an aspect of the present invention is a compound represented by the following formula (1):

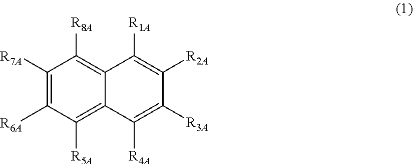

wherein in the formula (1),

one or more sets of the adjacent two or more of R_{1A} to R_{8A} form a substituted or unsubstituted single ring by bonding with each other, or form a substituted or unsubstituted fused ring by bonding with each other;

provided that when at least one set of a set of R_{4A} and R_{5A}, and a set of R_{8A} and R_{1A} is bonded, it is excluded that the compound represented by the formula (1) is a compound having a structure represented by the following formula (1A):

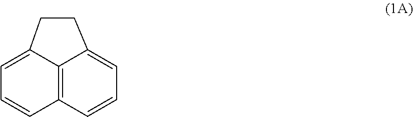 [SMILES: c1cc2c3c(cccc3c1)CC2]

R_{1A} to R_{8A} which do not form the substituted or unsubstituted single ring and which do not form the substituted or unsubstituted fused ring are independently a hydrogen atom or a substituent R;

the substituent R is

a substituted or unsubstituted alkyl group having 1 to 50 carbon atoms,

a substituted or unsubstituted alkenyl group having 2 to 50 carbon atoms,

a substituted or unsubstituted alkynyl group having 2 to 50 carbon atoms,

a substituted or unsubstituted cycloalkyl group having 3 to 50 ring carbon atoms,

—Si(R₉₀₁)(R₉₀₂)(R₉₀₃),

—O—(R₉₀₄),

—S—(R₉₀₅),

—N(R₉₀₆)(R₉₀₇)

(wherein R₉₀₁ to R₉₀₇ are independently

a hydrogen atom,

a substituted or unsubstituted alkyl group having 1 to 50 carbon atoms,

a substituted or unsubstituted cycloalkyl group having 3 to 50 ring carbon atoms,

a substituted or unsubstituted aryl group having 6 to 50 ring carbon atoms, or

a substituted or unsubstituted monovalent heterocyclic group having 5 to 50 ring atoms;
when two or more of each of R₉₀₁ to R₉₀₇ are present, the two or more of each of R₉₀₁ to R₉₀₇ may be the same as or different from each other),

a halogen atom, a cyano group, a nitro group,

a substituted or unsubstituted aryl group having 6 to 50 ring carbon atoms, or

a substituted or unsubstituted monovalent heterocyclic group having 5 to 50 ring atoms;

when two or more substituents R are present, the two or more substituents R may be the same as or different from each other;

provided that the compound represented by the formula (1) does not have a structure represented by the following formula (1 B), a structure represented by the following formula (1C), and a structure represented by the following formula (1 D) within a molecular thereof:

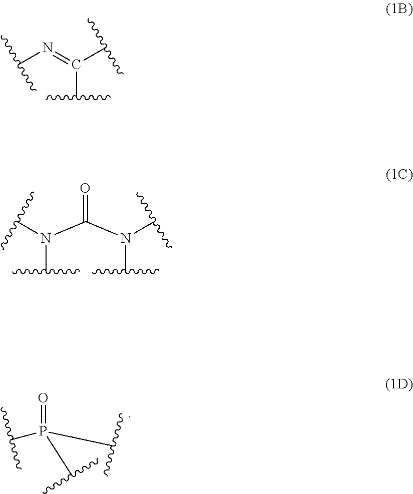 [SMILES: *N=C(*)* ; *N(*)C(=O)N(*)* ; *P(*)(*)=O]

The expression “one or more sets of the adjacent two or more of R_{1A} to R_{8A} form a substituted or unsubstituted single ring by bonding with each other, or form a substituted or unsubstituted fused ring by bonding with each other” is the same as described in the former two cases of the expression “one or more sets of adjacent two or more form a substituted or unsubstituted monocycle by bonding with each other, form a substituted or unsubstituted fused ring by bonding with each other, or do not bond with each other” in the [Definition].

In one embodiment, the substituted or unsubstituted single ring or the substituted or unsubstituted fused ring is a substituted or unsubstituted aromatic hydrocarbon ring having 6 to 30 ring carbon atoms, or a substituted or unsubstituted heterocycle having 5 to 30 ring atoms.

The expression “when at least one set of a set of R_{4A} and R_{5A}, and a set of R_{8A} and R_{1A} is bonded, it is excluded that the compound represented by the formula (1) is a compound having a structure represented by the following formula (1A)” will be described.

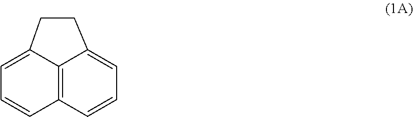 [SMILES: c1cc2c3c(cccc3c1)CC2]

The “compound having the structure represented by the formula (1A)” means a compound containing the structure represented by the formula (1A) as at least a part thereof, and it includes a compound containing the structure represented by the formula (1A) as a part of a fused ring structure, a compound in which any substituent is substituted with the structure represented by the formula (1A), and a compound in which no substituents are substituted with the structure represented by the formula (1A) (that is, a compound in which hydrogen atoms are liked with all of the bondable positions thereof).

Examples of the “compound having the structure represented by the formula (1A)” include a compound represented by the following formula (1-R1). Since the compound has the following structure surrounded by a dashed line (the structure represented by the formula (1A)) as a part of a fused ring structure, it is the compound having the structure represented by the formula (1A) and it does not fall under the definition of the compound represented by the formula (1).

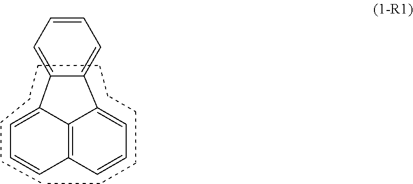 [SMILES: c1ccc2c(c1)-c1cccc3cccc-2c13]

That is, in the formula (1), a set of R_{8A} and R_{1A} does not form a substituted or unsubstituted indene ring by bonding with each other. The same applies for a set of R_{4A} and R_{5A}. It can also be said that the compound represented by the formula (1) does not have a fluoranthene structure.

The expression “when at least one set of a set of R_{4A} and R_{5A}, and a set of R_{8A} and R_{1A} is bonded, it is excluded that the compound represented by the formula (1) is a compound having a structure represented by the following formula (1A)” can also be rephrased as the expression “the 8th-position of carbon atom, the 8a-position of carbon atom, the 1st-position of carbon atom, and two carbon atoms do not form a five-membered ring in the naphthalene structure of the formula (1), and further, the 4th-position of carbon atom, the 4a-position of carbon atom, the 5th-position of carbon atom, and two carbon atoms do not form a five-membered ring in the naphthalene structure”. The numbering system of the naphthalene structure is shown as follows.

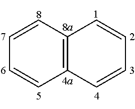

The expression “the compound represented by the formula (1) does not have a structure represented by the following formula (1 B), a structure represented by the following formula (1C), and a structure represented by the following formula (1 D) within a molecular thereof” will be described.

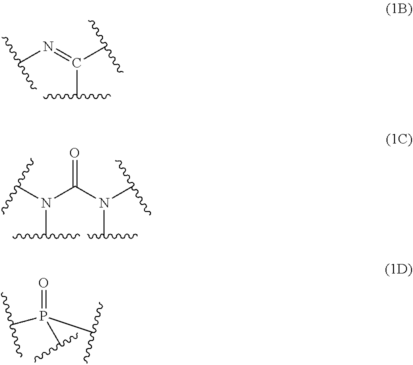

In the formulas (1B), (1C), and (1D), a wavy line terminating a bond means that any atom is present beyond the wavy line. For example, the bond may be terminated by a hydrogen atom, or may be a bond with an atom which can have divalent or more valence (for example, a carbon atom, a nitrogen atom, an oxygen atom, a sulfur atom, or the like).

The expression “the compound represented by the formula (1) does not have a structure represented by the formula (1B), a structure represented by the formula (1C), and a structure represented by the formula (1D) within a molecular thereof” means that it does not have the structure in any moiety within a molecular thereof, and for example, the structure is not included therein as a substituent and the structure is not included in the mother skeleton.

A compound including any one of the structure represented by the formula (1B), the structure represented by the formula (1C), and the structure represented by the formula (1D) does not fall under the definition of the compound represented by the formula (1).

Examples of a substituent containing the structure represented by the formula (1B) include a substituent represented by the following formula (1B-1) (an unsubstituted imidazolyl group).

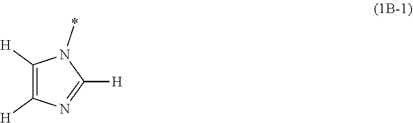 [SMILES: *n1ccnc1]

In the formula (1B-1), * represents a bonding position of the substituent.

In the formula (1B-1), a carbon atom in the formula (1B) is corresponding to the 2nd-position of carbon atom in the imidazole skeleton of the formula (1 B-1), and a nitrogen atom in the formula (1 B) is corresponding to the 3rd-position of nitrogen atom in the imidazole skeleton of the formula (1 B-1). That is, two wavy lines terminating two bonds extending from the carbon atom in the formula (1B) represent a hydrogen atom bonding to the carbon atom in the formula (1 B-1) and the 1st-position of nitrogen atom in the imidazole skeleton of the formula (1B-1), and a wavy line terminating a bond extending from the nitrogen atom in the formula (1 B) represent the 4th-position of carbon atom in the imidazole skeleton of the formula (1 B-1).

Accordingly, the compound represented by the formula (1) does not have an imidazolyl group and a group having an imidazolyl skeleton.

Examples of a compound in which the structure represented by the formula (1B) is included in the mother skeleton include a compound represented by the following formula (1B-2).

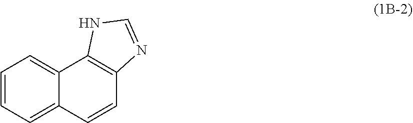 [SMILES: c1ccc2c(c1)ccc1nc[nH]c12]

In the formula (1B-2), the carbon atom in the formula (1B) is corresponding to the 2nd-position of carbon atom in the 1H-naphth[1,2-d]imidazole skeleton of the formula (1B-2), and the nitrogen atom in the formula (1B) is corresponding to the 3rd-position of nitrogen atom in the 1H-naphth[1,2-d]imidazole skeleton of the formula (1B-2). That is, two wavy lines terminating two bonds extending from the carbon atom in the formula (1B) represent a hydrogen atom (which is abbreviated in the formula (1B-2)) bonding to the carbon atom in the formula (1B-2) and the 1st-position of nitrogen atom in the 1H-naphth[1,2-d]imidazole skeleton of the formula (1B-2), and a wavy line terminating a bond extending from the nitrogen atom in the formula (1 B) represent the 4th-position of carbon atom in the 1H-naphth[1,2-d]imidazole skeleton of the formula (1B-2).

The formula (1B-2) indicates the case where a set of R_{1A} and R_{2A} form an imidazolyl ring by bonding with each other in the formula (1), the same applies for a set of R_{2A} and R_{3A}, a set of R_{3A} and R_{4A}, a set of R_{4A} and R_{5A}, a set of R_{5A} and R_{6A}, a set of R_{6A} and R_{7A}, a set of R_{7A} and R_{8A}, and a set of Rat, and R1A, and it is excluded that they form an imidazolyl ring by bonding with each other.

That is, the compound represented by the formula (1) does not have an imidazole structure.

Here, as understood by the formula (1B), each of atoms are present each beyond a bond extending from the nitrogen atom and a bond extending from the carbon atom, and it is excluded that the bond extending from the nitrogen atom and the bond extending from the carbon atom are one single bond (the same). In other words, the atom present beyond the wavy line terminating a bond extending from the nitrogen atom can not be the carbon atom bonded with the nitrogen atom via a double bond, and the atom present beyond the wavy line terminating a bond extending from the carbon atom can not be the nitrogen atom bonded with the carbon atom via a double bond. That is, since a cyano group in which the nitrogen atom and the carbon atom are bonded via a triple bond does not fall under the definition of the structure represented by the formula (1 B), the compound represented by the formula (1) may contain a cyano group.

The structure represented by the formula (1C) is derived from a urea bond, that is, a urea bond is not included in the compound represented by the formula (1).

Here, as understood by the formula (1C), it is excluded that two or more wavy lines terminating a bond extending from one nitrogen atom indicate that one common atom is present beyond the two or more wavy lines. For example, it does not include the case where one nitrogen atom is bonded with one sulfur atom via a double bond. That is, since a group represented by the following formula (1C-1) (a monovalent group derived from a carbamoylisothiocyanate) does not fall under the definition of the structure represented by the formula (1C), the compound represented by the formula (1) may contain the structure represented by the formula (1C-1).

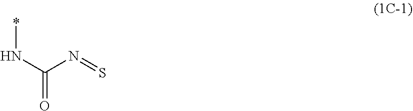 [SMILES: *NC(=O)N=S]

In the formula (1C-1), * represents a bonding position of the substituent.

The structure represented by the formula (1D) is derived from a phosphine oxide group, that is, the phosphine oxide group is not included in the compound represented by the formula (1).

Here, as understood by the formula (1D), it is excluded that two or more wavy lines terminating a bond extending from a phosphorus atom indicate that one common atom is present beyond the two or more wavy lines. For example, it does not include the case where the phosphorus atom is bonded with one carbon atom via a double bond. That is, since a group represented by the following formula (1 D-1) (a monovalent group derived from a methylidene phosphoryl) does not fall under the definition of the structure represented by the formula (1 D), the compound represented by the formula (1) may contain the structure represented by the formula (1D-1).

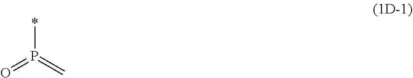 [SMILES: *P(=C)=O]

In the formula (1 D-1), * represents a bonding position of the substituent.

In one embodiment, the compound represented by the formula (1) is a compound having a structure in which three to five rings are fused, the three to five rings are independently a ring selected from the group consisting of a five-membered ring and a six-membered ring, and the compound may have a substituent.

In one embodiment, the compound represented by the formula (1) is a compound having a structure in which three or four rings are fused, the three or four rings are independently a ring selected from the group consisting of a five-membered ring and a six-membered ring, and the compound may have a substituent.

The expression “the compound represented by the formula (1) is a compound having a structure in which three to five rings are fused, the three to five rings are independently a ring selected from the group consisting of a five-membered ring and a six-membered ring, and the compound may have a substituent” will be described.

In the three to five rings, the combination of the number of five-membered ring and the number of six-membered ring is not particularly limited as long as it is the compound represented by the formula (1).

When three rings are fused, one five-membered ring and two six-membered rings may be fused, or three six-membered rings may be fused.

When four rings are fused, two five-membered rings and two six-membered rings may be fused, one five-membered ring and three six-membered rings may be fused, or four six-membered rings may be fused.

When five rings are fused, three five-membered rings and two six-membered rings may be fused, two five-membered rings and three six-membered rings may be fused, one five-membered ring and four six-membered rings may be fused, or five six-membered rings may be fused.

Examples of a compound in which the three six-membered rings are fused include a substituted or unsubstituted anthracene compound, a substituted or unsubstituted phenanthrene compound, and the like.

Examples of a compound in which the four six-membered rings are fused include a substituted or unsubstituted pyrene compound, a substituted or unsubstituted benzanthracene compound, a substituted or unsubstituted tetracene compound, a substituted or unsubstituted chrysene compound, a substituted or unsubstituted benzophenanthrene compound, and the like.

Examples of a compound in which the one five-membered ring and the three six-membered rings are fused include a substituted or unsubstituted naphthobenzofuran compound, a substituted or unsubstituted naphthobenzothiophene compound, a substituted or unsubstituted benzocarbazole compound, a substituted or unsubstituted benzofluorene compound, and the like.

In one embodiment, the compound represented by the formula (1) is a compound having the molecular weight of 400 to 700.

In one embodiment, the compound represented by the formula (1) is a compound having the molecular weight of 400 to 650, 400 to 630, or 400 to 620.

In one embodiment, the compound represented by the formula (1) is a compound represented by any one of the following formulas (1-1) to (1-7):

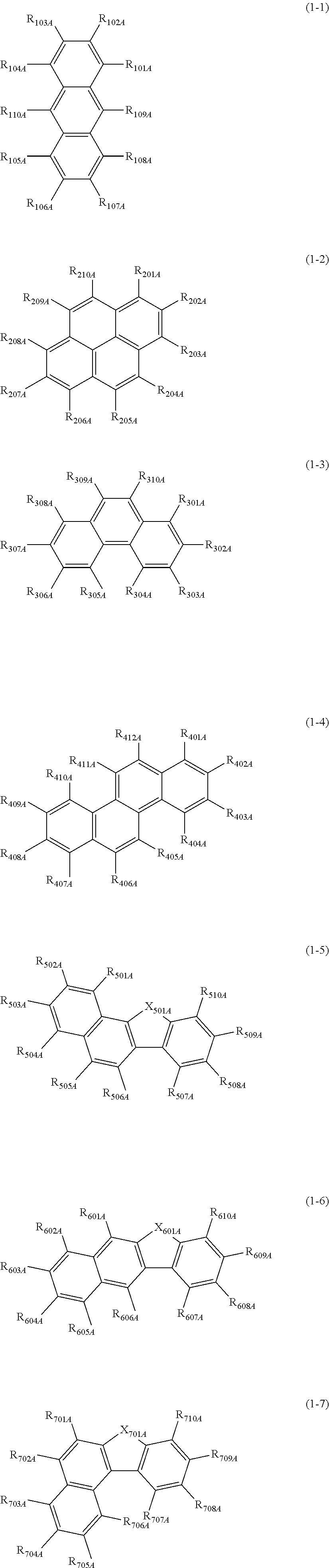

wherein in the formula (1-1),

one or more sets of the adjacent two or more of R_{101A} to R_{110A} do not bond with each other;

R_{101A} to R_{110A} are independently

a hydrogen atom,

a substituent R, or

a group represented by the following formula (11):

Ar₁₀₁-L₁₀₁- (11)

wherein in the formula (11),

L₁₀₁ is

a single bond,

a substituted or unsubstituted arylene group having 6 to 50 ring carbon atoms, or

a substituted or unsubstituted divalent heterocyclic group having 5 to 50 ring atoms;

Ar₁₀₁ is

a substituted or unsubstituted aryl group having 6 to 50 ring carbon atoms, or

a substituted or unsubstituted monovalent heterocyclic group having 5 to 50 ring atoms;

when two or more groups represented by the formula (11) are present, the two or more groups represented by the formula (11) may be the same as or different from each other;

in the formula (1-2),

one or more sets of the adjacent two or more of R_{201A} to R_{210A} do not bond with each other;

R_{201A} to R_{210A} are independently

a hydrogen atom,

a substituent R, or

the group represented by the formula (11);

in the formula (1-3),

one or more sets of the adjacent two or more of R_{301A} to R_{310A} do not bond with each other;

R_{301A} to R_{310A} are independently

a hydrogen atom,

a substituent R, or

the group represented by the formula (11);

in the formula (1-4),

one or more sets of the adjacent two or more of R_{401A} to R_{412A} do not bond with each other;

R_{401A} to R_{412A} are independently

a hydrogen atom,

a substituent R, or

the group represented by the formula (11);

in the formula (1-5),

X_{501A} is C(R_{511A})(R_{512A}), N(R_{513A}), O, or S;

one or more sets of the adjacent two or more of R_{501A} to R_{510A} do not bond with each other;

R_{501A} to _{R510A} are independently

a hydrogen atom,

a substituent R, or

the group represented by the formula (11);

R_{511A} to R_{513A} are independently a hydrogen atom or a substituent R;

in the formula (1-6),

X_{601A} is C(R_{611A})(R_{612A}), N(R_{613A}), O, or S;

one or more sets of the adjacent two or more of R_{601A} to R_{610A} do not bond with each other;

R_{601A} to R_{610A} are independently

a hydrogen atom,

a substituent R, or

the group represented by the formula (11);

R_{611A} to R_{613A} are independently a hydrogen atom or a substituent R;

in the formula (1-7),

X₇₀₁A is C(R_{711A})(R_{712A}), N(R_{713A}), O, or S;

one or more sets of the adjacent two or more of R_{701A} to R_{710A} do not bond with each other;

R_{701A} to R_{710A} are independently

a hydrogen atom,

a substituent R, or

the group represented by the formula (11);

R_{711A} to R_{713A} are independently a hydrogen atom or a substituent R; and

the substituent R is the same as defined in the formula (1).

In one embodiment, at least one of R_{101A} to R_{110A} is the group represented by the formula

In one embodiment, at least two of R_{101A} to R_{110A} are the group represented by the formula

In one embodiment, two of R_{101A} to R_{110A} are the group represented by the formula (11).

In one embodiment, the compound represented by the formula (1) is a compound represented by the following formula (1-11):

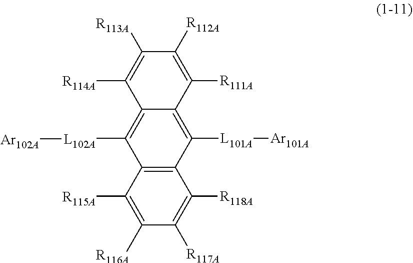

wherein in the formula (1-11),

R_{111A} to R_{118A} are independently a hydrogen atom or a substituent R;

L₁₀₁A and L_{102A} are independently

a single bond,

a substituted or unsubstituted arylene group having 6 to 50 ring carbon atoms, or

a substituted or unsubstituted divalent heterocyclic group having 5 to 50 ring atoms;

Ar_{101A} and Ar_{102A} are independently

a substituted or unsubstituted aryl group having 6 to 50 ring carbon atoms, or

a substituted or unsubstituted monovalent heterocyclic group having 5 to 50 ring atoms; and

the substituent R is the same as defined in the formula (1).

In one embodiment, R_{111A} to R_{118A} are hydrogen atoms.

In one embodiment, L_{101A} and L_{102A} are independently

a single bond,

a substituted or unsubstituted arylene group having 6 to 30 ring carbon atoms, or

a substituted or unsubstituted divalent heterocyclic group having 5 to 30 ring atoms.

In one embodiment, Ar_{101A} and Ar_{102A} are independently

a substituted or unsubstituted aryl group having 6 to 30 ring carbon atoms, or

a substituted or unsubstituted monovalent heterocyclic group having 5 to 30 ring atoms.

In one embodiment, the compound represented by the formula (1) is a compound represented by the following formula (1-12):

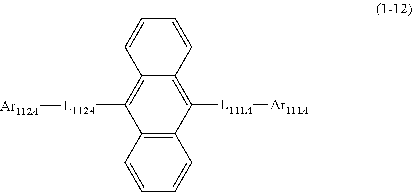

wherein in the formula (1-12),

L_{111A} and L_{112A} are independently

a single bond,

a substituted or unsubstituted arylene group having 6 to 18 ring carbon atoms, or

a substituted or unsubstituted divalent heterocyclic group having 5 to 18 ring atoms; and

Ar_{111A} and Ar_{112A} are independently

a substituted or unsubstituted aryl group having 6 to 18 ring carbon atoms, or

a substituted or unsubstituted monovalent heterocyclic group having 5 to 18 ring atoms.

In one embodiment, L_{111A} and L_{112A} are independently

a single bond,

a substituted or unsubstituted phenylene group, or

a substituted or unsubstituted naphthylene group.

In one embodiment, Ar_{111A} and Ar_{112A} are independently

a substituted or unsubstituted phenyl group,

a substituted or unsubstituted naphthyl group,

a substituted or unsubstituted dibenzofuranyl group, or

a substituted or unsubstituted naphthobenzofuranyl group.

In one embodiment, the compound represented by the formula (1) is a compound represented by the following formula (1-21):

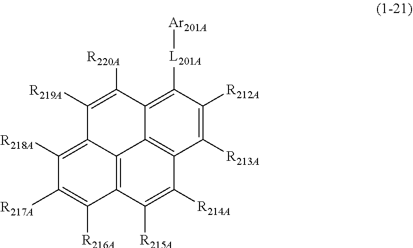

wherein in the formula (1-21),

one or more sets of the adjacent two or more of R_{212A} to R_{220A} do not bond with each other;

R_{212A} to R_{220A} are independently a hydrogen atom or a substituent R;

L_{201A} is

a single bond,

a substituted or unsubstituted arylene group having 6 to 50 ring carbon atoms, or

a substituted or unsubstituted divalent heterocyclic group having 5 to 50 ring atoms;

Ar_{201A} is

a substituted or unsubstituted aryl group having 6 to 50 ring carbon atoms, or

a substituted or unsubstituted monovalent heterocyclic group having 5 to 50 ring atoms; and

the substituent R is the same as defined in the formula (1).

In one embodiment, Ar_{201A} is a substituted or unsubstituted aryl group having 6 to 50 ring carbon atoms.

In one embodiment, Ar_{201A} is a substituted or unsubstituted aryl group having 6 to 30 ring carbon atoms.

In one embodiment, Ar_{201A} is a substituted or unsubstituted aryl group having 6 to 18 ring carbon atoms.

In one embodiment, Ar_{201A} is a substituted or unsubstituted pyrenyl group.

In one embodiment, the compound represented by the formula (1) is a compound represented by the following formula (1-22):

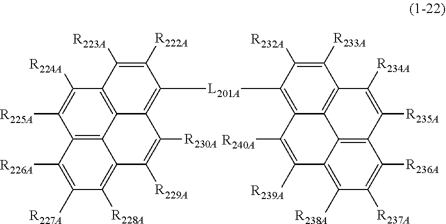

wherein in the formula (1-22),

one or more sets of the adjacent two or more of R_{222A} to R_{230A} and R_{232A} to R_{240A} do not bond with each other;

R_{222A} to R_{230A} and R_{232A} to R_{240A} are independently a hydrogen atom or a substituent R;

L_{201A} is

a single bond,

a substituted or unsubstituted arylene group having 6 to 50 ring carbon atoms, or

a substituted or unsubstituted divalent heterocyclic group having 5 to 50 ring atoms; and

the substituent R is the same as defined in the formula (1).

In one embodiment, R_{222A} to R_{230A} and R_{232A} to R_{240A} are hydrogen atoms.

In one embodiment, L_{201A} is a substituted or unsubstituted arylene group having 6 to 50 ring carbon atoms.

In one embodiment, L_{201A} is a substituted or unsubstituted arylene group having 6 to 30 ring carbon atoms.

In one embodiment, L_{201A} is a substituted or unsubstituted arylene group having 6 to 18 ring carbon atoms.

In one embodiment, L_{201A} is a substituted arylene group having 6 to 18 ring carbon atoms.

In one embodiment, the compound represented by the formula (1) is a substituted or unsubstituted aromatic hydrocarbon compound.

In one embodiment, X_{601A} is C(R_{611A})(R_{612A}) or O.

In one embodiment, the compound represented by the formula (1) is a compound represented by the following formula (1-61):

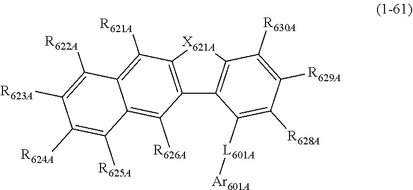

wherein in the formula (1-61),

X_{621A} is C(R_{611A})(R_{612A}), N(R_{613A}), O, or S;

one or more sets of the adjacent two or more of R_{621A} to R_{626A} and R_{628A} to R_{630A} do not bond with each other;

R_{611A} to R_{613A}, R_{621A} to R_{626A}, and R_{628A} to R_{630A} are independently a hydrogen atom or a substituent R;

L_{601A} is

a single bond,

a substituted or unsubstituted arylene group having 6 to 50 ring carbon atoms, or

a substituted or unsubstituted divalent heterocyclic group having 5 to 50 ring atoms;

Ar_{601A} is

a substituted or unsubstituted aryl group having 6 to 50 ring carbon atoms, or

a substituted or unsubstituted monovalent heterocyclic group having 5 to 50 ring atoms; and

the substituent R is the same as defined in the formula (1).

In one embodiment, X_{621A} is C(R_{611A})(R_{612A}) or O.

In one embodiment, R_{611A} to R_{613A}, R_{621A} to R_{626A}, and R_{628A} to R_{630A} are hydrogen atoms.

In one embodiment, the compound represented by the formula (1) is a compound represented by the following formula (1-62):

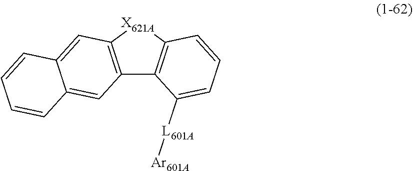

wherein in the formula (1-62),

X_{621A} is C(R_{611A})(R_{612A}), N(R_{613A}), O, or S;

R_{611A} to R_{613A} are independently a hydrogen atom or a substituent R;

L_{601A} is

a single bond,

a substituted or unsubstituted arylene group having 6 to 50 ring carbon atoms, or

a substituted or unsubstituted divalent heterocyclic group having 5 to 50 ring atoms;

Ar_{601A} is

a substituted or unsubstituted aryl group having 6 to 50 ring carbon atoms, or

a substituted or unsubstituted monovalent heterocyclic group having 5 to 50 ring atoms; and

the substituent R is the same as defined in the formula (1).

In one embodiment, X₆₂₁A is C(R_{611A})(R_{612A}) or O.

In one embodiment, L₆₀₁A is a substituted or unsubstituted arylene group having 6 to 50 ring carbon atoms.

In one embodiment, L_{601A} is a substituted or unsubstituted arylene group having 6 to 30 ring carbon atoms.

In one embodiment, L_{601A} is a substituted or unsubstituted arylene group having 6 to 18 ring carbon atoms.

In one embodiment, Ar_{601A} is a substituted or unsubstituted aryl group having 6 to 50 ring carbon atoms.

In one embodiment, Ar_{601A} is a substituted or unsubstituted aryl group having 6 to 30 ring carbon atoms.

In one embodiment, Ar_{601A} is a substituted or unsubstituted aryl group having 6 to 18 ring carbon atoms.

In one embodiment, Ar_{601A} is a substituted or unsubstituted phenyl group, or a substituted or unsubstituted naphthyl group.

As defined in the Definition, the “hydrogen atom” used in the present specification includes a protium atom, a deuterium atom, and a tritium atom. Accordingly, the inventive compounds may contain naturally derived deuterium atoms.

In addition, deuterium atoms may be intentionally introduced into the inventive compound by using a deuterated compound as a part or all of raw material compounds. Accordingly, in one embodiment of the present invention, the compound represented by formula (1) includes at least one deuterium atom. That is, the compound of the present embodiment may be the compound represented by the formula (1), wherein at least one of hydrogen atoms contained in the compound is a deuterium atom.

In the compound represented by the formula (1), at least one hydrogen atom selected from the group consisting of,

hydrogen atoms possessed by the ring in the case where a set of R_{1A} and R_{2A}, a set of R_{2A} and R_{3A}, a set of R_{3A} and R_{4A}, a set of R_{4A} and R_{5A}, a set of R_{5A} and R_{6A}, a set of R_{6A} and R_{7A}, a set of R_{7A} and R_{8A}, and a set of R_{8A} and R_{1A} form a substituted or unsubstituted aromatic hydrocarbon ring having 6 to 30 ring carbon atoms, or a substituted or unsubstituted heterocycle having 5 to 30 ring atoms by bonding with each other (which include hydrogen atoms possessed by the substituent in the case where the ring has the substituent) ;

R_{1A} to R_{8A} which are hydrogen atoms ; and

hydrogen atoms possessed by R_{1A} to R_{8A} which are the substituents R (which include hydrogen atoms possessed by the substituent in the case where the substituent R has the substituent) ;

may be a deuterium atom.

In the compound represented by the formula (1-1), at least one hydrogen atom selected from the group consisting of,

R_{101A} to R_{110A} which are hydrogen atoms ;

hydrogen atoms possessed by R₁₀₁A to R_{110A} which are the substituents R (which include hydrogen atoms possessed by the substituent in the case where the substituent R has the substituent) ;

hydrogen atoms possessed by L₁₀₁ in the case where R_{101A} to R_{110A} are the group represented by the formula (11) (which include hydrogen atoms possessed by the substituent in the case where L₁₀₁ has the substituent) ; and

hydrogen atoms possessed by Ar₁₀₁ in the case where R_{101A} to R_{110A} are the group represented by the formula (11) (which include hydrogen atoms possessed by the substituent in the case where Ar₁₀₁ has the substituent) ; may be a deuterium atom.

In the compound represented by the formula (1-2), at least one hydrogen atom selected from the group consisting of,

R_{201A} to R_{210A} which are hydrogen atoms;

hydrogen atoms possessed by R_{201A} to R_{210A} which are the substituents R (which include hydrogen atoms possessed by the substituent in the case where the substituent R has the substituent) ;

hydrogen atoms possessed by L₁₀₁ in the case where R_{201A} to R_{210A} are the group represented by the formula (11) (which include hydrogen atoms possessed by the substituent in the case where L₁₀₁ has the substituent) ; and

hydrogen atoms possessed by Ar₁₀₁ in the case where R_{201A} to R_{210A} are the group represented by the formula (11) (which include hydrogen atoms possessed by the substituent in the case where Ar₁₀₁ has the substituent) ; may be a deuterium atom.

In the compound represented by the formula (1-3), at least one hydrogen atom selected from the group consisting of,

R_{301A} to R_{310A} which are hydrogen atoms ; hydrogen atoms possessed by R_{301A} to R_{310A} which are the substituents R (which include hydrogen atoms possessed by the substituent in the case where the substituent R has the substituent) ;

hydrogen atoms possessed by L₁₀₁ in the case where R_{301A} to R_{310A} are the group represented by the formula (11) (which include hydrogen atoms possessed by the substituent in the case where L₁₀₁ has the substituent) ; and

hydrogen atoms possessed by Ar₁₀₁ in the case where R_{301A} to R_{310A} are the group represented by the formula (11) (which include hydrogen atoms possessed by the substituent in the case where Ar₁₀₁ has the substituent) ; may be a deuterium atom.

In the compound represented by the formula (1-4), at least one hydrogen atom selected from the group consisting of,

R_{401A} to R₄₁₂A which are hydrogen atoms ;

hydrogen atoms possessed by R_{401A} ^{to R}_{412A} which are the substituents R (which include hydrogen atoms possessed by the substituent in the case where the substituent R has the substituent) ;

hydrogen atoms possessed by L₁₀₁ in the case where R_{401A} to R_{412A} are the group represented by the formula (11) (which include hydrogen atoms possessed by the substituent in the case where L₁₀₁ has the substituent) ; and

hydrogen atoms possessed by Ar₁₀₁ in the case where _{R401A} to R_{412A} are the group represented by the formula (11) (which include hydrogen atoms possessed by the substituent in the case where Ar₁₀₁ has the substituent) ; may be a deuterium atom.

In the compound represented by the formula (1-5), at least one hydrogen atom selected from the group consisting of,

R_{511A} and R_{512A} which are hydrogen atoms in the case where X_{501A} is C(R_{511A})(R_{512A})

hydrogen atoms possessed by R₅₁₁A and R₅₁₂A which are the substituents R in the case where X₅₀₁A is C(R_{511A})(R_{512A}) (which include hydrogen atoms possessed by the substituent in the case where the substituent R has the substituent) ;

R_{513A} which is a hydrogen atom in the case where X₅₀₁A is N(R_{513A}) hydrogen atoms possessed by R_{513A} which is the substituent R in the case where X_{501A} is N(R_{513A}) (which include hydrogen atoms possessed by the substituent in the case where the substituent R has the substituent) ;

R_{501A} to R_{510A} which are hydrogen atoms ;

hydrogen atoms possessed by R_{501A} to R_{510A} which are the substituents R (which include hydrogen atoms possessed by the substituent in the case where the substituent R has the substituent) ;

hydrogen atoms possessed by L₁₀₁ in the case where R_{501A} to R_{510A} are the group represented by the formula (11) (which include hydrogen atoms possessed by the substituent in the case where L₁₀₁ has the substituent) ; and

hydrogen atoms possessed by Ar₁₀₁ in the case where R_{501A} to R_{510A} are the group represented by the formula (11) (which include hydrogen atoms possessed by the substituent in the case where Ar₁₀₁ has the substituent) ;

may be a deuterium atom.

In the compound represented by the formula (1-6), at least one hydrogen atom selected from the group consisting of,

R_{611A}and R_{612A}which are hydrogen atoms in the case where X_{601A} is C(R_{611A})(R_{612A}) hydrogen atoms possessed by R_{611A} and R_{612A} which are the substituents R in the case where X_{601A} is C(R_{611A})(R_{612A}) (which include hydrogen atoms possessed by the substituent in the case where the substituent R has the substituent) ;

R_{613A} which is a hydrogen atom in the case where X_{601A} is N(R_{613A})

hydrogen atoms possessed by R_{613A} which is the substituent R in the case where X_{601A} is N(R_{613A}) (which include hydrogen atoms possessed by the substituent in the case where the substituent R has the substituent) ;

R_{601A} to R_{610A} which are hydrogen atoms ;

hydrogen atoms possessed by R_{601A} to R_{610A} which are the substituents R (which include hydrogen atoms possessed by the substituent in the case where the substituent R has the substituent) ;

hydrogen atoms possessed by L₁₀₁ in the case where R_{601A} to R_{610A} are the group represented by the formula (11) (which include hydrogen atoms possessed by the substituent in the case where L₁₀₁ has the substituent) ; and

hydrogen atoms possessed by Ar₁₀₁ in the case where R_{601A} to R_{610A} are the group represented by the formula (11) (which include hydrogen atoms possessed by the substituent in the case where Ar₁₀₁ has the substituent) ;

may be a deuterium atom.

In the compound represented by the formula (1-7), at least one hydrogen atom selected from the group consisting of,

R_{711A} and R_{712A} which are hydrogen atoms in the case where X₇₀₁A is C(R_{711A})(R_{712A}) hydrogen atoms possessed by R_{711A} and R_{712A} which are the substituents R in the case where X₇₀₁A is C(R_{711A})(R_{712A}) (which include hydrogen atoms possessed by the substituent in the case where the substituent R has the substituent) ;

R_{713A} which is a hydrogen atom in the case where X₇₀₁A is N(R_{713A})

hydrogen atoms possessed by R_{713A} which is the substituent R in the case where X_{701A} is N(R_{713A}) (which include hydrogen atoms possessed by the substituent in the case where the substituent R has the substituent) ;

R_{701A} to R_{710A} which are hydrogen atoms;

hydrogen atoms possessed by R_{701A} to R_{710A} which are the substituents R (which include hydrogen atoms possessed by the substituent in the case where the substituent R has the substituent);

hydrogen atoms possessed by L₁₀₁ in the case where R_{701A} to R_{710A} are the group represented by the formula (11) (which include hydrogen atoms possessed by the substituent in the case where L₁₀₁ has the substituent) ; and

hydrogen atoms possessed by Ar₁₀₁ in the case where R_{701A} to R_{710A} are the group represented by the formula (11) (which include hydrogen atoms possessed by the substituent in the case where Ar₁₀₁ has the substituent) ;

may be a deuterium atom.

The deuteration rate of the compound depends on the deuteration rate of the raw material compounds used. Even if a raw material having a predetermined deuteration rate is used, a protium atom isotope may be included at a certain proportion derived naturally. Accordingly, an aspect of the deuteration rate includes a proportion in which a trace amount of naturally derived isotopes is considered, based on a proportion obtained by simply counting the number of deuterium atoms represented by the chemical formula.

In one embodiment, the deuteration rate of the compound is preferably 1% or more, more preferably 3% or more, still more preferably 5% or more, still more preferably 10% or more, and still more preferably 50% or more.

The compound represented by the formula (1) can be synthesized by using known alternative reactions or raw materials adapted to the target compound.

Specific examples of the first component will be described below, but these are merely examples, and the first component is not limited to the following specific examples. In the following specific examples, “Me” represents a methyl group, “Ph” represents a phenyl group, and “D” represents a deuterium atom.

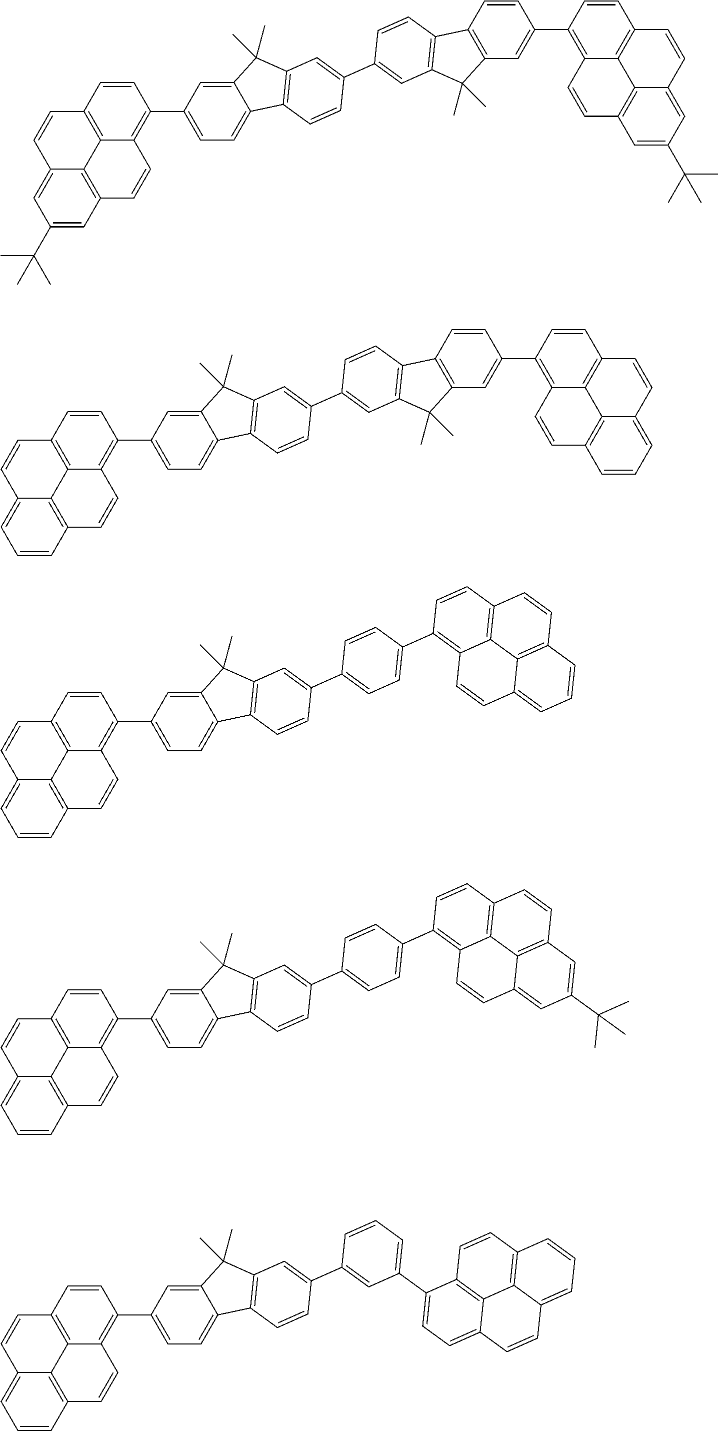

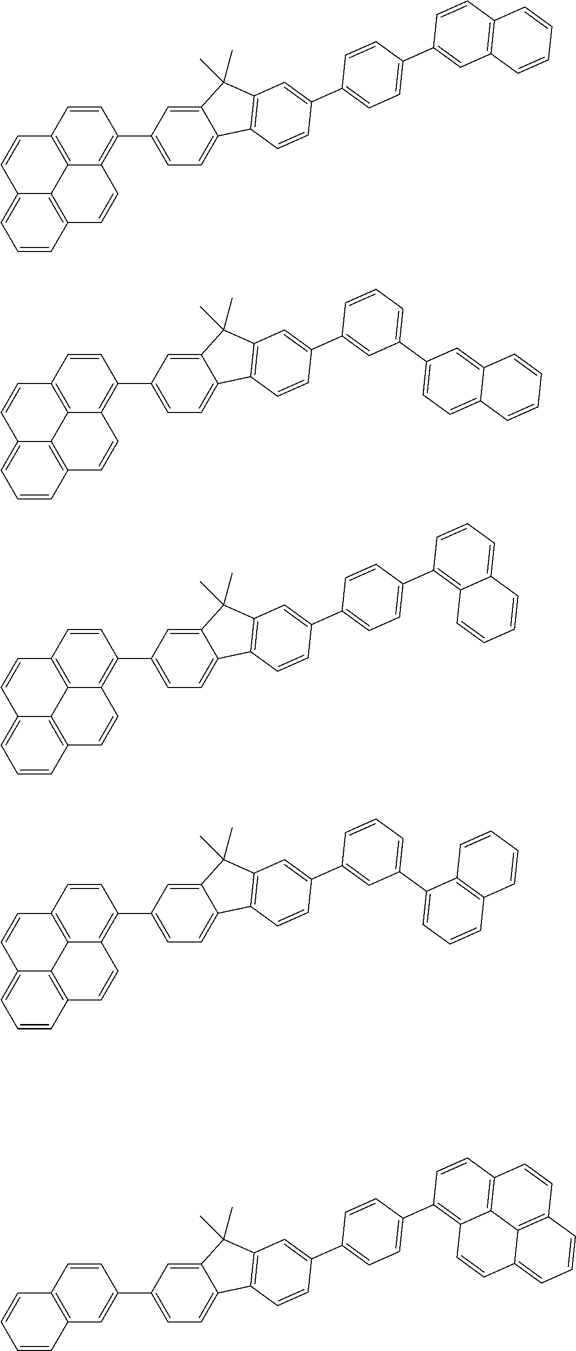

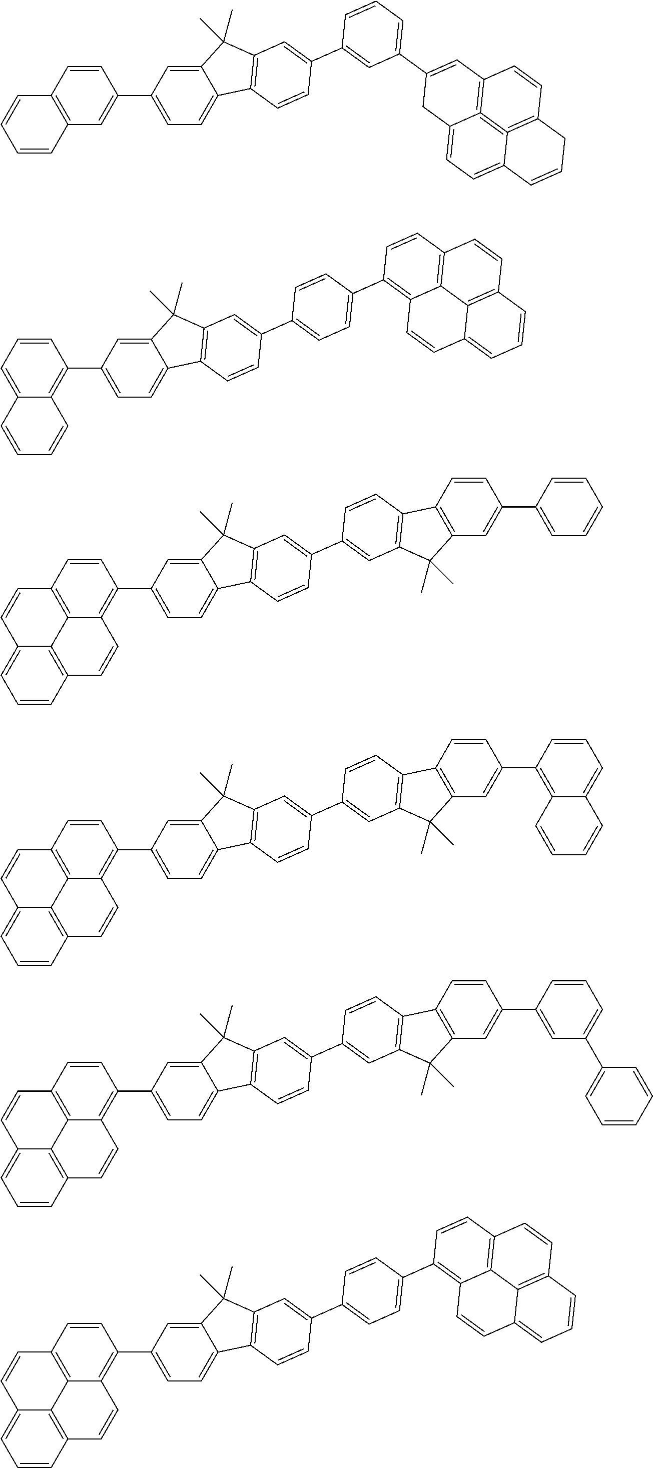

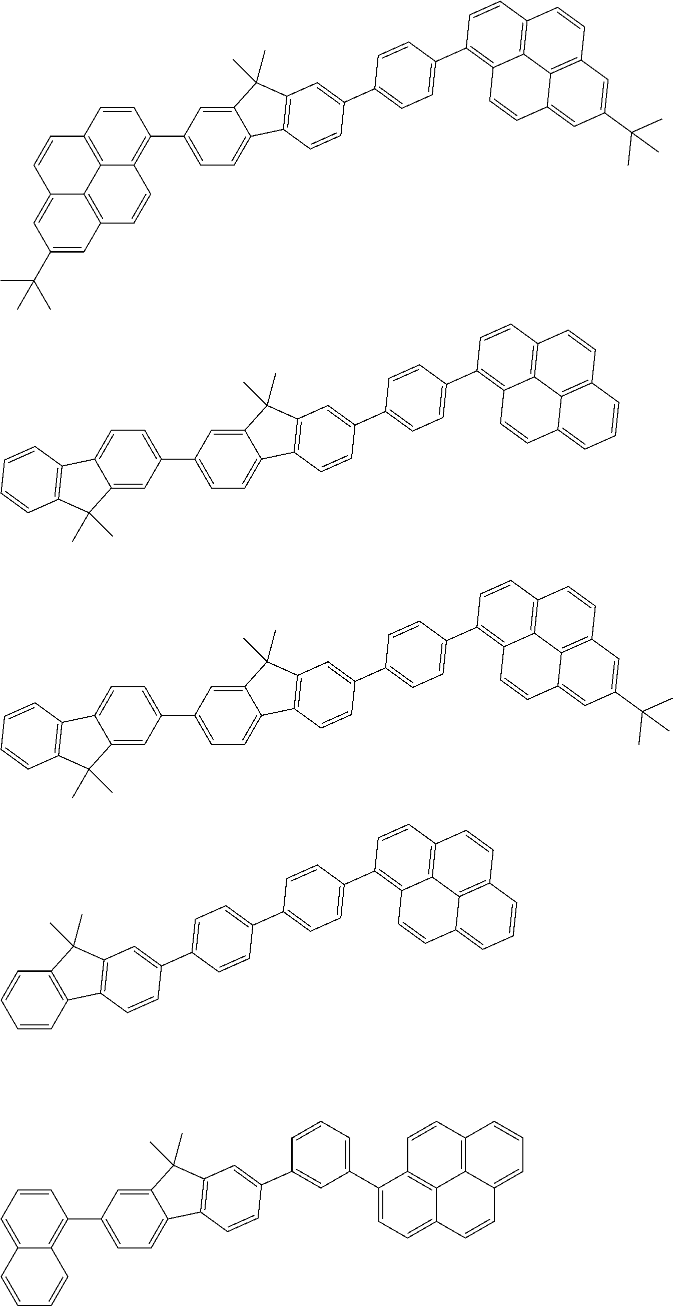

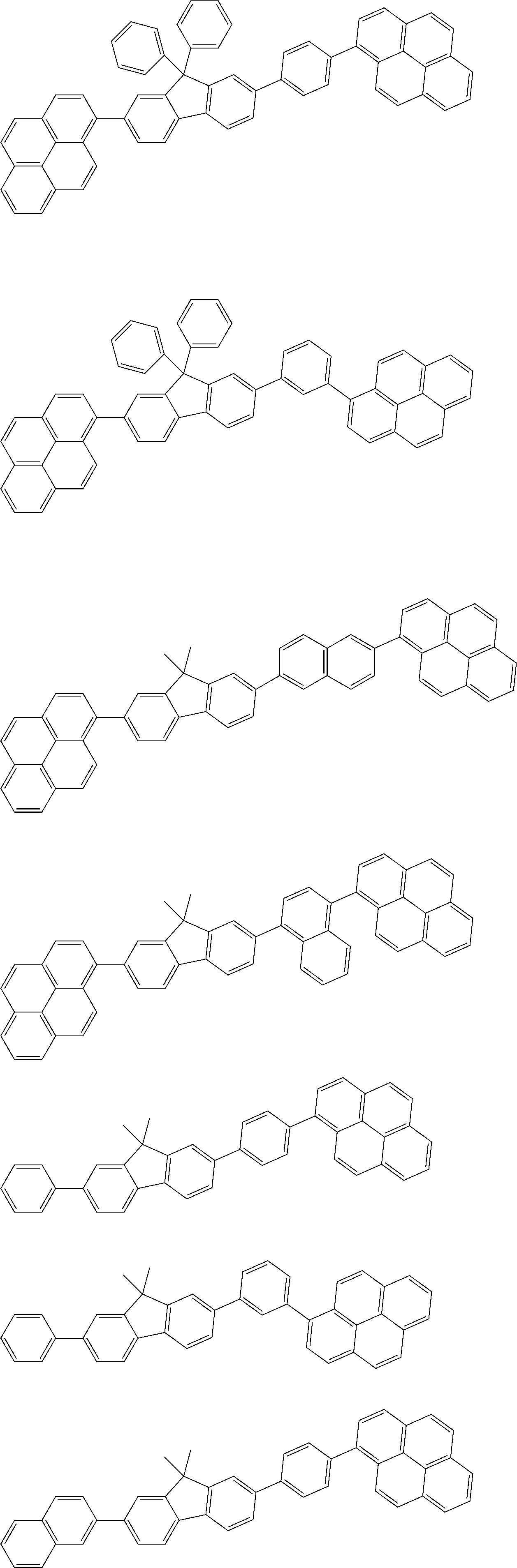

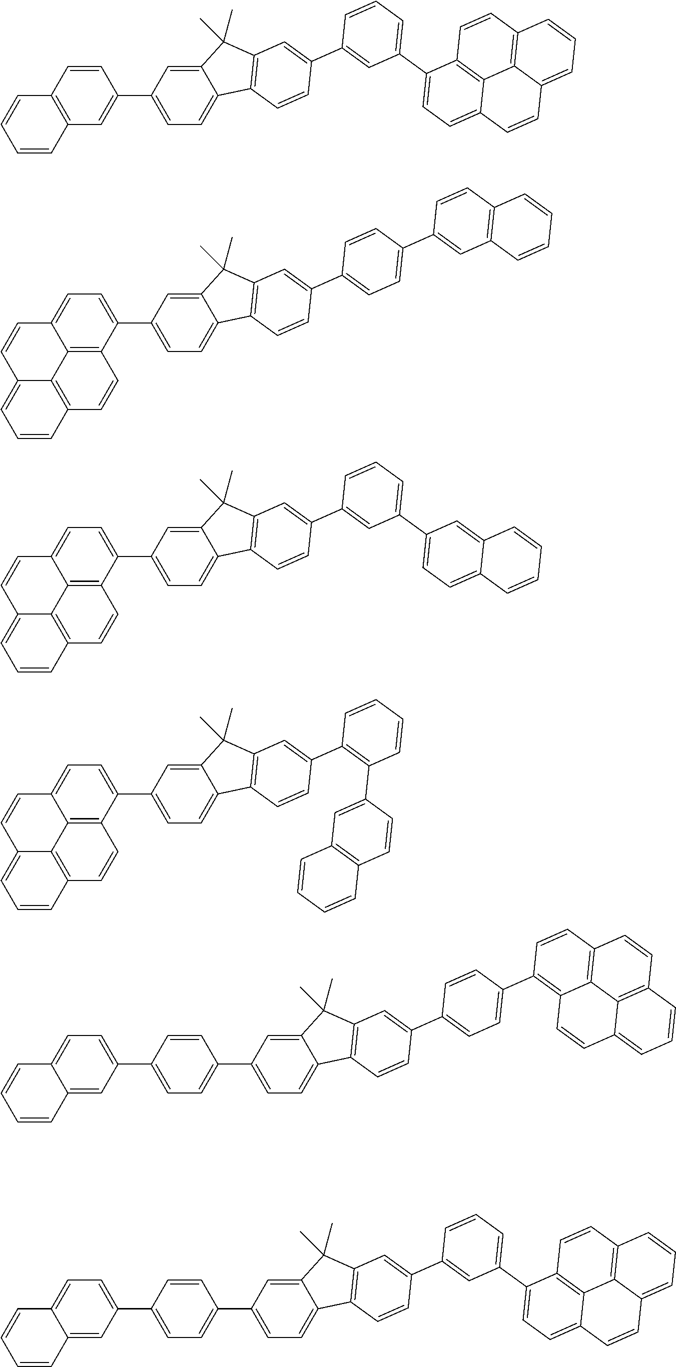

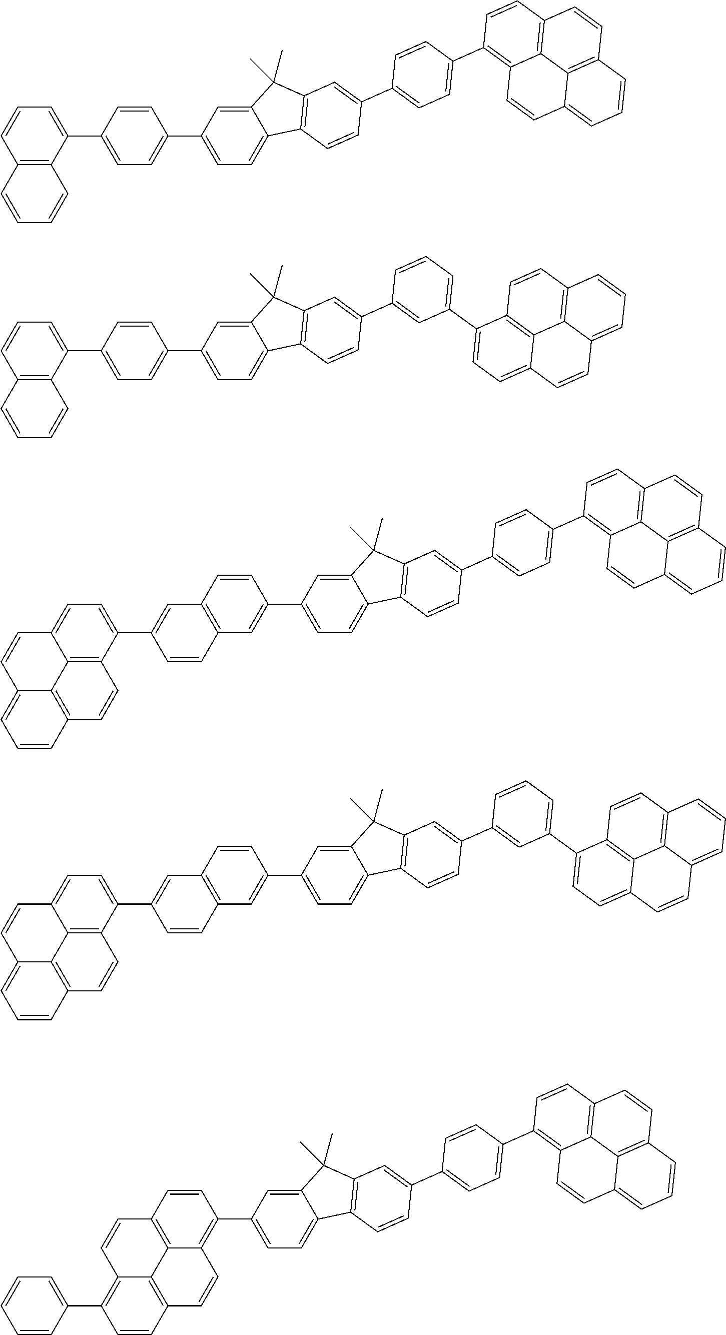

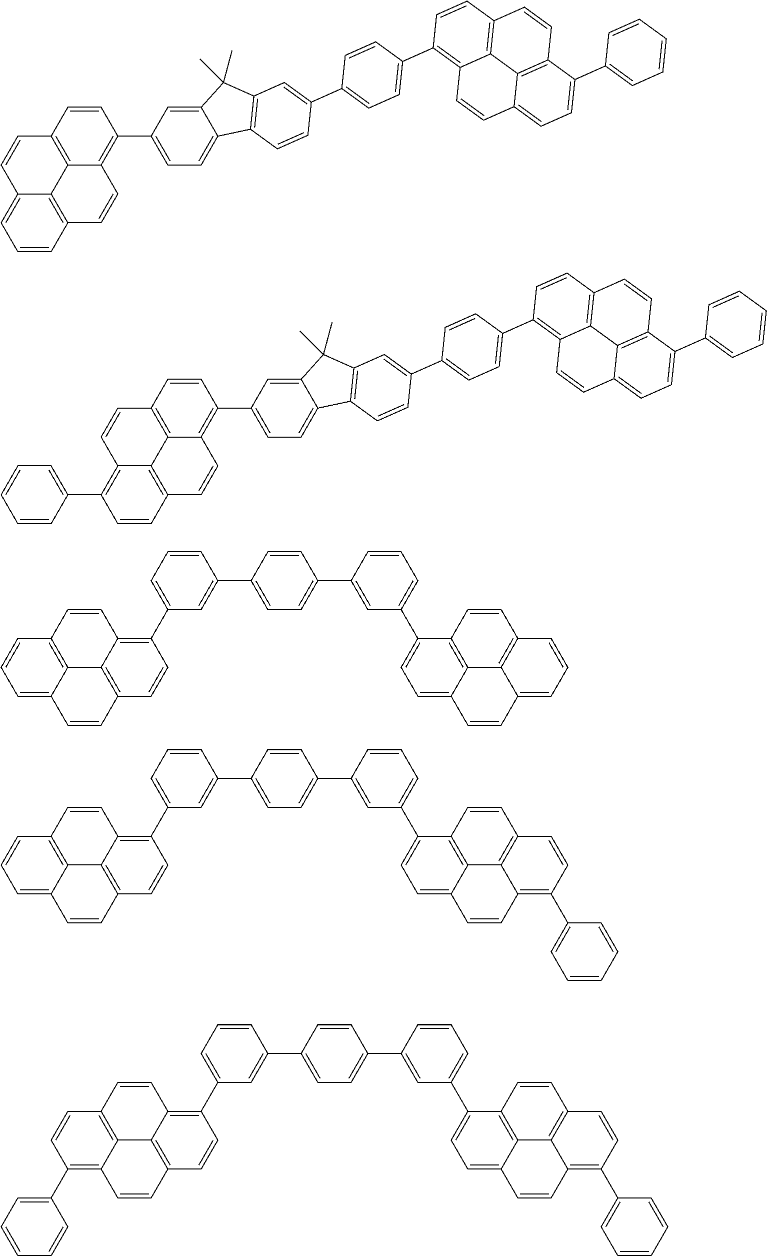

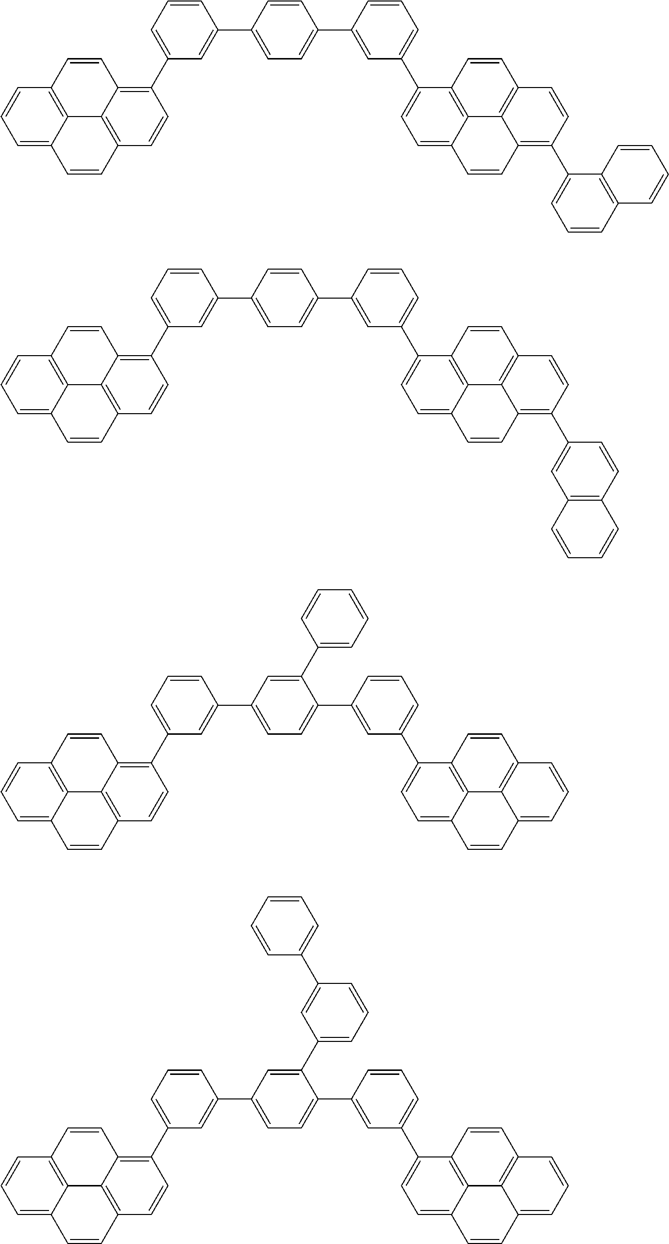

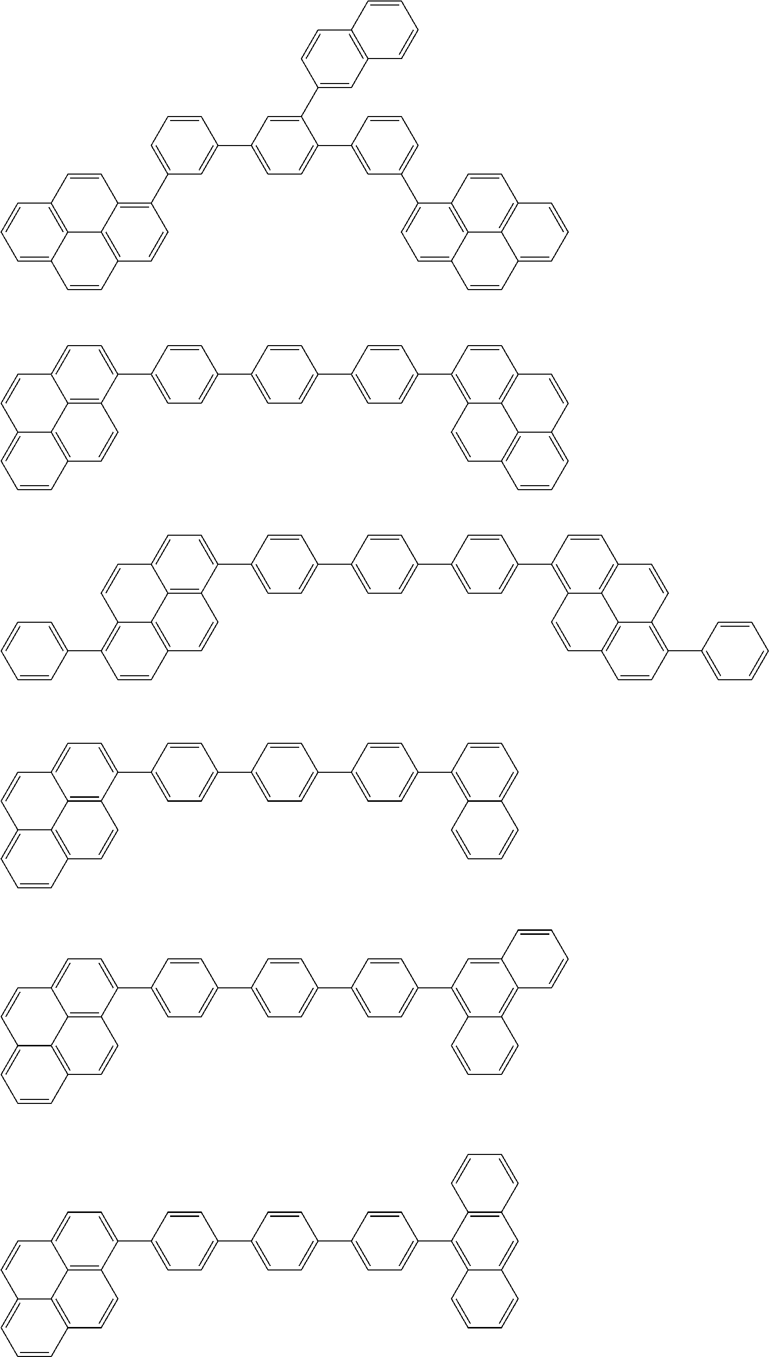

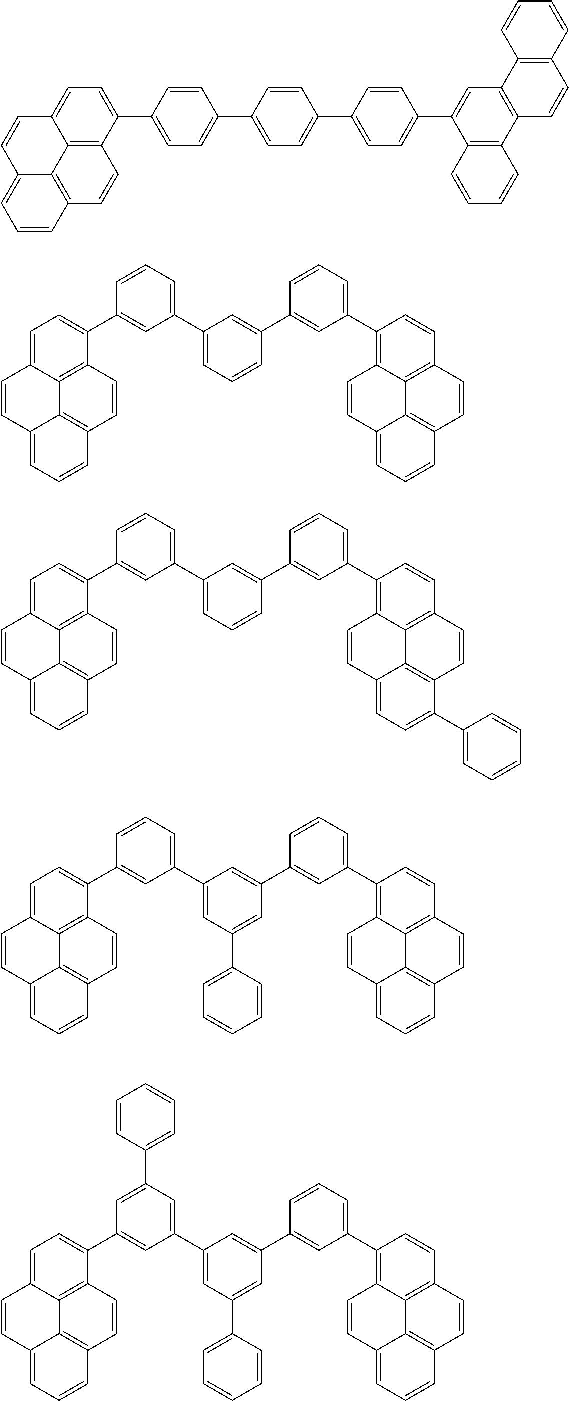

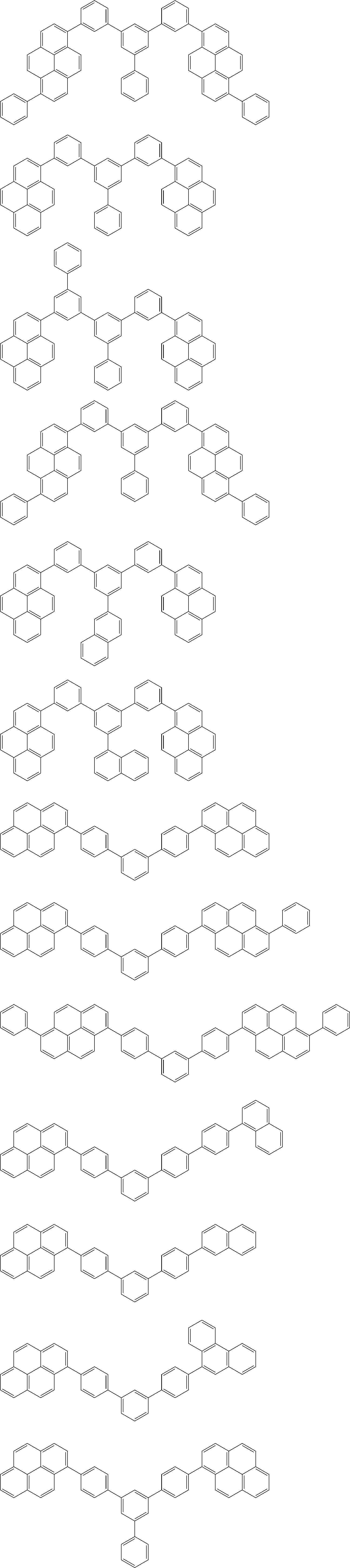

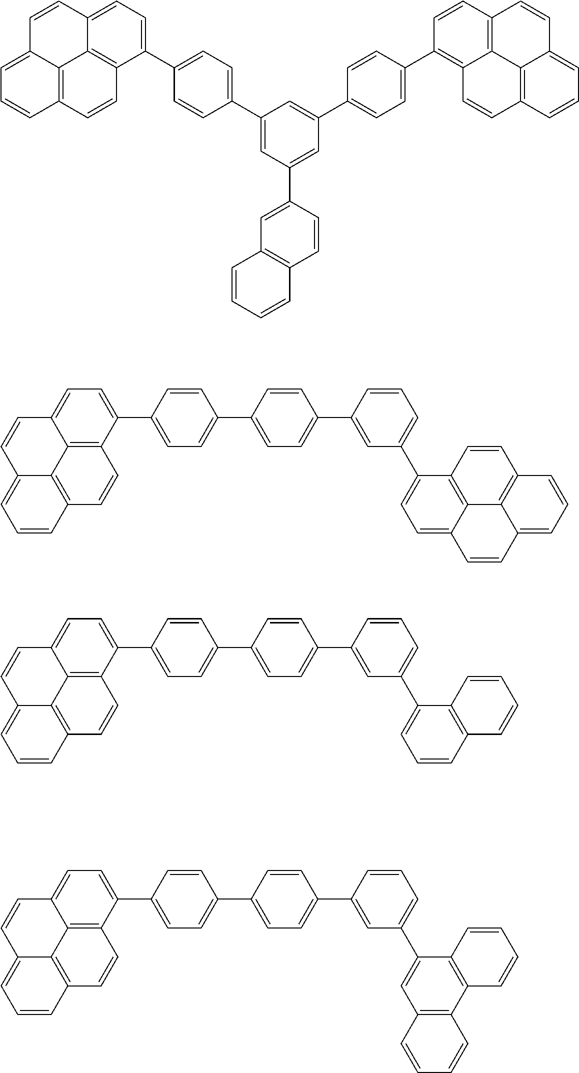

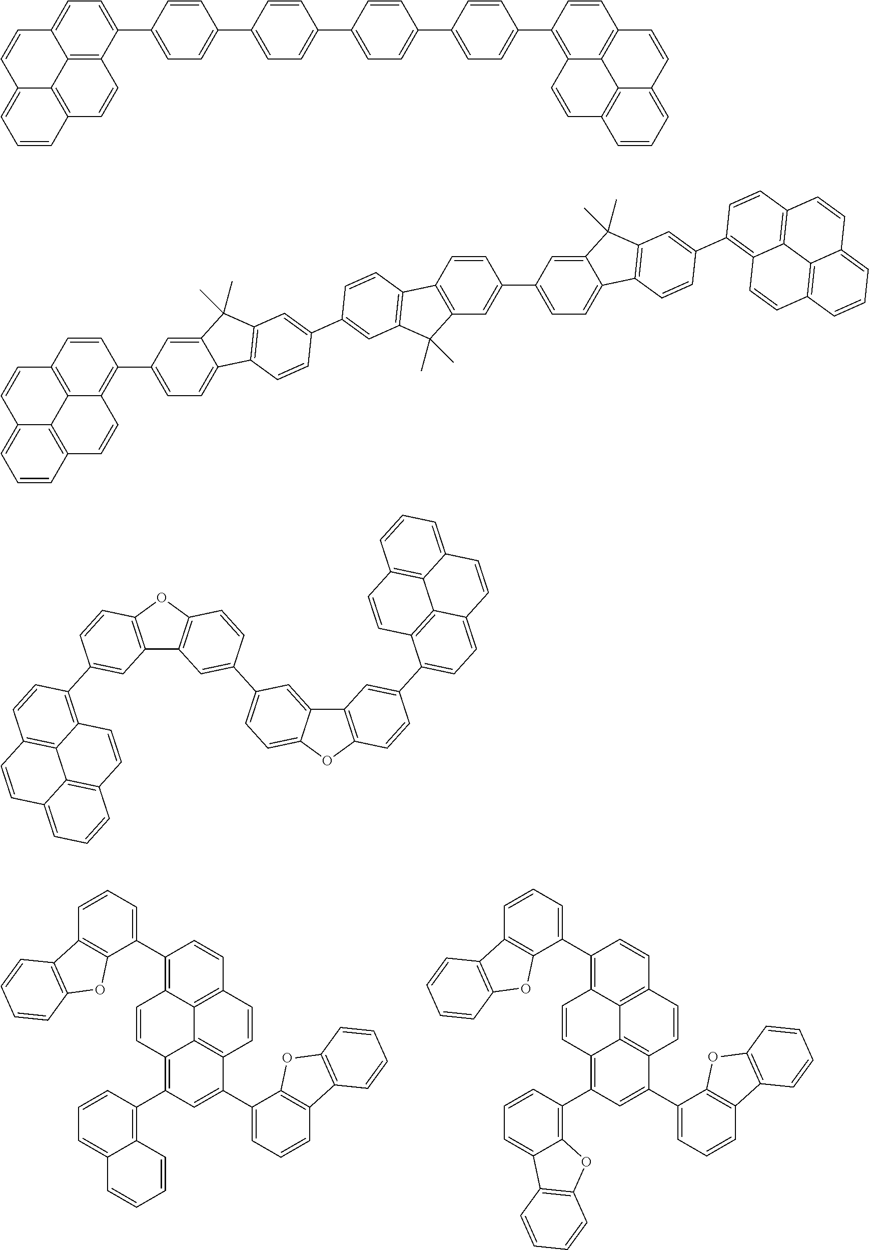

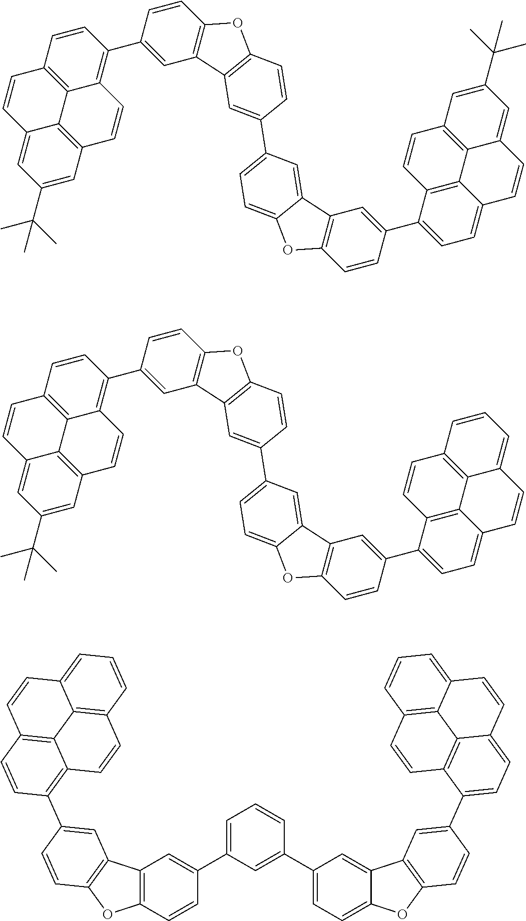

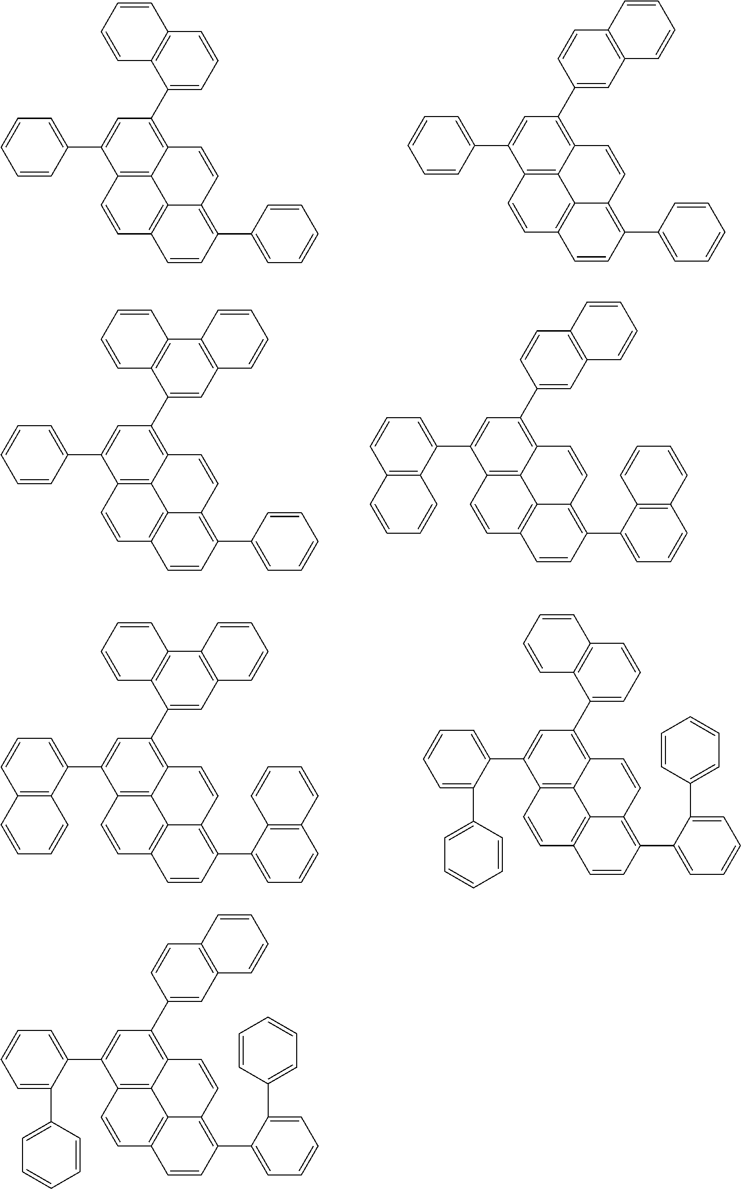

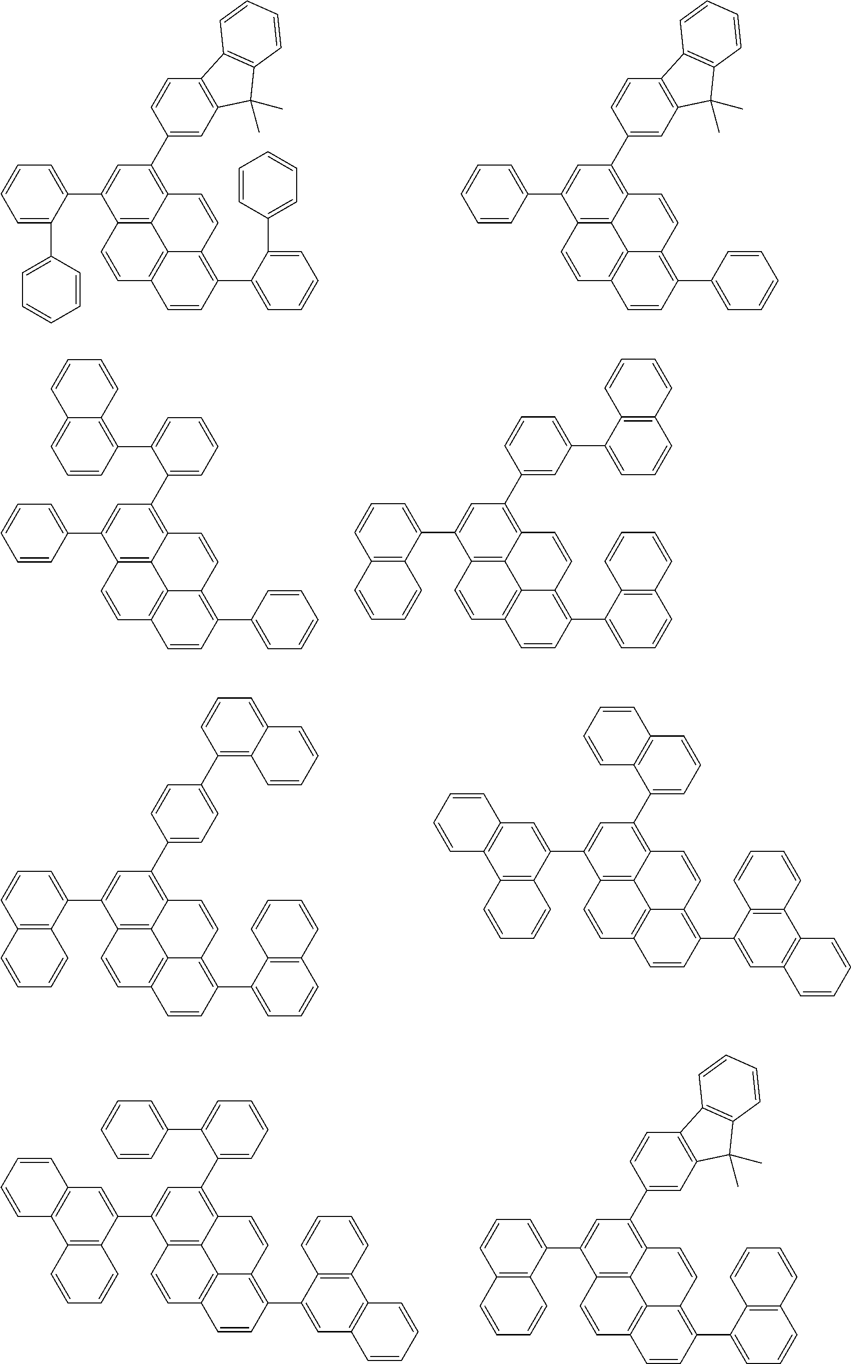

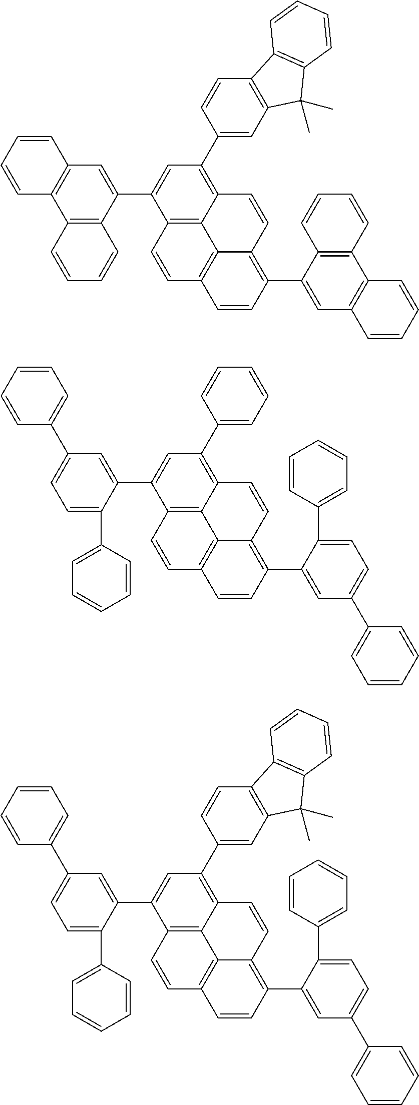

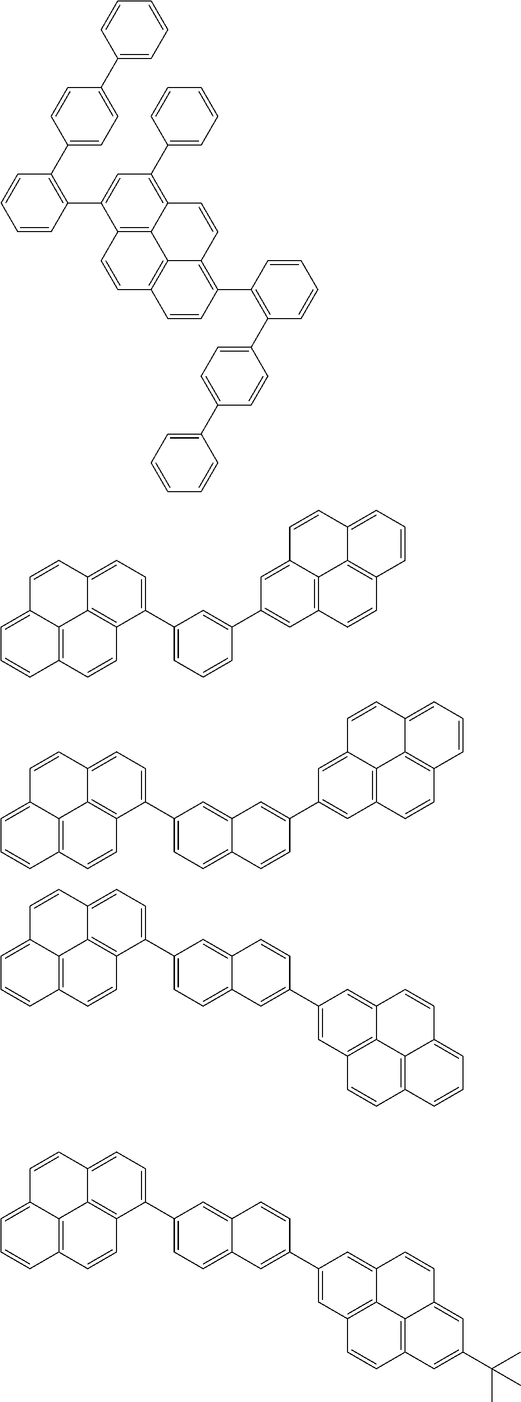

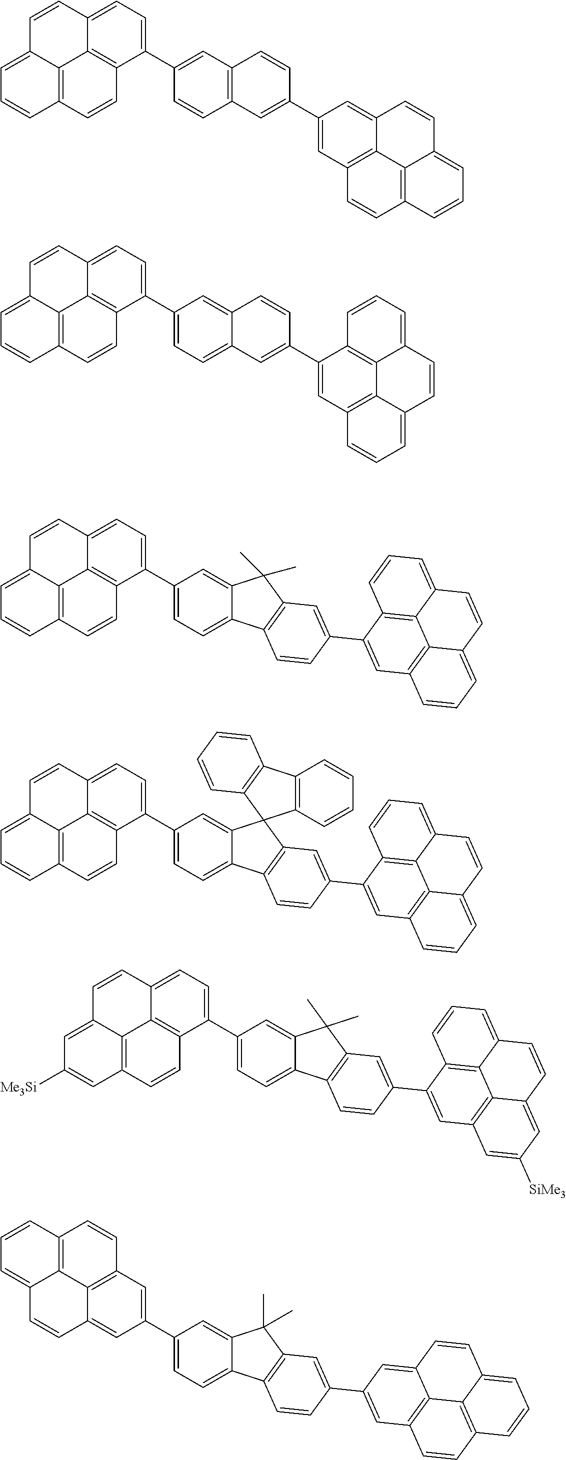

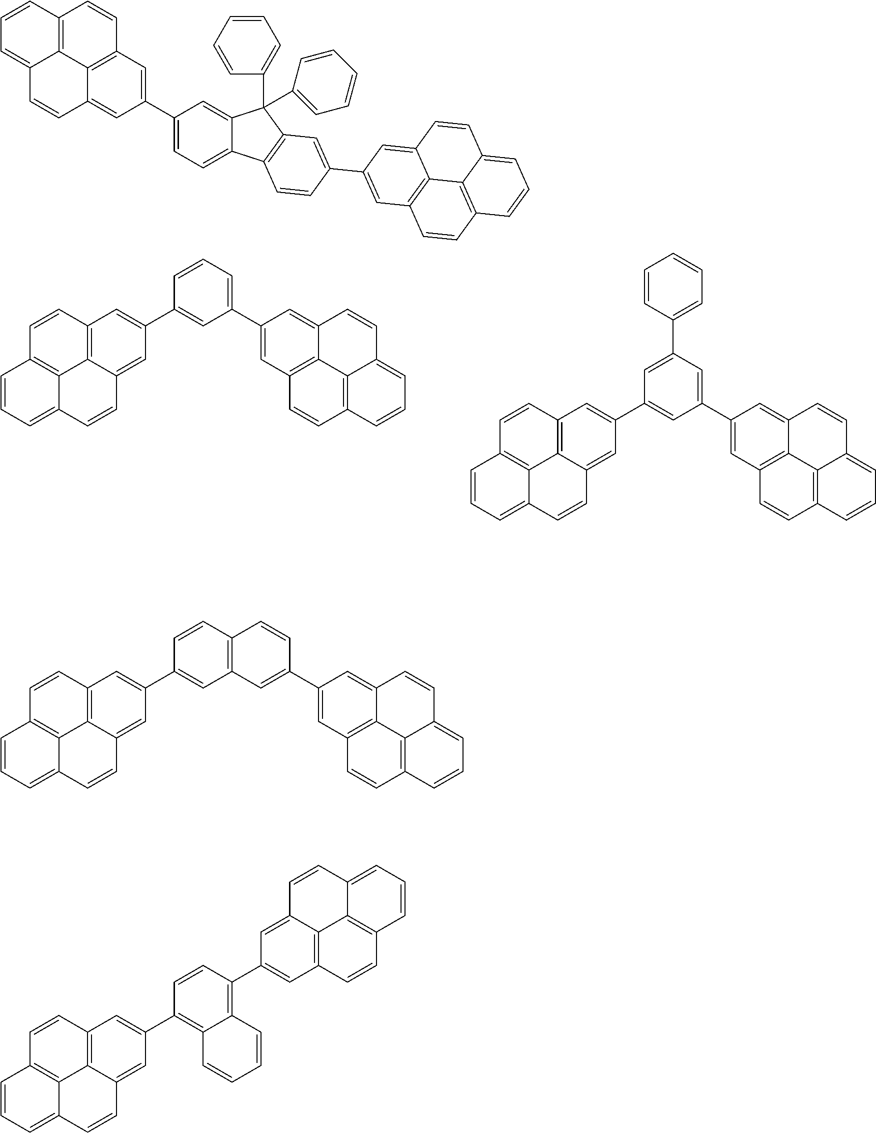

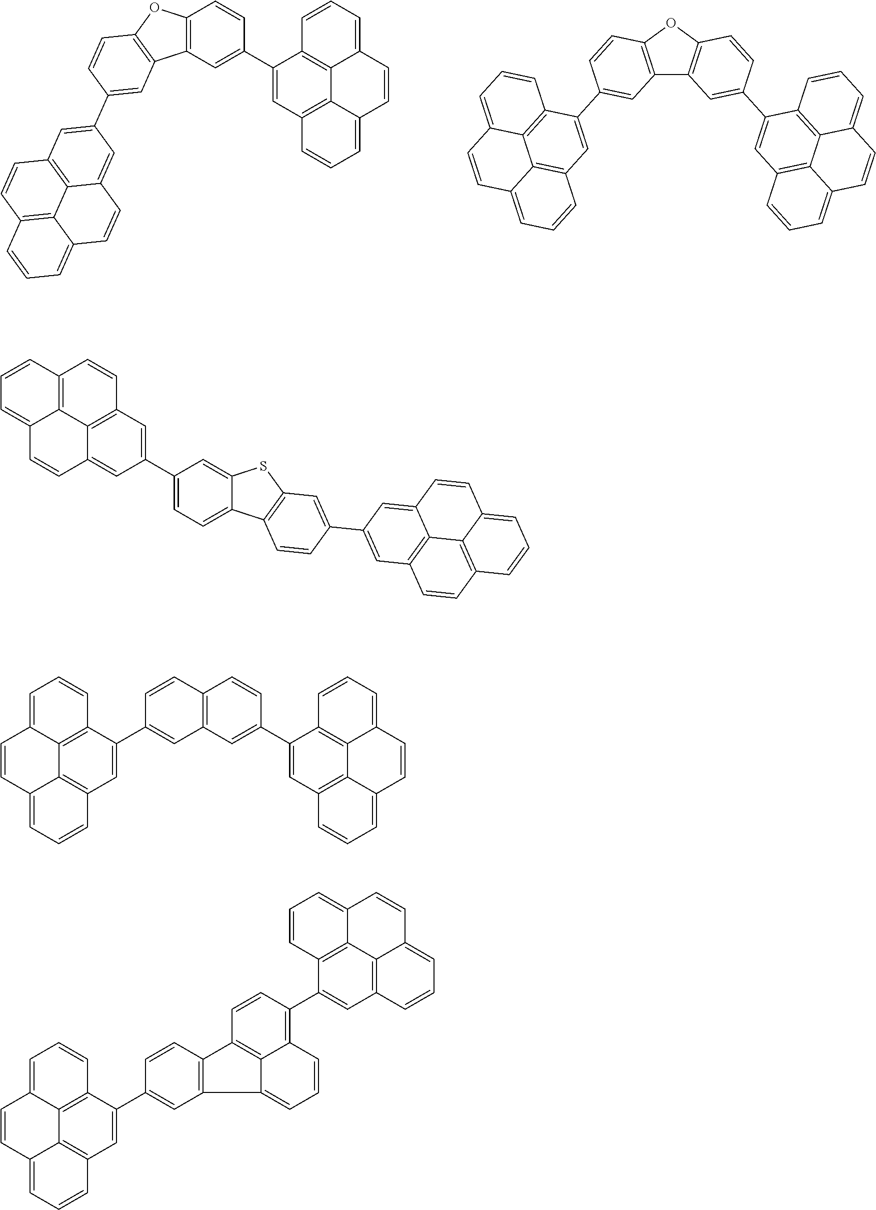

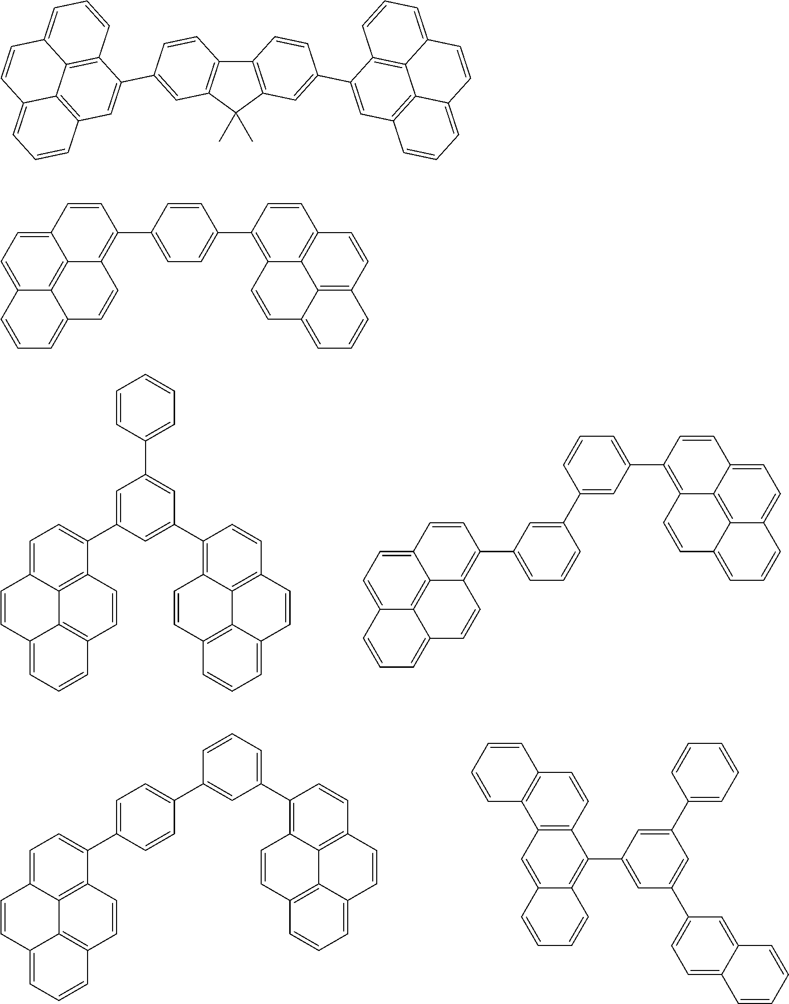

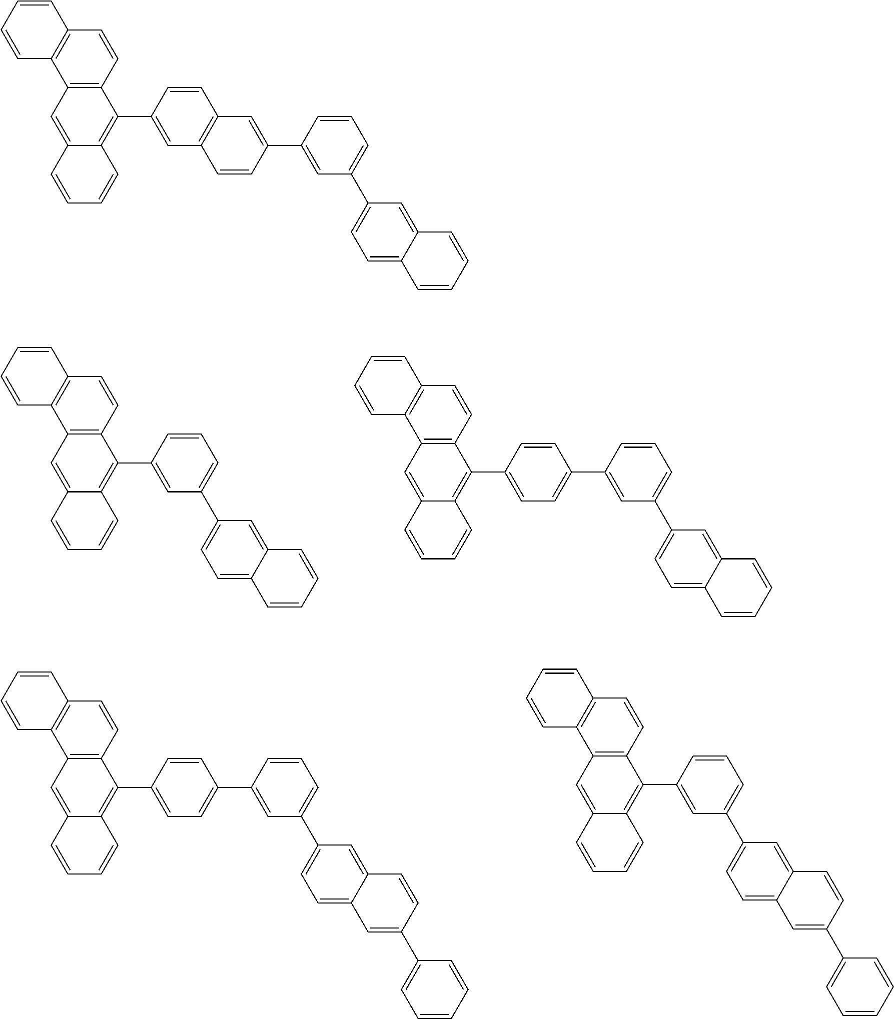

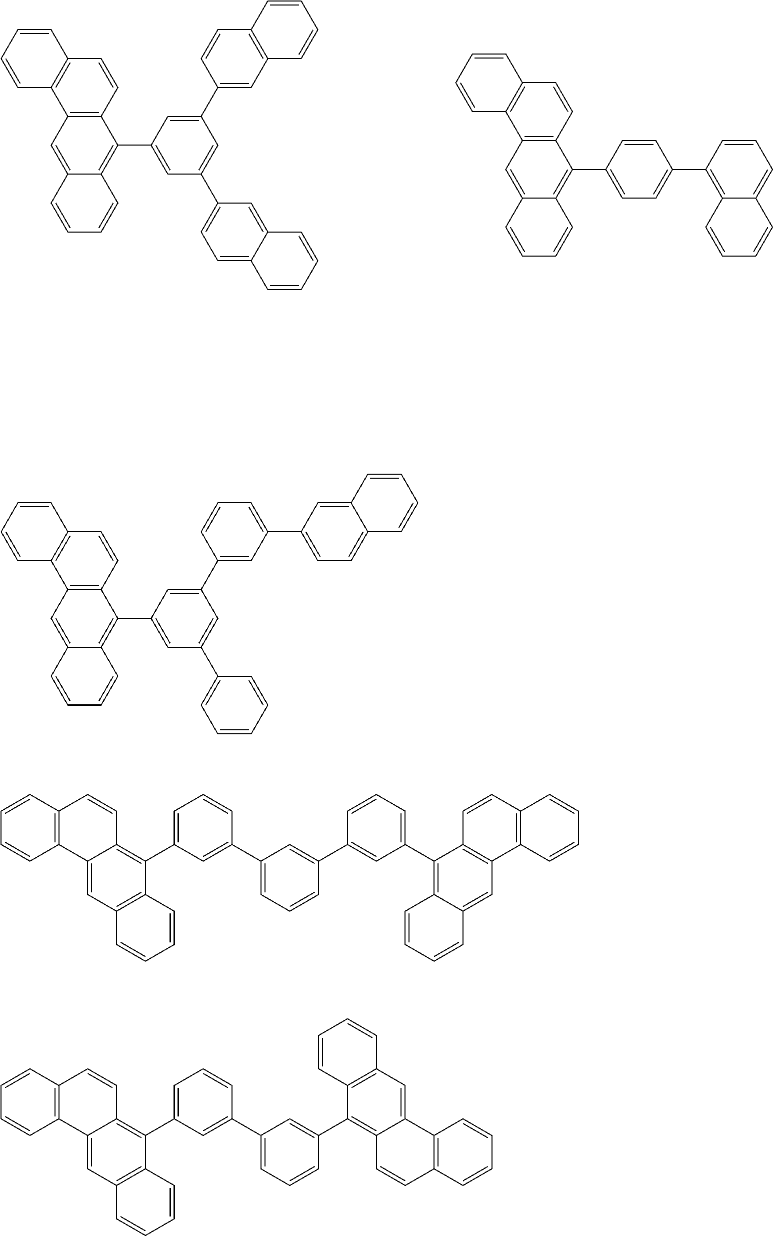

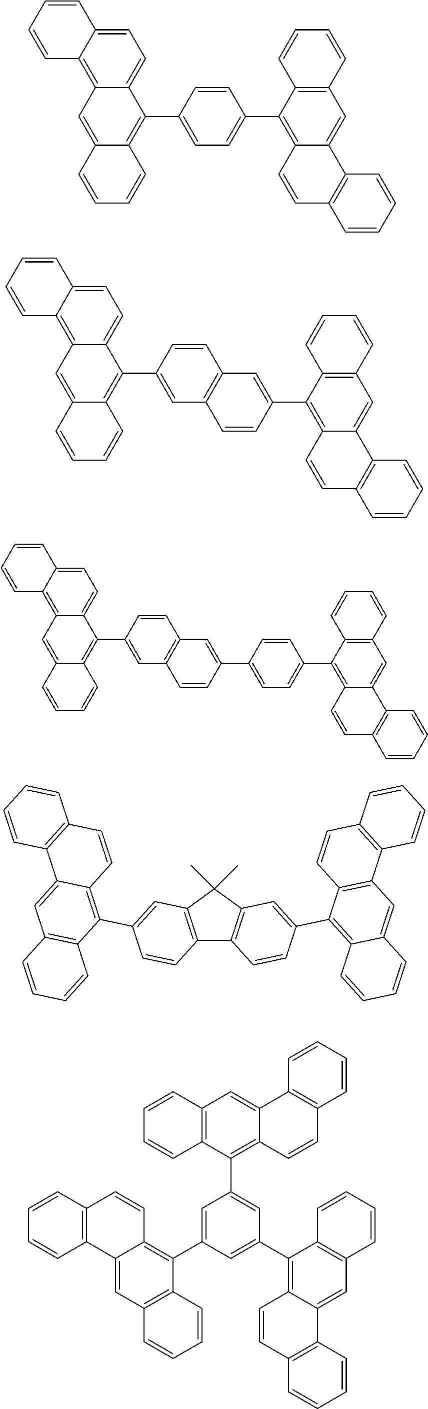

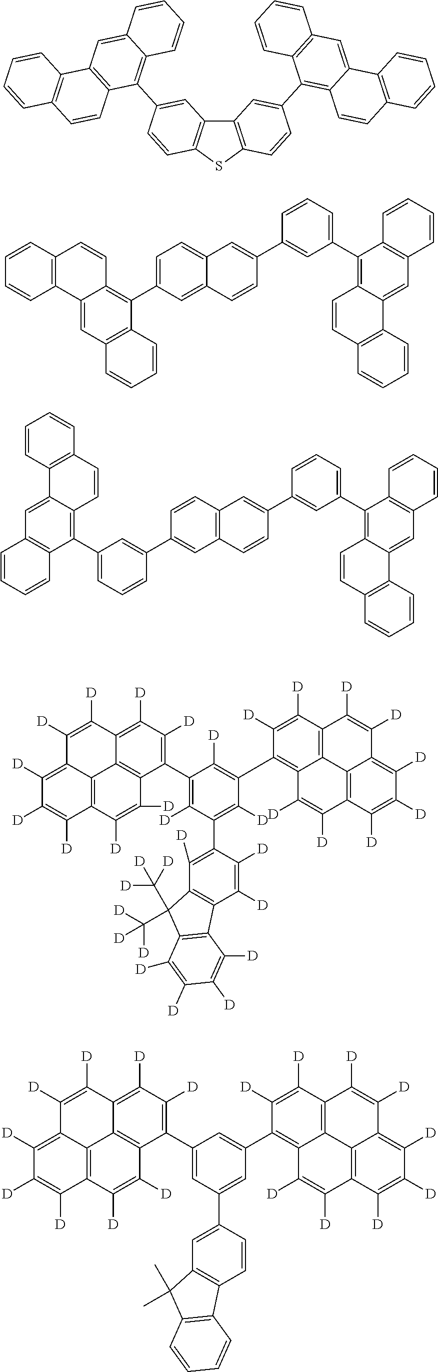

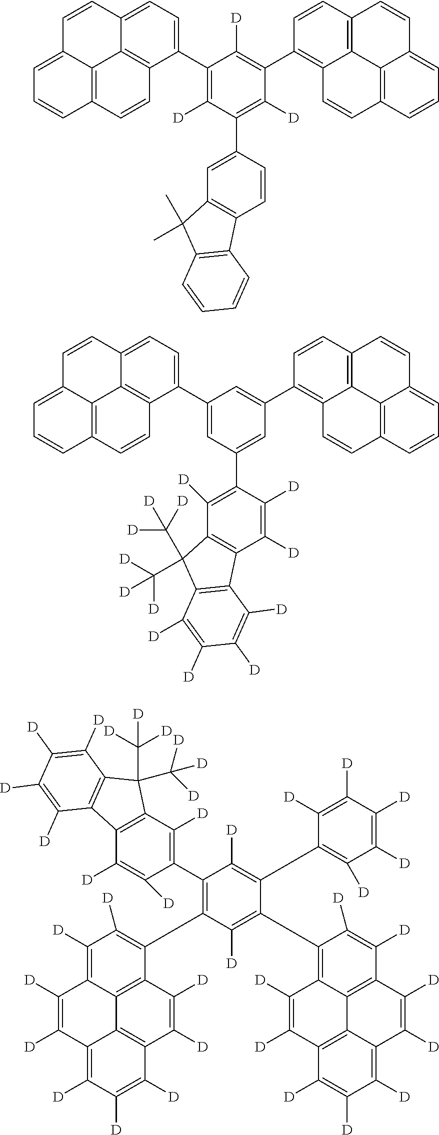

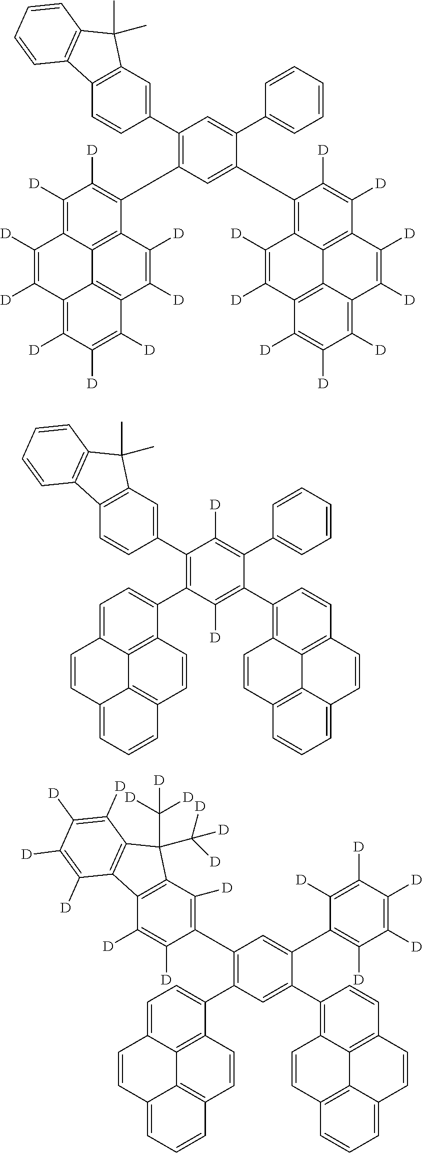

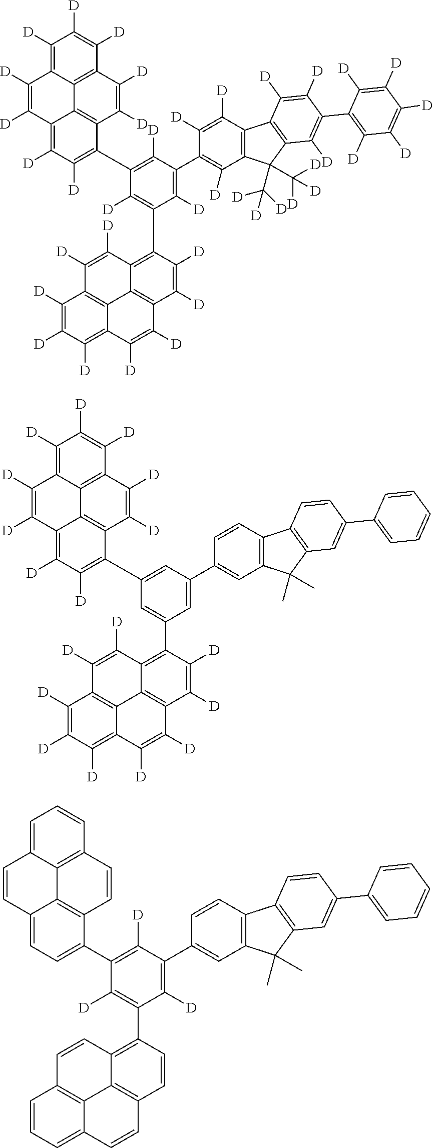

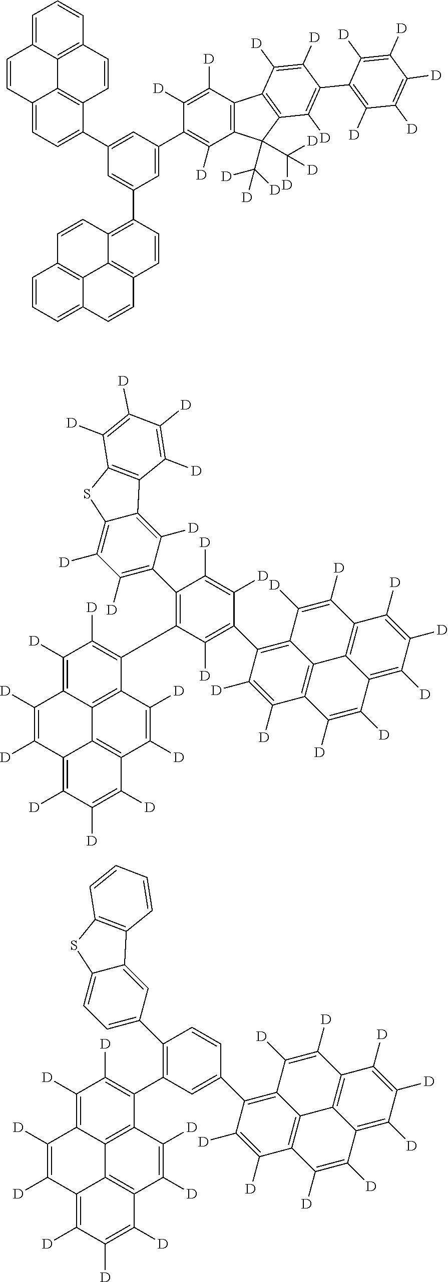

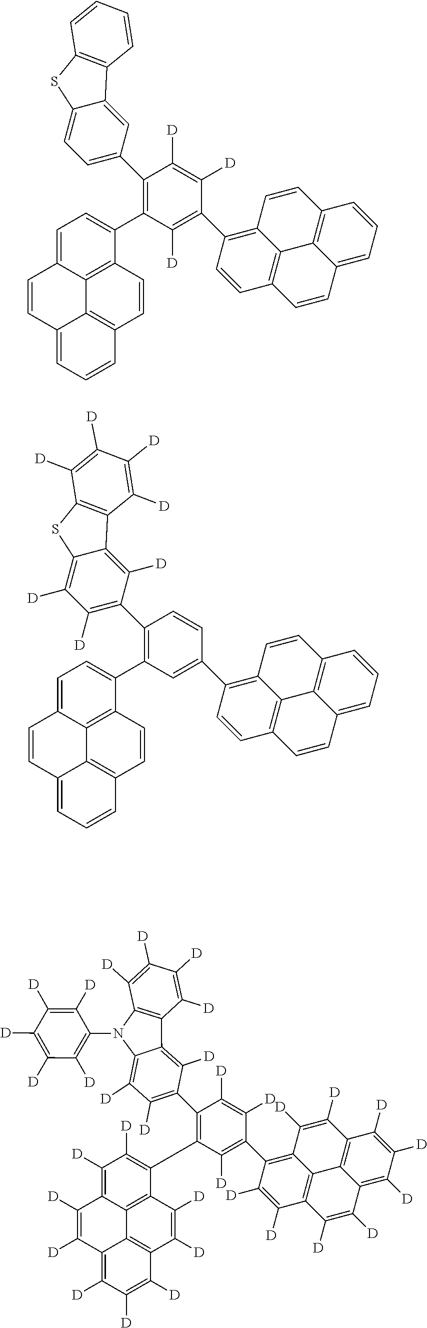

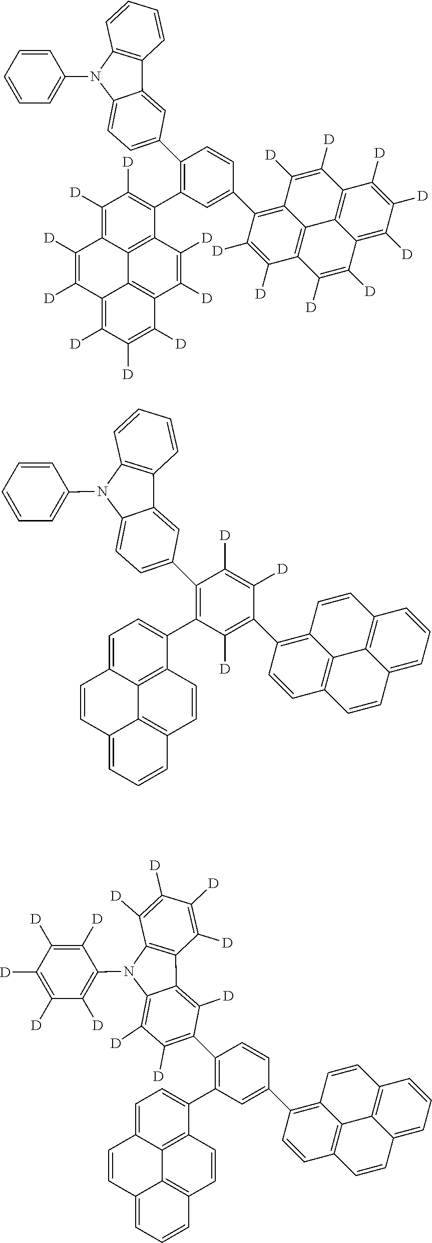

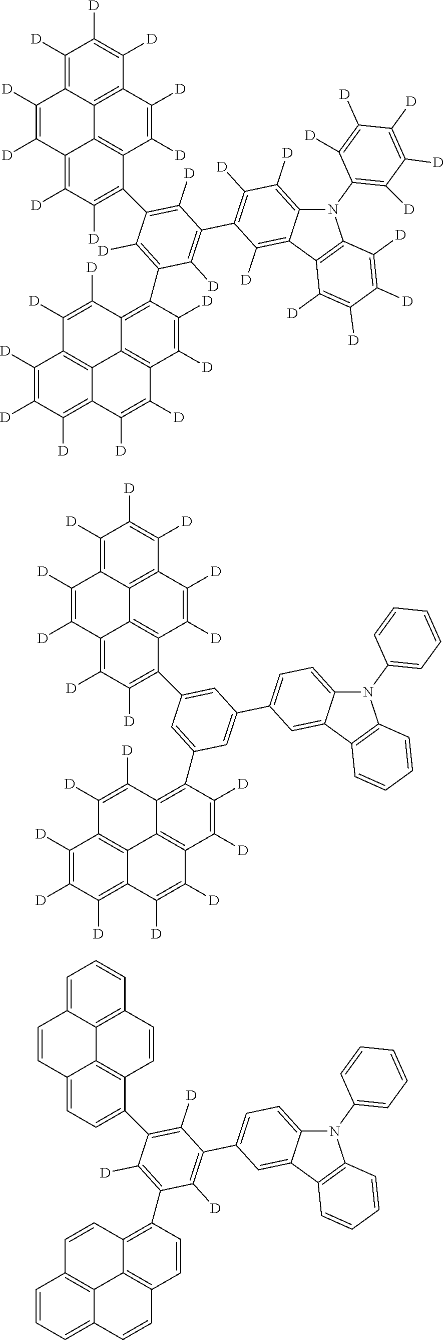

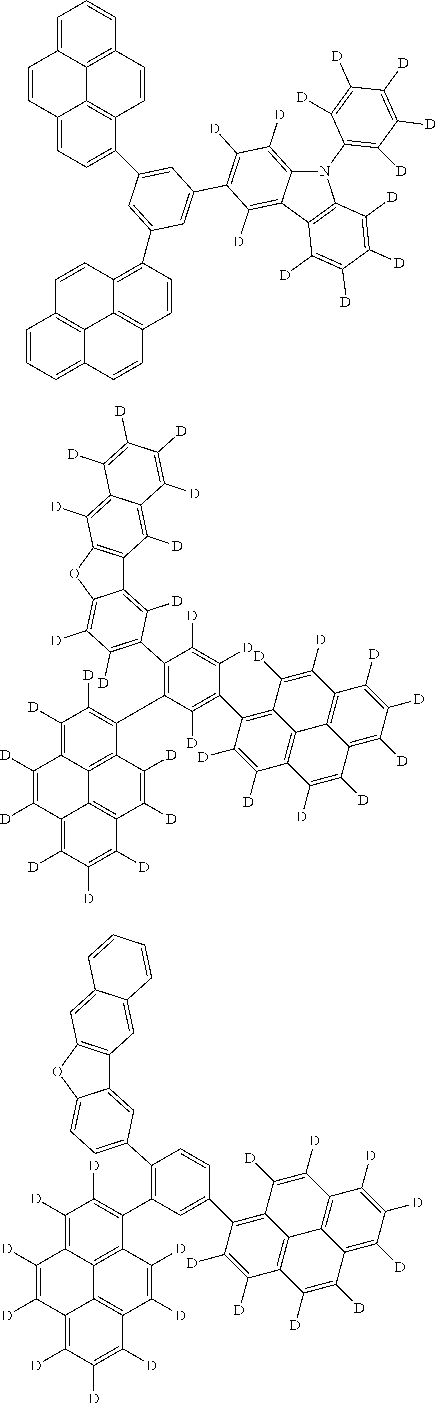

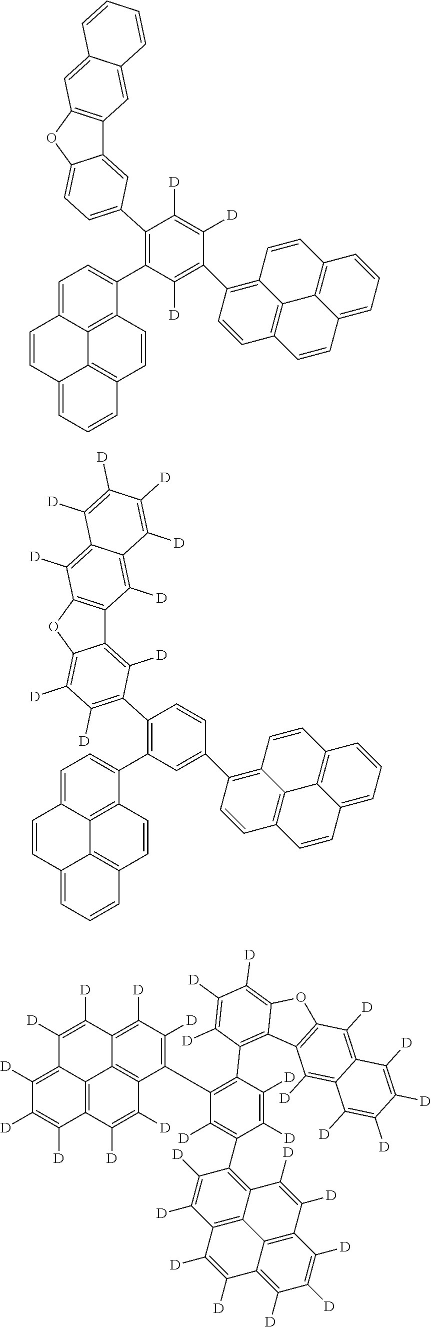

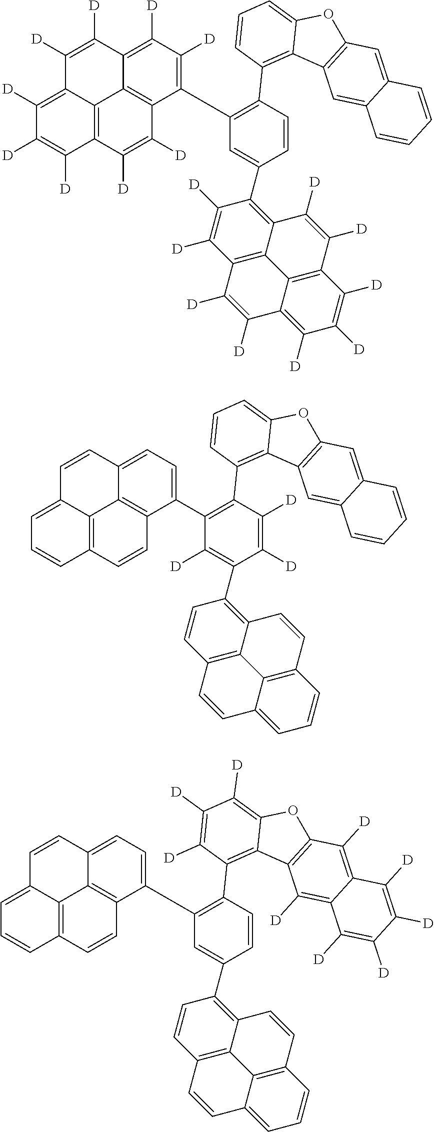 [SMILES: [2H]c1c([2H])c2c([2H])c([2H])c3c([2H])c([2H])c(-c4ccc(-c5cccc6oc7cc8ccccc8cc7c56)c(-c5c([2H])c([2H])c6c([2H])c([2H])c7c([2H])c([2H])c([2H])c8c([2H])c([2H])c5c6c78)c4)c4c([2H])c([2H])c(c1[2H])c2c34 ; [2H]c1c([2H])c(-c2cccc3oc4cc5ccccc5cc4c23)c(-c2ccc3ccc4cccc5ccc2c3c45)c([2H])c1-c1ccc2ccc3cccc4ccc1c2c34 ; [2H]c1c([2H])c(-c2ccc(-c3ccc4ccc5cccc6ccc3c4c56)cc2-c2ccc3ccc4cccc5ccc2c3c45)c2c(oc3c([2H])c4c([2H])c([2H])c([2H])c([2H])c4c([2H])c32)c1[2H]]

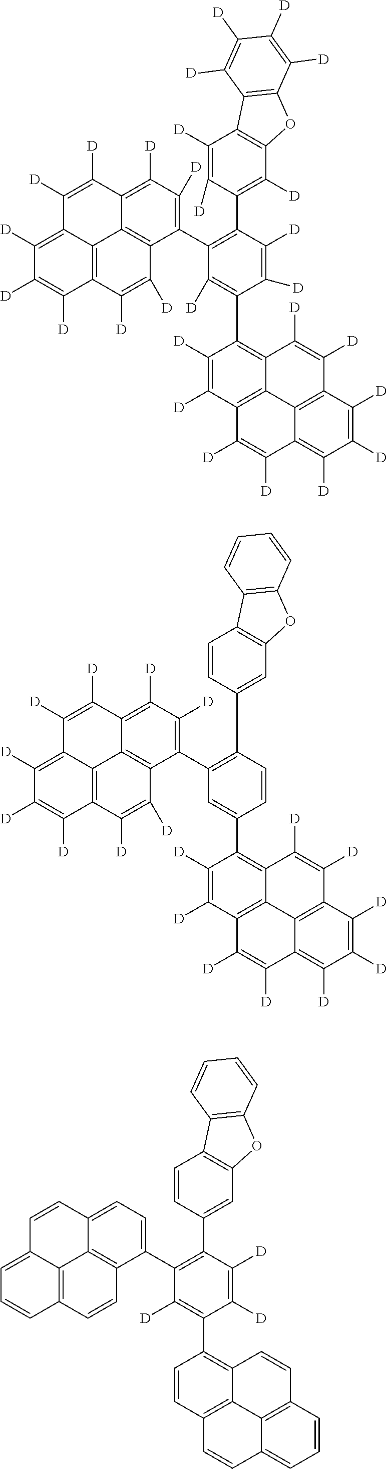

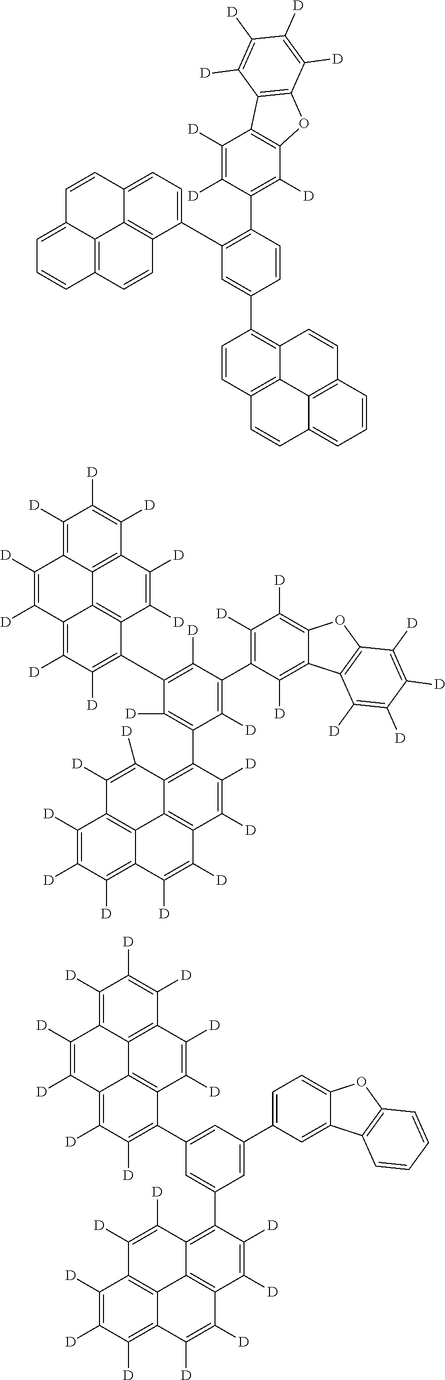

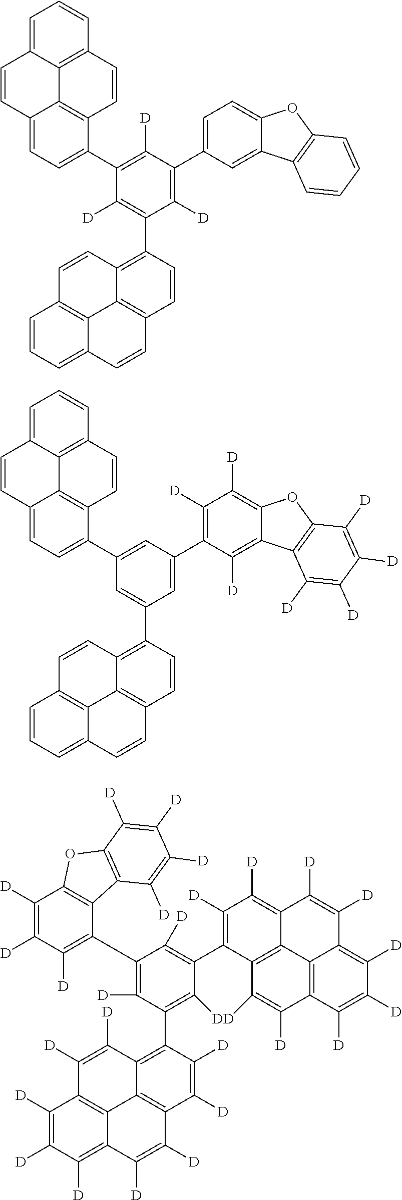

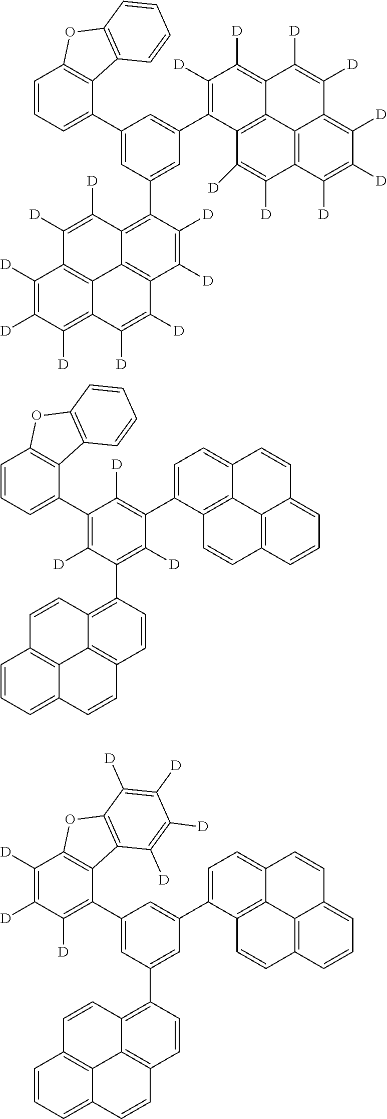

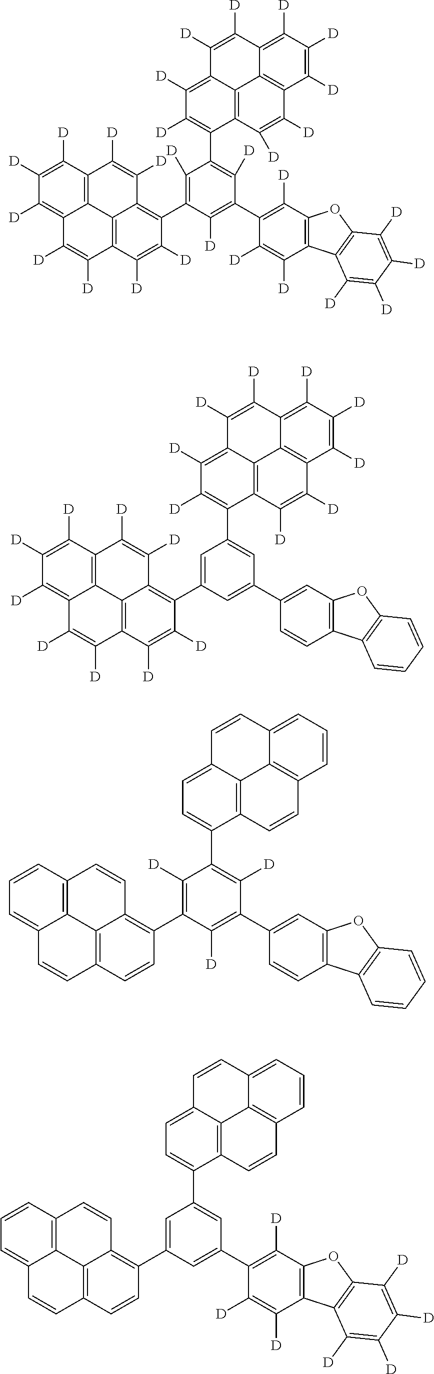

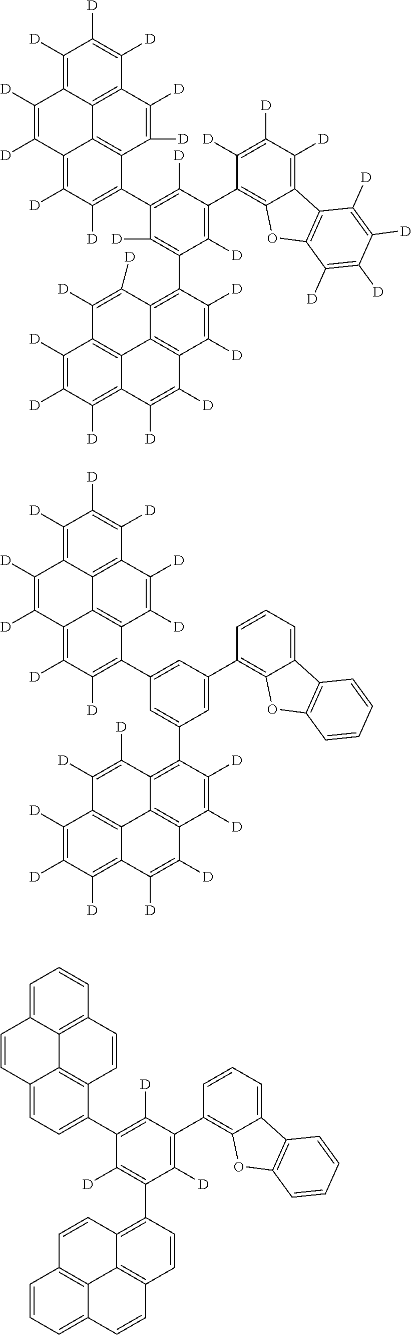

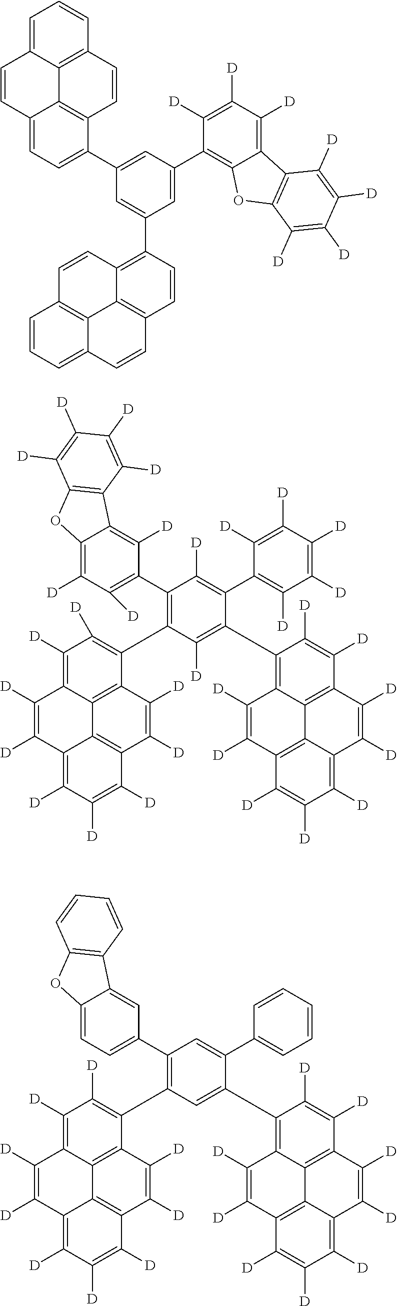

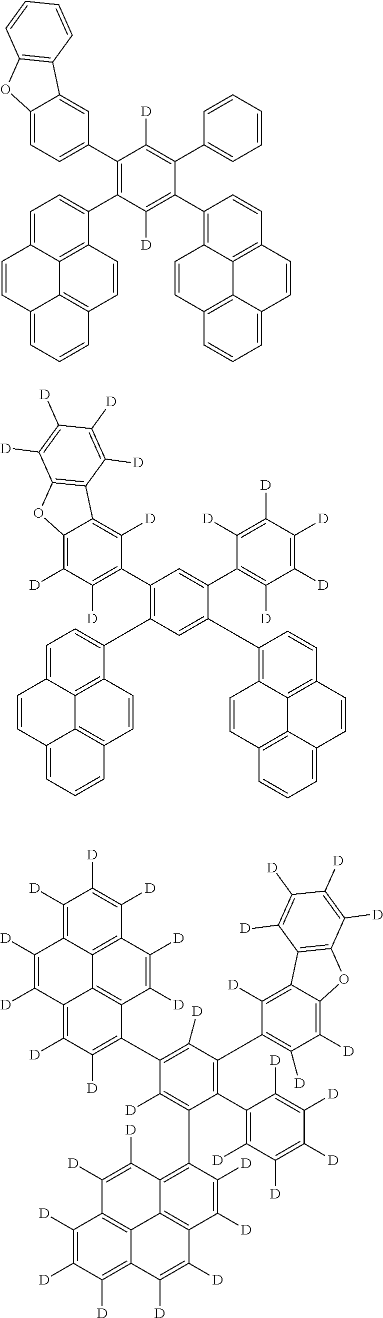

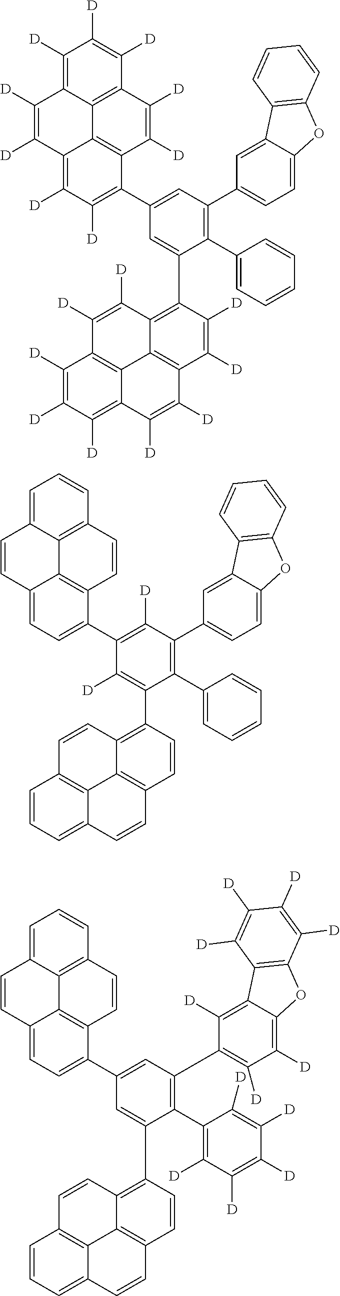

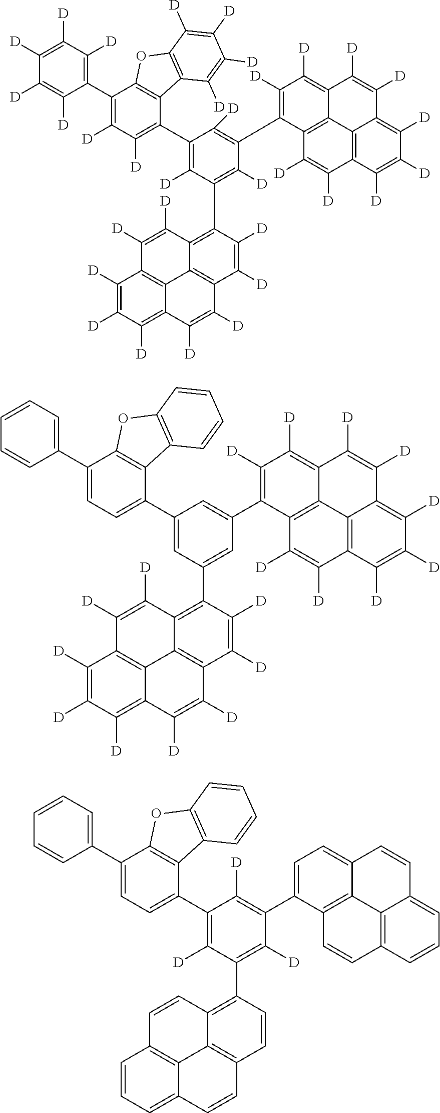

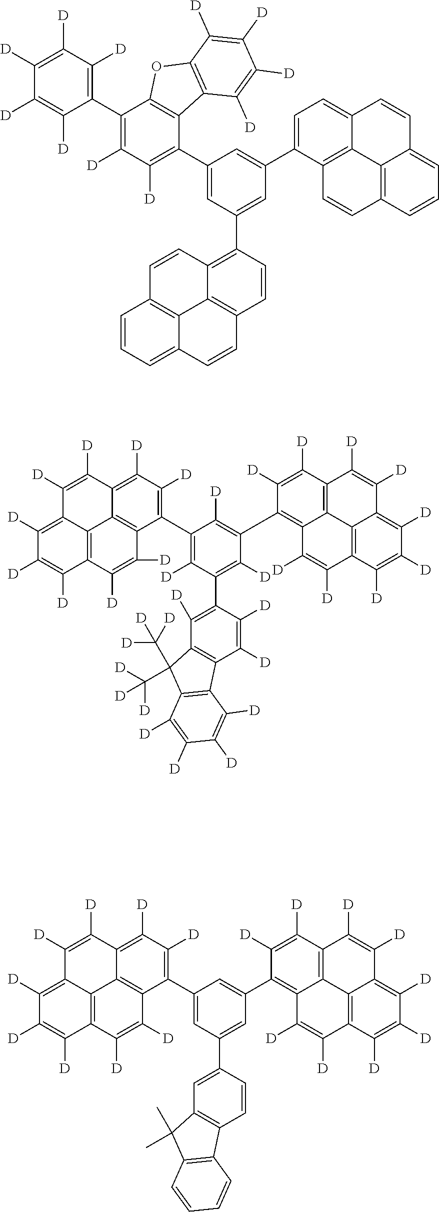

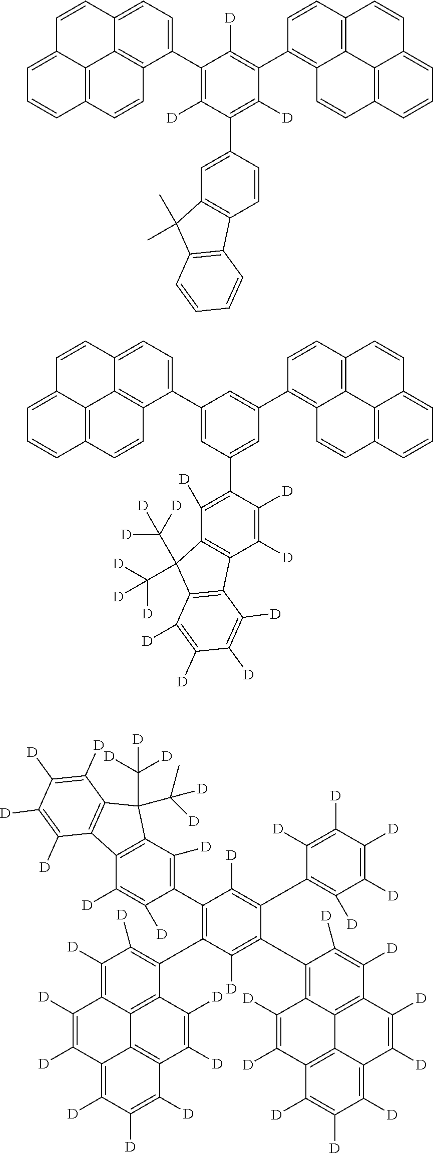

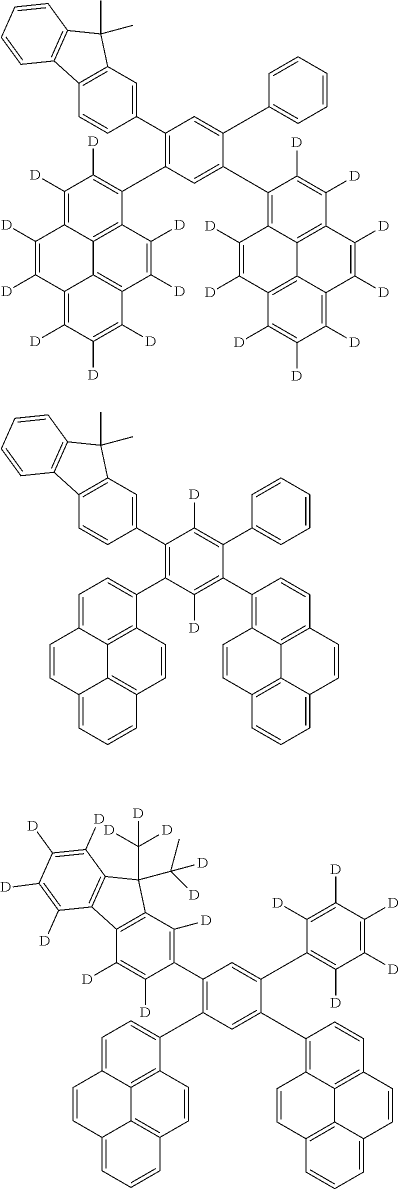

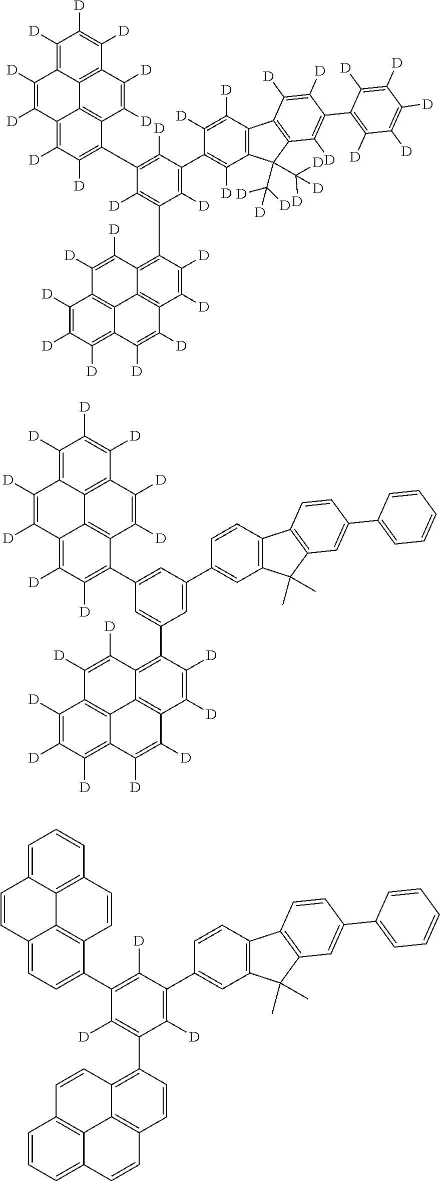

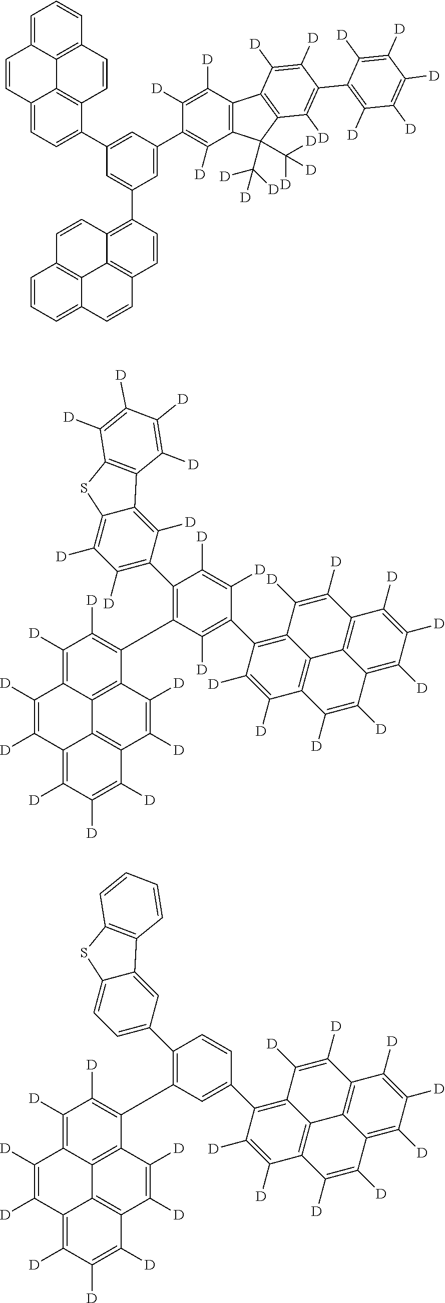

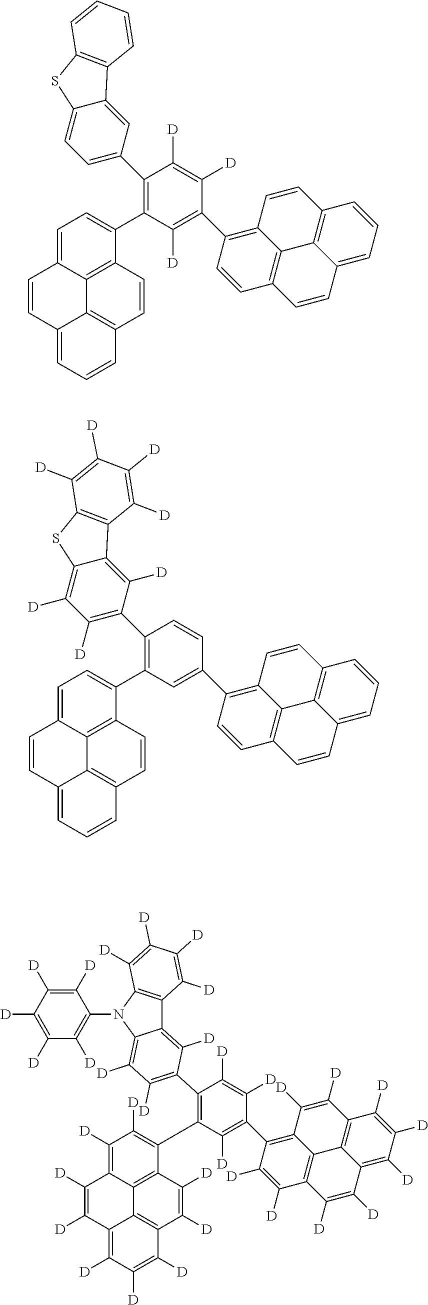

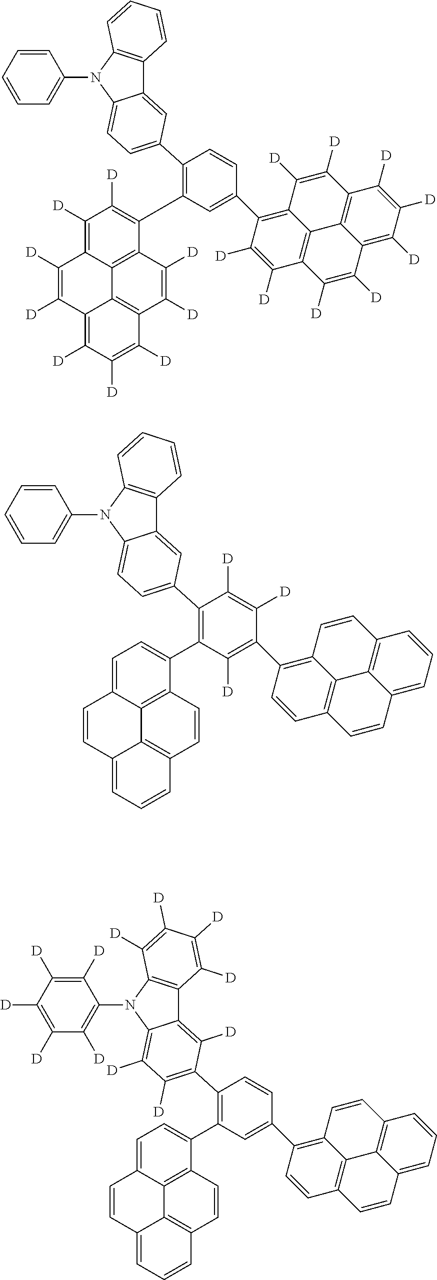 [SMILES: [2H]c1c([2H])c2c([2H])c([2H])c3c([2H])c([2H])c(-c4ccc(-c5ccc6c(c5)c5ccccc5n6-c5ccccc5)c(-c5c([2H])c([2H])c6c([2H])c([2H])c7c([2H])c([2H])c([2H])c8c([2H])c([2H])c5c6c78)c4)c4c([2H])c([2H])c(c1[2H])c2c34 ; [2H]c1c([2H])c(-c2ccc3c(c2)c2ccccc2n3-c2ccccc2)c(-c2ccc3ccc4cccc5ccc2c3c45)c([2H])c1-c1ccc2ccc3cccc4ccc1c2c34 ; [2H]c1c([2H])c([2H])c(-n2c3c([2H])c([2H])c([2H])c([2H])c3c3c([2H])c(-c4ccc(-c5ccc6ccc7cccc8ccc5c6c78)cc4-c4ccc5ccc6cccc7ccc4c5c67)c([2H])c([2H])c32)c([2H])c1[2H]]

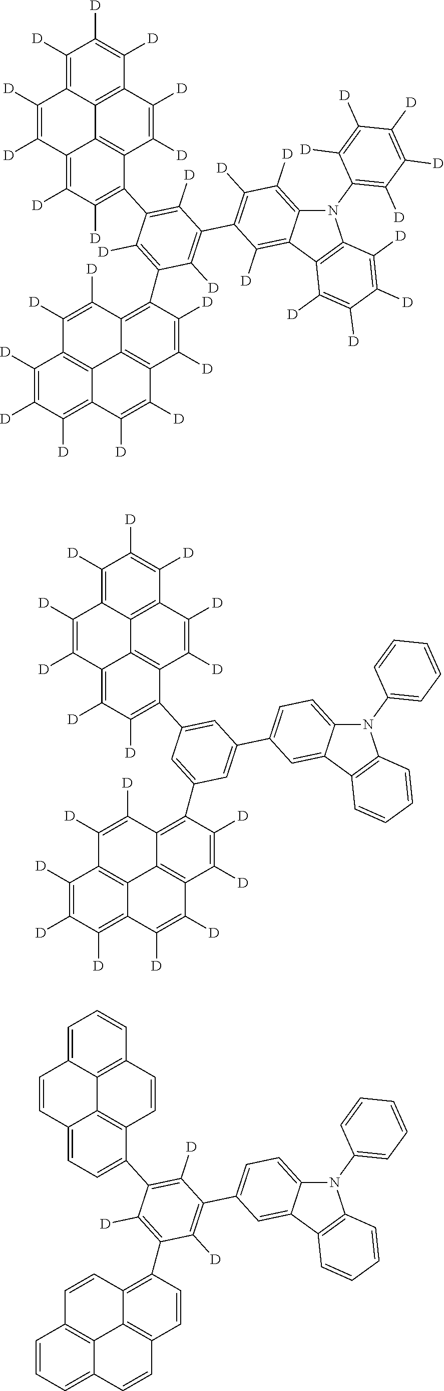

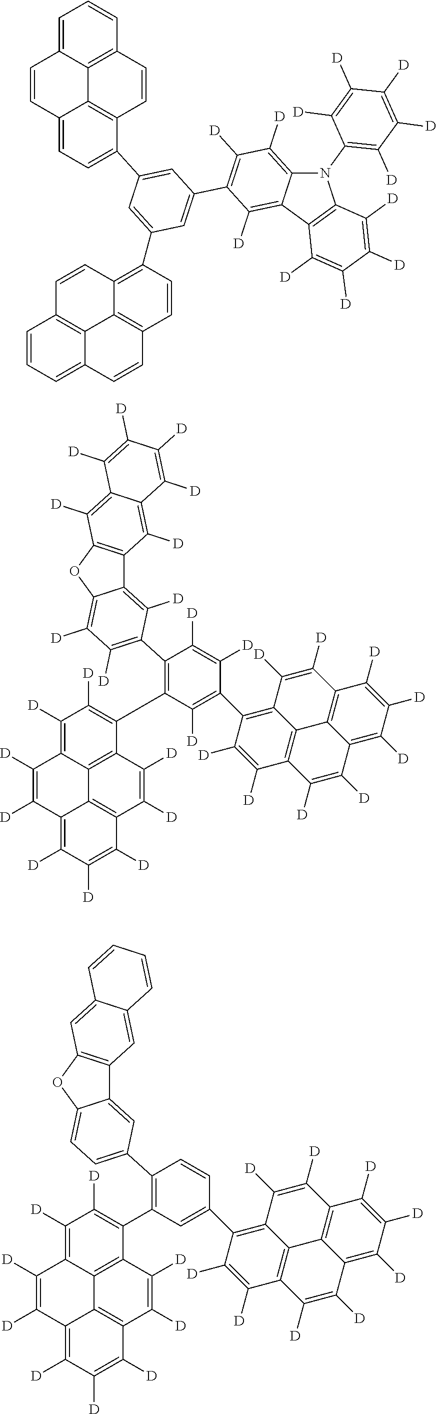

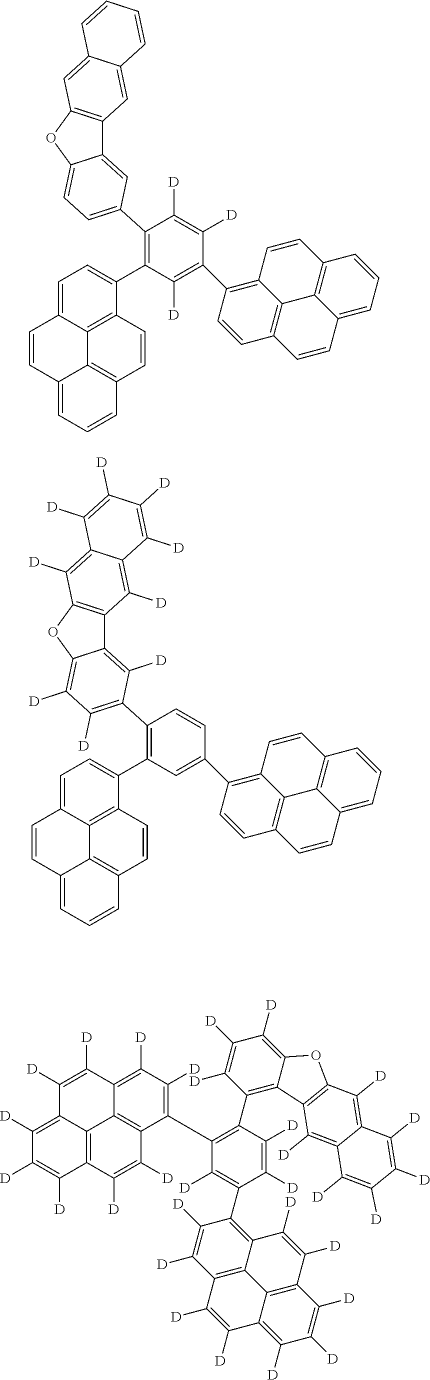

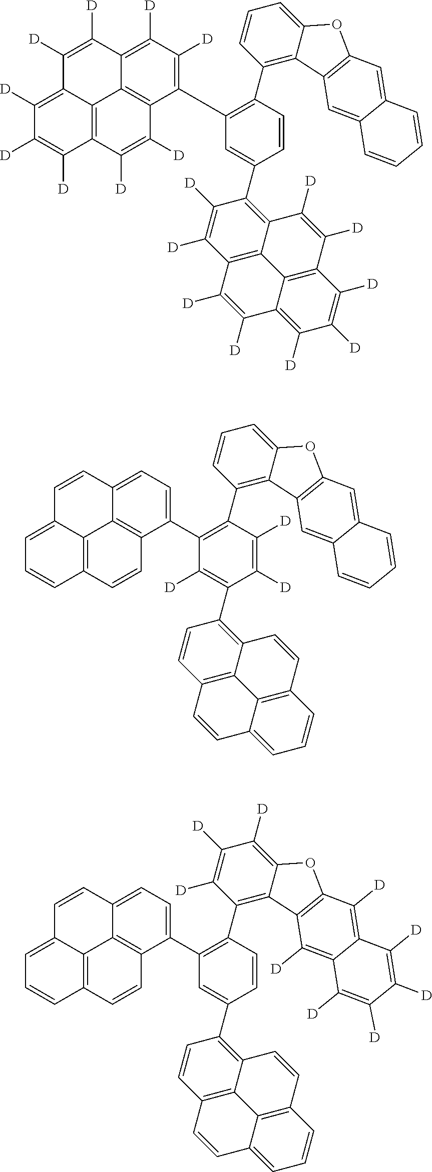 [SMILES: [2H]c1c([2H])c2c([2H])c([2H])c3c([2H])c([2H])c(-c4ccc(-c5cccc6oc7cc8ccccc8cc7c56)c(-c5c([2H])c([2H])c6c([2H])c([2H])c7c([2H])c([2H])c([2H])c8c([2H])c([2H])c5c6c78)c4)c4c([2H])c([2H])c(c1[2H])c2c34 ; [2H]c1c([2H])c(-c2cccc3oc4cc5ccccc5cc4c23)c(-c2ccc3ccc4cccc5ccc2c3c45)c([2H])c1-c1ccc2ccc3cccc4ccc1c2c34 ; [2H]c1c([2H])c(-c2ccc(-c3ccc4ccc5cccc6ccc3c4c56)cc2-c2ccc3ccc4cccc5ccc2c3c45)c2c(oc3c([2H])c4c([2H])c([2H])c([2H])c([2H])c4c([2H])c32)c1[2H]]

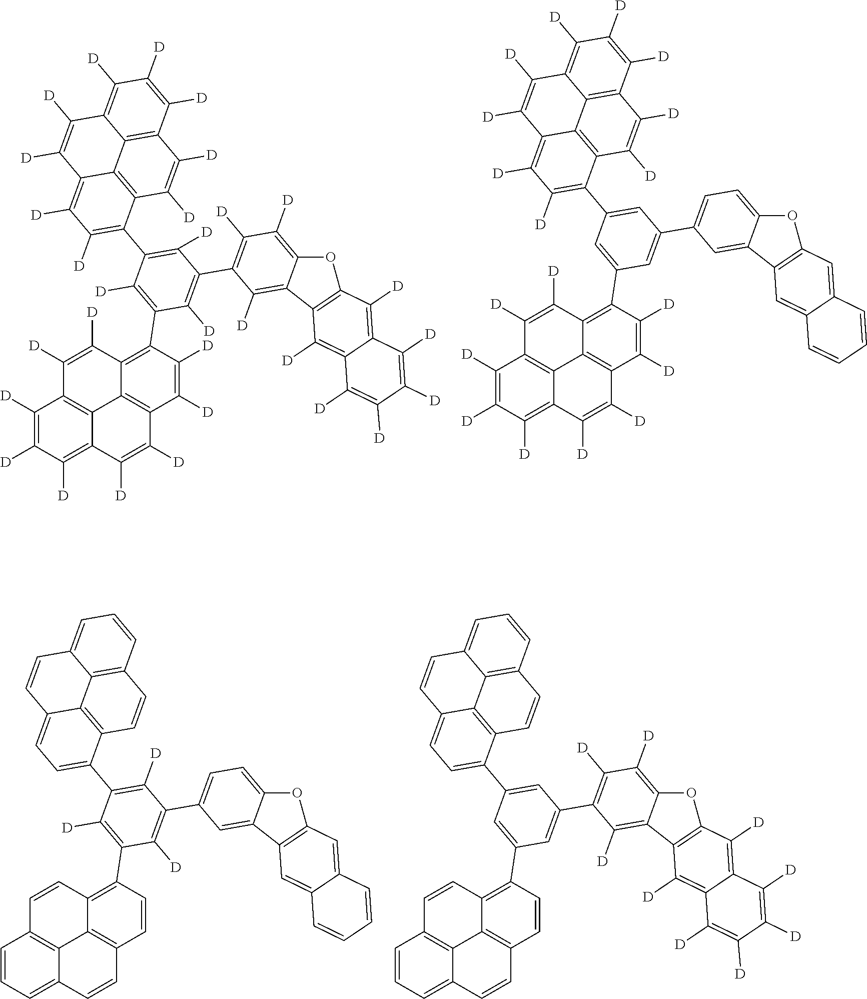

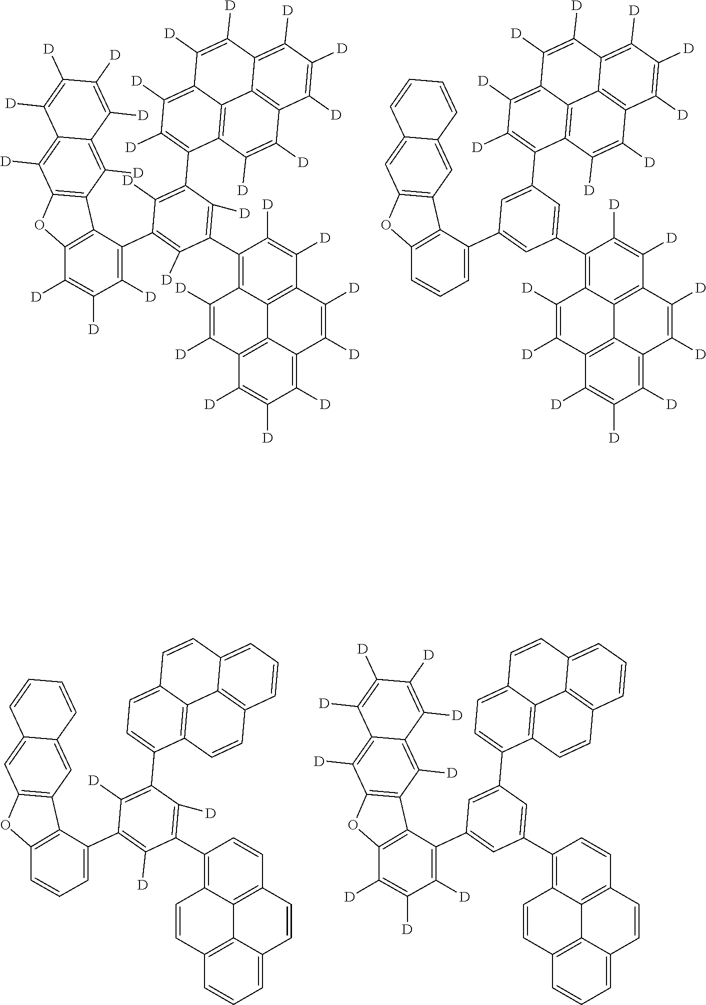

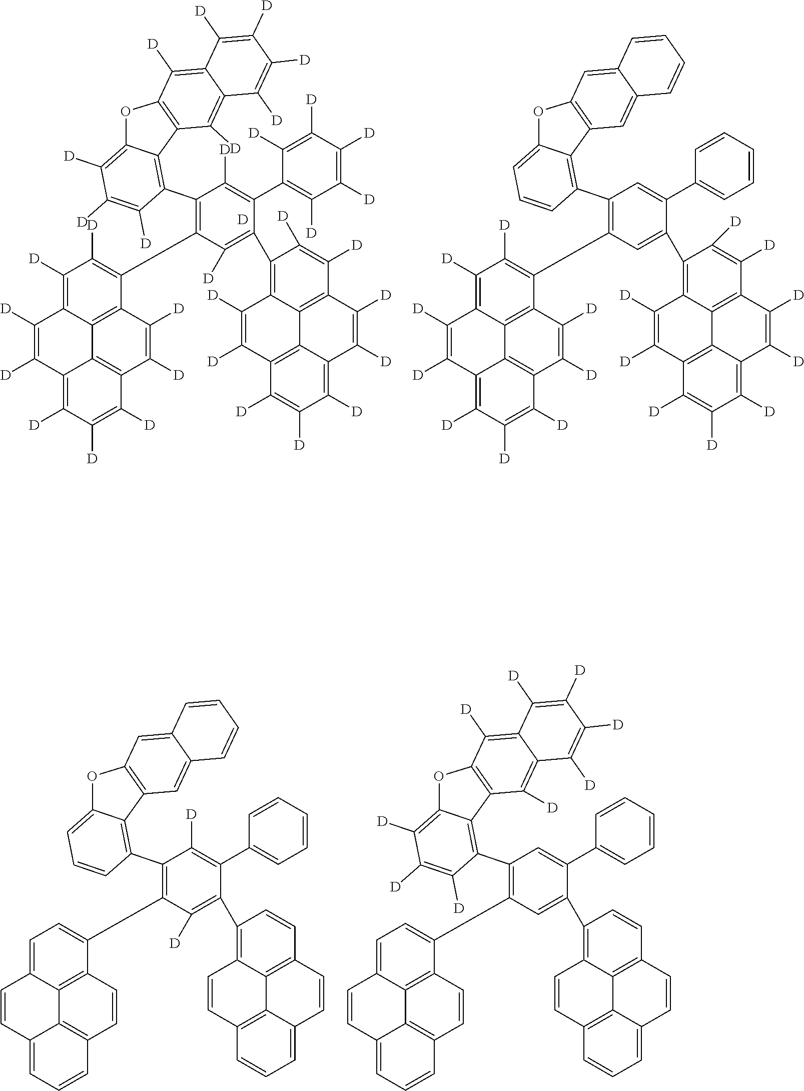

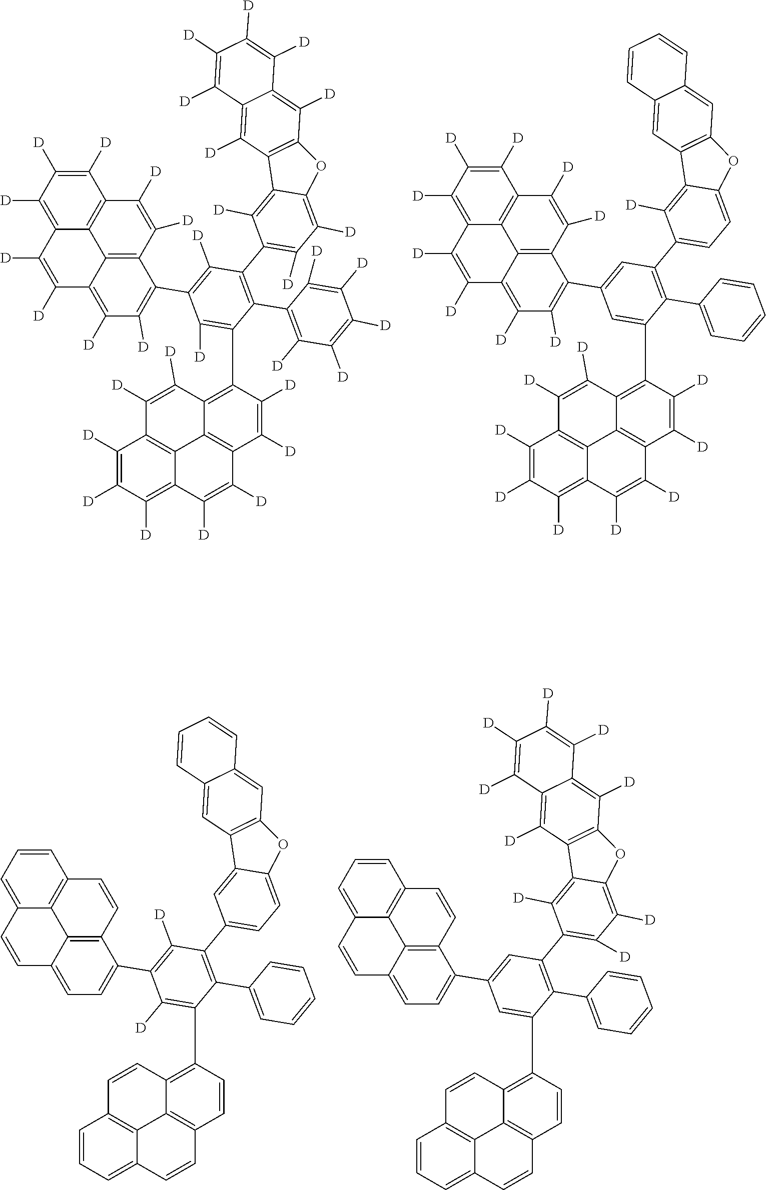

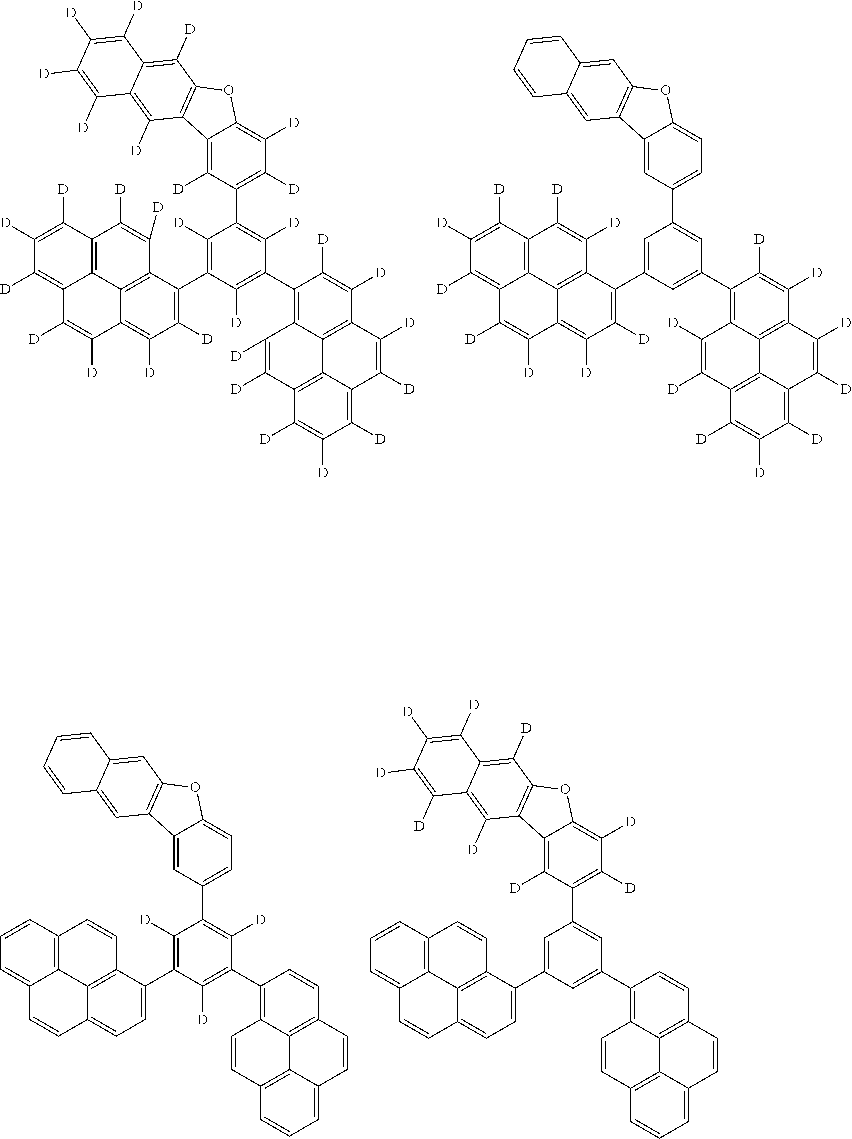

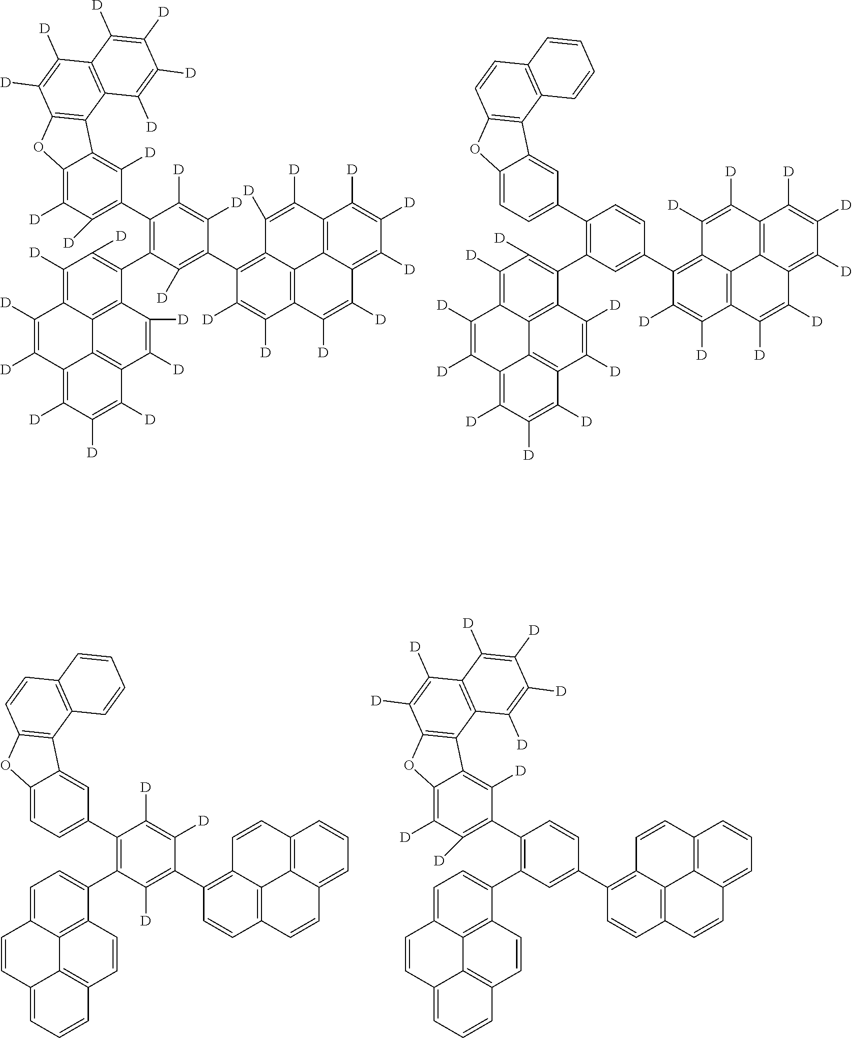

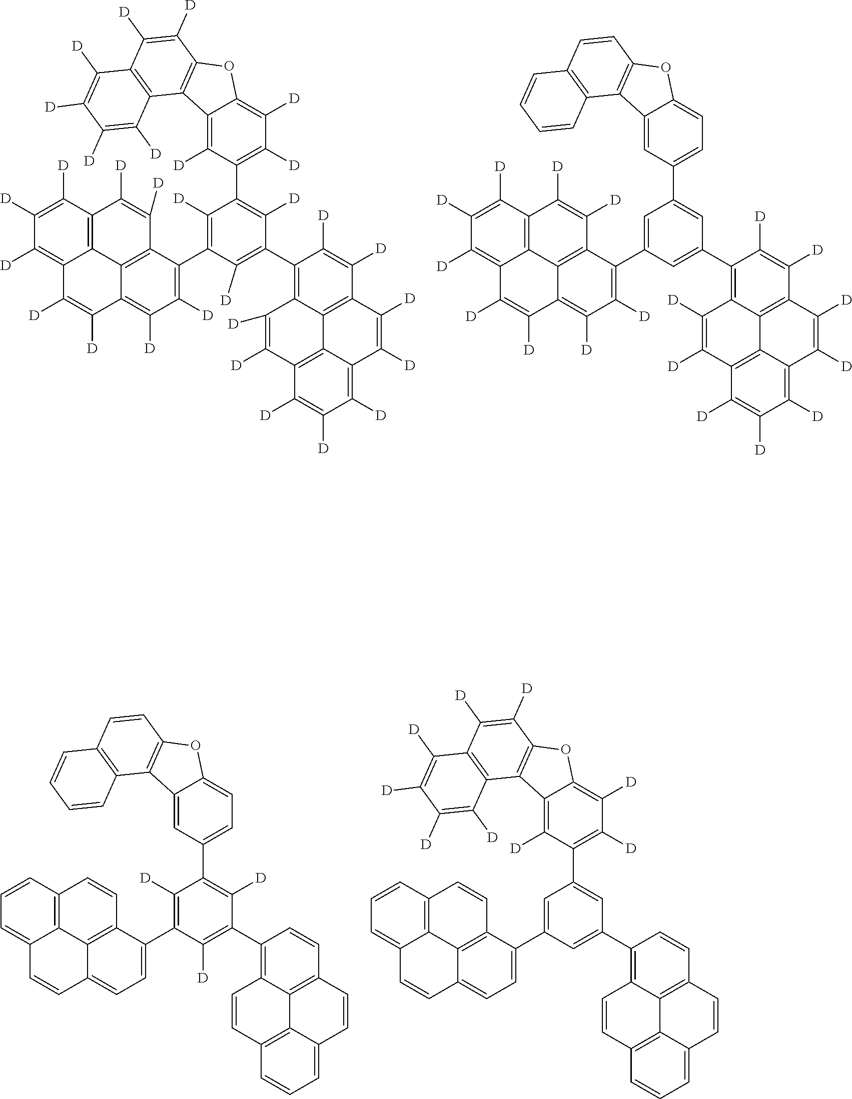

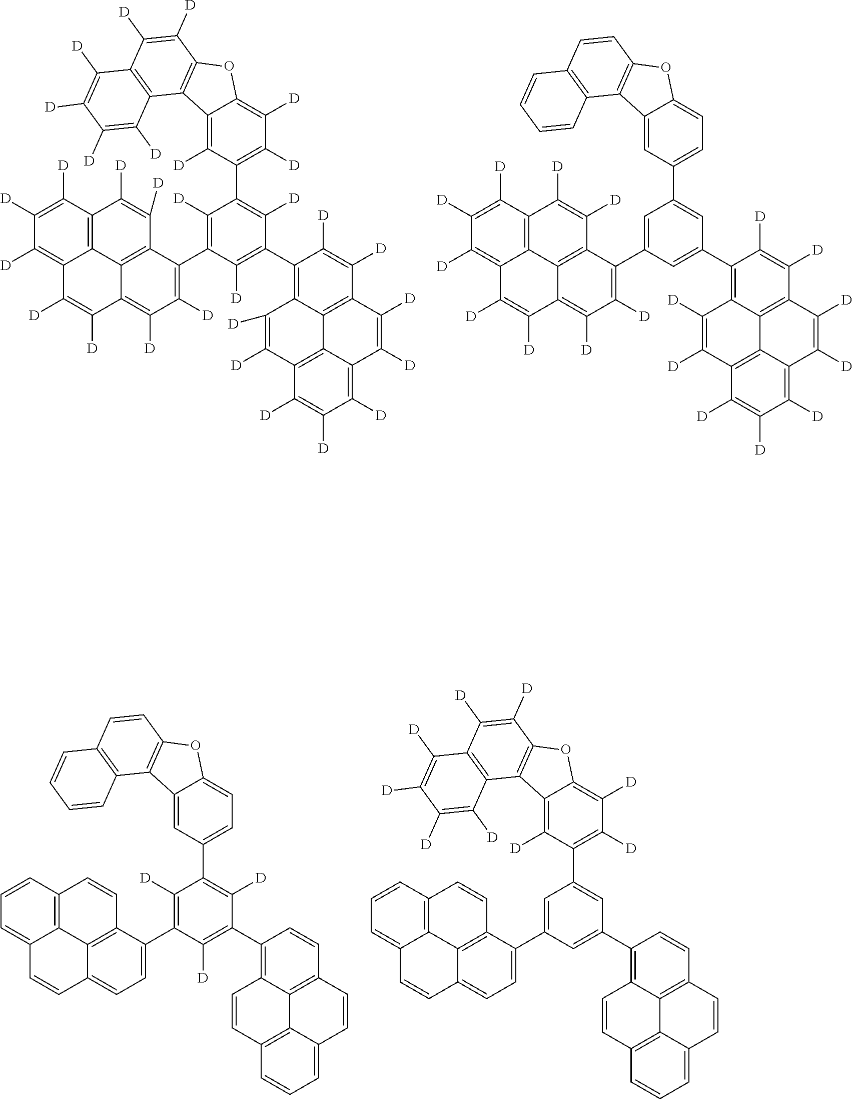

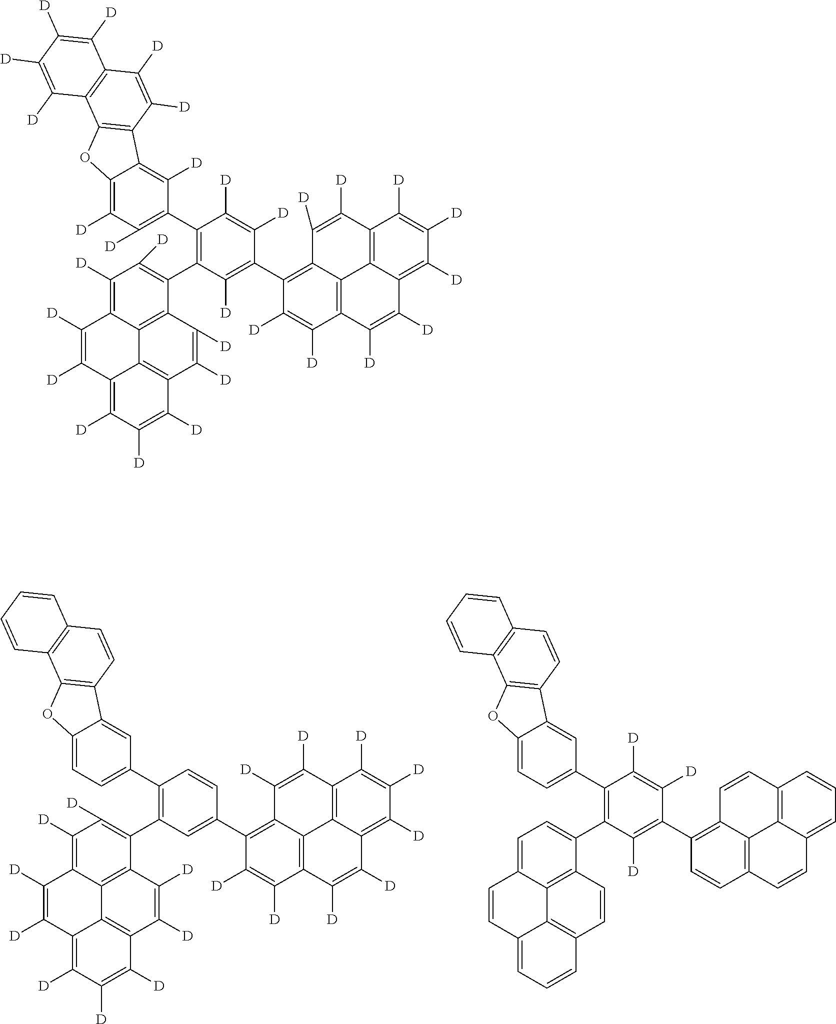

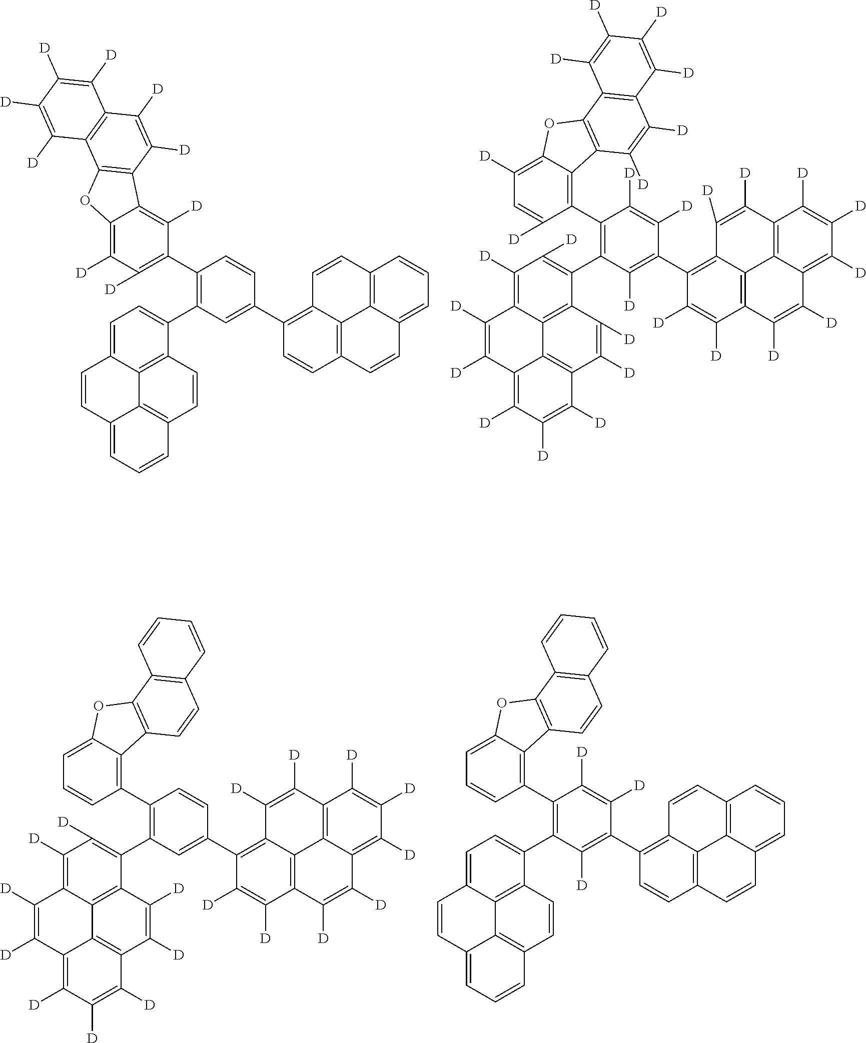

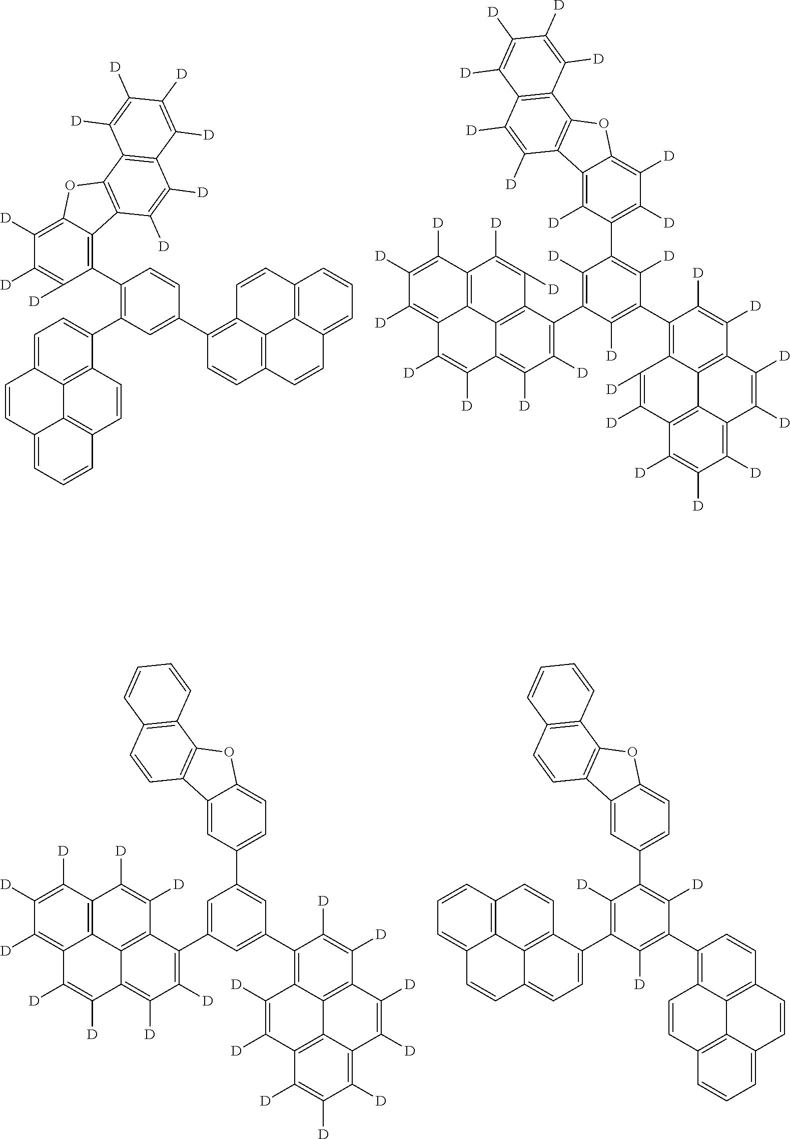

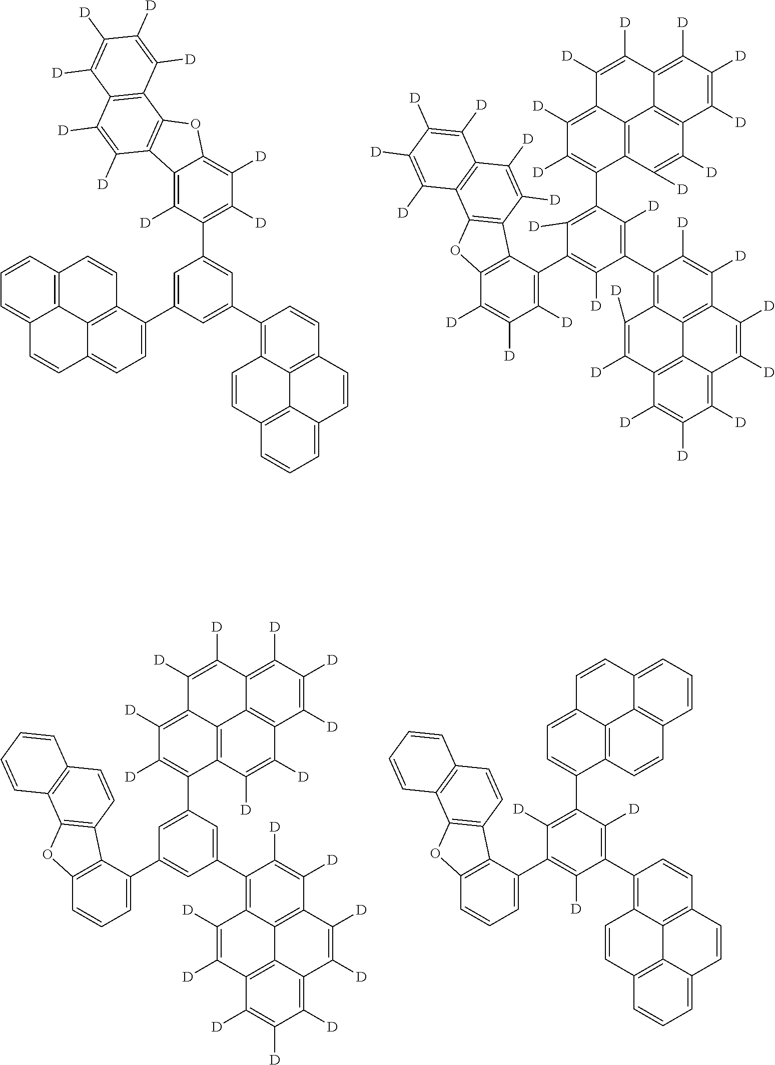

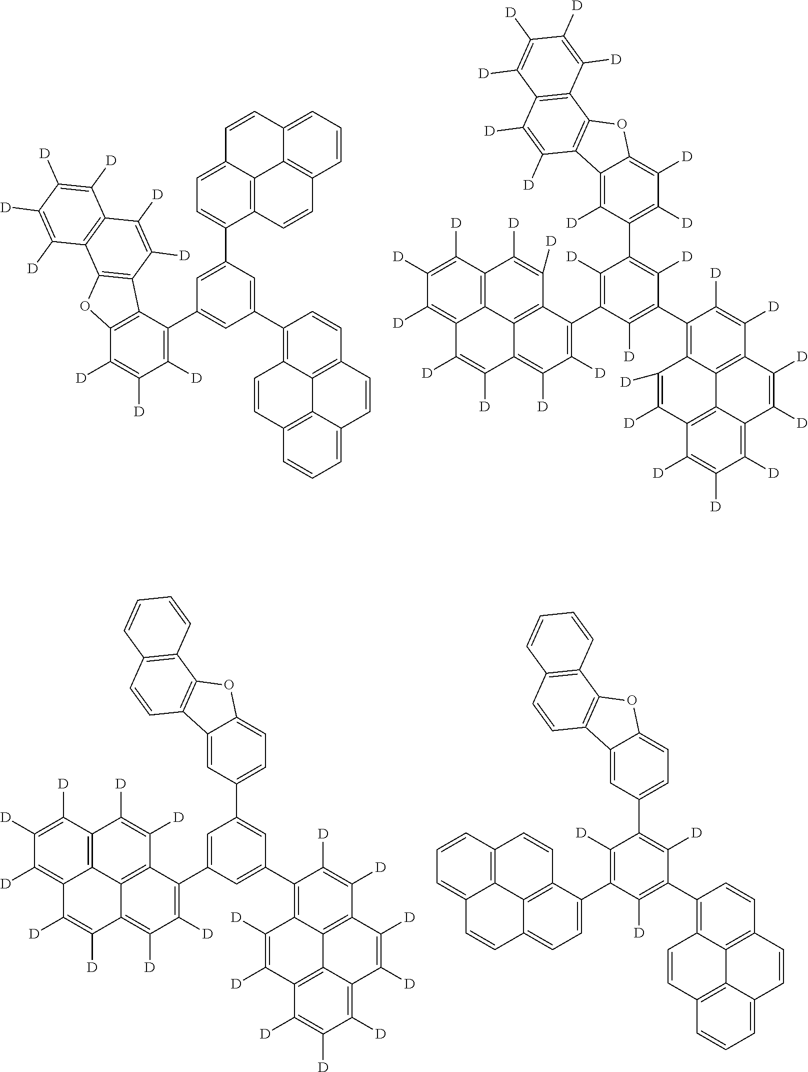

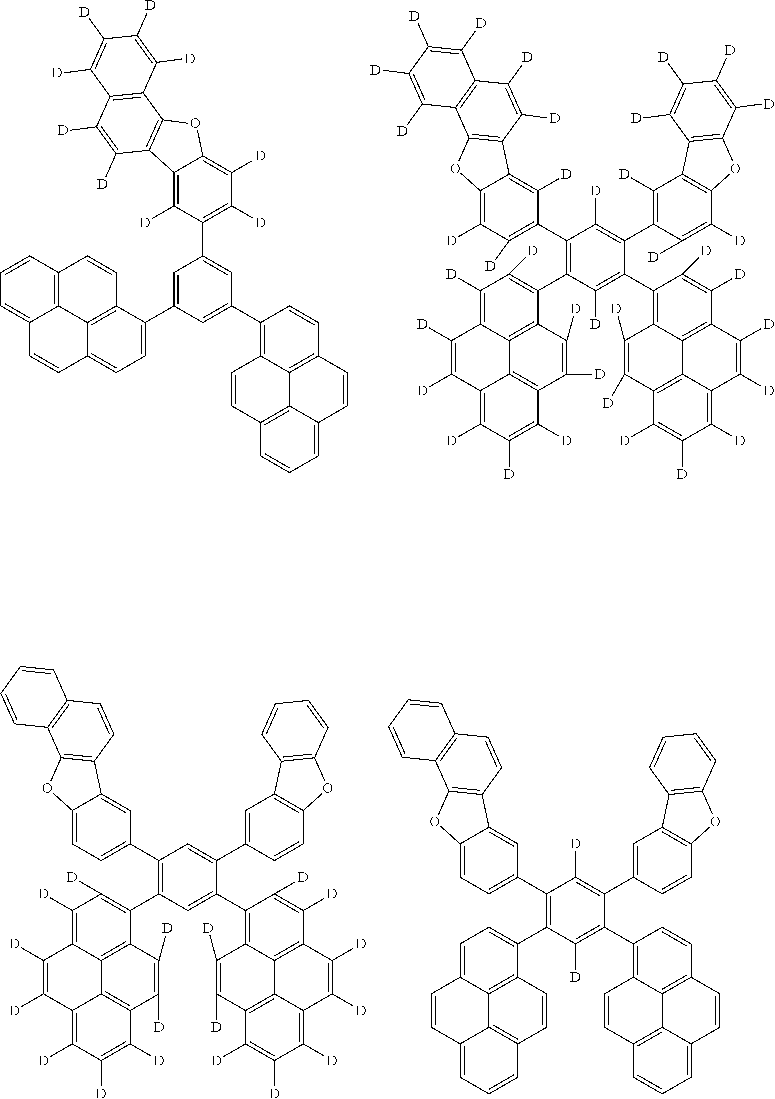

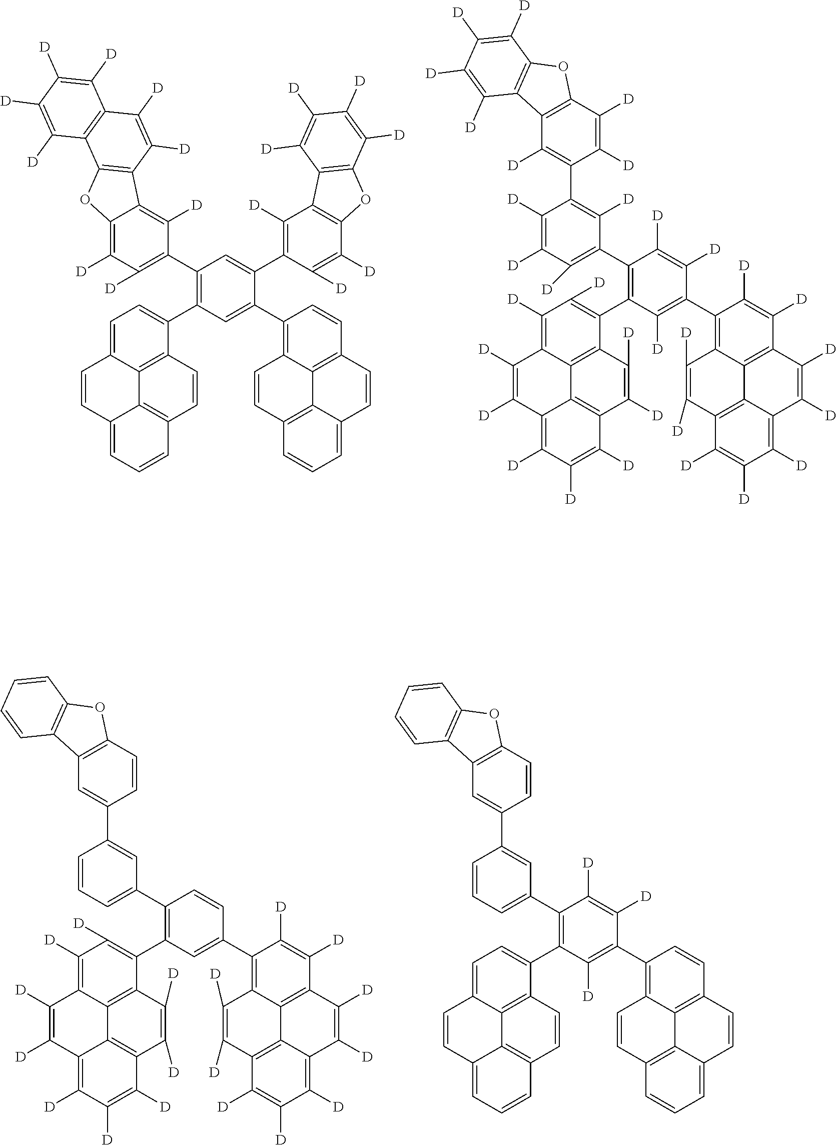

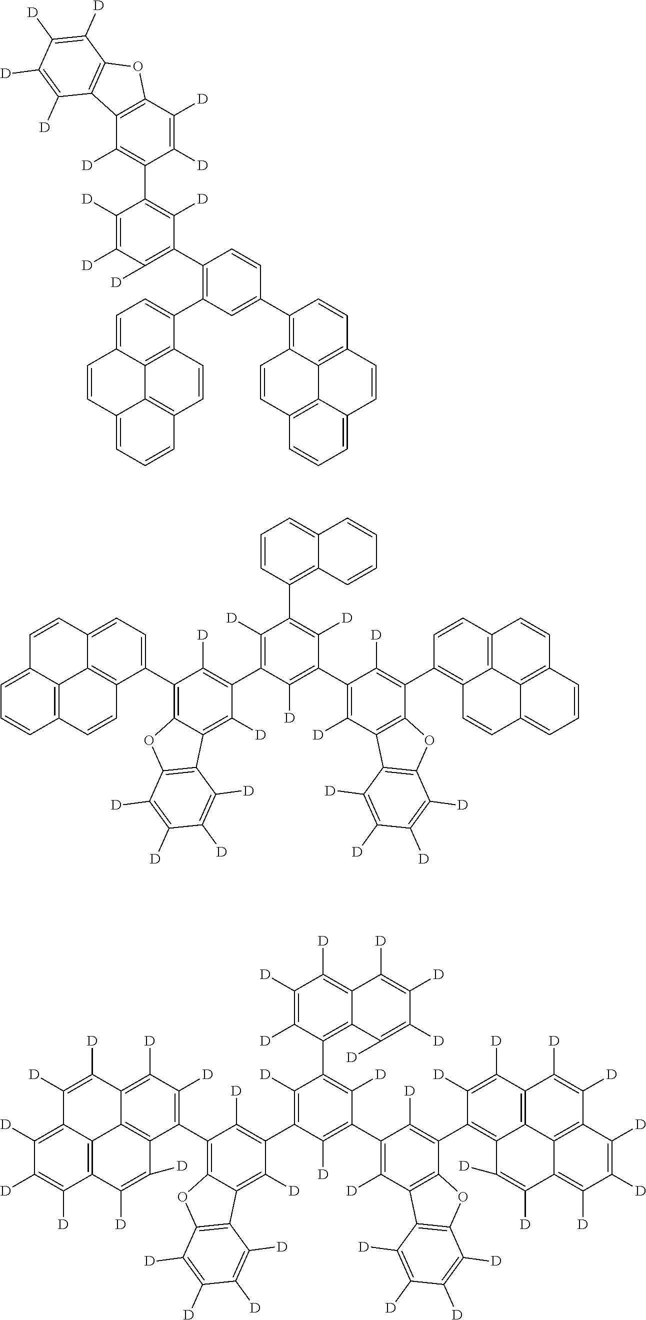

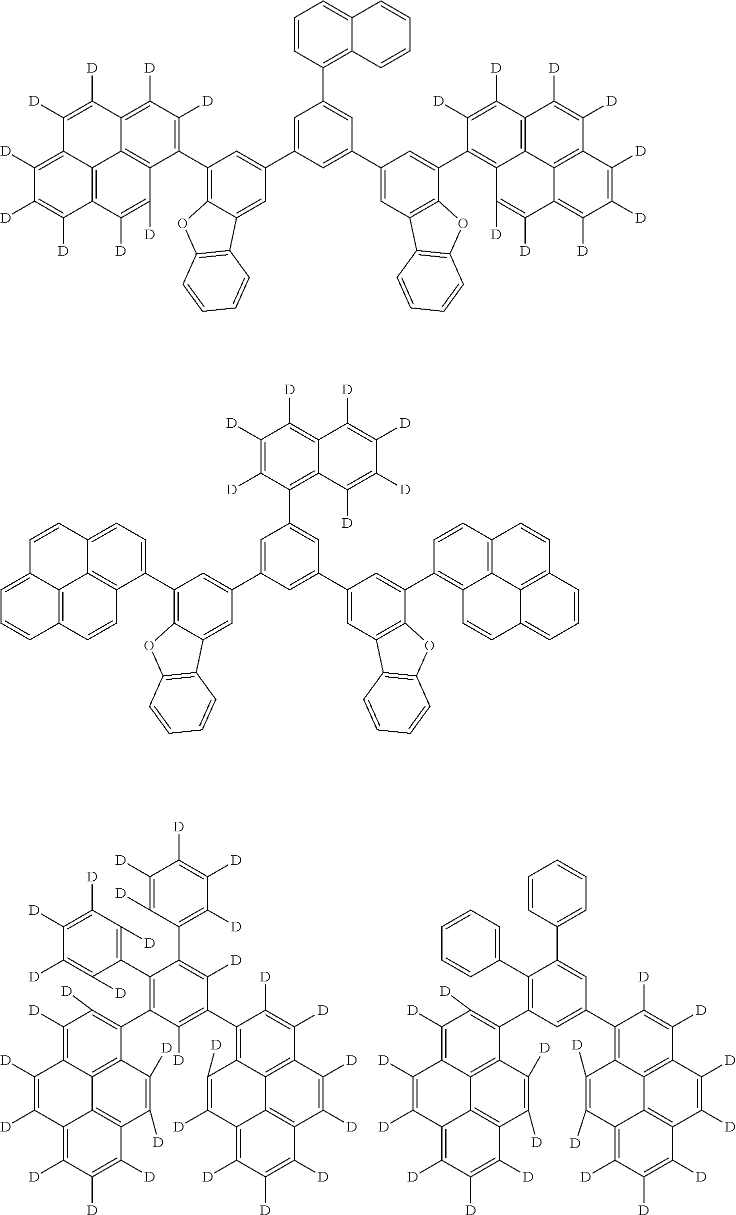

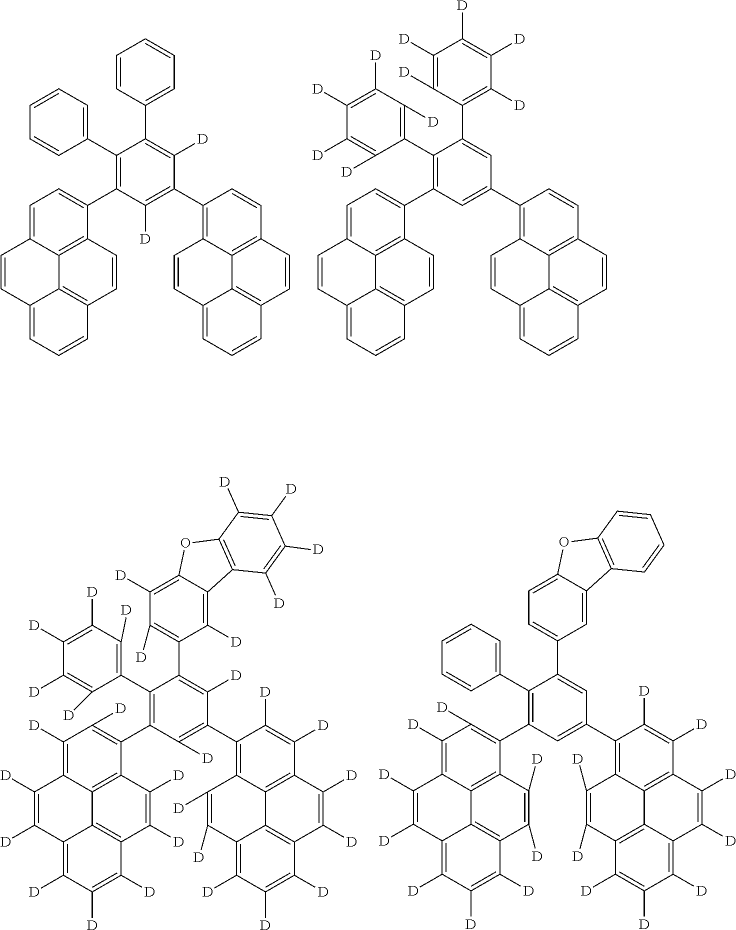

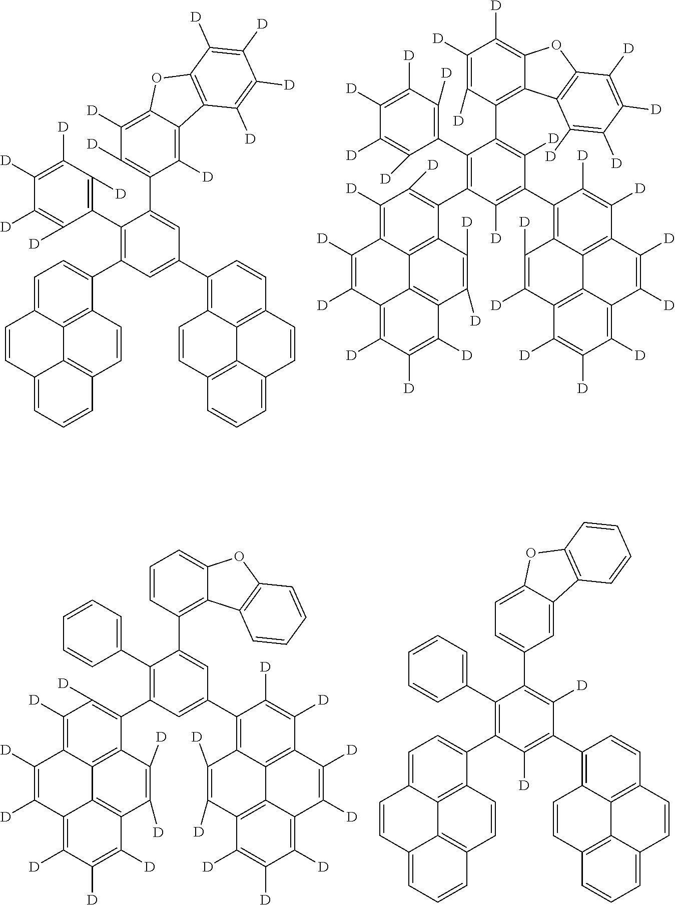

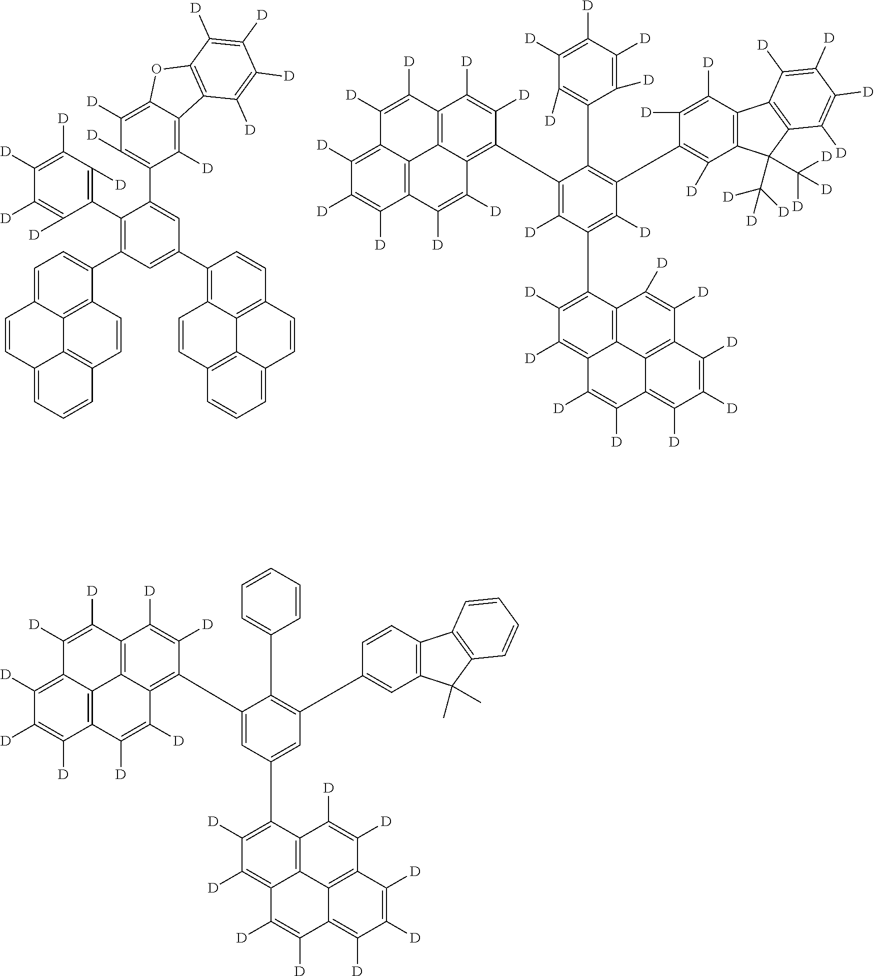

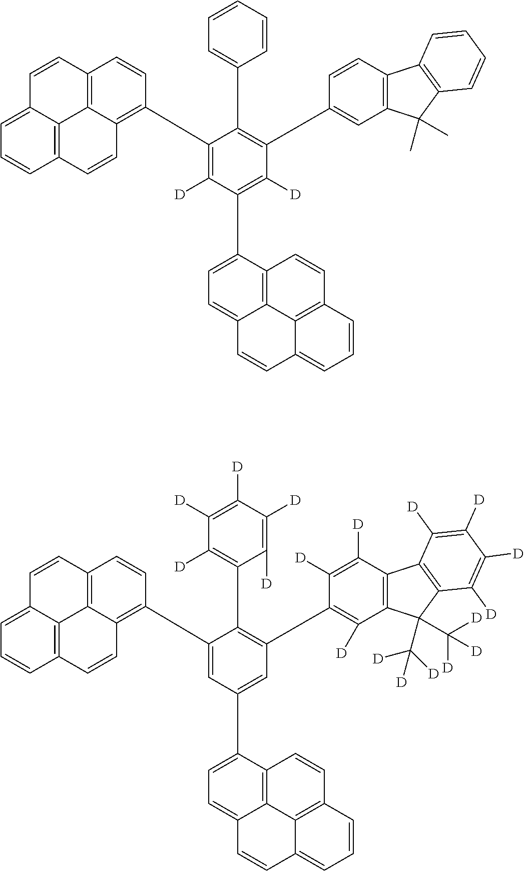 [SMILES: [2H]c1c(-c2ccc3ccc4cccc5ccc2c3c45)c([2H])c(-c2ccc3ccc4cccc5ccc2c3c45)c(-c2ccccc2)c1-c1ccc2c(c1)C(C)(C)c1ccccc1-2 ; [2H]c1c([2H])c([2H])c(-c2c(-c3c([2H])c([2H])c4c(c3[2H])C(C([2H])([2H])[2H])(C([2H])([2H])[2H])c3c([2H])c([2H])c([2H])c([2H])c3-4)cc(-c3ccc4ccc5cccc6ccc3c4c56)cc2-c2ccc3ccc4cccc5ccc2c3c45)c([2H])c1[2H]]

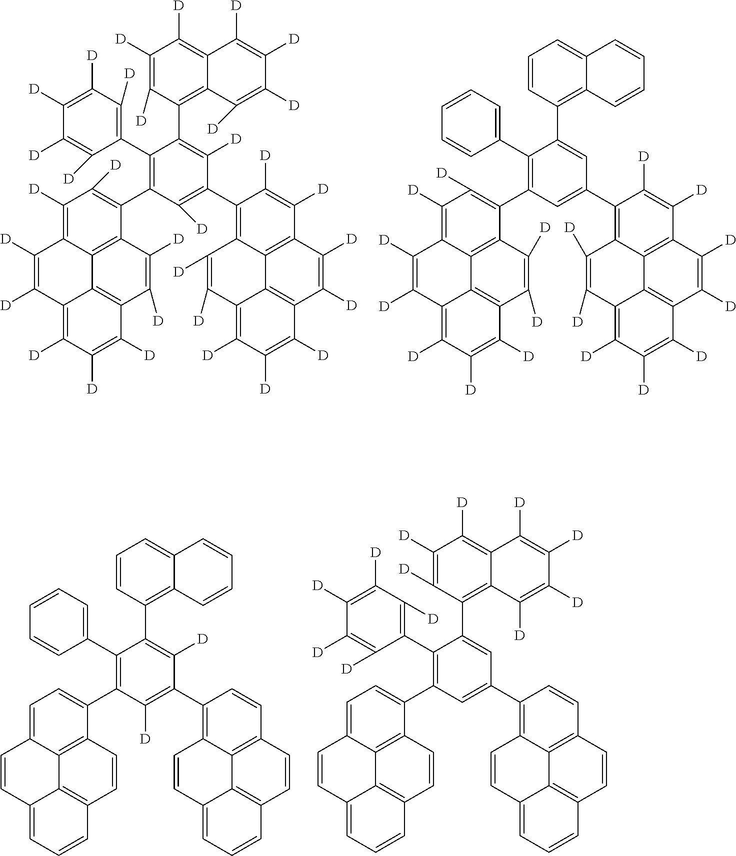

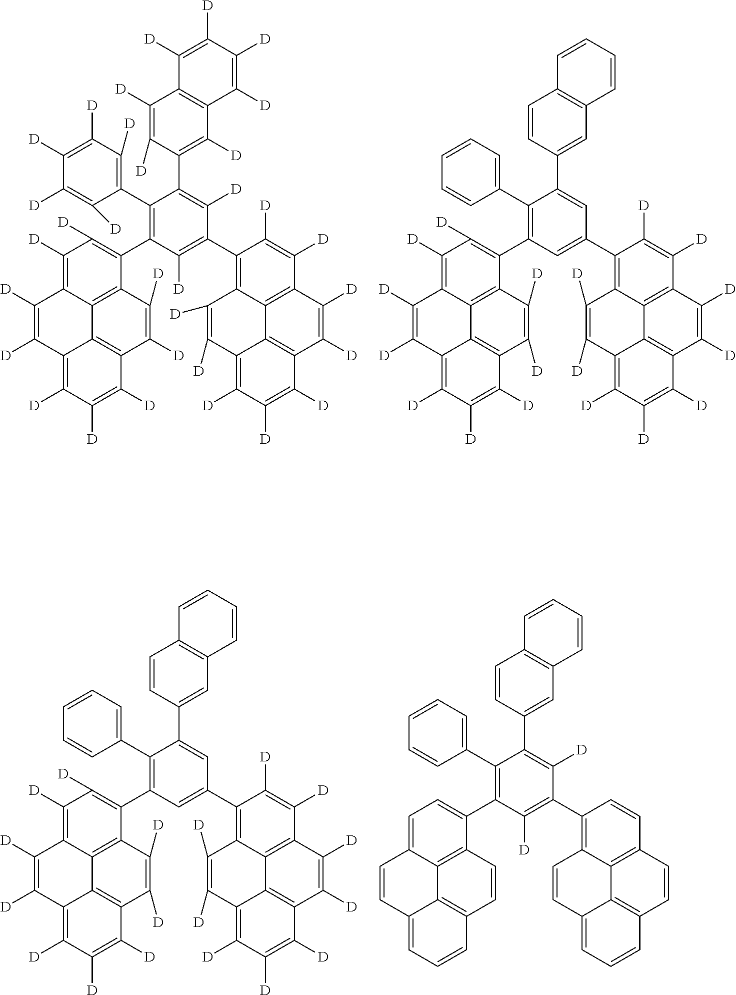

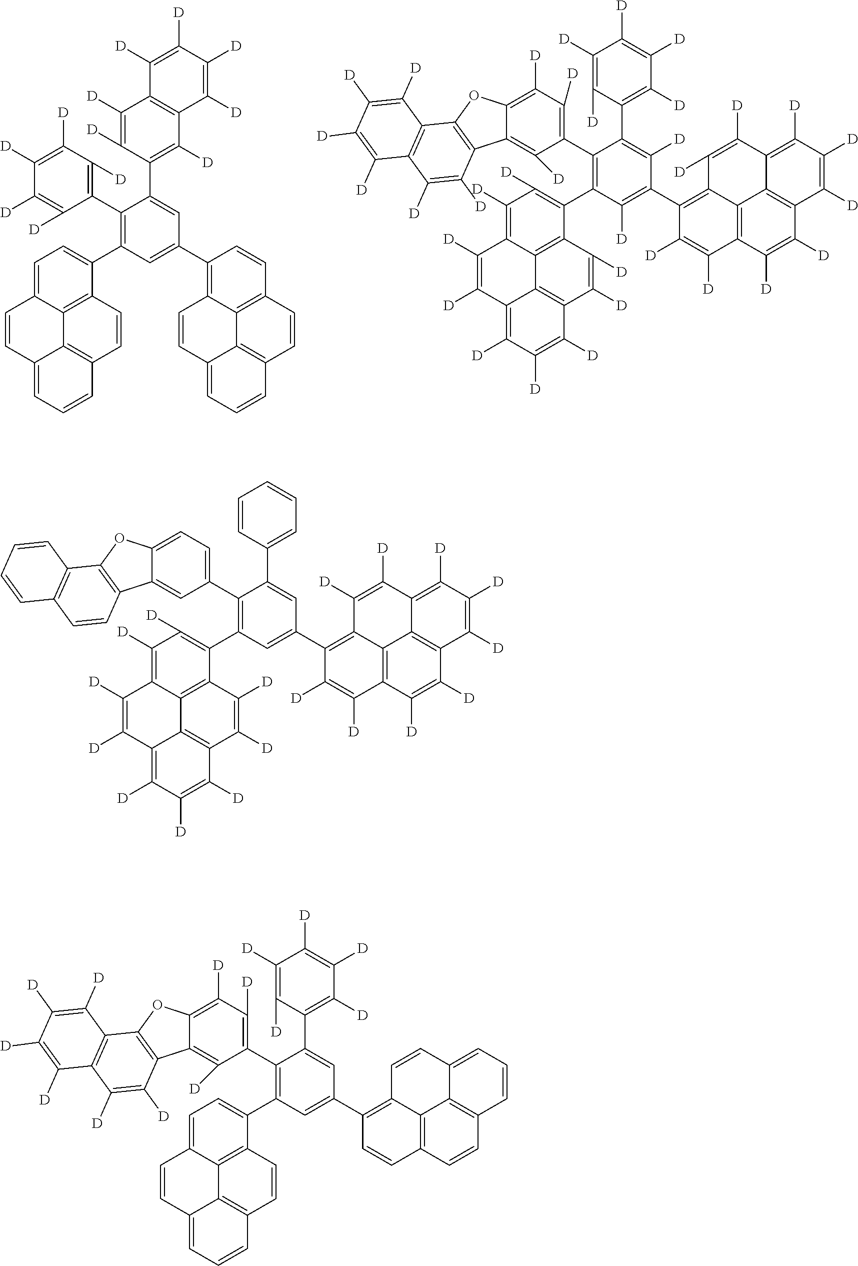

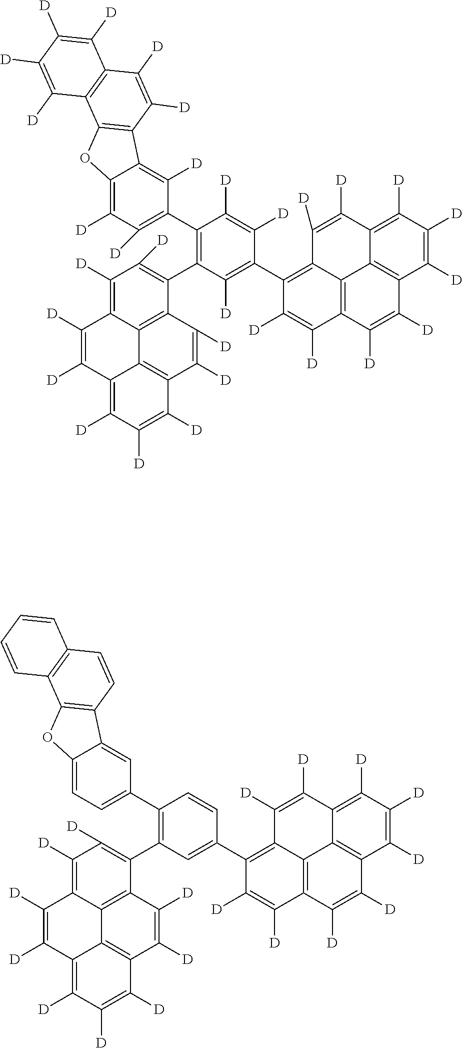 [SMILES: [2H]c1c([2H])c(-c2c([2H])c([2H])c3oc4c5c([2H])c([2H])c([2H])c([2H])c5c([2H])c([2H])c4c3c2[2H])c(-c2c([2H])c([2H])c3c([2H])c([2H])c4c([2H])c([2H])c([2H])c5c([2H])c([2H])c2c3c45)c([2H])c1-c1c([2H])c([2H])c2c([2H])c([2H])c3c([2H])c([2H])c([2H])c4c([2H])c([2H])c1c2c34 ; [2H]c1c([2H])c2c([2H])c([2H])c3c([2H])c([2H])c(-c4ccc(-c5ccc6oc7c8ccccc8ccc7c6c5)c(-c5c([2H])c([2H])c6c([2H])c([2H])c7c([2H])c([2H])c([2H])c8c([2H])c([2H])c5c6c78)c4)c4c([2H])c([2H])c(c1[2H])c2c34]

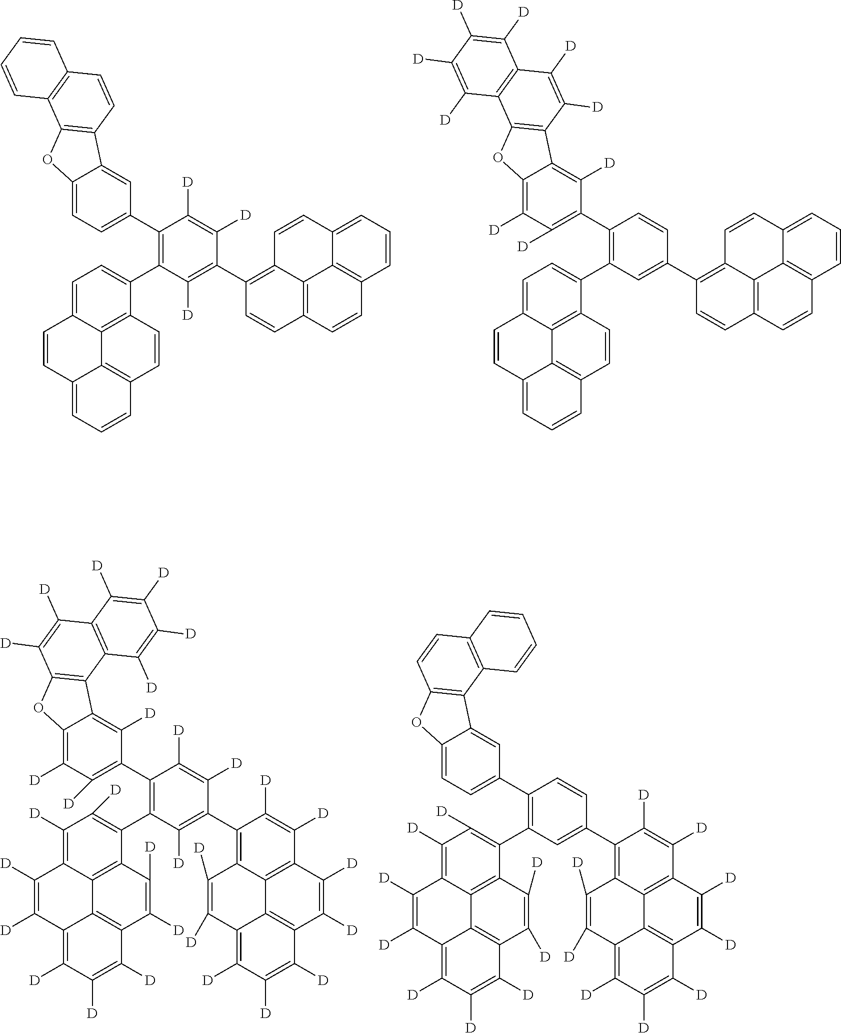

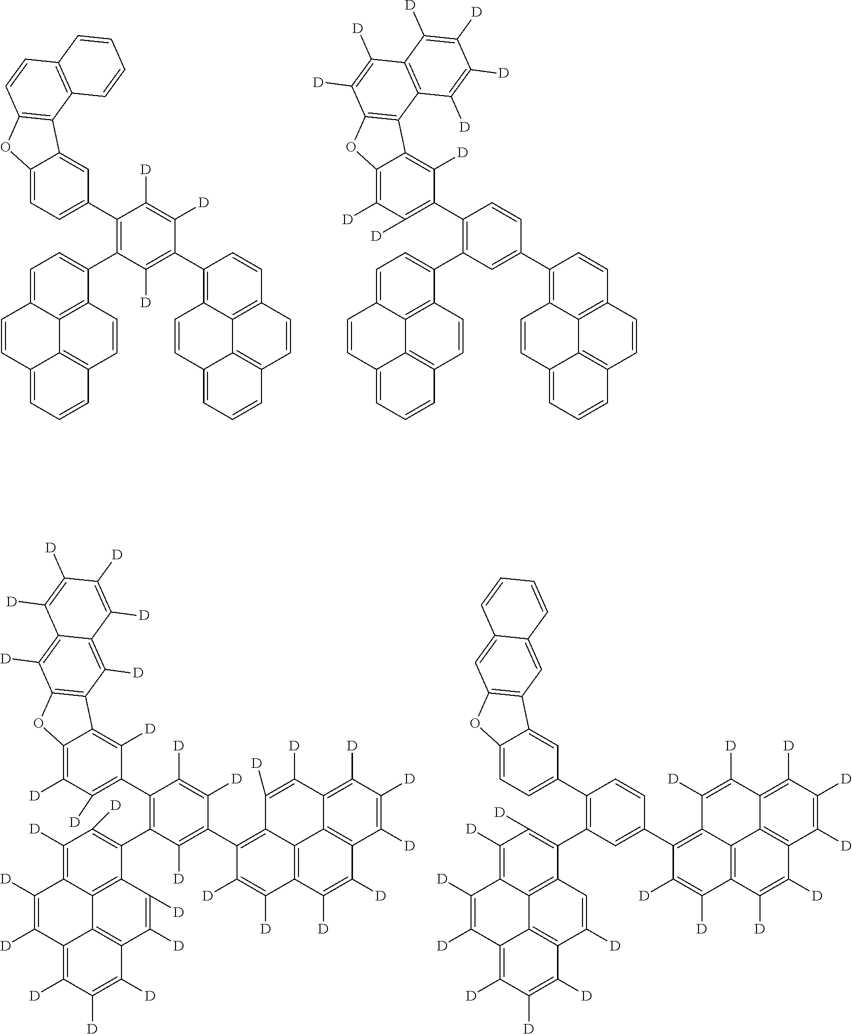

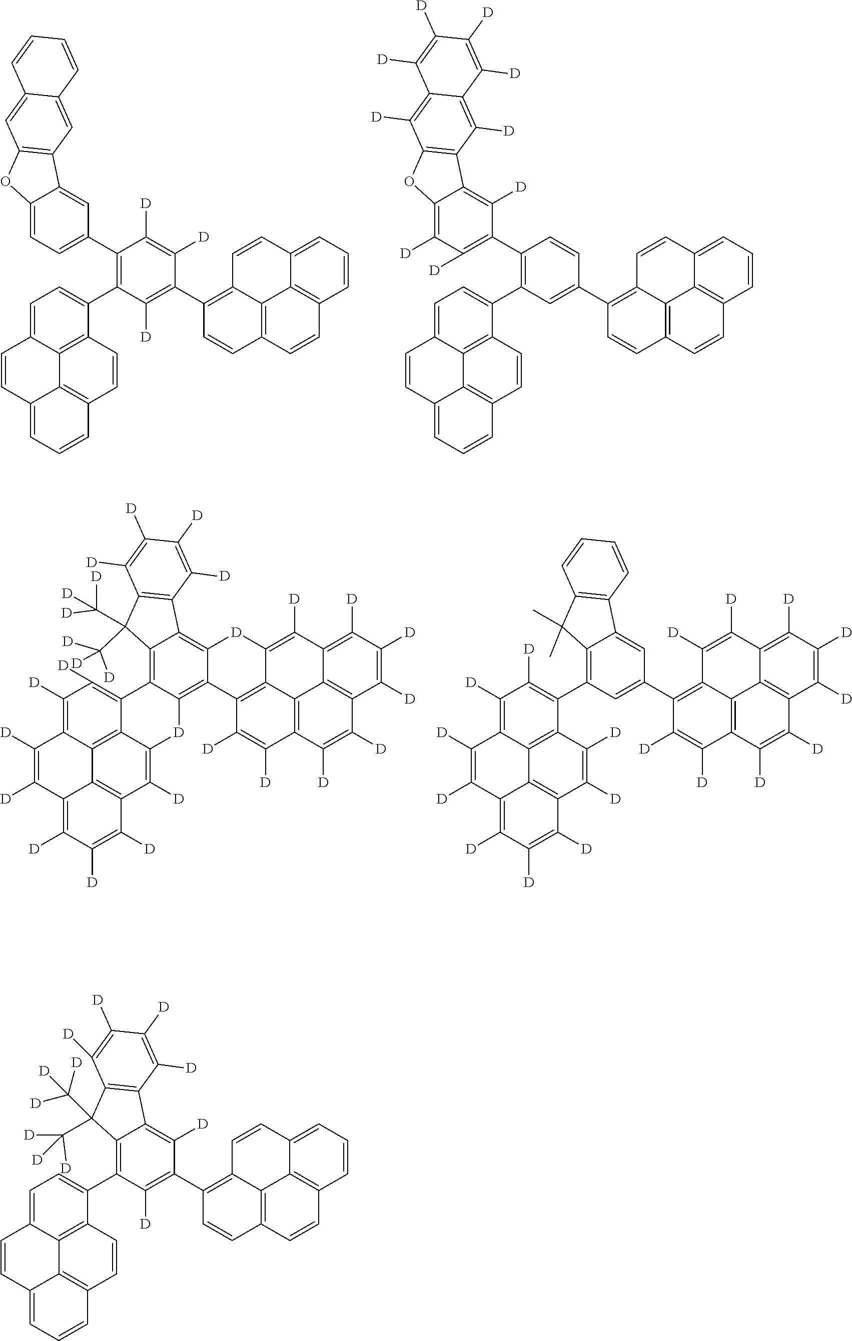

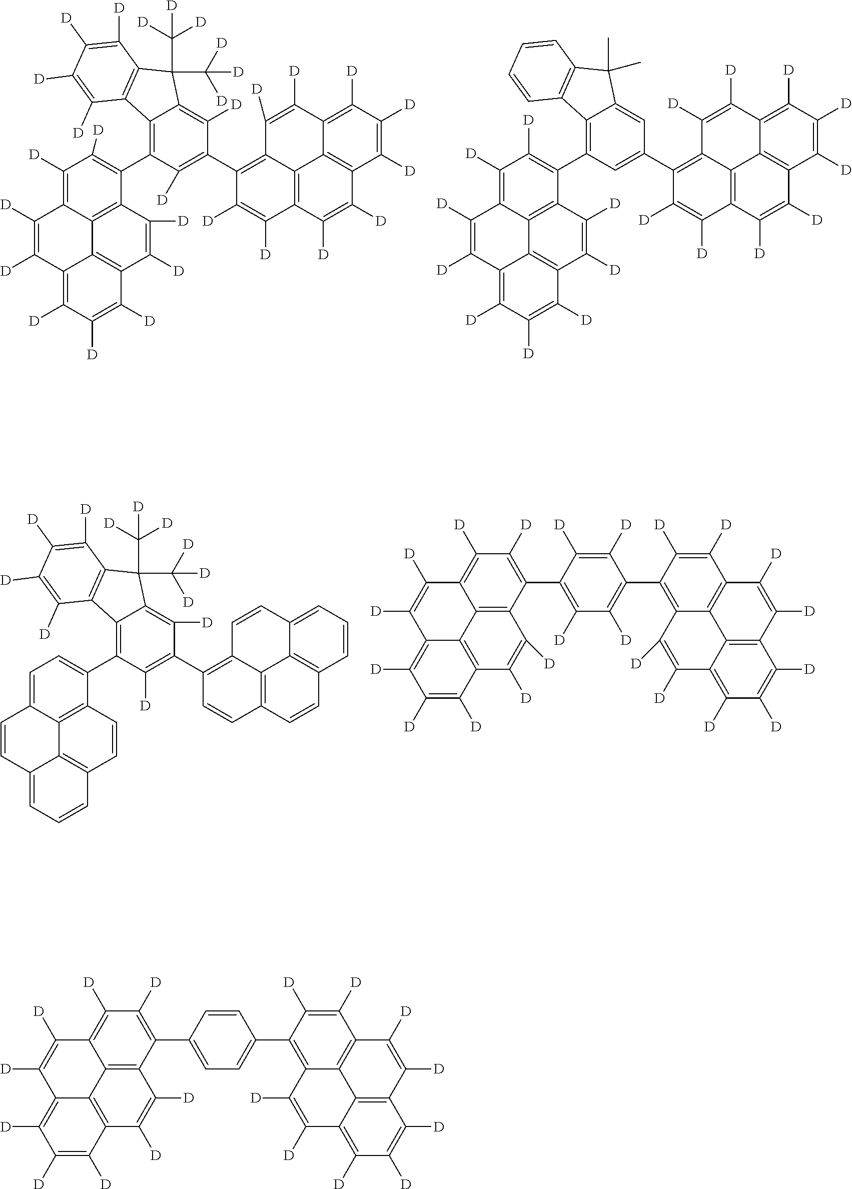

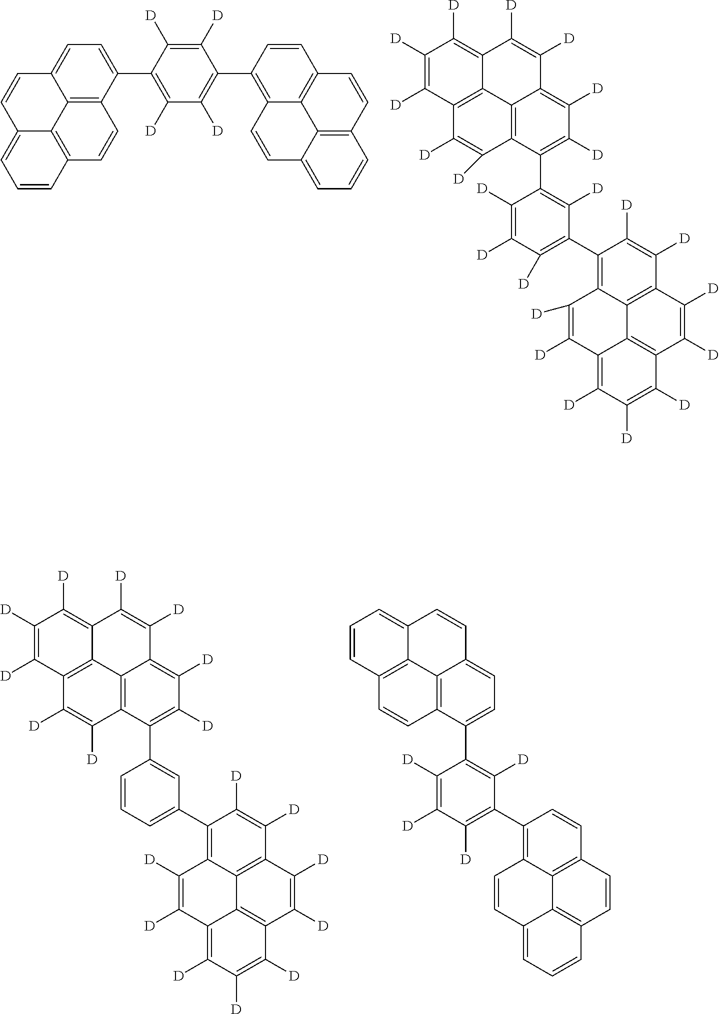

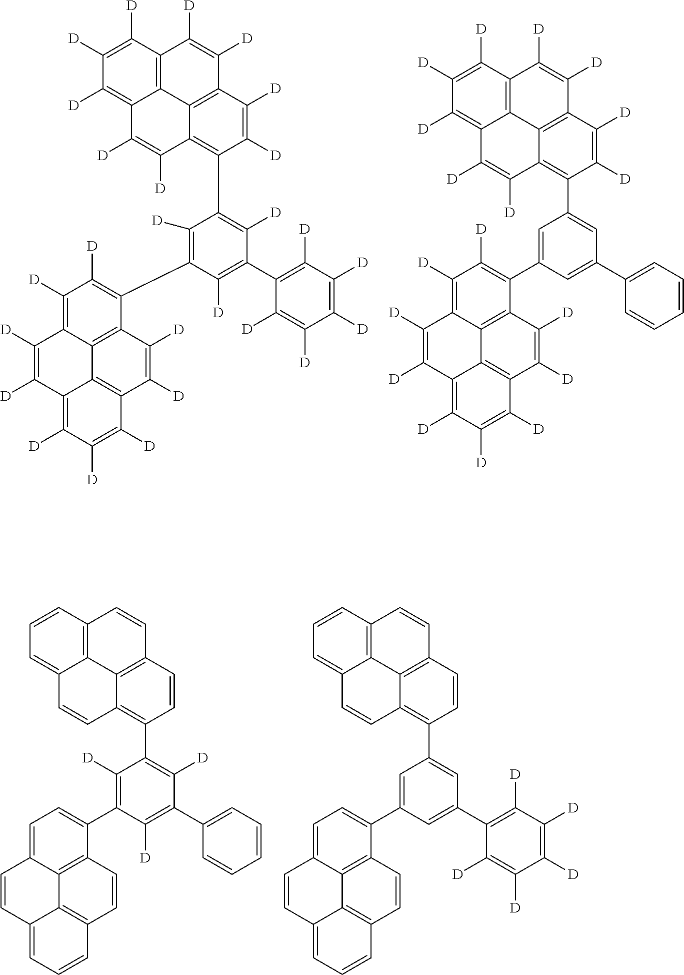

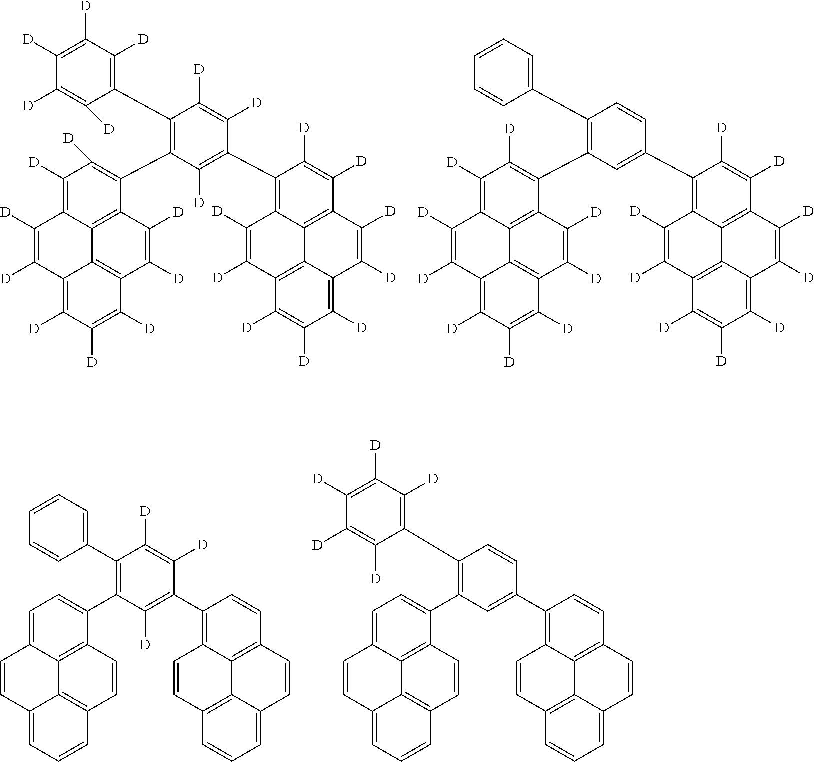

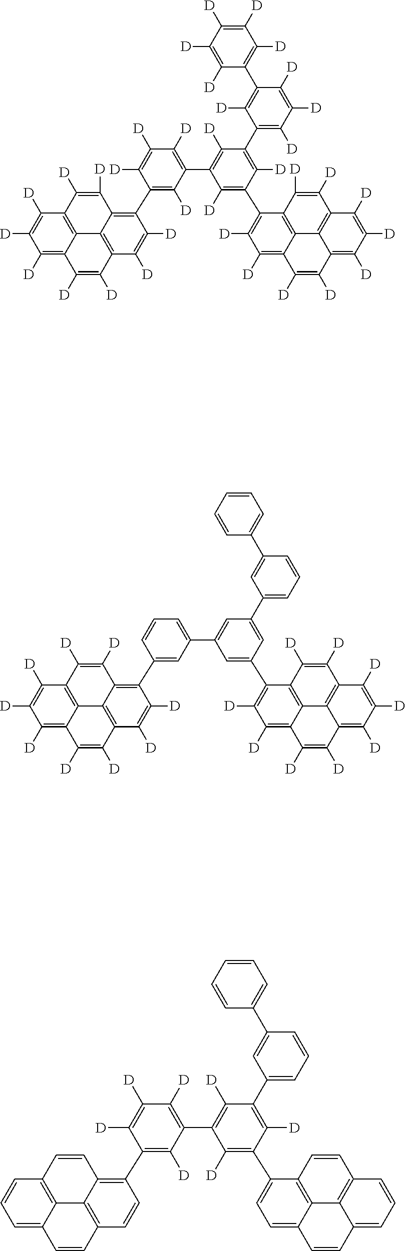

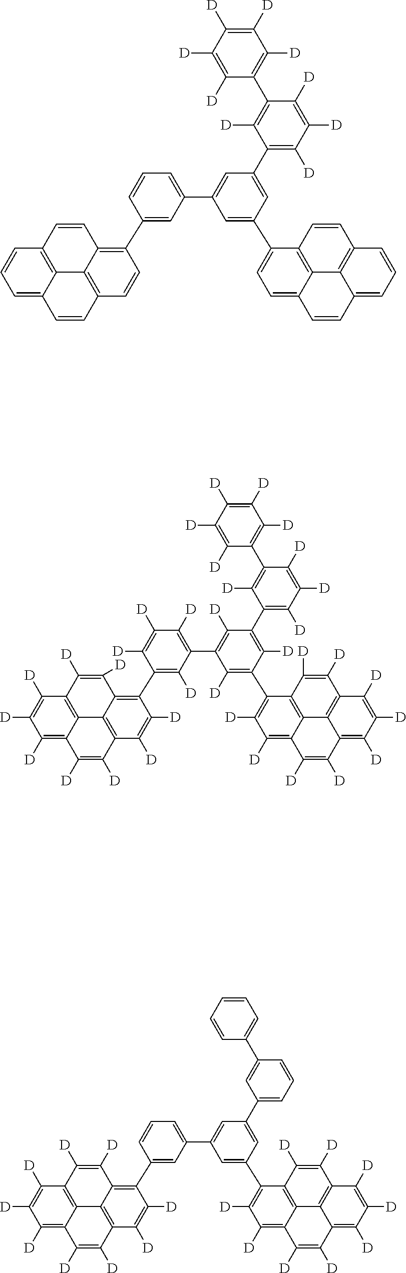

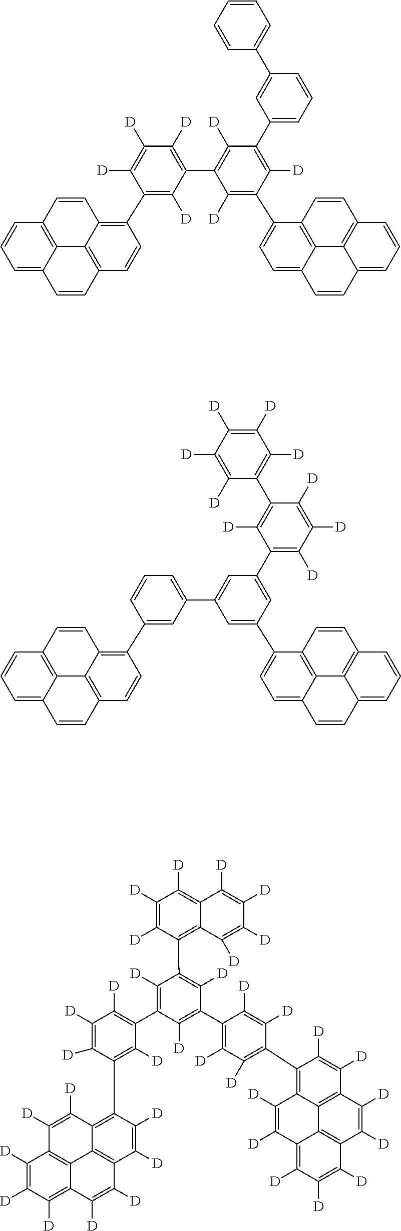

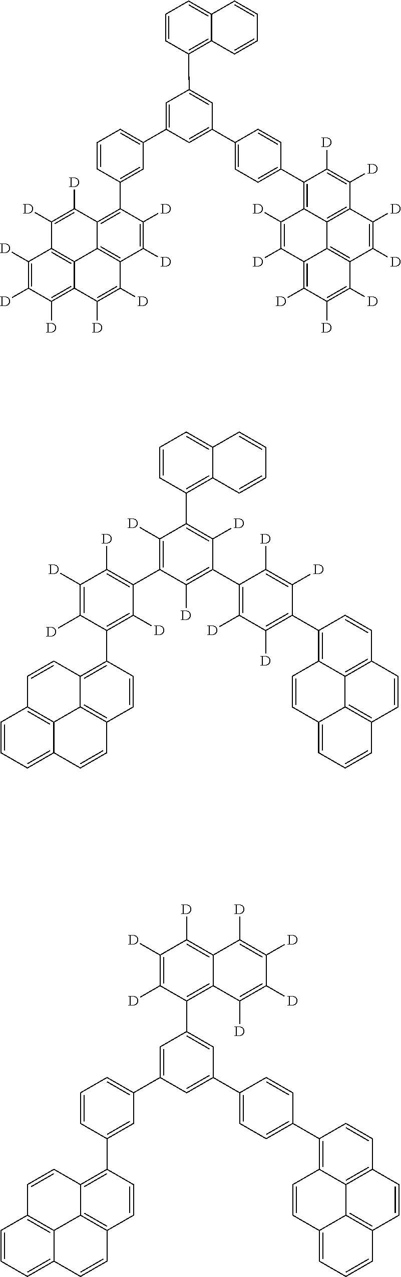

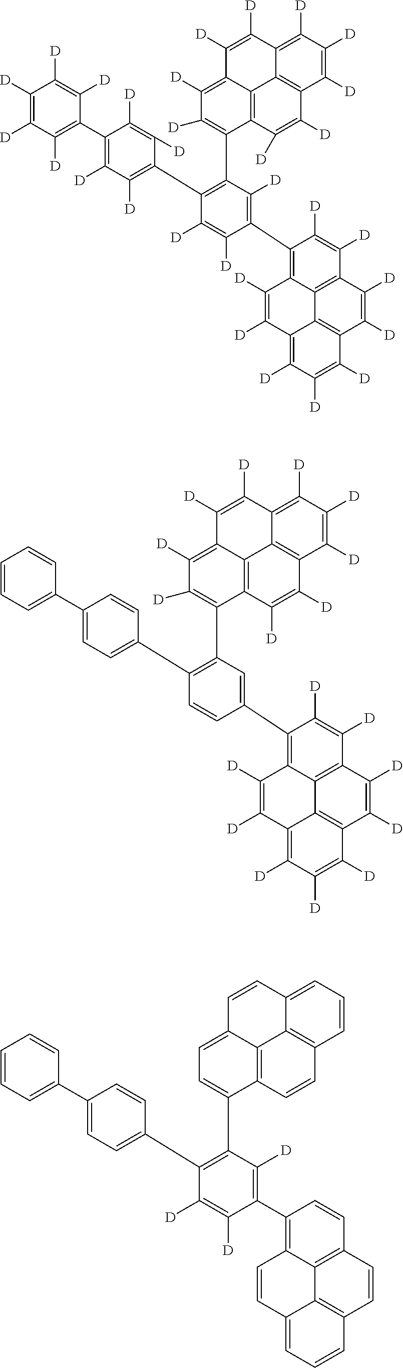

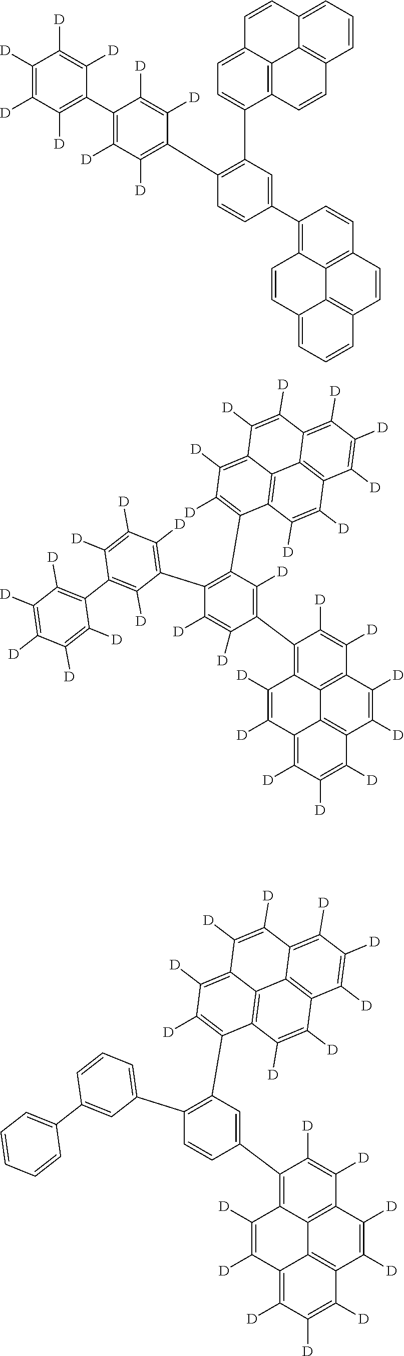

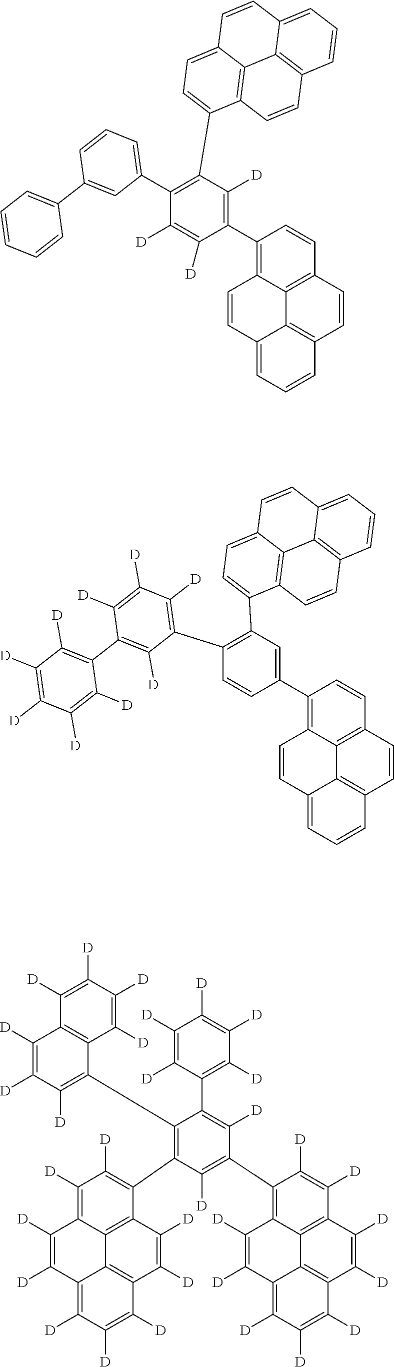

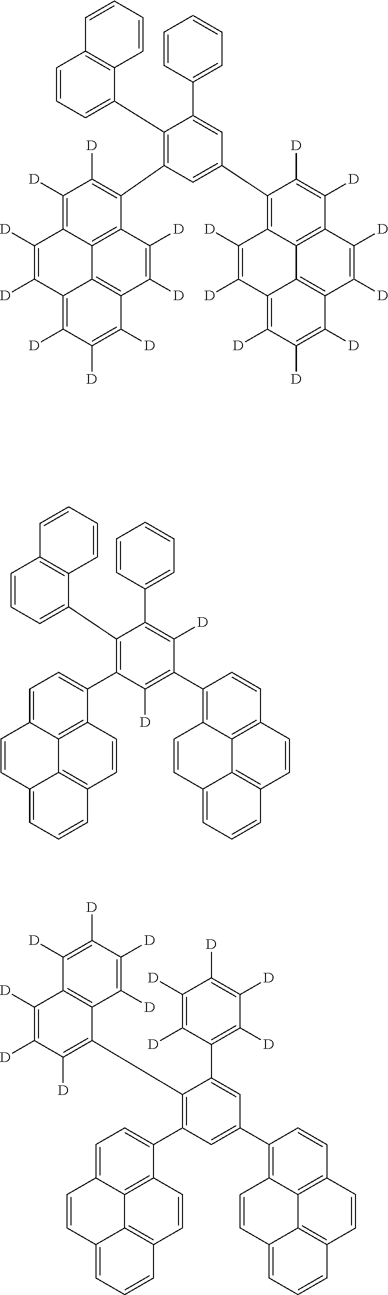 [SMILES: [2H]c1c([2H])c2c([2H])c([2H])c3c([2H])c([2H])c(-c4cc(-c5ccccc5)c(-c5cccc6ccccc56)c(-c5c([2H])c([2H])c6c([2H])c([2H])c7c([2H])c([2H])c([2H])c8c([2H])c([2H])c5c6c78)c4)c4c([2H])c([2H])c(c1[2H])c2c34 ; [2H]c1c(-c2ccc3ccc4cccc5ccc2c3c45)c([2H])c(-c2ccc3ccc4cccc5ccc2c3c45)c(-c2cccc3ccccc23)c1-c1ccccc1 ; [2H]c1c([2H])c([2H])c(-c2cc(-c3ccc4ccc5cccc6ccc3c4c56)cc(-c3ccc4ccc5cccc6ccc3c4c56)c2-c2c([2H])c([2H])c([2H])c3c([2H])c([2H])c([2H])c([2H])c23)c([2H])c1[2H]]

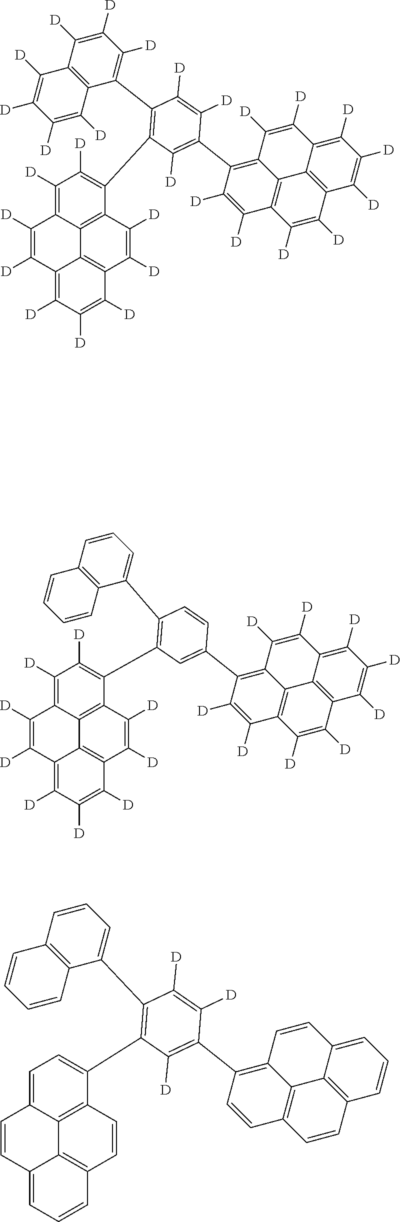

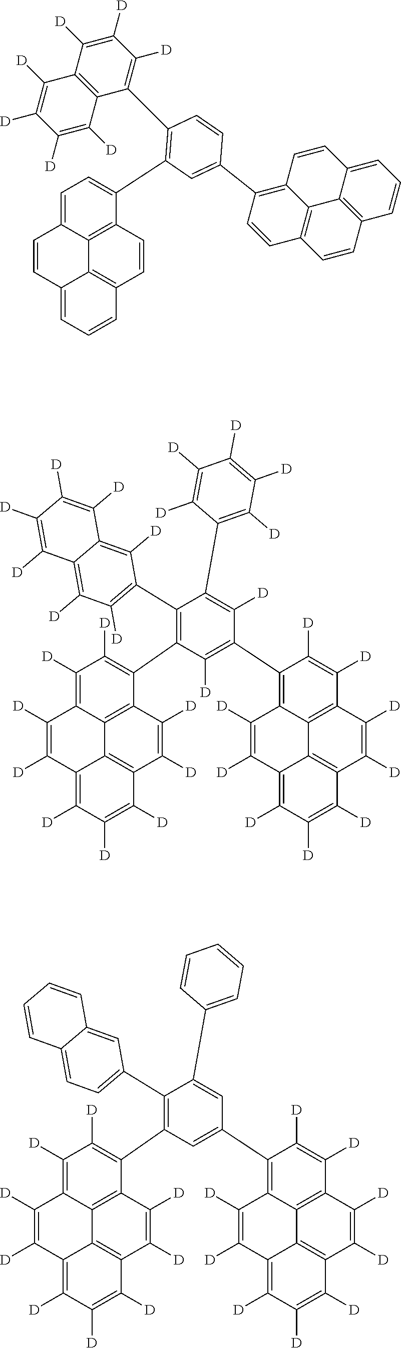

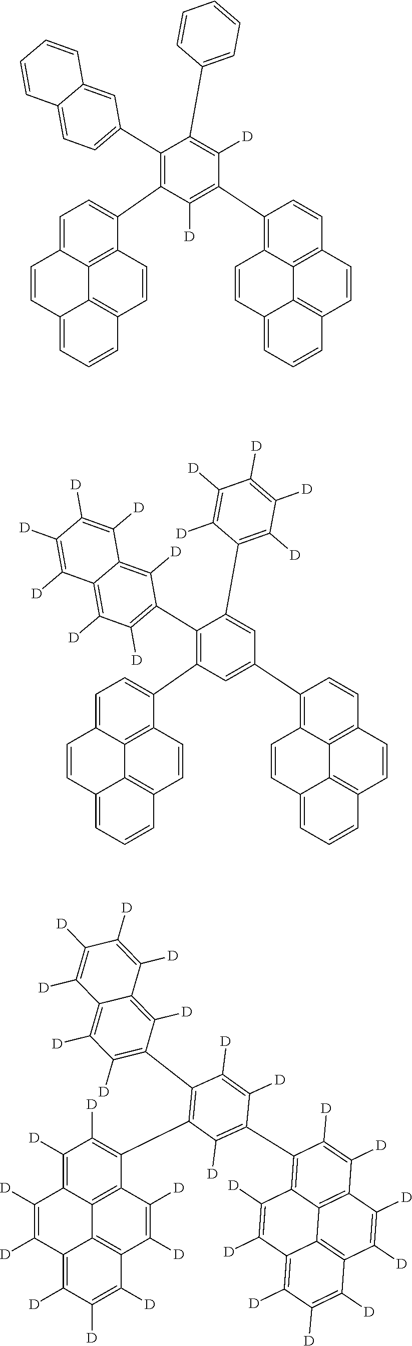 [SMILES: [2H]c1c(-c2ccc3ccc4cccc5ccc2c3c45)c([2H])c(-c2ccc3ccc4cccc5ccc2c3c45)c(-c2ccc3ccccc3c2)c1-c1ccccc1 ; [2H]c1c([2H])c([2H])c(-c2cc(-c3ccc4ccc5cccc6ccc3c4c56)cc(-c3ccc4ccc5cccc6ccc3c4c56)c2-c2c([2H])c([2H])c3c([2H])c([2H])c([2H])c([2H])c3c2[2H])c([2H])c1[2H] ; [2H]c1c([2H])c(-c2c([2H])c([2H])c3c([2H])c([2H])c([2H])c([2H])c3c2[2H])c(-c2c([2H])c([2H])c3c([2H])c([2H])c4c([2H])c([2H])c([2H])c5c([2H])c([2H])c2c3c45)c([2H])c1-c1c([2H])c([2H])c2c([2H])c([2H])c3c([2H])c([2H])c([2H])c4c([2H])c([2H])c1c2c34]

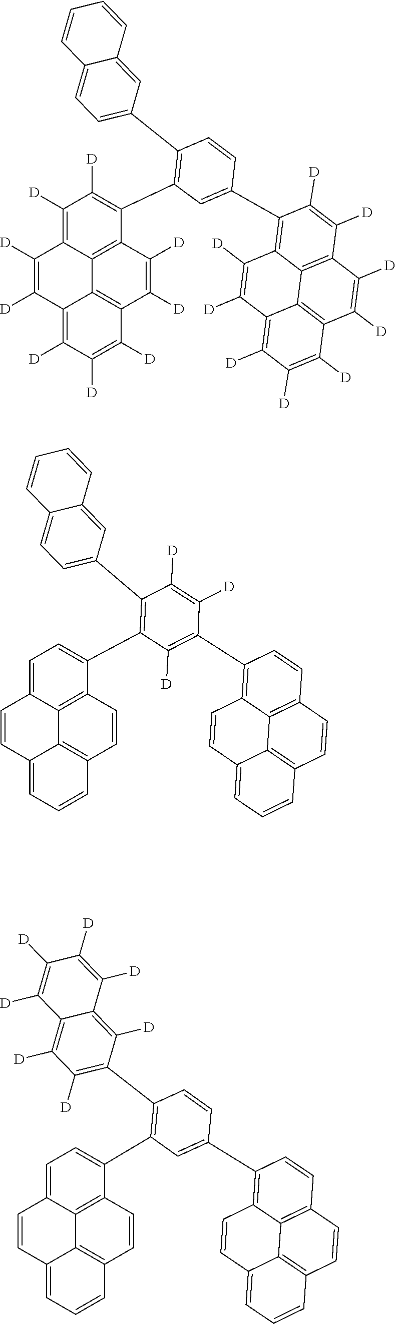 [SMILES: [2H]c1c([2H])c2c([2H])c([2H])c3c([2H])c([2H])c(-c4ccc(-c5ccc6ccccc6c5)c(-c5c([2H])c([2H])c6c([2H])c([2H])c7c([2H])c([2H])c([2H])c8c([2H])c([2H])c5c6c78)c4)c4c([2H])c([2H])c(c1[2H])c2c34 ; [2H]c1c([2H])c(-c2ccc3ccccc3c2)c(-c2ccc3ccc4cccc5ccc2c3c45)c([2H])c1-c1ccc2ccc3cccc4ccc1c2c34 ; [2H]c1c([2H])c([2H])c2c([2H])c(-c3ccc(-c4ccc5ccc6cccc7ccc4c5c67)cc3-c3ccc4ccc5cccc6ccc3c4c56)c([2H])c([2H])c2c1[2H]]

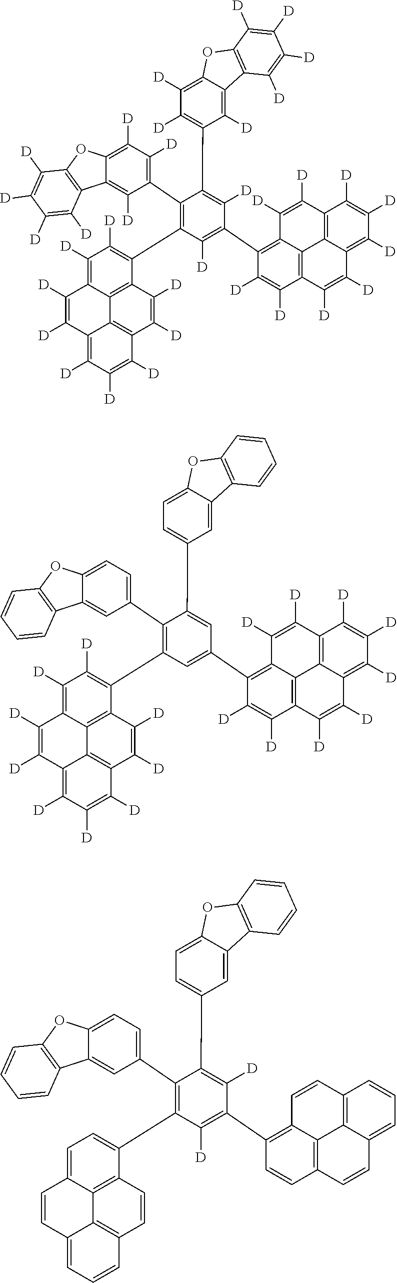

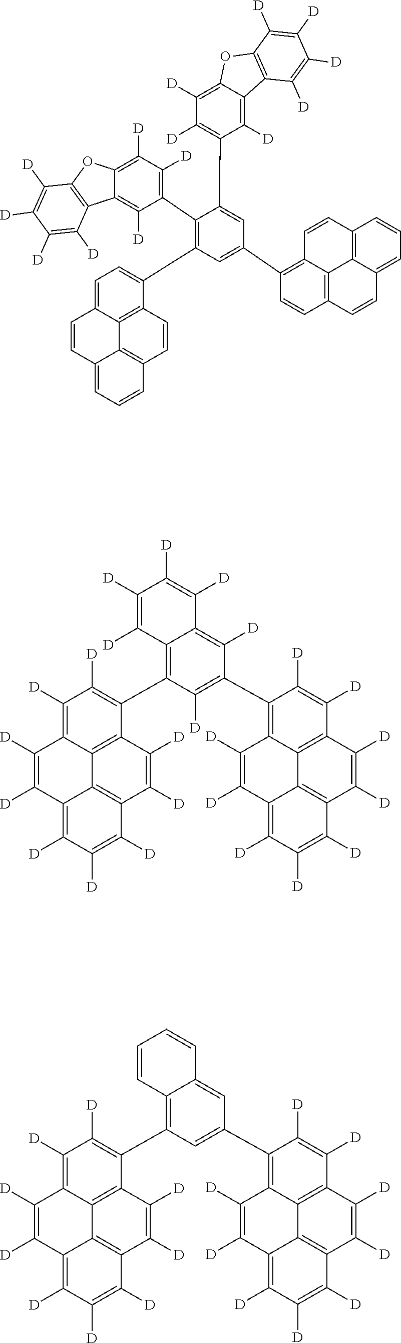

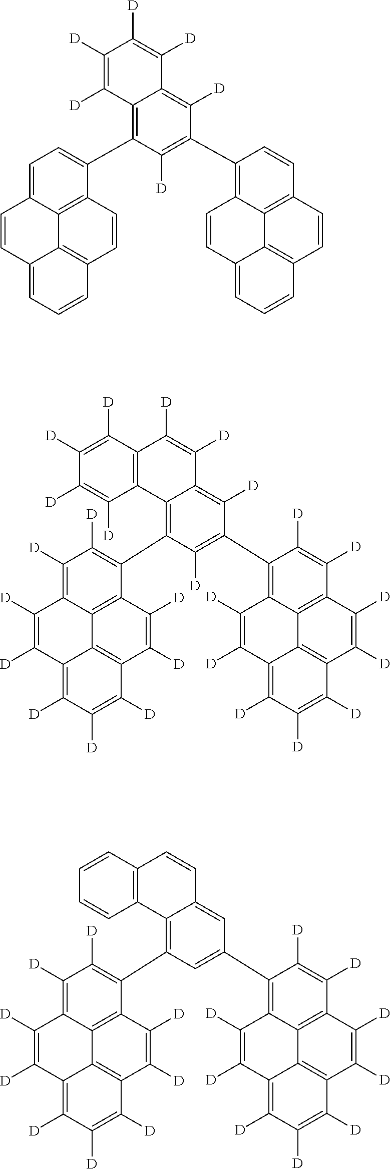

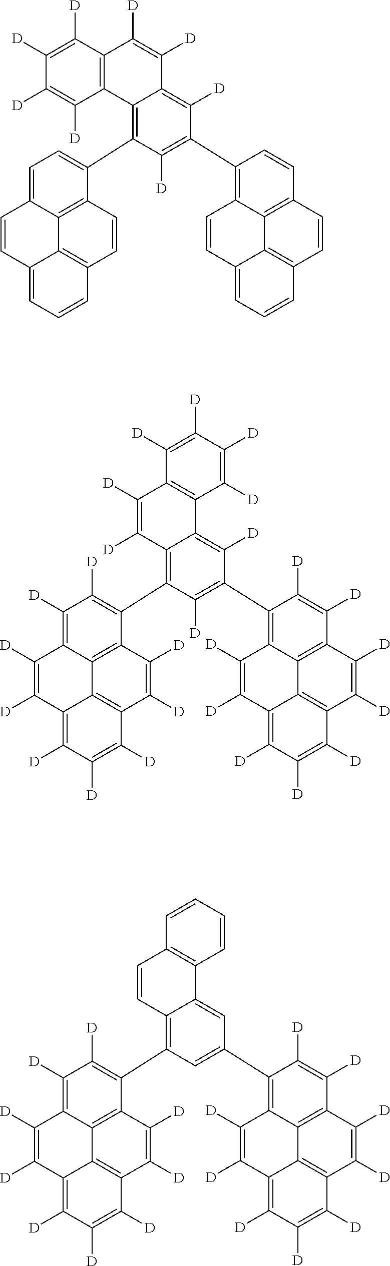

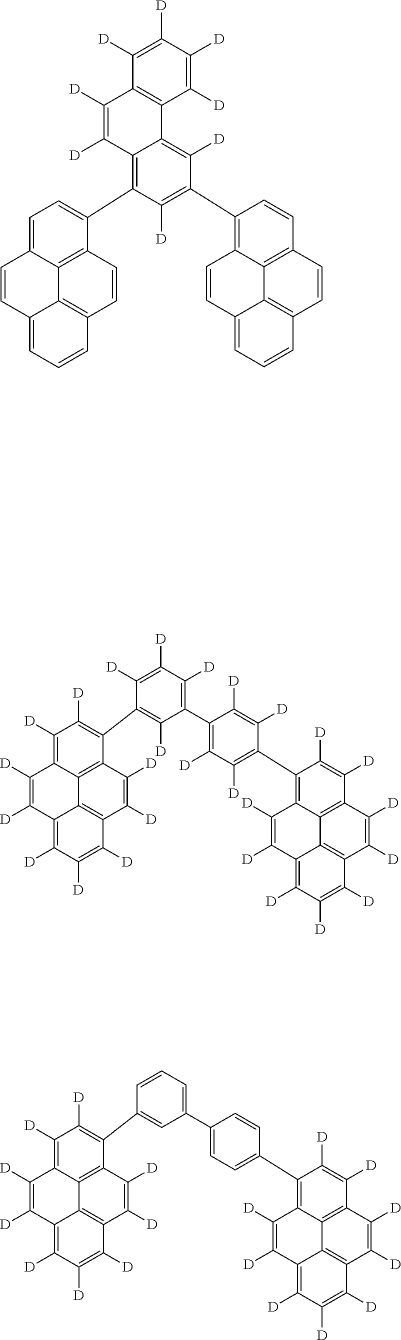

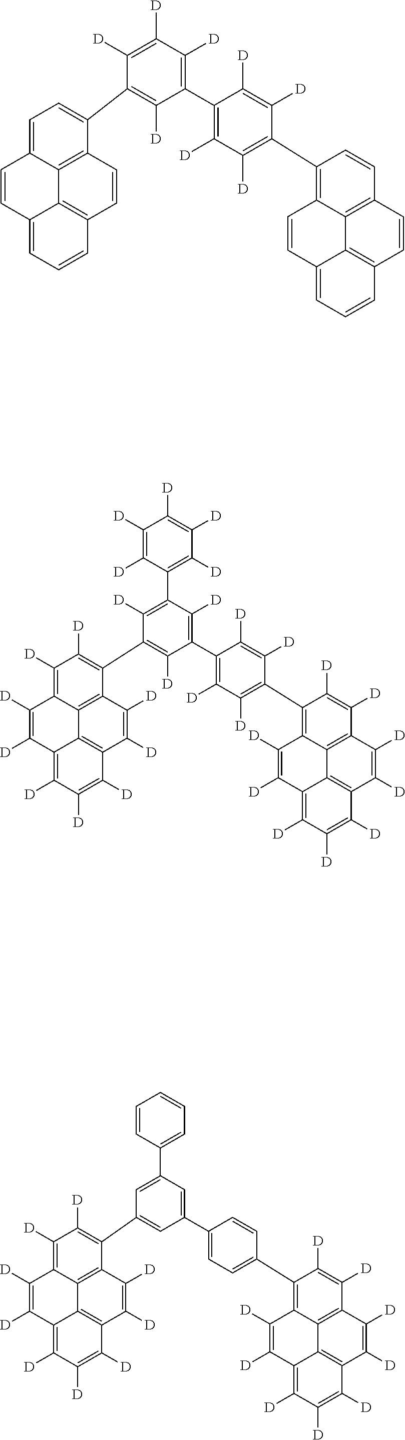

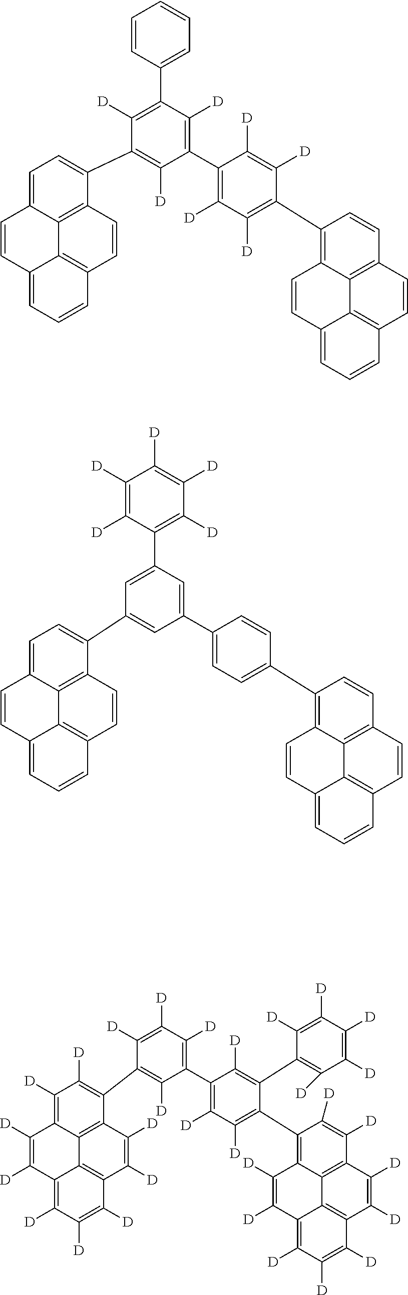 [SMILES: [2H]c1c([2H])c(-c2ccc3ccc4cccc5ccc2c3c45)c([2H])c([2H])c1-c1c([2H])c(-c2ccccc2)c([2H])c(-c2ccc3ccc4cccc5ccc2c3c45)c1[2H] ; [2H]c1c([2H])c([2H])c(-c2cc(-c3ccc(-c4ccc5ccc6cccc7ccc4c5c67)cc3)cc(-c3ccc4ccc5cccc6ccc3c4c56)c2)c([2H])c1[2H] ; [2H]c1c([2H])c([2H])c(-c2c([2H])c(-c3c([2H])c([2H])c([2H])c(-c4c([2H])c([2H])c5c([2H])c([2H])c6c([2H])c([2H])c([2H])c7c([2H])c([2H])c4c5c67)c3[2H])c([2H])c([2H])c2-c2c([2H])c([2H])c3c([2H])c([2H])c4c([2H])c([2H])c([2H])c5c([2H])c([2H])c2c3c45)c([2H])c1[2H]]

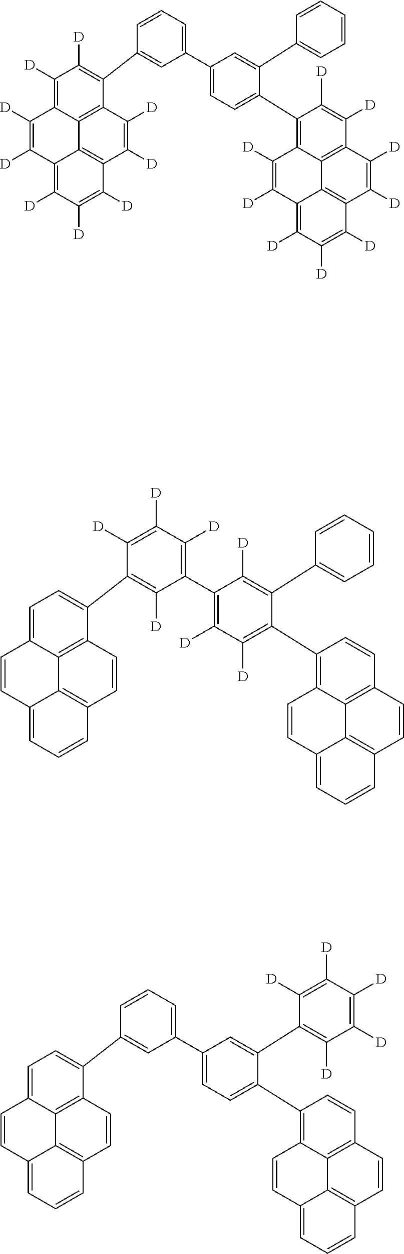 [SMILES: [2H]c1c([2H])c2c([2H])c([2H])c3c([2H])c([2H])c(-c4cccc(-c5ccc(-c6c([2H])c([2H])c7c([2H])c([2H])c8c([2H])c([2H])c([2H])c9c([2H])c([2H])c6c7c89)c(-c6ccccc6)c5)c4)c4c([2H])c([2H])c(c1[2H])c2c34 ; [2H]c1c([2H])c(-c2c([2H])c([2H])c(-c3ccc4ccc5cccc6ccc3c4c56)c(-c3ccccc3)c2[2H])c([2H])c(-c2ccc3ccc4cccc5ccc2c3c45)c1[2H] ; [2H]c1c([2H])c([2H])c(-c2cc(-c3cccc(-c4ccc5ccc6cccc7ccc4c5c67)c3)ccc2-c2ccc3ccc4cccc5ccc2c3c45)c([2H])c1[2H]]

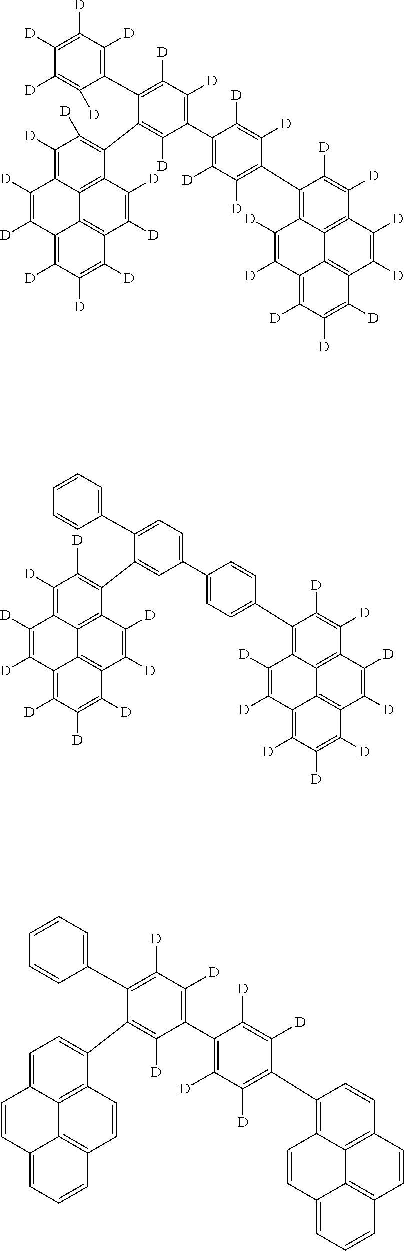

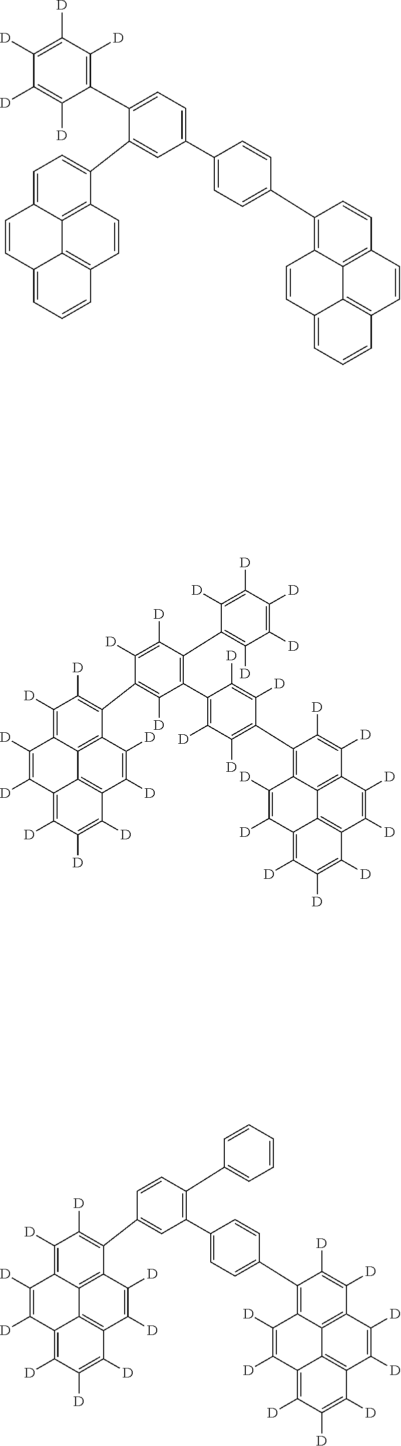

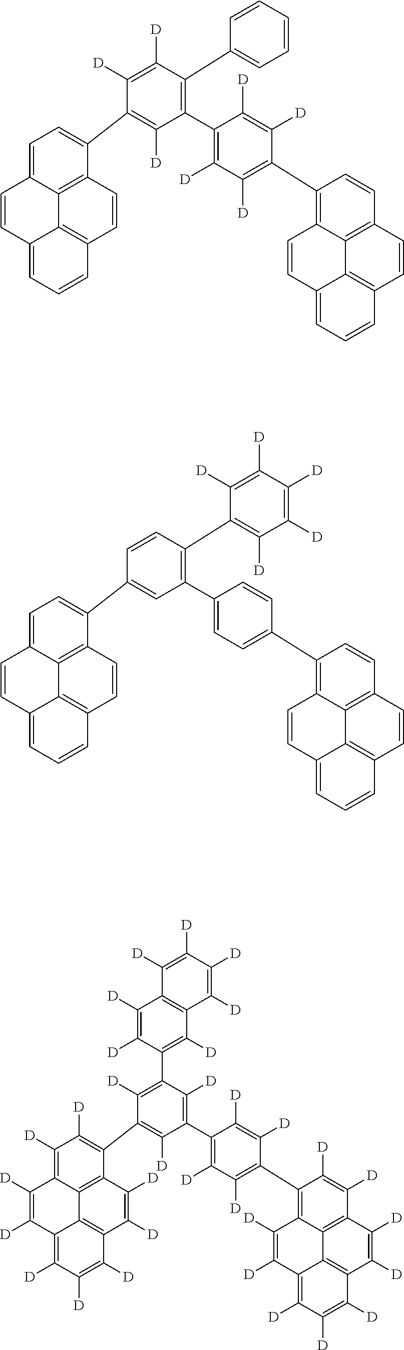

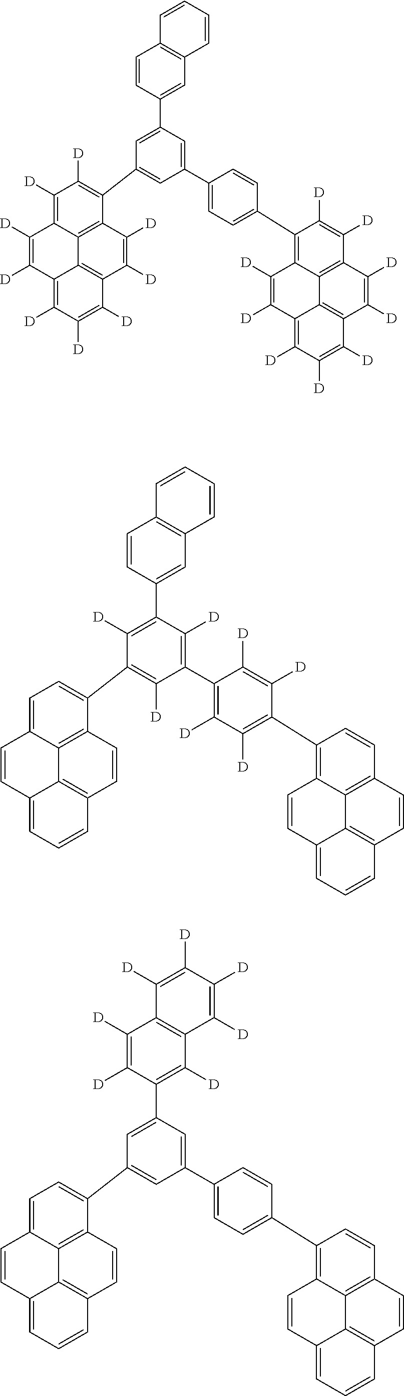 [SMILES: [2H]c1c([2H])c2c([2H])c([2H])c3c([2H])c([2H])c(-c4ccc(-c5cc(-c6ccc7ccccc7c6)cc(-c6c([2H])c([2H])c7c([2H])c([2H])c8c([2H])c([2H])c([2H])c9c([2H])c([2H])c6c7c89)c5)cc4)c4c([2H])c([2H])c(c1[2H])c2c34 ; [2H]c1c([2H])c(-c2ccc3ccc4cccc5ccc2c3c45)c([2H])c([2H])c1-c1c([2H])c(-c2ccc3ccccc3c2)c([2H])c(-c2ccc3ccc4cccc5ccc2c3c45)c1[2H] ; [2H]c1c([2H])c([2H])c2c([2H])c(-c3cc(-c4ccc(-c5ccc6ccc7cccc8ccc5c6c78)cc4)cc(-c4ccc5ccc6cccc7ccc4c5c67)c3)c([2H])c([2H])c2c1[2H]]

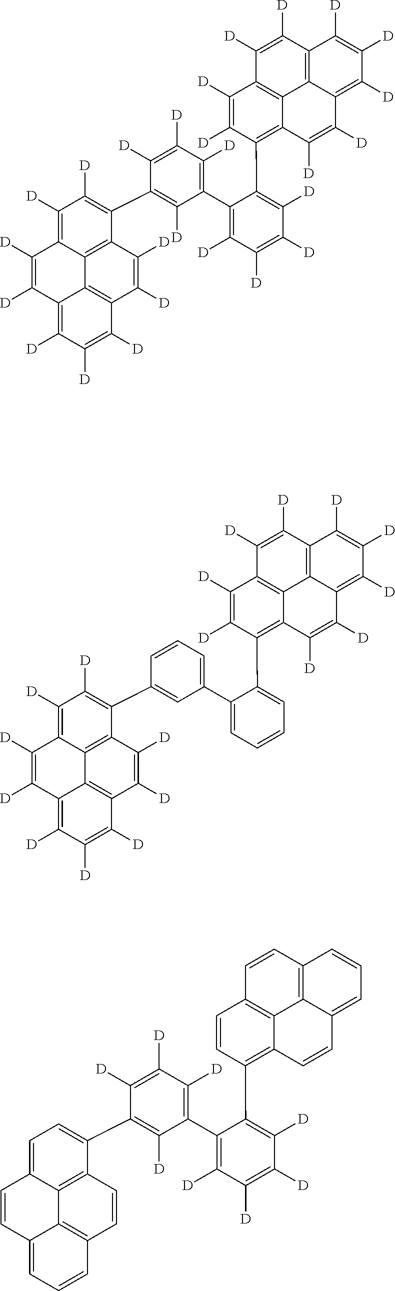

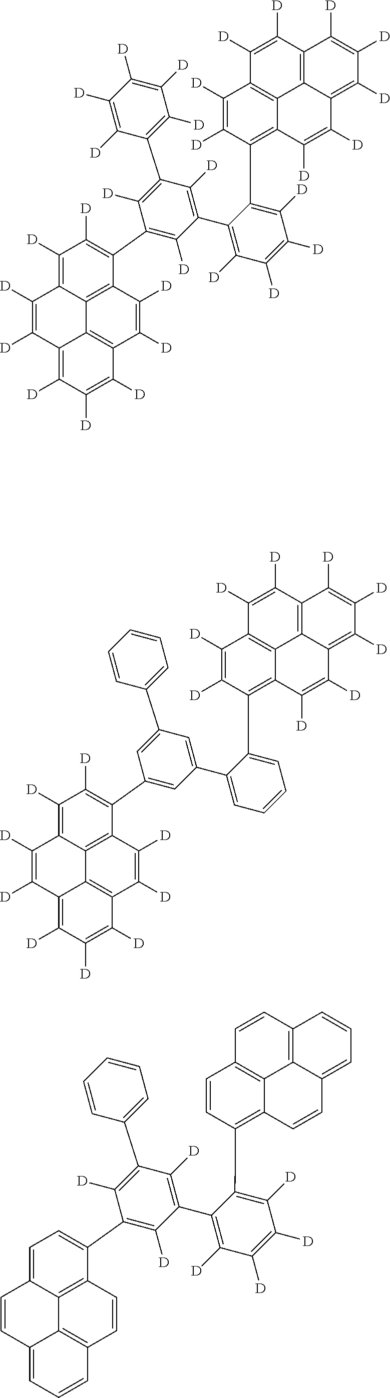

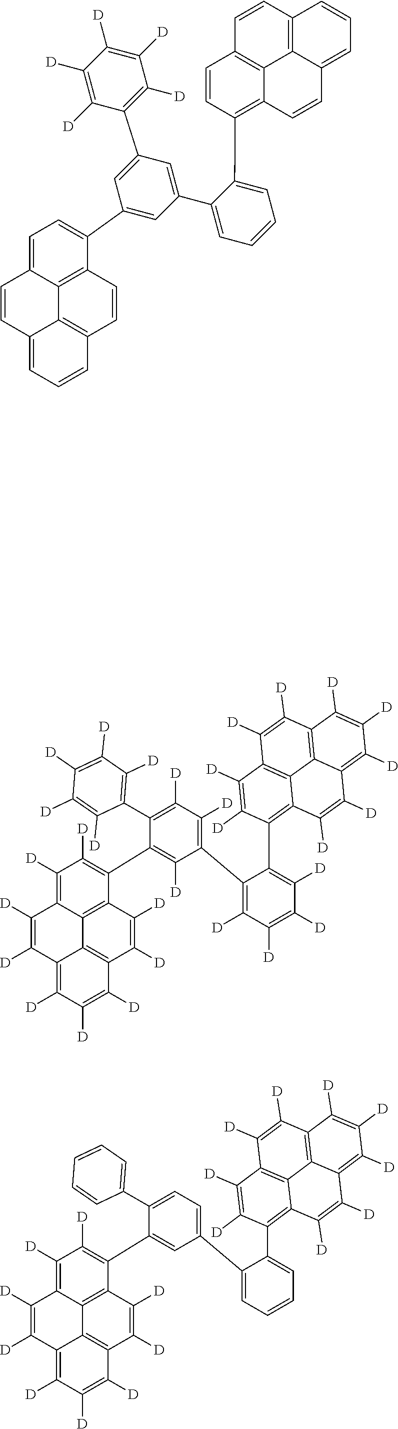

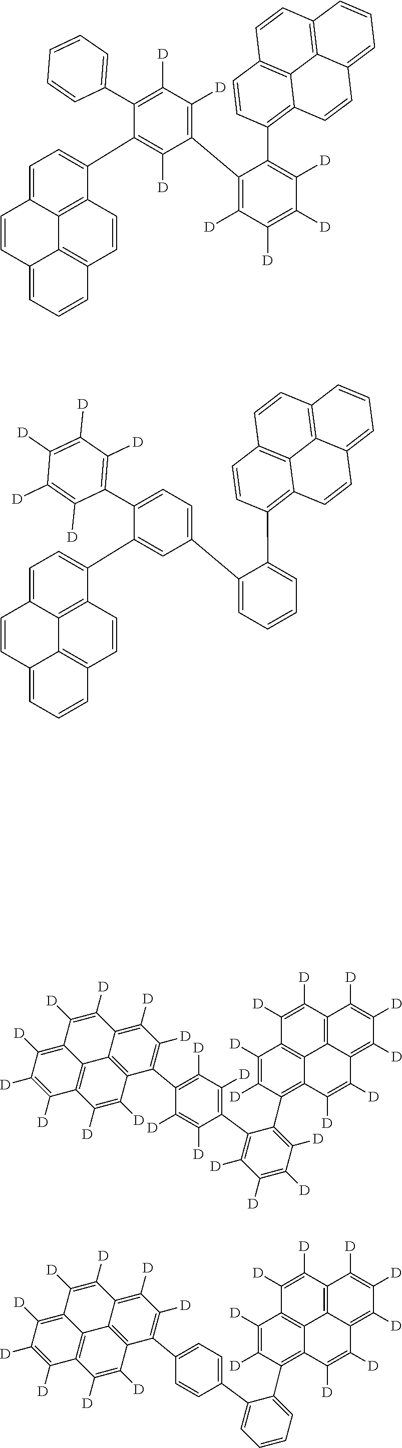

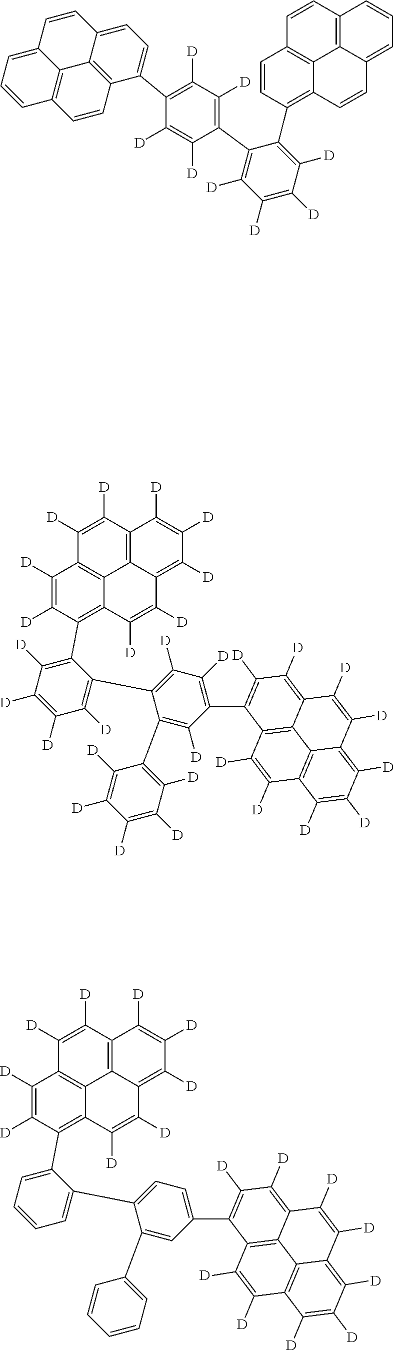

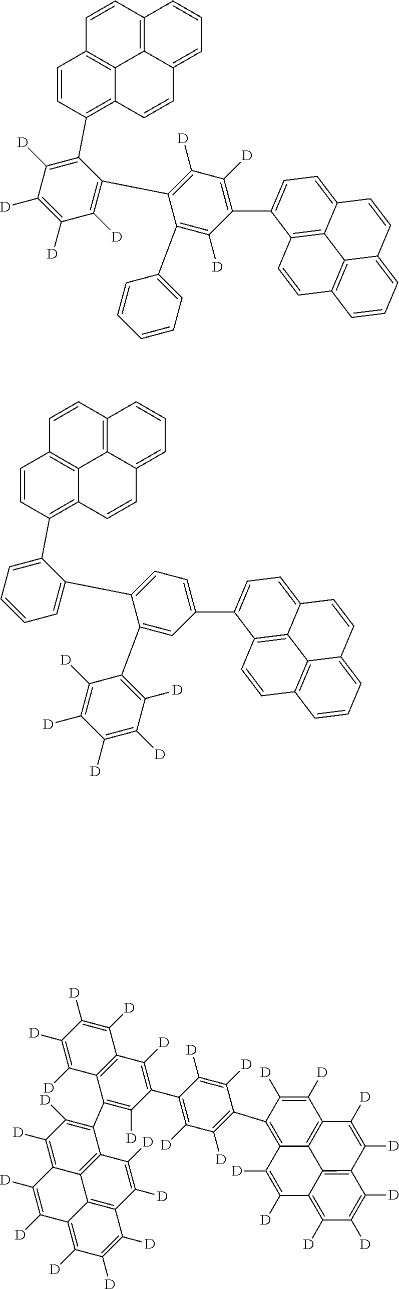 [SMILES: [2H]c1c([2H])c([2H])c(-c2ccc3ccc4cccc5ccc2c3c45)c(-c2c([2H])c([2H])c(-c3ccc4ccc5cccc6ccc3c4c56)c([2H])c2-c2ccccc2)c1[2H] ; [2H]c1c([2H])c([2H])c(-c2cc(-c3ccc4ccc5cccc6ccc3c4c56)ccc2-c2ccccc2-c2ccc3ccc4cccc5ccc2c3c45)c([2H])c1[2H] ; [2H]c1c([2H])c(-c2c([2H])c([2H])c3c([2H])c([2H])c4c([2H])c([2H])c([2H])c5c([2H])c([2H])c2c3c45)c([2H])c([2H])c1-c1c([2H])c(-c2c([2H])c([2H])c3c([2H])c([2H])c4c([2H])c([2H])c([2H])c5c([2H])c([2H])c2c3c45)c2c([2H])c([2H])c([2H])c([2H])c2c1[2H]]

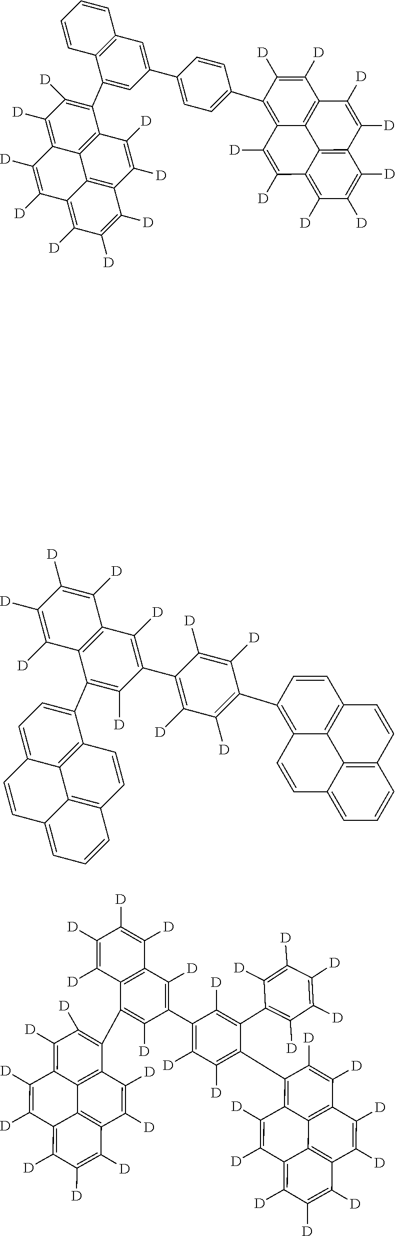

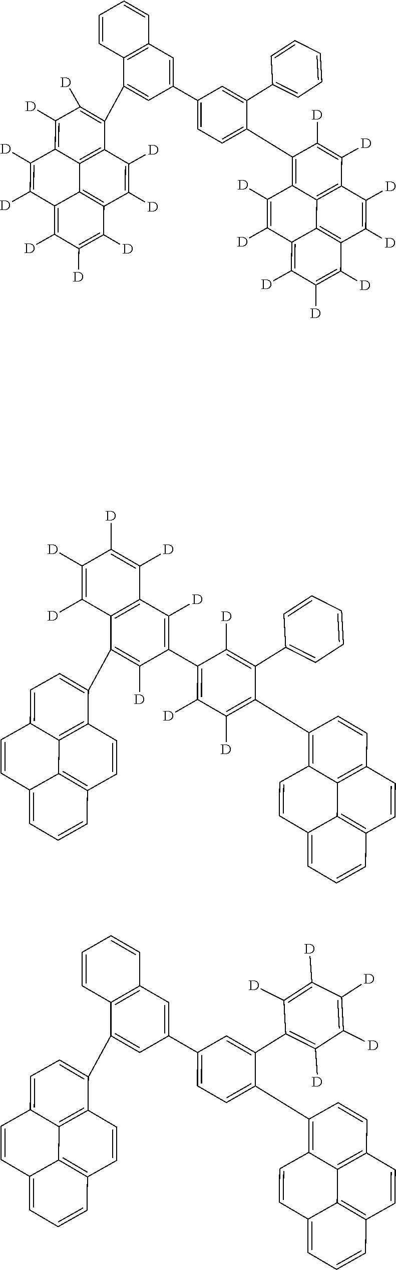 [SMILES: [2H]c1c([2H])c2c([2H])c([2H])c3c([2H])c([2H])c(-c4ccc(-c5cc(-c6c([2H])c([2H])c7c([2H])c([2H])c8c([2H])c([2H])c([2H])c9c([2H])c([2H])c6c7c89)c6ccccc6c5)cc4-c4ccccc4)c4c([2H])c([2H])c(c1[2H])c2c34 ; [2H]c1c([2H])c(-c2ccc3ccc4cccc5ccc2c3c45)c(-c2ccccc2)c([2H])c1-c1c([2H])c(-c2ccc3ccc4cccc5ccc2c3c45)c2c([2H])c([2H])c([2H])c([2H])c2c1[2H] ; [2H]c1c([2H])c([2H])c(-c2cc(-c3cc(-c4ccc5ccc6cccc7ccc4c5c67)c4ccccc4c3)ccc2-c2ccc3ccc4cccc5ccc2c3c45)c([2H])c1[2H]]

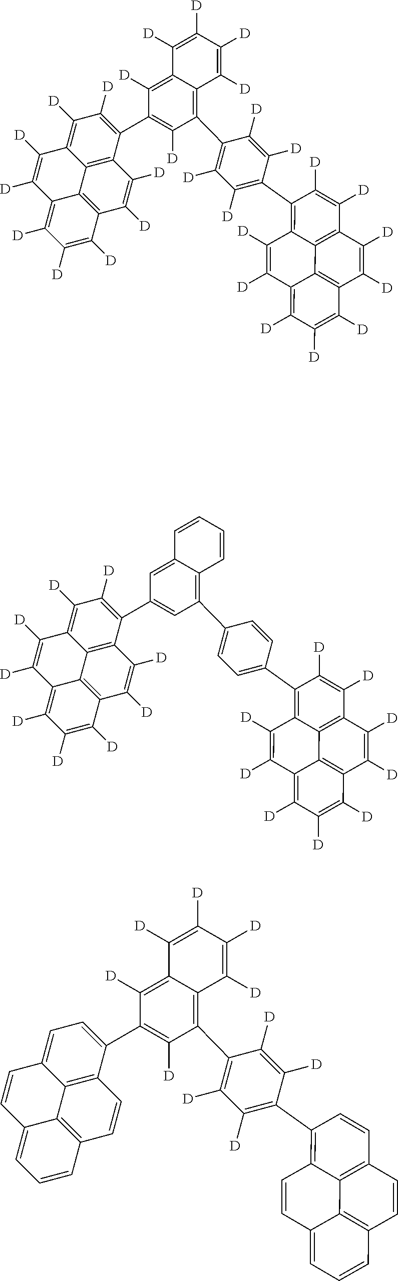

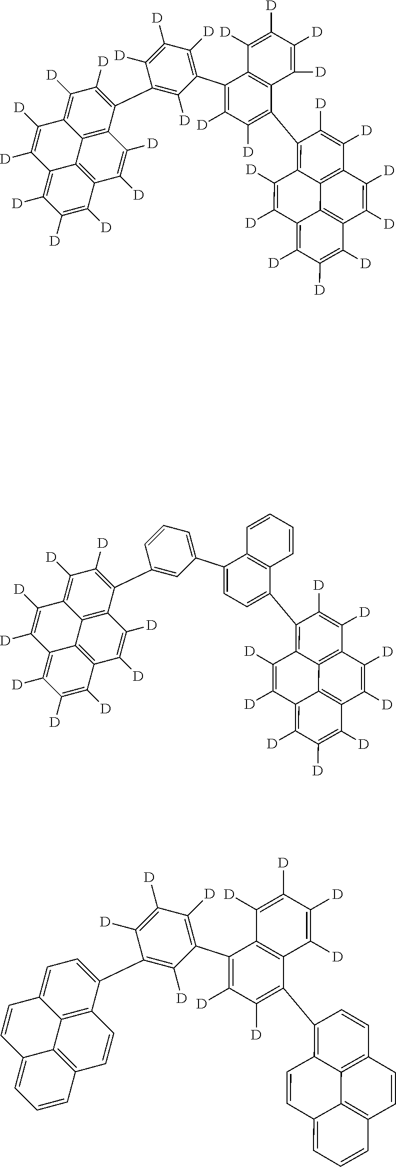

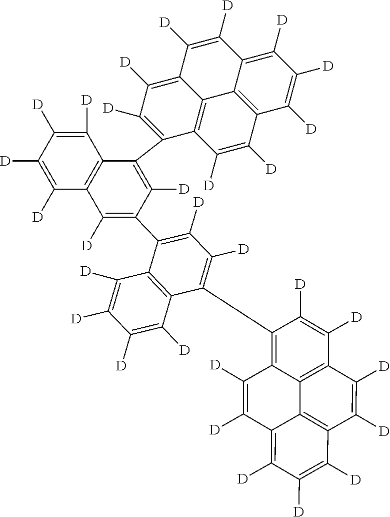 [SMILES: [2H]c1c([2H])c([2H])c2c(-c3c([2H])c([2H])c4c([2H])c([2H])c5c([2H])c([2H])c([2H])c6c([2H])c([2H])c3c4c56)c([2H])c(-c3c([2H])c([2H])c(-c4c([2H])c([2H])c5c([2H])c([2H])c6c([2H])c([2H])c([2H])c7c([2H])c([2H])c4c5c67)c4c([2H])c([2H])c([2H])c([2H])c34)c([2H])c2c1[2H]]

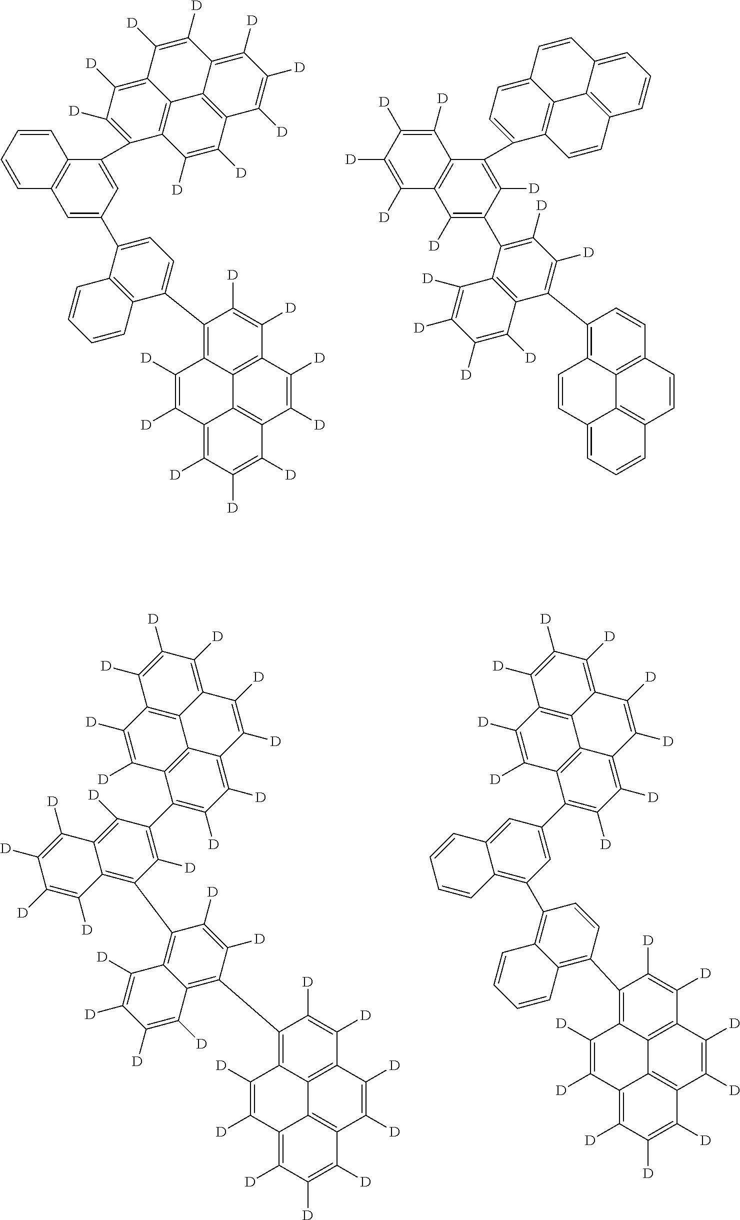

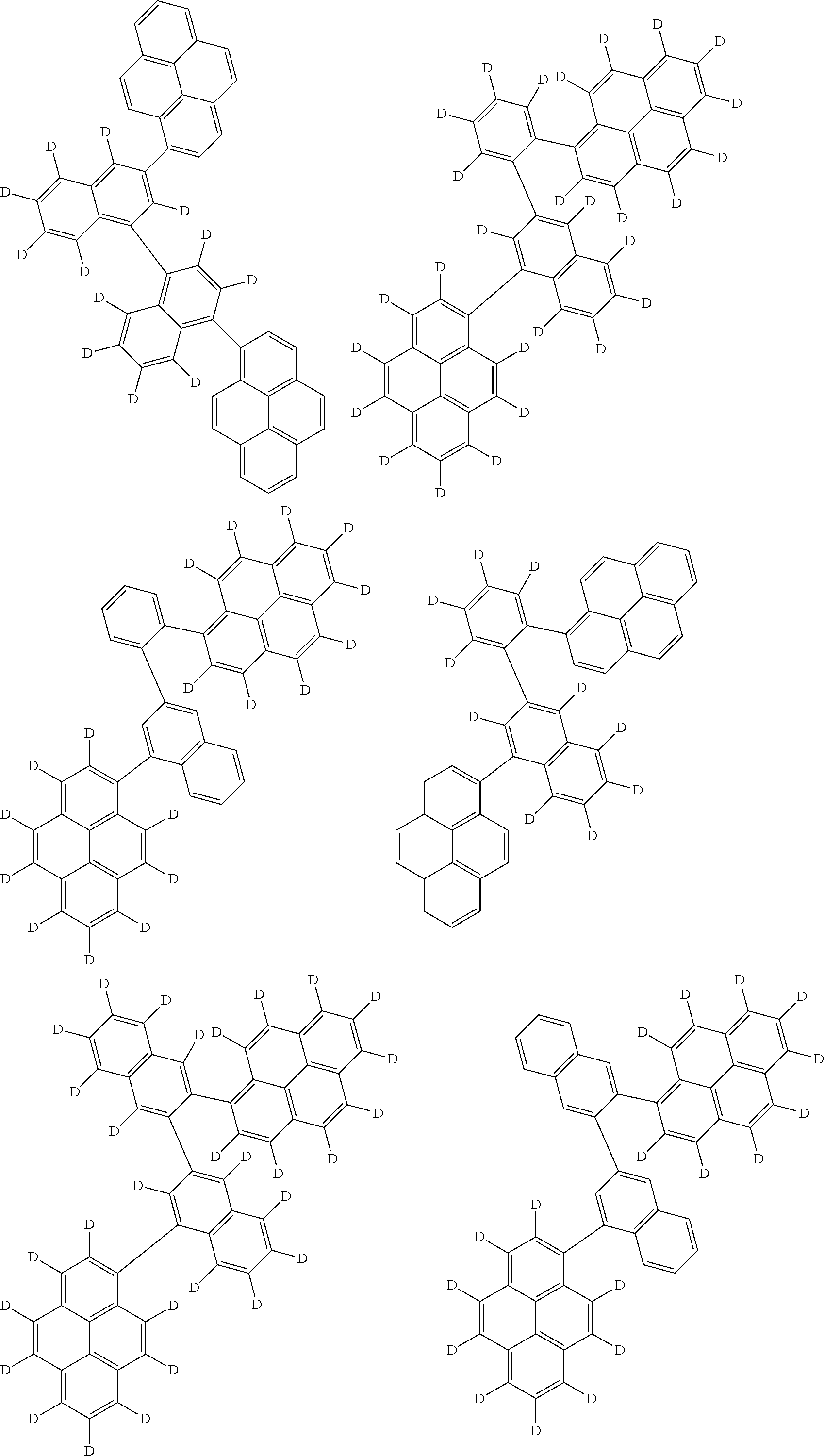

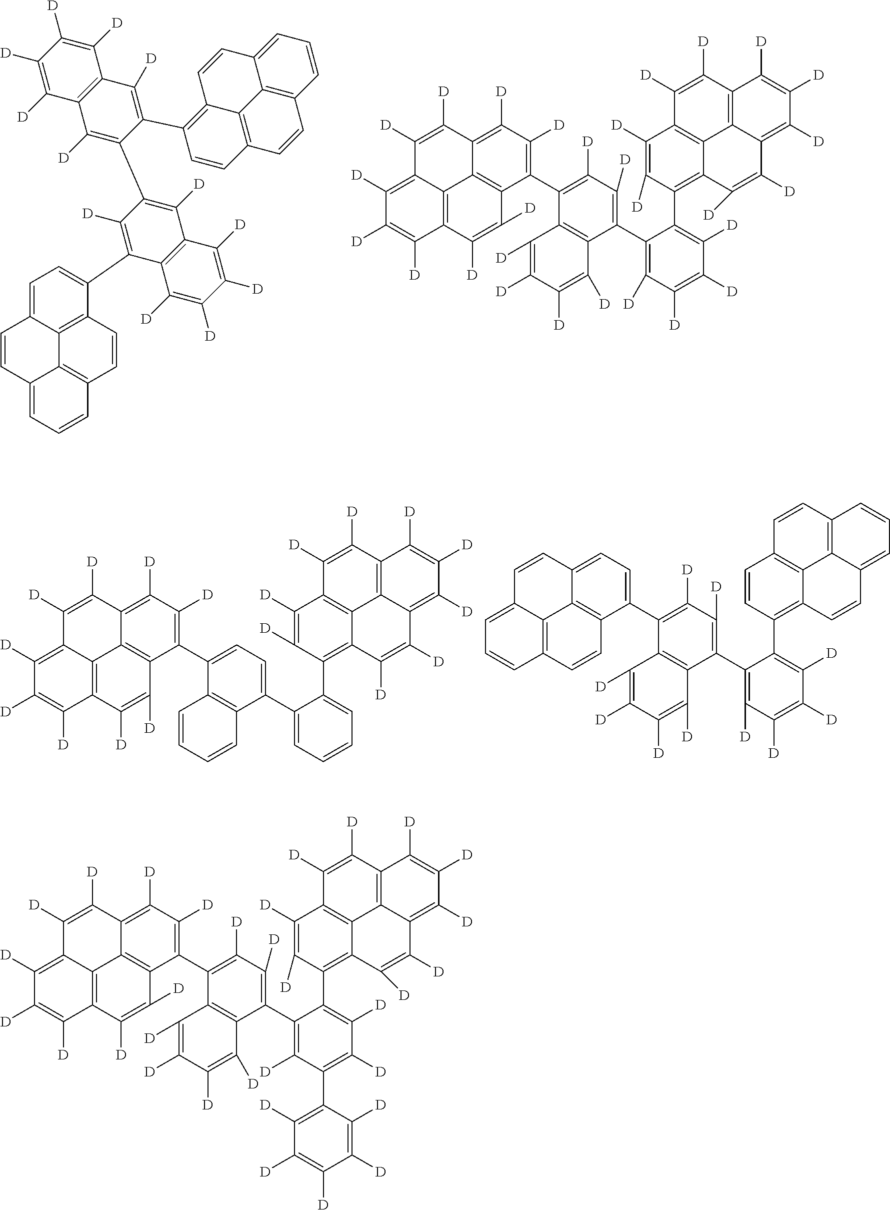

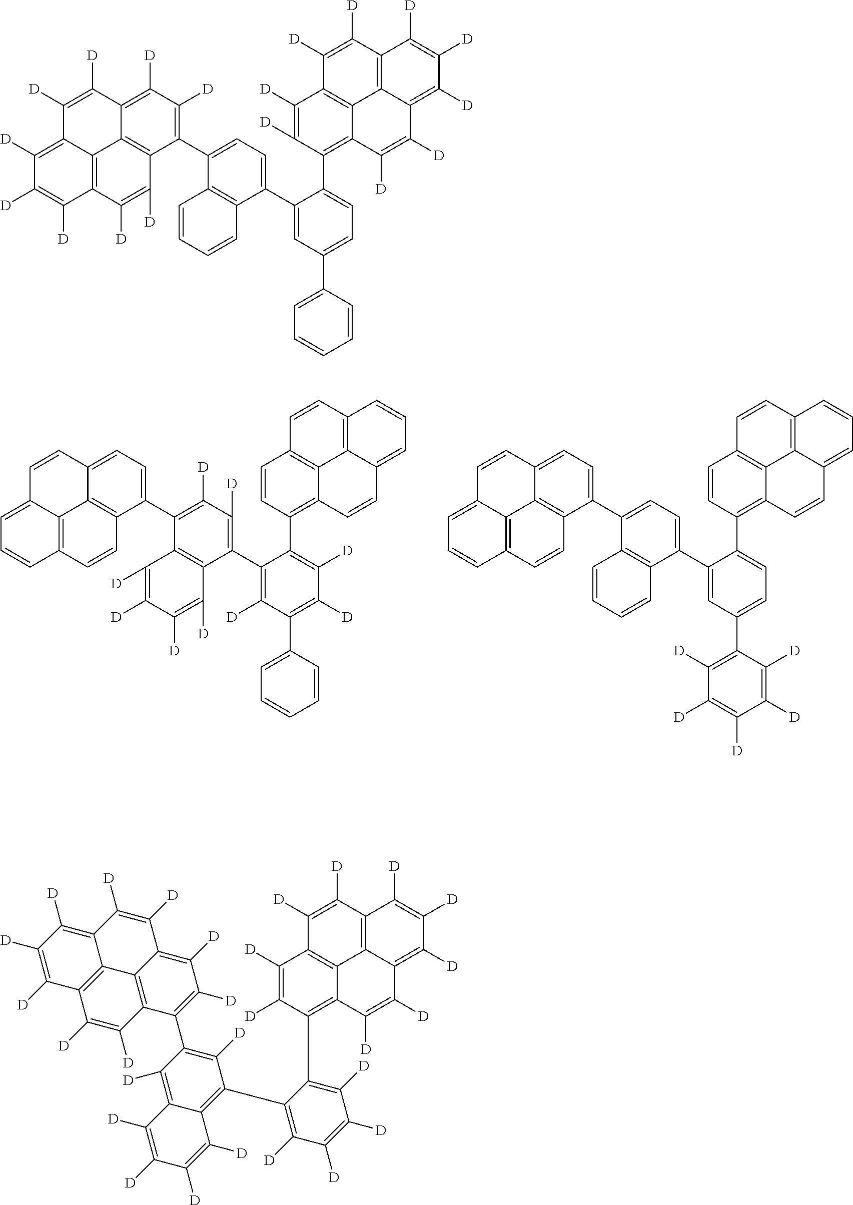

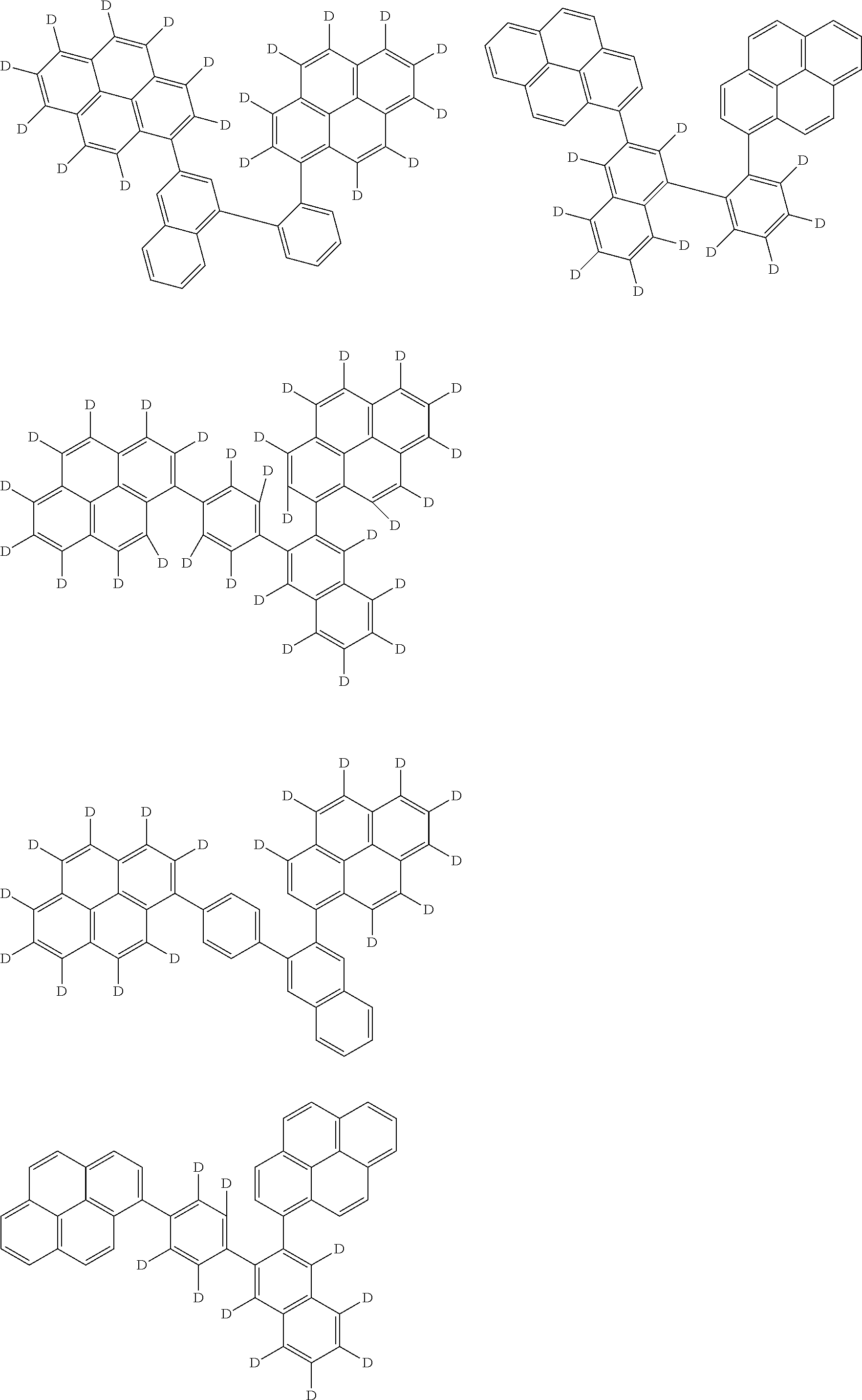

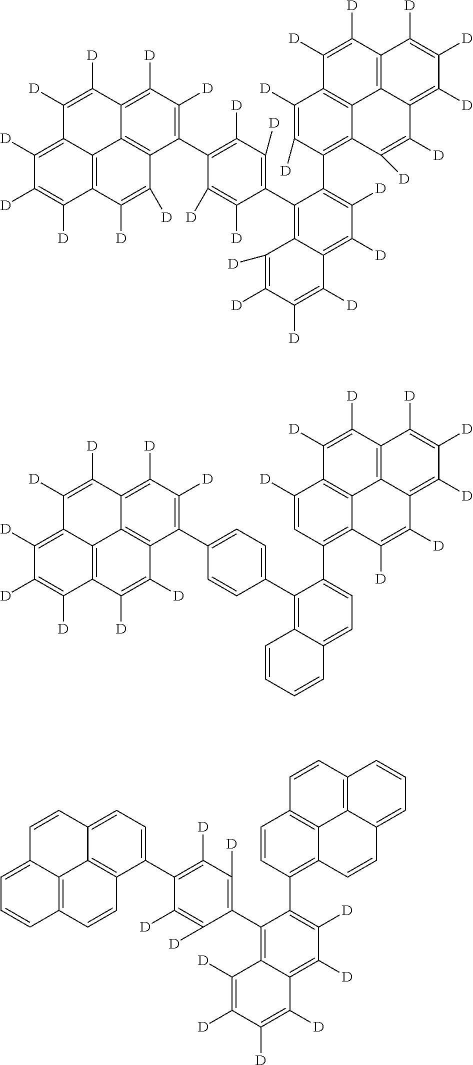

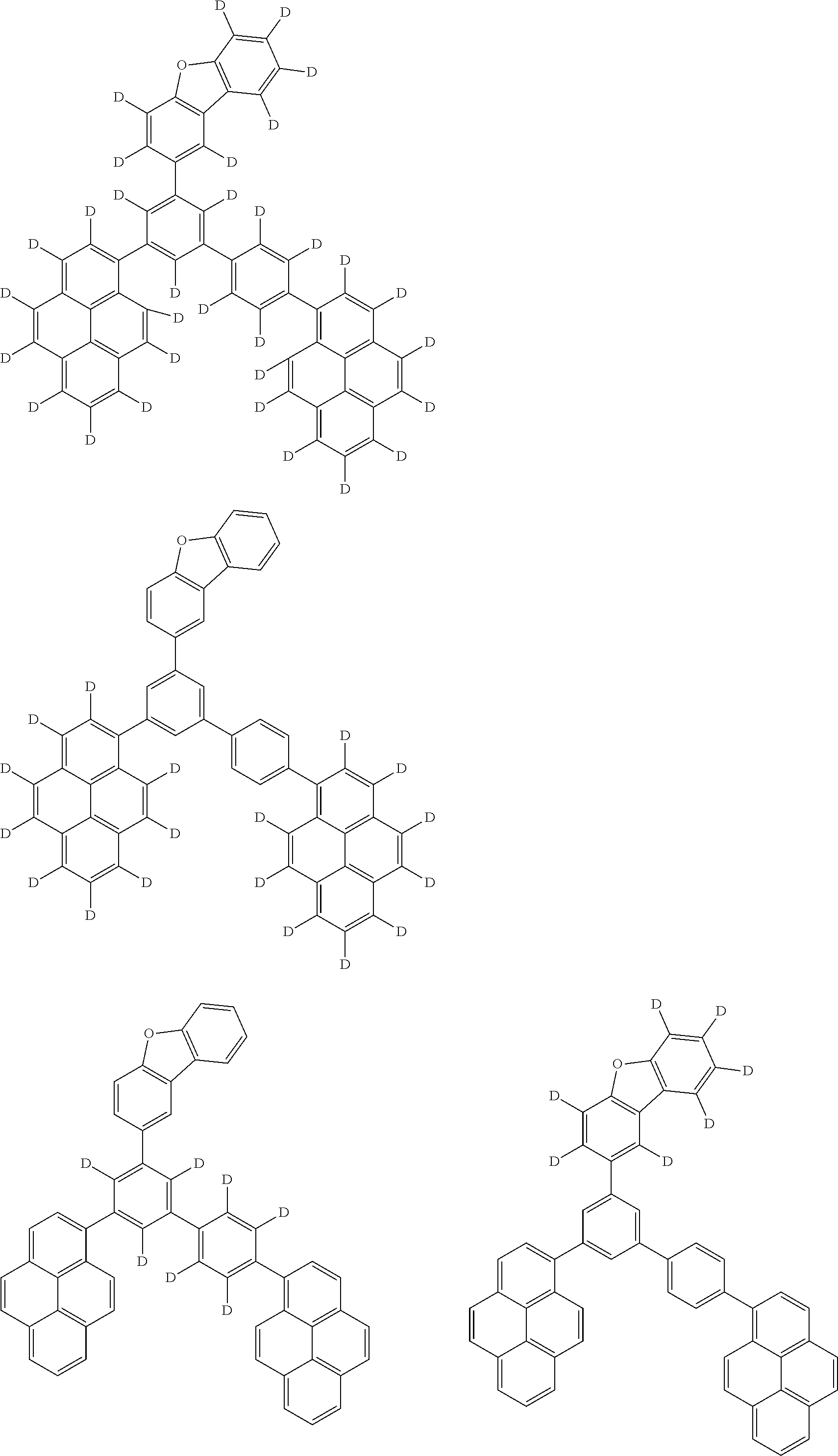

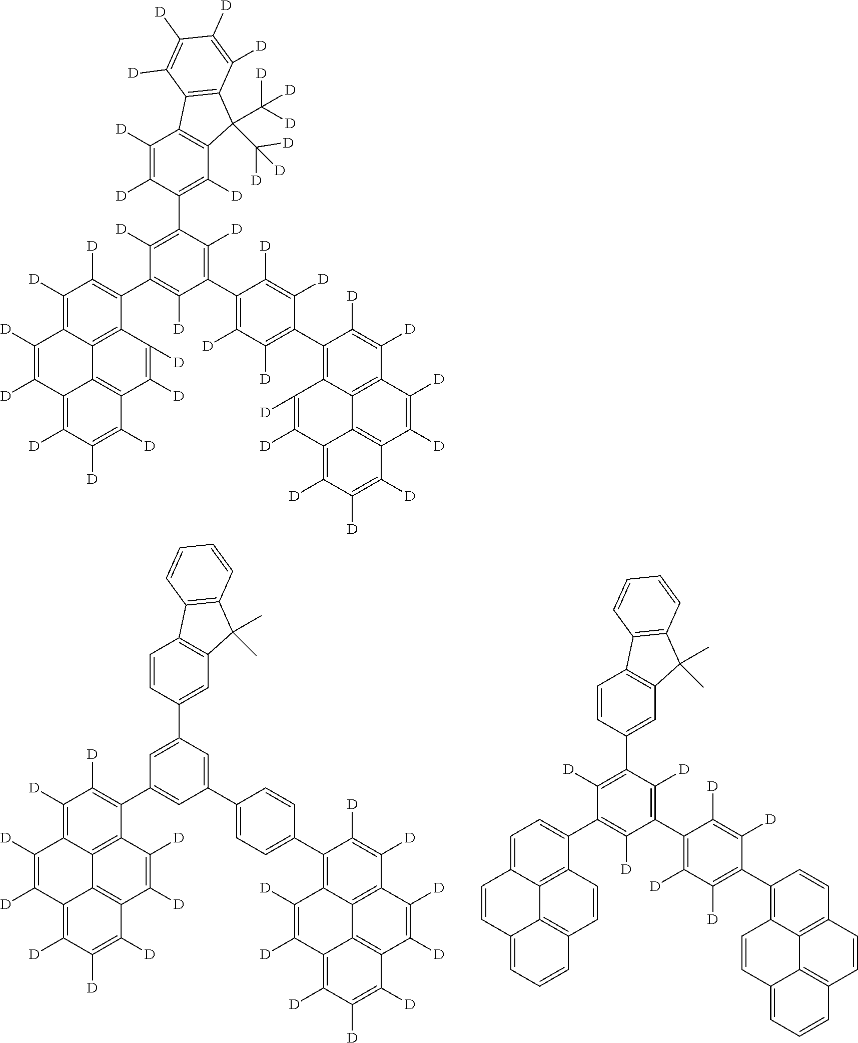

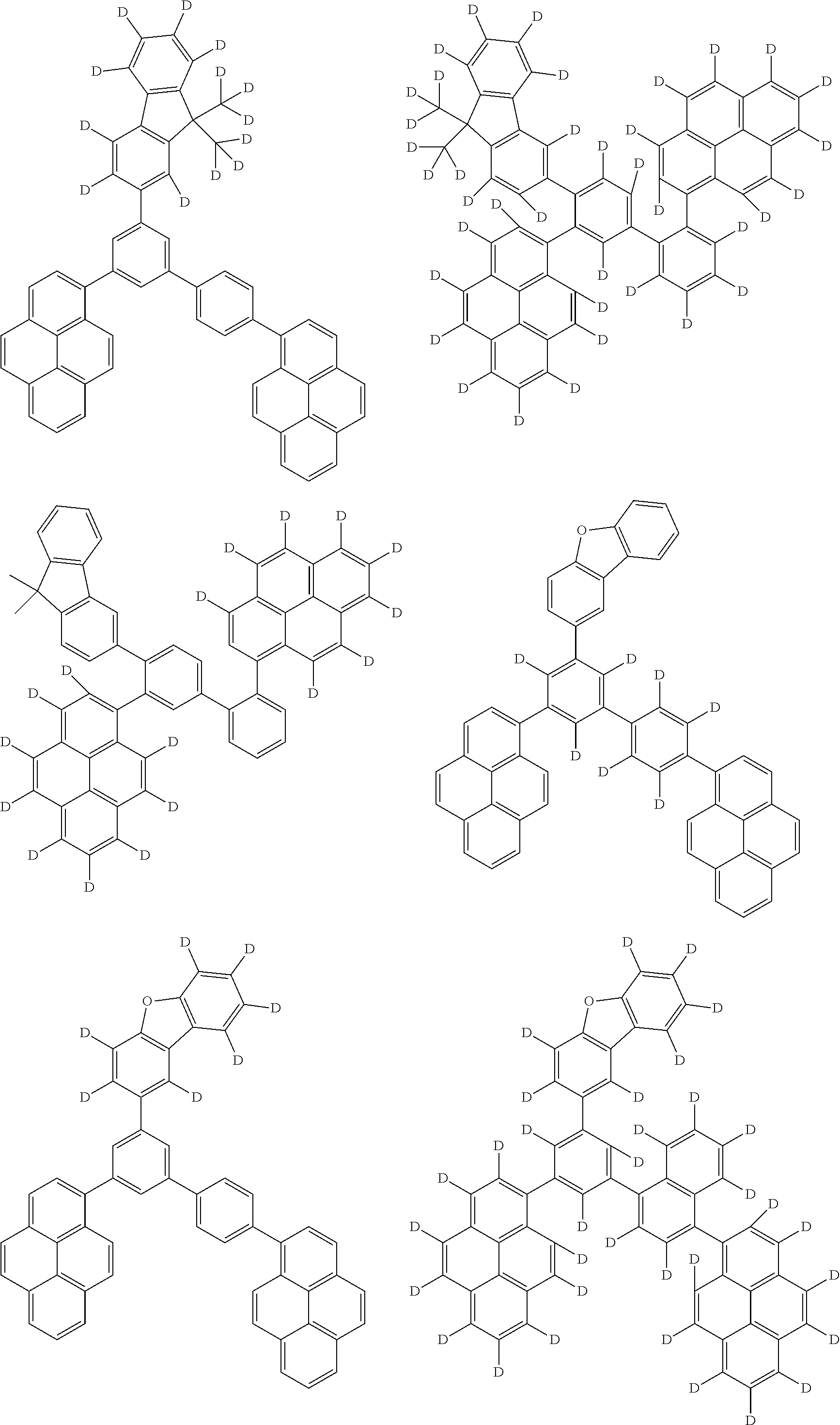

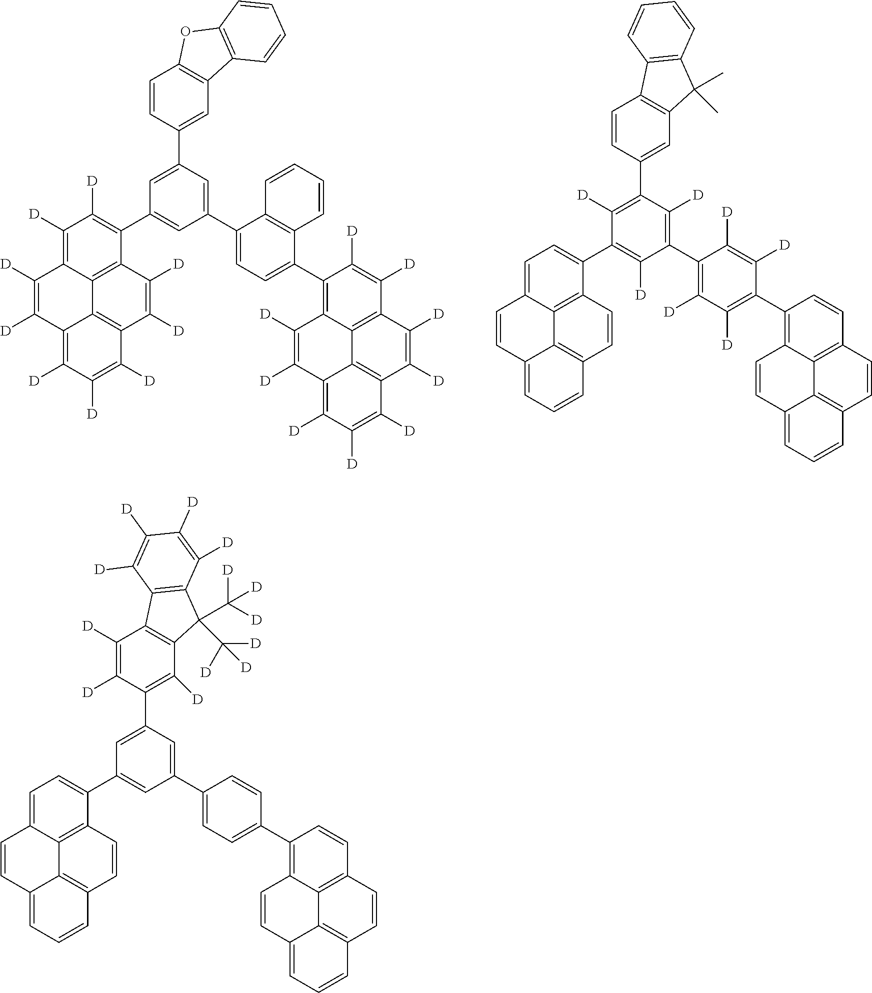

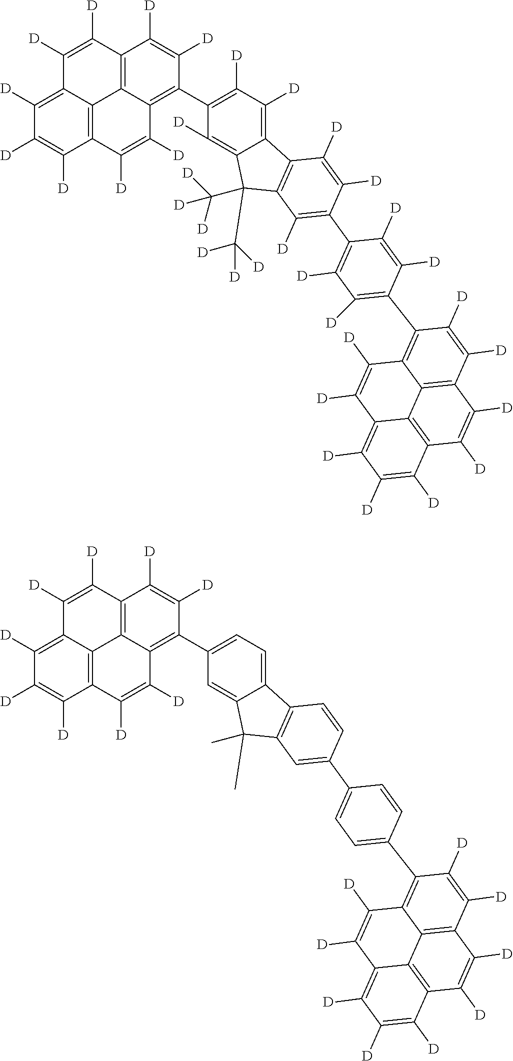 [SMILES: [2H]c1c([2H])c(-c2c([2H])c([2H])c3c([2H])c([2H])c4c([2H])c([2H])c([2H])c5c([2H])c([2H])c2c3c45)c([2H])c([2H])c1-c1c([2H])c([2H])c2c(c1[2H])C(C([2H])([2H])[2H])(C([2H])([2H])[2H])c1c([2H])c(-c3c([2H])c([2H])c4c([2H])c([2H])c5c([2H])c([2H])c([2H])c6c([2H])c([2H])c3c4c56)c([2H])c([2H])c1-2 ; [2H]c1c([2H])c2c([2H])c([2H])c3c([2H])c([2H])c(-c4ccc(-c5ccc6c(c5)C(C)(C)c5cc(-c7c([2H])c([2H])c8c([2H])c([2H])c9c([2H])c([2H])c([2H])c%10c([2H])c([2H])c7c8c9%10)ccc5-6)cc4)c4c([2H])c([2H])c(c1[2H])c2c34]

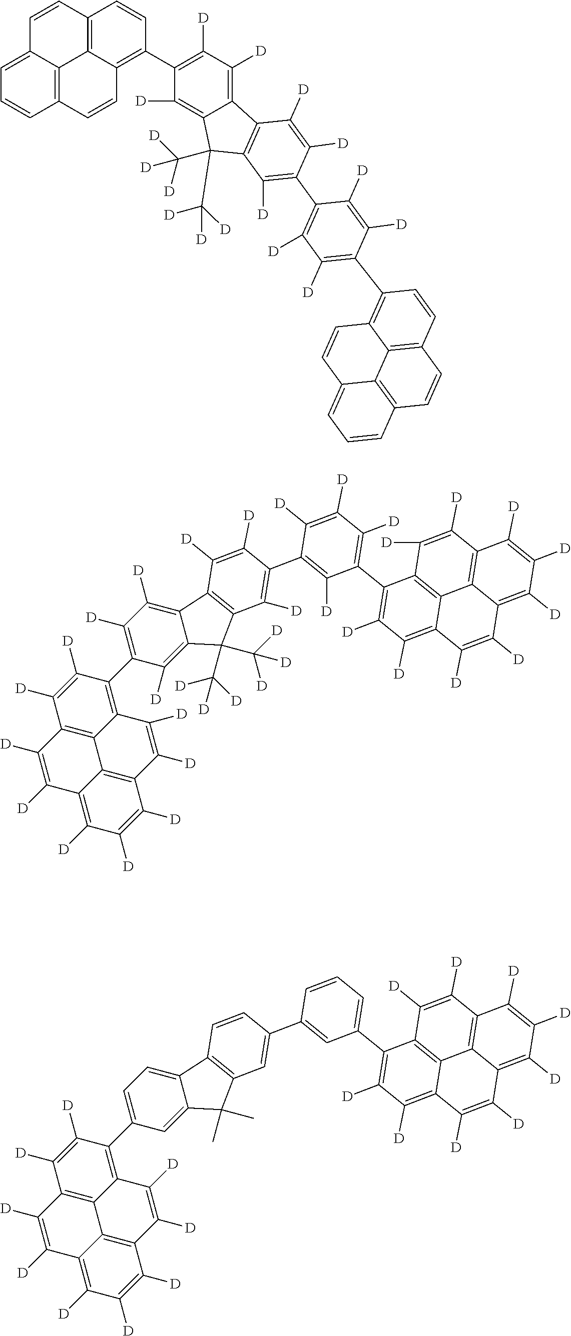

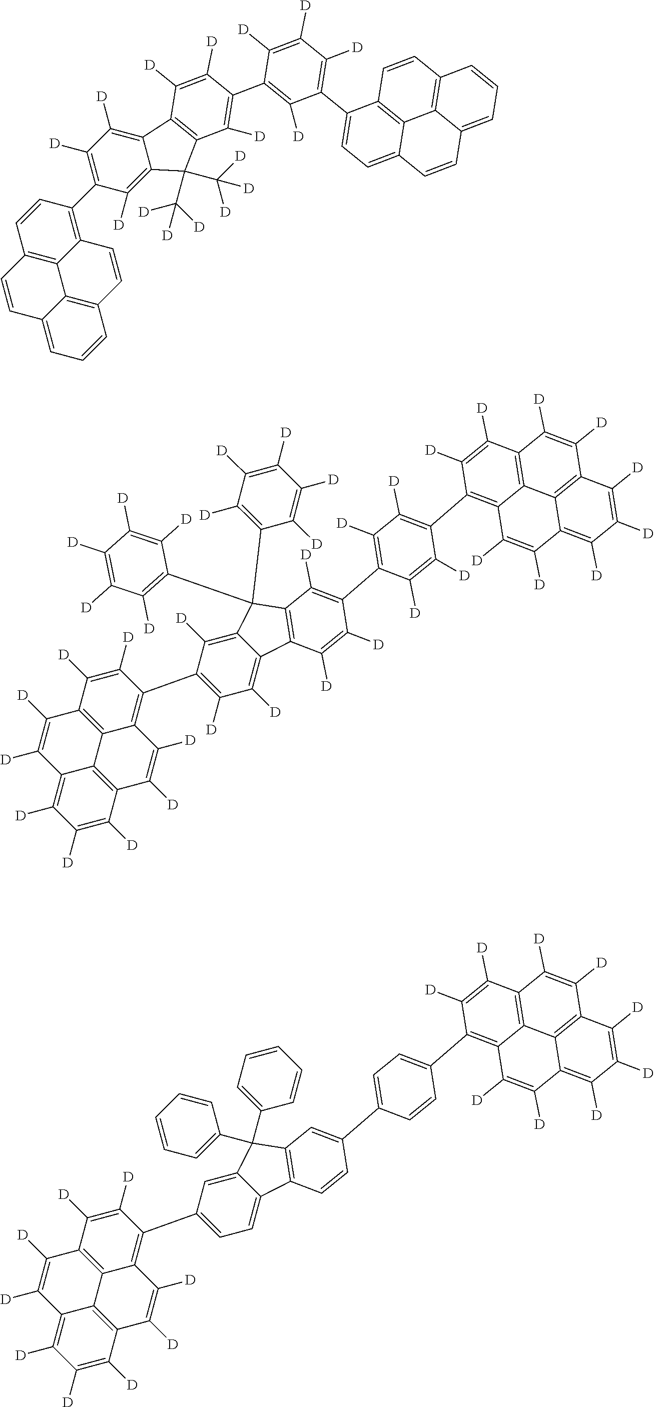

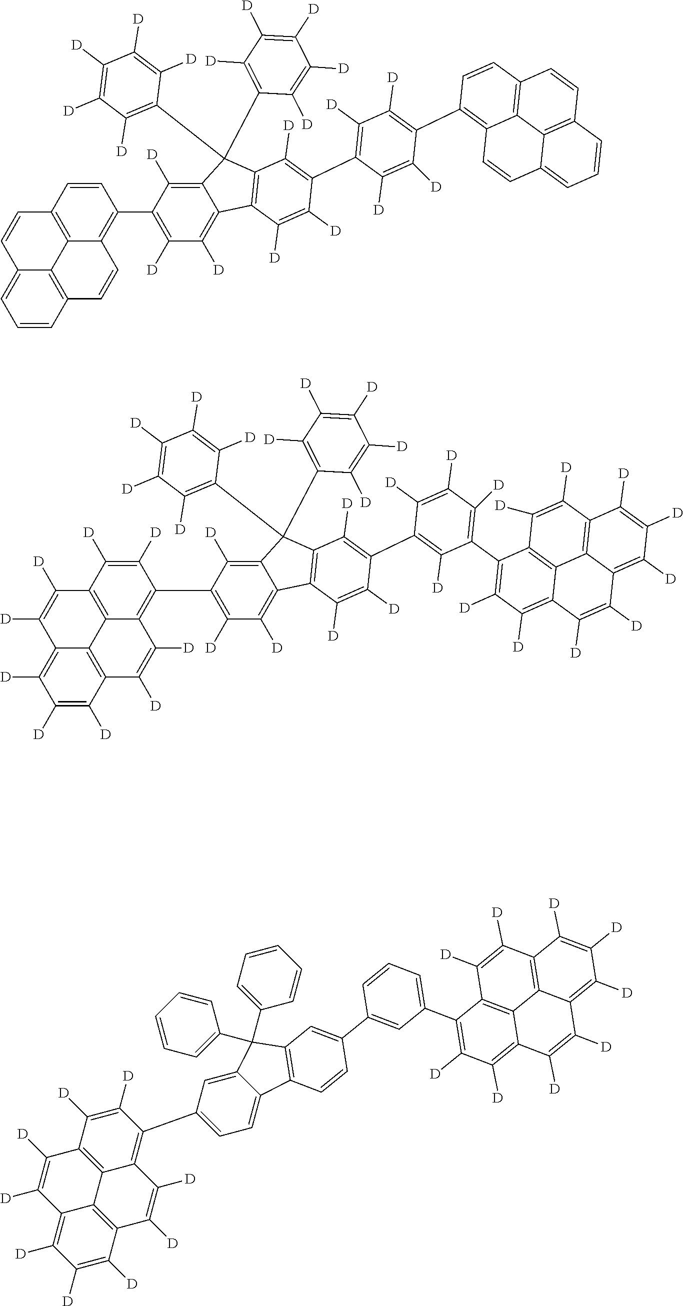

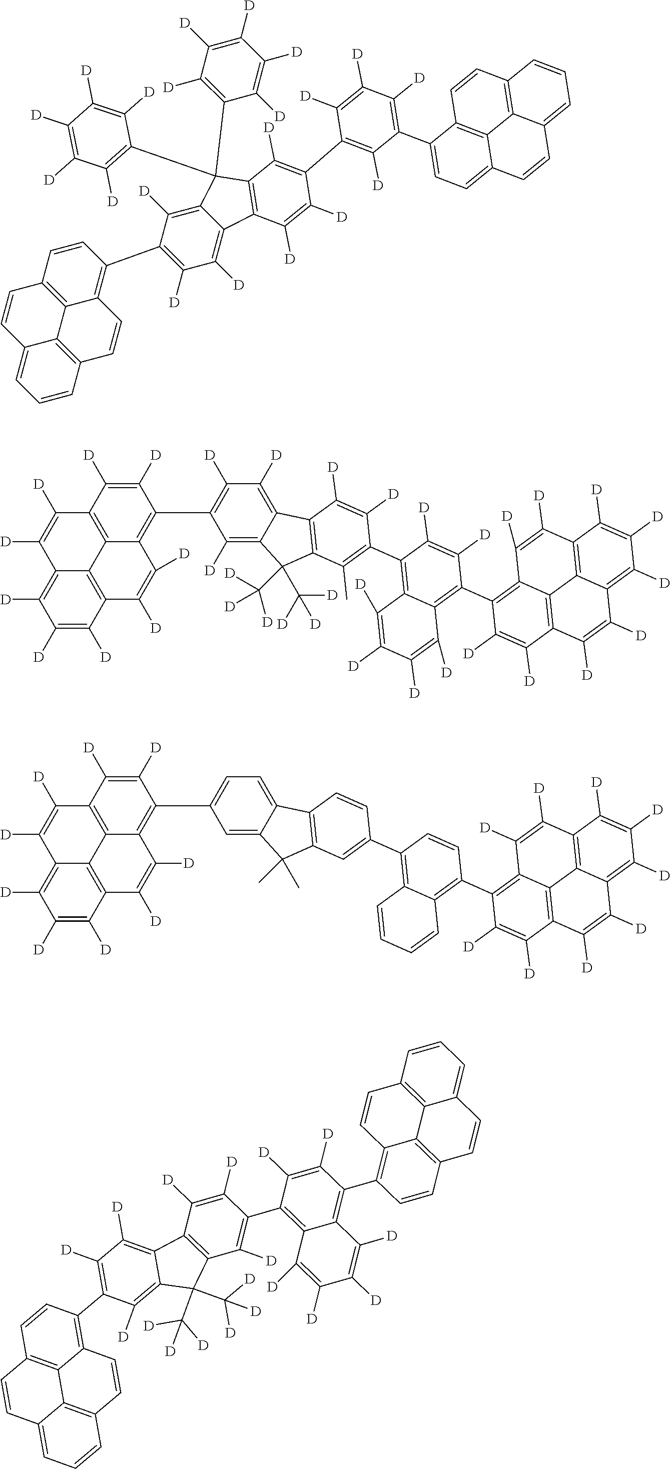

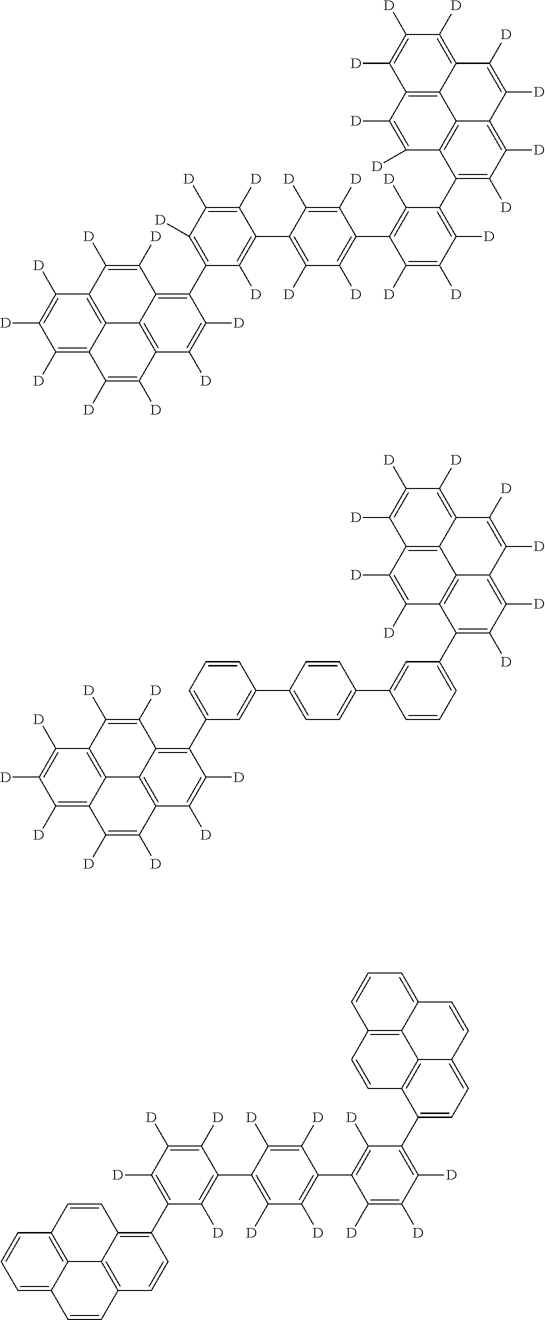

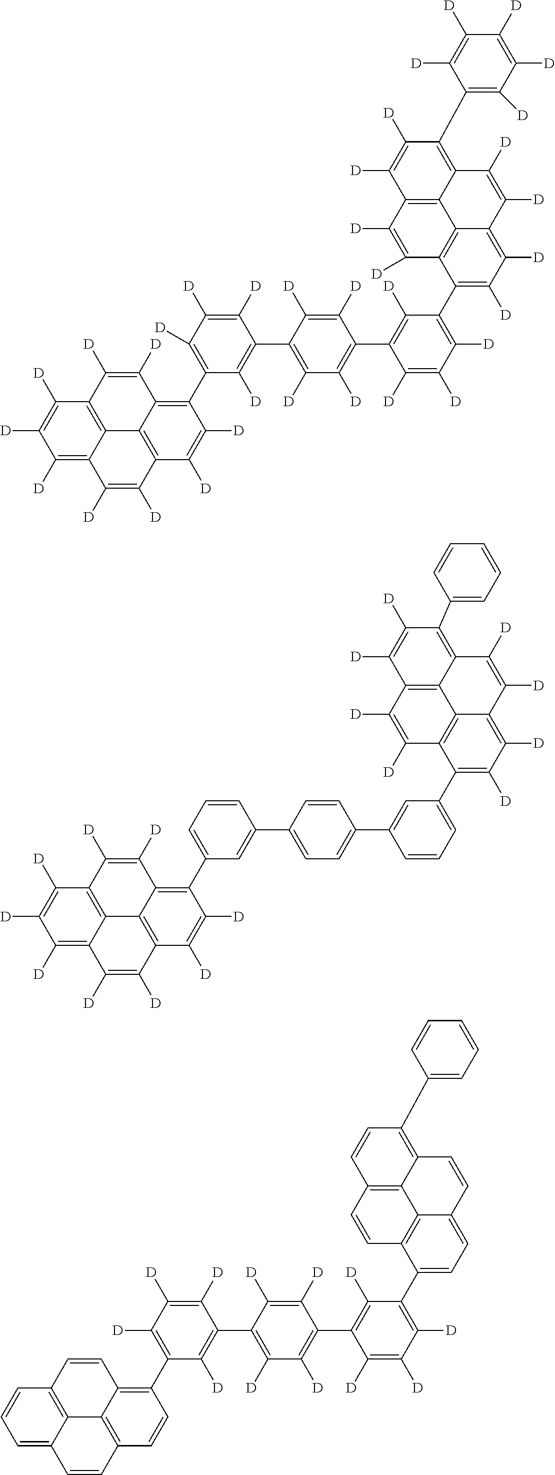

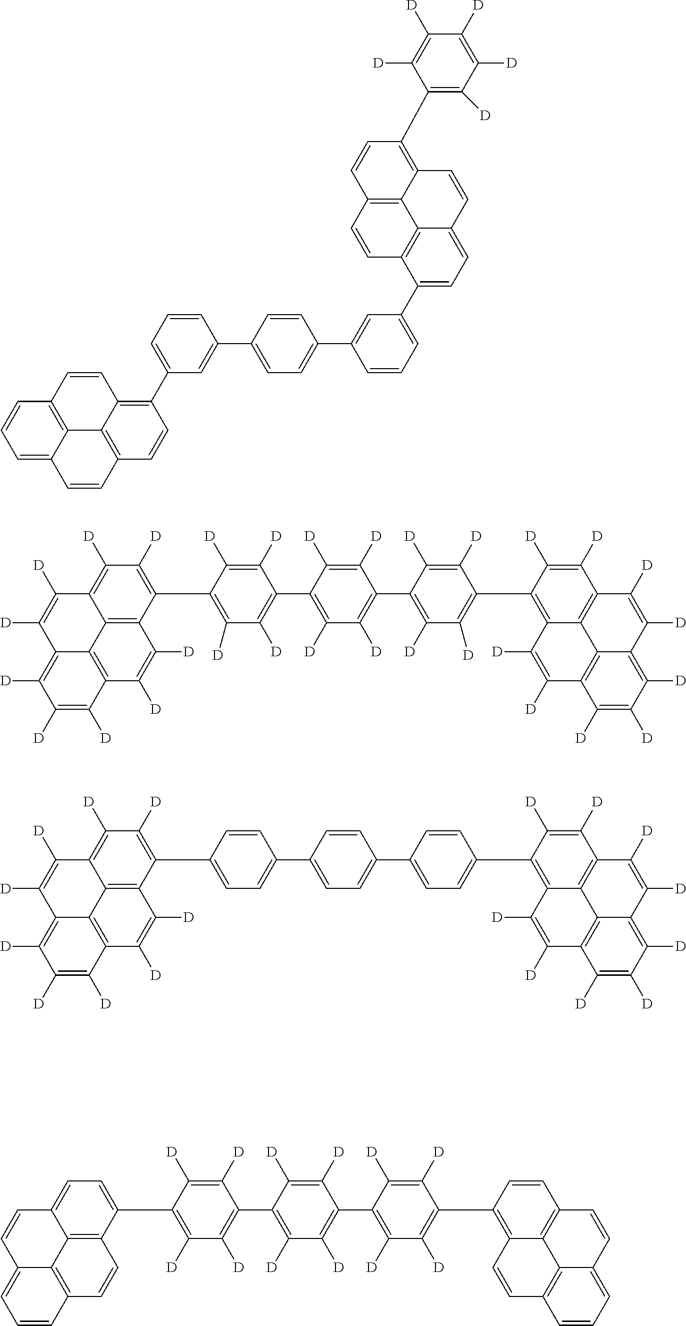

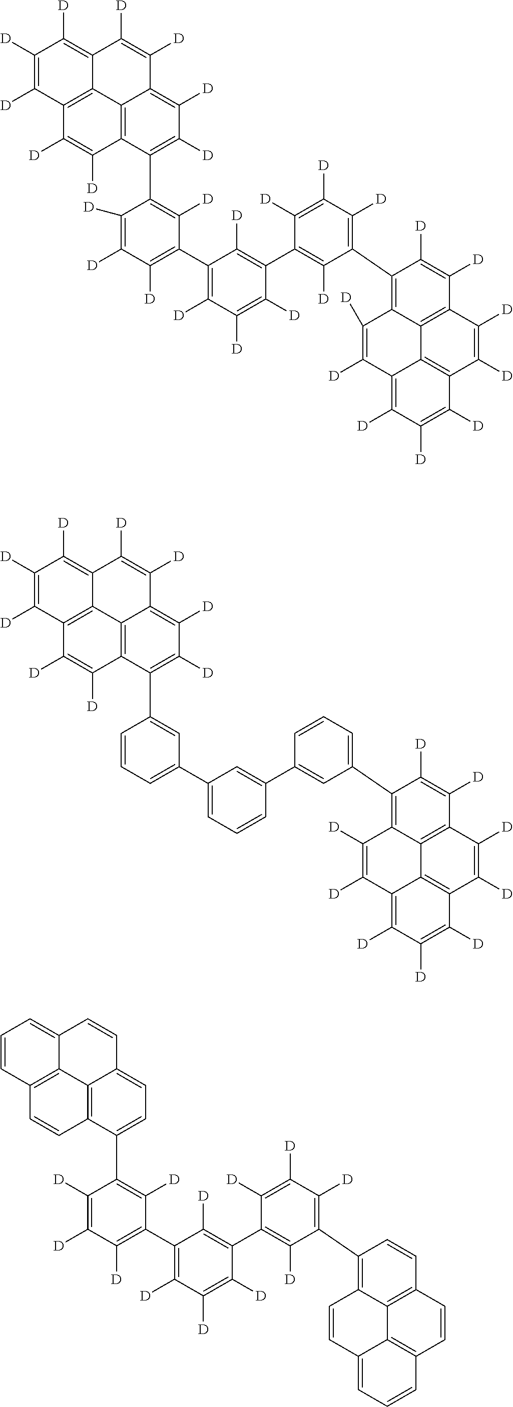

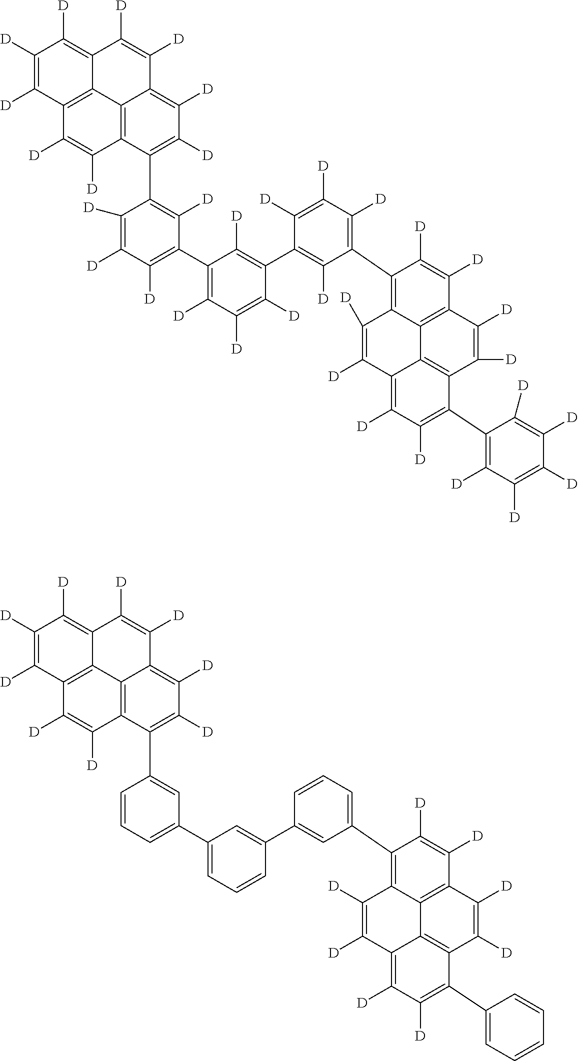

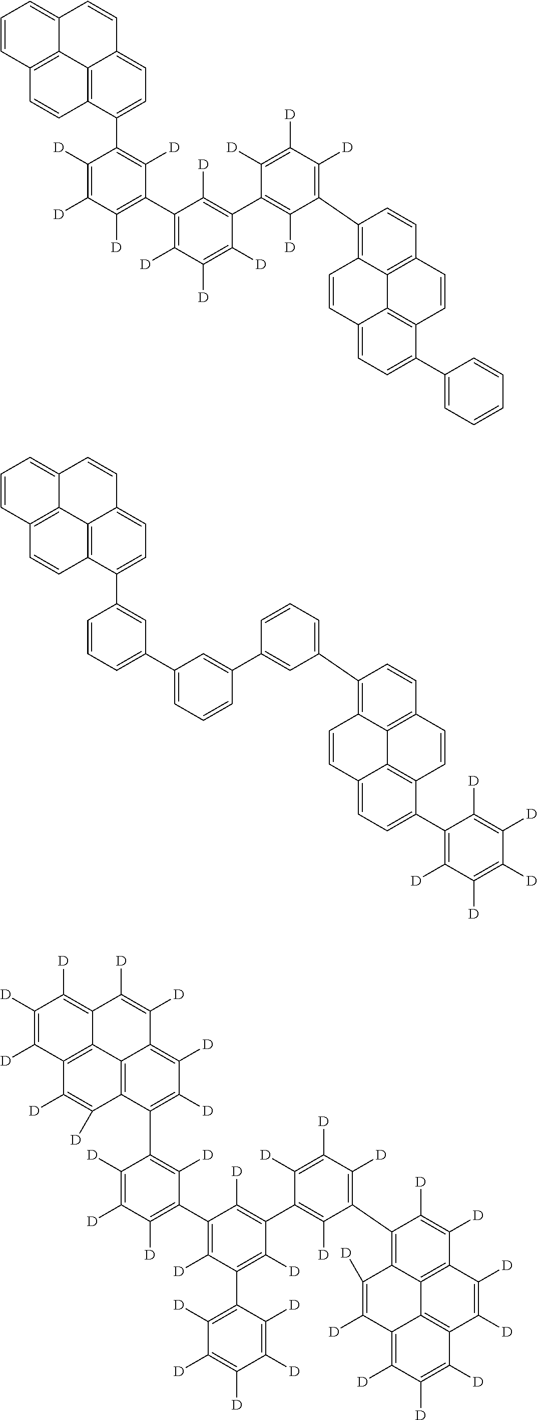

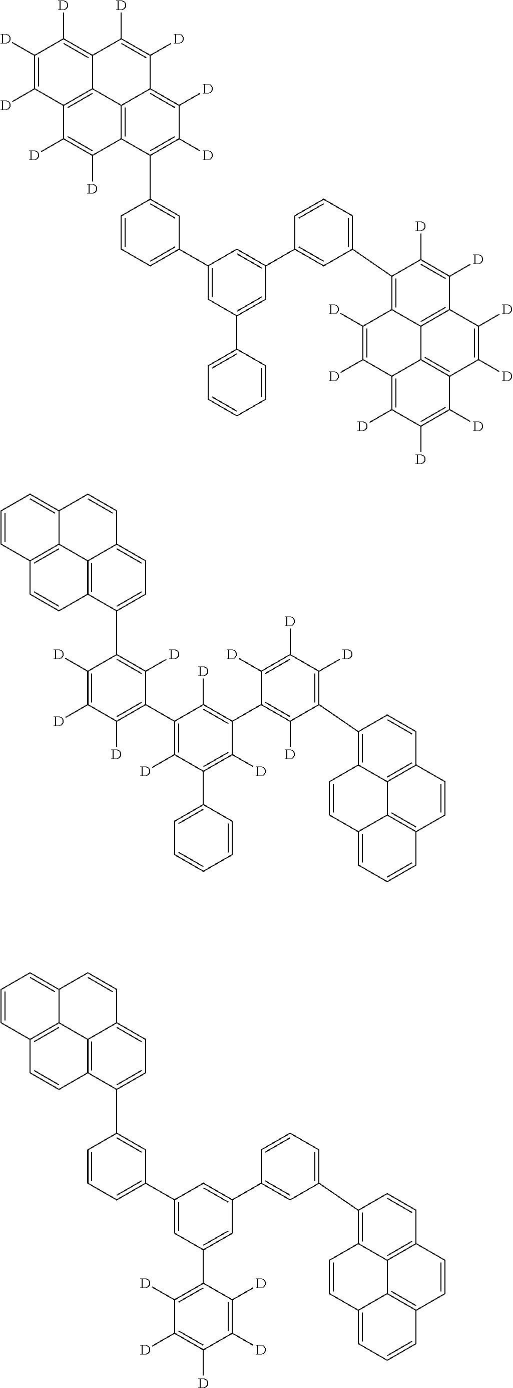 [SMILES: [2H]c1c([2H])c2c([2H])c([2H])c3c([2H])c([2H])c(-c4cccc(-c5cc(-c6ccccc6)cc(-c6cccc(-c7c([2H])c([2H])c8c([2H])c([2H])c9c([2H])c([2H])c([2H])c%10c([2H])c([2H])c7c8c9%10)c6)c5)c4)c4c([2H])c([2H])c(c1[2H])c2c34 ; [2H]c1c([2H])c(-c2c([2H])c(-c3ccccc3)c([2H])c(-c3c([2H])c([2H])c([2H])c(-c4ccc5ccc6cccc7ccc4c5c67)c3[2H])c2[2H])c([2H])c(-c2ccc3ccc4cccc5ccc2c3c45)c1[2H] ; [2H]c1c([2H])c([2H])c(-c2cc(-c3cccc(-c4ccc5ccc6cccc7ccc4c5c67)c3)cc(-c3cccc(-c4ccc5ccc6cccc7ccc4c5c67)c3)c2)c([2H])c1[2H]]

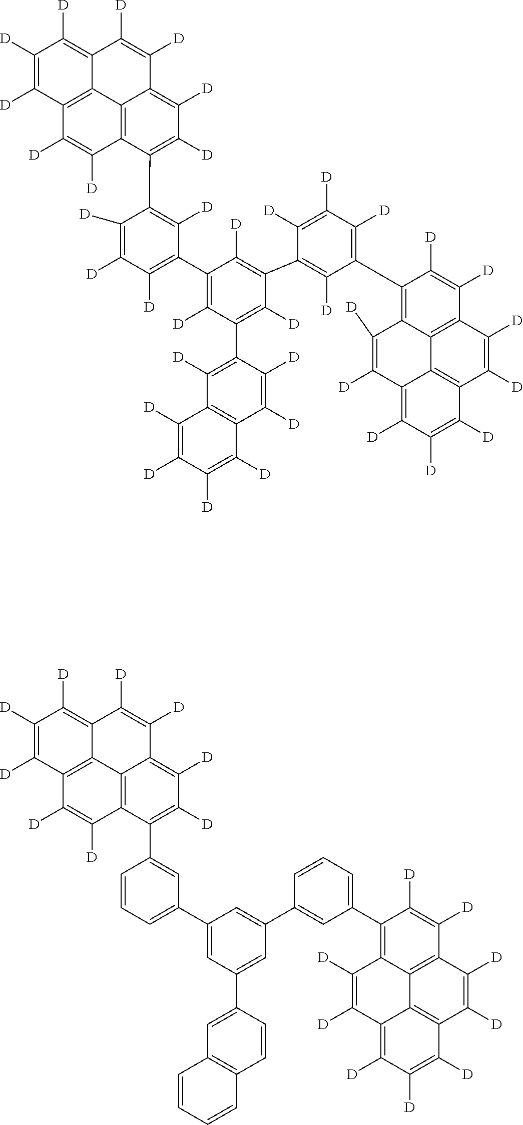

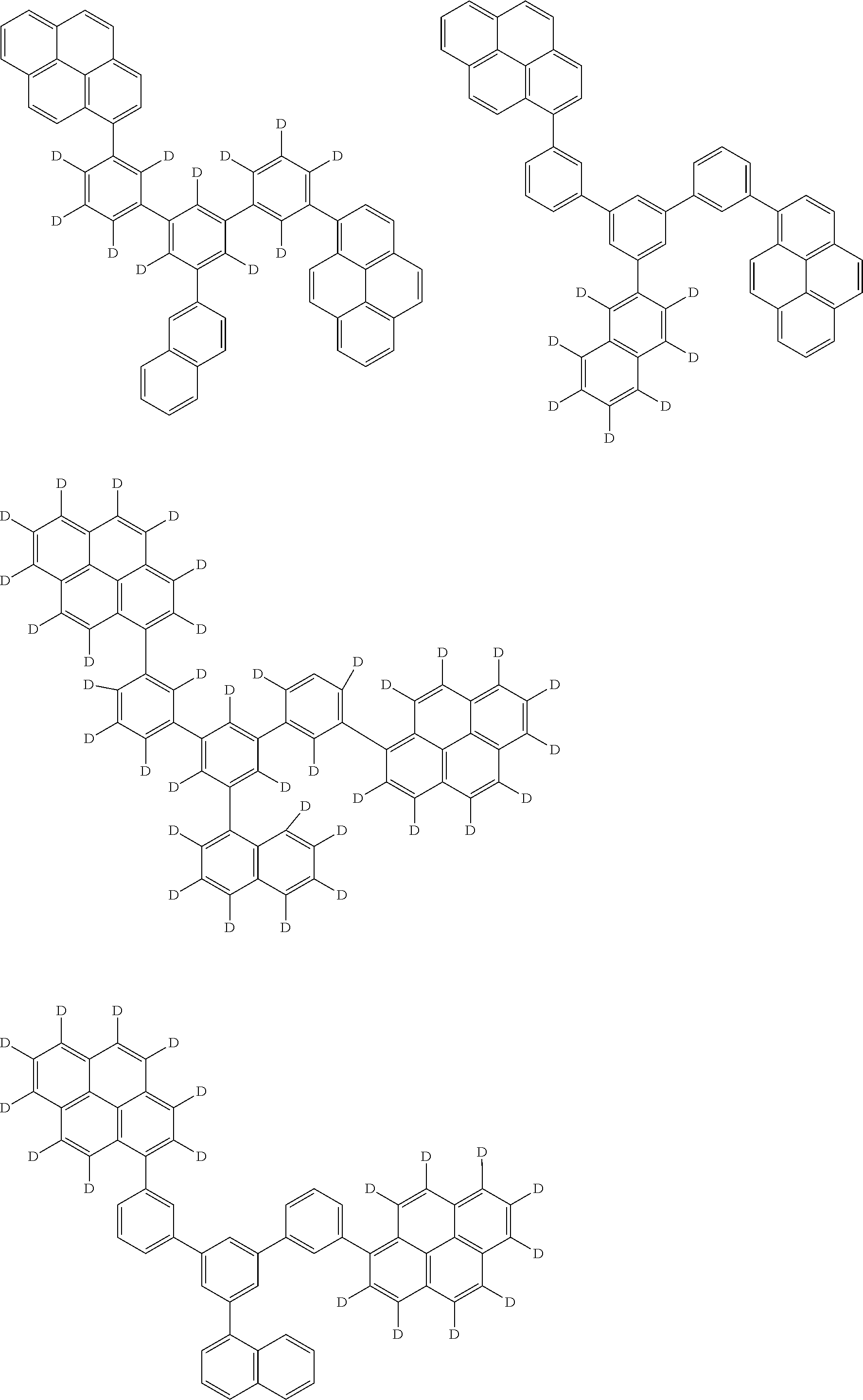

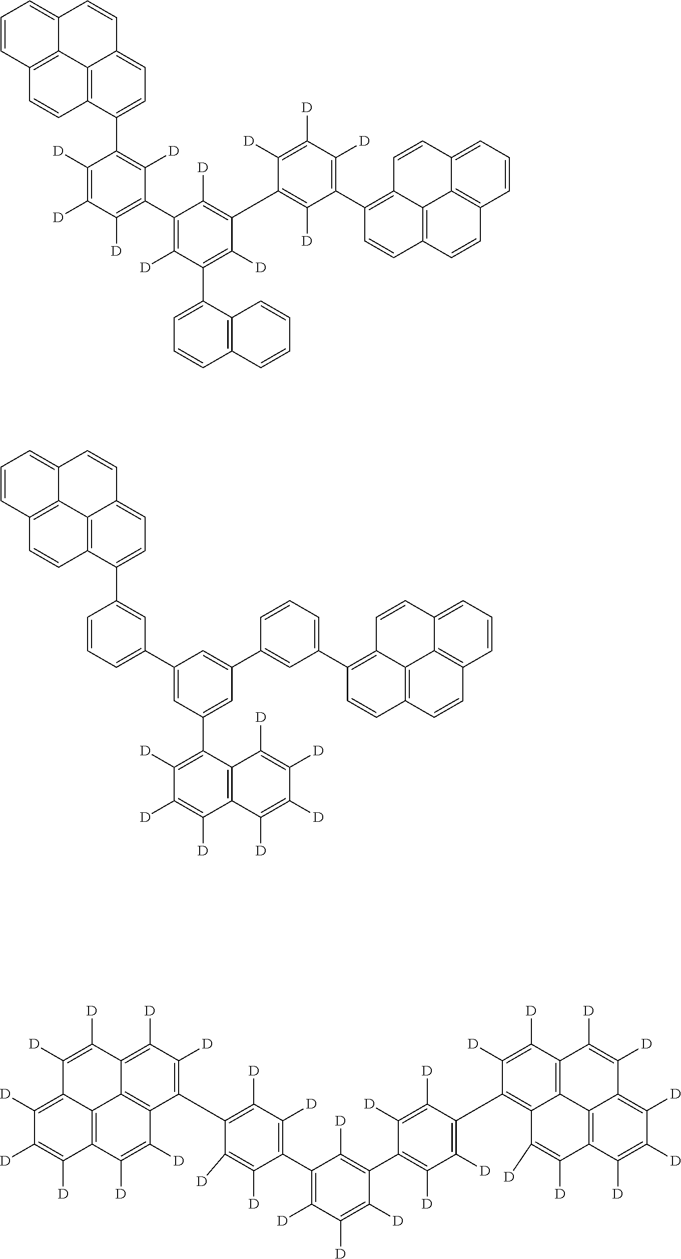

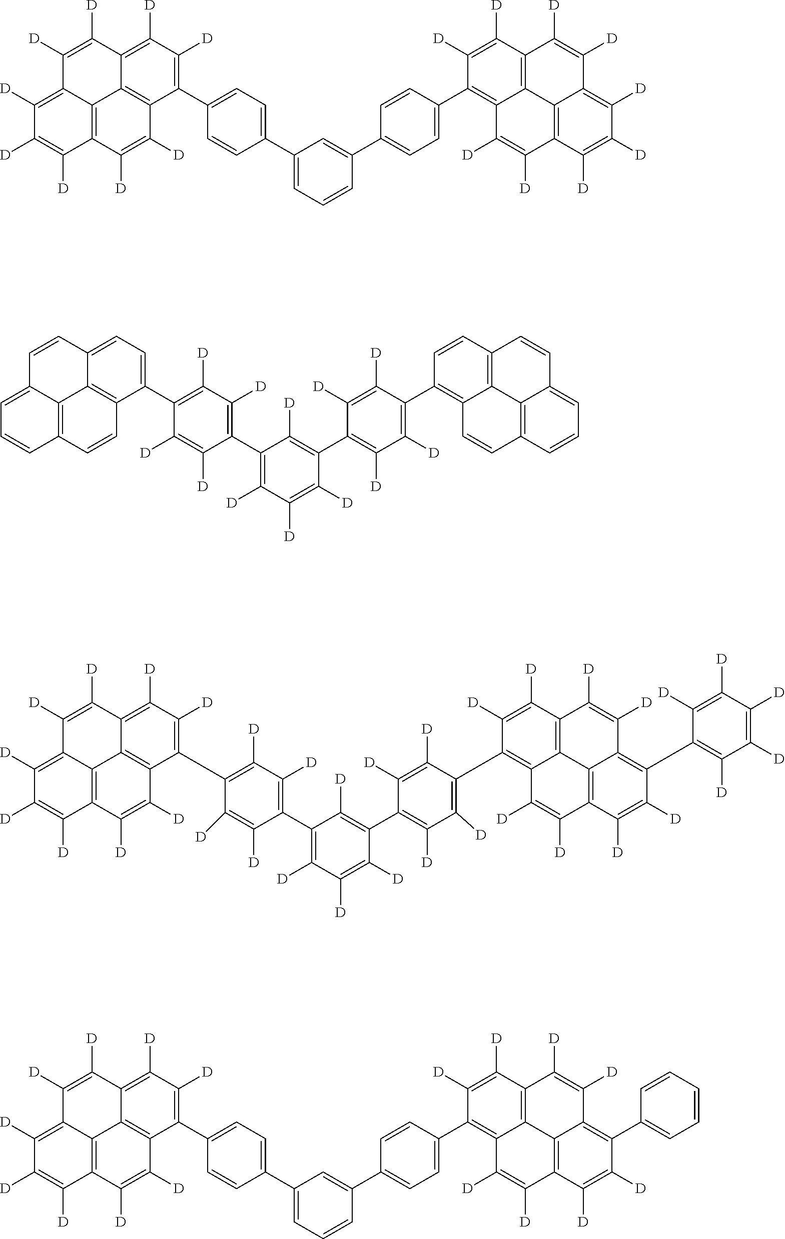

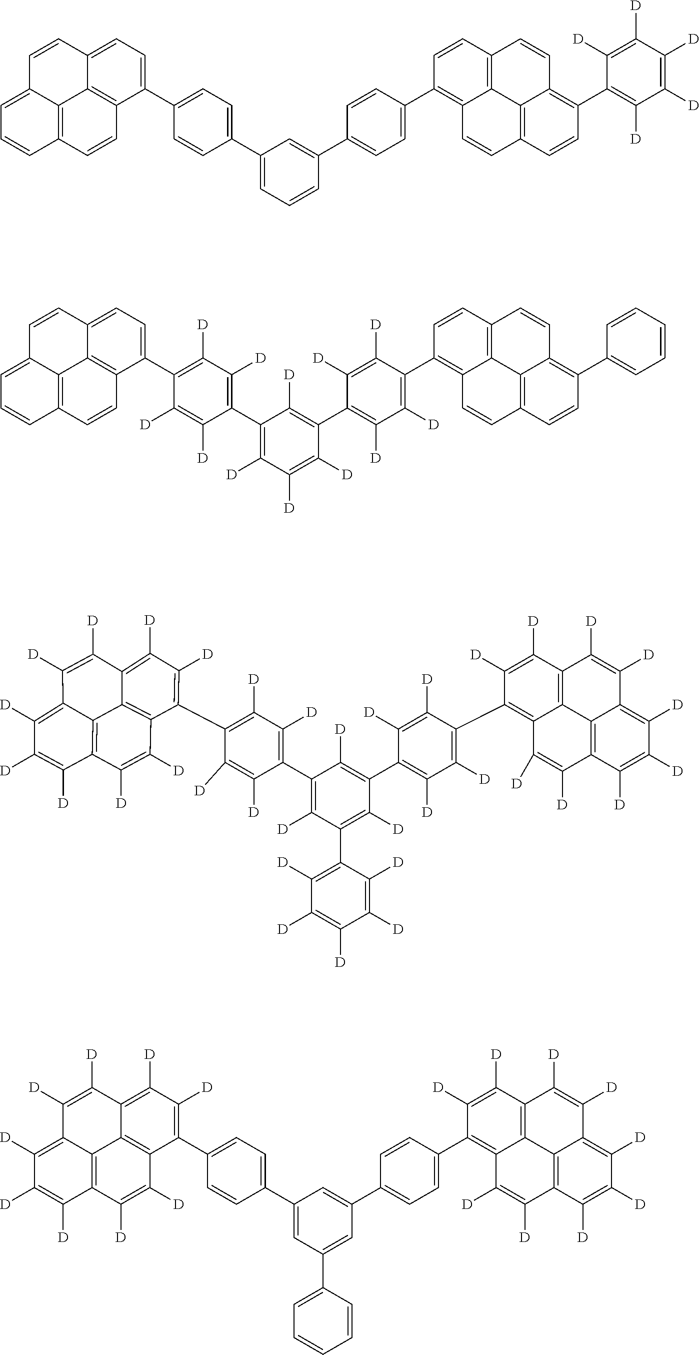

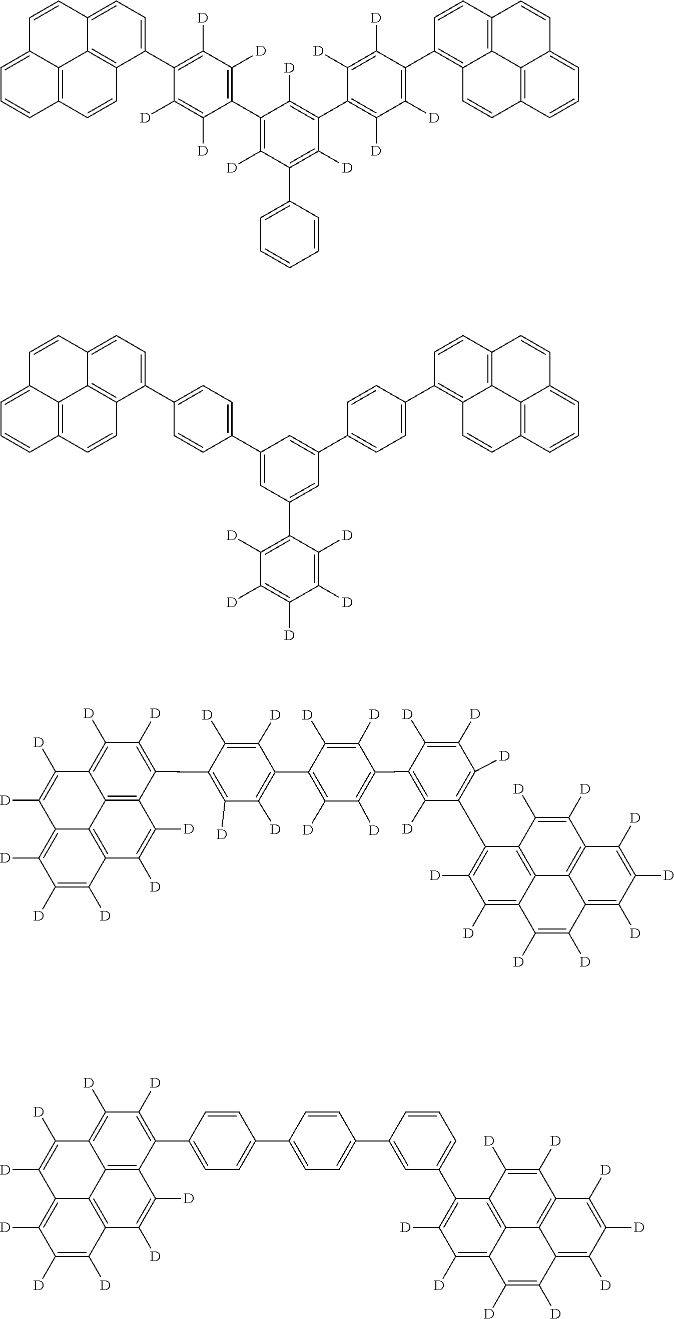

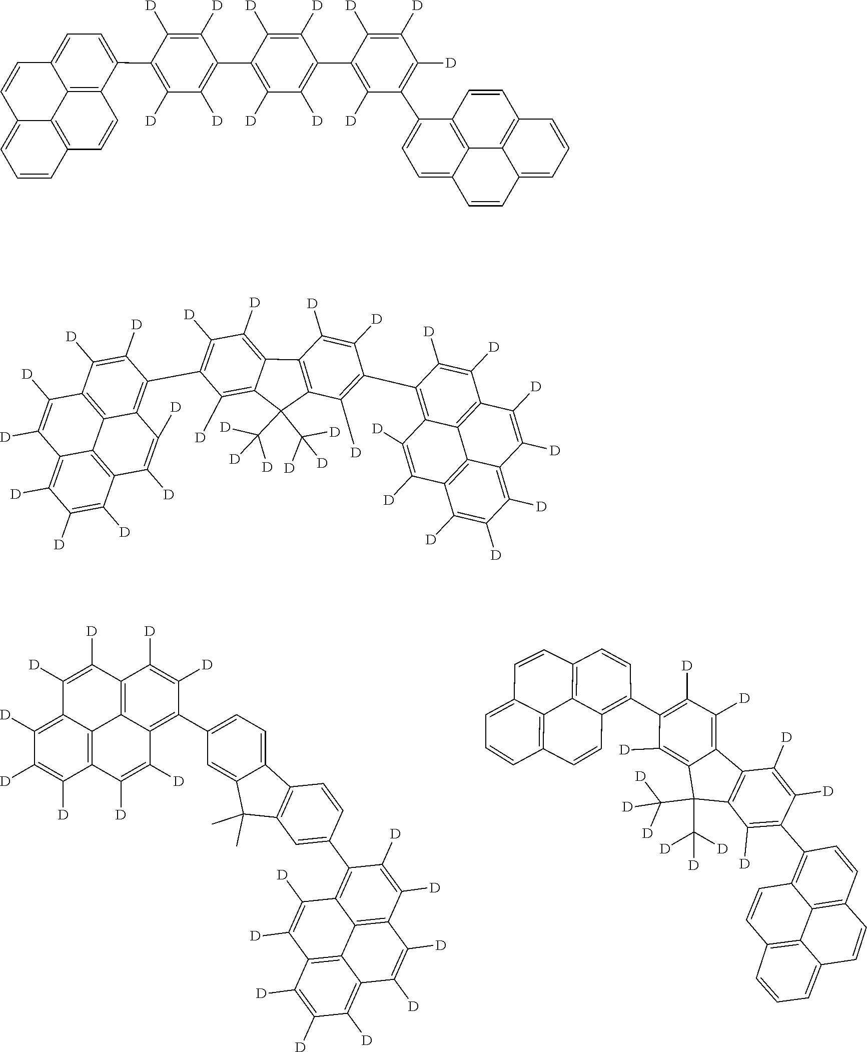

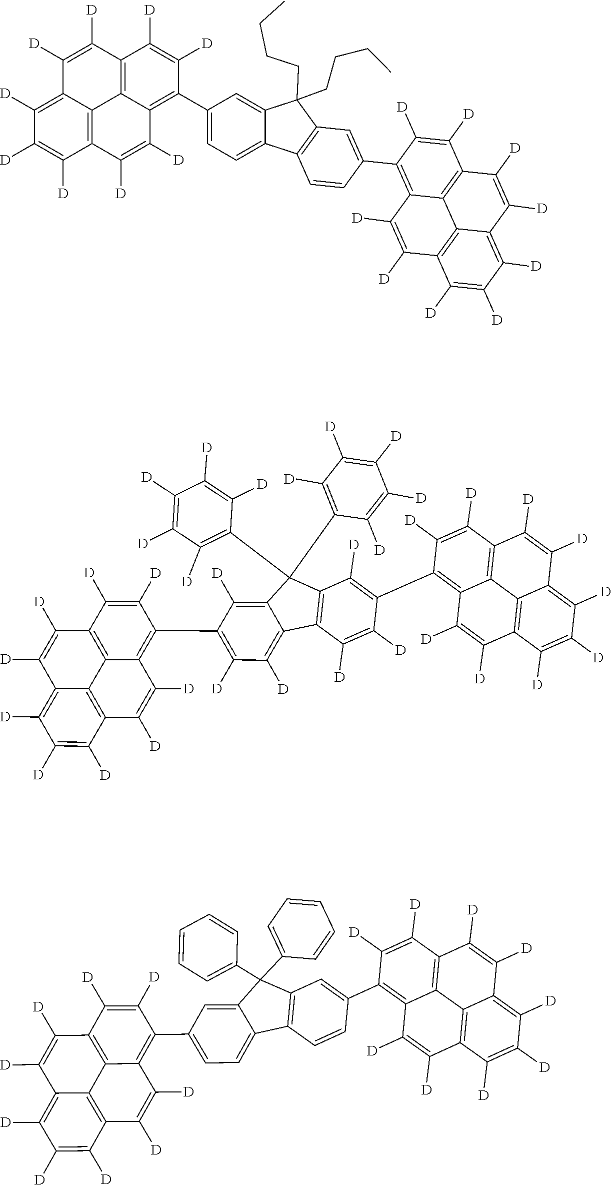

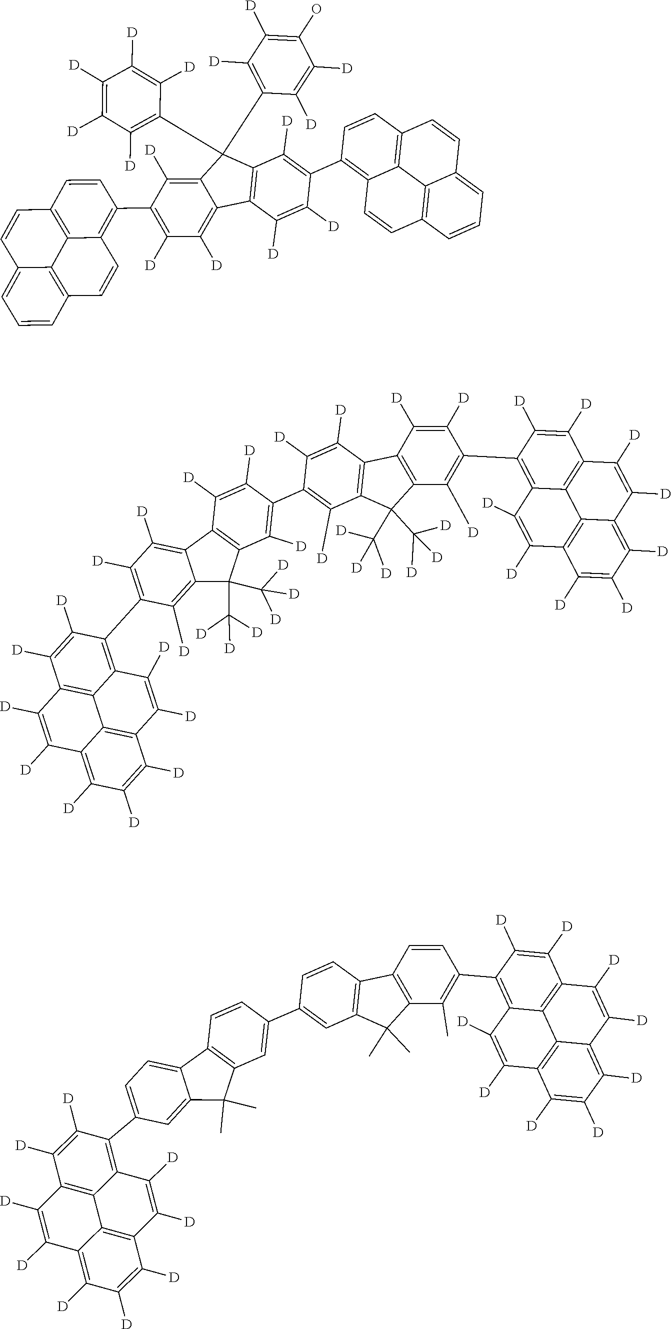

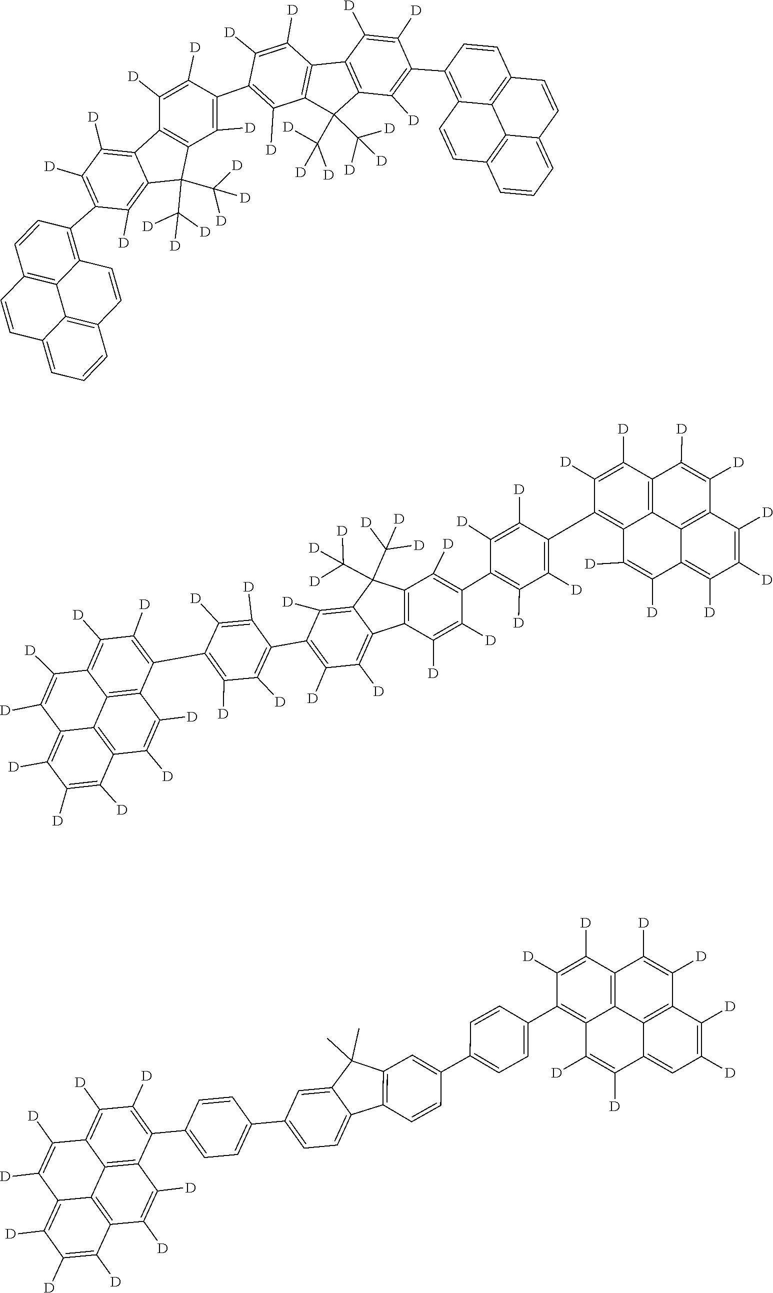

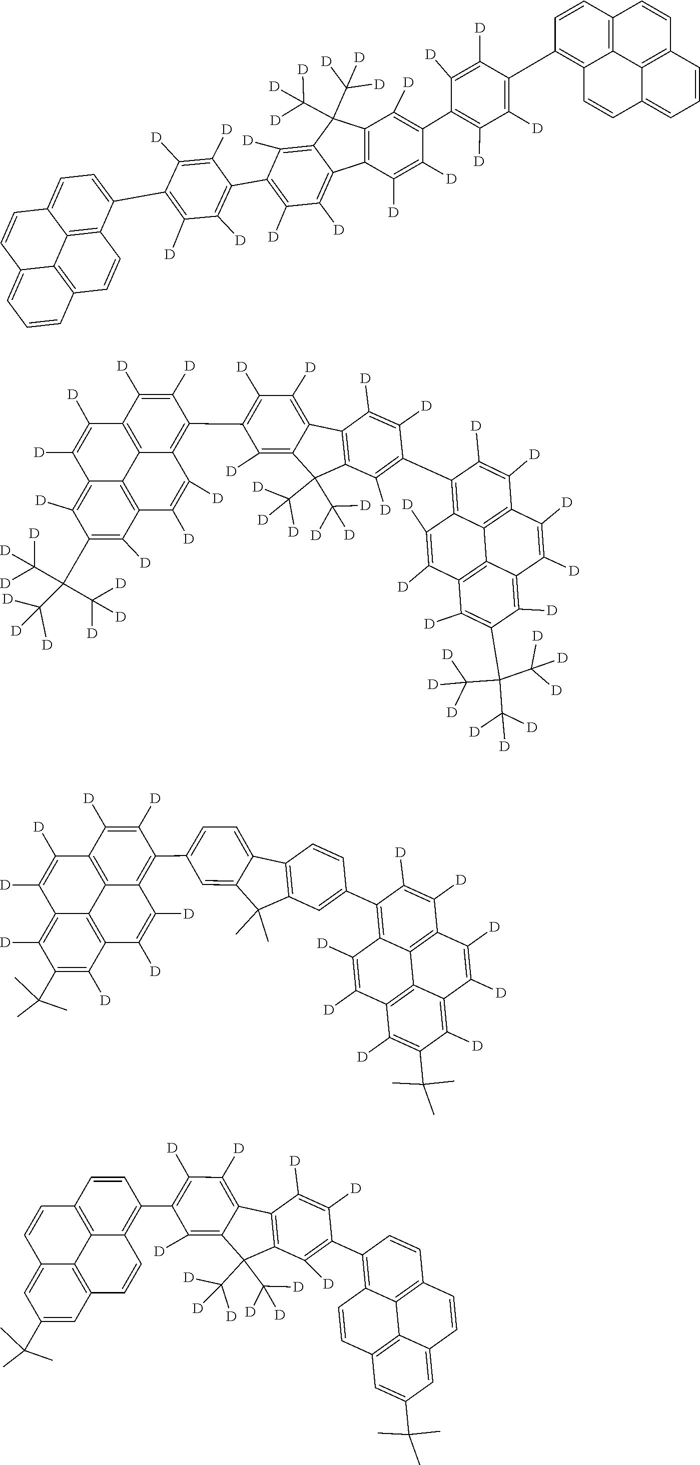

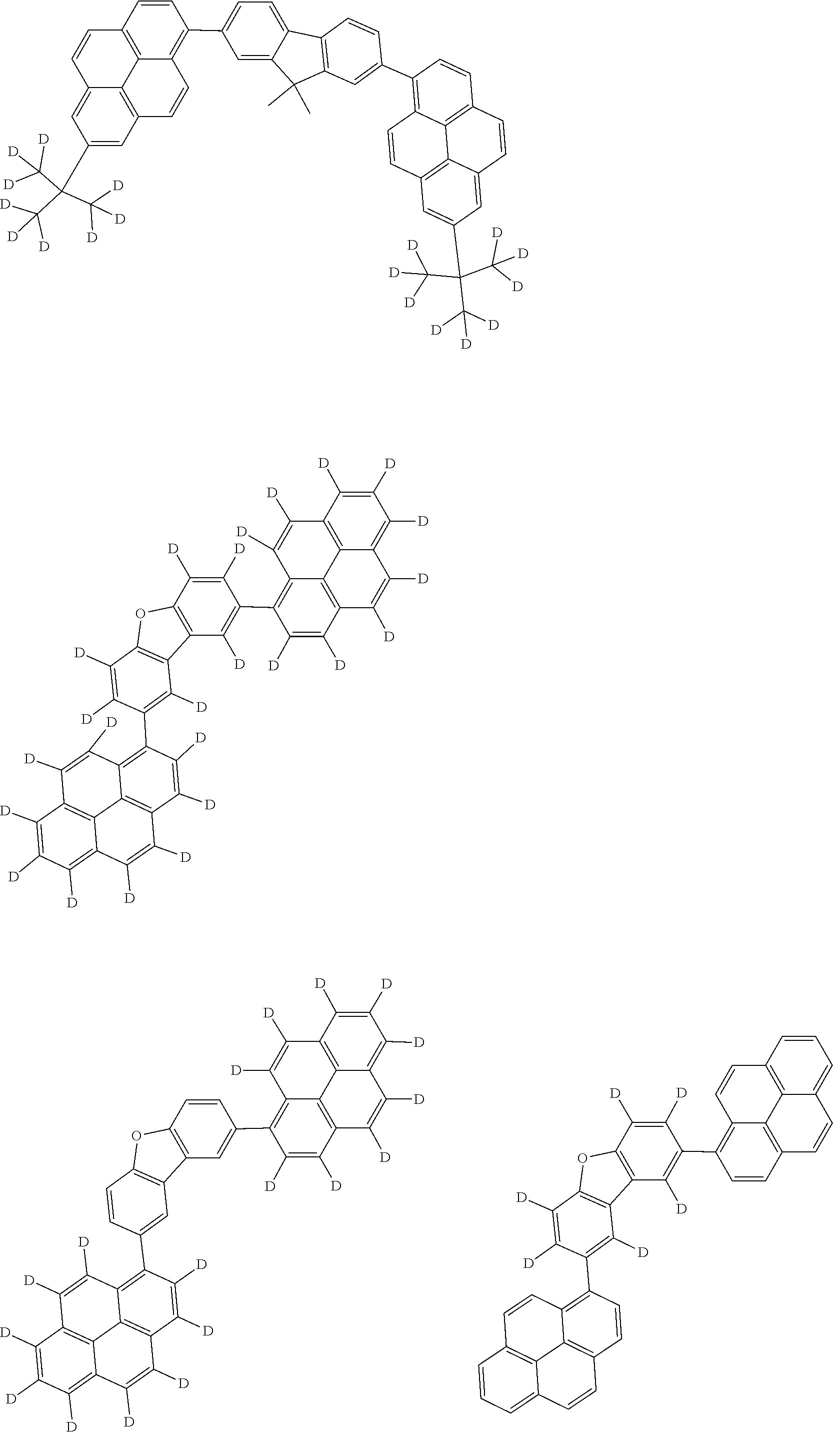

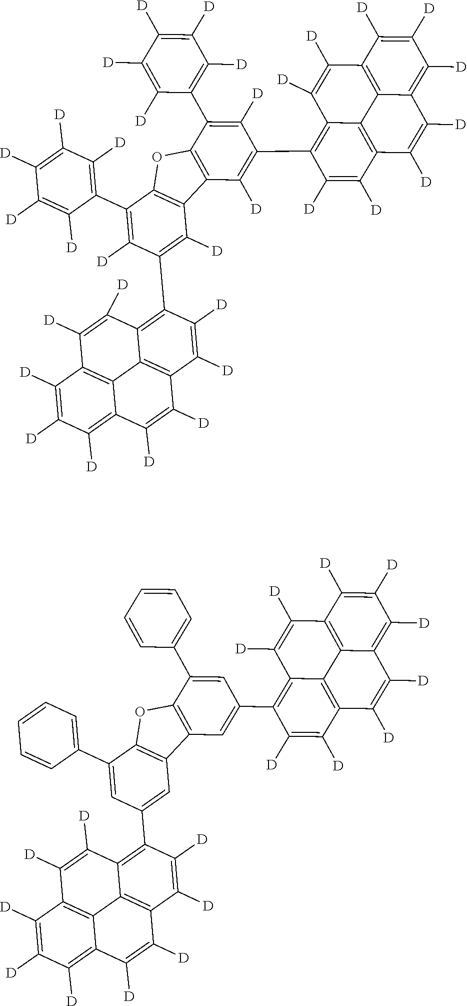 [SMILES: [2H]c1c([2H])c([2H])c(-c2c([2H])c(-c3c([2H])c([2H])c4c([2H])c([2H])c5c([2H])c([2H])c([2H])c6c([2H])c([2H])c3c4c56)c([2H])c3c2oc2c(-c4c([2H])c([2H])c([2H])c([2H])c4[2H])c([2H])c(-c4c([2H])c([2H])c5c([2H])c([2H])c6c([2H])c([2H])c([2H])c7c([2H])c([2H])c4c5c67)c([2H])c23)c([2H])c1[2H] ; [2H]c1c([2H])c2c([2H])c([2H])c3c([2H])c([2H])c(-c4cc(-c5ccccc5)c5oc6c(-c7ccccc7)cc(-c7c([2H])c([2H])c8c([2H])c([2H])c9c([2H])c([2H])c([2H])c%10c([2H])c([2H])c7c8c9%10)cc6c5c4)c4c([2H])c([2H])c(c1[2H])c2c34]

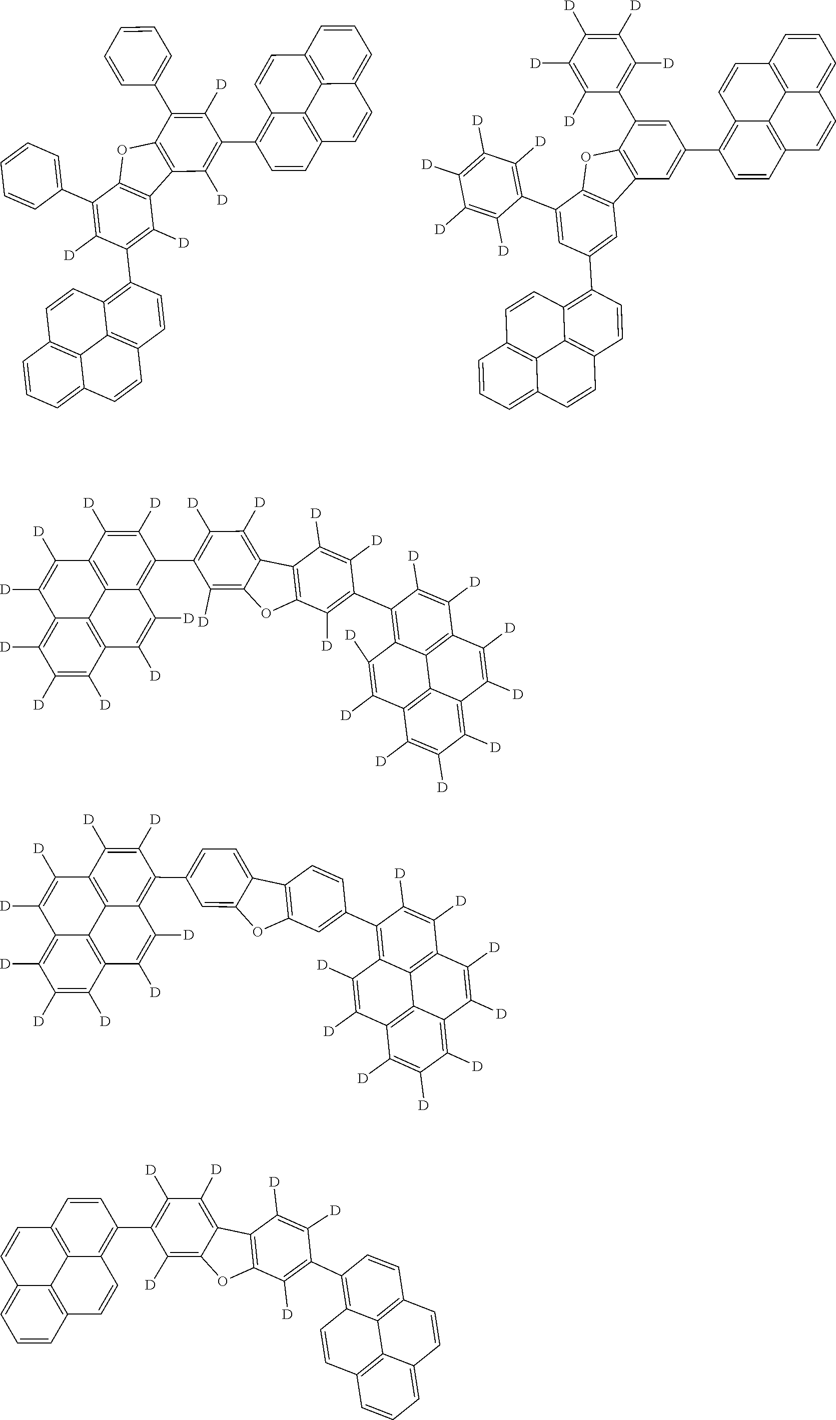

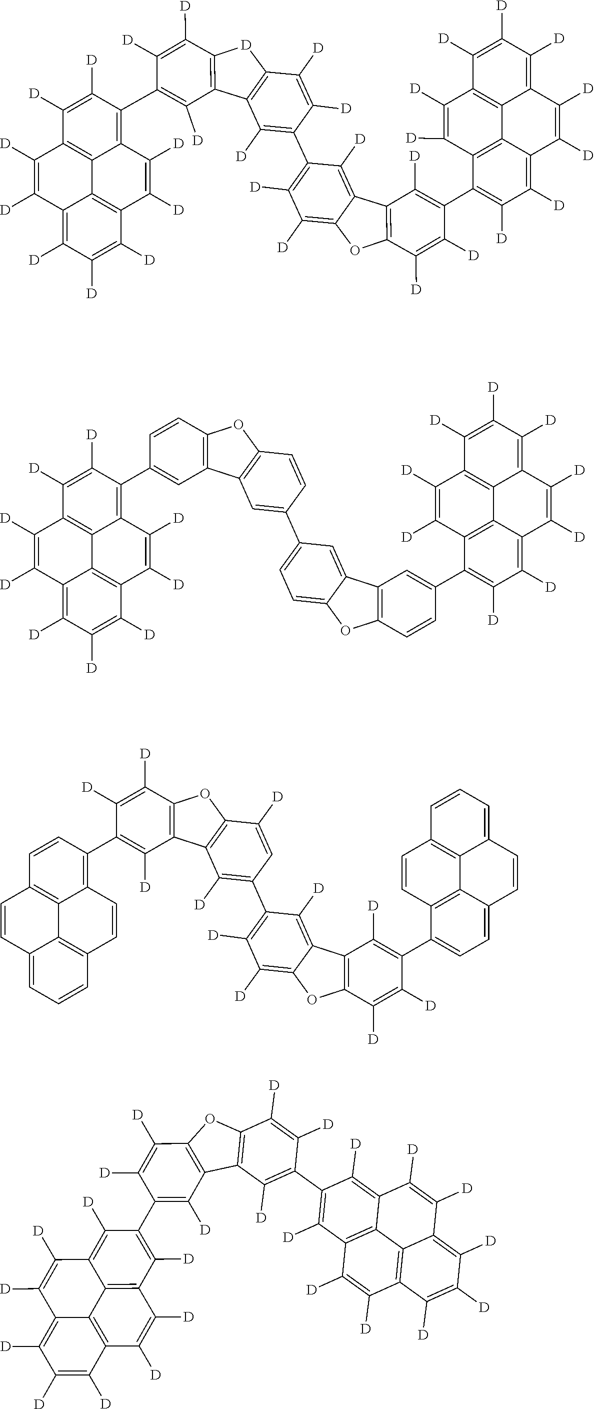

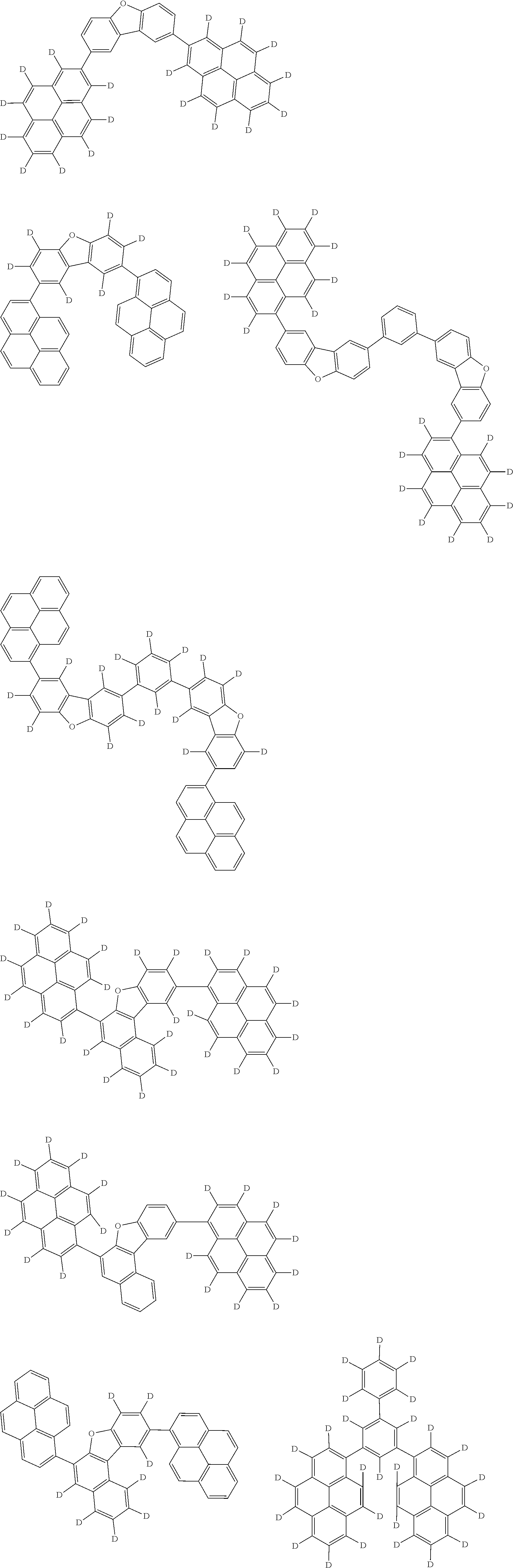

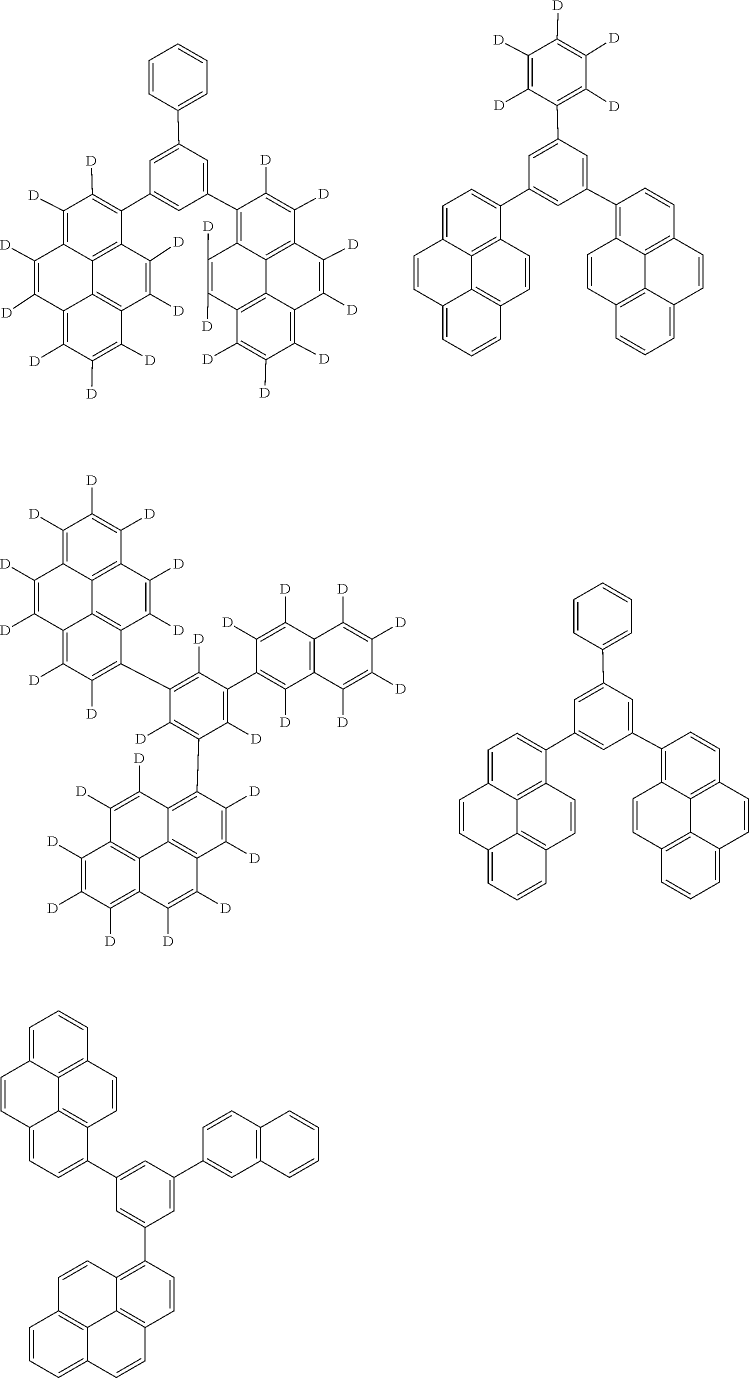

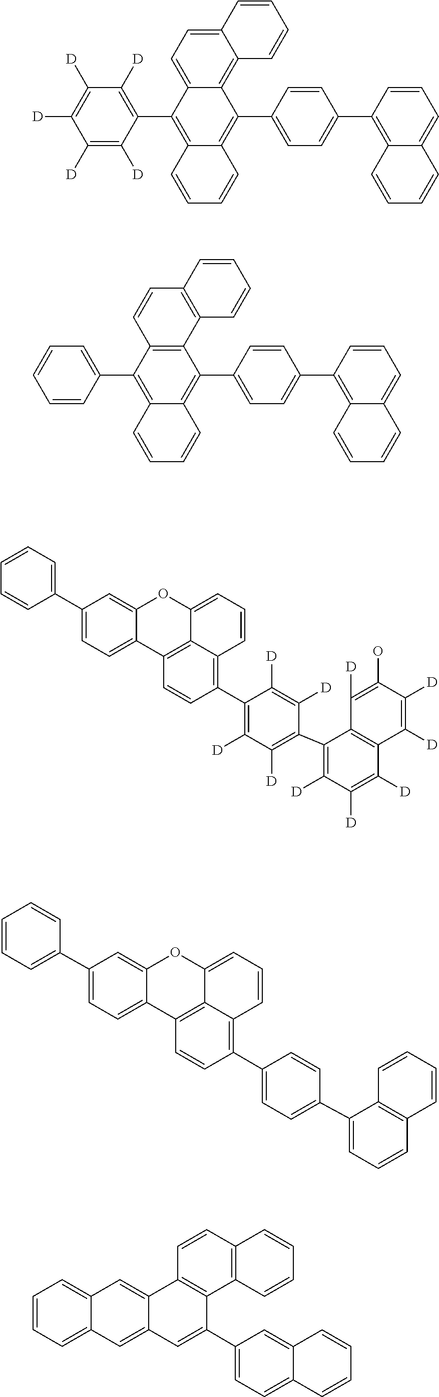

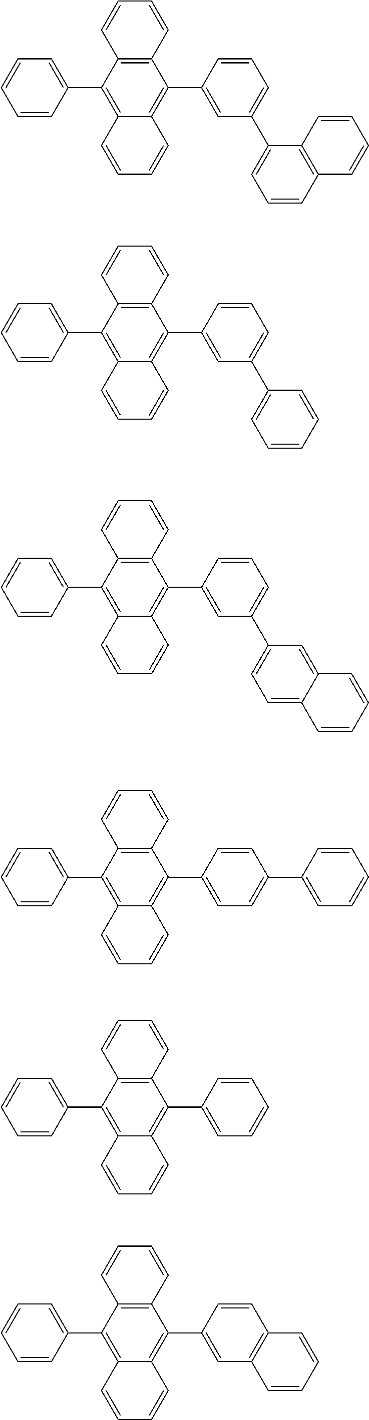

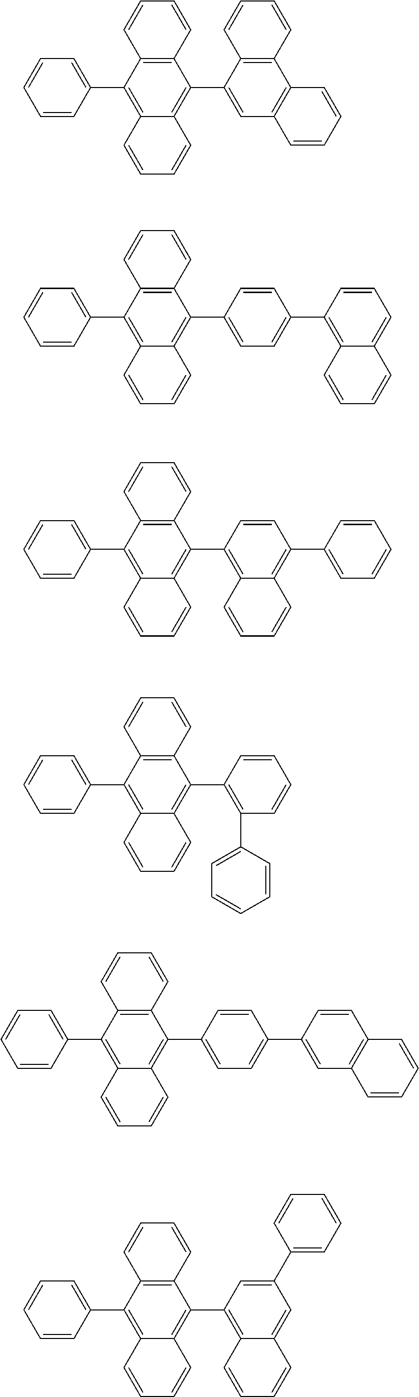

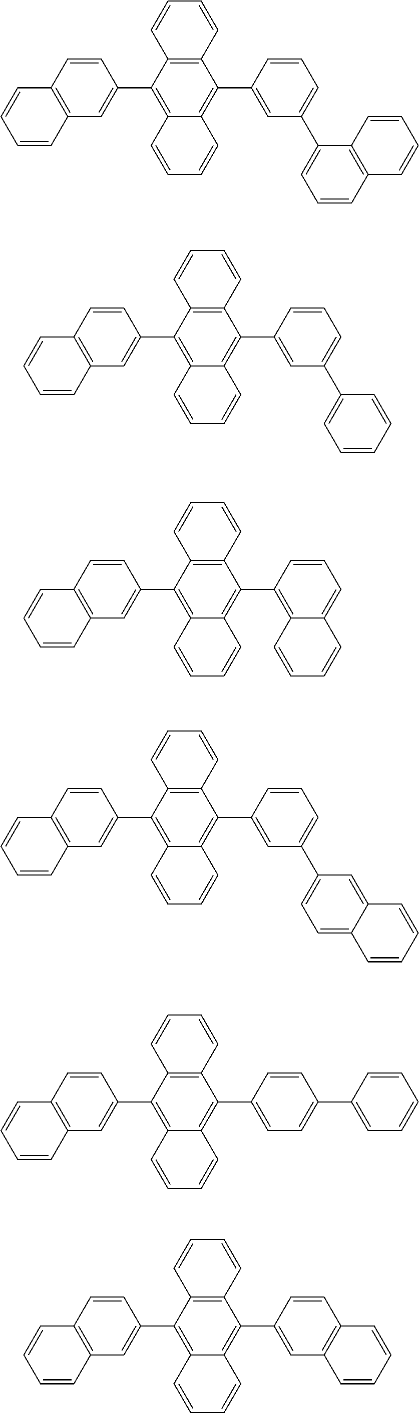

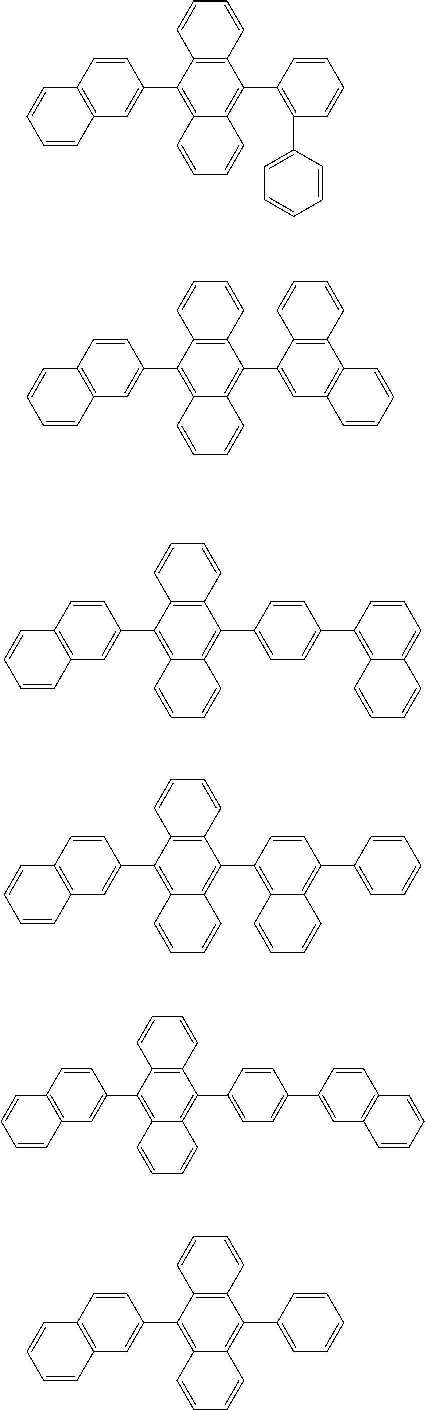

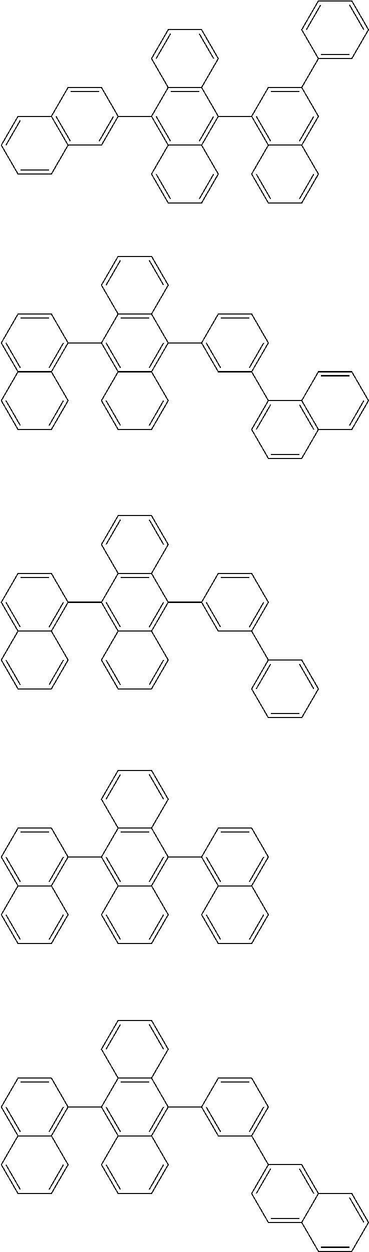

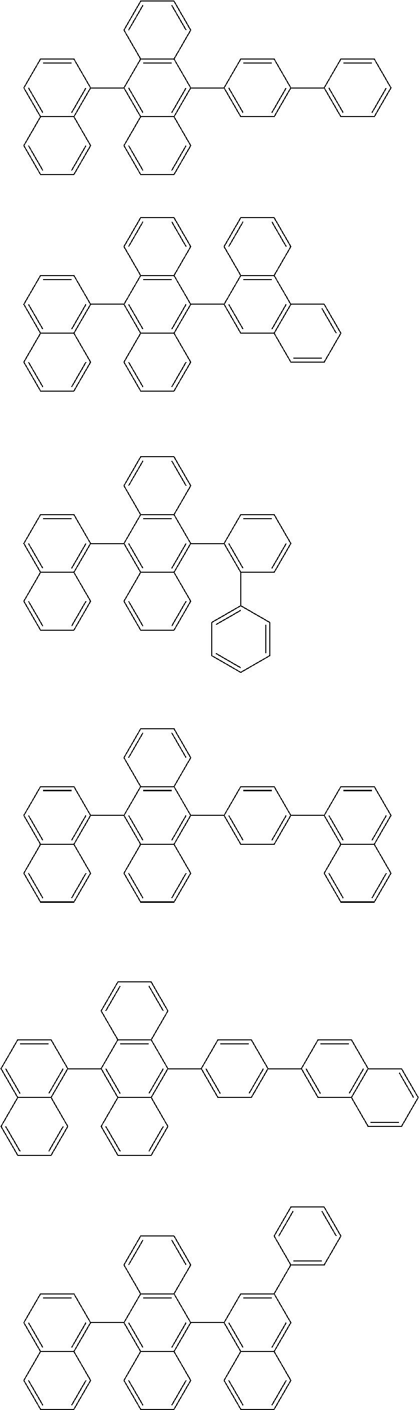

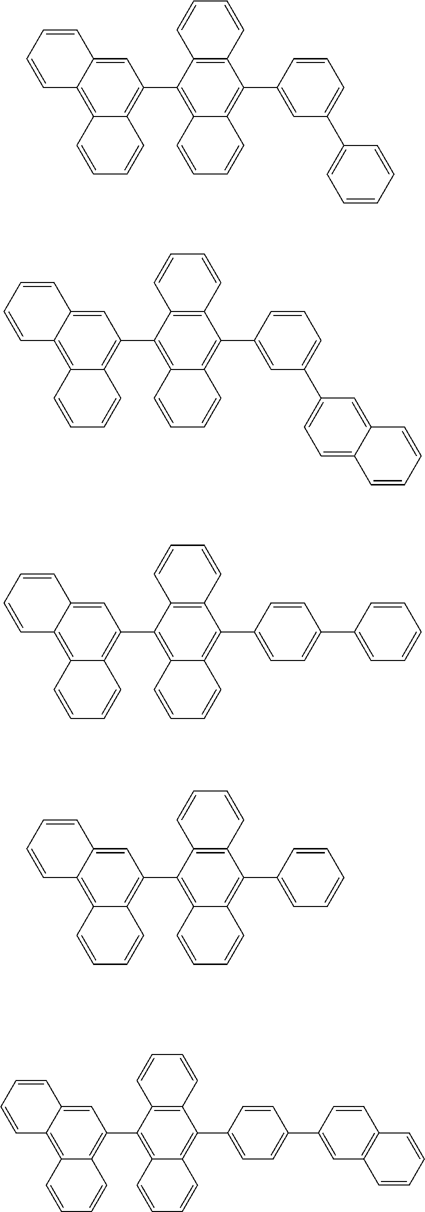

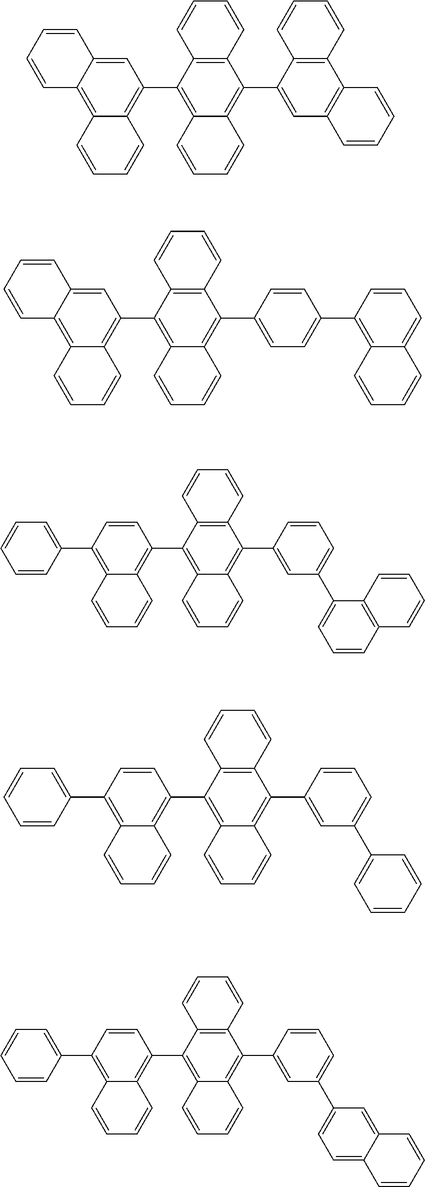

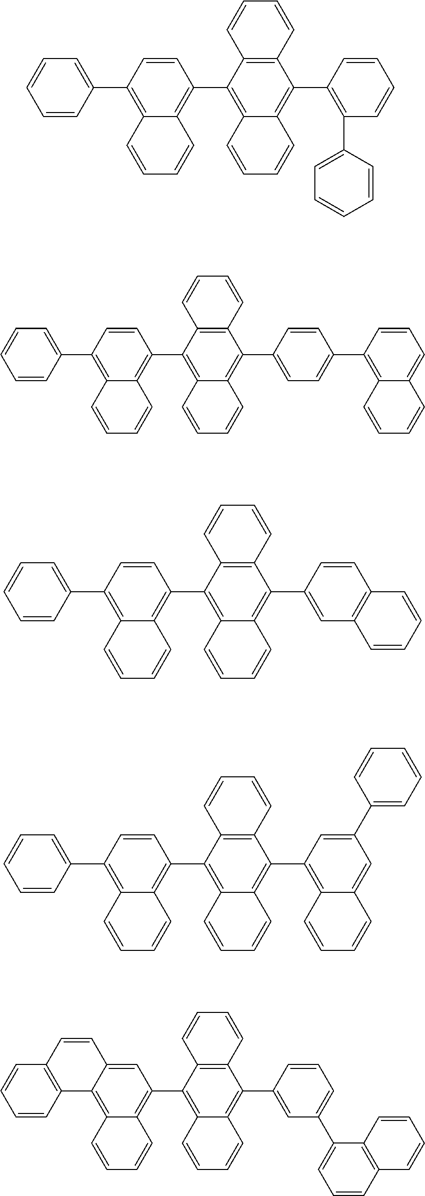

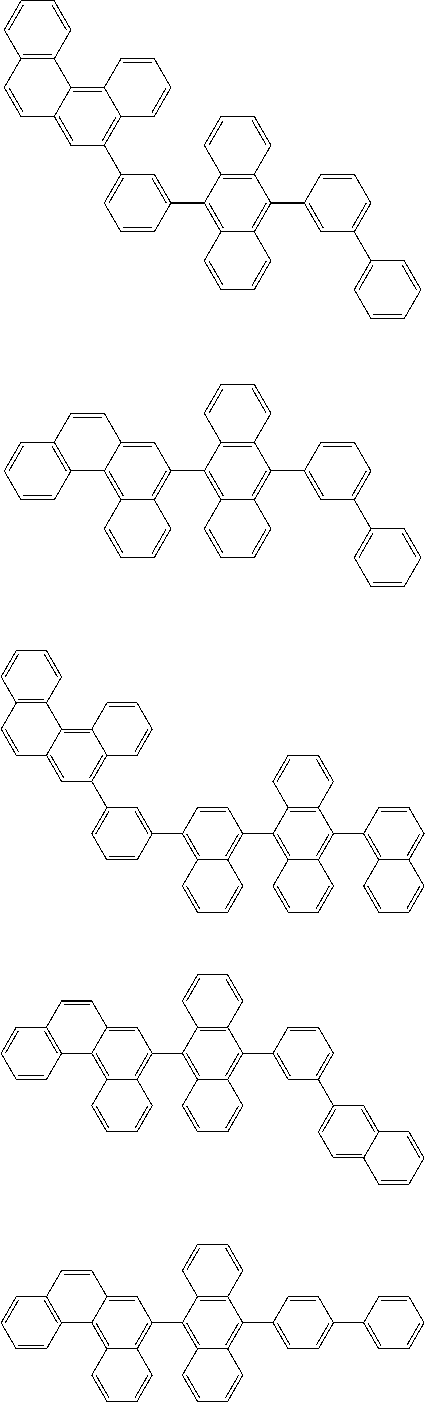

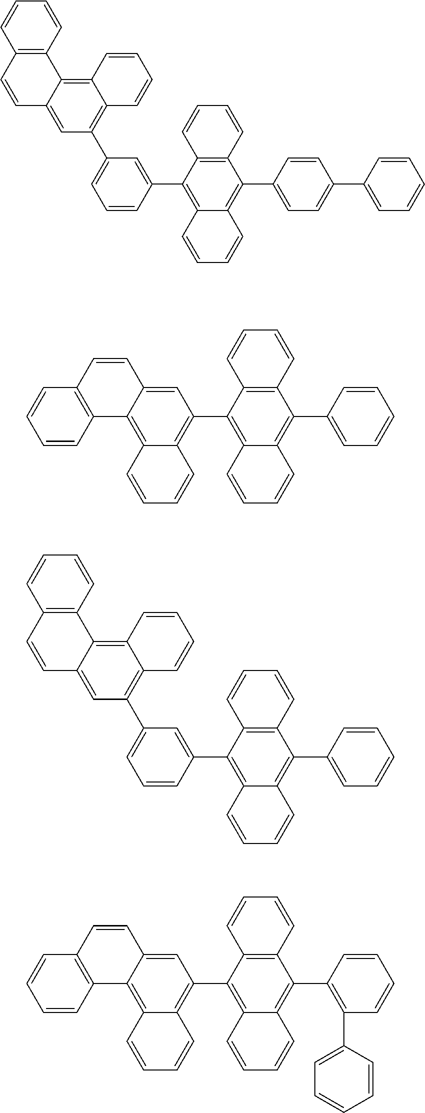

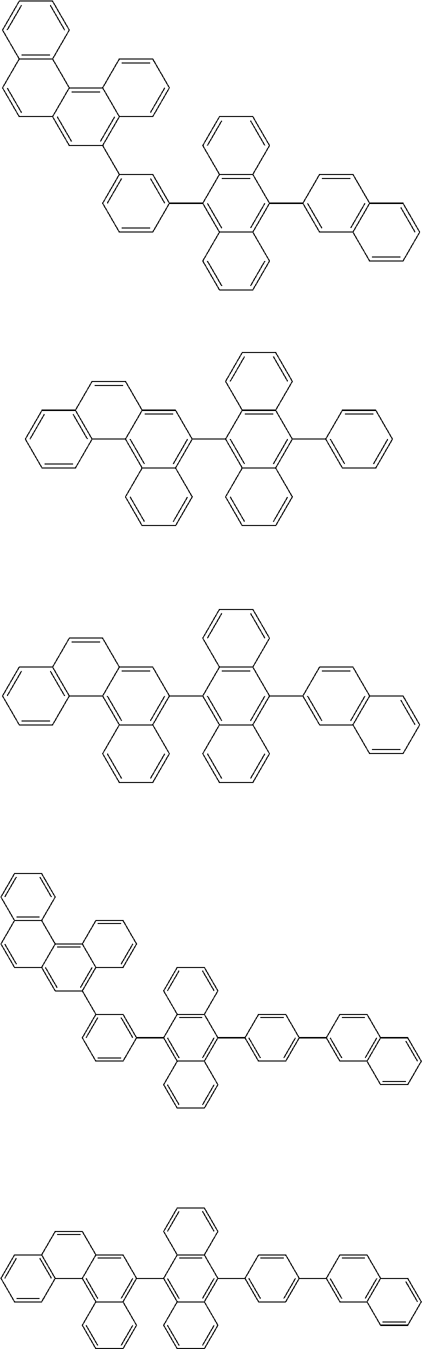

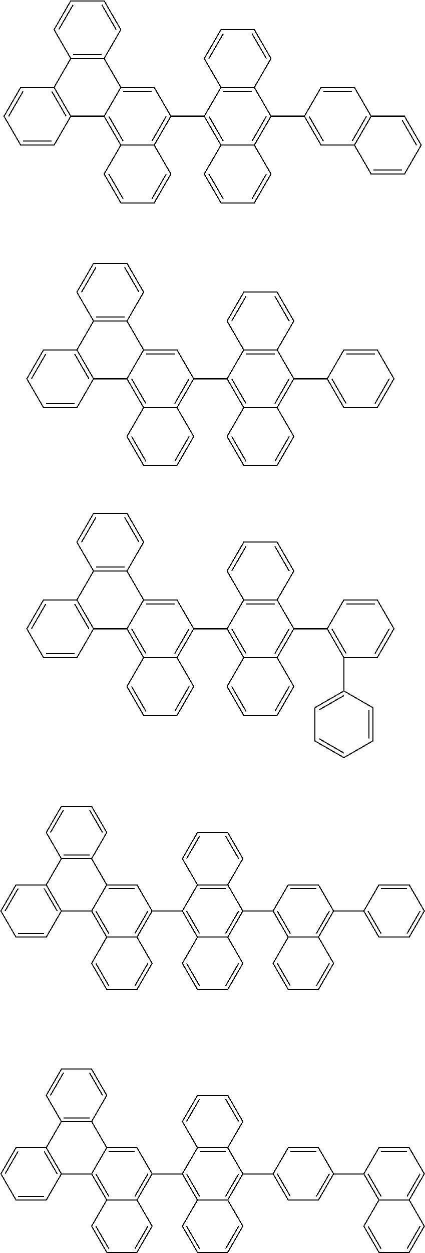

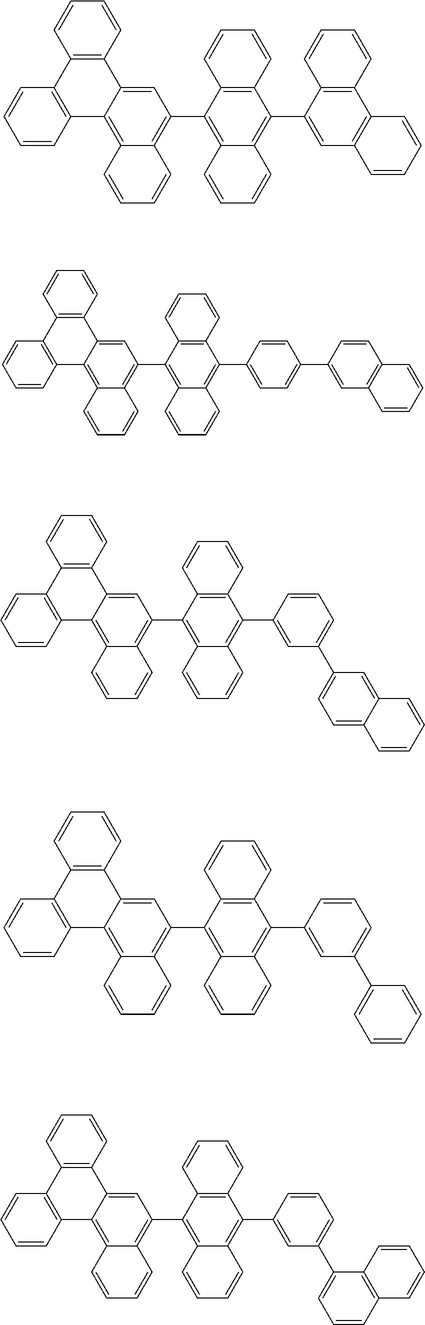

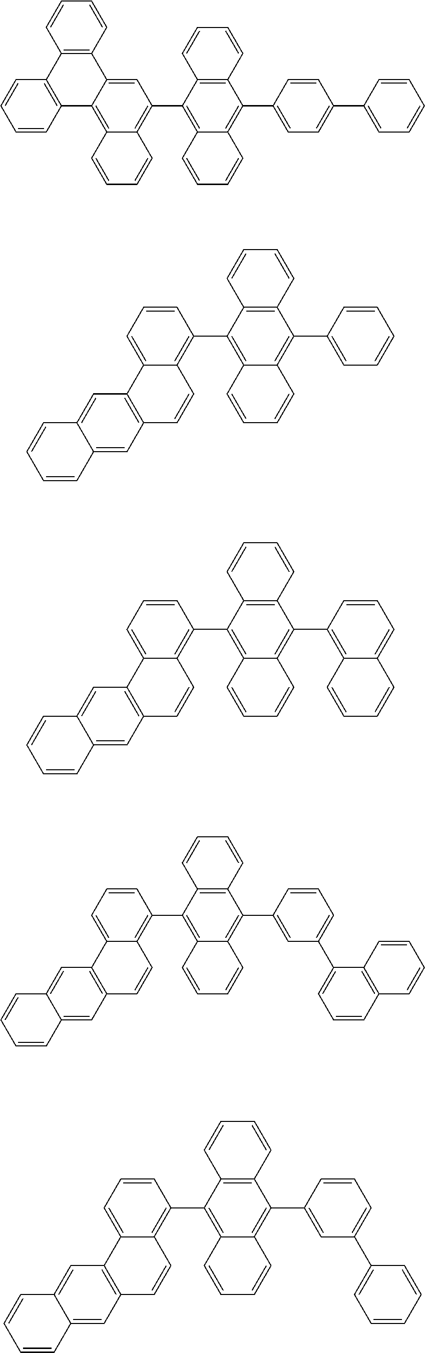

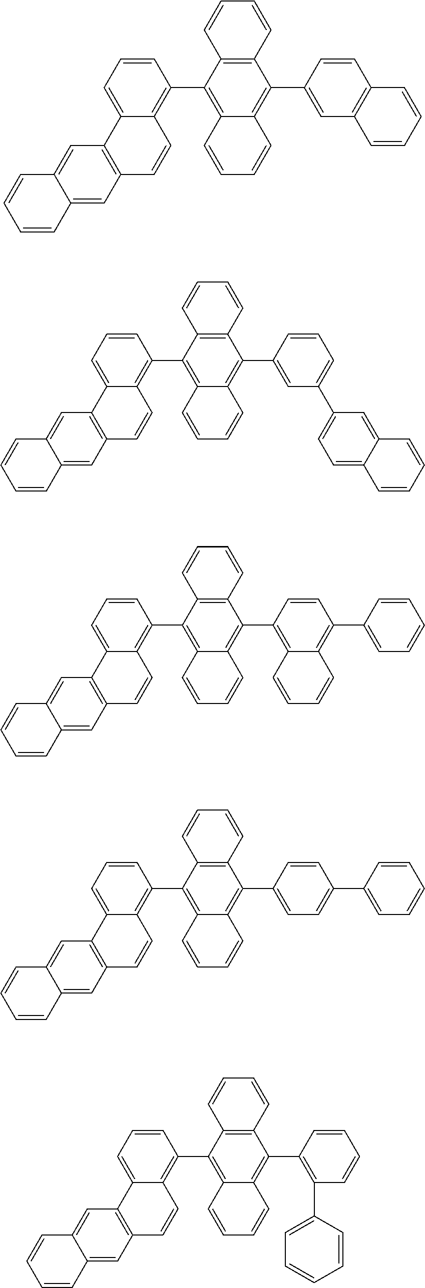

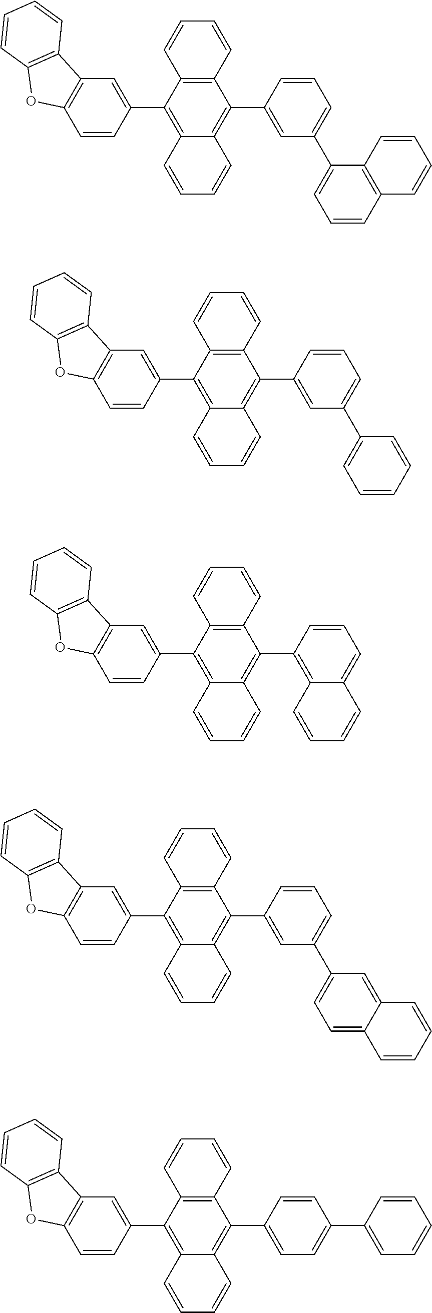 [SMILES: c1cc(-c2cccc3ccccc23)cc(-c2c3ccccc3c(-c3ccc4oc5ccccc5c4c3)c3ccccc23)c1 ; c1ccc(-c2cccc(-c3c4ccccc4c(-c4ccc5oc6ccccc6c5c4)c4ccccc34)c2)cc1 ; c1ccc2c(-c3c4ccccc4c(-c4ccc5oc6ccccc6c5c4)c4ccccc34)cccc2c1 ; c1cc(-c2ccc3ccccc3c2)cc(-c2c3ccccc3c(-c3ccc4oc5ccccc5c4c3)c3ccccc23)c1 ; c1ccc(-c2ccc(-c3c4ccccc4c(-c4ccc5oc6ccccc6c5c4)c4ccccc34)cc2)cc1]

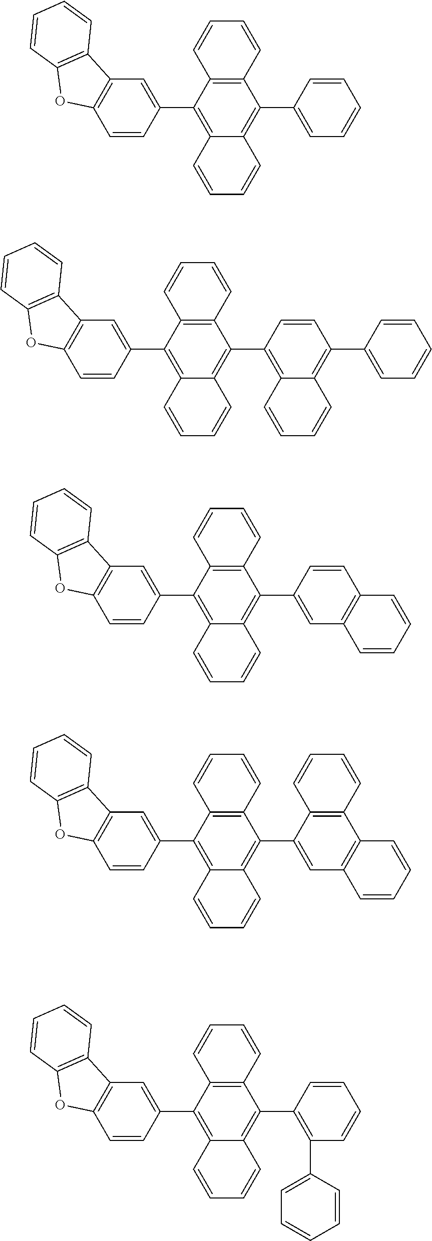 [SMILES: c1ccc(-c2c3ccccc3c(-c3ccc4oc5ccccc5c4c3)c3ccccc23)cc1 ; c1ccc(-c2ccc(-c3c4ccccc4c(-c4ccc5oc6ccccc6c5c4)c4ccccc34)c3ccccc23)cc1 ; c1ccc2cc(-c3c4ccccc4c(-c4ccc5oc6ccccc6c5c4)c4ccccc34)ccc2c1 ; c1ccc2c(c1)cc(-c1c3ccccc3c(-c3ccc4oc5ccccc5c4c3)c3ccccc13)c1ccccc12 ; c1ccc(-c2ccccc2-c2c3ccccc3c(-c3ccc4oc5ccccc5c4c3)c3ccccc23)cc1]

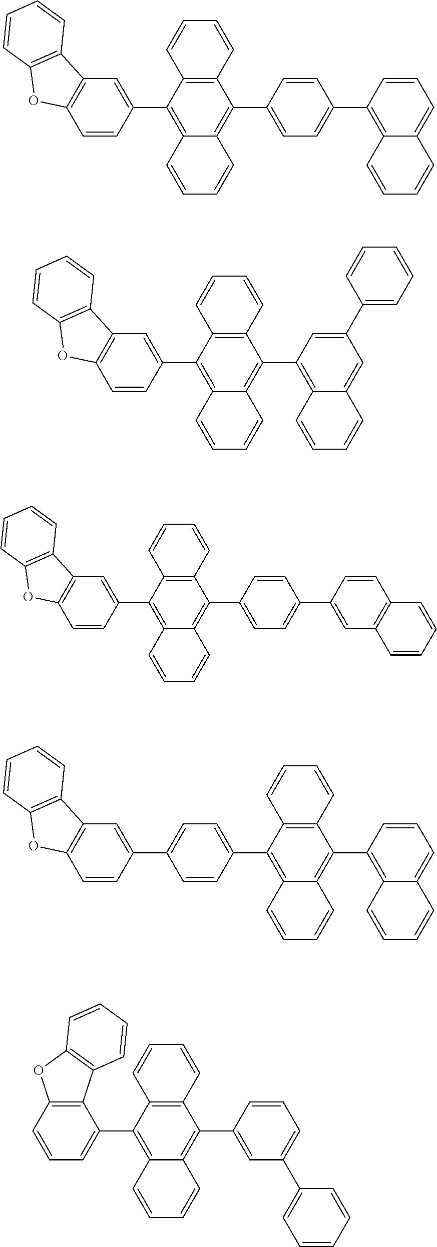 [SMILES: c1ccc2c(-c3ccc(-c4c5ccccc5c(-c5ccc6oc7ccccc7c6c5)c5ccccc45)cc3)cccc2c1 ; c1ccc(-c2cc(-c3c4ccccc4c(-c4ccc5oc6ccccc6c5c4)c4ccccc34)c3ccccc3c2)cc1 ; c1ccc2cc(-c3ccc(-c4c5ccccc5c(-c5ccc6oc7ccccc7c6c5)c5ccccc45)cc3)ccc2c1 ; c1ccc2c(-c3c4ccccc4c(-c4ccc(-c5ccc6oc7ccccc7c6c5)cc4)c4ccccc34)cccc2c1 ; c1ccc(-c2cccc(-c3c4ccccc4c(-c4cccc5oc6ccccc6c45)c4ccccc34)c2)cc1]

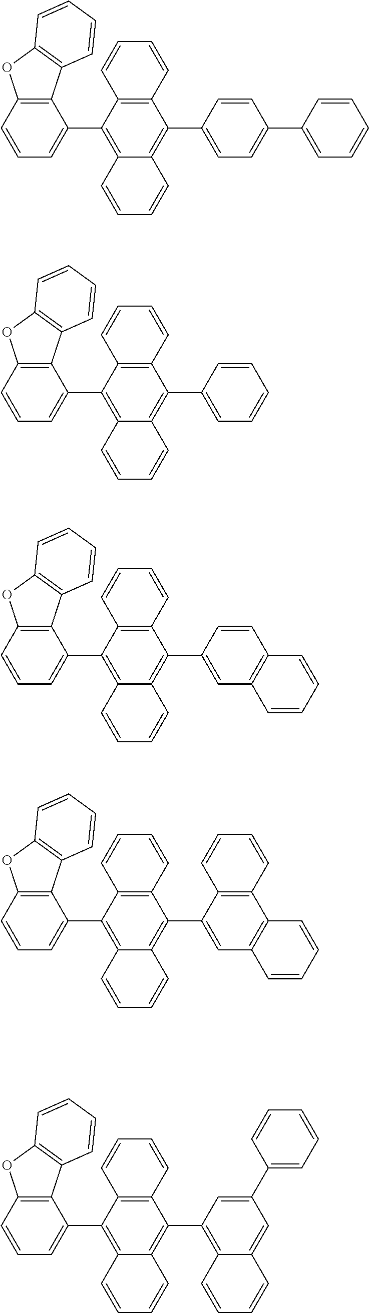 [SMILES: c1ccc(-c2ccc(-c3c4ccccc4c(-c4cccc5oc6ccccc6c45)c4ccccc34)cc2)cc1 ; c1ccc(-c2c3ccccc3c(-c3cccc4oc5ccccc5c34)c3ccccc23)cc1 ; c1ccc2cc(-c3c4ccccc4c(-c4cccc5oc6ccccc6c45)c4ccccc34)ccc2c1 ; c1ccc2c(c1)cc(-c1c3ccccc3c(-c3cccc4oc5ccccc5c34)c3ccccc13)c1ccccc12 ; c1ccc(-c2cc(-c3c4ccccc4c(-c4cccc5oc6ccccc6c45)c4ccccc34)c3ccccc3c2)cc1]

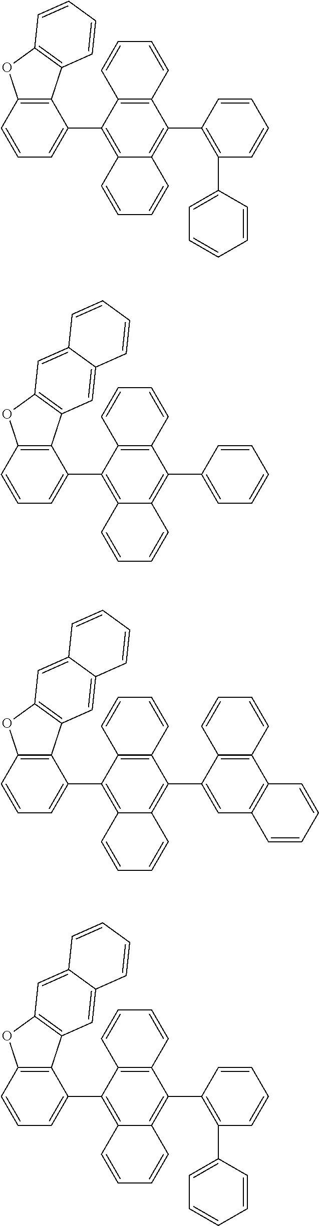 [SMILES: c1ccc(-c2ccccc2-c2c3ccccc3c(-c3cccc4oc5ccccc5c34)c3ccccc23)cc1 ; c1ccc(-c2c3ccccc3c(-c3cccc4oc5cc6ccccc6cc5c34)c3ccccc23)cc1 ; c1ccc2cc3c(cc2c1)oc1cccc(-c2c4ccccc4c(-c4cc5ccccc5c5ccccc45)c4ccccc24)c13 ; c1ccc(-c2ccccc2-c2c3ccccc3c(-c3cccc4oc5cc6ccccc6cc5c34)c3ccccc23)cc1]

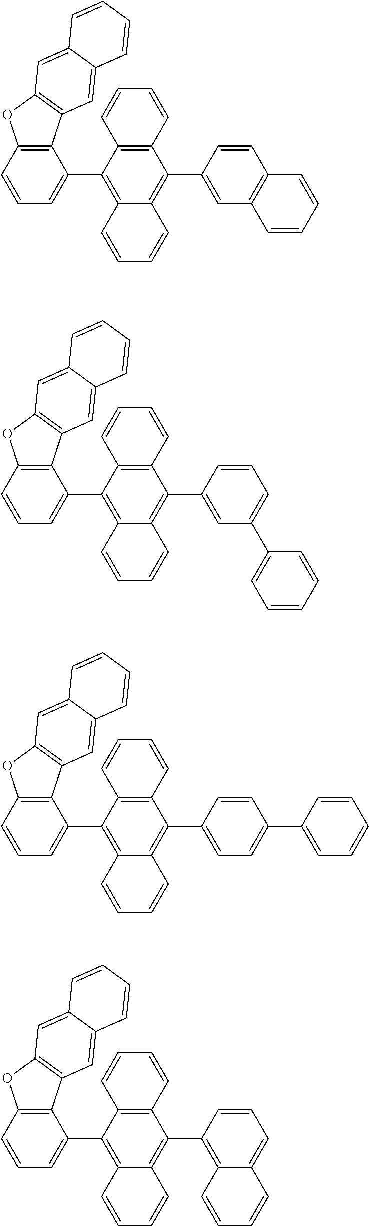 [SMILES: c1ccc2cc(-c3c4ccccc4c(-c4cccc5oc6cc7ccccc7cc6c45)c4ccccc34)ccc2c1 ; c1ccc(-c2cccc(-c3c4ccccc4c(-c4cccc5oc6cc7ccccc7cc6c45)c4ccccc34)c2)cc1 ; c1ccc(-c2ccc(-c3c4ccccc4c(-c4cccc5oc6cc7ccccc7cc6c45)c4ccccc34)cc2)cc1 ; c1ccc2cc3c(cc2c1)oc1cccc(-c2c4ccccc4c(-c4cccc5ccccc45)c4ccccc24)c13]

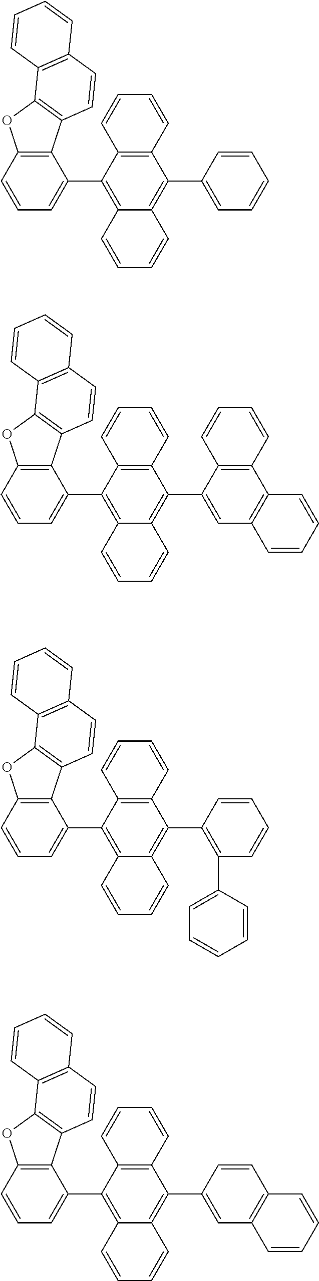 [SMILES: c1ccc(-c2c3ccccc3c(-c3cccc4oc5c6ccccc6ccc5c34)c3ccccc23)cc1 ; c1ccc2c(c1)cc(-c1c3ccccc3c(-c3cccc4oc5c6ccccc6ccc5c34)c3ccccc13)c1ccccc12 ; c1ccc(-c2ccccc2-c2c3ccccc3c(-c3cccc4oc5c6ccccc6ccc5c34)c3ccccc23)cc1 ; c1ccc2cc(-c3c4ccccc4c(-c4cccc5oc6c7ccccc7ccc6c45)c4ccccc34)ccc2c1]

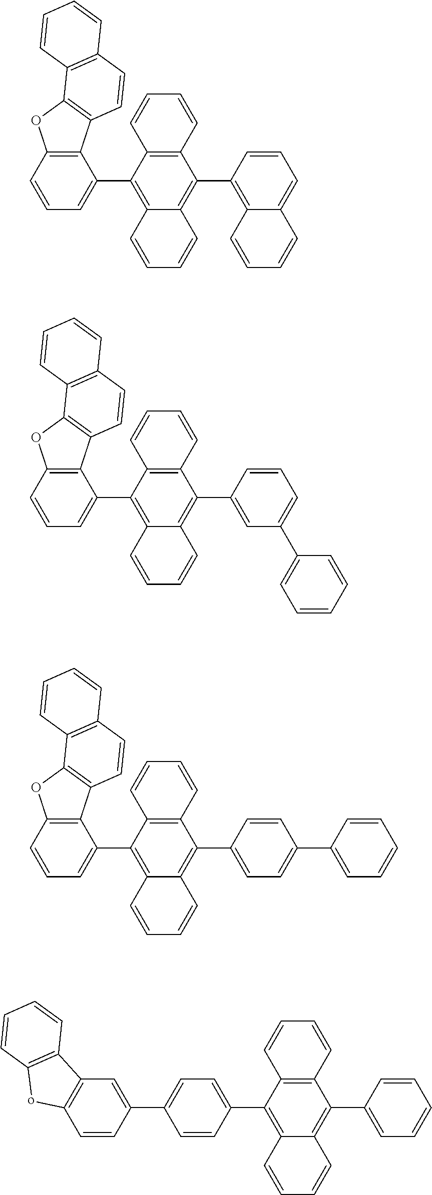

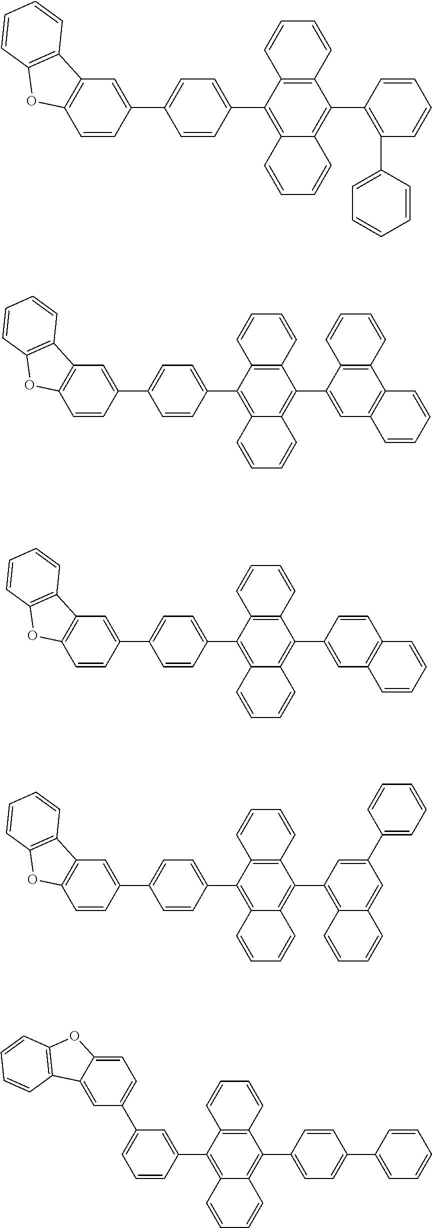 [SMILES: c1ccc(-c2ccccc2-c2c3ccccc3c(-c3ccc(-c4ccc5oc6ccccc6c5c4)cc3)c3ccccc23)cc1 ; c1ccc2c(c1)cc(-c1c3ccccc3c(-c3ccc(-c4ccc5oc6ccccc6c5c4)cc3)c3ccccc13)c1ccccc12 ; c1ccc2cc(-c3c4ccccc4c(-c4ccc(-c5ccc6oc7ccccc7c6c5)cc4)c4ccccc34)ccc2c1 ; c1ccc(-c2cc(-c3c4ccccc4c(-c4ccc(-c5ccc6oc7ccccc7c6c5)cc4)c4ccccc34)c3ccccc3c2)cc1 ; c1ccc(-c2ccc(-c3c4ccccc4c(-c4cccc(-c5ccc6oc7ccccc7c6c5)c4)c4ccccc34)cc2)cc1]

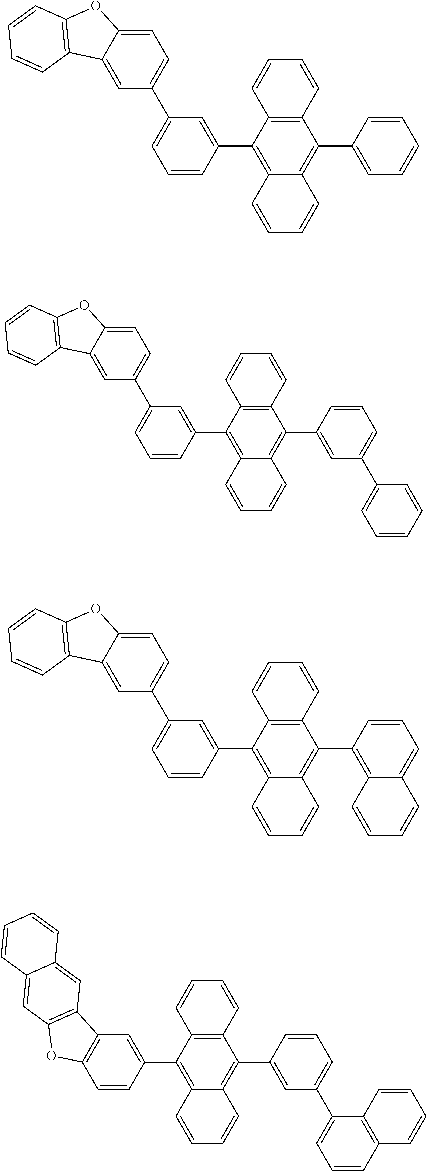 [SMILES: c1ccc(-c2c3ccccc3c(-c3cccc(-c4ccc5oc6ccccc6c5c4)c3)c3ccccc23)cc1 ; c1ccc(-c2cccc(-c3c4ccccc4c(-c4cccc(-c5ccc6oc7ccccc7c6c5)c4)c4ccccc34)c2)cc1 ; c1cc(-c2ccc3oc4ccccc4c3c2)cc(-c2c3ccccc3c(-c3cccc4ccccc34)c3ccccc23)c1 ; c1cc(-c2cccc3ccccc23)cc(-c2c3ccccc3c(-c3ccc4oc5cc6ccccc6cc5c4c3)c3ccccc23)c1]

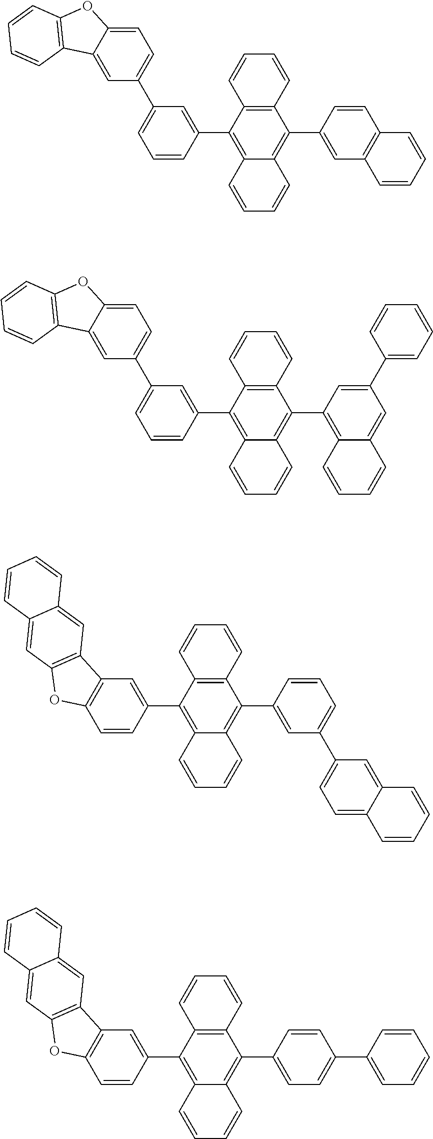 [SMILES: c1cc(-c2ccc3oc4ccccc4c3c2)cc(-c2c3ccccc3c(-c3ccc4ccccc4c3)c3ccccc23)c1 ; c1ccc(-c2cc(-c3c4ccccc4c(-c4cccc(-c5ccc6oc7ccccc7c6c5)c4)c4ccccc34)c3ccccc3c2)cc1 ; c1cc(-c2ccc3ccccc3c2)cc(-c2c3ccccc3c(-c3ccc4oc5cc6ccccc6cc5c4c3)c3ccccc23)c1 ; c1ccc(-c2ccc(-c3c4ccccc4c(-c4ccc5oc6cc7ccccc7cc6c5c4)c4ccccc34)cc2)cc1]

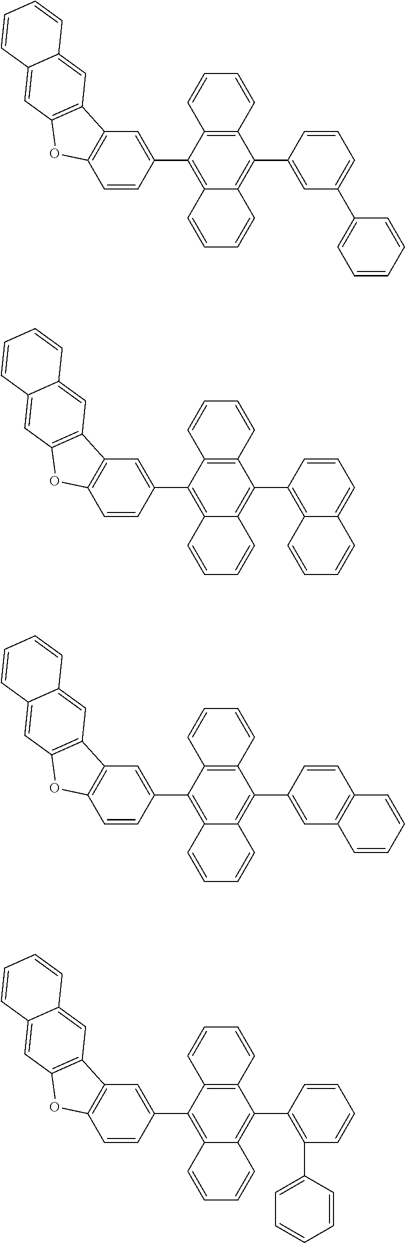 [SMILES: c1ccc(-c2cccc(-c3c4ccccc4c(-c4ccc5oc6cc7ccccc7cc6c5c4)c4ccccc34)c2)cc1 ; c1ccc2cc3c(cc2c1)oc1ccc(-c2c4ccccc4c(-c4cccc5ccccc45)c4ccccc24)cc13 ; c1ccc2cc(-c3c4ccccc4c(-c4ccc5oc6cc7ccccc7cc6c5c4)c4ccccc34)ccc2c1 ; c1ccc(-c2ccccc2-c2c3ccccc3c(-c3ccc4oc5cc6ccccc6cc5c4c3)c3ccccc23)cc1]

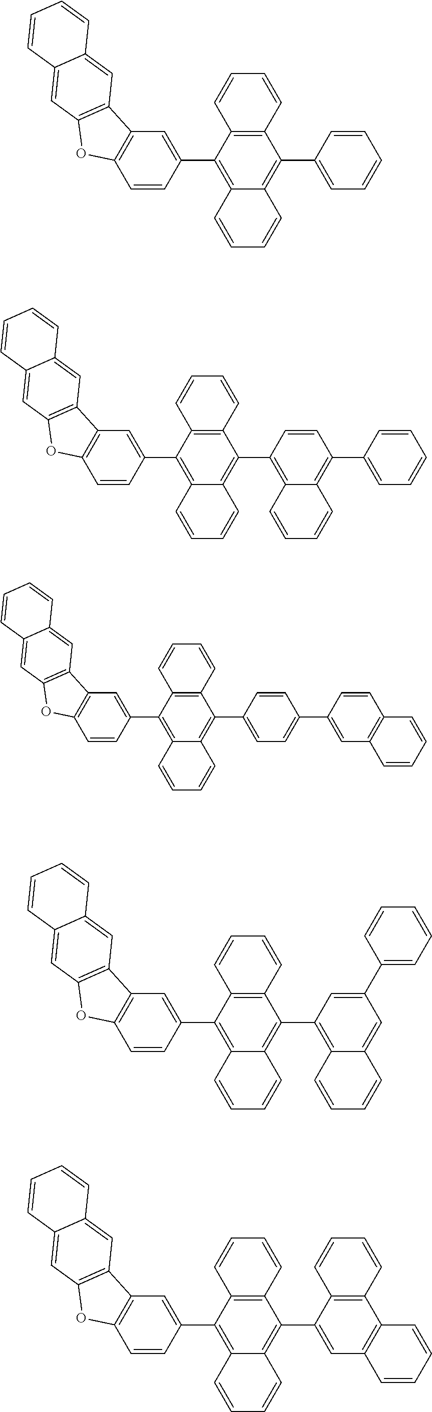 [SMILES: c1ccc(-c2c3ccccc3c(-c3ccc4oc5cc6ccccc6cc5c4c3)c3ccccc23)cc1 ; c1ccc(-c2ccc(-c3c4ccccc4c(-c4ccc5oc6cc7ccccc7cc6c5c4)c4ccccc34)c3ccccc23)cc1 ; c1ccc2cc(-c3ccc(-c4c5ccccc5c(-c5ccc6oc7cc8ccccc8cc7c6c5)c5ccccc45)cc3)ccc2c1 ; c1ccc(-c2cc(-c3c4ccccc4c(-c4ccc5oc6cc7ccccc7cc6c5c4)c4ccccc34)c3ccccc3c2)cc1 ; c1ccc2cc3c(cc2c1)oc1ccc(-c2c4ccccc4c(-c4cc5ccccc5c5ccccc45)c4ccccc24)cc13]

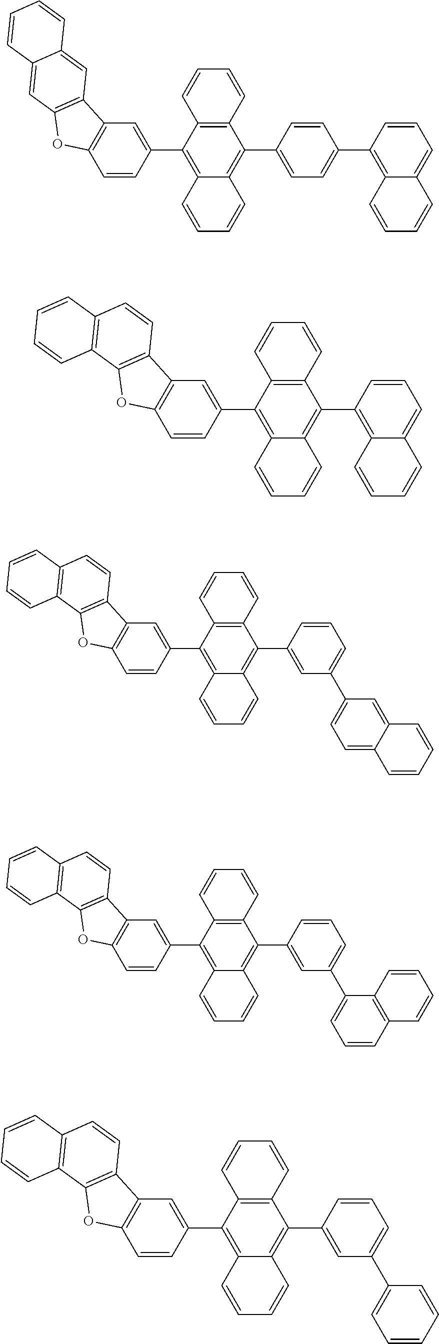 [SMILES: c1ccc2cc3c(cc2c1)oc1ccc(-c2c4ccccc4c(-c4ccc(-c5cccc6ccccc56)cc4)c4ccccc24)cc13 ; c1ccc2c(-c3c4ccccc4c(-c4ccc5oc6c7ccccc7ccc6c5c4)c4ccccc34)cccc2c1 ; c1cc(-c2ccc3ccccc3c2)cc(-c2c3ccccc3c(-c3ccc4oc5c6ccccc6ccc5c4c3)c3ccccc23)c1 ; c1cc(-c2cccc3ccccc23)cc(-c2c3ccccc3c(-c3ccc4oc5c6ccccc6ccc5c4c3)c3ccccc23)c1 ; c1ccc(-c2cccc(-c3c4ccccc4c(-c4ccc5oc6c7ccccc7ccc6c5c4)c4ccccc34)c2)cc1]

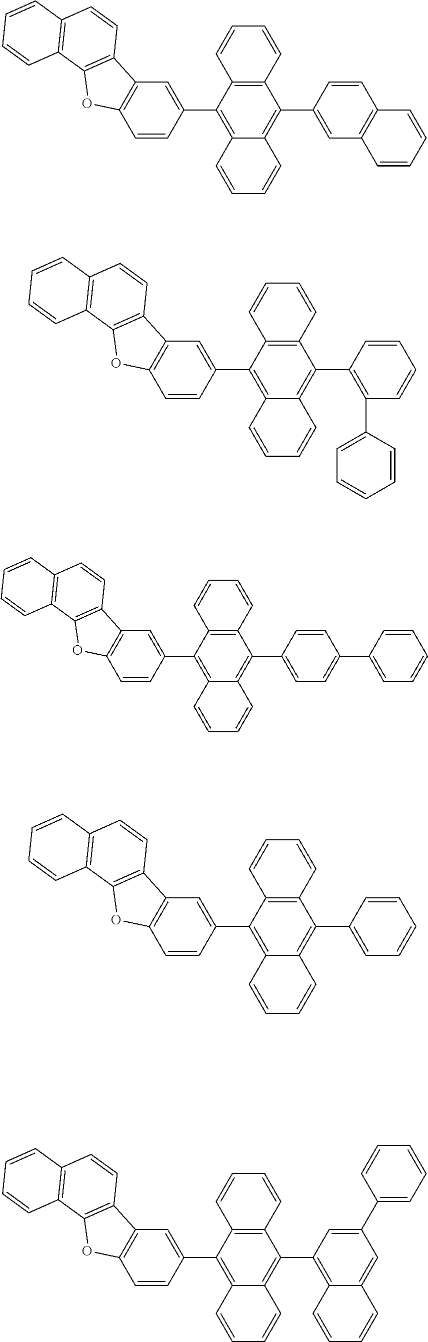 [SMILES: c1ccc2cc(-c3c4ccccc4c(-c4ccc5oc6c7ccccc7ccc6c5c4)c4ccccc34)ccc2c1 ; c1ccc(-c2ccccc2-c2c3ccccc3c(-c3ccc4oc5c6ccccc6ccc5c4c3)c3ccccc23)cc1 ; c1ccc(-c2ccc(-c3c4ccccc4c(-c4ccc5oc6c7ccccc7ccc6c5c4)c4ccccc34)cc2)cc1 ; c1ccc(-c2c3ccccc3c(-c3ccc4oc5c6ccccc6ccc5c4c3)c3ccccc23)cc1 ; c1ccc(-c2cc(-c3c4ccccc4c(-c4ccc5oc6c7ccccc7ccc6c5c4)c4ccccc34)c3ccccc3c2)cc1]

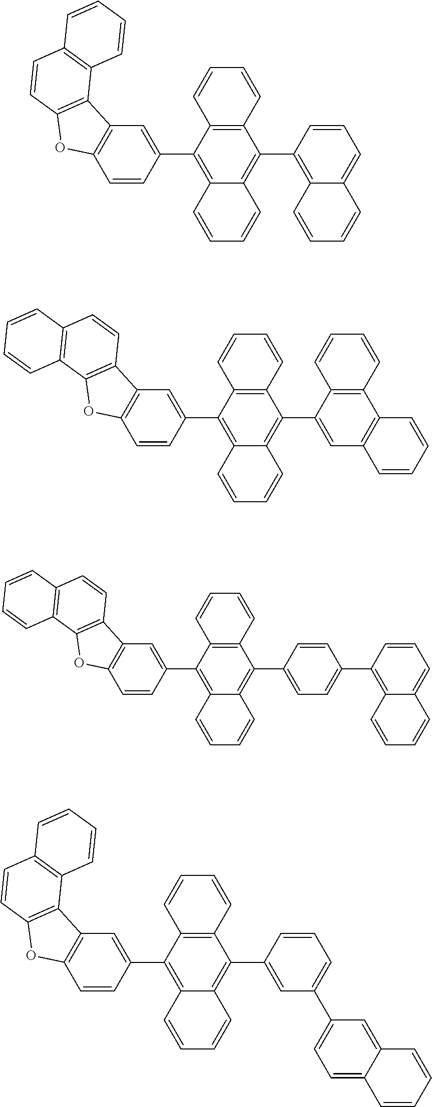 [SMILES: c1ccc2c(-c3c4ccccc4c(-c4ccc5oc6ccc7ccccc7c6c5c4)c4ccccc34)cccc2c1 ; c1ccc2c(c1)cc(-c1c3ccccc3c(-c3ccc4oc5c6ccccc6ccc5c4c3)c3ccccc13)c1ccccc12 ; c1ccc2c(-c3ccc(-c4c5ccccc5c(-c5ccc6oc7c8ccccc8ccc7c6c5)c5ccccc45)cc3)cccc2c1 ; c1cc(-c2ccc3ccccc3c2)cc(-c2c3ccccc3c(-c3ccc4oc5ccc6ccccc6c5c4c3)c3ccccc23)c1]

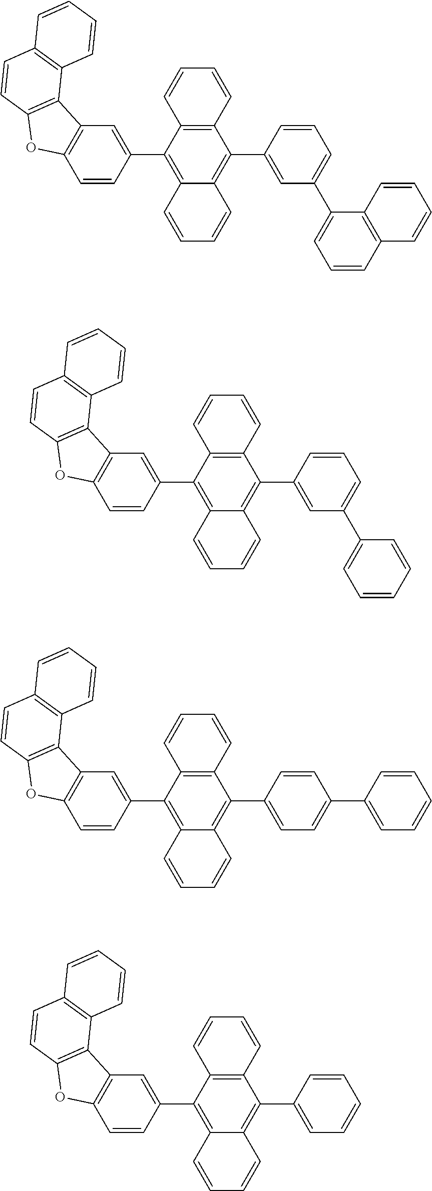 [SMILES: c1cc(-c2cccc3ccccc23)cc(-c2c3ccccc3c(-c3ccc4oc5ccc6ccccc6c5c4c3)c3ccccc23)c1 ; c1ccc(-c2cccc(-c3c4ccccc4c(-c4ccc5oc6ccc7ccccc7c6c5c4)c4ccccc34)c2)cc1 ; c1ccc(-c2ccc(-c3c4ccccc4c(-c4ccc5oc6ccc7ccccc7c6c5c4)c4ccccc34)cc2)cc1 ; c1ccc(-c2c3ccccc3c(-c3ccc4oc5ccc6ccccc6c5c4c3)c3ccccc23)cc1]

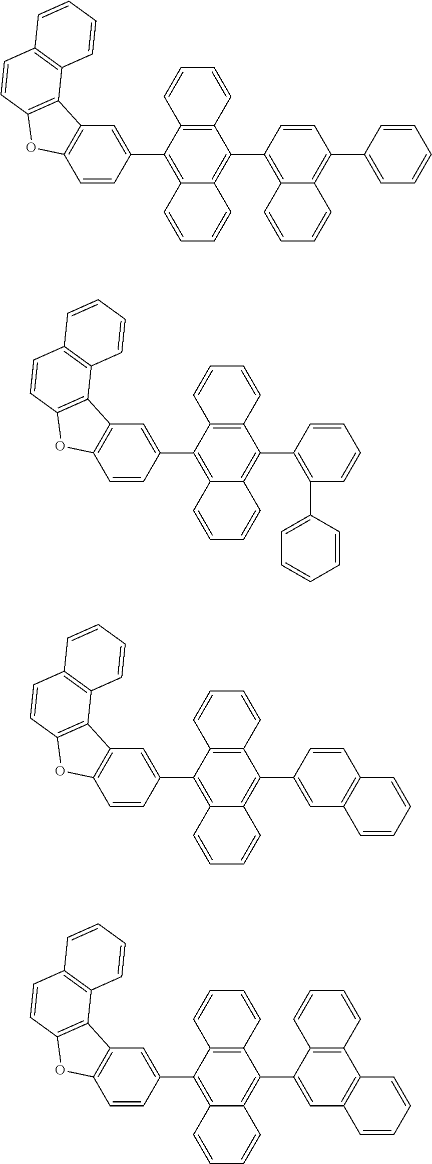 [SMILES: c1ccc(-c2ccc(-c3c4ccccc4c(-c4ccc5oc6ccc7ccccc7c6c5c4)c4ccccc34)c3ccccc23)cc1 ; c1ccc(-c2ccccc2-c2c3ccccc3c(-c3ccc4oc5ccc6ccccc6c5c4c3)c3ccccc23)cc1 ; c1ccc2cc(-c3c4ccccc4c(-c4ccc5oc6ccc7ccccc7c6c5c4)c4ccccc34)ccc2c1 ; c1ccc2c(c1)cc(-c1c3ccccc3c(-c3ccc4oc5ccc6ccccc6c5c4c3)c3ccccc13)c1ccccc12]

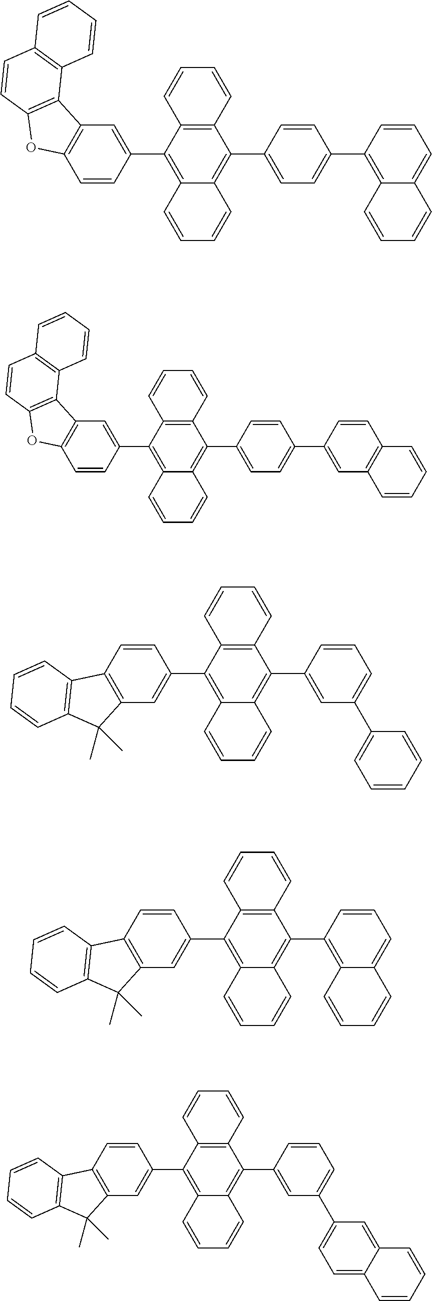

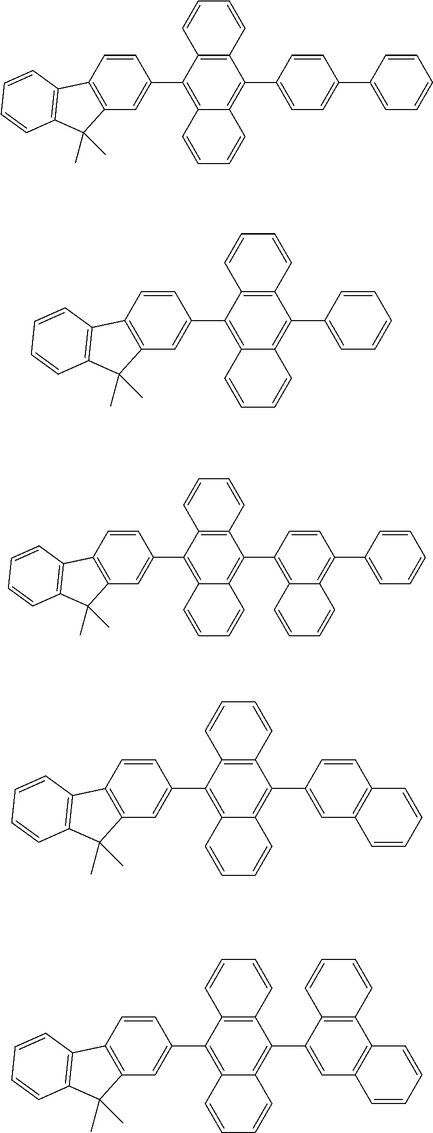

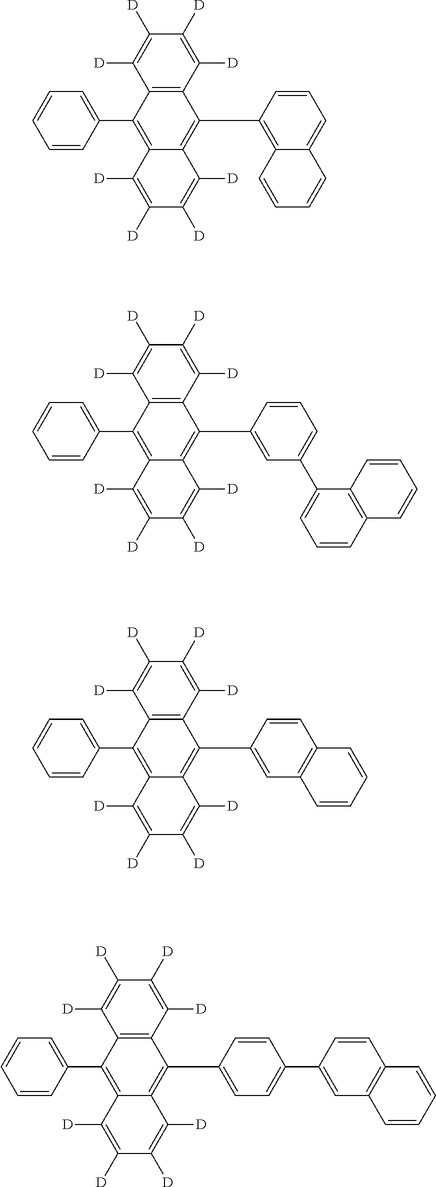 [SMILES: [2H]c1c([2H])c([2H])c2c(-c3cccc4ccccc34)c3c([2H])c([2H])c([2H])c([2H])c3c(-c3ccccc3)c2c1[2H] ; [2H]c1c([2H])c([2H])c2c(-c3cccc(-c4cccc5ccccc45)c3)c3c([2H])c([2H])c([2H])c([2H])c3c(-c3ccccc3)c2c1[2H] ; [2H]c1c([2H])c([2H])c2c(-c3ccc4ccccc4c3)c3c([2H])c([2H])c([2H])c([2H])c3c(-c3ccccc3)c2c1[2H] ; [2H]c1c([2H])c([2H])c2c(-c3ccc(-c4ccc5ccccc5c4)cc3)c3c([2H])c([2H])c([2H])c([2H])c3c(-c3ccccc3)c2c1[2H]]

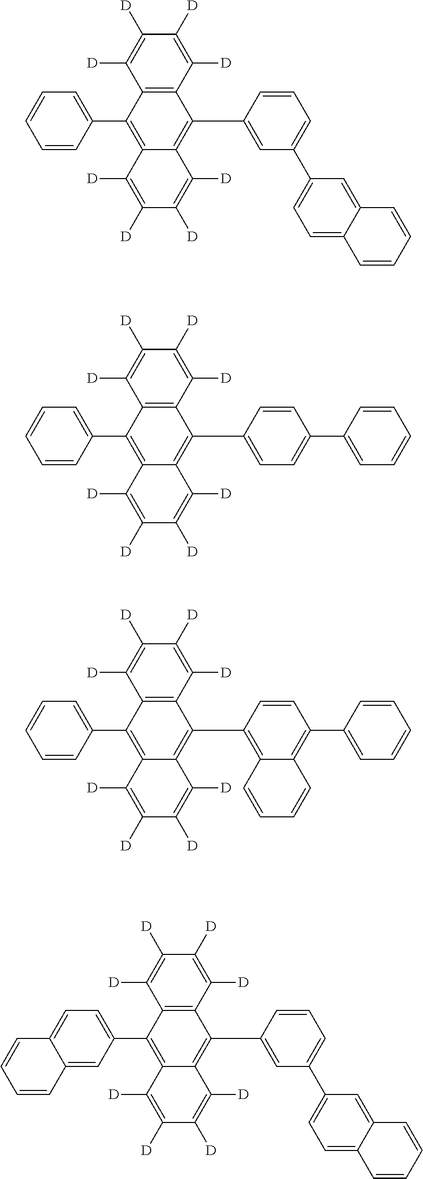 [SMILES: [2H]c1c([2H])c([2H])c2c(-c3cccc(-c4ccc5ccccc5c4)c3)c3c([2H])c([2H])c([2H])c([2H])c3c(-c3ccccc3)c2c1[2H] ; [2H]c1c([2H])c([2H])c2c(-c3ccc(-c4ccccc4)cc3)c3c([2H])c([2H])c([2H])c([2H])c3c(-c3ccccc3)c2c1[2H] ; [2H]c1c([2H])c([2H])c2c(-c3ccc(-c4ccccc4)c4ccccc34)c3c([2H])c([2H])c([2H])c([2H])c3c(-c3ccccc3)c2c1[2H] ; [2H]c1c([2H])c([2H])c2c(-c3ccc4ccccc4c3)c3c([2H])c([2H])c([2H])c([2H])c3c(-c3cccc(-c4ccc5ccccc5c4)c3)c2c1[2H]]

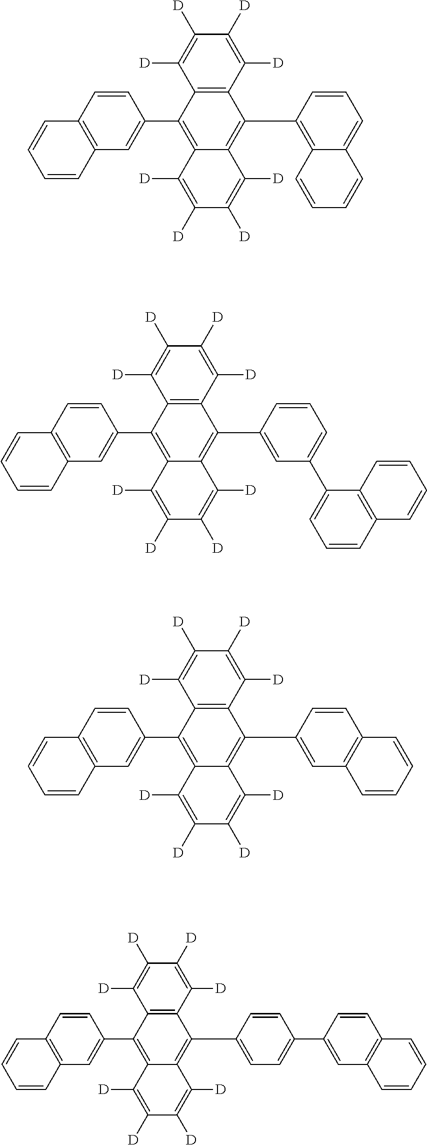 [SMILES: [2H]c1c([2H])c([2H])c2c(-c3cccc4ccccc34)c3c([2H])c([2H])c([2H])c([2H])c3c(-c3ccc4ccccc4c3)c2c1[2H] ; [2H]c1c([2H])c([2H])c2c(-c3ccc4ccccc4c3)c3c([2H])c([2H])c([2H])c([2H])c3c(-c3cccc(-c4cccc5ccccc45)c3)c2c1[2H] ; [2H]c1c([2H])c([2H])c2c(-c3ccc4ccccc4c3)c3c([2H])c([2H])c([2H])c([2H])c3c(-c3ccc4ccccc4c3)c2c1[2H] ; [2H]c1c([2H])c([2H])c2c(-c3ccc4ccccc4c3)c3c([2H])c([2H])c([2H])c([2H])c3c(-c3ccc(-c4ccc5ccccc5c4)cc3)c2c1[2H]]

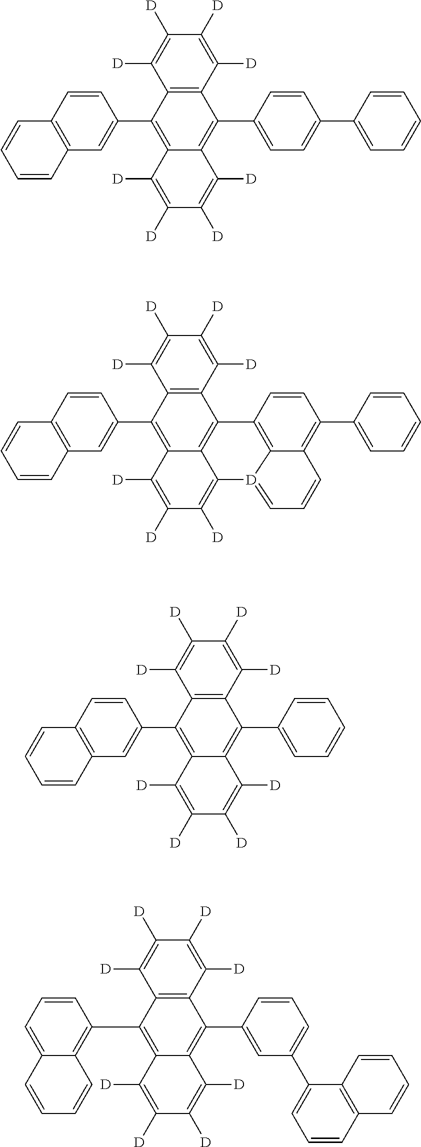

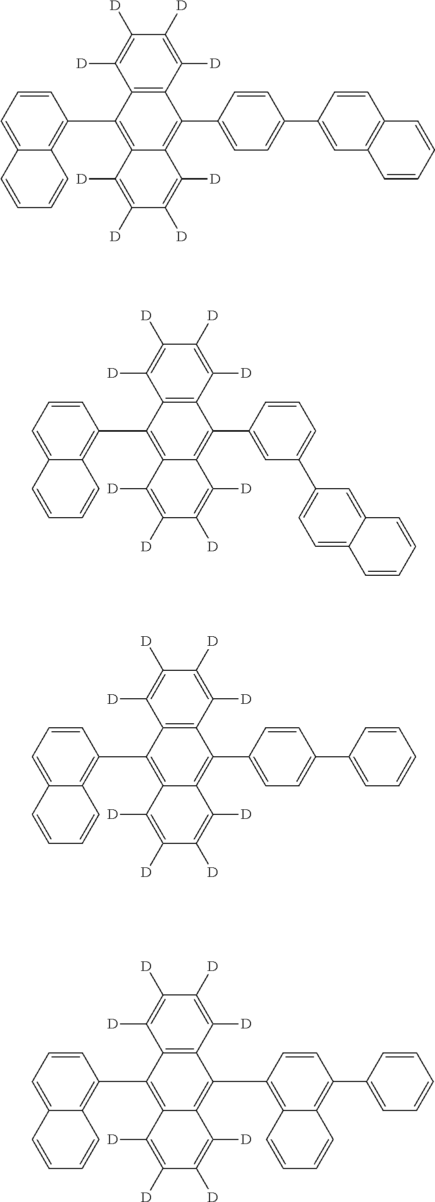 [SMILES: [2H]c1c([2H])c([2H])c2c(-c3cccc4ccccc34)c3c([2H])c([2H])c([2H])c([2H])c3c(-c3ccc(-c4ccc5ccccc5c4)cc3)c2c1[2H] ; [2H]c1c([2H])c([2H])c2c(-c3cccc4ccccc34)c3c([2H])c([2H])c([2H])c([2H])c3c(-c3cccc(-c4ccc5ccccc5c4)c3)c2c1[2H] ; [2H]c1c([2H])c([2H])c2c(-c3cccc4ccccc34)c3c([2H])c([2H])c([2H])c([2H])c3c(-c3ccc(-c4ccccc4)cc3)c2c1[2H] ; [2H]c1c([2H])c([2H])c2c(-c3ccc(-c4ccccc4)c4ccccc34)c3c([2H])c([2H])c([2H])c([2H])c3c(-c3cccc4ccccc34)c2c1[2H]]

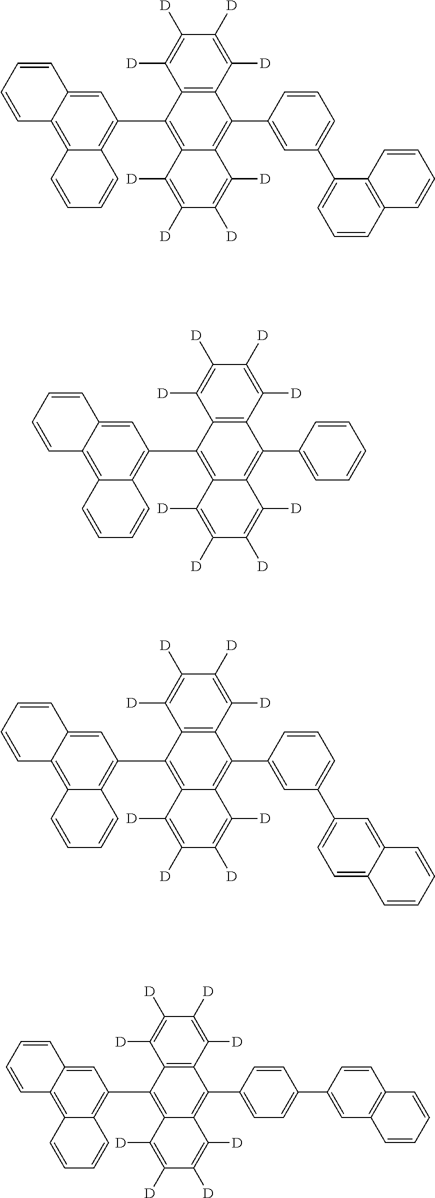 [SMILES: [2H]c1c([2H])c([2H])c2c(-c3cc4ccccc4c4ccccc34)c3c([2H])c([2H])c([2H])c([2H])c3c(-c3cccc(-c4cccc5ccccc45)c3)c2c1[2H] ; [2H]c1c([2H])c([2H])c2c(-c3cc4ccccc4c4ccccc34)c3c([2H])c([2H])c([2H])c([2H])c3c(-c3ccccc3)c2c1[2H] ; [2H]c1c([2H])c([2H])c2c(-c3cc4ccccc4c4ccccc34)c3c([2H])c([2H])c([2H])c([2H])c3c(-c3cccc(-c4ccc5ccccc5c4)c3)c2c1[2H] ; [2H]c1c([2H])c([2H])c2c(-c3cc4ccccc4c4ccccc34)c3c([2H])c([2H])c([2H])c([2H])c3c(-c3ccc(-c4ccc5ccccc5c4)cc3)c2c1[2H]]

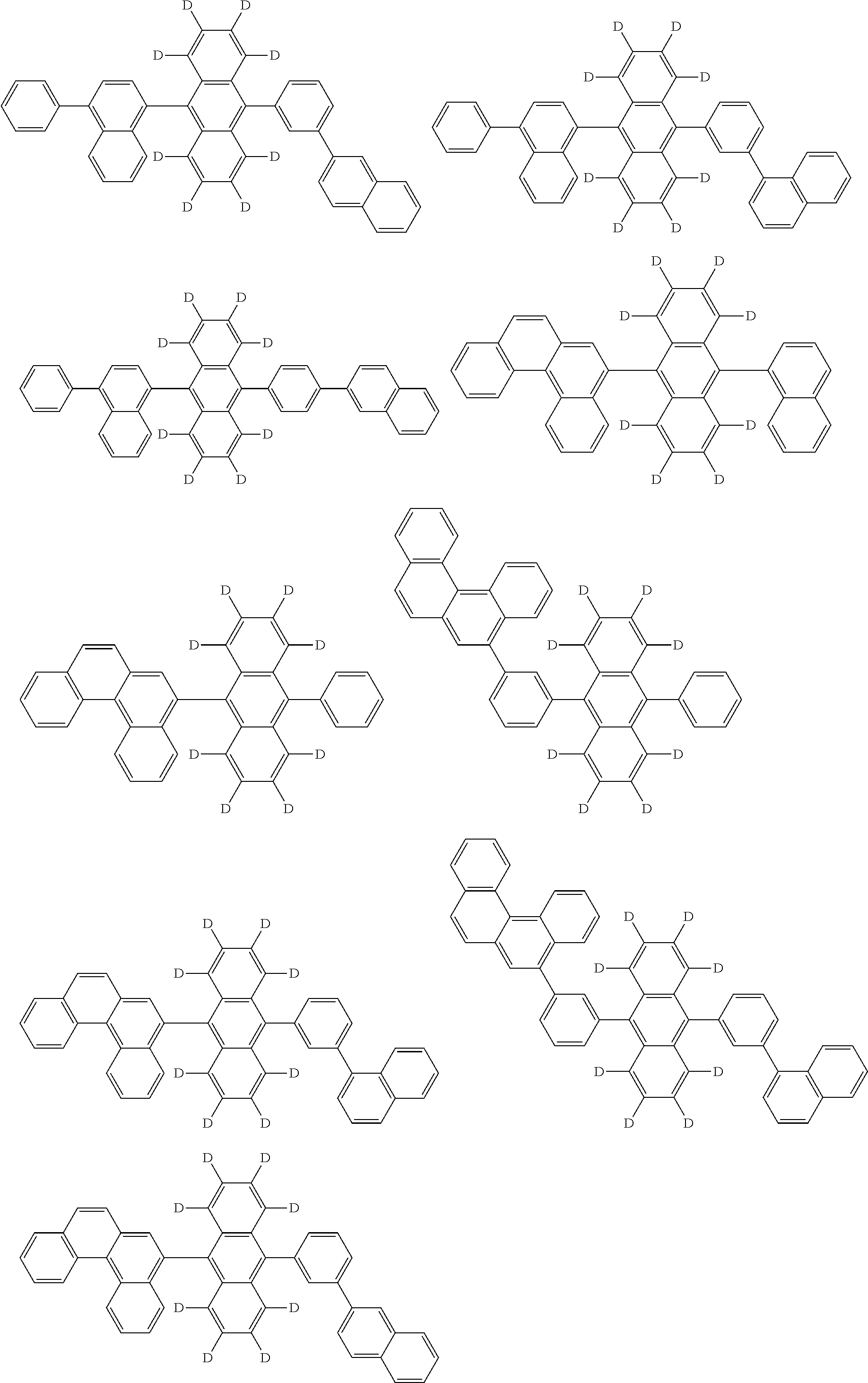

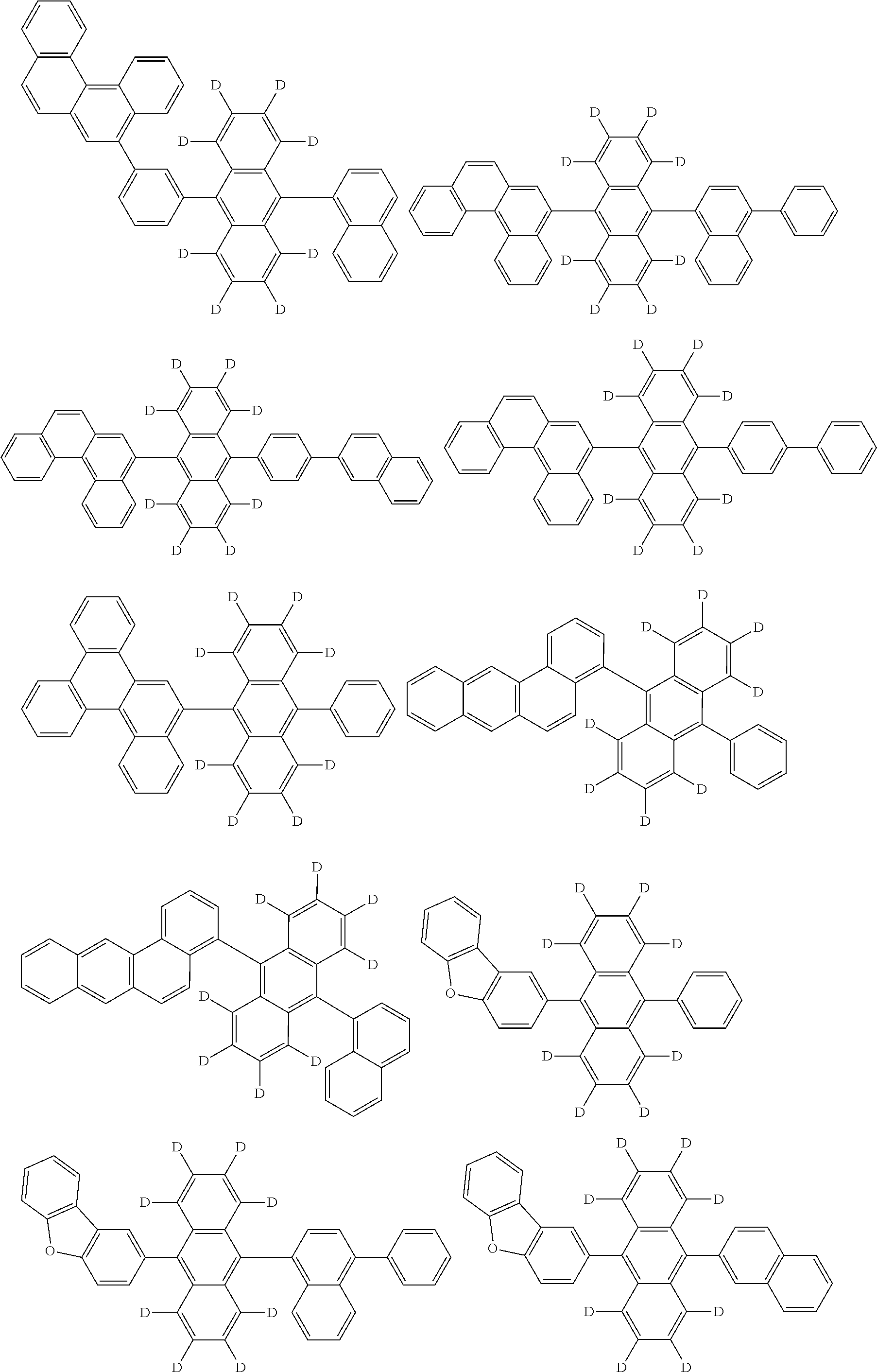

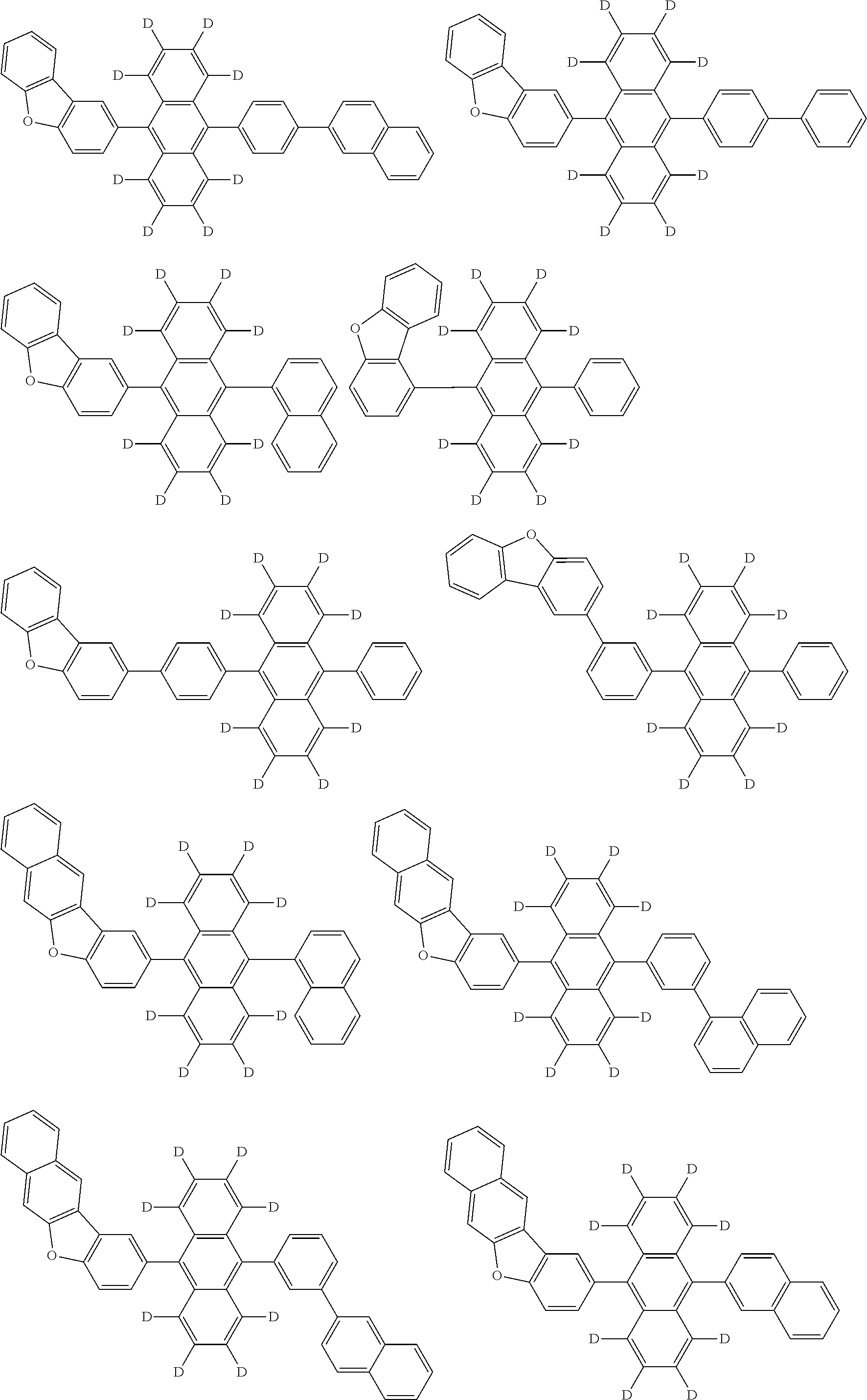

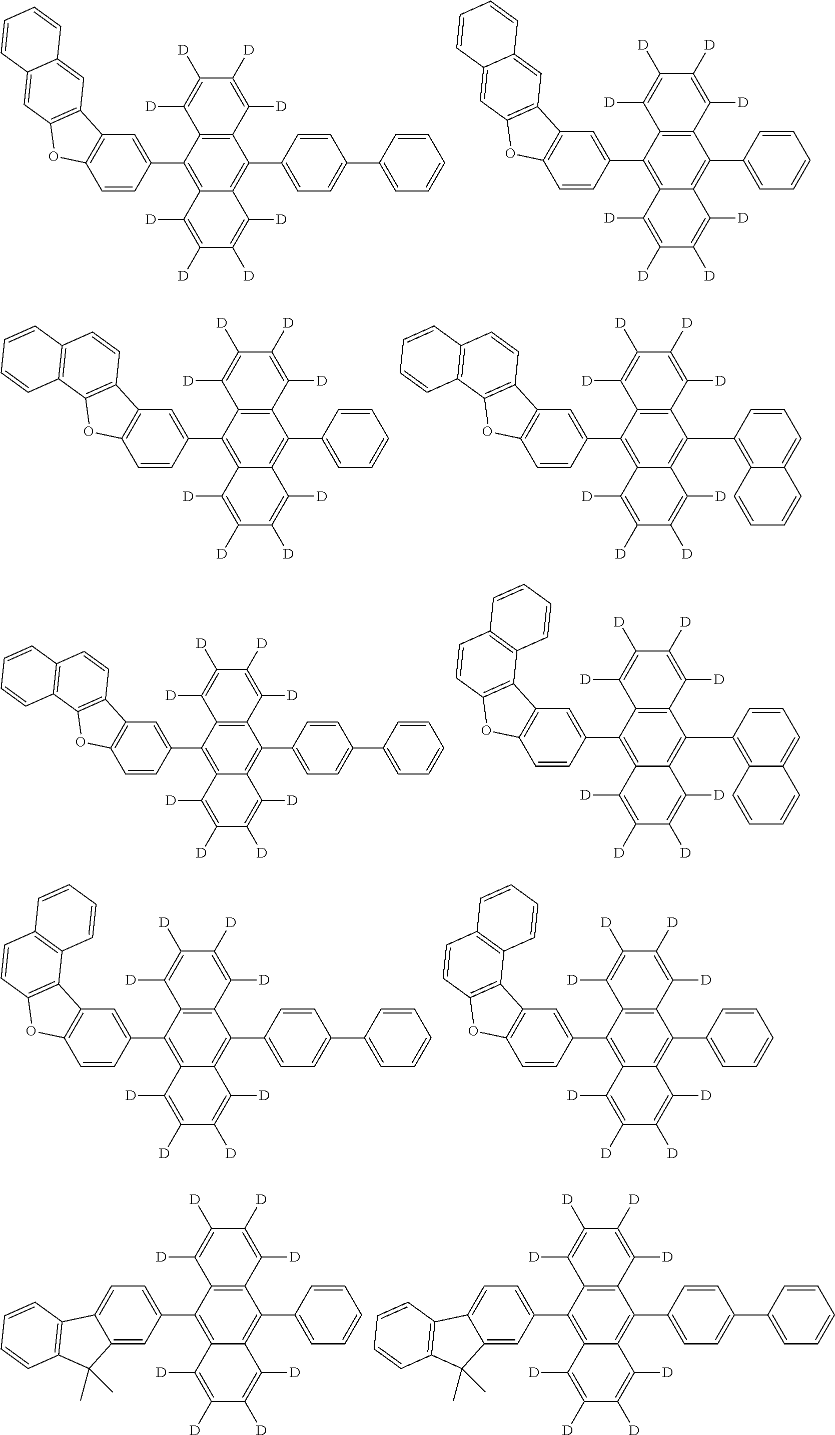

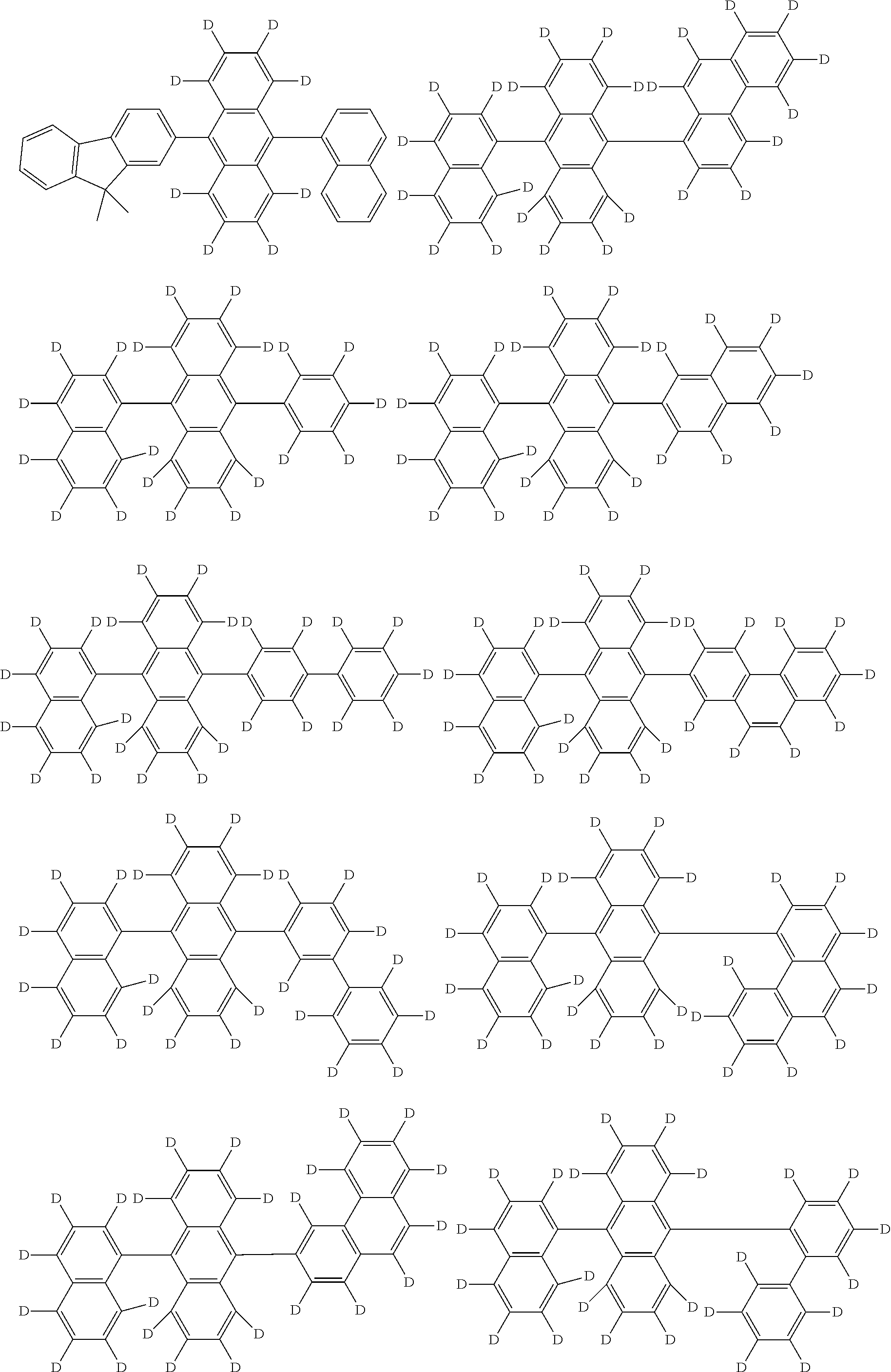

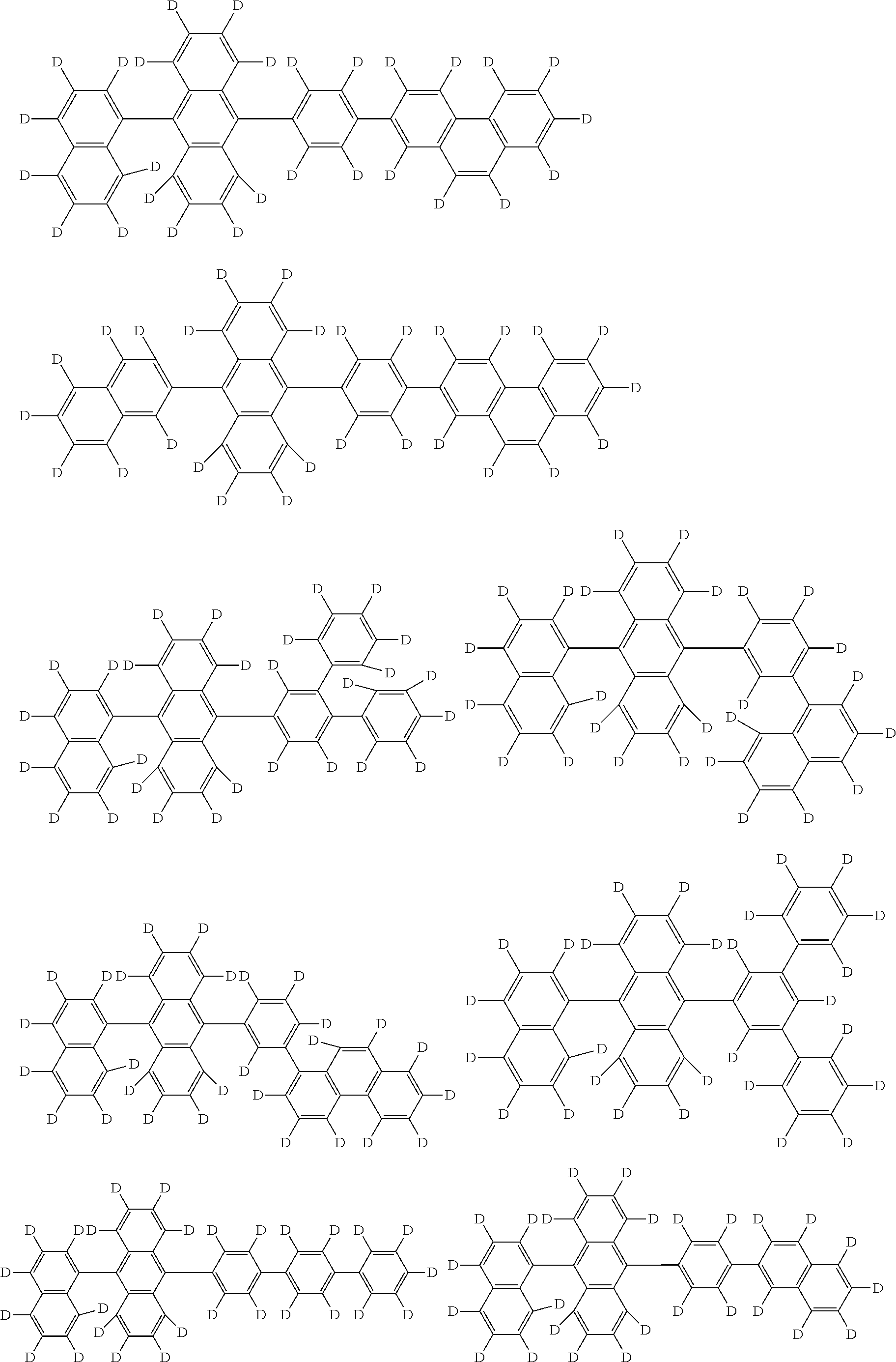

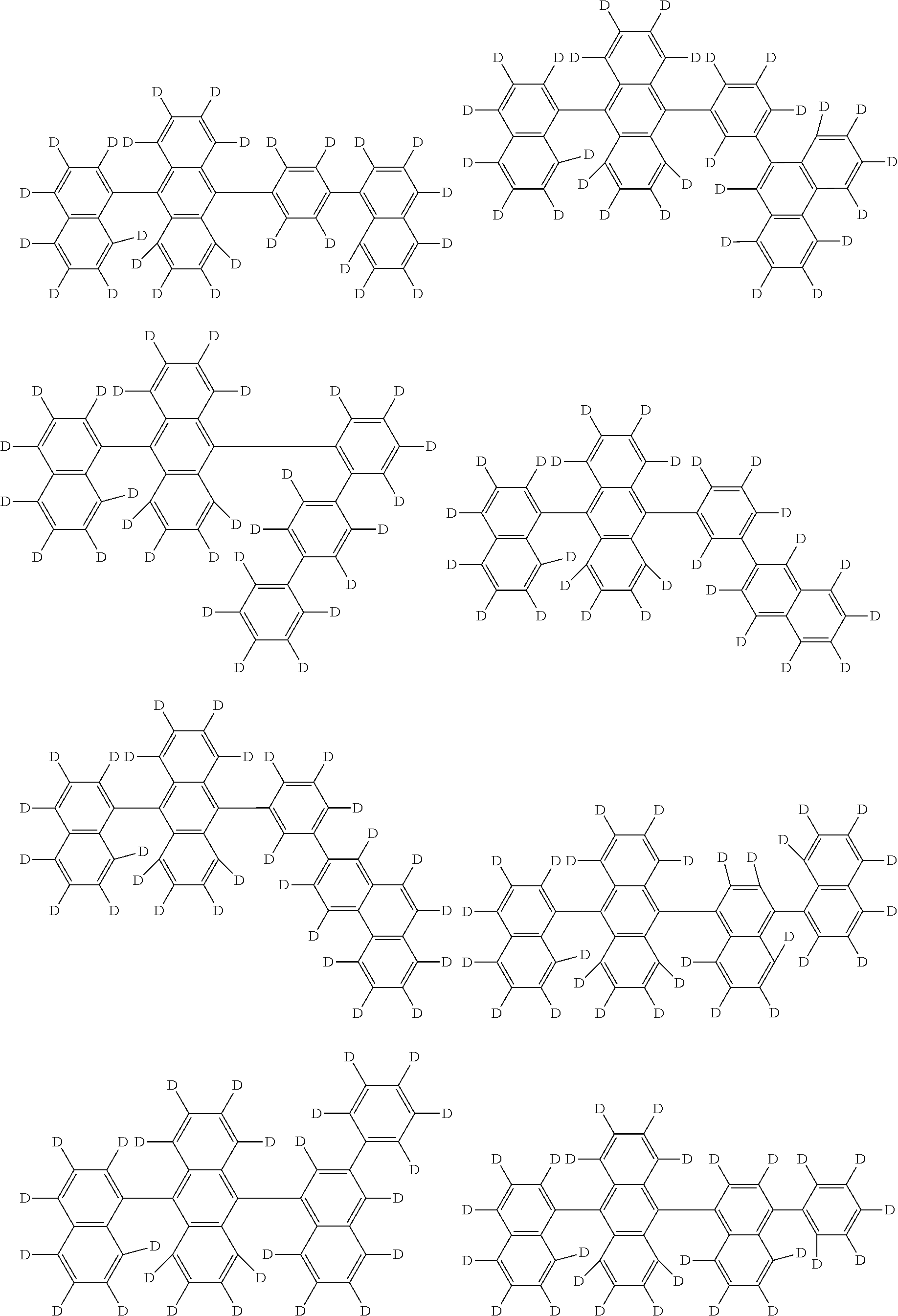

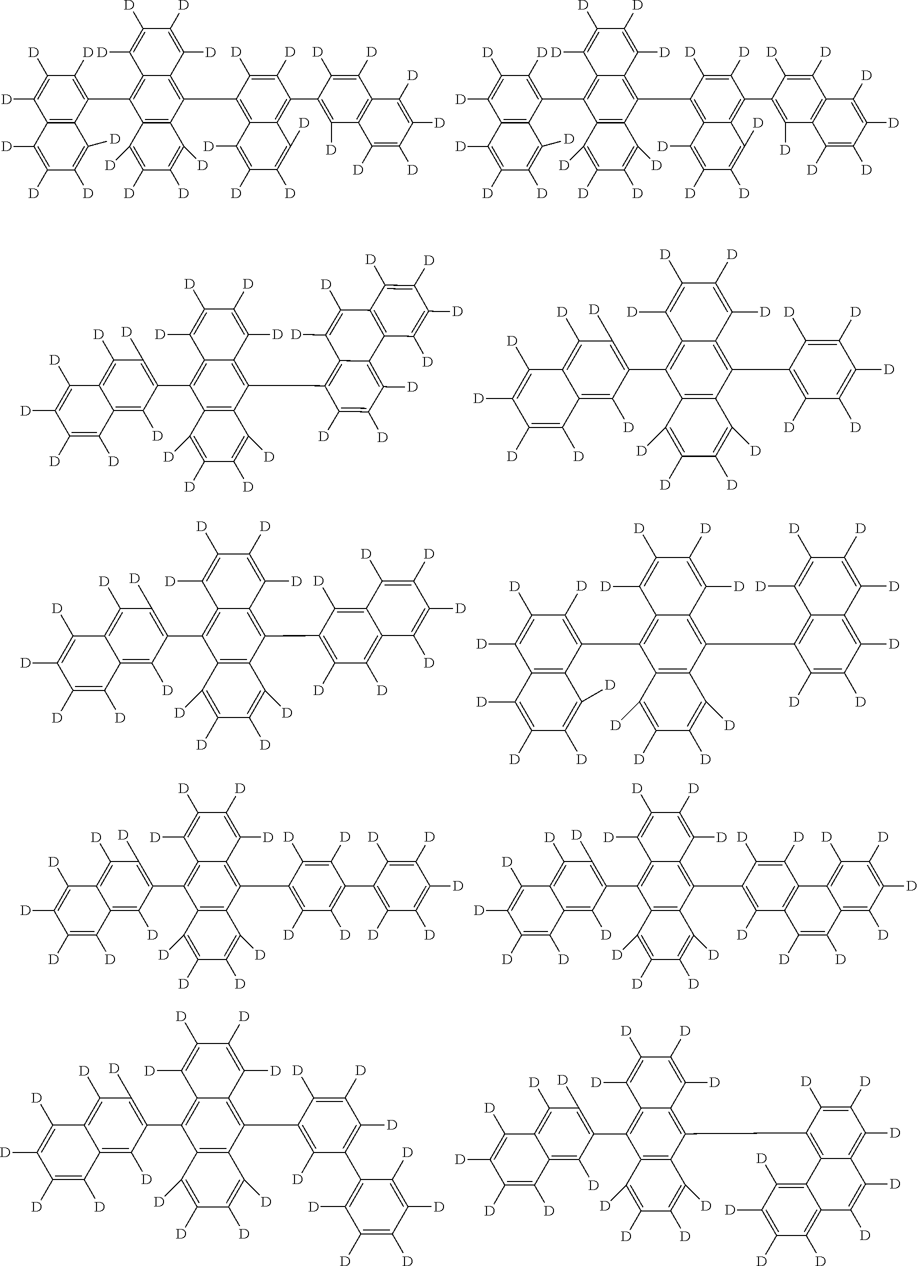

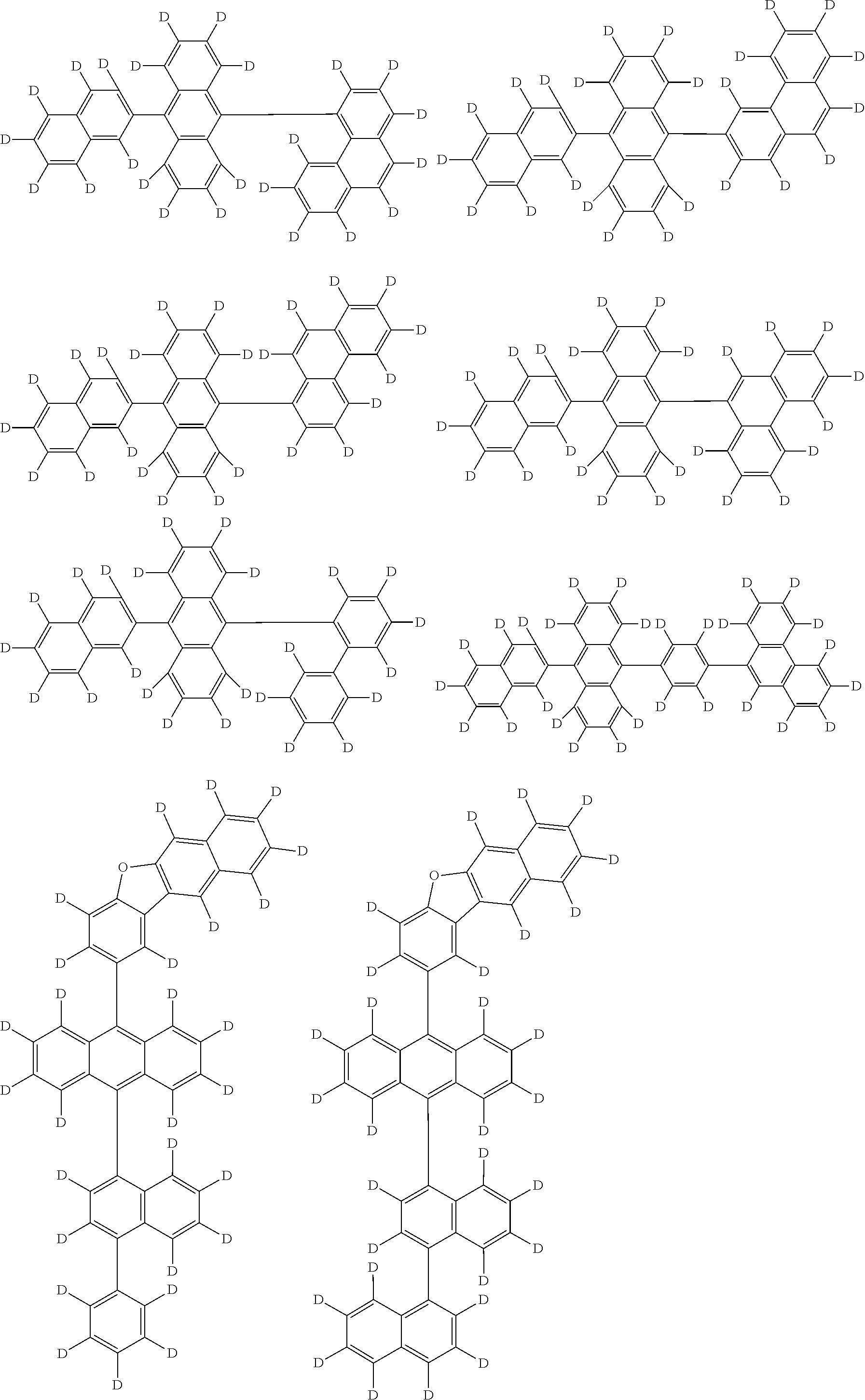

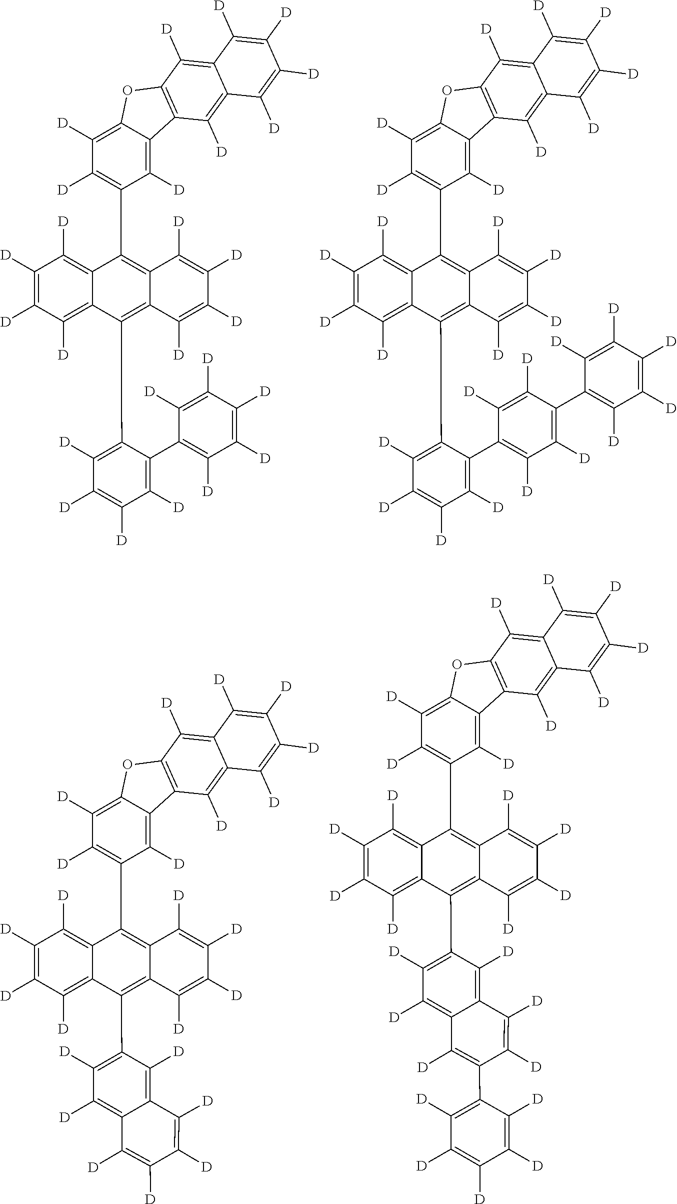

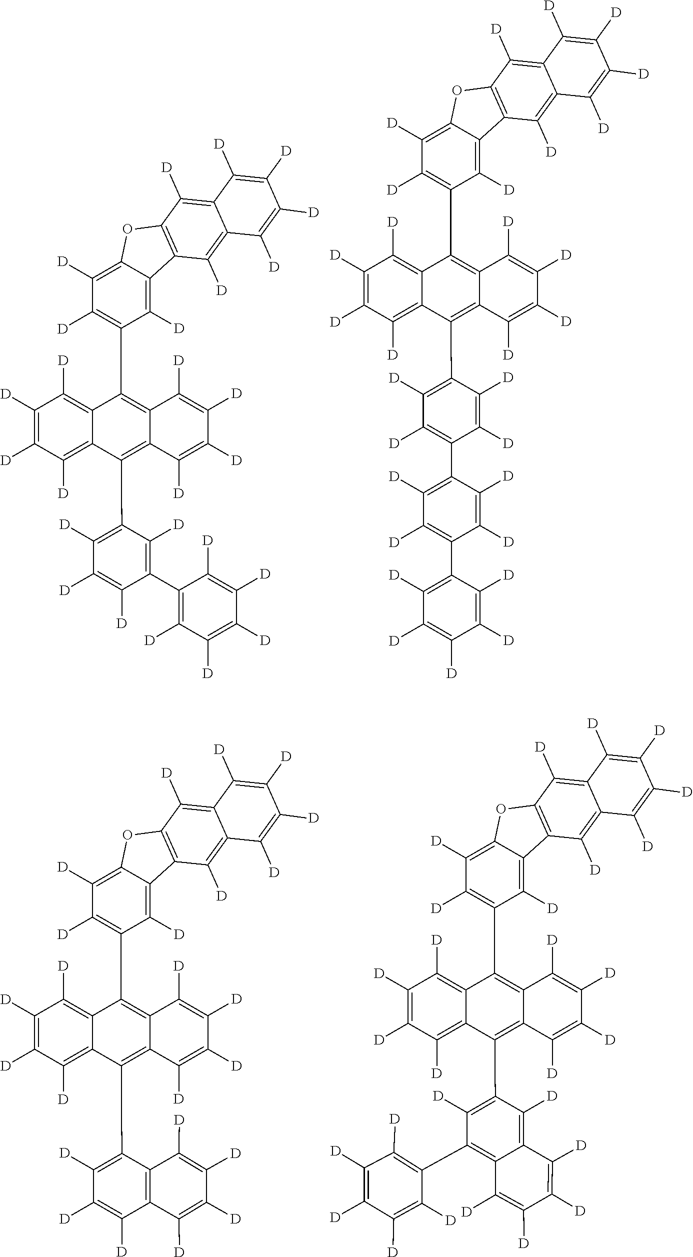

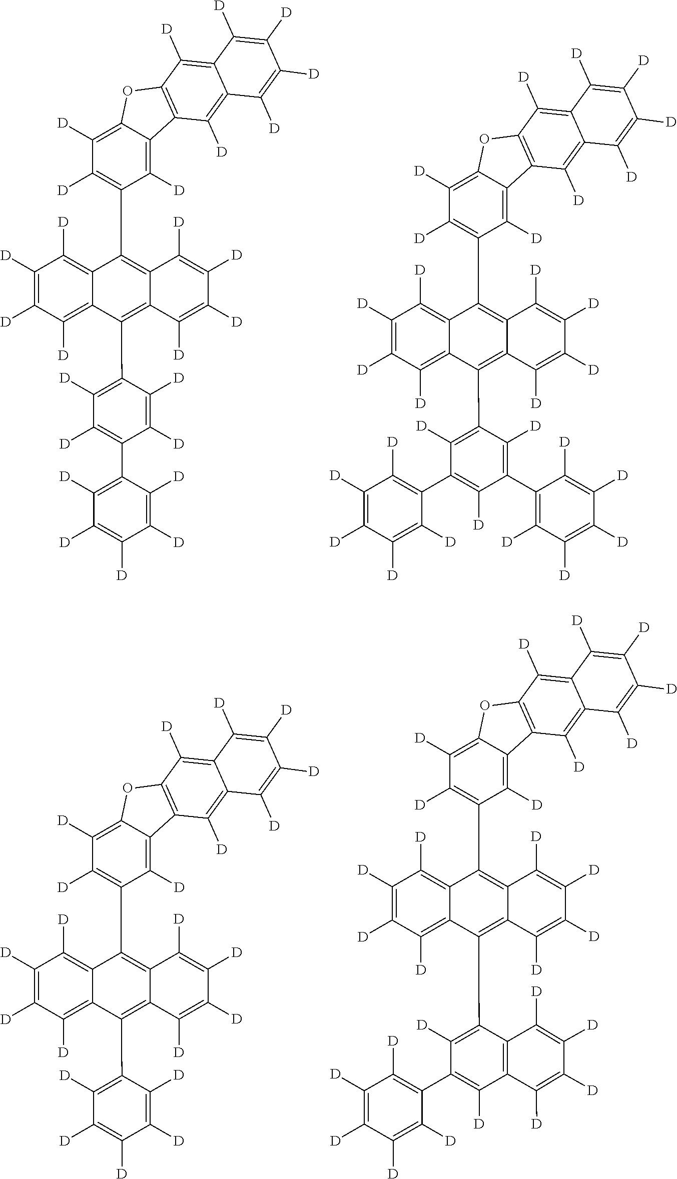

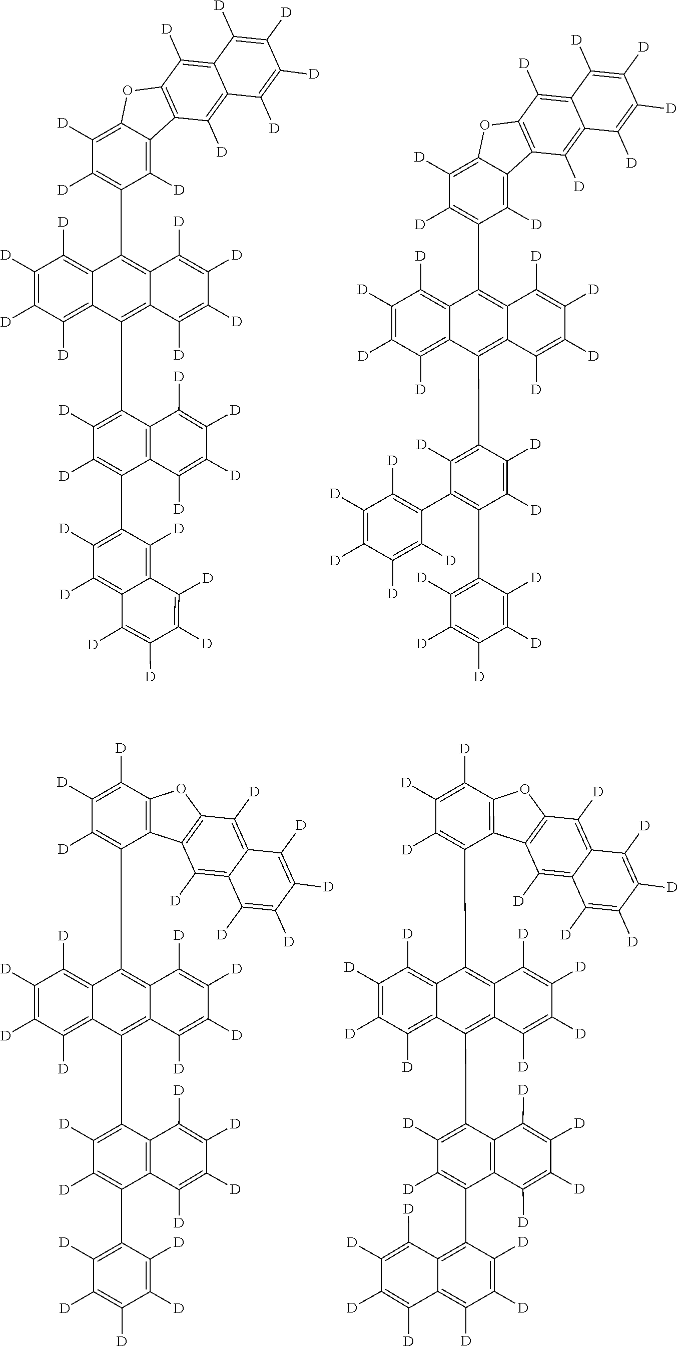

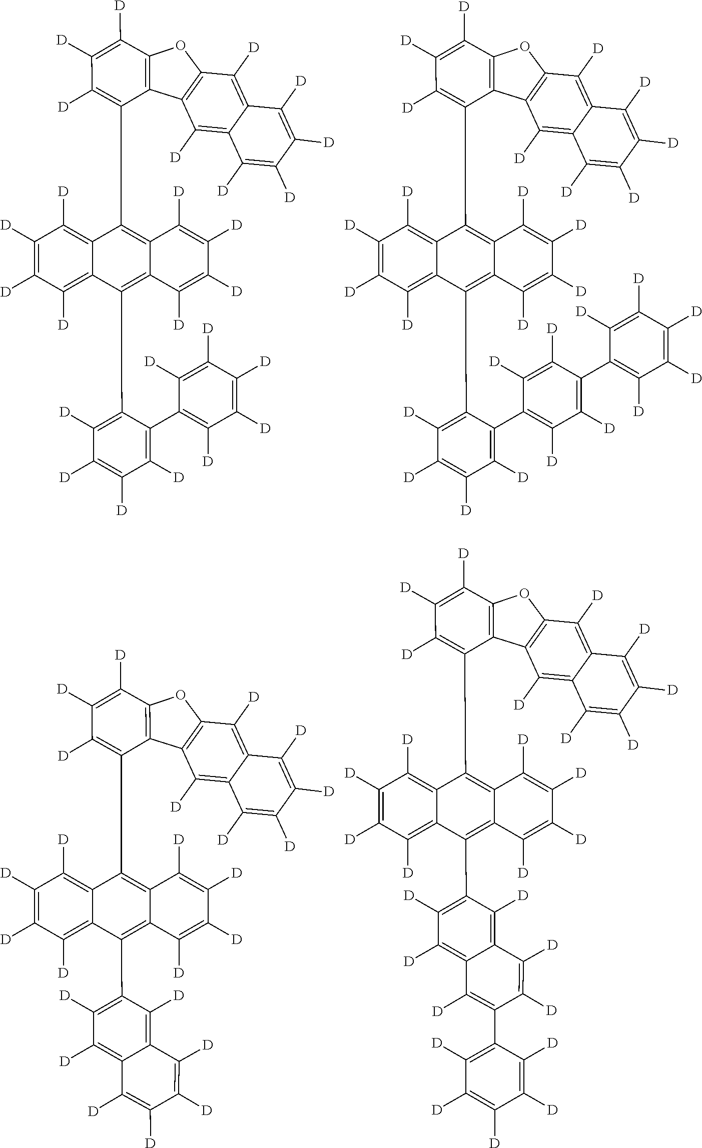

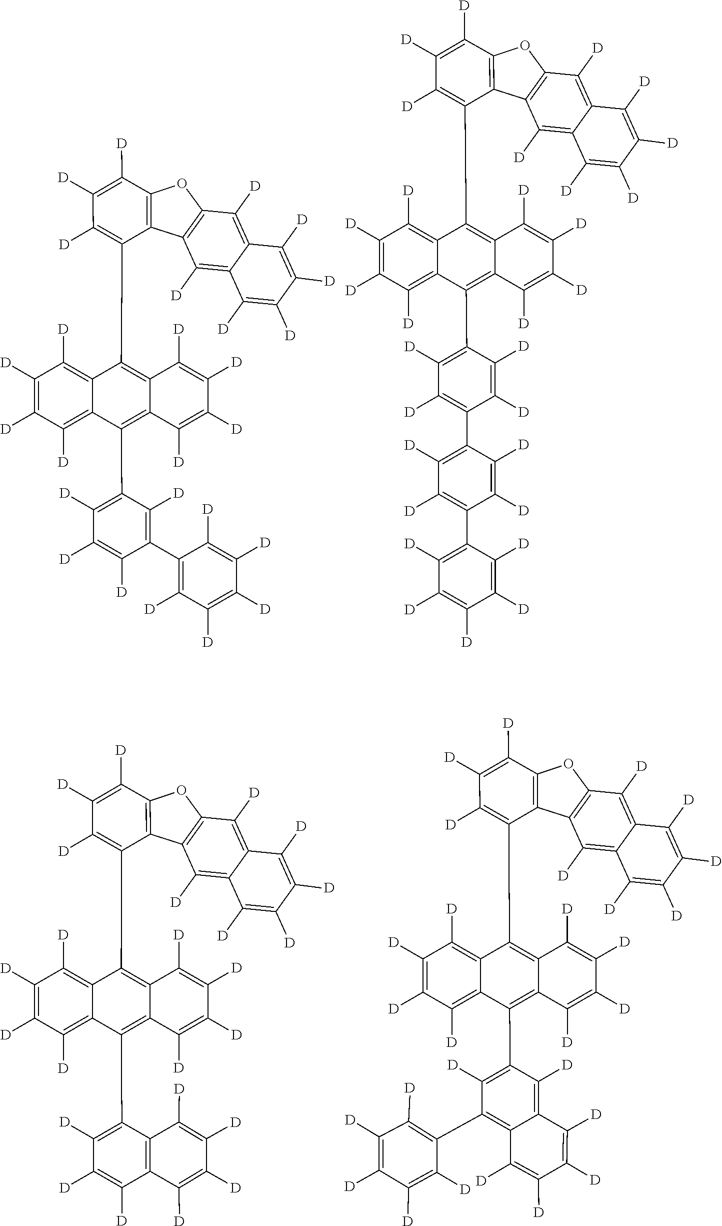

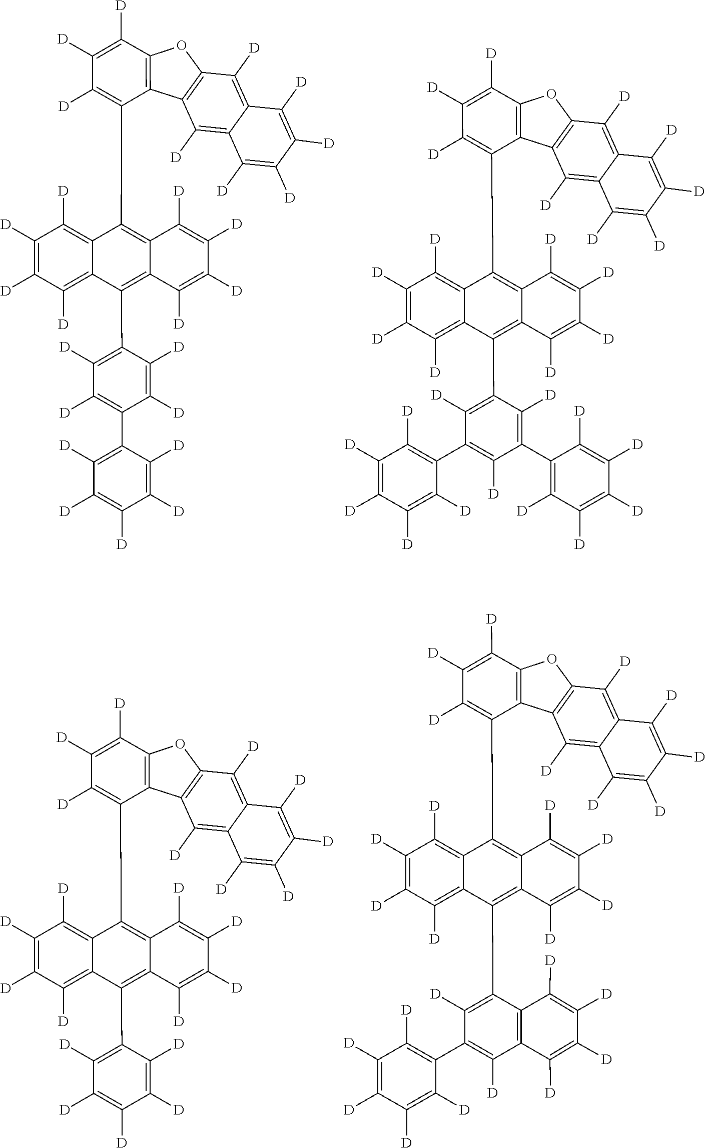

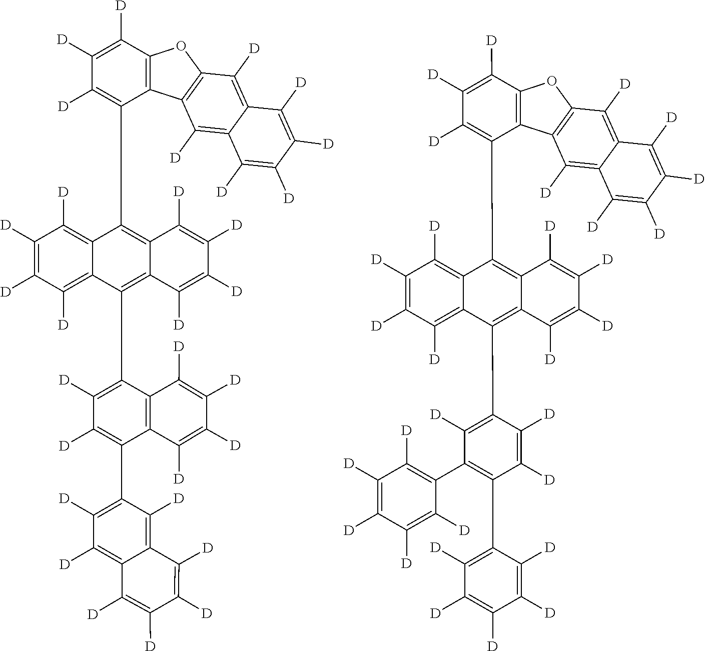

n

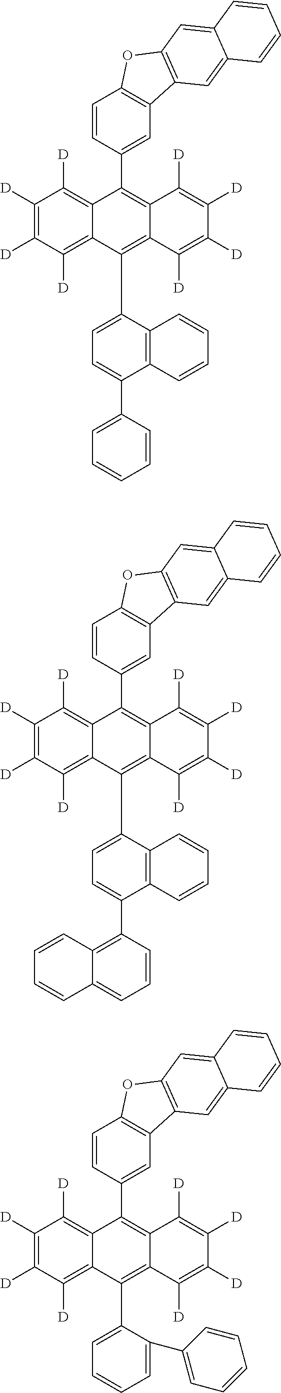 [SMILES: [2H]c1c([2H])c([2H])c2c(-c3ccc(-c4ccccc4)c4ccccc34)c3c([2H])c([2H])c([2H])c([2H])c3c(-c3ccc4oc5cc6ccccc6cc5c4c3)c2c1[2H] ; [2H]c1c([2H])c([2H])c2c(-c3ccc(-c4cccc5ccccc45)c4ccccc34)c3c([2H])c([2H])c([2H])c([2H])c3c(-c3ccc4oc5cc6ccccc6cc5c4c3)c2c1[2H] ; [2H]c1c([2H])c([2H])c2c(-c3ccccc3-c3ccccc3)c3c([2H])c([2H])c([2H])c([2H])c3c(-c3ccc4oc5cc6ccccc6cc5c4c3)c2c1[2H]]

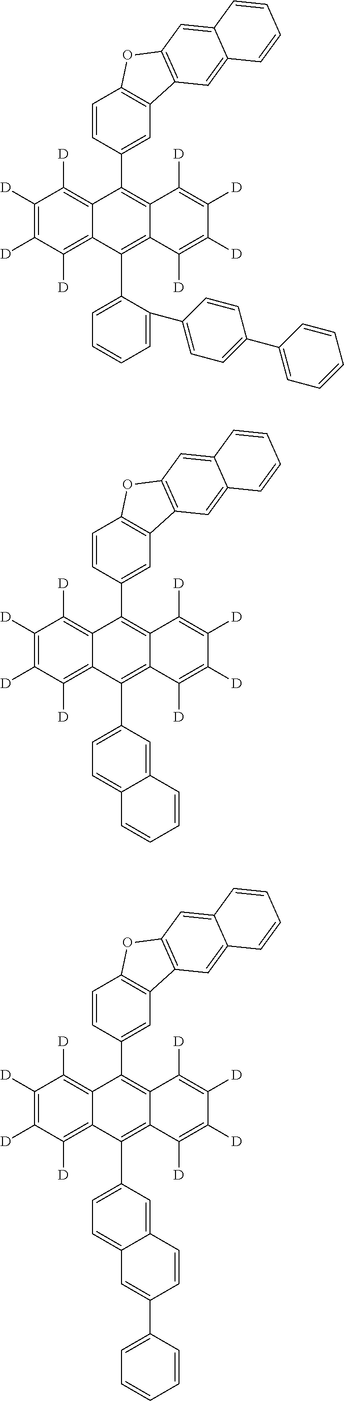 [SMILES: [2H]c1c([2H])c([2H])c2c(-c3ccccc3-c3ccc(-c4ccccc4)cc3)c3c([2H])c([2H])c([2H])c([2H])c3c(-c3ccc4oc5cc6ccccc6cc5c4c3)c2c1[2H] ; [2H]c1c([2H])c([2H])c2c(-c3ccc4oc5cc6ccccc6cc5c4c3)c3c([2H])c([2H])c([2H])c([2H])c3c(-c3ccc4ccccc4c3)c2c1[2H] ; [2H]c1c([2H])c([2H])c2c(-c3ccc4oc5cc6ccccc6cc5c4c3)c3c([2H])c([2H])c([2H])c([2H])c3c(-c3ccc4cc(-c5ccccc5)ccc4c3)c2c1[2H]]

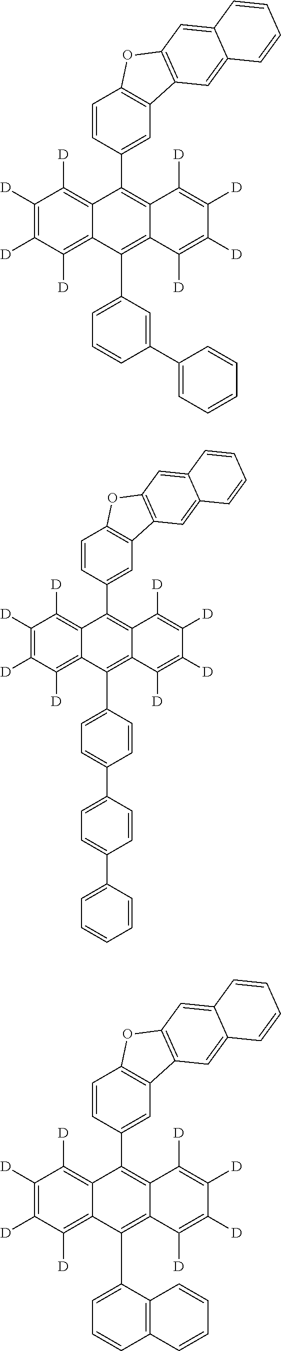

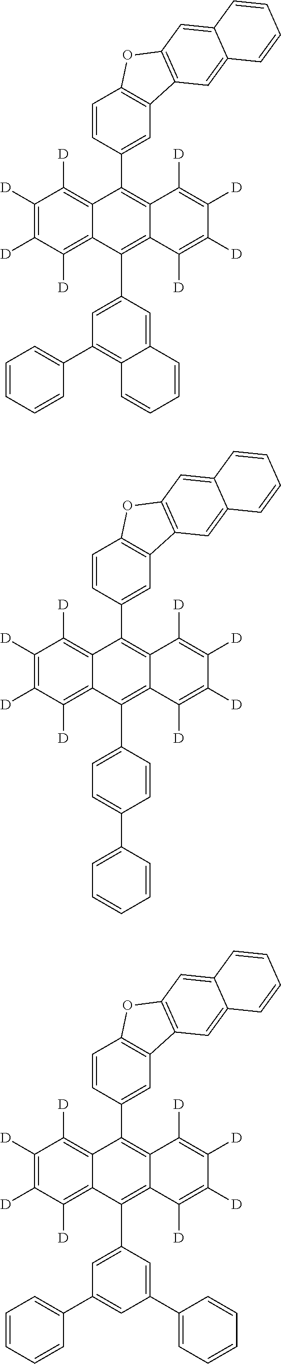 [SMILES: [2H]c1c([2H])c([2H])c2c(-c3ccc4oc5cc6ccccc6cc5c4c3)c3c([2H])c([2H])c([2H])c([2H])c3c(-c3cc(-c4ccccc4)c4ccccc4c3)c2c1[2H] ; [2H]c1c([2H])c([2H])c2c(-c3ccc4oc5cc6ccccc6cc5c4c3)c3c([2H])c([2H])c([2H])c([2H])c3c(-c3ccc(-c4ccccc4)cc3)c2c1[2H] ; [2H]c1c([2H])c([2H])c2c(-c3ccc4oc5cc6ccccc6cc5c4c3)c3c([2H])c([2H])c([2H])c([2H])c3c(-c3cc(-c4ccccc4)cc(-c4ccccc4)c3)c2c1[2H]]

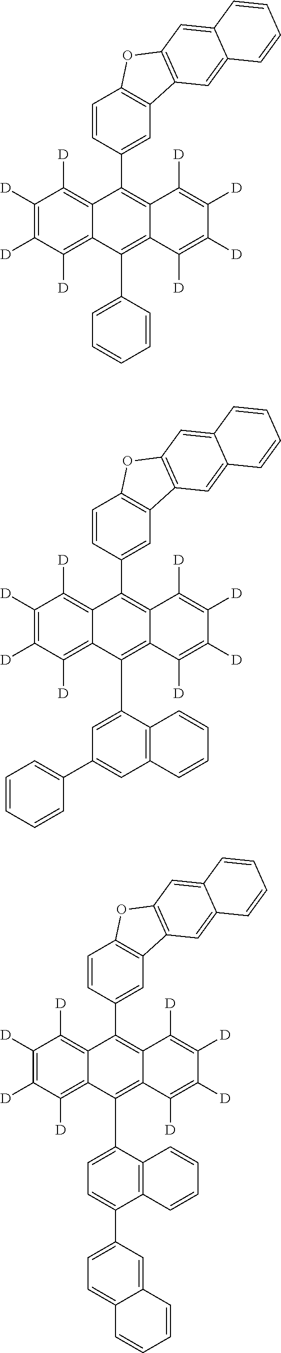 [SMILES: [2H]c1c([2H])c([2H])c2c(-c3ccc4oc5cc6ccccc6cc5c4c3)c3c([2H])c([2H])c([2H])c([2H])c3c(-c3ccccc3)c2c1[2H] ; [2H]c1c([2H])c([2H])c2c(-c3cc(-c4ccccc4)cc4ccccc34)c3c([2H])c([2H])c([2H])c([2H])c3c(-c3ccc4oc5cc6ccccc6cc5c4c3)c2c1[2H] ; [2H]c1c([2H])c([2H])c2c(-c3ccc(-c4ccc5ccccc5c4)c4ccccc34)c3c([2H])c([2H])c([2H])c([2H])c3c(-c3ccc4oc5cc6ccccc6cc5c4c3)c2c1[2H]]

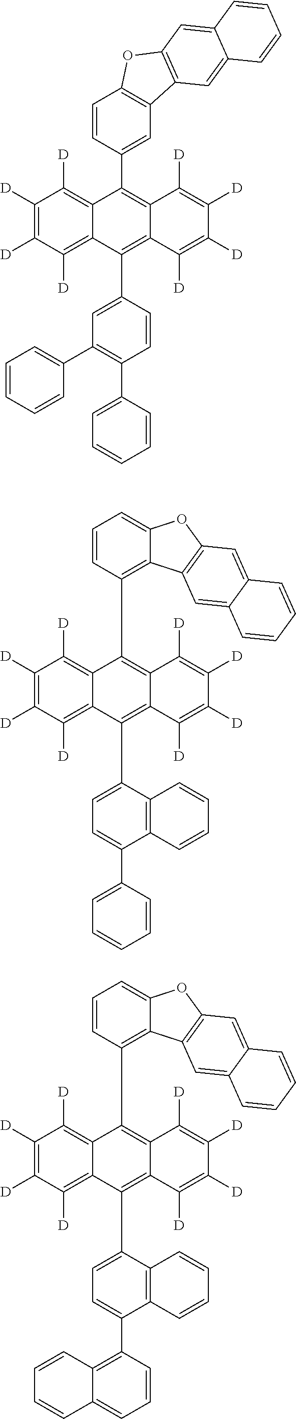

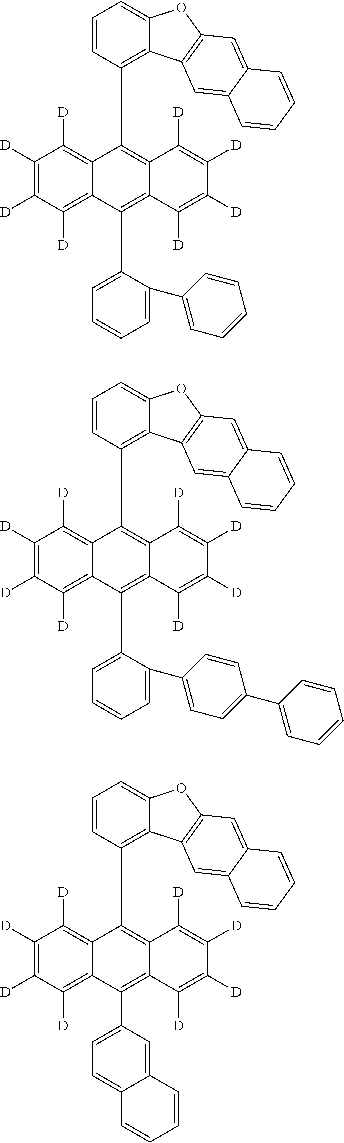

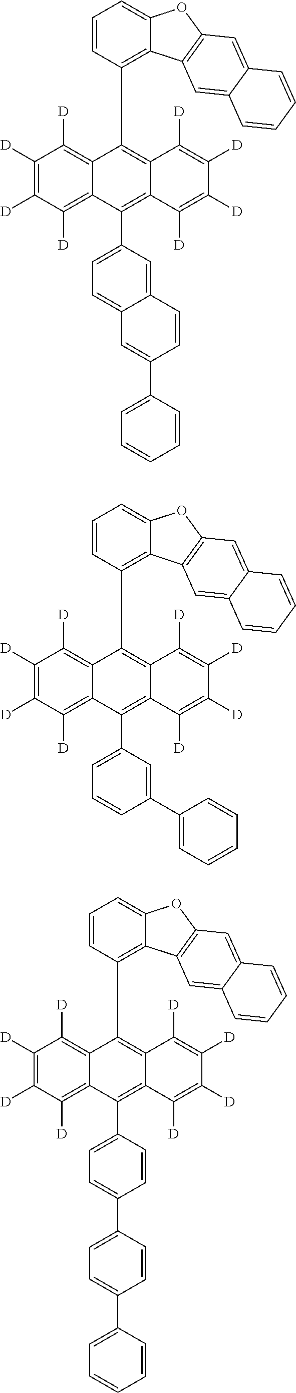 [SMILES: [2H]c1c([2H])c([2H])c2c(-c3cccc4oc5cc6ccccc6cc5c34)c3c([2H])c([2H])c([2H])c([2H])c3c(-c3ccc4cc(-c5ccccc5)ccc4c3)c2c1[2H] ; [2H]c1c([2H])c([2H])c2c(-c3cccc4oc5cc6ccccc6cc5c34)c3c([2H])c([2H])c([2H])c([2H])c3c(-c3cccc(-c4ccccc4)c3)c2c1[2H] ; [2H]c1c([2H])c([2H])c2c(-c3cccc4oc5cc6ccccc6cc5c34)c3c([2H])c([2H])c([2H])c([2H])c3c(-c3ccc(-c4ccc(-c5ccccc5)cc4)cc3)c2c1[2H]]

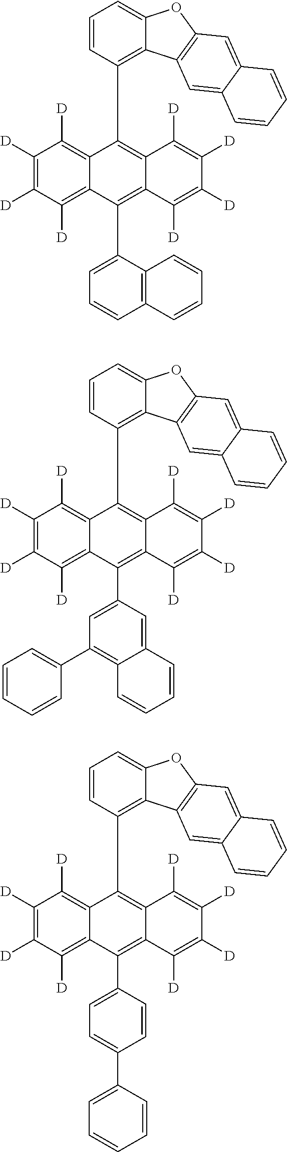

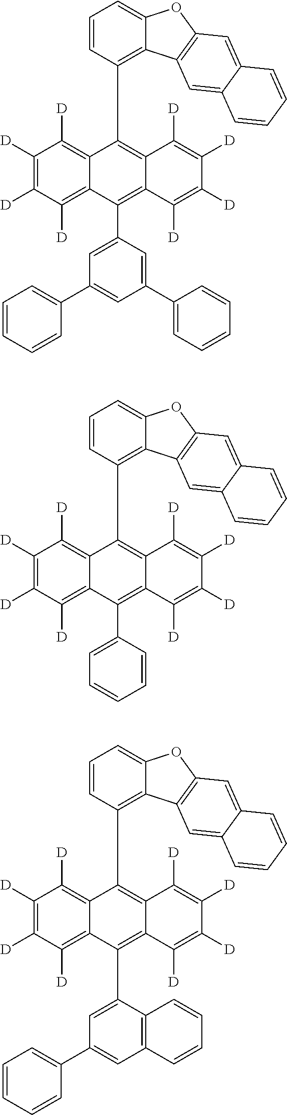

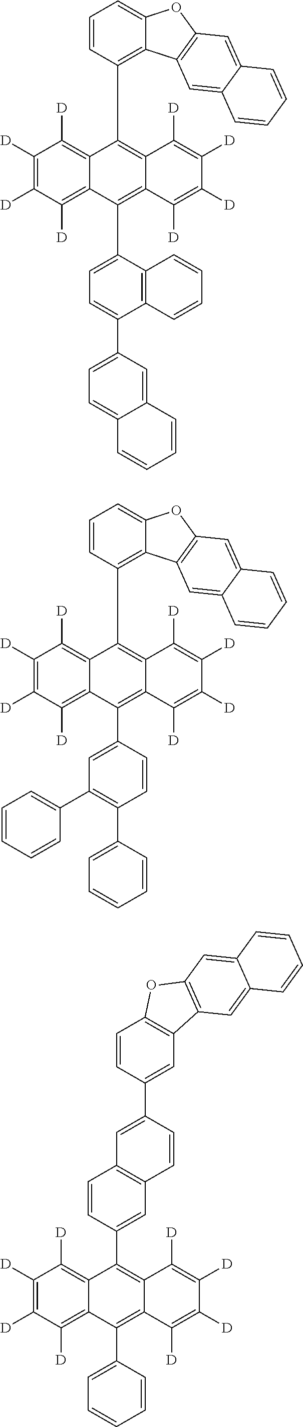

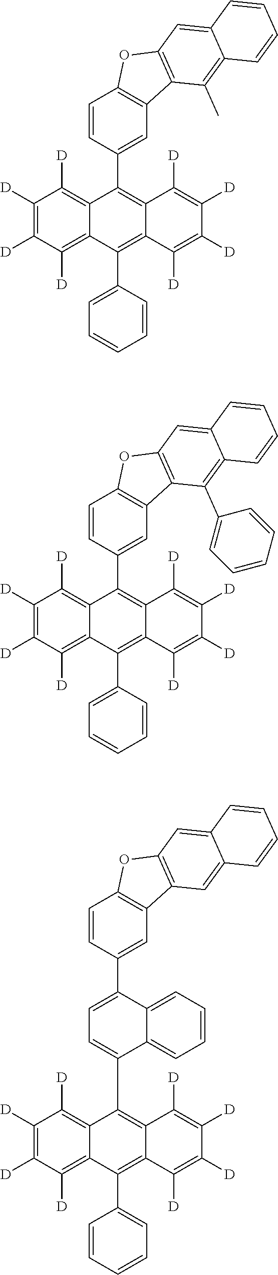 [SMILES: [2H]c1c([2H])c([2H])c2c(-c3ccc4oc5cc6ccccc6c(C)c5c4c3)c3c([2H])c([2H])c([2H])c([2H])c3c(-c3ccccc3)c2c1[2H] ; [2H]c1c([2H])c([2H])c2c(-c3ccc4oc5cc6ccccc6c(-c6ccccc6)c5c4c3)c3c([2H])c([2H])c([2H])c([2H])c3c(-c3ccccc3)c2c1[2H] ; [2H]c1c([2H])c([2H])c2c(-c3ccc(-c4ccc5oc6cc7ccccc7cc6c5c4)c4ccccc34)c3c([2H])c([2H])c([2H])c([2H])c3c(-c3ccccc3)c2c1[2H]]

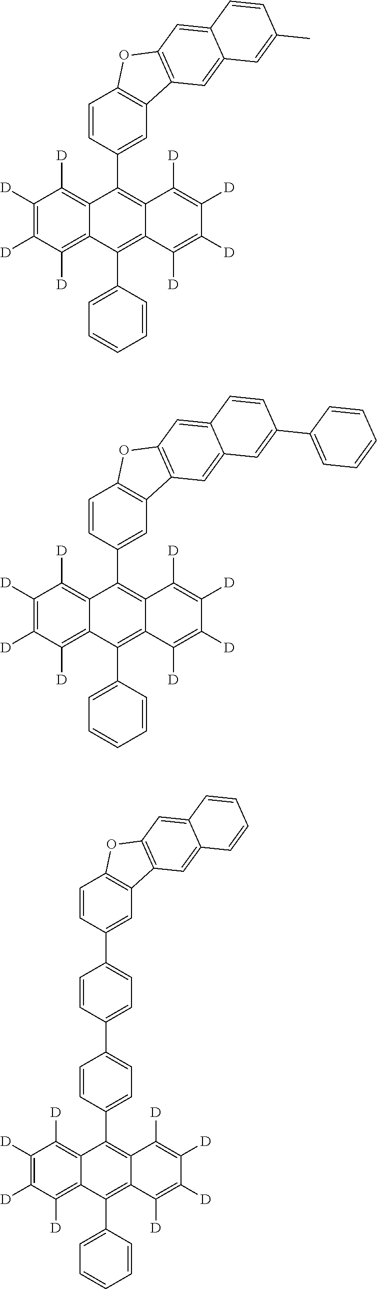 [SMILES: [2H]c1c([2H])c([2H])c2c(-c3ccc4oc5cc6ccc(C)cc6cc5c4c3)c3c([2H])c([2H])c([2H])c([2H])c3c(-c3ccccc3)c2c1[2H] ; [2H]c1c([2H])c([2H])c2c(-c3ccc4oc5cc6ccc(-c7ccccc7)cc6cc5c4c3)c3c([2H])c([2H])c([2H])c([2H])c3c(-c3ccccc3)c2c1[2H] ; [2H]c1c([2H])c([2H])c2c(-c3ccc(-c4ccc(-c5ccc6oc7cc8ccccc8cc7c6c5)cc4)cc3)c3c([2H])c([2H])c([2H])c([2H])c3c(-c3ccccc3)c2c1[2H]]

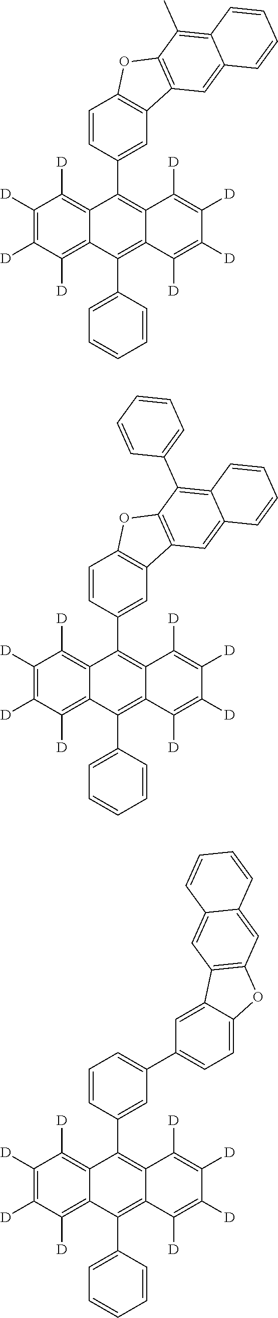

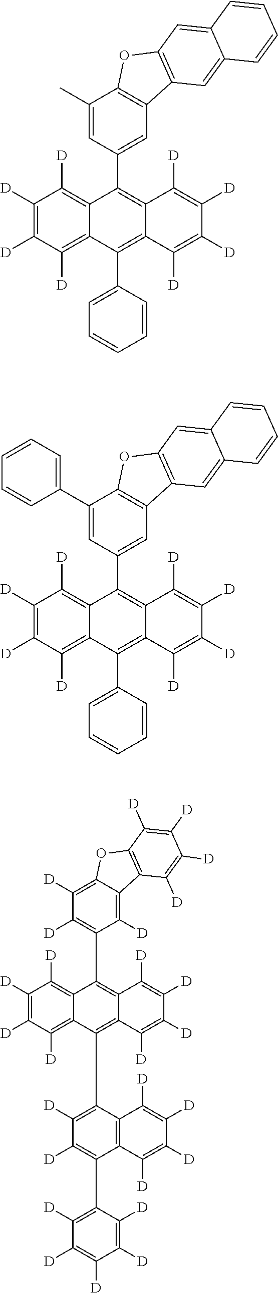 [SMILES: [2H]c1c([2H])c([2H])c2c(-c3cc(C)c4oc5cc6ccccc6cc5c4c3)c3c([2H])c([2H])c([2H])c([2H])c3c(-c3ccccc3)c2c1[2H] ; [2H]c1c([2H])c([2H])c2c(-c3cc(-c4ccccc4)c4oc5cc6ccccc6cc5c4c3)c3c([2H])c([2H])c([2H])c([2H])c3c(-c3ccccc3)c2c1[2H] ; [2H]c1c([2H])c([2H])c(-c2c([2H])c([2H])c(-c3c4c([2H])c([2H])c([2H])c([2H])c4c(-c4c([2H])c([2H])c5oc6c([2H])c([2H])c([2H])c([2H])c6c5c4[2H])c4c([2H])c([2H])c([2H])c([2H])c34)c3c([2H])c([2H])c([2H])c([2H])c23)c([2H])c1[2H]]

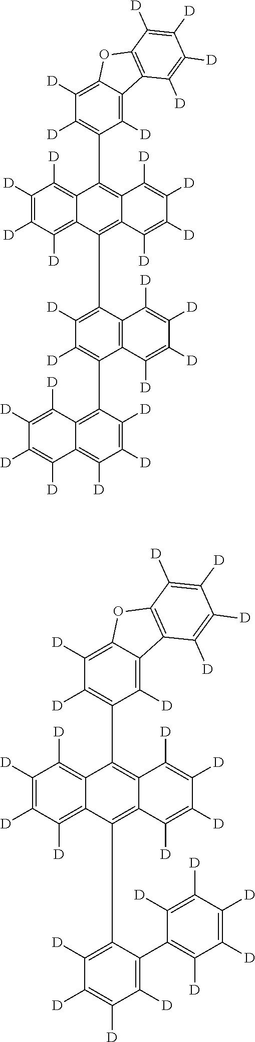 [SMILES: [2H]c1c([2H])c([2H])c2c(oc3c([2H])c([2H])c(-c4c5c([2H])c([2H])c([2H])c([2H])c5c(-c5c([2H])c([2H])c(-c6c([2H])c([2H])c([2H])c7c([2H])c([2H])c([2H])c([2H])c67)c6c([2H])c([2H])c([2H])c([2H])c56)c5c([2H])c([2H])c([2H])c([2H])c45)c([2H])c32)c1[2H] ; [2H]c1c([2H])c([2H])c(-c2c([2H])c([2H])c([2H])c([2H])c2-c2c3c([2H])c([2H])c([2H])c([2H])c3c(-c3c([2H])c([2H])c4oc5c([2H])c([2H])c([2H])c([2H])c5c4c3[2H])c3c([2H])c([2H])c([2H])c([2H])c23)c([2H])c1[2H]]

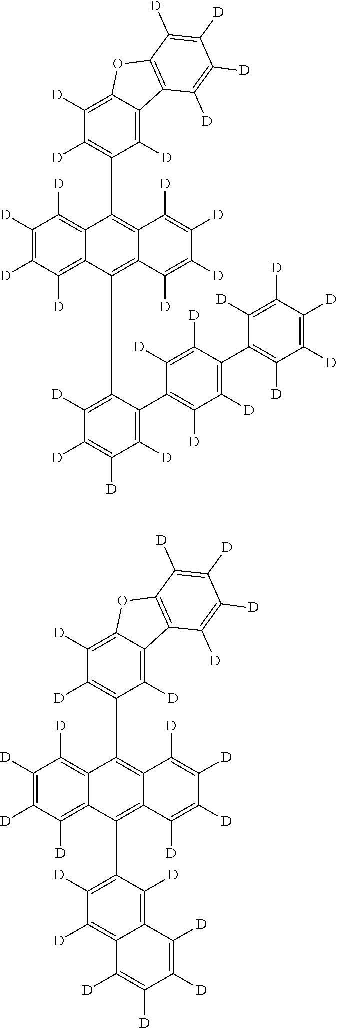 [SMILES: [2H]c1c([2H])c([2H])c(-c2c([2H])c([2H])c(-c3c([2H])c([2H])c([2H])c([2H])c3-c3c4c([2H])c([2H])c([2H])c([2H])c4c(-c4c([2H])c([2H])c5oc6c([2H])c([2H])c([2H])c([2H])c6c5c4[2H])c4c([2H])c([2H])c([2H])c([2H])c34)c([2H])c2[2H])c([2H])c1[2H] ; [2H]c1c([2H])c([2H])c2c(oc3c([2H])c([2H])c(-c4c5c([2H])c([2H])c([2H])c([2H])c5c(-c5c([2H])c([2H])c6c([2H])c([2H])c([2H])c([2H])c6c5[2H])c5c([2H])c([2H])c([2H])c([2H])c45)c([2H])c32)c1[2H]]

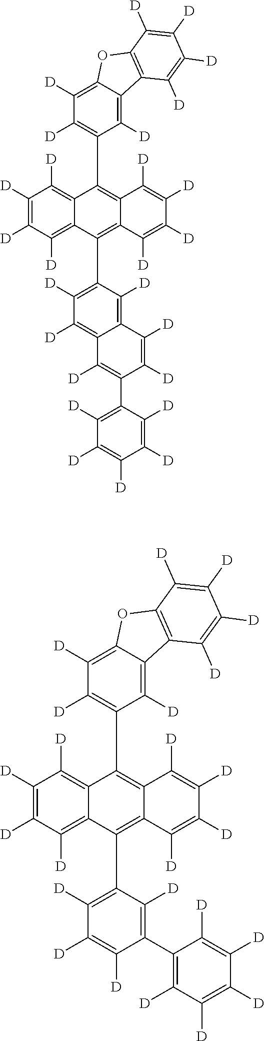 [SMILES: [2H]c1c([2H])c([2H])c(-c2c([2H])c([2H])c3c([2H])c(-c4c5c([2H])c([2H])c([2H])c([2H])c5c(-c5c([2H])c([2H])c6oc7c([2H])c([2H])c([2H])c([2H])c7c6c5[2H])c5c([2H])c([2H])c([2H])c([2H])c45)c([2H])c([2H])c3c2[2H])c([2H])c1[2H] ; [2H]c1c([2H])c([2H])c(-c2c([2H])c([2H])c([2H])c(-c3c4c([2H])c([2H])c([2H])c([2H])c4c(-c4c([2H])c([2H])c5oc6c([2H])c([2H])c([2H])c([2H])c6c5c4[2H])c4c([2H])c([2H])c([2H])c([2H])c34)c2[2H])c([2H])c1[2H]]

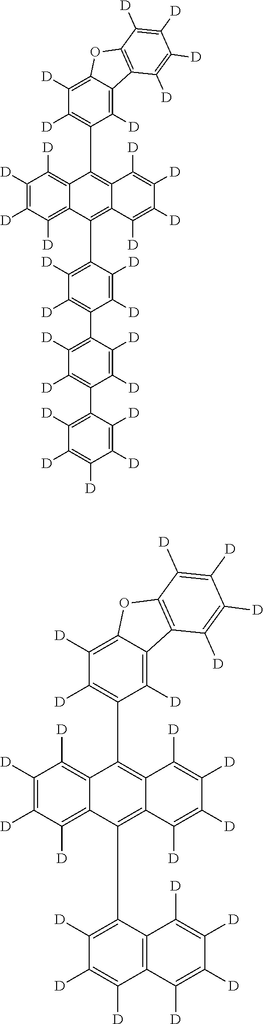 [SMILES: [2H]c1c([2H])c([2H])c(-c2c([2H])c([2H])c(-c3c([2H])c([2H])c(-c4c5c([2H])c([2H])c([2H])c([2H])c5c(-c5c([2H])c([2H])c6oc7c([2H])c([2H])c([2H])c([2H])c7c6c5[2H])c5c([2H])c([2H])c([2H])c([2H])c45)c([2H])c3[2H])c([2H])c2[2H])c([2H])c1[2H] ; [2H]c1c([2H])c([2H])c2c(oc3c([2H])c([2H])c(-c4c5c([2H])c([2H])c([2H])c([2H])c5c(-c5c([2H])c([2H])c([2H])c6c([2H])c([2H])c([2H])c([2H])c56)c5c([2H])c([2H])c([2H])c([2H])c45)c([2H])c32)c1[2H]]

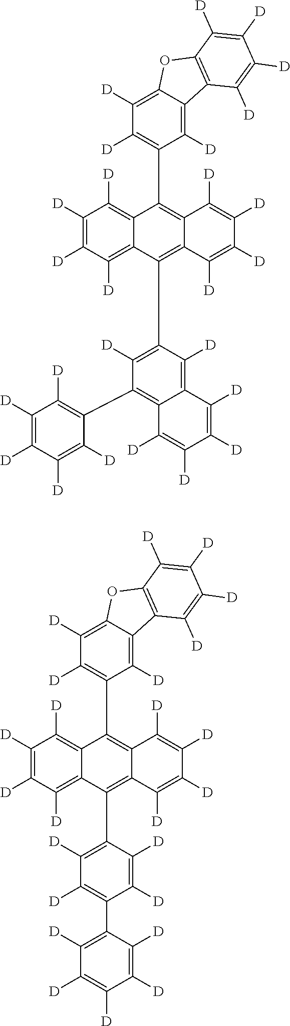 [SMILES: [2H]c1c([2H])c([2H])c(-c2c([2H])c(-c3c4c([2H])c([2H])c([2H])c([2H])c4c(-c4c([2H])c([2H])c5oc6c([2H])c([2H])c([2H])c([2H])c6c5c4[2H])c4c([2H])c([2H])c([2H])c([2H])c34)c([2H])c3c([2H])c([2H])c([2H])c([2H])c23)c([2H])c1[2H] ; [2H]c1c([2H])c([2H])c(-c2c([2H])c([2H])c(-c3c4c([2H])c([2H])c([2H])c([2H])c4c(-c4c([2H])c([2H])c5oc6c([2H])c([2H])c([2H])c([2H])c6c5c4[2H])c4c([2H])c([2H])c([2H])c([2H])c34)c([2H])c2[2H])c([2H])c1[2H]]

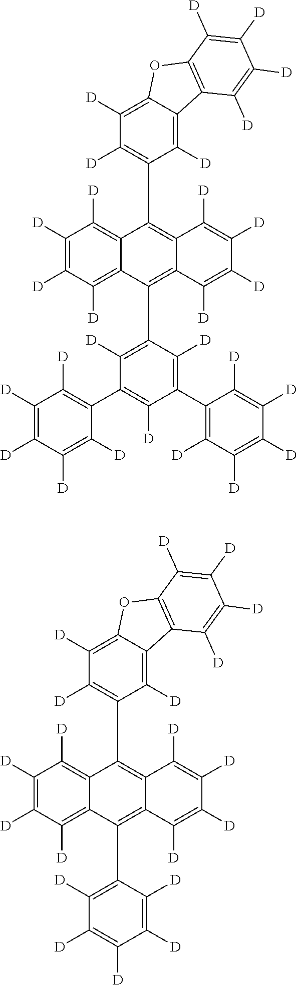 [SMILES: [2H]c1c([2H])c([2H])c(-c2c([2H])c(-c3c([2H])c([2H])c([2H])c([2H])c3[2H])c([2H])c(-c3c4c([2H])c([2H])c([2H])c([2H])c4c(-c4c([2H])c([2H])c5oc6c([2H])c([2H])c([2H])c([2H])c6c5c4[2H])c4c([2H])c([2H])c([2H])c([2H])c34)c2[2H])c([2H])c1[2H] ; [2H]c1c([2H])c([2H])c(-c2c3c([2H])c([2H])c([2H])c([2H])c3c(-c3c([2H])c([2H])c4oc5c([2H])c([2H])c([2H])c([2H])c5c4c3[2H])c3c([2H])c([2H])c([2H])c([2H])c23)c([2H])c1[2H]]

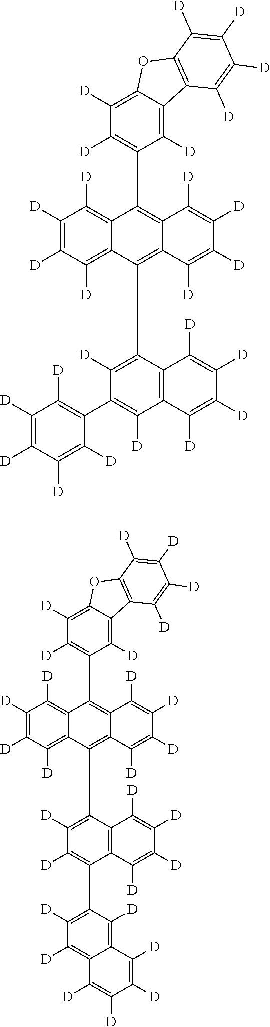 [SMILES: [2H]c1c([2H])c([2H])c(-c2c([2H])c(-c3c4c([2H])c([2H])c([2H])c([2H])c4c(-c4c([2H])c([2H])c5oc6c([2H])c([2H])c([2H])c([2H])c6c5c4[2H])c4c([2H])c([2H])c([2H])c([2H])c34)c3c([2H])c([2H])c([2H])c([2H])c3c2[2H])c([2H])c1[2H] ; [2H]c1c([2H])c([2H])c2c(oc3c([2H])c([2H])c(-c4c5c([2H])c([2H])c([2H])c([2H])c5c(-c5c([2H])c([2H])c(-c6c([2H])c([2H])c7c([2H])c([2H])c([2H])c([2H])c7c6[2H])c6c([2H])c([2H])c([2H])c([2H])c56)c5c([2H])c([2H])c([2H])c([2H])c45)c([2H])c32)c1[2H]]

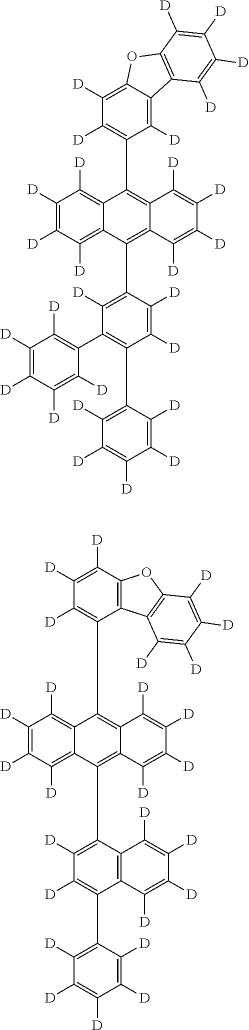 [SMILES: [2H]c1c([2H])c([2H])c(-c2c([2H])c([2H])c(-c3c4c([2H])c([2H])c([2H])c([2H])c4c(-c4c([2H])c([2H])c5oc6c([2H])c([2H])c([2H])c([2H])c6c5c4[2H])c4c([2H])c([2H])c([2H])c([2H])c34)c([2H])c2-c2c([2H])c([2H])c([2H])c([2H])c2[2H])c([2H])c1[2H] ; [2H]c1c([2H])c([2H])c(-c2c([2H])c([2H])c(-c3c4c([2H])c([2H])c([2H])c([2H])c4c(-c4c([2H])c([2H])c([2H])c5oc6c([2H])c([2H])c([2H])c([2H])c6c45)c4c([2H])c([2H])c([2H])c([2H])c34)c3c([2H])c([2H])c([2H])c([2H])c23)c([2H])c1[2H]]

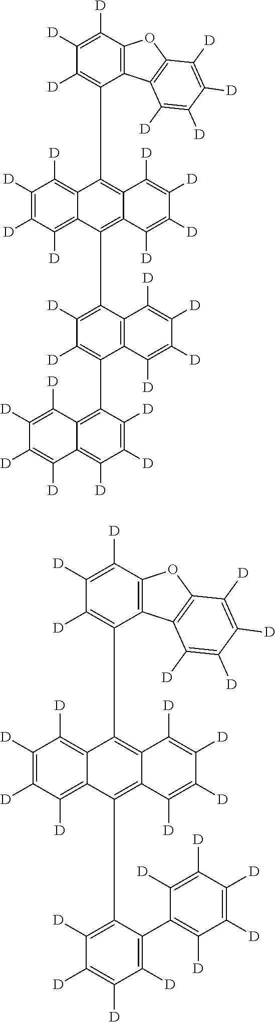 [SMILES: [2H]c1c([2H])c([2H])c2c(oc3c([2H])c([2H])c([2H])c(-c4c5c([2H])c([2H])c([2H])c([2H])c5c(-c5c([2H])c([2H])c(-c6c([2H])c([2H])c([2H])c7c([2H])c([2H])c([2H])c([2H])c67)c6c([2H])c([2H])c([2H])c([2H])c56)c5c([2H])c([2H])c([2H])c([2H])c45)c32)c1[2H] ; [2H]c1c([2H])c([2H])c(-c2c([2H])c([2H])c([2H])c([2H])c2-c2c3c([2H])c([2H])c([2H])c([2H])c3c(-c3c([2H])c([2H])c([2H])c4oc5c([2H])c([2H])c([2H])c([2H])c5c34)c3c([2H])c([2H])c([2H])c([2H])c23)c([2H])c1[2H]]

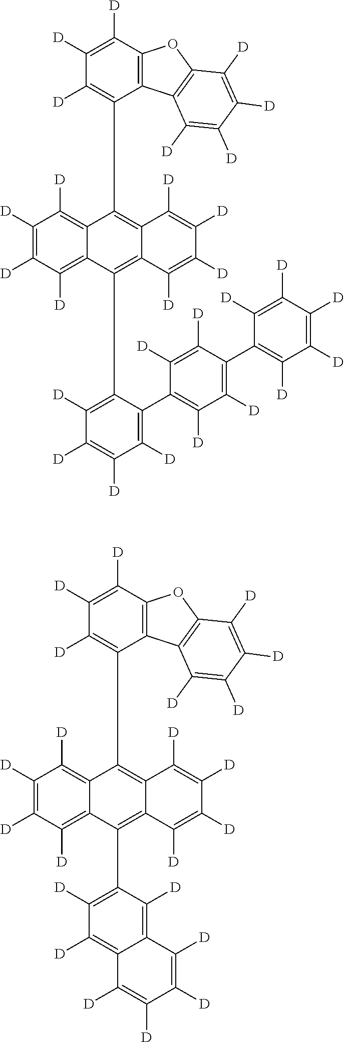 [SMILES: [2H]c1c([2H])c([2H])c(-c2c([2H])c([2H])c(-c3c([2H])c([2H])c([2H])c([2H])c3-c3c4c([2H])c([2H])c([2H])c([2H])c4c(-c4c([2H])c([2H])c([2H])c5oc6c([2H])c([2H])c([2H])c([2H])c6c45)c4c([2H])c([2H])c([2H])c([2H])c34)c([2H])c2[2H])c([2H])c1[2H] ; [2H]c1c([2H])c([2H])c2c(oc3c([2H])c([2H])c([2H])c(-c4c5c([2H])c([2H])c([2H])c([2H])c5c(-c5c([2H])c([2H])c6c([2H])c([2H])c([2H])c([2H])c6c5[2H])c5c([2H])c([2H])c([2H])c([2H])c45)c32)c1[2H]]

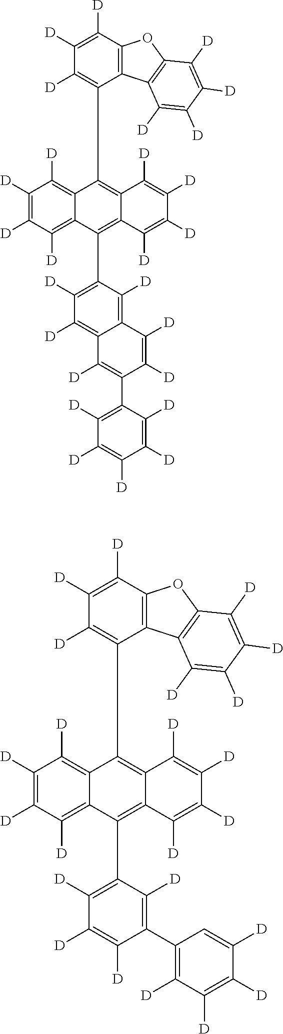 [SMILES: [2H]c1c([2H])c([2H])c(-c2c([2H])c([2H])c3c([2H])c(-c4c5c([2H])c([2H])c([2H])c([2H])c5c(-c5c([2H])c([2H])c([2H])c6oc7c([2H])c([2H])c([2H])c([2H])c7c56)c5c([2H])c([2H])c([2H])c([2H])c45)c([2H])c([2H])c3c2[2H])c([2H])c1[2H] ; [2H]c1cc(-c2c([2H])c([2H])c([2H])c(-c3c4c([2H])c([2H])c([2H])c([2H])c4c(-c4c([2H])c([2H])c([2H])c5oc6c([2H])c([2H])c([2H])c([2H])c6c45)c4c([2H])c([2H])c([2H])c([2H])c34)c2[2H])c([2H])c([2H])c1[2H]]

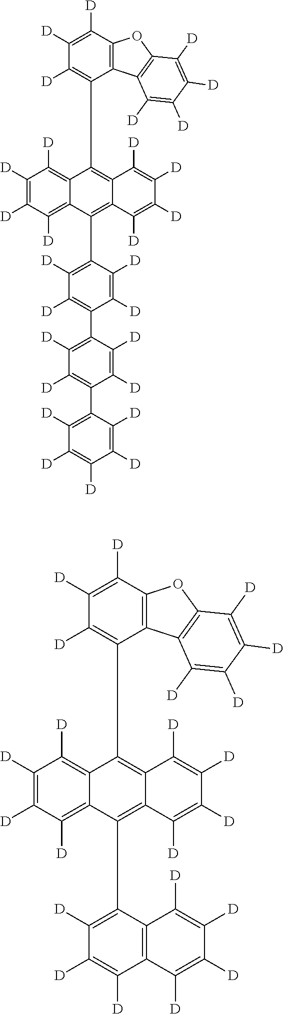 [SMILES: [2H]c1c([2H])c([2H])c(-c2c([2H])c([2H])c(-c3c([2H])c([2H])c(-c4c5c([2H])c([2H])c([2H])c([2H])c5c(-c5c([2H])c([2H])c([2H])c6oc7c([2H])c([2H])c([2H])c([2H])c7c56)c5c([2H])c([2H])c([2H])c([2H])c45)c([2H])c3[2H])c([2H])c2[2H])c([2H])c1[2H] ; [2H]c1c([2H])c([2H])c2c(oc3c([2H])c([2H])c([2H])c(-c4c5c([2H])c([2H])c([2H])c([2H])c5c(-c5c([2H])c([2H])c([2H])c6c([2H])c([2H])c([2H])c([2H])c56)c5c([2H])c([2H])c([2H])c([2H])c45)c32)c1[2H]]

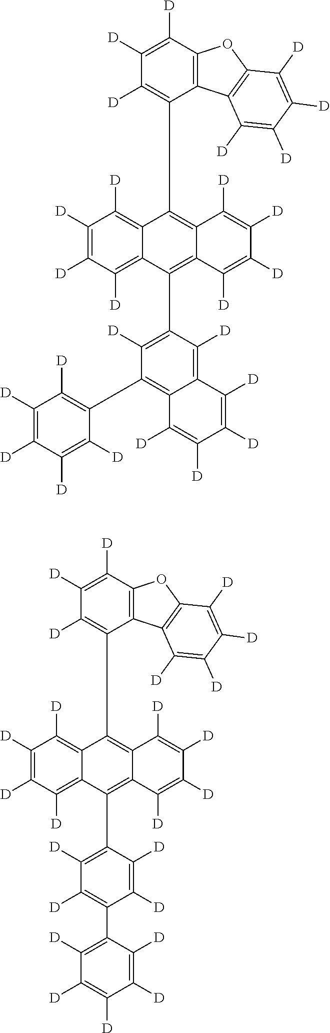 [SMILES: [2H]c1c([2H])c([2H])c(-c2c([2H])c(-c3c4c([2H])c([2H])c([2H])c([2H])c4c(-c4c([2H])c([2H])c([2H])c5oc6c([2H])c([2H])c([2H])c([2H])c6c45)c4c([2H])c([2H])c([2H])c([2H])c34)c([2H])c3c([2H])c([2H])c([2H])c([2H])c23)c([2H])c1[2H] ; [2H]c1c([2H])c([2H])c(-c2c([2H])c([2H])c(-c3c4c([2H])c([2H])c([2H])c([2H])c4c(-c4c([2H])c([2H])c([2H])c5oc6c([2H])c([2H])c([2H])c([2H])c6c45)c4c([2H])c([2H])c([2H])c([2H])c34)c([2H])c2[2H])c([2H])c1[2H]]

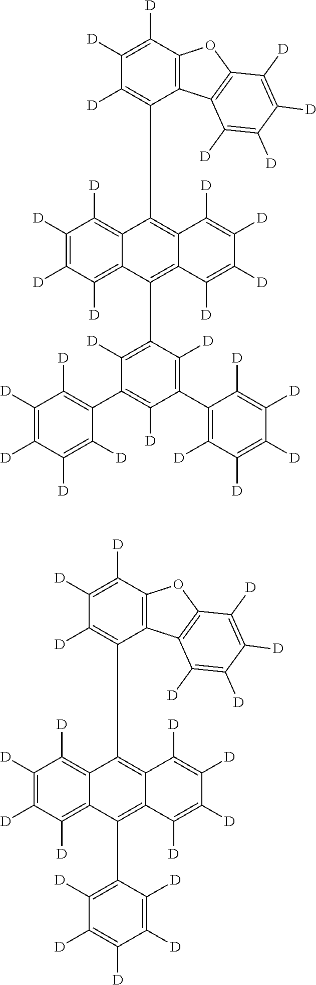 [SMILES: [2H]c1c([2H])c([2H])c(-c2c([2H])c(-c3c([2H])c([2H])c([2H])c([2H])c3[2H])c([2H])c(-c3c4c([2H])c([2H])c([2H])c([2H])c4c(-c4c([2H])c([2H])c([2H])c5oc6c([2H])c([2H])c([2H])c([2H])c6c45)c4c([2H])c([2H])c([2H])c([2H])c34)c2[2H])c([2H])c1[2H] ; [2H]c1c([2H])c([2H])c(-c2c3c([2H])c([2H])c([2H])c([2H])c3c(-c3c([2H])c([2H])c([2H])c4oc5c([2H])c([2H])c([2H])c([2H])c5c34)c3c([2H])c([2H])c([2H])c([2H])c23)c([2H])c1[2H]]

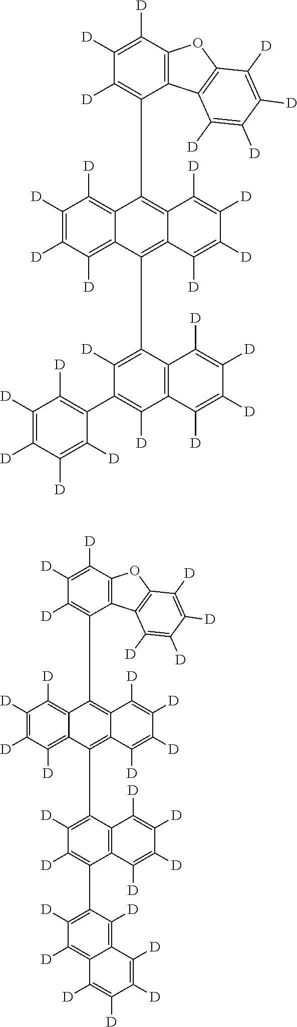 [SMILES: [2H]c1c([2H])c([2H])c(-c2c([2H])c(-c3c4c([2H])c([2H])c([2H])c([2H])c4c(-c4c([2H])c([2H])c([2H])c5oc6c([2H])c([2H])c([2H])c([2H])c6c45)c4c([2H])c([2H])c([2H])c([2H])c34)c3c([2H])c([2H])c([2H])c([2H])c3c2[2H])c([2H])c1[2H] ; [2H]c1c([2H])c([2H])c2c(oc3c([2H])c([2H])c([2H])c(-c4c5c([2H])c([2H])c([2H])c([2H])c5c(-c5c([2H])c([2H])c(-c6c([2H])c([2H])c7c([2H])c([2H])c([2H])c([2H])c7c6[2H])c6c([2H])c([2H])c([2H])c([2H])c56)c5c([2H])c([2H])c([2H])c([2H])c45)c32)c1[2H]]

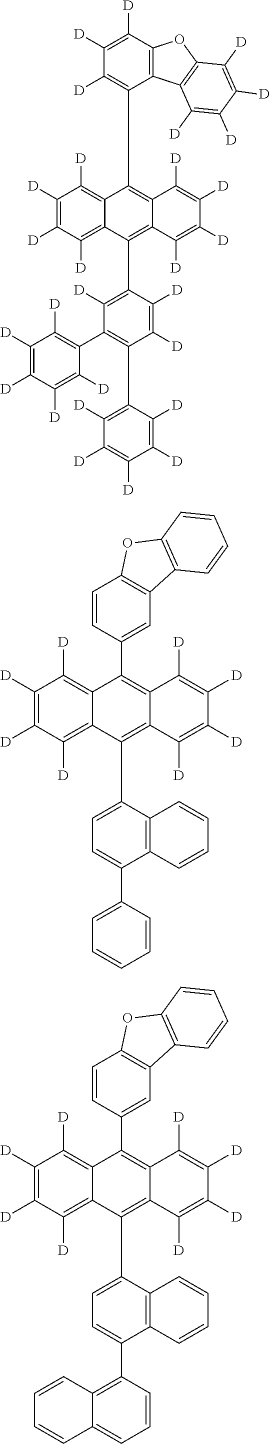 [SMILES: [2H]c1c([2H])c([2H])c(-c2c([2H])c([2H])c(-c3c4c([2H])c([2H])c([2H])c([2H])c4c(-c4c([2H])c([2H])c([2H])c5oc6c([2H])c([2H])c([2H])c([2H])c6c45)c4c([2H])c([2H])c([2H])c([2H])c34)c([2H])c2-c2c([2H])c([2H])c([2H])c([2H])c2[2H])c([2H])c1[2H] ; [2H]c1c([2H])c([2H])c2c(-c3ccc(-c4ccccc4)c4ccccc34)c3c([2H])c([2H])c([2H])c([2H])c3c(-c3ccc4oc5ccccc5c4c3)c2c1[2H] ; [2H]c1c([2H])c([2H])c2c(-c3ccc(-c4cccc5ccccc45)c4ccccc34)c3c([2H])c([2H])c([2H])c([2H])c3c(-c3ccc4oc5ccccc5c4c3)c2c1[2H]]

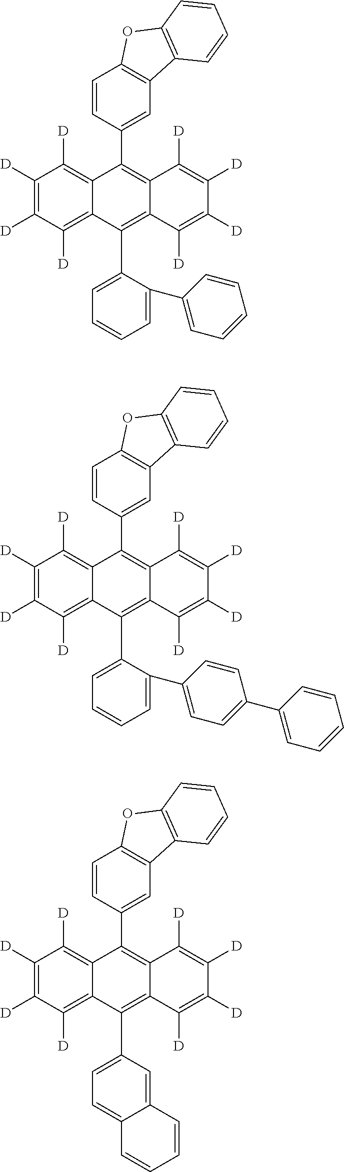 [SMILES: [2H]c1c([2H])c([2H])c2c(-c3ccccc3-c3ccccc3)c3c([2H])c([2H])c([2H])c([2H])c3c(-c3ccc4oc5ccccc5c4c3)c2c1[2H] ; [2H]c1c([2H])c([2H])c2c(-c3ccccc3-c3ccc(-c4ccccc4)cc3)c3c([2H])c([2H])c([2H])c([2H])c3c(-c3ccc4oc5ccccc5c4c3)c2c1[2H] ; [2H]c1c([2H])c([2H])c2c(-c3ccc4oc5ccccc5c4c3)c3c([2H])c([2H])c([2H])c([2H])c3c(-c3ccc4ccccc4c3)c2c1[2H]]

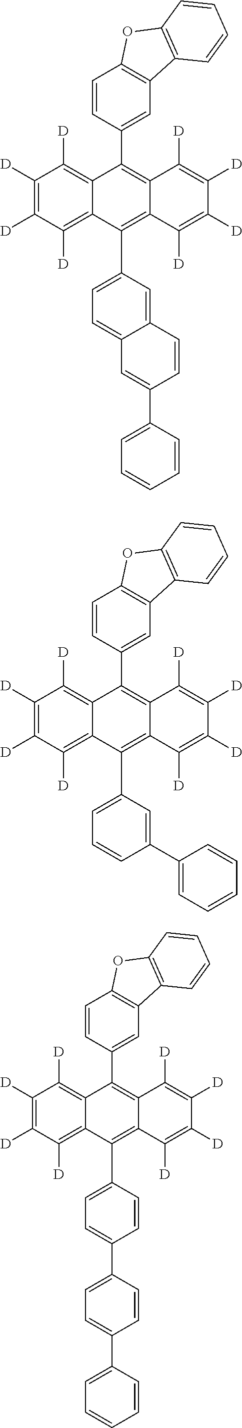

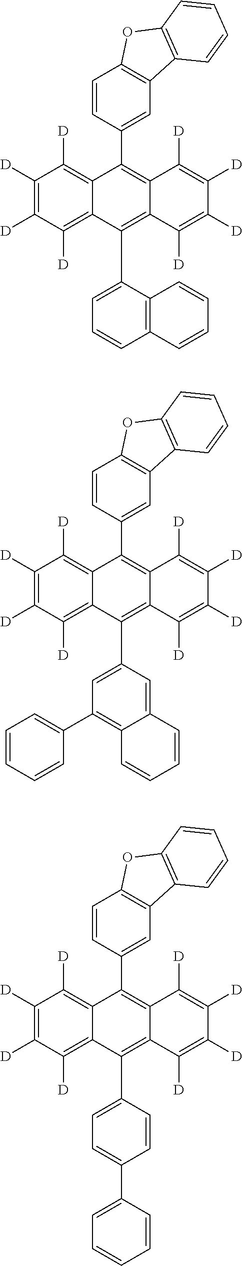

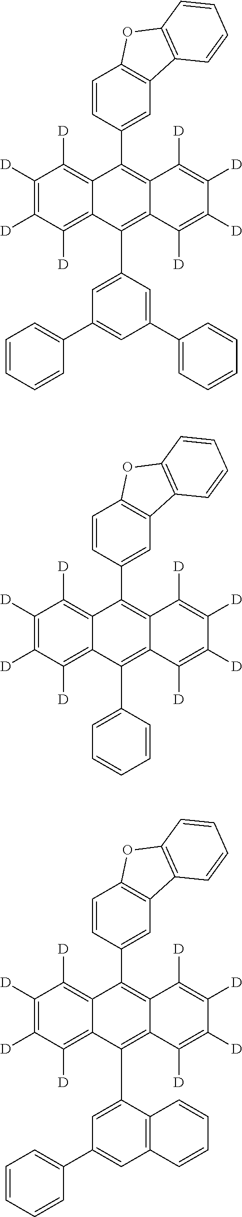 [SMILES: [2H]c1c([2H])c([2H])c2c(-c3ccc4oc5ccccc5c4c3)c3c([2H])c([2H])c([2H])c([2H])c3c(-c3cc(-c4ccccc4)cc(-c4ccccc4)c3)c2c1[2H] ; [2H]c1c([2H])c([2H])c2c(-c3ccc4oc5ccccc5c4c3)c3c([2H])c([2H])c([2H])c([2H])c3c(-c3ccccc3)c2c1[2H] ; [2H]c1c([2H])c([2H])c2c(-c3cc(-c4ccccc4)cc4ccccc34)c3c([2H])c([2H])c([2H])c([2H])c3c(-c3ccc4oc5ccccc5c4c3)c2c1[2H]]

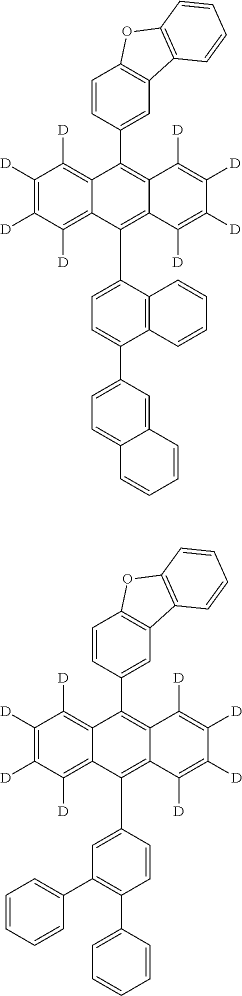 [SMILES: [2H]c1c([2H])c([2H])c2c(-c3ccc(-c4ccc5ccccc5c4)c4ccccc34)c3c([2H])c([2H])c([2H])c([2H])c3c(-c3ccc4oc5ccccc5c4c3)c2c1[2H] ; [2H]c1c([2H])c([2H])c2c(-c3ccc4oc5ccccc5c4c3)c3c([2H])c([2H])c([2H])c([2H])c3c(-c3ccc(-c4ccccc4)c(-c4ccccc4)c3)c2c1[2H]]

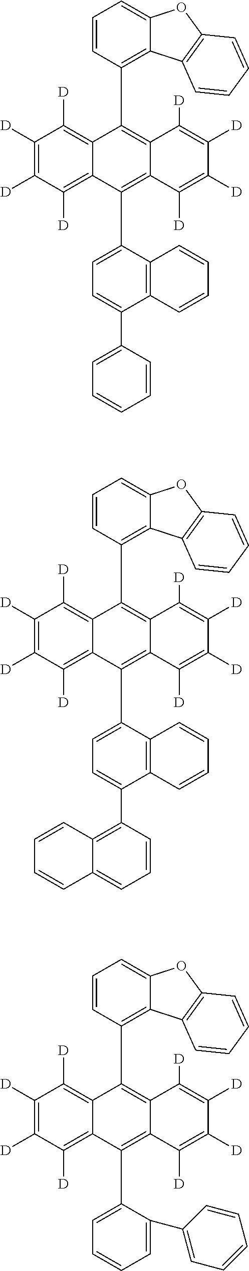 [SMILES: [2H]c1c([2H])c([2H])c2c(-c3cccc4oc5ccccc5c34)c3c([2H])c([2H])c([2H])c([2H])c3c(-c3ccc(-c4ccccc4)c4ccccc34)c2c1[2H] ; [2H]c1c([2H])c([2H])c2c(-c3cccc4oc5ccccc5c34)c3c([2H])c([2H])c([2H])c([2H])c3c(-c3ccc(-c4cccc5ccccc45)c4ccccc34)c2c1[2H] ; [2H]c1c([2H])c([2H])c2c(-c3cccc4oc5ccccc5c34)c3c([2H])c([2H])c([2H])c([2H])c3c(-c3ccccc3-c3ccccc3)c2c1[2H]]

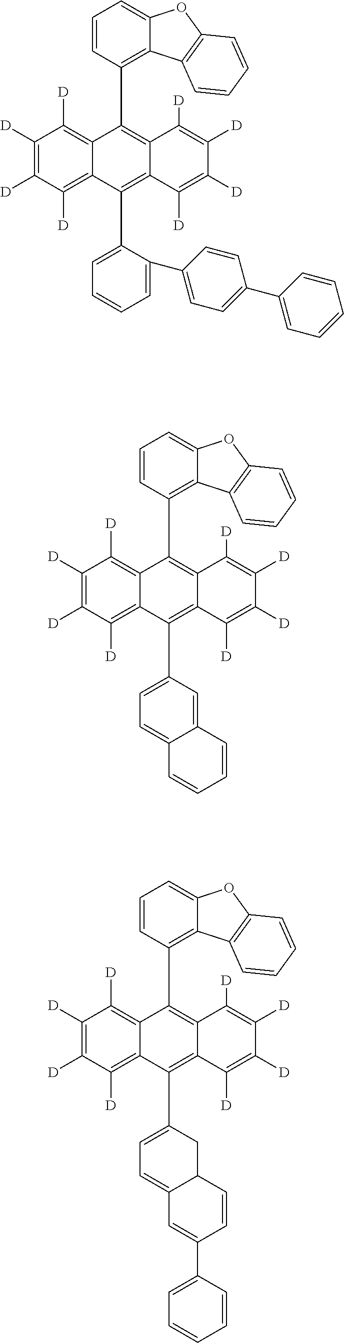 [SMILES: [2H]c1c([2H])c([2H])c2c(-c3cccc4oc5ccccc5c34)c3c([2H])c([2H])c([2H])c([2H])c3c(-c3ccccc3-c3ccc(-c4ccccc4)cc3)c2c1[2H] ; [2H]c1c([2H])c([2H])c2c(-c3cccc4oc5ccccc5c34)c3c([2H])c([2H])c([2H])c([2H])c3c(-c3ccc4ccccc4c3)c2c1[2H] ; [2H]c1c([2H])c([2H])c2c(-c3cccc4oc5ccccc5c34)c3c([2H])c([2H])c([2H])c([2H])c3c(C3=CC=C4C=C(c5ccccc5)C=CC4C3)c2c1[2H]]

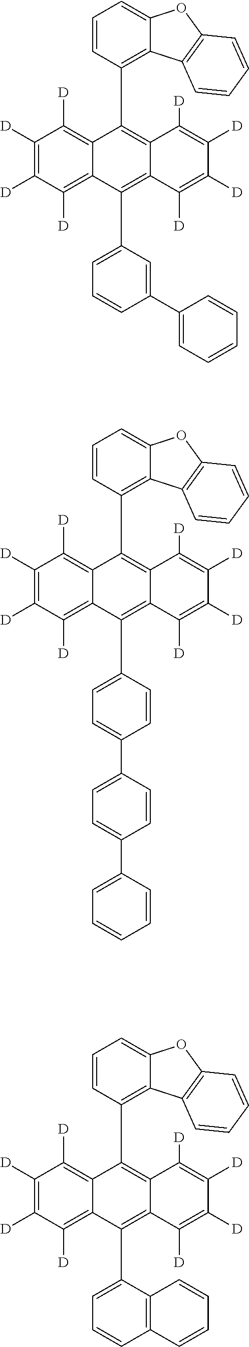 [SMILES: [2H]c1c([2H])c([2H])c2c(-c3cccc4oc5ccccc5c34)c3c([2H])c([2H])c([2H])c([2H])c3c(-c3cccc(-c4ccccc4)c3)c2c1[2H] ; [2H]c1c([2H])c([2H])c2c(-c3cccc4oc5ccccc5c34)c3c([2H])c([2H])c([2H])c([2H])c3c(-c3ccc(-c4ccc(-c5ccccc5)cc4)cc3)c2c1[2H] ; [2H]c1c([2H])c([2H])c2c(-c3cccc4oc5ccccc5c34)c3c([2H])c([2H])c([2H])c([2H])c3c(-c3cccc4ccccc34)c2c1[2H]]

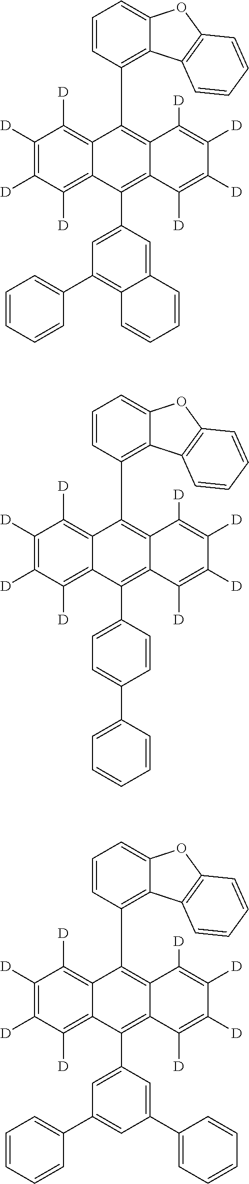 [SMILES: [2H]c1c([2H])c([2H])c2c(-c3cccc4oc5ccccc5c34)c3c([2H])c([2H])c([2H])c([2H])c3c(-c3cc(-c4ccccc4)c4ccccc4c3)c2c1[2H] ; [2H]c1c([2H])c([2H])c2c(-c3cccc4oc5ccccc5c34)c3c([2H])c([2H])c([2H])c([2H])c3c(-c3ccc(-c4ccccc4)cc3)c2c1[2H] ; [2H]c1c([2H])c([2H])c2c(-c3cccc4oc5ccccc5c34)c3c([2H])c([2H])c([2H])c([2H])c3c(-c3cc(-c4ccccc4)cc(-c4ccccc4)c3)c2c1[2H]]

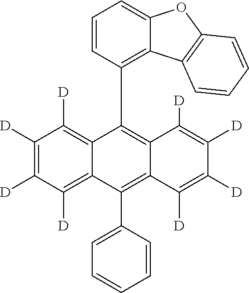 [SMILES: [2H]c1c([2H])c([2H])c2c(-c3cccc4oc5ccccc5c34)c3c([2H])c([2H])c([2H])c([2H])c3c(-c3ccccc3)c2c1[2H]]

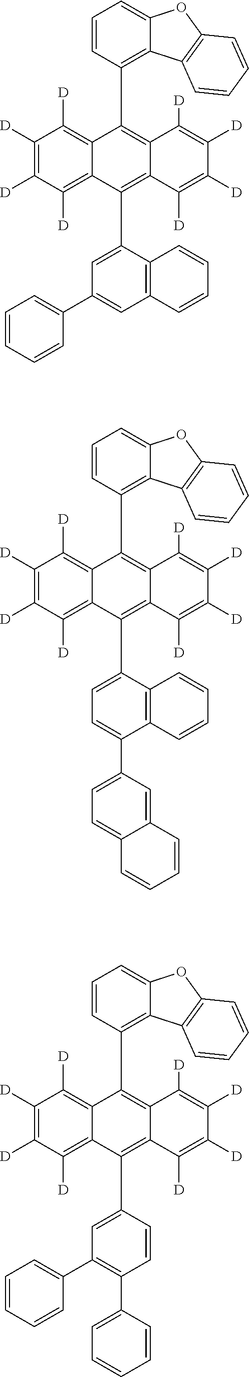 [SMILES: [2H]c1c([2H])c([2H])c2c(-c3cccc4oc5ccccc5c34)c3c([2H])c([2H])c([2H])c([2H])c3c(-c3cc(-c4ccccc4)cc4ccccc34)c2c1[2H] ; [2H]c1c([2H])c([2H])c2c(-c3cccc4oc5ccccc5c34)c3c([2H])c([2H])c([2H])c([2H])c3c(-c3ccc(-c4ccc5ccccc5c4)c4ccccc34)c2c1[2H] ; [2H]c1c([2H])c([2H])c2c(-c3cccc4oc5ccccc5c34)c3c([2H])c([2H])c([2H])c([2H])c3c(-c3ccc(-c4ccccc4)c(-c4ccccc4)c3)c2c1[2H]]

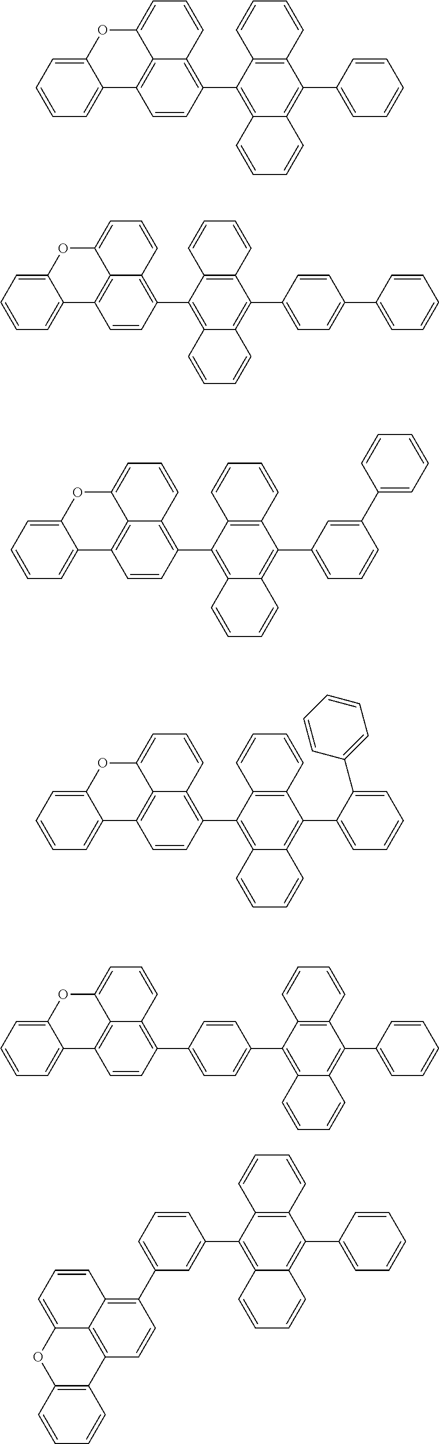

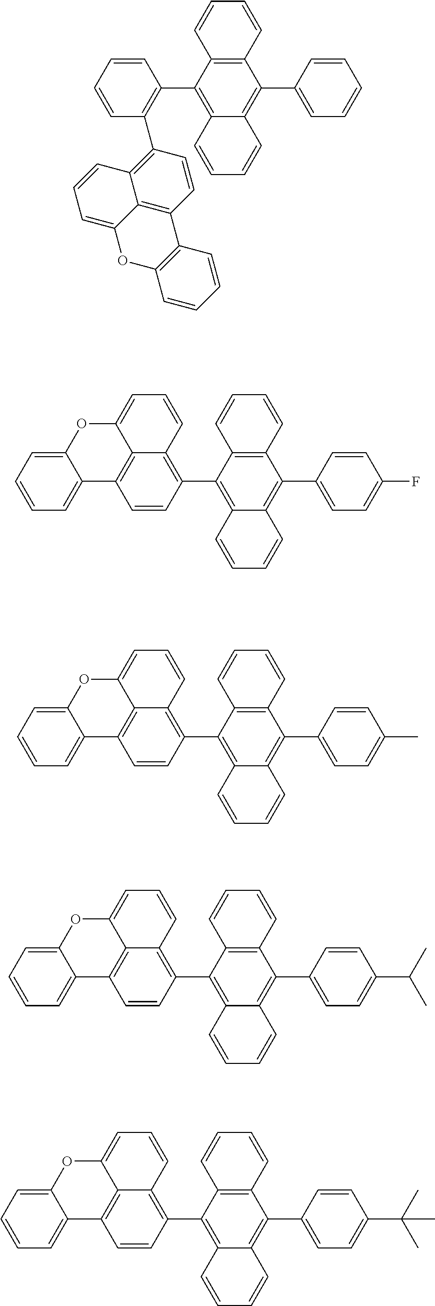 [SMILES: c1ccc(-c2c3ccccc3c(-c3ccccc3-c3ccc4c5c(cccc35)Oc3ccccc3-4)c3ccccc23)cc1 ; Fc1ccc(-c2c3ccccc3c(-c3ccc4c5c(cccc35)Oc3ccccc3-4)c3ccccc23)cc1 ; Cc1ccc(-c2c3ccccc3c(-c3ccc4c5c(cccc35)Oc3ccccc3-4)c3ccccc23)cc1 ; CC(C)c1ccc(-c2c3ccccc3c(-c3ccc4c5c(cccc35)Oc3ccccc3-4)c3ccccc23)cc1 ; CC(C)(C)c1ccc(-c2c3ccccc3c(-c3ccc4c5c(cccc35)Oc3ccccc3-4)c3ccccc23)cc1]

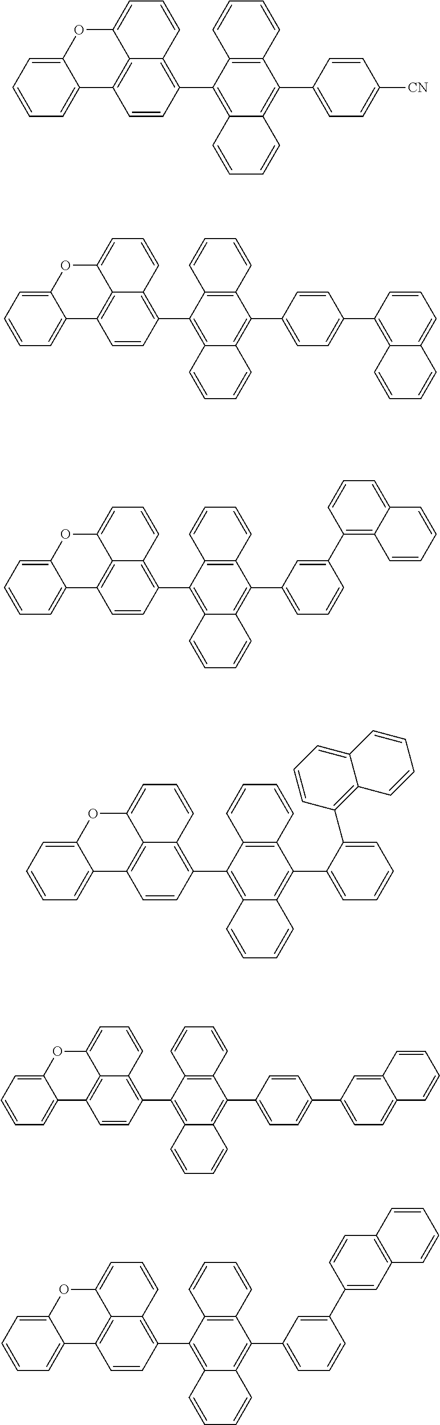 [SMILES: N#Cc1ccc(-c2c3ccccc3c(-c3ccc4c5c(cccc35)Oc3ccccc3-4)c3ccccc23)cc1 ; c1ccc2c(c1)Oc1cccc3c(-c4c5ccccc5c(-c5ccc(-c6cccc7ccccc67)cc5)c5ccccc45)ccc-2c13 ; c1cc(-c2cccc3ccccc23)cc(-c2c3ccccc3c(-c3ccc4c5c(cccc35)Oc3ccccc3-4)c3ccccc23)c1 ; c1ccc2c(c1)Oc1cccc3c(-c4c5ccccc5c(-c5ccccc5-c5cccc6ccccc56)c5ccccc45)ccc-2c13 ; c1ccc2c(c1)Oc1cccc3c(-c4c5ccccc5c(-c5ccc(-c6ccc7ccccc7c6)cc5)c5ccccc45)ccc-2c13 ; c1cc(-c2ccc3ccccc3c2)cc(-c2c3ccccc3c(-c3ccc4c5c(cccc35)Oc3ccccc3-4)c3ccccc23)c1]

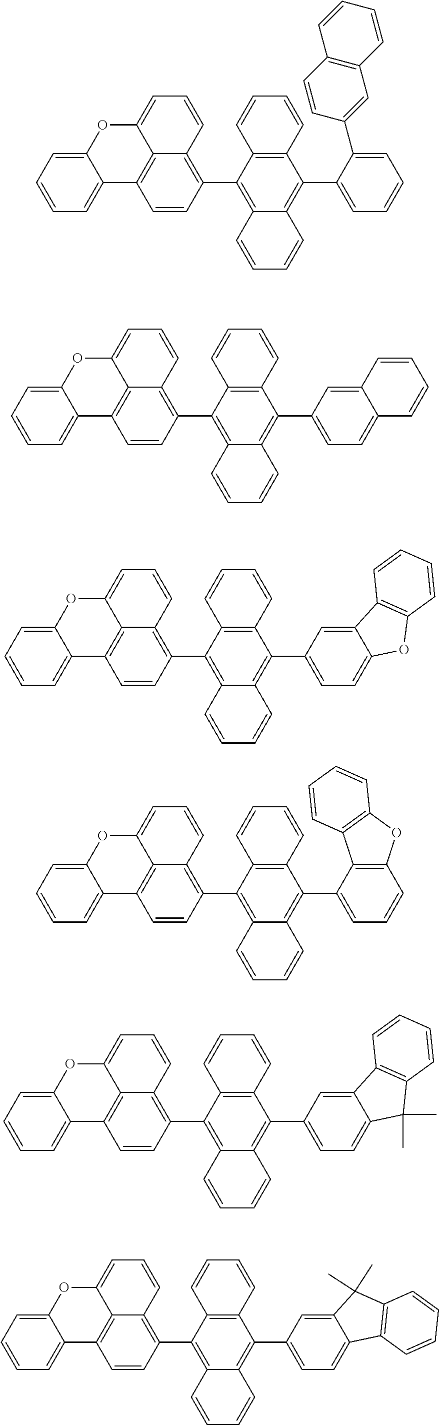 [SMILES: c1ccc2c(c1)Oc1cccc3c(-c4c5ccccc5c(-c5ccccc5-c5ccc6ccccc6c5)c5ccccc45)ccc-2c13 ; c1ccc2c(c1)Oc1cccc3c(-c4c5ccccc5c(-c5ccc6ccccc6c5)c5ccccc45)ccc-2c13 ; c1ccc2c(c1)Oc1cccc3c(-c4c5ccccc5c(-c5ccc6oc7ccccc7c6c5)c5ccccc45)ccc-2c13 ; c1ccc2c(c1)Oc1cccc3c(-c4c5ccccc5c(-c5cccc6oc7ccccc7c56)c5ccccc45)ccc-2c13 ; CC1(C)c2ccccc2-c2cc(-c3c4ccccc4c(-c4ccc5c6c(cccc46)Oc4ccccc4-5)c4ccccc34)ccc21 ; CC1(C)c2ccccc2-c2ccc(-c3c4ccccc4c(-c4ccc5c6c(cccc46)Oc4ccccc4-5)c4ccccc34)cc21]

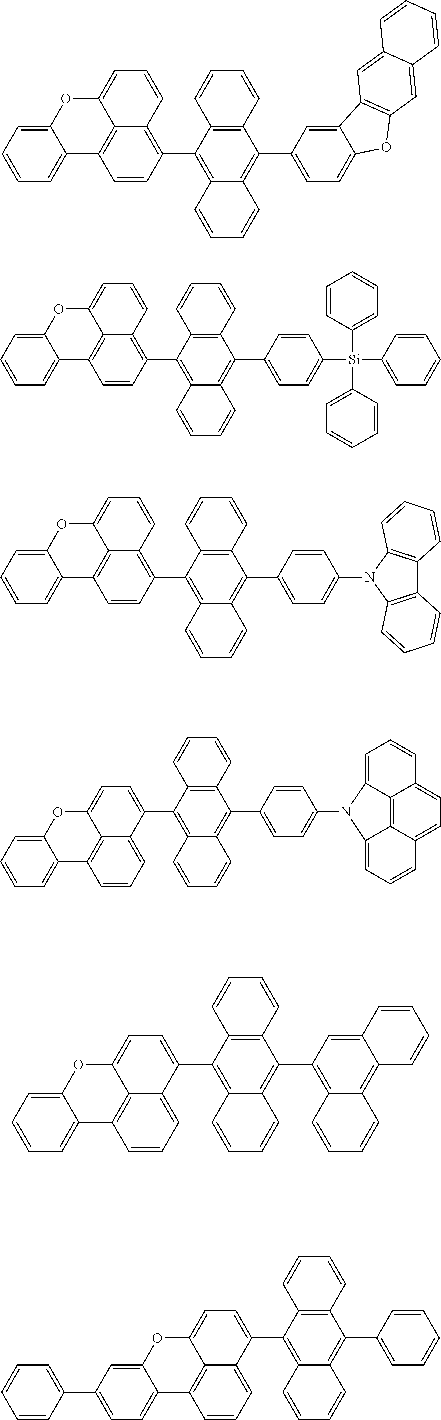

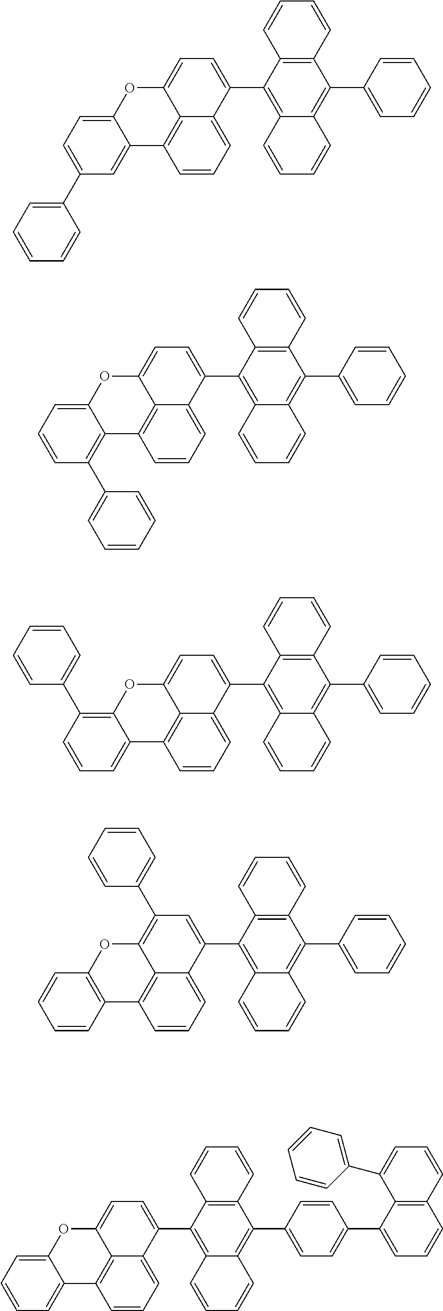 [SMILES: c1ccc(-c2ccc3c(c2)-c2cccc4c(-c5c6ccccc6c(-c6ccccc6)c6ccccc56)ccc(c24)O3)cc1 ; c1ccc(-c2cccc3c2-c2cccc4c(-c5c6ccccc6c(-c6ccccc6)c6ccccc56)ccc(c24)O3)cc1 ; c1ccc(-c2cccc3c2Oc2ccc(-c4c5ccccc5c(-c5ccccc5)c5ccccc45)c4cccc-3c24)cc1 ; c1ccc(-c2cc(-c3c4ccccc4c(-c4ccccc4)c4ccccc34)c3cccc4c3c2Oc2ccccc2-4)cc1 ; c1ccc(-c2cccc3cccc(-c4ccc(-c5c6ccccc6c(-c6ccc7c8c(cccc68)-c6ccccc6O7)c6ccccc56)cc4)c23)cc1]

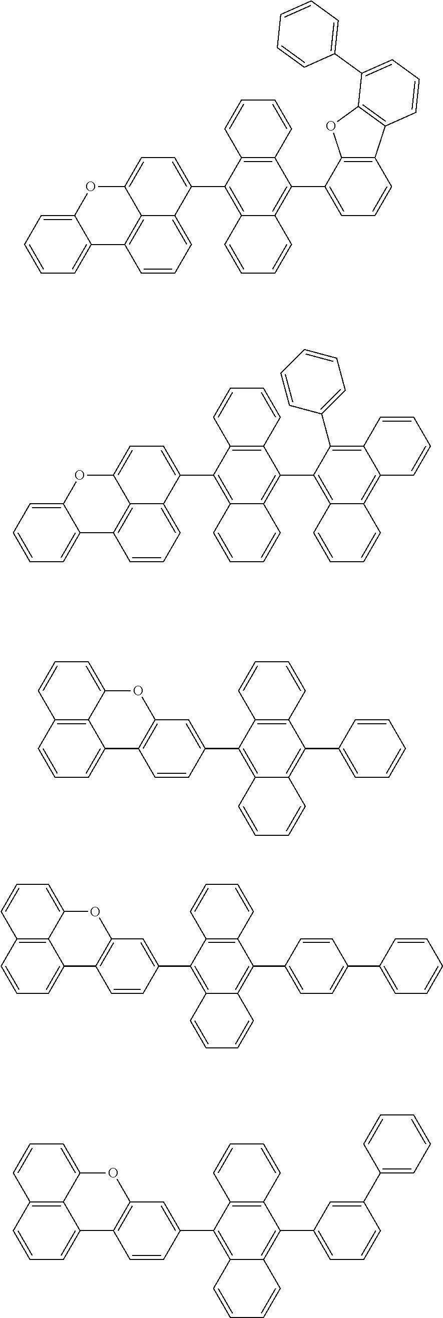 [SMILES: c1ccc(-c2cccc3c2oc2c(-c4c5ccccc5c(-c5ccc6c7c(cccc57)-c5ccccc5O6)c5ccccc45)cccc23)cc1 ; c1ccc(-c2c(-c3c4ccccc4c(-c4ccc5c6c(cccc46)-c4ccccc4O5)c4ccccc34)c3ccccc3c3ccccc23)cc1 ; c1ccc(-c2c3ccccc3c(-c3ccc4c(c3)Oc3cccc5cccc-4c35)c3ccccc23)cc1 ; c1ccc(-c2ccc(-c3c4ccccc4c(-c4ccc5c(c4)Oc4cccc6cccc-5c46)c4ccccc34)cc2)cc1 ; c1ccc(-c2cccc(-c3c4ccccc4c(-c4ccc5c(c4)Oc4cccc6cccc-5c46)c4ccccc34)c2)cc1]

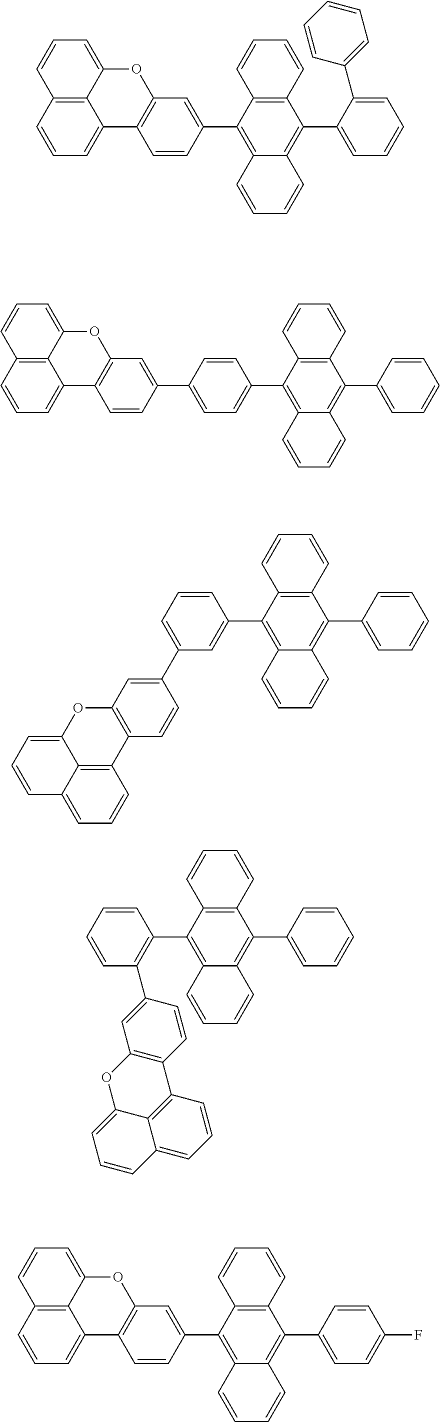 [SMILES: c1ccc(-c2ccccc2-c2c3ccccc3c(-c3ccc4c(c3)Oc3cccc5cccc-4c35)c3ccccc23)cc1 ; c1ccc(-c2c3ccccc3c(-c3ccc(-c4ccc5c(c4)Oc4cccc6cccc-5c46)cc3)c3ccccc23)cc1 ; c1ccc(-c2c3ccccc3c(-c3cccc(-c4ccc5c(c4)Oc4cccc6cccc-5c46)c3)c3ccccc23)cc1 ; c1ccc(-c2c3ccccc3c(-c3ccccc3-c3ccc4c(c3)Oc3cccc5cccc-4c35)c3ccccc23)cc1 ; Fc1ccc(-c2c3ccccc3c(-c3ccc4c(c3)Oc3cccc5cccc-4c35)c3ccccc23)cc1]

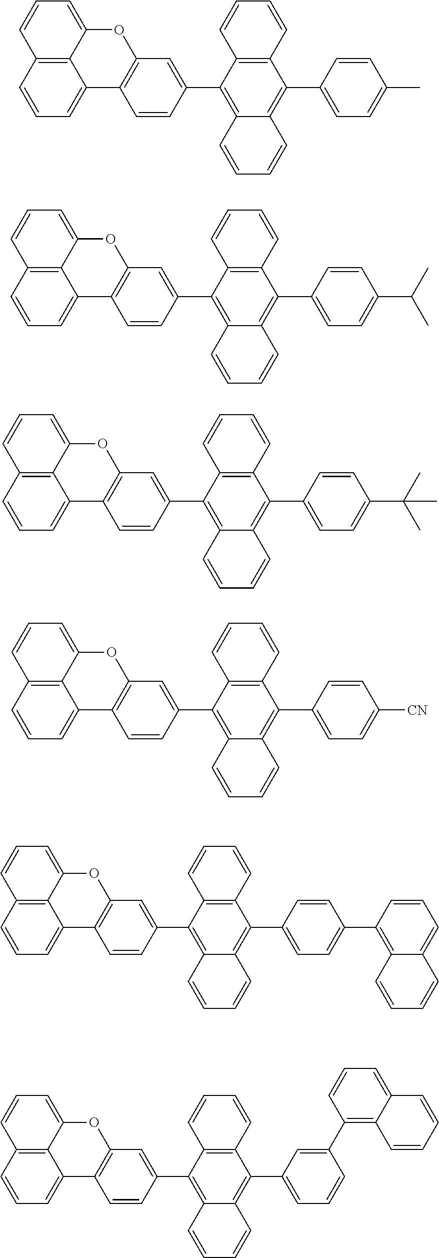

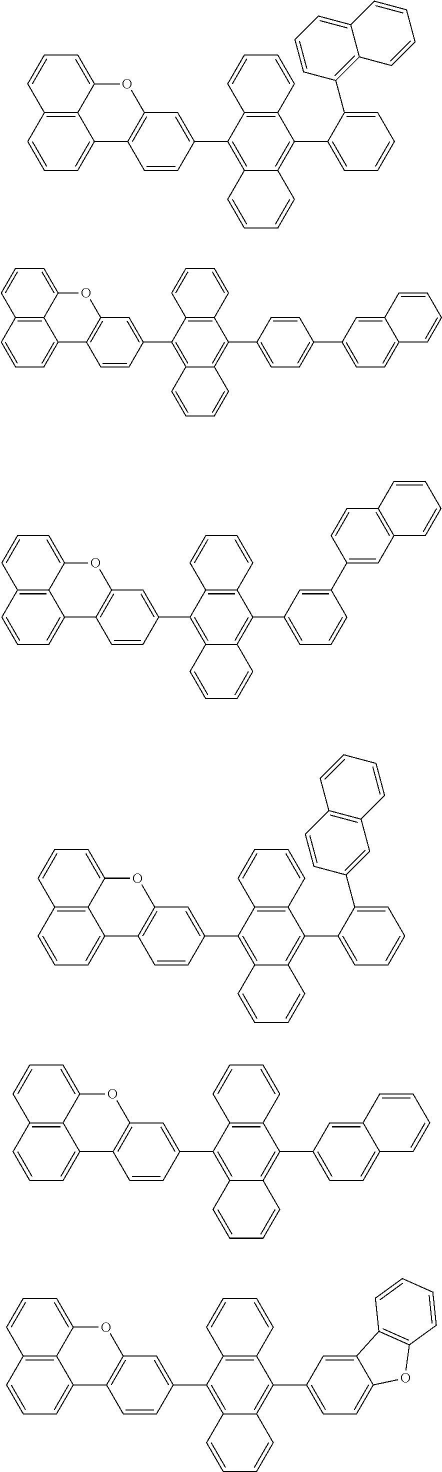

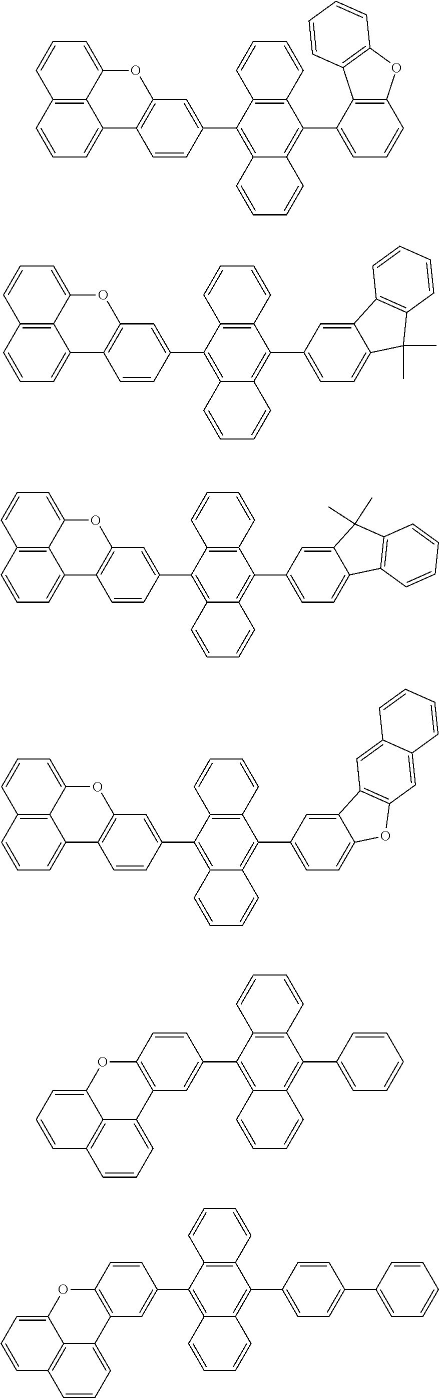 [SMILES: c1cc2c3c(cccc3c1)-c1ccc(-c3c4ccccc4c(-c4cccc5oc6ccccc6c45)c4ccccc34)cc1O2 ; CC1(C)c2ccccc2-c2cc(-c3c4ccccc4c(-c4ccc5c(c4)Oc4cccc6cccc-5c46)c4ccccc34)ccc21 ; CC1(C)c2ccccc2-c2ccc(-c3c4ccccc4c(-c4ccc5c(c4)Oc4cccc6cccc-5c46)c4ccccc34)cc21 ; c1ccc2cc3c(cc2c1)oc1ccc(-c2c4ccccc4c(-c4ccc5c(c4)Oc4cccc6cccc-5c46)c4ccccc24)cc13 ; c1ccc(-c2c3ccccc3c(-c3ccc4c(c3)-c3cccc5cccc(c35)O4)c3ccccc23)cc1 ; c1ccc(-c2ccc(-c3c4ccccc4c(-c4ccc5c(c4)-c4cccc6cccc(c46)O5)c4ccccc34)cc2)cc1]

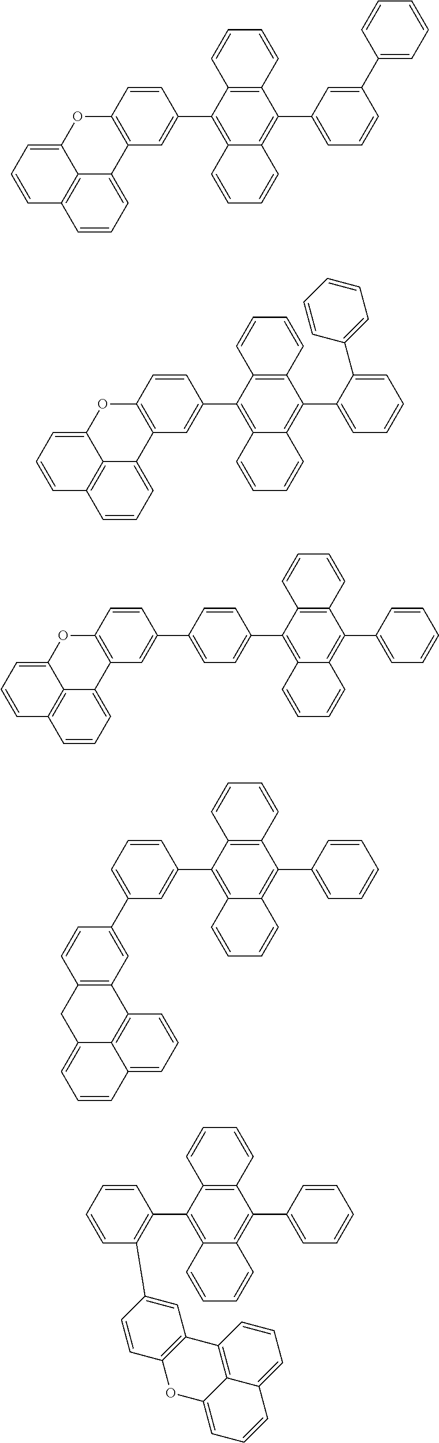

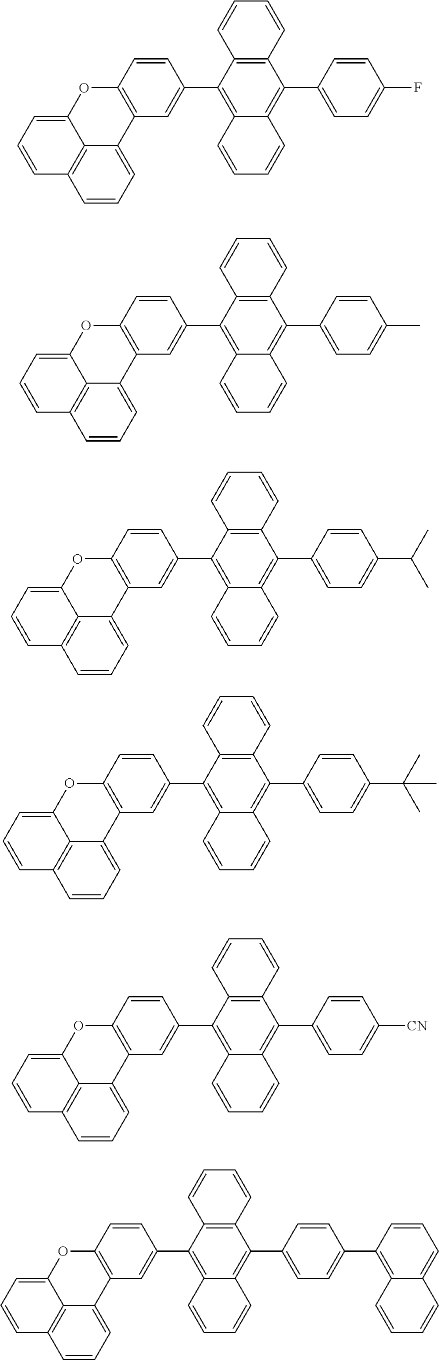 [SMILES: Fc1ccc(-c2c3ccccc3c(-c3ccc4c(c3)-c3cccc5cccc(c35)O4)c3ccccc23)cc1 ; Cc1ccc(-c2c3ccccc3c(-c3ccc4c(c3)-c3cccc5cccc(c35)O4)c3ccccc23)cc1 ; CC(C)c1ccc(-c2c3ccccc3c(-c3ccc4c(c3)-c3cccc5cccc(c35)O4)c3ccccc23)cc1 ; CC(C)(C)c1ccc(-c2c3ccccc3c(-c3ccc4c(c3)-c3cccc5cccc(c35)O4)c3ccccc23)cc1 ; N#Cc1ccc(-c2c3ccccc3c(-c3ccc4c(c3)-c3cccc5cccc(c35)O4)c3ccccc23)cc1 ; c1ccc2c(-c3ccc(-c4c5ccccc5c(-c5ccc6c(c5)-c5cccc7cccc(c57)O6)c5ccccc45)cc3)cccc2c1]

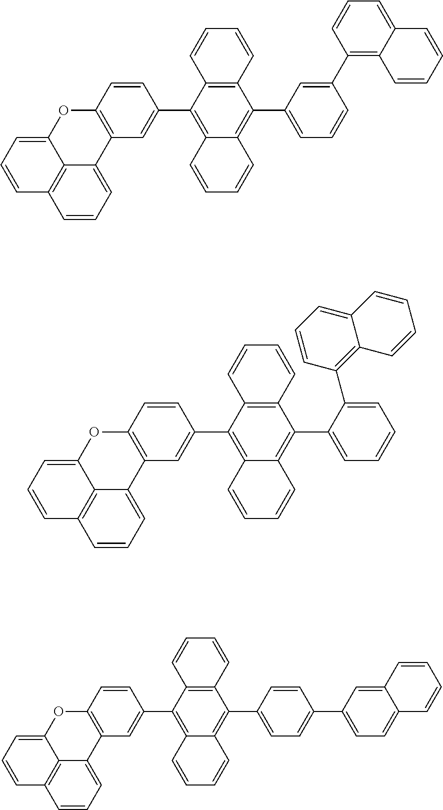 [SMILES: c1cc(-c2cccc3ccccc23)cc(-c2c3ccccc3c(-c3ccc4c(c3)-c3cccc5cccc(c35)O4)c3ccccc23)c1 ; c1ccc(-c2c3ccccc3c(-c3ccc4c(c3)-c3cccc5cccc(c35)O4)c3ccccc23)c(-c2cccc3ccccc23)c1 ; c1ccc2cc(-c3ccc(-c4c5ccccc5c(-c5ccc6c(c5)-c5cccc7cccc(c57)O6)c5ccccc45)cc3)ccc2c1]

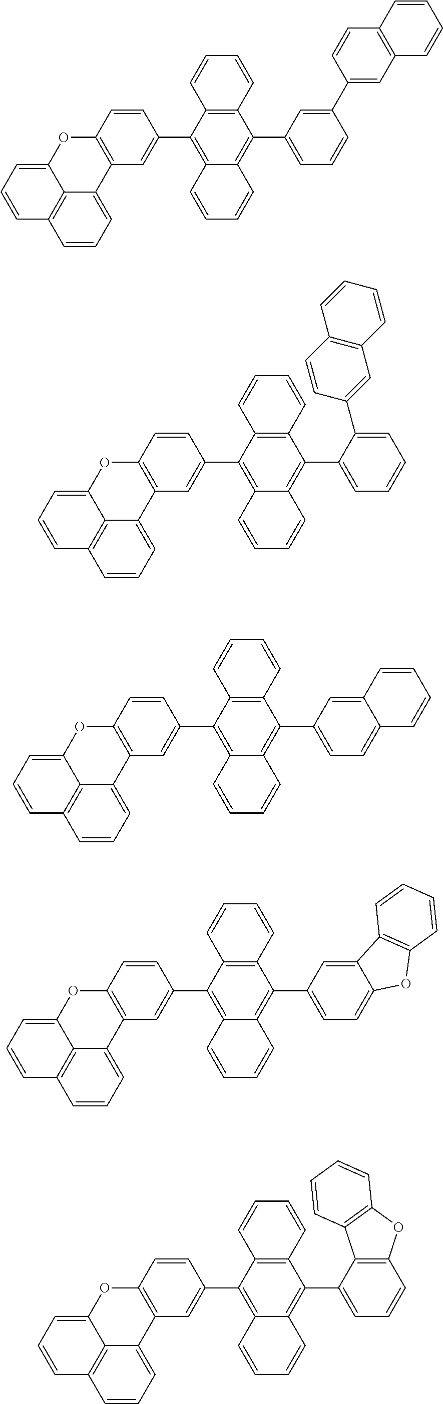 [SMILES: c1cc(-c2ccc3ccccc3c2)cc(-c2c3ccccc3c(-c3ccc4c(c3)-c3cccc5cccc(c35)O4)c3ccccc23)c1 ; c1ccc(-c2c3ccccc3c(-c3ccc4c(c3)-c3cccc5cccc(c35)O4)c3ccccc23)c(-c2ccc3ccccc3c2)c1 ; c1ccc2cc(-c3c4ccccc4c(-c4ccc5c(c4)-c4cccc6cccc(c46)O5)c4ccccc34)ccc2c1 ; c1cc2c3c(cccc3c1)-c1cc(-c3c4ccccc4c(-c4ccc5oc6ccccc6c5c4)c4ccccc34)ccc1O2 ; c1cc2c3c(cccc3c1)-c1cc(-c3c4ccccc4c(-c4cccc5oc6ccccc6c45)c4ccccc34)ccc1O2]

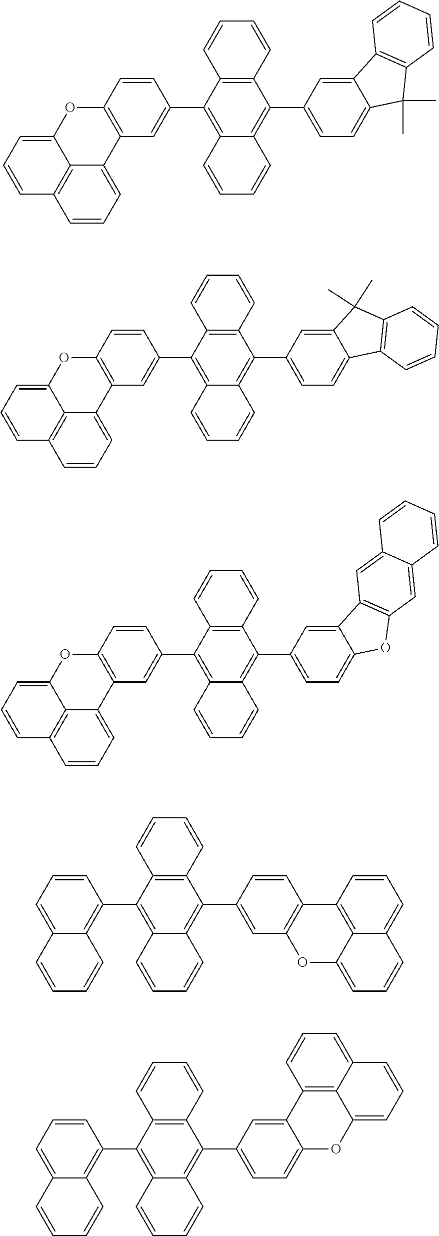

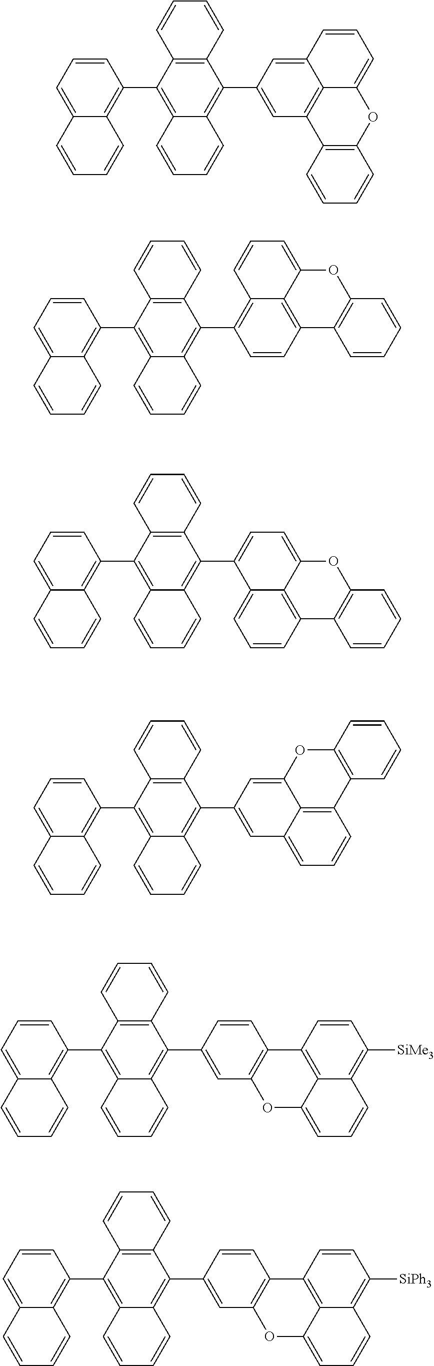

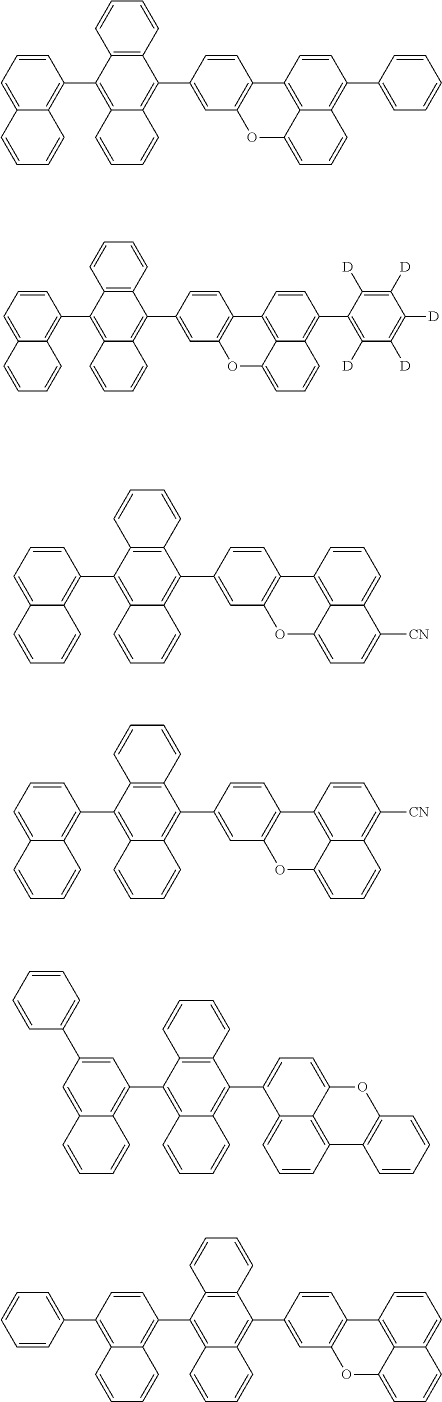 [SMILES: c1ccc(-c2ccc3c4c(cccc24)Oc2cc(-c4c5ccccc5c(-c5cccc6ccccc56)c5ccccc45)ccc2-3)cc1 ; [2H]c1c([2H])c([2H])c(-c2ccc3c4c(cccc24)Oc2cc(-c4c5ccccc5c(-c5cccc6ccccc56)c5ccccc45)ccc2-3)c([2H])c1[2H] ; N#Cc1ccc2c3c(cccc13)-c1ccc(-c3c4ccccc4c(-c4cccc5ccccc45)c4ccccc34)cc1O2 ; N#Cc1ccc2c3c(cccc13)Oc1cc(-c3c4ccccc4c(-c4cccc5ccccc45)c4ccccc34)ccc1-2 ; c1ccc(-c2cc(-c3c4ccccc4c(-c4ccc5c6c(cccc46)-c4ccccc4O5)c4ccccc34)c3ccccc3c2)cc1 ; c1ccc(-c2ccc(-c3c4ccccc4c(-c4ccc5c(c4)Oc4cccc6cccc-5c46)c4ccccc34)c3ccccc23)cc1]

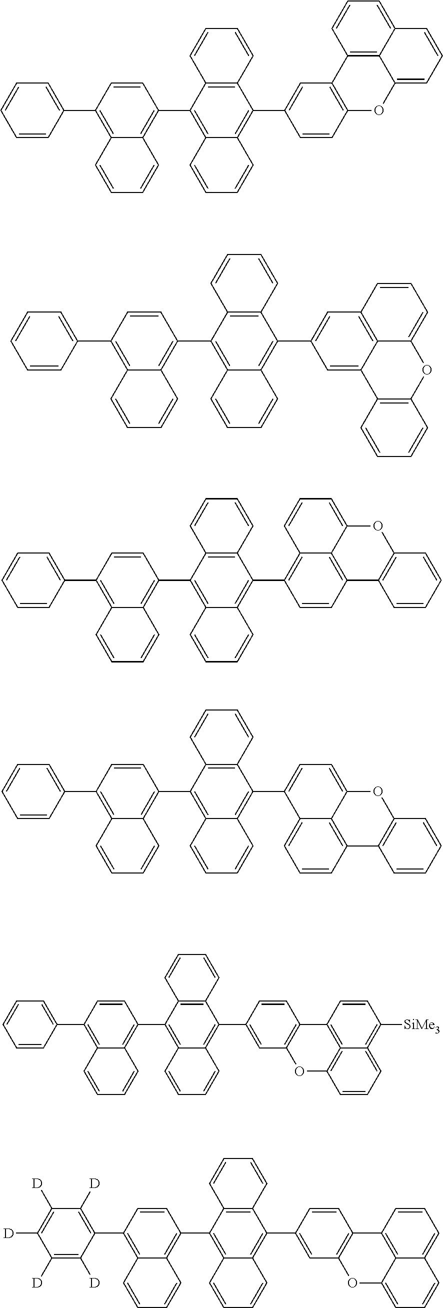

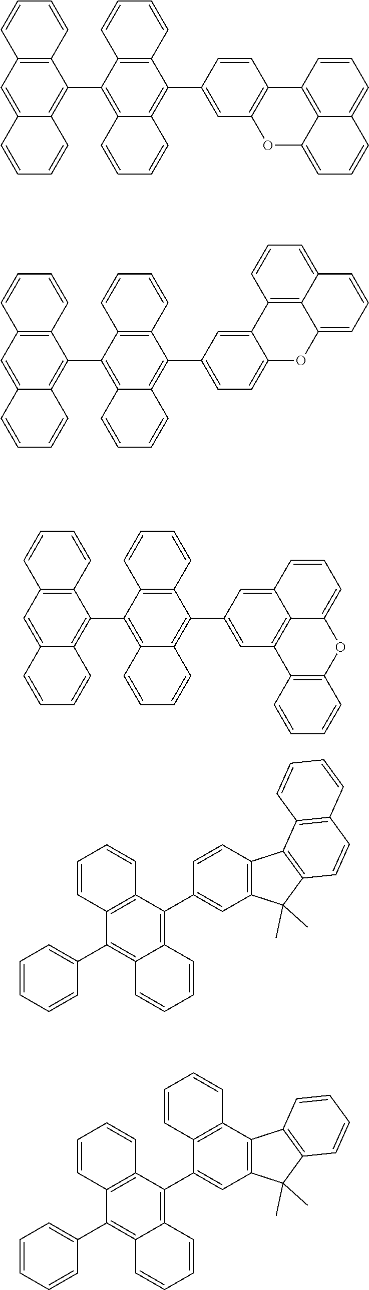

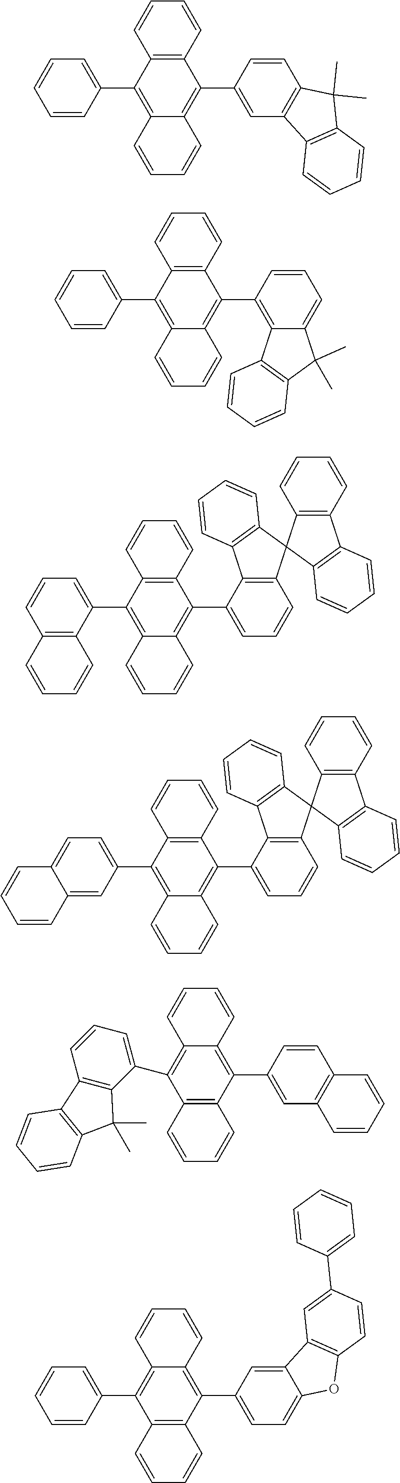

### (Second Component)

A second component in the organic EL device according to an aspect of the present invention is a compound represented by the following formula (2):

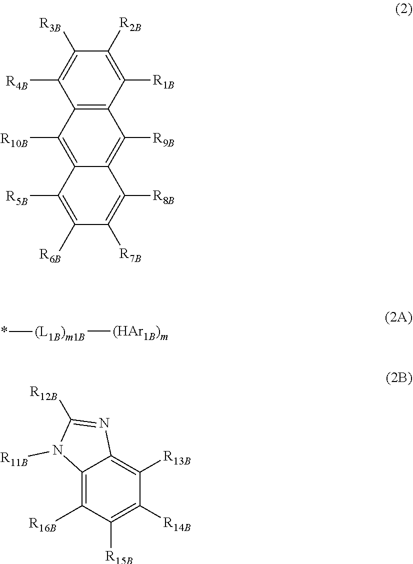

wherein in the formula (2),

at least one of R_{1B} to R_{10B} is a group represented by the formula (2A);

one or more sets of the adjacent two or more of R_{1B} to R_{10B} which are not the group represented by the formula (2A) form a substituted or unsubstituted single ring by bonding with each other, form a substituted or unsubstituted fused ring by bonding with each other, or do not bond with each other;

R_{1B} to R_{10B} which are not the group represented by the formula (2A) and which do not bond with each other are independently a hydrogen atom or a substituent R;

in the formula (2A),

HAr_{1B} is a group represented by the formula (2B); m is an integer of 1 to 5; when two or more HAr_{1B}'s are present, the two or more HAr_{1B}'s may be the same as or different from each other;

L_{1B} is

a substituted or unsubstituted aromatic hydrocarbon group having 6 to 30 ring carbon atoms, or

a substituted or unsubstituted heterocyclic group having 5 to 30 ring atoms;

m1B is an integer of 0 to 3; when m1 B is 0, m is 1 and HAr_{1B} is directly bonded with the anthracene skeleton in the formula (2) via a single bond; when m1B is 2 or 3, a plurality of L_{1B}'s is linked in series with each other and HAr_{1B} is bonded with L_{1B} which is farthest from the anthracene skeleton; when two or more L_{1B}'s are present, the two or more L_{1B}'s may be the same as or different from each other;

in the formula (2B),

any one of R_{11B} to R_{16B} represents a bond with L_{1B} in the formula (2A); when m1B is 0, any of carbon atoms and nitrogen atoms in the benzimidazole and any of carbon atoms in the anthracene skeleton of the formula (2) are directly bonded via a single bond;

one or more sets of the adjacent two or more of R_{11B} to R_{16B} which do not represent a bond with L_{1B} form a substituted or unsubstituted single ring by bonding with each other, form a substituted or unsubstituted fused ring by bonding with each other, or do not bond with each other;

R_{11B} to R_{16B} which do not represent a bond with L_{1B} and which do not bond with each other are independently a hydrogen atom or a substituent R; and

the substituent R is the same as defined in the formula (1).

In the formula (2), at least one of R_{1B} to R_{10B} is the group represented by the formula (2A). The number of the group represented by the formula (2A) in R_{1B} to R_{10B} is not limited, and only any one of R_{1B} to R_{10B} may be the group represented by the formula (2A), or two or more of R_{1B} to R_{10B} may be the group represented by the formula (2A). When a plurality of groups represented by the formula (2A) is present, each of them may be the same as or different from each other.

In one embodiment, at least one of R_{1B}, R_{4B}, R_{5B}, and R_{8B} to R_{10B} is the group represented by the formula (2A).

In one embodiment, at least one of R_{9B} and R_{10B} is the group represented by the formula (2A).

R_{1B} to R_{10B} which are not the group represented by the formula (2A) will be described.

In one embodiment, one or more sets of the adjacent two or more of R_{1B} to R_{10B} do not bond with each other.

R_{1B} to R_{10B} which are not the group represented by the formula (2A) are independently a hydrogen atom or a substituent R, and all of them may be hydrogen atoms, or a part of them may be the substituent R.

In one embodiment, R_{1B} to R_{8B} are hydrogen atoms.

In one embodiment, one of R_{9B} and R_{10B} is the group represented by the formula (2A), and the other of R_{9B} and R_{10B} is the substituent R, and R_{1B} to R_{8B} are hydrogen atoms.

In one embodiment, R_{1B} to R_{10B} which is the substituent R is a substituted or unsubstituted aryl group having 6 to 50 ring carbon atoms, or a substituted or unsubstituted monovalent heterocyclic group having 5 to 50 ring atoms.

The group represented by the formula (2A) will be described.

When m1B is 0, m is 1 and HAr_{1B} is directly bonded with the anthracene skeleton in the formula (2) via a single bond. When m1B is 2 or 3, a plurality of L_{1B}'s is linked in series with each other and HAr_{1B} is bonded with L_{1B} which is farthest from the anthracene skeleton.

When m is 2 or more and m1 B is 1, two or more of each of HAr_{1B}'s are bonded with L_{1B}. When m is 2 or more and m1B is 2 or 3, two or more of each of HAr_{1B}'s are is bonded with L_{1B} which is farthest from the anthracene skeleton.

For example, when R_{9B} is the group represented by the formula (2A), m1 B is 2, and m is 2, the compound represented by the formula (2) is the following structure.

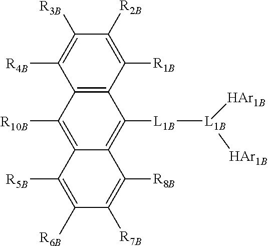

In one embodiment, L_{1B} is an unsubstituted aromatic hydrocarbon group having 6 to 30 ring carbon atoms, or an unsubstituted heterocyclic group having 5 to 30 ring atoms.

In one embodiment, L_{1B} is a substituted or unsubstituted aromatic hydrocarbon group having 6 to 30 ring carbon atoms.

m1B is not particularly limited, m1B may be any of 0, 1, 2 and 3, and in one embodiment, m1B is 1 or 2.

m is not particularly limited, m may be any of 1, 2, 3, 4 and 5, and in one embodiment, m is 1.

The group represented by the formula (2B) will be described.

Any one of R_{11B} to R_{16B} represents a bond with L_{1B} in the formula (2A). The expression “represents a bond” means any of carbon atoms and nitrogen atoms in the benzimidazole which R_{11B} to R_{16B} are bonded with and L_{1B} are directly bonded. When m1B is 0, any of carbon atoms and nitrogen atoms in the benzimidazole and any of carbon atoms in the anthracene skeleton of the formula (2) are directly bonded via a single bond.

In one embodiment, any one of R_{11B} to R_{13B} and R_{16B} represents a bond with L_{1B} in the formula (2A).

In one embodiment, any one of R_{11B} and R_{13B} to R_{16B} represents a bond with L_{1B} in the formula (2A).

In one embodiment, any one of R_{11B} and R_{13B} to R_{16B} represents a bond with L_{1B} in the formula (2A),

R_{12B} is

a hydrogen atom,

a substituted or unsubstituted alkyl group having 1 to 50 carbon atoms,

a substituted or unsubstituted alkenyl group having 2 to 50 carbon atoms,

a substituted or unsubstituted alkynyl group having 2 to 50 carbon atoms,

a substituted or unsubstituted cycloalkyl group having 3 to 50 ring carbon atoms,

—Si(R₉₀₁)(R₉₀₂)(R₉₀₃),

—O—(R₉₀₄),

—S—(R₉₀₅),

—N(R₉₀₆)(R₉₀₇)

(wherein R₉₀₁ to R₉₀₇ are the same as defined in the formula (1)),

a halogen atom, a cyano group, a nitro group,

an unsubstituted aryl group having 6 to 50 ring carbon atoms, or

a substituted or unsubstituted monovalent heterocyclic group having 5 to 50 ring atoms.

In one embodiment, R_{11B} represents the bond with L_{1B} in the formula (2A).

R_{11B} to R_{16B} which do not represent a bond with L_{1B} are independently a hydrogen atom or a substituent R. All of R_{11B} to R_{16B} which do not represent a bond with L_{1B} may be hydrogen atoms, or part of them may be the substituent R, and for example, R_{11B} or R_{12B} may be the substituent R.

When R_{11B} represents a bonding position with L_{1B}, R_{12B} may be the substituent R. In such a case, R_{13B} to R_{16B} may be hydrogen atoms.

In one embodiment, R_{12B} represents the bond with L_{1B} in the formula (2A). In such a case, R_{11B} may be the substituent R. In such a case, R_{13B} to R_{16B} may be hydrogen atoms.

In one embodiment, R_{11B} to R_{16B} which are the substituents R are independently a substituted or unsubstituted alkyl group having 1 to 50 carbon atoms, or a substituted or unsubstituted aryl group having 6 to 50 ring carbon atoms.

In one embodiment, the compound represented by the formula (2) is a compound represented by the following formula (2-1):

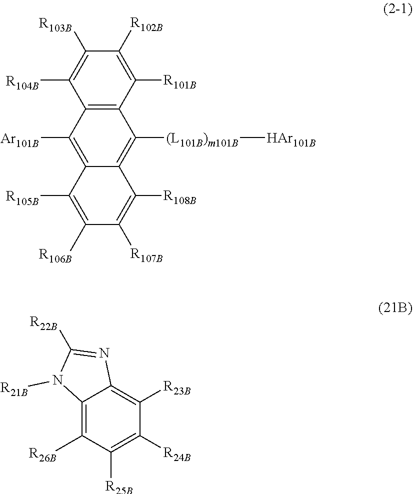

wherein in the formula (2-1),

one or more sets of the adjacent two or more of R_{101B} to R_{108B} form a substituted or unsubstituted single ring by bonding with each other, form a substituted or unsubstituted fused ring by bonding with each other, or do not bond with each other;

R_{101B} to R_{108B} which do not bond with each other are independently a hydrogen atom or a substituent R;

HAr_{101B} is a group represented by the formula (21B);

L_{101B} is

a substituted or unsubstituted aromatic hydrocarbon group having 6 to 30 ring carbon atoms, or

a substituted or unsubstituted heterocyclic group having 5 to 30 ring atoms;

m101B is an integer of 0 to 3; when m101B is 0, HAr_{101B} is directly bonded with the anthracene skeleton in the formula (2-1) via a single bond; when m101B is 2 or 3, a plurality of L_{101B}'s is linked in series with each other and HAr_{101B} is bonded with L_{101B} which is farthest from the anthracene skeleton; when two or more L_{101B}'s are present, the two or more L_{101B}'s may be the same as or different from each other;

one or more sets of the adjacent two or more of m101B L_{101B}'s and HAr_{101B} do not bond with each other;

in the formula (21 B),

any one of R_{21B} to R_{26B} represents a bond with L₁₀₁B in the formula (2-1); when m101B is 0, any of carbon atoms and nitrogen atoms in the benzimidazole and any of carbon atoms in the anthracene skeleton of the formula (2-1) are directly bonded via a single bond;

R_{21B} to R_{26B} which do not represent a bond with L₁₀₁B are independently a hydrogen atom or a substituent R; one or more sets of the adjacent two or more of R_{21B} to R_{26B} do not bond with each other;

Ar_{101B} is

a substituted or unsubstituted aryl group having 6 to 30 ring carbon atoms, or

a substituted or unsubstituted monovalent heterocyclic group having 5 to 30 ring atoms; and

the substituent R is the same as defined in the formula (1).

In one embodiment, one or more sets of the adjacent two or more of R_{101B} to R_{108B} do not bond with each other.

R₁₀₁B ^{to R}_{108B} are independently a hydrogen atom ora substituent R, and all of them may be hydrogen atoms, or part of them may be the substituent R.

In one embodiment, R_{101B} to R_{108B} are hydrogen atoms.

When m101B is 0, HAr_{101B} is directly bonded with the anthracene skeleton in the formula (2-1) via a single bond. When m101B is 2 or 3, a plurality of L_{101B}'s is linked in series with each other and HAr_{101B} is bonded with L_{101B} which is farthest from the anthracene skeleton.

In one embodiment, L_{101B} is a substituted or unsubstituted aromatic hydrocarbon group having 6 to 30 ring carbon atoms.

m101 B is not particularly limited, m101 B may be any of 0, 1, 2 and 3, and in one embodiment, m101B is 1 or 2.

R_{21B} to R_{26B} in the formula (21 B) are the same as described in R_{11B} to R_{16B} of the formula (2 B).

In one embodiment, the compound represented by the formula (2-1) is a compound represented by the following formula (2-11):

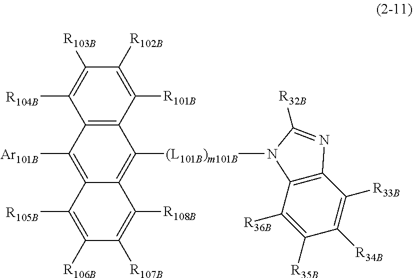

wherein in the formula (2-11),

R_{101B} to R_{108B}, L_{101B}, m101B, and Ar_{101B} are the same as defined in the formula (2-1);

R_{32B} to R_{36B} are independently a hydrogen atom or a substituent R; one or more sets of the adjacent two or more of R_{32B} to R_{36B} do not bond with each other; and the substituent R is the same as defined in the formula (1).

The compound represented by the formula (2-11) is one in which the bonding position of the group represented by the formula (21B) and L_{101B} is specified in the compound represented by the formula (2-1). The conditions other than that are the same as described in the formula (2-1).

In one embodiment, m101B is 1.

In one embodiment, the compound represented by the formula (2-1) is a compound represented by the following formula (2-12):

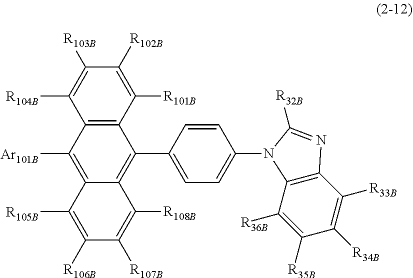

wherein in the formula (2-12), R_{101B} to R_{108B} and Ar_{101B} are the same as defined in the formula (2-1);

R_{32B} to R_{36B} are independently a hydrogen atom or a substituent R; one or more sets of the adjacent two or more of R_{32B} to R_{36B} do not bond with each other; and the substituent R is the same as defined in the formula (1).

The compound represented by the formula (2-12) is one in which aspects of L_{101B} and m101B are specified in the compound represented by the formula (2-11). The conditions other than that are the same as described in the formula (2-1) or (2-11).

As understood by the [Definition], hydrogen atoms possessed by the phenylene group arranged between the anthracene skeleton and the benzimidazole skeleton may be deuterium atoms.

In one embodiment, the compound represented by the formula (2-1) is a compound represented by the following formula (2-13):

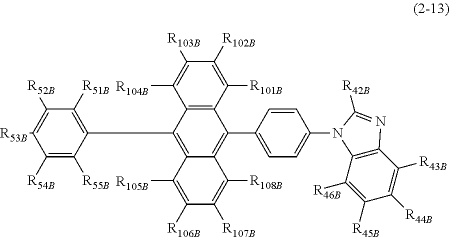

wherein in the formula (2-13),

R_{101B} to R_{108B} are the same as defined in the formula (2-1);

R_{42B} to R_{46B} are independently

a hydrogen atom, or

a substituted or unsubstituted alkyl group having 1 to 50 carbon atoms;

one or more sets of the adjacent two or more of R_{51B} to R_{55B} form a substituted or unsubstituted single ring by bonding with each other, form a substituted or unsubstituted fused ring by bonding with each other, or do not bond with each other; and

R_{51B} to R_{55B} which do not bond with each other are independently

a hydrogen atom,

a substituted or unsubstituted alkyl group having 1 to 50 carbon atoms,

a substituted or unsubstituted aryl group having 6 to 50 ring carbon atoms, or

a substituted or unsubstituted monovalent heterocyclic group having 5 to 50 ring atoms.

The compound represented by the formula (2-13) is one in which aspects of AR_{101B} and R_{32B} to R_{36B} are specified in the compound represented by the formula (2-12).

In one embodiment, one or more sets of the adjacent two or more of R_{51B} to R_{55B} do not bond with each other, and R_{51B} to R_{55B} are independently a hydrogen atom, or a substituted or unsubstituted aryl group having 6 to 50 ring carbon atoms.

The conditions other than that are the same as described in the formulas (2-1) to (2-12). As understood by [Definition], hydrogen atoms possessed by the phenylene group aranged between the anthracene skeleton and the benzimidazole skeleton may be deuterium atoms.

In one embodiment, the compound represented by the formula (2-13) is a compound represented by the following formula (2-14):

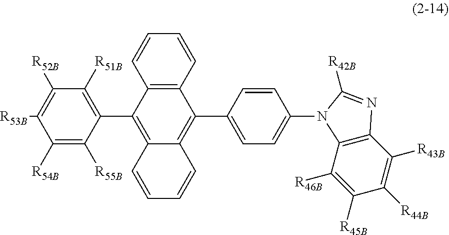

wherein in the formula (2-14), R_{42B} to R_{46B} and R_{51 B}to R_{55B} are the same as defined in the formula (2-13).

The compound represented by the formula (2-14) is one in which aspects of R₁₀₁B ^{to} R108B are specified in the compound represented by the formula (2-13). The conditions other than that are the same as described in the formulas (2-1) to (2-13).

As understood by the [Definition], hydrogen atoms possessed by the phenylene group arranged between the anthracene skeleton and the benzimidazole skeleton may be deuterium atoms.

In the compound represented by the formula (2), at least one hydrogen atom selected from the group consisting of,

R_{1B} to R_{10B} which are hydrogen atoms ;

hydrogen atoms possessed by R_{1B} to R_{10B} which are the substituents R (which include hydrogen atoms possessed by the substituent in the case where the substituent R has the substituent) ;

hydrogen atoms possessed by L_{1B} in the case where R_{1B} to R_{10B} are the group represented by the formula (2A) (which include hydrogen atoms possessed by the substituent in the case where L1B has the substituent) ; and

hydrogen atoms possessed by HAr_{1B} in the case where R_{1B} to R_{10B} are the group represented by the formula (2A) (which include hydrogen atoms possessed by the substituent in the case where HAr_{1B} has the substituent) ;

may be a deuterium atom.

Those described above in the first component can be used for the deuteration rate of the above compound.

The compound represented by the formula (2) can be synthesized by using known alternative reactions or raw materials adapted to the target compound.

Specific examples of the second component will be described below, but these are merely examples, and the second component is not limited to the following specific examples.

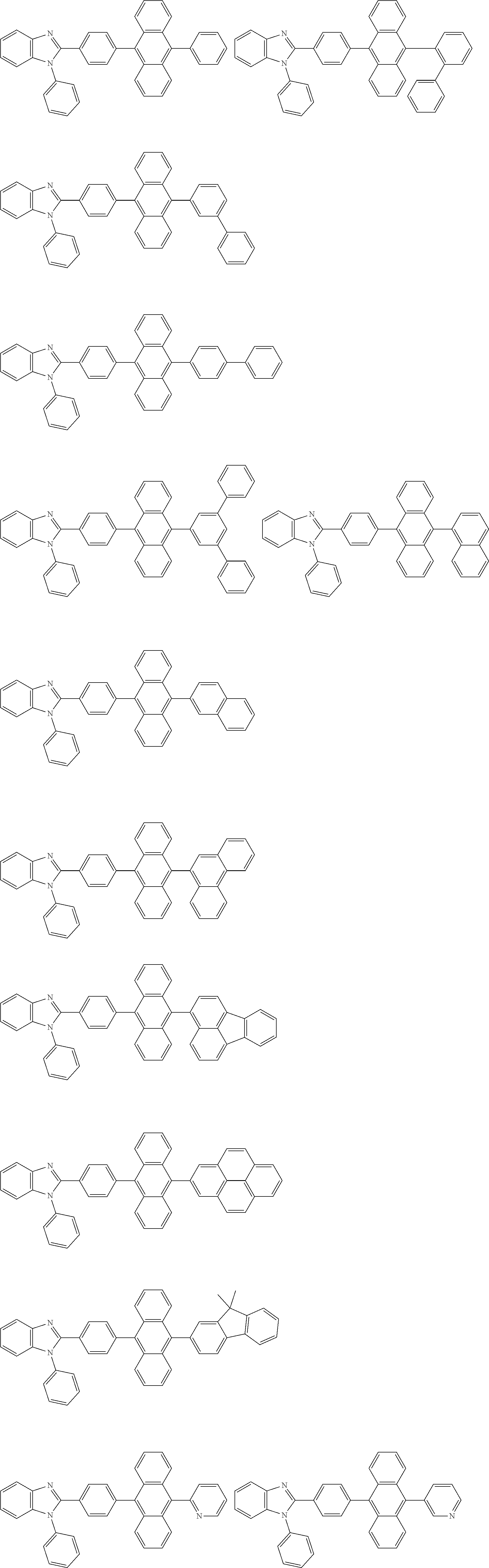

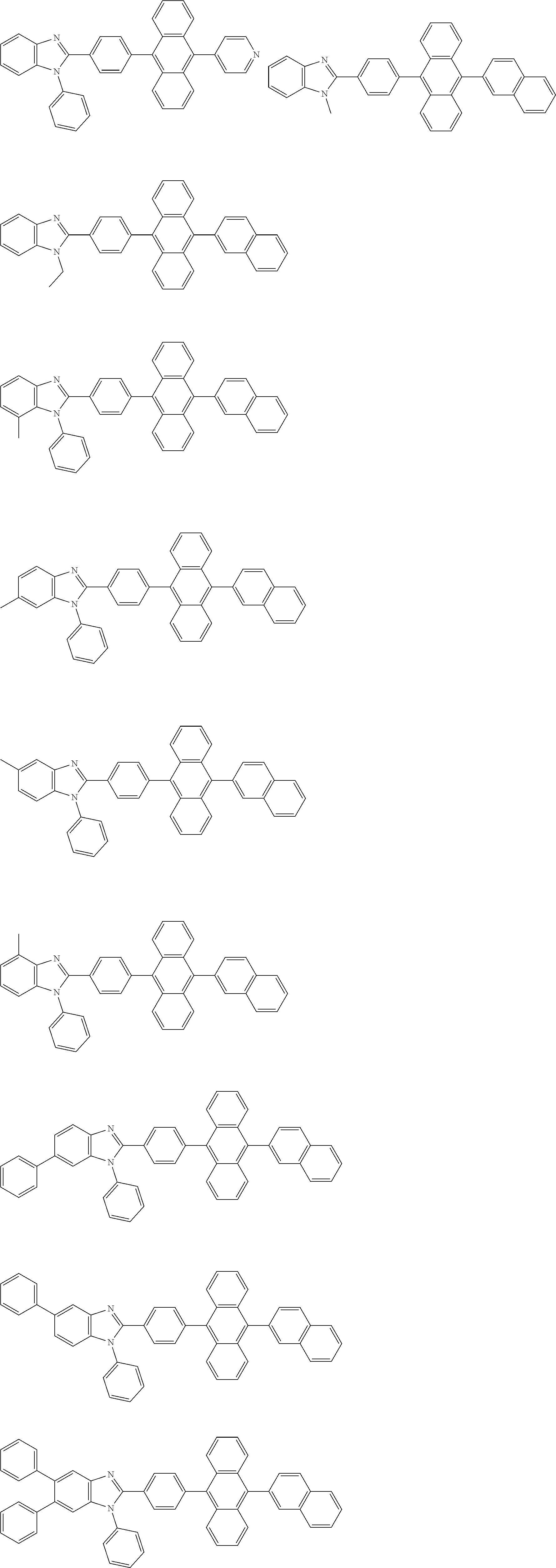

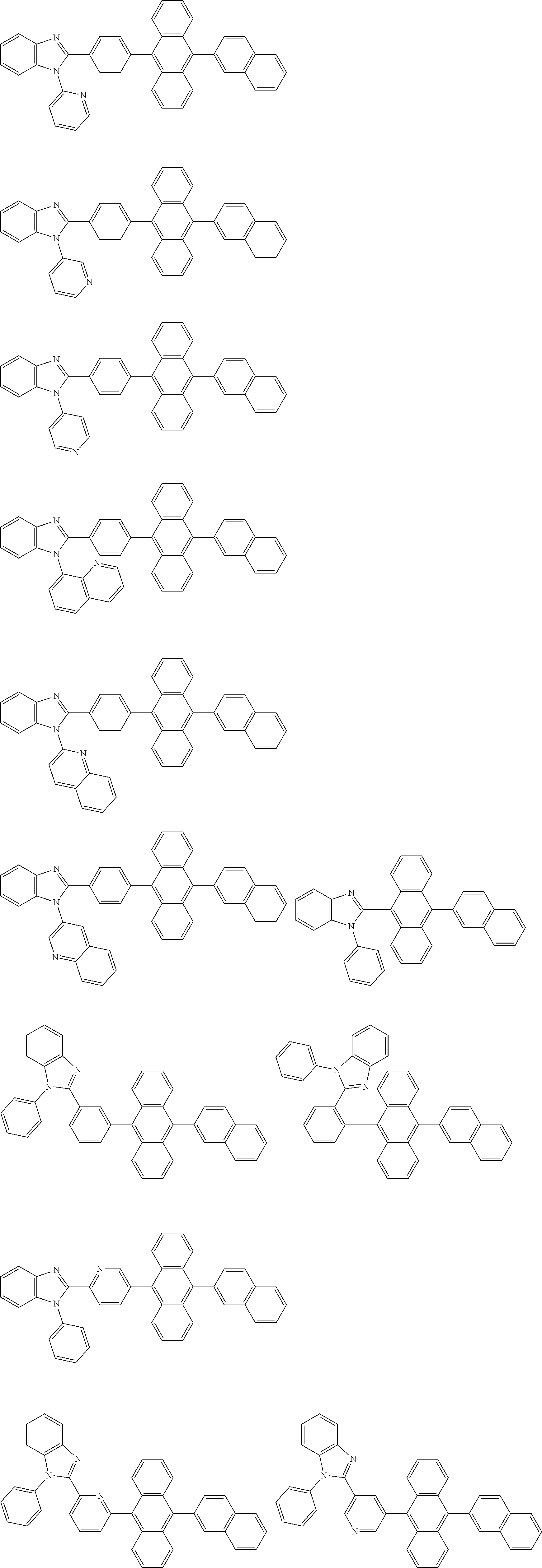

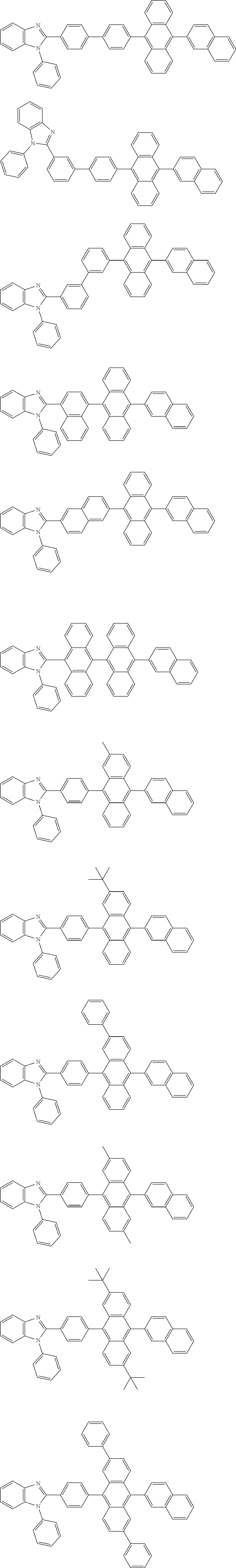

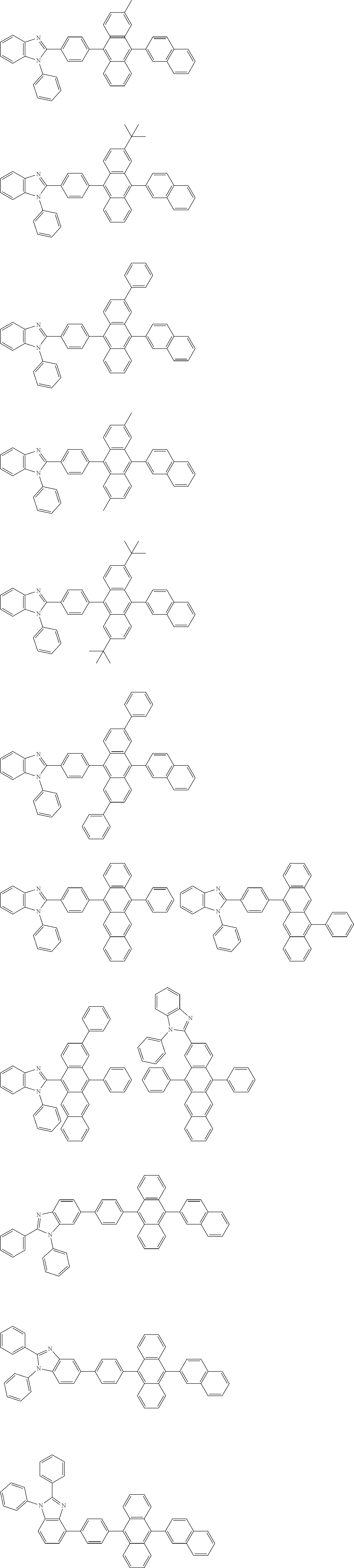

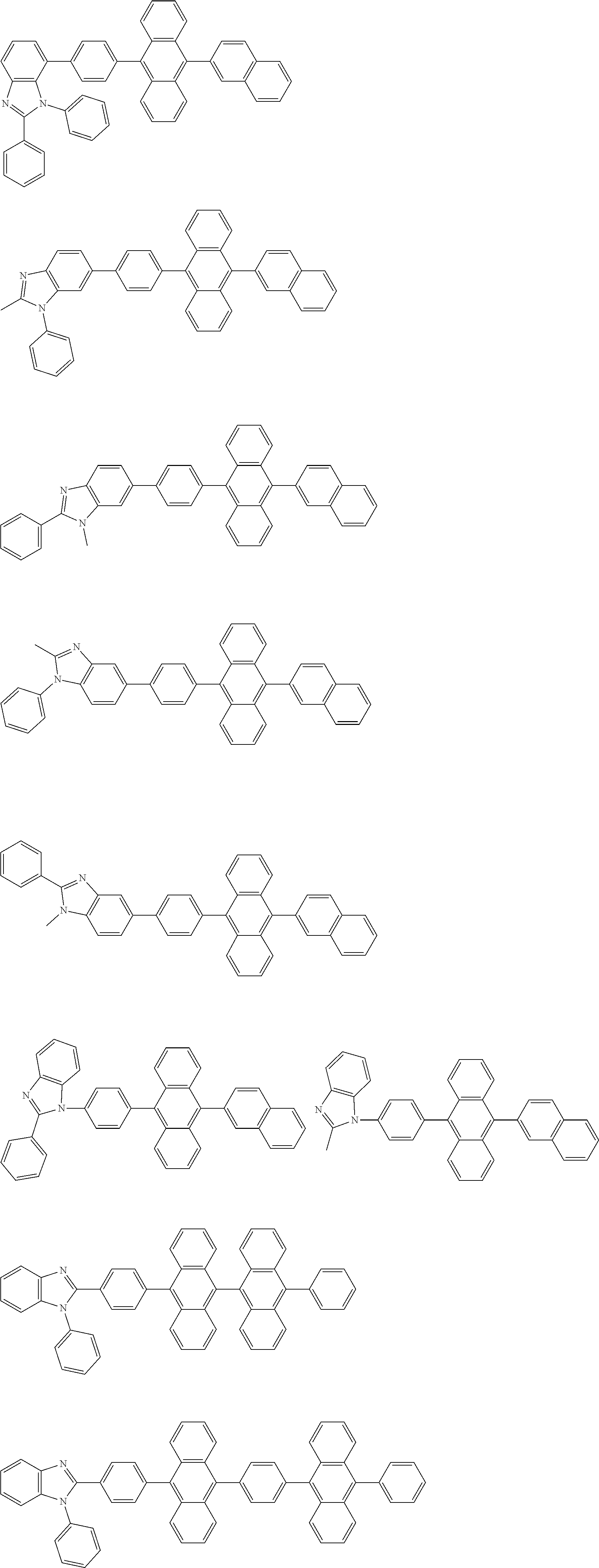

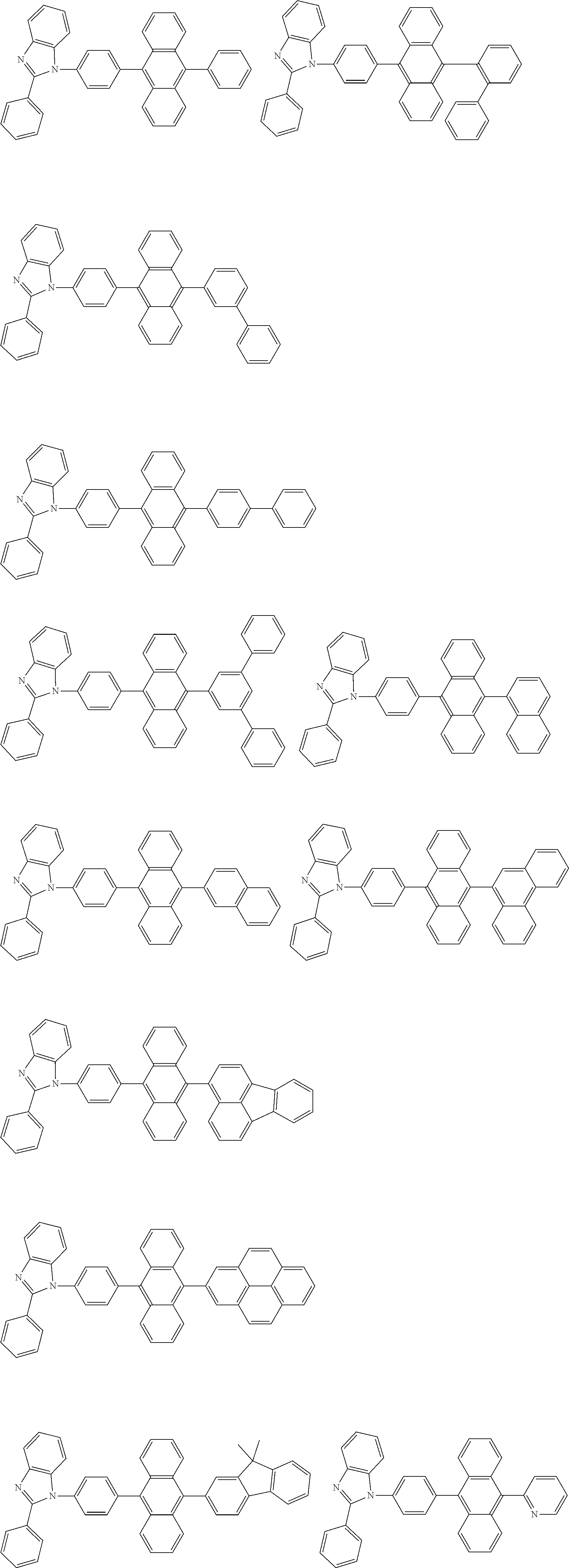

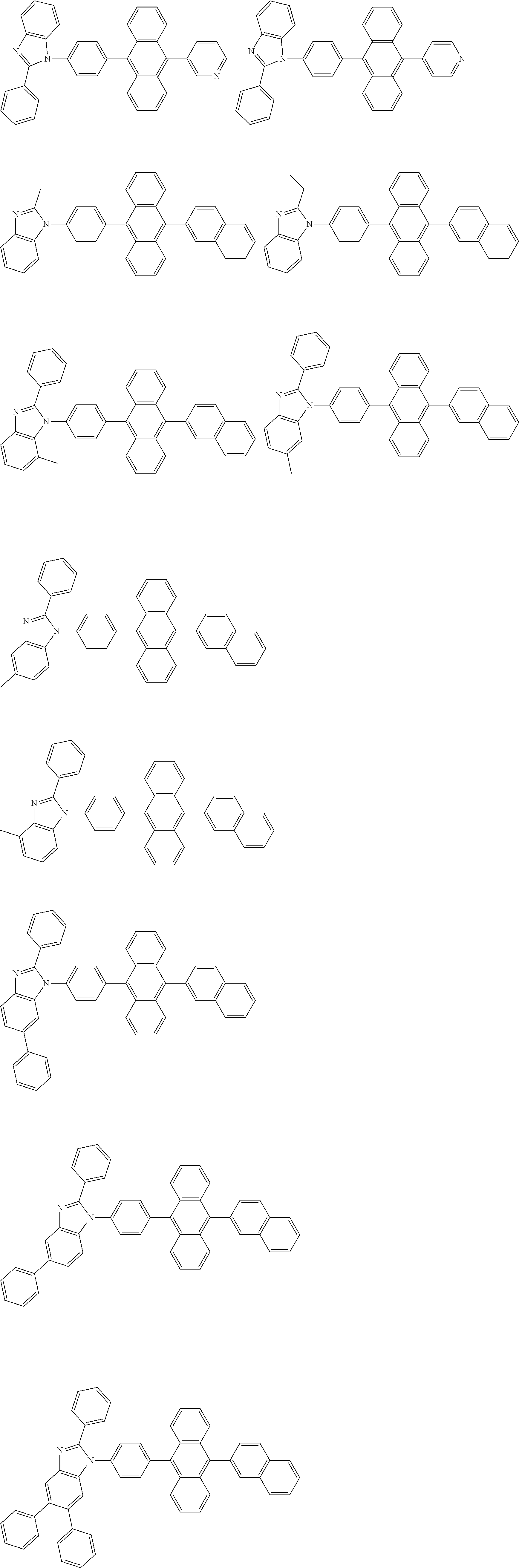

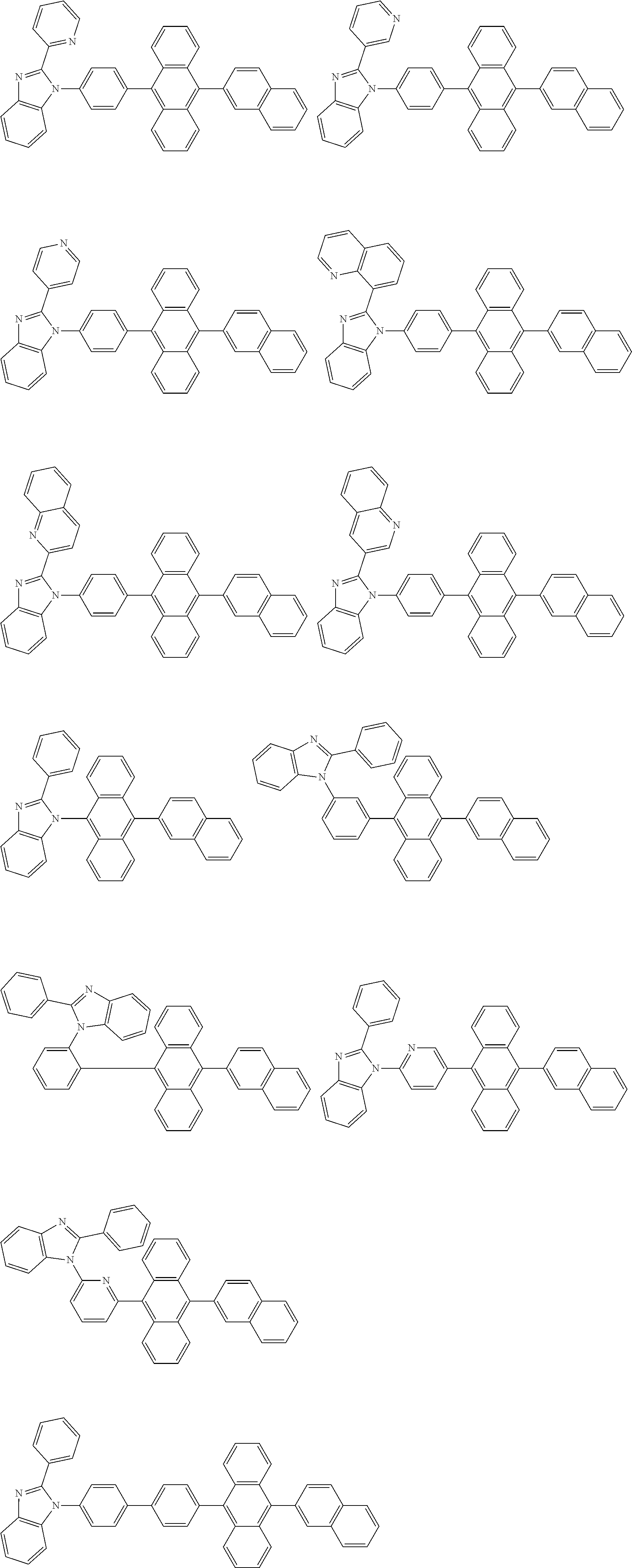

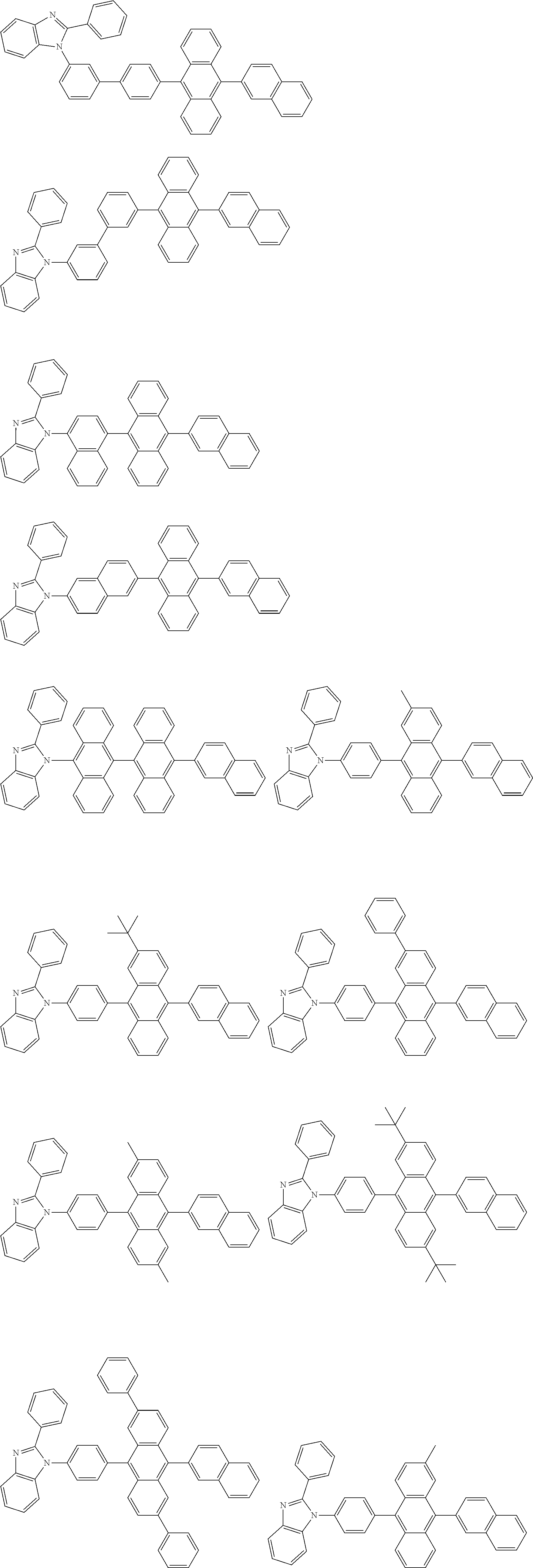

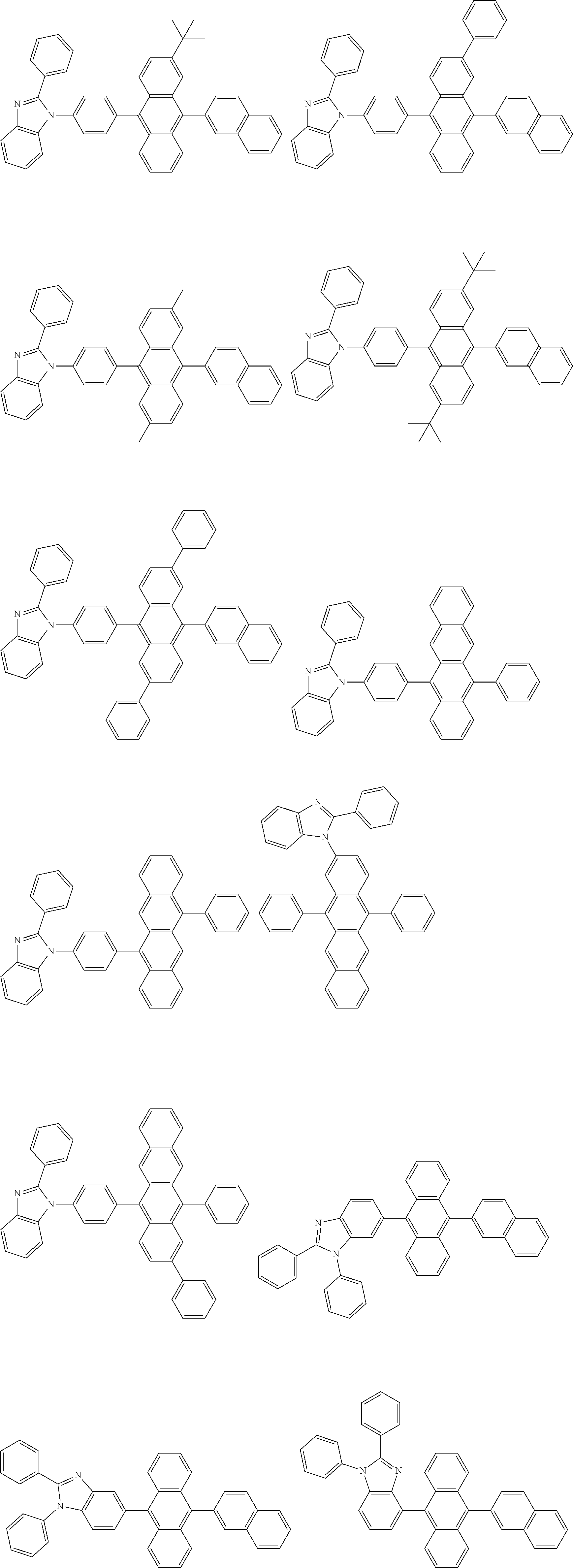

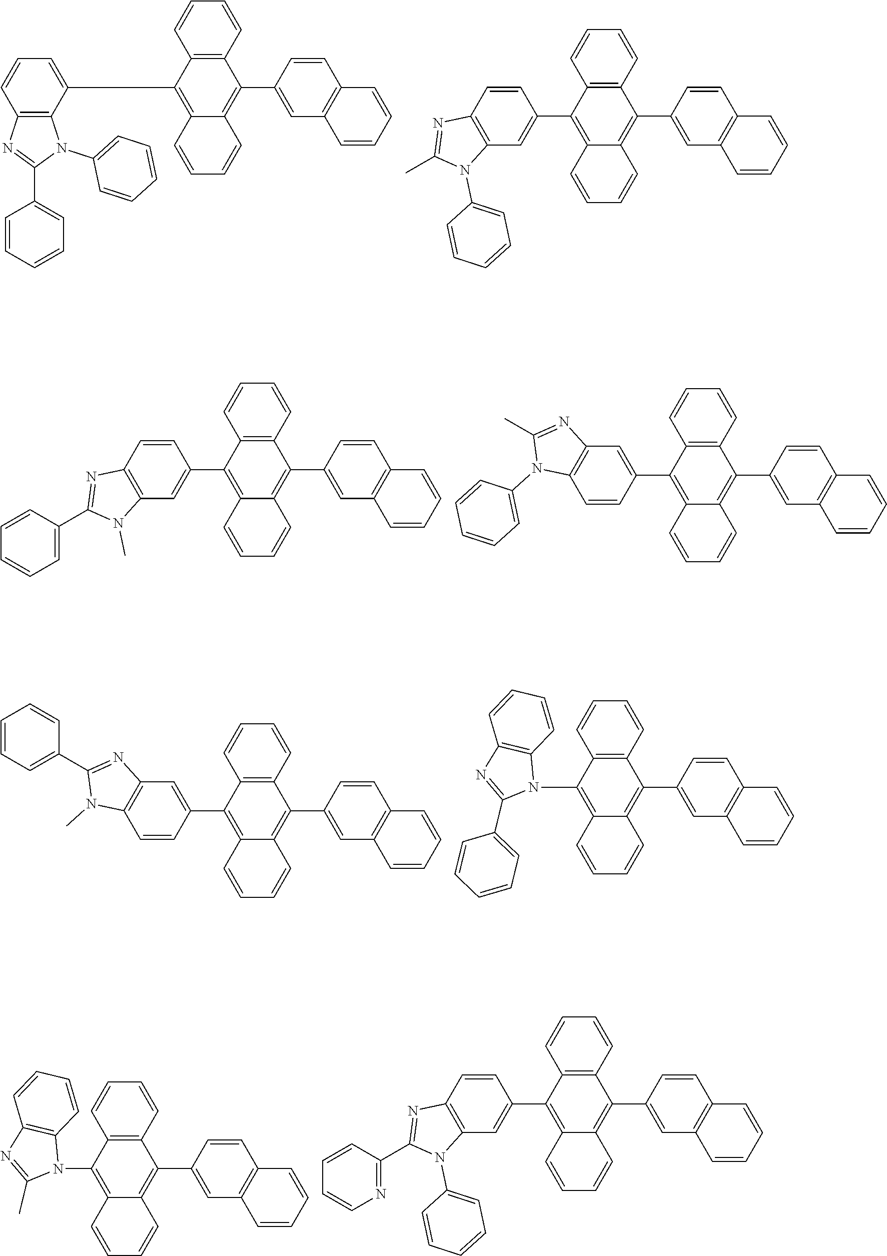

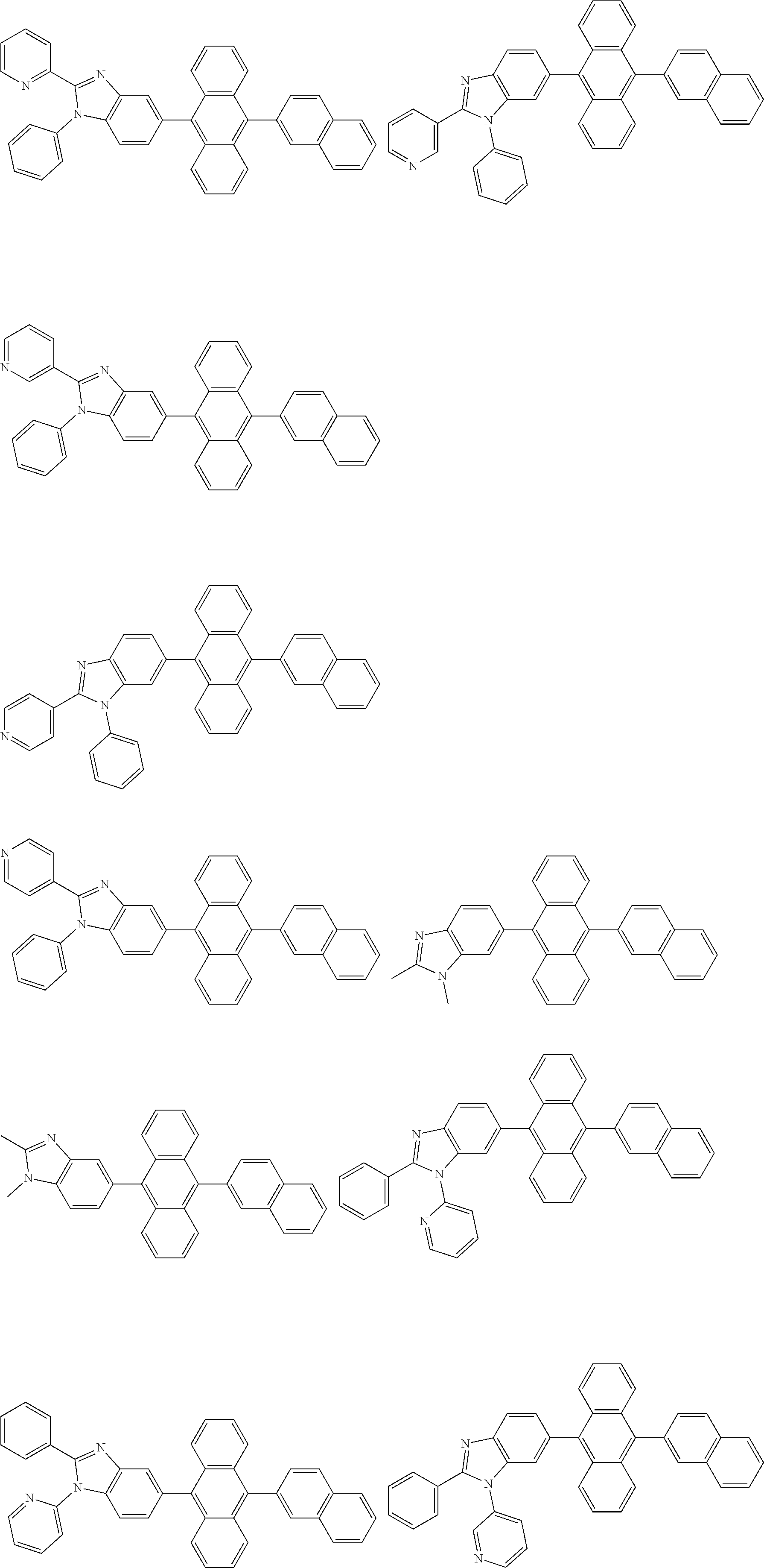

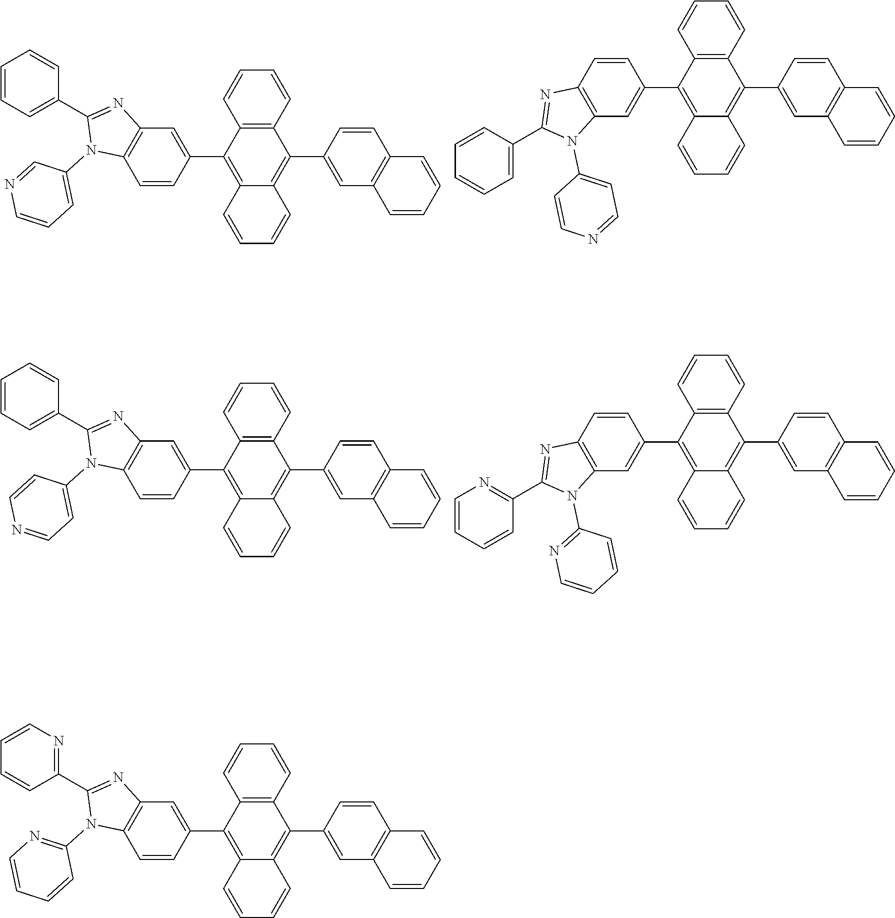

The amount ratio of the first component and the second component in a layer including the first component and the second component (hereinafter, also referred to as a “layer A”) is not particularly limited, but in one embodiment, the amount of the first component is 30 to 70% by mass based on the total amount of the first component and the second component, and it may be 40 to 60% by mass.

The layer A may or may not include other component other than the first component and the second component.

In one embodiment, the layerA substantially consists of the first component and the second component.

The expression “substantially consists of the first component and the second component” refers that the layer A includes no other component or includes extreamly small amount of other component as long as the effects of the present invention are not impaired. For example, the expression includes the case where unavoidable impurities are immixed therein as other component.

In one embodiment, 80% by mass or more, 90% by mass or more, 95% by mass or more, 99% by mass or more, 99.5% by mass or more, 99.9% by mass or more, 99.99% by mass or more, or 100% by mass of the layerA is the first component and the second component.

In one embodiment, 80 mol % or more, 90 mol % or more, 95 mol % or more, 99 mol % or more, 99.5 mol % or more, 99.9 mol % or more, 99.99 mol % or more, or 100 mol % of the layer A is the first component and the second component.

In one embodiment, the layer A consists of the first component and the second component.

In one embodiment, the layer A further includes one or more members selected from the group consisting of an alkali metal, an alkali metal compound, an alkaline earth metal, an alkaline earth metal compound, a rare earth metal, a rare earth metal compound, an organic metal complex containing an alkali metal, an organic metal complex containing an alkaline earth metal, and an organic metal complex containing a rare earth metal as a third component.

Examples of the alkali metal include lithium, sodium, potassium, rubidium, cesium, and francium.

Examples of the alkaline earth metal include beryllium, magnesium, calcium, strontium, barium, and radium. In one embodiment, the alkaline earth metal is one or more metals selected from the group consisting of calcium, strontium, barium, and radium.

Examples of the rare earth metal include scandium, yttrium, lanthanum, cerium, praseodymium, neodymium, promethium, samarium, europium, gadolinium, terbium, dysprosium, holmium, erbium, thulium, ytterbium, and lutetium.

Examples of the alkali metal compound include alkali oxide such as Li₂O, Cs₂O, K₂O, alkali halide such as LiF, NaF, CsF, KF, and the like.

Examples of the alkaline earth metal compound include BaO, SrO, CaO, and BaₓSri₁₋ₓO (0<x<1) and BaₓCa₁₋ₓO (0<x<1) being mixture of these, and the like.

Examples of the rare earth metal compound include YbF₃, ScF₃, ScO₃, Y₂O₃, Ce₂O₃, GdF₃, TbF₃, and the like.

The organic metal complex containing an alkali metal, the organic metal complex containing an alkaline earth metal and the organic metal complex containing a rare earth metal are not particularly limited, as long as it contains at least one of an alkali metal ion, an alkaline earth metal ion and a rare earth metal ion each as a metal ion. As a ligand, quinolinol, benzoquinolinol, acridinol, phenanthridinol, hydroxyphenyloxazole, hydroxyphenylthiazole, hydroxydiaryloxadiazole, hydroxydiarylthiadiazole, hydroxyphenylpyridine, hydroxyphenylbenzimidazole, hydroxybenzotriazole, hydroxyfluborane, bipyridyl, phenanthroline, phthalocyanine, porphyrin, cyclopentadiene, β-diketones, azomethines, derivative of these and the like can be given.

Examples of the organic metal complex containing an alkali metal include 8-hydroxyquinolinolato-lithium (Liq).

In one embodiment, the layer A includes one or more members selected from the group consisting of the alkali metal, the alkali metal compound, and the organic metal complex containing an alkali metal.

In one embodiment, the layer A includes one or more members selected from the group consisting of lithium (Li), ytterbium (Yb), lithium fluoride (LiF), cesium fluoride (CsF), calcium fluoride (CaF₂), a metal complex compound such as 8-hydroxyquinolinolato-lithium (Liq), and lithium oxide (LiOₓ).

In one embodiment, the layer A substantially does not include an alkali metal, an alkali metal compound, an alkaline earth metal, an alkaline earth metal compound, a rare earth metal, a rare earth metal compound, an organic metal complex containing an alkali metal, an organic metal complex containing an alkaline earth metal, and an organic metal complex containing a rare earth metal.

The expression “substantially does not include” refers that the layer A does not include the component at all or includes extreamly small amount of the component as long as the effects of the present invention are not impaired. For example, the expression includes the case where unavoidable impurities are immixed therein.

A schematic configuration of the organic EL device according to an aspect of the present invention will be described with reference to the FIGURE.

The organic EL device 1 according to an aspect of the present invention includes a substrate 2, an anode 3, an emitting layer 5 being an organic layer, a cathode 10, an organic layer 4 between the anode 3 and the emitting layer 5, and an organic layer 6 between the emitting layer 5 and the cathode 10.

Each of the organic layer 4 and the organic layer 6 may be a single layer or may composed of a plurality of layers.

In one embodiment, the organic EL device according to an aspect of the present invention includes the anode, an emitting layer, an electron-transporting region, and the cathode in this order, and at least one layer in the electron-transporting region includes the first component and the second component.

### (Electron-Transporting Region)

The electron-transporting region indicates a general term for one or two or more layers arranged between the emitting layer and the cathode. The electron-transporting region is configured, for example, from each layer which is referred to as a hole-blocking layer, an electron-transporting layer, and an electron-injecting layer described later from the emitting layer side, and it may be a stacked structure including all of them, or may be a layer configuration merely including a part of them. Further, each of the above layers may be formed by using two or more kinds of layers, and for example, two kinds of electron-transporting layers having different compositions may be stacked.

Each layer may be formed by using one kind of material alone, or may be formed by using two or more kinds of materials in combination.

Stacked structures of the electron-transporting region in the organic EL device according to an aspect of the present invention are shown below.
(a) (an emitting layer/) a first layer (an electron-transporting layer)/a second layer (an electron-injecting layer) (/a cathode)
(b) (an emitting layer/) a third layer (a hole-blocking layer)/a first layer (an electron-transporting layer) a second layer (an electron-injecting layer) (/a cathode)
(c) (an emitting layer/) a third layer (a hole-blocking layer)/a fourth layer (a first electron-transporting layer)/a first layer (a second electron-transporting layer)/a second layer (an electron-injecting layer) (/a cathode)

In one embodiment, the electron-transporting region includes at least a first layer and a second layer in this order from the emitting layer side, and the second layer includes the first component and the second component.

In one embodiment, the second layer substantially does not include the compound having the structure represented by the formula (1B) within a molecular thereof, the compound having the structure represented by the formula (1C) within a molecular thereof, and the compound having the structure represented by the formula (1D) within a molecular thereof.

The expression “substantially does not include” refers that the second layer does not include the compound at all or includes extreamly small amount of the compound as long as the effects of the present invention are not impaired. For example, the expression includes the case where unavoidable impurities are immixed therein.

In one embodiment, the second layer substantially consists of the first component and the second component.

The expression “substantially consists of the first component and the second component” refers that the second layer includes no other component or includes extreamly small amount of other component as long as the effects of the present invention are not impaired. For example, the expression includes the case where unavoidable impurities are immixed therein as other component.

### (Other Configuration of Organic EL Device)

Conventionally-known materials and device configurations can be applied to the organic EL device according to an aspect of the present invention as long as the one or two or more organic layers arranged between the cathode and the anode satisfy the above conditions, and further as long as the effects of the present invention are not impaired.

Device configurations, materials for forming each layer, and the like in the organic EL device according to an aspect of the present invention will be described below.

As a representative device configuration of the organic EL device, structures in which the following structures are stacked on a substrate can be given:
(1) an anode/an emitting layer/an electron-transporting region/a cathode,
(2) an anode/a hole-transporting region/an emitting layer/an electron-transporting region/a cathode,

wherein “/” indicates that the layers are stacked adjacent to each other.

### (Hole-Transporting Region)

The hole-transporting region indicates a general term for one or two or more layers arranged between the anode and the emitting layer. The hole-transporting region is configured, for example, from each layer which is referred to as the electron-blocking layer, the hole-transporting layer and the hole-injecting layer described later from the emitting layer side, and it may be a stacked structure including all of them, or may be a layer configuration merely including a part of them. Further, each of the above layers may be formed by using two or more kinds of layers, and for example, two kinds of hole-transporting layers having different compositions may be stacked.

Each layer may be formed by using one kind of material alone, or may be formed by using two or more kinds of materials in combination.

Each layer of the organic EL device according to an aspect of the present invention will be described below.

### (Substrate)

The substrate is used as a support of an emitting device. As the substrate, glass, quartz, plastic or the like can be used, for example. Further, a flexible substrate may be used. The term “flexible substrate” means a bendable (flexible) substrate, and specific examples thereof include a plastic substrate formed of polycarbonate, polyvinyl chloride or the like.

### (Anode)

For the anode formed on the substrate, metals, alloys, electrically conductive compounds, mixtures thereof, and the like, which have large work function (specifically 4.0 eV or more) are preferably used. Specific examples thereof include indium oxide-tin oxide (ITO: Indium Tin Oxide), indium oxide-tin oxide containing silicon or silicon oxide, indium oxide-zinc oxide, tungsten oxide, indium oxide containing zinc oxide, graphene, and the like. In addition thereto, specific examples thereof include gold (Au), platinum (Pt), a nitride of a metallic material (for example, titanium nitride), or the like.

### (Hole-Injecting Layer)

The hole-injecting layer is a layer containing a substance having high hole-injecting property. As the substance having high hole-injecting property, molybdenum oxide, titanium oxide, vanadium oxide, rhenium oxide, ruthenium oxide, chromium oxide, zirconium oxide, hafnium oxide, tantalum oxide, silver oxide, tungsten oxide, manganese oxide, an aromatic amine compound, a polymer compound (oligomers, dendrimers, polymers, and the like), or the like can be given.

### (Hole-Transporting Layer)

The hole-transporting layer is a layer containing a substance having high hole-transporting property. For the hole-transporting layer, an aromatic amine compound, a carbazole derivative, an anthracene derivative, or the like can be used. A polymer compound such as poly(N-vinylcarbazole) (abbreviation: PVK) and poly(4-vinyltriphenylamine) (abbreviation: PVTPA) can also be used. Provided that a substance other than the above-described substances may be used as long as the substance has higher hole-transporting property than electron-transporting property. The layer containing the substance having high hole-transporting property may be not only a single layer, but also layers in which two or more layers formed of the above-described substances are stacked.

### (Guest (Dopant) Material of Emitting Layer)

The emitting layer is a layer containing a substance having high luminous property, and various materials can be used. For example, as the substance having high emitting property, a fluorescent compound which emits fluorescence or a phosphorescent compound which emits phosphorescence can be used. The fluorescent compound is a compound which can emit from a singlet excited state, and the phosphorescent compound is a compound which can emit from a triplet excited state.

As a blue fluorescent emitting material which can be used for the emitting layer, pyrene derivatives, styrylamine derivatives, chrysene derivatives, fluoranthene derivatives, fluorene derivatives, diamine derivatives, triarylamine derivatives, and the like can be used. As a green fluorescent emitting material which can be used for the emitting layer, aromatic amine derivatives and the like can be used. As a red fluorescent emitting material which can be used for the emitting layer, tetracene derivatives, diamine derivatives and the like can be used.

As a blue phosphorescent emitting material which can be used for the emitting layer, metal complexes such as iridium complexes, osmium complexes and platinum complexes are used. As a green phosphorescent emitting material which can be used for the emitting layer, iridium complexes and the like are used. As a red phosphorescent emitting material which can be used for the emitting layer, metal complexes such as iridium complexes, platinum complexes, terbium complexes and europium complexes are used.

### (Host Material for Emitting Layer)

The emitting layer may have a constitution in which the substance having high emitting property (guest material) is dispersed in another substance (host material). As a substance for dispersing the substance having high emitting property, a variety of substances can be used, and it is preferable to use a substance having a higher lowest unoccupied molecular orbital level (LUMO level) and a lower highest occupied molecular orbital level (HOMO level) than a substance having high emitting property.

As a substance (host material) for dispersing the substance having high emitting property, 1) a metal complex such as an aluminum complex, a beryllium complex, and a zinc complex, 2) a heterocyclic compound such as an oxadiazole derivative, a benzimidazole derivative, and a phenanthroline derivative, 3) a fused aromatic compound such as a carbazole derivative, an anthracene derivative, a phenanthrene derivative, a pyrene derivative, and a chrysene derivative, and 4) an aromatic amine compound such as a triarylamine derivative and a fused polycyclic aromatic amine derivative are used.

A compound having delayed fluorescence (thermally activated delayed fluorescence) can also be used as the host material. It is also preferable that the emitting layer includes the material used in the present invention described above and the host compound having delayed fluorescence.

### (Electron-Blocking Layer, Hole-Blocking Layer, Exciton-Blocking Layer)

An electron-blocking layer, a hole-blocking layer, an exciton (triplet)-blocking layer, and the like may be provided adjacent to the emitting layer.

The electron-blocking layer is a layer which has a function of preventing leakage of electrons from the emitting layer to the hole-transporting layer. The hole-blocking layer is a layer which has a function of preventing leakage of holes from the emitting layer to the electron-transporting layer. The exciton-blocking layer is a layer which has a function of preventing diffusion of excitons generated in the emitting layer into the adjacent layers to confine the excitons within the emitting layer.

### (Electron-Transporting Layer)

The electron-transporting layer is a layer containing a substance having high electron-transporting property. For the electron-transporting layer, 1) a metal complex such as an aluminum complex, a beryllium complex, and a zinc complex; 2) a heteroaromatic complex such as an imidazole derivative, a benzimidazole derivative, an azine derivative, carbazole derivative, and a phenanthroline derivative; and 3) a polymer compound can be used.

### (Electron-Injecting Layer)

The electron-injecting layer is a layer containing a substance having high electron-injecting property. For the electron-injecting layer, lithium (Li), ytterbium (Yb), lithium fluoride (LiF), cesium fluoride (CsF), calcium fluoride (CaF₂), a metal complex compound such as 8-hydroxyquinolinolato-lithium (Liq), an alkali metal such as lithium oxide (LiOₓ), an alkaline earth metal, ora compound thereof can be used.

### (Cathode)

For the cathode, metals, alloys, electrically conductive compounds, mixtures thereof, and the like, which have small work function (specifically 3.8 eV or less) are preferably used. Specific examples of such a cathode material include an element belonging to Group 1 or Group 2 of the Periodic Table of the Elements, i.e., an alkali metal such as lithium (Li) and cesium (Cs), an alkaline earth metal such as magnesium (Mg), calcium (Ca) and strontium (Sr), and an alloy containing these (e.g., MgAg and AlLi); a rare earth metal such as europium (Eu) and ytterbium (Yb), and an alloy containing these.

In the organic EL device according to an aspect of the present invention, the thickness of each layer is not particularly limited, but is normally preferable several nm to 1 μm generally in order to suppress defects such as pinholes, to suppress applied voltages to be low, and to improve luminous efficiency.

### [Method for Fabricating Organic EL Device]

In the organic EL device according to an aspect of the present invention, the method for forming each layer is not particularly limited. A conventionally-known method for forming each layer such as a vacuum deposition process and a spin coating process can be used. Each layer such as the emitting layer can be formed by a known method such as a vacuum deposition process, a molecular beam deposition process (MBE process), or an application process such as a dipping process, a spin coating process, a casting process, a bar coating process and a roll coating process, using a solution prepared by dissolving the material in a solvent.

A method for fabricating the organic EL device according to an aspect of the present invention including: forming a film on a substrate by depositing the first component and the second component in the same deposition source or different deposition sources.

A method of simultaneously depositing (co-depositing) the first component and the second component each in different deposition sources to form the layer A may be used, or a method of mixing them in advance, and then depositing them in the same deposition source to form the layer A may be used.

### [Composition]

A composition according to an aspect of the present invention includes a first component and a second component,

the first component is the compound represented by the formula (1), and

the second component is the compound represented by the formula (2).

The first component and the second component in the composition according to an aspect of the present invention are the same as described above in those of the organic EL device according to an aspect of the present invention.

The amount ratio of the first component and the second component is not particularly limited, and the amount ratio of materials can be appropriately determined depending on effects desired for the composition.

In one embodiment, the amount of the first component is 30 to 70% by mass based on the total amount of the first component and the second component, and it may be 40 to 60% by mass.

In one embodiment, the composition may or may not include a component other than the first component and the second component. In one embodiment, the composition substantially consists of the first component and the second component.

The expression “substantially consists of the first component and the second component” refers that the composition includes no other component or includes extreamly small amount of other component as long as the effects of the present invention are not impaired. For example, the expression includes the case where unavoidable impurities are immixed therein.

In one embodiment, 80% by mass or more, 90% by mass or more, 95% by mass or more, 99% by mass or more, 99.5% by mass or more, 99.9% by mass or more, 99.99% by mass or more, or 100% by mass of the composition is the first component and the second component.

In one embodiment, 80 mol % or more, 90 mol % or more, 95 mol % or more, 99 mol % or more, 99.5 mol % or more, 99.9 mol % or more, 99.99 mol % or more, or 100 mol % of the composition is the first component and the second component.

In one embodiment, the composition consists of the first component and the second component.

In one embodiment, the composition further includes one or more members selected from the group consisting of an alkali metal, an alkali metal compound, an alkaline earth metal, an alkaline earth metal compound, a rare earth metal, a rare earth metal compound, an organic metal complex containing an alkali metal, an organic metal complex containing an alkaline earth metal, and an organic metal complex containing a rare earth metal as the third component.

The third component in the composition according to an aspect of the present invention is the same as described above in that of the organic EL device according to an aspect of the present invention.

The form of the composition according to an aspect of the present invention is not particularly limited, and for example, solid, powder, solution, and a film (layer) can be given. As the film (layer), for example, an organic layer configuring the organic EL device (for example, a hole-blocking layer, an electron-transporting layer and an electron-injecting layer) can be used. When the composition according to an aspect of the present invention is solid-like or powder-like, it may be formed in the shape of pellet.

When the composition is powder-like (mixed powder), it may be the mixed powder containing the first component and the second component in one particle, or it may be the mixed powder in which a particle composed of the first component and a particle composed of the second component are mixed.

A method for producing mixed powder, for example, may include pulverizing and mixing the first component and the second component by using a mortar and the like, or may include putting the first component and the second component in a container and the like, heating and melting them under a chemically inert environment, subsequently, cooling them to the ambient temperature, and pulverizing the obtained mixture by using a mixer and the like to obtain powder. The latter method can lead mixing the first component and the second component at the molecular level to allow more uniform deposition. It can also prevent problems such as mix unevenness which can be caused during transport of the mixed powder.

The mixed powder may be compressed and formed to be pellet-like.

In one embodiment, the composition can be used for a deposition method (including a vacuum deposition method), that is, it can be used for any technical field including depositing an organic compound to form a film.

The expression “can be used for a deposition method (including a vacuum deposition method)” can also be rephrased as the words “for a deposition method (or for a vacuum deposition method)”.

Combinations of the first component (the compound represented by the formula (1)) and the second component (the compound represented by the formula (2)) included in the composition according to an aspect of the present invention are specifically shown below.
Combination 1

The compound represented by the formula (1) is 1-1, and the compound represented by the formula (2) is 2-1.

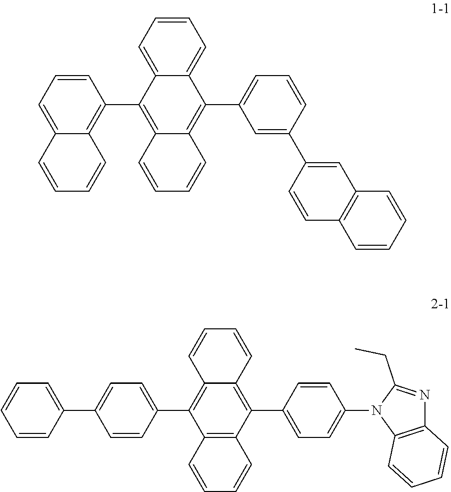

Combination 2

The compound represented by the formula (1) is 1-2, and the compound represented by the formula (2) is 2-1.

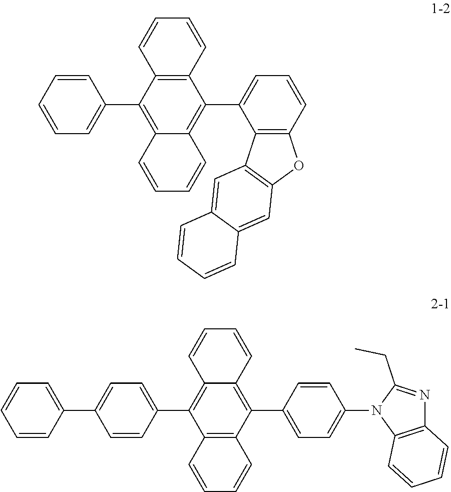 [SMILES: c1ccc(-c2c3ccccc3c(-c3cccc4oc5cc6ccccc6cc5c34)c3ccccc23)cc1 ; CCc1nc2ccccc2n1-c1ccc(-c2c3ccccc3c(-c3ccc(-c4ccccc4)cc3)c3ccccc23)cc1]

Combination 3

The compound represented by the formula (1) is 1-3, and the compound represented by the formula (2) is 2-1.

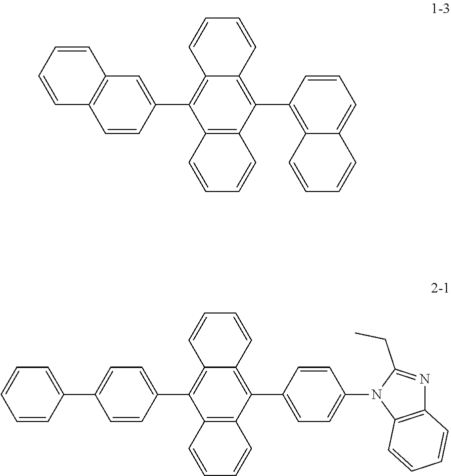

Combination 4

The compound represented by the formula (1) is 1-4, and the compound represented by the formula (2) is 2-1.

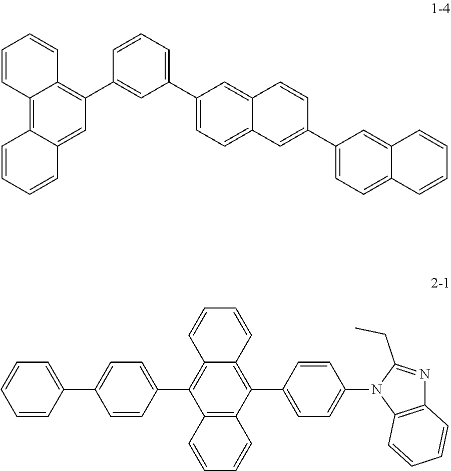

Combination 5

The compound represented by the formula (1) is 1-5, and the compound represented by the formula (2) is 2-1.

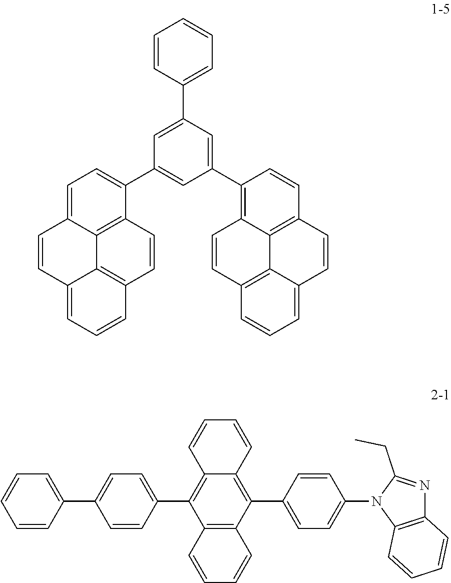

Combination 6

The compound represented by the formula (1) is 1-6, and the compound represented by the formula (2) is 2-1.

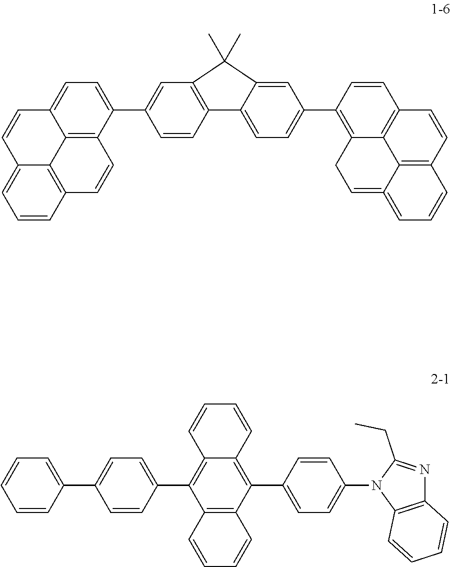

### [Electronic Apparatus]

An electronic apparatus according to an aspect of the present invention is characterized by including the organic EL device according to an aspect of the present invention.

Specific examples of the electronic apparatus include display components such as an organic EL panel module; display devices for a television, a cellular phone and a personal computer; and emitting devices such as a light and a vehicular lamp; and the like.

### EXAMPLES

### <Compound>

First components (compounds represented by the formula (1)) used in the fabrication of the organic EL devices of Examples and Comparative Example are shown below.

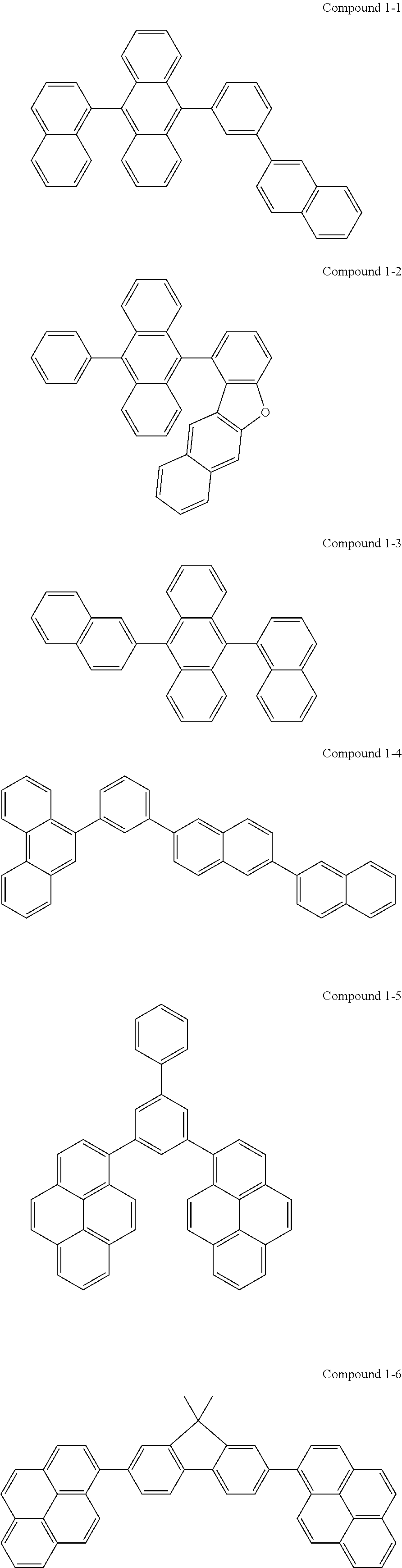

Molecular weights of Compound 1-1 to Compound 1-6 are shown in Table 1.

TABLE 1

| | Molecular weight |
|---|---|
| Compound 1-1 | 506.6 |
| Compound 1-2 | 470.6 |
| Compound 1-3 | 430.5 |
| Compound 1-4 | 506.6 |
| Compound 1-5 | 554.7 |
| Compound 1-6 | 594.7 |

A second component (a compound represented by the formula (2)) used in the fabrication of the organic EL devices of Examples are shown below.

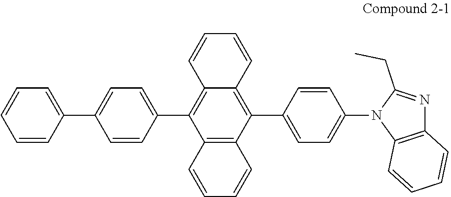 [SMILES: CCc1nc2ccccc2n1-c1ccc(-c2c3ccccc3c(-c3ccc(-c4ccccc4)cc3)c3ccccc23)cc1]

Other compound structures used in the fabrication of the organic EL devices of Examples and Comparative Examples are shown below.

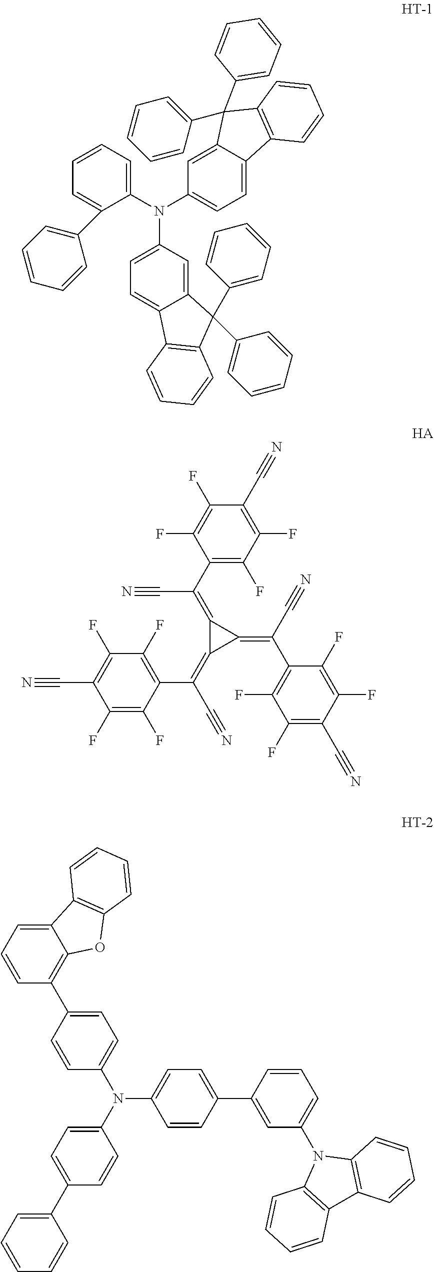 [SMILES: c1ccc(-c2ccccc2N(c2ccc3c(c2)C(c2ccccc2)(c2ccccc2)c2ccccc2-3)c2ccc3c(c2)C(c2ccccc2)(c2ccccc2)c2ccccc2-3)cc1 ; N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F ; c1ccc(-c2ccc(N(c3ccc(-c4cccc(-n5c6ccccc6c6ccccc65)c4)cc3)c3ccc(-c4cccc5c4oc4ccccc45)cc3)cc2)cc1]

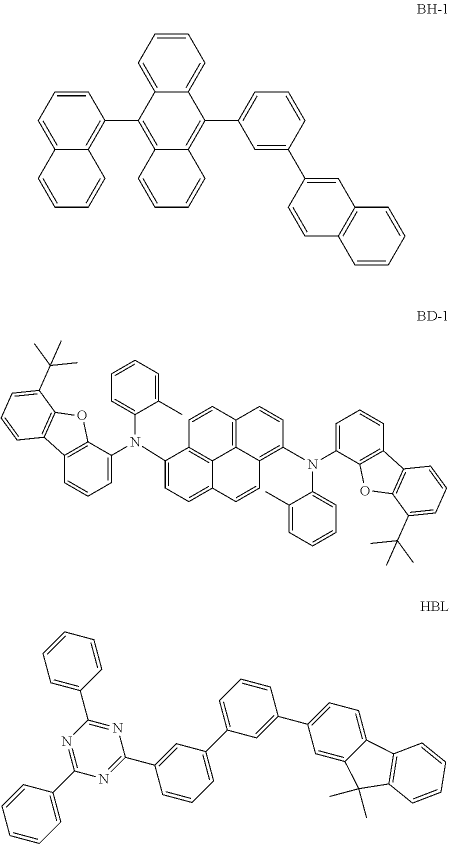

### Example 1

### <Fabrication of Organic EL Device>

Organic EL devices were fabricated as follows.

A25 mm×75 mm×1.1 mm-thick glass substrate with an ITO transparent electrode (anode) (manufactured by GEOMATEC Co., Ltd.) was subjected to ultrasonic cleaning in isopropyl alcohol for 5 minutes, and then subjected to UV-ozone cleaning for 30 minutes. The ITO has the film thickness of 130 nm.

The glass substrate with the transparent electrode after being cleaned was mounted onto a substrate holder in a vacuum vapor deposition apparatus. First, compounds HT-1 and HA were co-deposited on the surface on the side where the transparent electrode was formed so as to cover the transparent electrode to be 3% by mass in a proportion of the compound HA to form a first hole-transporting layer having the thickness of 10 nm.

The compound HT-1 was deposited on the first hole-transporting layer to form a second hole-transporting layer having the thickness of 80 nm.

The compound HT-2 was deposited on the second hole-transporting layer to form a third hole-transporting layer having the thickness of 10 nm.

A compound BH-1 (host material) and a compound BD-1 (dopant material) were co-deposited on the third hole-transporting layer to be 4% by mass in a proportion of the compound BD-1 to form an emitting layer having the thickness of 25 nm.

A compound HBL was deposited on the emitting layer to form a first electron-transporting layer having the thickness of 10 nm.

A compound 1-1 and a compound 2-1 were co-deposited on the first electron-transporting layer to be 50% by mass in a proportion of the compound 2-1 to form a second electron-transporting layer having the thickness of 15 nm.

A metal Yb was deposited on the second electron-transporting layer to form an electron-injecting layer having the thickness of 1 nm.

A metal Al was deposited on the electron-injecting layer to form a cathode having the thickness of 50 nm.

The device configuration of the organic EL device of Example 1 is schematically shown as follows.
ITO(130)/HT-1:HA(10:3%)/HT-1(80)/HT-2(10)/BH-1:BD-1(25:4%)/HBL(10)/Compound 1-1:Compound 2-1(15:50%)/Yb(1)/A1(50)

The numerical values in parentheses indicate the film thickness (unit: nm). The numerical values represented by percent in parentheses indicate a proportion (% by mass) of the latter compound in the layer.

### <Evaluation of Organic EL Device>

The fabricated organic EL device was evaluated as follows. The results are shown in Table 2.
Driving Voltage

The initial property of the organic EL device was measured by driving it using DC (direct current) constant current of 10 mA/cm² at room temperature.
External Quantum Efficiency

A voltage was applied to the organic EL device so that the current density became 10 mA/cm², and the EL emission spectrum was measured by using Spectroradiometer CS-2000 (manufactured by KONICA MINOLTA, INC.). External quantum efficiency (EQE) (%) was calculated from the obtained spectral emission luminance spectrum.

### Examples 2 to 6

Organic EL devices were fabricated and evaluated in the same manner as in Example 1, except that compounds shown in Table 2 were used instead of the compound 1-1 in formation of the second electron-transporting layer. The results are shown in Table 2.

### Comparative Examples 1 to 2

Organic EL devices were fabricated and evaluated in the same manner as in Example 1, except that compounds shown in Table 2 were used alone in formation of the second electron-transporting layer. The results are shown in Table 2.

TABLE 2

| | Composition of second electron- | | |
|---|---|---|---|
| | transporting layer | Voltage (V) | EQE (%) |
| Example 1 | Compound 1-1:Compound 2-1 | 3.79 | 10.0 |
| | (50% by mass:50% by mass) | | |
| Example 2 | Compound 1-2:Compound 2-1 | 3.78 | 9.9 |
| | (50% by mass:50% by mass) | | |
| Example 3 | Compound 1-3:Compound 2-1 | 3.74 | 10.1 |
| | (50% by mass:50% by mass) | | |
| Example 4 | Compound 1-4:Compound 2-1 | 3.53 | 8.8 |
| | (50% by mass:50% by mass) | | |
| Example 5 | Compound 1-5:Compound 2-1 | 3.79 | 9.7 |
| | (50% by mass:50% by mass) | | |
| Example 6 | Compound 1-6:Compound 2-1 | 3.87 | 9.5 |
| | (50% by mass:50% by mass) | | |
| Comparative | Compound 1-1 | 8.76 | 5.2 |
| Example 1 | | | |
| Comparative | Compound 1-2 | 7.57 | 6.2 |
| Example 2 | | | |

As seen from the results shown in Table 2, it was found that organic EL devices of the present invention exhibited low driving voltage and high external quantum efficiency by using the first component (the compound represented by the formula (1)) and the second component (the compound represented by the formula (2)) having the specific structure therein in combination. Organic EL devices of Examples 1 to 3 exhibited extreamly high external quantum efficiency using compounds 1-1 to 1-3 having the anthracene skeleton among the compounds represented by the formula (1).

Although only some exemplary embodiments and/or examples of this invention have been described in detail above, those skilled in the art will readily appreciate that many modifications are possible in the exemplary embodiments and/or examples without materially departing from the novel teachings and advantages of this invention. Accordingly, all such modifications are intended to be included within the scope of this invention.

The documents described in the specification and the specification of Japanese application(s) on the basis of which the present application claims Paris convention priority are incorporated herein by reference in its entirety.

1 An organic electroluminescence device comprising
a cathode,
an anode, and
one or two or more organic layers arranged between the cathode and the anode,
wherein at least one layer of the one or two or more organic layers
comprises a first component and a second component,
the first component is a compound represented by the following formula (1),
the second component is a compound represented by the following formula (2): 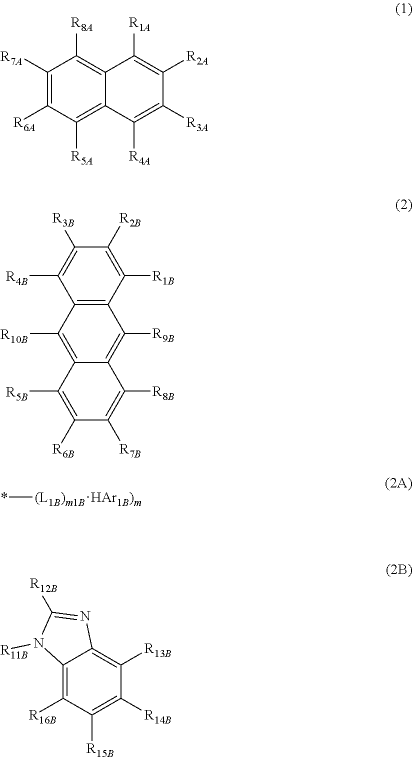
wherein in the formula (1),
one or more sets of the adjacent two or more of R_{1A} to R_{8A} form a substituted or unsubstituted single ring by bonding with each other, or form a substituted or unsubstituted fused ring by bonding with each other;
provided that when at least one set of a set of R_{4A} and R_{5A}, and a set of R_{8A} and R_{1A} is bonded, it is excluded that the compound represented by the formula (1) is a compound having a structure represented by the following formula (1A): 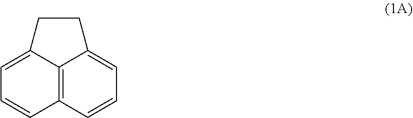 [SMILES: c1cc2c3c(cccc3c1)CC2]
R_{1A} to R_{8A} which do not form the substituted or unsubstituted single ring and which do not form the substituted or unsubstituted fused ring are independently a hydrogen atom or a substituent R;
the substituent R is
a substituted or unsubstituted alkyl group having 1 to 50 carbon atoms,
a substituted or unsubstituted alkenyl group having 2 to 50 carbon atoms,
a substituted or unsubstituted alkynyl group having 2 to 50 carbon atoms,
a substituted or unsubstituted cycloalkyl group having 3 to 50 ring carbon atoms,
—Si(R₉₀₁)(R₉₀₂)(R₉₀₃),
—O—(R₉₀₄),
—S—(R₉₀₅),
—N(R₉₀₆)(R₉₀₇)
(wherein R₉₀₁ to R₉₀₇ are independently
a hydrogen atom,
a substituted or unsubstituted alkyl group having 1 to 50 carbon atoms,
a substituted or unsubstituted cycloalkyl group having 3 to 50 ring carbon atoms,
a substituted or unsubstituted aryl group having 6 to 50 ring carbon atoms, or
a substituted or unsubstituted monovalent heterocyclic group having 5 to 50 ring atoms;
when two or more of each of R₉₀₁ to R₉₀₇ are present, the two or more of each of R₉₀₁ to R₉₀₇ may be the same as or different from each other),
a halogen atom, a cyano group, a nitro group,
a substituted or unsubstituted aryl group having 6 to 50 ring carbon atoms, or
a substituted or unsubstituted monovalent heterocyclic group having 5 to 50 ring atoms;
when two or more substituents R are present, the two or more substituents R may be the same as or different from each other;
provided that the compound represented by the formula (1) does not have a structure represented by the following formula (1B), a structure represented by the following formula (1C), and a structure represented by the following formula (1 D) within a molecular thereof: 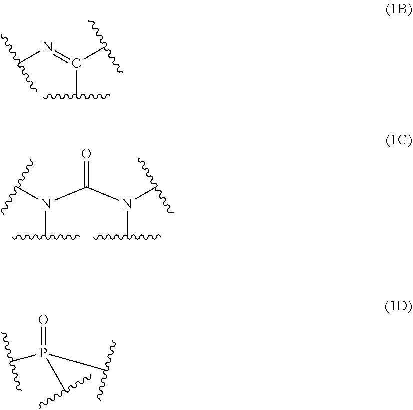 [SMILES: *N=C(*)* ; *N(*)C(=O)N(*)* ; *P(*)(*)=O]
wherein in the formula (2),
at least one of R_{1B} to R_{10B} is a group represented by the formula (2A);
one or more sets of the adjacent two or more of R_{1B} to R_{10B} which are not the group represented by the formula (2A) form a substituted or unsubstituted single ring by bonding with each other, form a substituted or unsubstituted fused ring by bonding with each other, or do not bond with each other;
R_{1B} to R_{10B} which are not the group represented by the formula (2A) and which do not bond with each other are independently a hydrogen atom or a substituent R;
in the formula (2A),
HAr_{1B} is a group represented by the formula (2B); m is an integer of 1 to 5; when two or more HAr_{1B}'s are present, the two or more HAr_{1B}'s may be the same as or different from each other;
m1B is an integer of 0 to 3; when m1 B is 0, m is 1 and HAr_{1B} is directly bonded with the anthracene skeleton in the formula (2) via a single bond; when m1B is 2 or 3, a plurality of L_{1B}'s is linked in series with each other and HAr_{1B} is bonded with L_{1B} which is farthest from the anthracene skeleton; when two or more L_{1B}'s are present, one or more sets of the adjacent two or more of the two or more L_{1B}'s form a substituted or unsubstituted single ring by bonding with each other, form a substituted or unsubstituted fused ring by bonding with each other, or do not bond with each other; when two or more L_{1B}'s are present, the two or more L_{1B}'s may be the same as or different from each other;
L_{1B} which does not form the ring is
a substituted or unsubstituted aromatic hydrocarbon group having 6 to 30 ring carbon atoms, or
a substituted or unsubstituted heterocyclic group having 5 to 30 ring atoms;
in the formula (2B),
any one of R_{11B} to R_{16B} represents a bond with L_{1B} in the formula (2A); when ml B is 0, any of carbon atoms and nitrogen atoms in the benzimidazole and any of carbon atoms in the anthracene skeleton of the formula (2) are directly bonded via a single bond;
one or more sets of the adjacent two or more of R_{11B} to R_{16B} which do not represent a bond with L_{1B} form a substituted or unsubstituted single ring by bonding with each other, form a substituted or unsubstituted fused ring by bonding with each other, or do not bond with each other;
R_{11B} to R_{16B} which do not represent a bond with L_{1B} and which do not bond with each other are independently a hydrogen atom or a substituent R; and
the substituent R is the same as defined in the formula (1).

2. The organic electroluminescence device according to claim 1, wherein the substituted or unsubstituted single ring or the substituted or unsubstituted fused ring is a substituted or unsubstituted aromatic hydrocarbon ring having 6 to 30 ring carbon atoms, or a substituted or unsubstituted heterocycle having 5 to 30 ring atoms.

3. The organic electroluminescence device according to claim 1, wherein the compound represented by the formula (1) is a compound having a structure in which three to five rings are fused, the three to five rings are independently a ring selected from the group consisting of a five-membered ring and a six-membered ring, and the compound may have a substituent.

4. The organic electroluminescence device according to claim 1, wherein the compound represented by the formula (1) is a compound having the molecular weight of 400 to 700.

5. The organic electroluminescence device according to claim 1, wherein the compound represented by the formula (1) is a compound represented by any one of the following formulas (1-1) to (1-7): 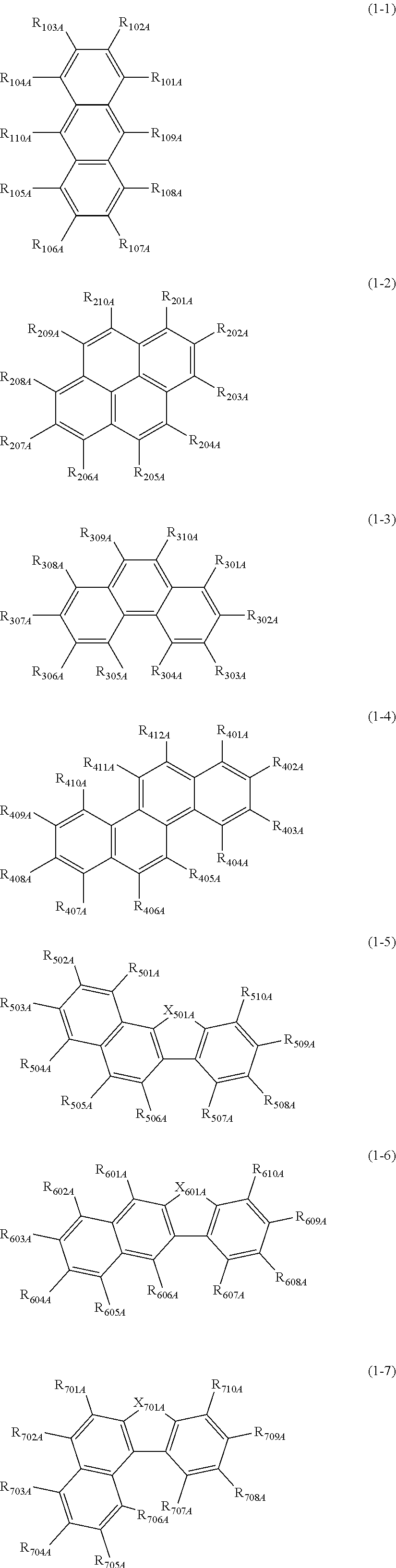
wherein in the formula (1-1),
one or more sets of the adjacent two or more of R_{101A} to R_{110A} do not bond with each other;
R_{101A} to R_{110A} are independently
a hydrogen atom,
a substituent R, or
a group represented by the following formula (11):
Ar₁₀₁-L₁₀₁- (11)
wherein in the formula (11),
L₁₀₁ is
a single bond,
a substituted or unsubstituted arylene group having 6 to 50 ring carbon atoms, or
a substituted or unsubstituted divalent heterocyclic group having 5 to 50 ring atoms;
Ar₁₀₁ is
a substituted or unsubstituted aryl group having 6 to 50 ring carbon atoms, or
a substituted or unsubstituted monovalent heterocyclic group having 5 to 50 ring atoms;
when two or more groups represented by the formula (11) are present, the two or more groups represented by the formula (11) may be the same as or different from each other;
in the formula (1-2),
one or more sets of the adjacent two or more of R_{2o1A} to R_{210A} do not bond with each other;
R_{201A} to R_{210A} are independently
a hydrogen atom,
a substituent R, or
the group represented by the formula (11);
in the formula (1-3),
one or more sets of the adjacent two or more of R_{301A} to R_{310A} do not bond with each other;
R_{301A} to R_{310A} are independently
a hydrogen atom,
a substituent R, or
the group represented by the formula (11);
in the formula (1-4),
one or more sets of the adjacent two or more of R_{401A} to R_{412A} do not bond with each other;
R_{401A} to R_{412A} are independently
a hydrogen atom,
a substituent R, or
the group represented by the formula (11);
in the formula (1-5),
X₅₀₁A is C(R_{511A})(R_{512A}), N(R_{513A}), O, or S;
one or more sets of the adjacent two or more of R_{501A} to R_{510A} do not bond with each other;
R_{501A} to R_{510A} are independently
a hydrogen atom,
a substituent R, or
the group represented by the formula (11);
R_{511A} to R_{513A} are independently a hydrogen atom or a substituent R;
in the formula (1-6),
X₆₀₁A is C(R_{611A})(R_{612A}), N(R_{613A}), O, or S;
one or more sets of the adjacent two or more of R_{601A} to R_{610A} do not bond with each other;
R₆₀₁A to R_{610A} are independently
a hydrogen atom,
a substituent R, or
the group represented by the formula (11);
R_{611A} to R_{613A} are independently a hydrogen atom or a substituent R;
in the formula (1-7),
X₇₀₁A is C(R_{711A})(R_{712A}), N(R_{713A}), O, or S;
one or more sets of the adjacent two or more of R_{701A} to R_{710A} do not bond with each other;
R_{701A} to R_{710A} are independently
a hydrogen atom,
a substituent R, or
the group represented by the formula (11);
R_{711A} to R_{713A} are independently a hydrogen atom or a substituent R; and
the substituent R is the same as defined in the formula (1).

6. The organic electroluminescence device according to claim 1, wherein the compound represented by the formula (1) is a compound represented by the following formula (1-11): 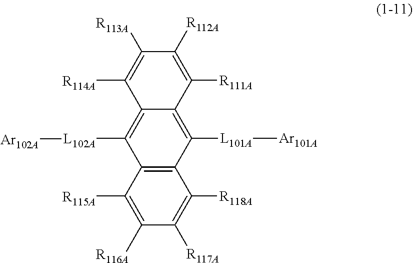
wherein in the formula (1-11),
R_{111A} to R_{118A} are independently a hydrogen atom or a substituent R;
L_{101A} and L_{102A} are independently
a single bond,
a substituted or unsubstituted arylene group having 6 to 50 ring carbon atoms, or
a substituted or unsubstituted divalent heterocyclic group having 5 to 50 ring atoms;
Ar_{101A} and Ar_{102A} are independently
a substituted or unsubstituted aryl group having 6 to 50 ring carbon atoms, or
a substituted or unsubstituted monovalent heterocyclic group having 5 to 50 ring atoms; and
the substituent R is the same as defined in the formula (1).

7. The organic electroluminescence device according to claim 1, wherein the compound represented by the formula (1) is a compound represented by the following formula (1-12): 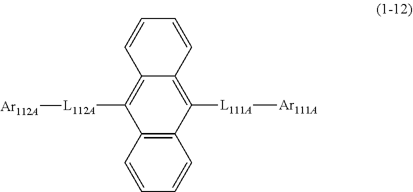
wherein in the formula (1-12),
L_{111A} and L_{112A} are independently
a single bond,
a substituted or unsubstituted arylene group having 6 to 18 ring carbon atoms, or
a substituted or unsubstituted divalent heterocyclic group having 5 to 18 ring atoms; and
Ar_{111A} and Ar_{112A} are independently
a substituted or unsubstituted aryl group having 6 to 18 ring carbon atoms, or
a substituted or unsubstituted monovalent heterocyclic group having 5 to 18 ring atoms.

8. The organic electroluminescence device according to claim 1, wherein the compound represented by the formula (1) is a compound represented by the following formula (1-21): 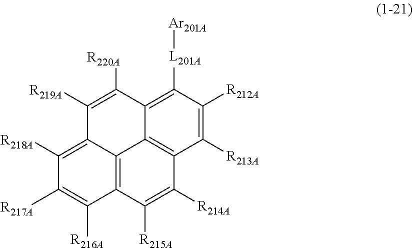
wherein in the formula (1-21),
one or more sets of the adjacent two or more of R_{212A} to R_{220A} do not bond with each other;
R_{212A} to R_{220A} are independently a hydrogen atom or a substituent R;
L₂₀₁A is
a single bond,
a substituted or unsubstituted arylene group having 6 to 50 ring carbon atoms, or
a substituted or unsubstituted divalent heterocyclic group having 5 to 50 ring atoms;
Ar_{201 A} is
a substituted or unsubstituted aryl group having 6 to 50 ring carbon atoms, or
a substituted or unsubstituted monovalent heterocyclic group having 5 to 50 ring atoms; and
the substituent R is the same as defined in the formula (1).

9. The organic electroluminescence device according to claim 1, wherein the compound represented by the formula (1) is a compound represented by the following formula (1-22): 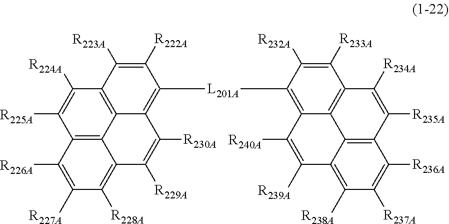
wherein in the formula (1-22),
one or more sets of the adjacent two or more of R_{222A} to R_{230A} and R_{232A} to R_{240A} do not bond with each other;
R_{222A} to R_{230A} and R_{232A} to R_{240A} are independently a hydrogen atom or a substituent R;
L₂₀₁A is
a single bond,
a substituted or unsubstituted arylene group having 6 to 50 ring carbon atoms, or
a substituted or unsubstituted divalent heterocyclic group having 5 to 50 ring atoms; and
the substituent R is the same as defined in the formula (1).

10. The organic electroluminescence device according to claim 9, wherein R_{222A} to R_{230A} and R_{232A} to R_{240A} are hydrogen atoms.

11. The organic electroluminescence device according to claim 8, wherein L_{201A} is a substituted or unsubstituted arylene group having 6 to 50 ring carbon atoms.

12. The organic electroluminescence device according to claim 1, wherein the compound represented by the formula (1) is a substituted or unsubstituted aromatic hydrocarbon compound.

13. The organic electroluminescence device according to claim 1, wherein the compound represented by the formula (1) is a compound represented by the following formula (1-61): 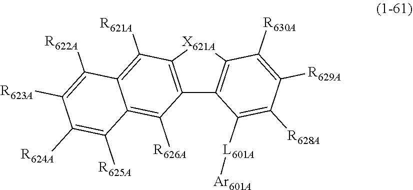
wherein in the formula (1-61),
X_{621A} is C(R_{611A})(R_{612A}), N(R_{613A}), O, or S;
one or more sets of the adjacent two or more of R_{621A} to R_{626A} and R_{628A} to R_{630A} do not bond with each other;
R_{611A} to R_{613A}, R_{621A} to R_{626A}, and R_{628A} to R_{630A} are independently a hydrogen atom or a substituent R;
L_{601A} is
a single bond,
a substituted or unsubstituted arylene group having 6 to 50 ring carbon atoms, or
a substituted or unsubstituted divalent heterocyclic group having 5 to 50 ring atoms;
Ar_{601A} is
a substituted or unsubstituted aryl group having 6 to 50 ring carbon atoms, or
a substituted or unsubstituted monovalent heterocyclic group having 5 to 50 ring atoms; and
the substituent R is the same as defined in the formula (1).

14. The organic electroluminescence device according to claim 1, wherein the compound represented by the formula (1) is a compound represented by the following formula (1-62): 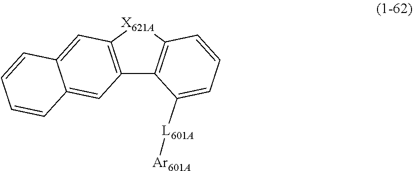
wherein in the formula (1-62),
X_{621A} is C(R_{611A})(R_{612A}), N(R_{613A}), O, or S;
R_{611A} to R_{613A} are independently a hydrogen atom or a substituent R;
L_{601A} is
a single bond,
a substituted or unsubstituted arylene group having 6 to 50 ring carbon atoms, or
a substituted or unsubstituted divalent heterocyclic group having 5 to 50 ring atoms;
Ar_{601A} is
a substituted or unsubstituted aryl group having 6 to 50 ring carbon atoms, or
a substituted or unsubstituted monovalent heterocyclic group having 5 to 50 ring atoms; and
the substituent R is the same as defined in the formula (1).

15. The organic electroluminescence device according to claim 13, wherein L_{601A} is a substituted or unsubstituted arylene group having 6 to 50 ring carbon atoms.

16. The organic electroluminescence device according to claim 13, wherein Ar_{601A} is a substituted or unsubstituted aryl group having 6 to 50 ring carbon atoms.

17. The organic electroluminescence device according to claim 1, wherein in the formula (2B), any one of R_{11B} to R_{13B} and R_{16B} represents a bond with L_{1B} in the formula (2A).

18. The organic electroluminescence device according to claim 1, wherein in the formula (2B), R_{11B} represents a bond with L_{1B} in the formula (2A).

19. The organic electroluminescence device according to claim 1, wherein in the formula (2), at least one of R_{1B}, R_{4B}, R_{5B}, and R_{9B} to R_{10B} is the group represented by the formula (2A).

20. The organic electroluminescence device according to claim 1, wherein in the formula (2), at least one of R_{9B} and R_{10B} is the group represented by the formula (2A).

21. The organic electroluminescence device according to claim 1, wherein in the formula (2), one or more sets of the adjacent two or more of R_{1B} to R_{10B} do not bond with each other.

22. The organic electroluminescence device according to claim 1, wherein in the formula (2), R_{1B} to R_{8B} are hydrogen atoms.

23. The organic electroluminescence device according to claim 1, wherein the compound represented by the formula (2) is a compound represented by the following formula (2-1): 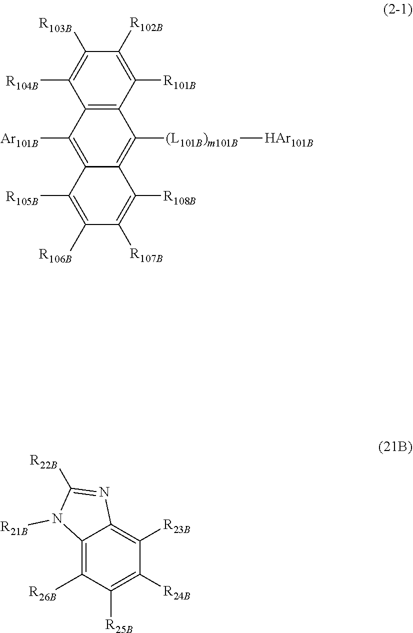
wherein in the formula (2-1),
one or more sets of the adjacent two or more of R_{101B} to R_{108B} form a substituted or unsubstituted single ring by bonding with each other, form a substituted or unsubstituted fused ring by bonding with each other, or do not bond with each other;
R_{101B} to R₁₀₈B which do not bond with each other are independently a hydrogen atom or a substituent R;
HAr_{101B} is a group represented by the formula (21B);
L_{101B} is
a substituted or unsubstituted aromatic hydrocarbon group having 6 to 30 ring carbon atoms, or
a substituted or unsubstituted heterocyclic group having 5 to 30 ring atoms;
m101B is an integer of 0 to 3; when m101B is 0, HAr_{101B} is directly bonded with the anthracene skeleton in the formula (2-1) via a single bond; when m101B is 2 or 3, a plurality of L_{101B}'s is linked in series with each other and HAr_{101B} is bonded with LioiB which is farthest from the anthracene skeleton; when two or more L_{101B}'s are present, the two or more L_{101B}'s may be the same as or different from each other;
one or more sets of the adjacent two or more of m101B Lioi_{B}'s and HAr_{101B} do not bond with each other;
in the formula (21B),
any one of R_{21B} to R_{26B} represents a bond with L_{101B} in the formula (2-1); when m101B is 0, any of carbon atoms and nitrogen atoms in the benzimidazole and any of carbon atoms in the anthracene skeleton of the formula (2-1) are directly bonded via a single bond;
R_{21B} to R_{26B} which do not represent a bond with L_{101B} are independently a hydrogen atom or a substituent R; one or more sets of the adjacent two or more of R_{21B} to R_{26B} do not bond with each other;
Ar_{101B} is
a substituted or unsubstituted aryl group having 6 to 30 ring carbon atoms, or
a substituted or unsubstituted monovalent heterocyclic group having 5 to 30 ring atoms; and
the substituent R is the same as defined in the formula (1).

24. The organic electroluminescence device according to claim 23, wherein the compound represented by the formula (2-1) is a compound represented by the following formula (2-11): 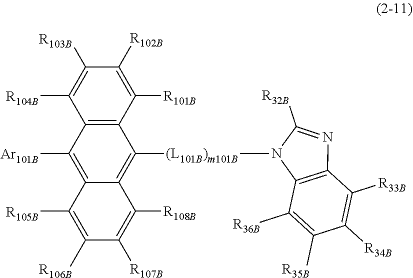
wherein in the formula (2-11),
R₁₀₁B to R_{108B,} L_{101B}, m101B, and AR_{101B} are the same as defined in the formula (2-1);
R_{32B} to R_{36B} are independently a hydrogen atom or a substituent R; one or more sets of the adjacent two or more of R_{32B} to R_{36B} do not bond with each other; and
the substituent R is the same as defined in the formula (1).

25. The organic electroluminescence device according to claim 23, wherein m101B is 1.

26. The organic electroluminescence device according to claim 23, wherein the compound represented by the formula (2-1) is a compound represented by the following formula (2-12): 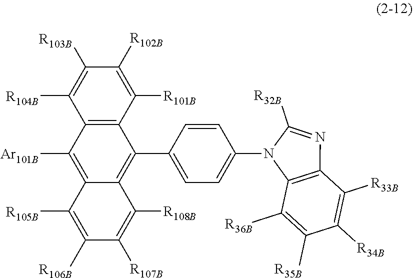
wherein in the formula (2-12), R_{101B} to R_{108B} and Ar_{101B} are the same as defined in the formula (2-1);
R_{32B} to R_{36B} are independently a hydrogen atom or a substituent R; one or more sets of the adjacent two or more of R_{32B} to R_{36B} do not bond with each other; and
the substituent R is the same as defined in the formula (1).

27. The organic electroluminescence device according to claim 23, wherein the compound represented by the formula (2-1) is a compound represented by the following formula (2-13): 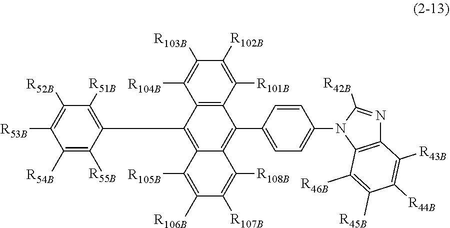
wherein in the formula (2-13),
R_{101B} to R_{108B} are the same as defined in the formula (2-1);
R_{42B} to R_{46B} are independently
a hydrogen atom, or
a substituted or unsubstituted alkyl group having 1 to 50 carbon atoms;
one or more sets of the adjacent two or more of R_{51B} to R_{55B} form a substituted or unsubstituted single ring by bonding with each other, form a substituted or unsubstituted fused ring by bonding with each other, or do not bond with each other; and
R_{51B} to R_{55B} which do not bond with each other are independently
a hydrogen atom,
a substituted or unsubstituted alkyl group having 1 to 50 carbon atoms,
a substituted or unsubstituted aryl group having 6 to 50 ring carbon atoms, or
a substituted or unsubstituted monovalent heterocyclic group having 5 to 50 ring atoms.

28. The organic electroluminescence device according to claim 27, wherein the compound represented by the formula (2-13) is a compound represented by the following formula (2-14): 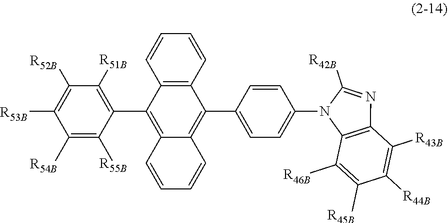
wherein in the formula (2-14), R_{42B} to R_{46B} and R_{51B} to R_{55B} are the same as defined in the formula (2-13).

29. The organic electroluminescence device according to claim 1, wherein the amount of the first component is 30 to 70% by mass based on the total amount of the first component and the second component.

30. The organic electroluminescence device according to claim 1, wherein the at least one layer of the one or two or more organic layers further comprises one or more members selected from the group consisting of an alkali metal, an alkali metal compound, an alkaline earth metal, an alkaline earth metal compound, a rare earth metal, a rare earth metal compound, an organic metal complex containing an alkali metal, an organic metal complex containing an alkaline earth metal, and an organic metal complex containing a rare earth metal.

31. The organic electroluminescence device according to claim 1, wherein the at least one layer of the one or two or more organic layers substantially does not comprise an alkali metal, an alkali metal compound, an alkaline earth metal, an alkaline earth metal compound, a rare earth metal, a rare earth metal compound, an organic metal complex containing an alkali metal, an organic metal complex containing an alkaline earth metal, and an organic metal complex containing a rare earth metal.

32. The organic electroluminescence device according to claim 1, which comprises the anode, an emitting layer, an electron-transporting region, and the cathode in this order, and at least one layer in the electron-transporting region comprises the first component and the second component.

33. The organic electroluminescence device according to claim 32, wherein the electron-transporting region comprises at least a first layer and a second layer in this order from the emitting layer side, and
the second layer comprises the first component and the second component.

34. The organic electroluminescence device according to claim 33, wherein the second layer substantially does not comprise the compound having the structure represented by the formula (1 B) within a molecular thereof, the compound having the structure represented by the formula (1C) within a molecular thereof, and the compound having the structure represented by the formula (1D) within a molecular thereof.

35. The organic electroluminescence device according to claim 33, wherein the second layer substantially consists of the first component and the second component.

36. An electronic apparatus, comprising the organic electroluminescence device according to claim 1.

37. A composition comprising a first component and a second component,
the first component is a compound represented by the following formula (1),
the second component is a compound represented by the following formula (2): 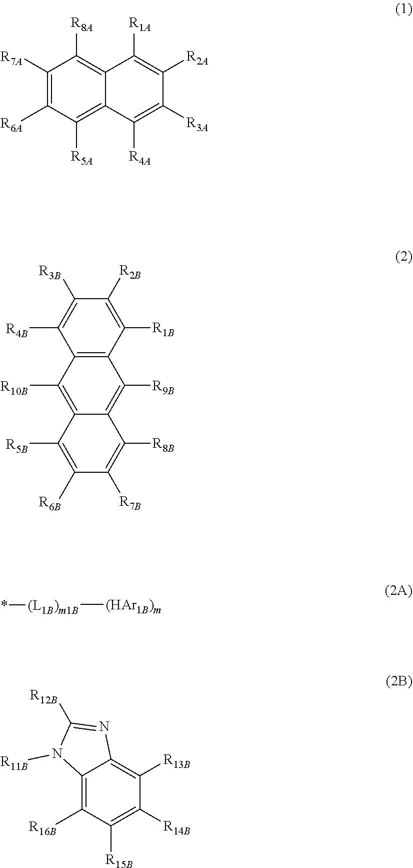
wherein in the formula (1),
one or more sets of the adjacent two or more of R_{1A} to R_{8A} form a substituted or unsubstituted single ring by bonding with each other, or form a substituted or unsubstituted fused ring by bonding with each other;
provided that when at least one set of a set of R_{4A} and R_{SA}, and a set of R_{8A} and R_{1A} is bonded, it is excluded that the compound represented by the formula (1) is a compound having a structure represented by the following formula (1A): 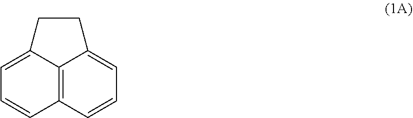 [SMILES: c1cc2c3c(cccc3c1)CC2]
R_{1A} to R_{8A} which do not form the substituted or unsubstituted single ring and which do not form the substituted or unsubstituted fused ring are independently a hydrogen atom or a substituent R;
the substituent R is
a substituted or unsubstituted alkyl group having 1 to 50 carbon atoms,
a substituted or unsubstituted alkenyl group having 2 to 50 carbon atoms,
a substituted or unsubstituted alkynyl group having 2 to 50 carbon atoms,
a substituted or unsubstituted cycloalkyl group having 3 to 50 ring carbon atoms,
—Si(R₉₀₁)(R₉₀₂)(R₉₀₃),
—O—(R₉₀₄),
—S—(R₉₀₅),
—N(R₉₀₆)(R₉₀₇)
(wherein R₉₀₁ to R₉₀₇ are independently
a hydrogen atom,
a substituted or unsubstituted alkyl group having 1 to 50 carbon atoms,
a substituted or unsubstituted cycloalkyl group having 3 to 50 ring carbon atoms,
a substituted or unsubstituted aryl group having 6 to 50 ring carbon atoms, or
a substituted or unsubstituted monovalent heterocyclic group having 5 to 50 ring atoms;
when two or more of each of R₉₀₁ to R₉₀₇ are present, the two or more of each of R₉₀₁ to R₉₀₇ may be the same as or different from each other),
a halogen atom, a cyano group, a nitro group,
a substituted or unsubstituted aryl group having 6 to 50 ring carbon atoms, or
a substituted or unsubstituted monovalent heterocyclic group having 5 to 50 ring atoms;
when two or more substituents R are present, the two or more substituents R may be the same as or different from each other;
provided that the compound represented by the formula (1) does not have a structure represented by the following formula (1B), a structure represented by the following formula (1C), and a structure represented by the following formula (1 D) within a molecular thereof: 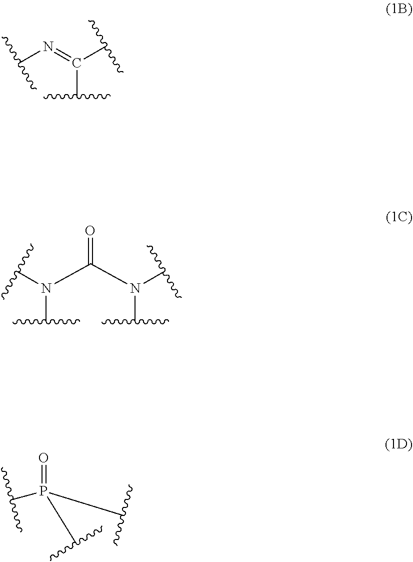 [SMILES: *N=C(*)* ; *N(*)C(=O)N(*)* ; *P(*)(*)=O]
wherein in the formula (2),
at least one of R_{1B} to R_{10B} is a group represented by the formula (2A);
one or more sets of the adjacent two or more of R_{1B} to R_{10B} which are not the group represented by the formula (2A) form a substituted or unsubstituted single ring by bonding with each other, form a substituted or unsubstituted fused ring by bonding with each other, or do not bond with each other;
R_{1B} to R_{10B} which are not the group represented by the formula (2A) and which do not bond with each other are independently a hydrogen atom or a substituent R;
in the formula (2A),
HAr_{1B} is a group represented by the formula (2B); m is an integer of 1 to 5; when two or more HAr_{1B}'s are present, the two or more HAr_{1B}'s may be the same as or different from each other;
L_{1B} is
a substituted or unsubstituted aromatic hydrocarbon group having 6 to 30 ring carbon atoms, or
a substituted or unsubstituted heterocyclic group having 5 to 30 ring atoms;
m1B is an integer of 0 to 3; when m1 B is 0, m is 1 and HAr_{1B} is directly bonded with the anthracene skeleton in the formula (2) via a single bond; when m1B is 2 or 3, a plurality of L_{1B}'s is linked in series with each other and HAr_{1B} is bonded with L_{1B} which is farthest from the anthracene skeleton; when two or more L_{1B}'s are present, the two or more L_{1B}'s may be the same as or different from each other;
in the formula (2B),
any one of R_{11B} to R_{16B} represents a bond with L_{1B} in the formula (2A); when m1B is 0, any of carbon atoms and nitrogen atoms in the benzimidazole and any of carbon atoms in the anthracene skeleton of the formula (2) are directly bonded via a single bond;
one or more sets of the adjacent two or more of R_{11B} to R_{16B} which do not represent a bond with L_{1B} form a substituted or unsubstituted single ring by bonding with each other, form a substituted or unsubstituted fused ring by bonding with each other, or do not bond with each other;
R_{11B} to R_{16B} which do not represent a bond with L_{1B} and which do not bond with each other are independently a hydrogen atom or a substituent R; and
the substituent R is the same as defined in the formula (1).
